(19) United States
(12) Patent Application Publication
(10) Pub. No.: US 2024/0008356 A1
(43) Pub. Date: Jan. 4, 2024

(54) ORGANIC ELECTROLUMINESCENT MATERIAL AND DEVICE THEREOF

(71) Applicant: BEIJING SUMMER SPROUT TECHNOLOGY CO., LTD., Beijing (CN)

(72) Inventors: Nannan Lu, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 18/216,253

(22) Filed: Jun. 29, 2023

(30) Foreign Application Priority Data
Jun. 30, 2022 (CN) 202210755442.1
Apr. 19, 2023 (CN) 202310421323.7

(51) Int. Cl. H10K 85/30; C09K 11/06; C07F 15/00

(52) U.S. Cl. CPC H10K 85/342; C09K 11/06; H10K 50/12; C09K 2211/185; C09K 2211/1033; C07F 15/0033

(57) ABSTRACT

Provided are an organic electroluminescent material and a device comprising the same. The organic electroluminescent material is a metal complex comprising a metal M and a ligand Lₐ having a structure of Formula 1, and the metal complex can be applied to an electroluminescent device as a light-emitting material. The metal complex is applied to the electroluminescent device so that the metal complex, while maintaining a very narrow full width at half maximum, can effectively adjust a light emission wavelength to better meet a requirement of saturated red light emission and can obtain higher device efficiency at a lower voltage, thereby providing better device performance. Further provided are an electroluminescent device comprising the metal complex and a compound composition comprising the metal complex.

### CROSS-REFERENCE TO RELATED APPLICATION(S)

This application claims priority to Chinese Patent Application No. 202210755442.1 filed on Jun. 30, 2022 and Chinese Patent Application No. 202310421323.7 filed on Apr. 19, 2023, the disclosure of which are incorporated herein by reference in their entireties.

### TECHNICAL FIELD

The present disclosure relates to compounds for organic electronic devices such as organic electroluminescent devices. More particularly, the present disclosure relates to a metal complex comprising a ligand Lₐ having a structure of Formula 1 and an electroluminescent device and compound composition comprising the metal complex.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which includes an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may include multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may include one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

Phosphorescent metal complexes can be used as phosphorescent doping materials of light-emitting layers and applied to the field of organic electroluminescence lighting or display. To meet requirements in different cases, a color of a material can be adjusted on a certain basis by adjusting a structure type of a ligand of the material so that phosphorescent metal complexes with different emission wavelengths are obtained.

The previous patent application CN114437134A of the applicant of the present disclosure has disclosed a metal complex having a structure of

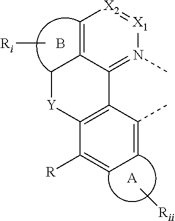

and discloses the compound

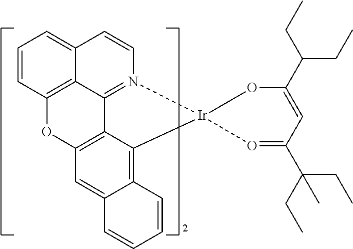

in a specific structure. This patent application does not disclose or teach an effect on device performance when a fused ring system formed by fusing rings is further introduced at a particular position of an isoquinoline ring or other fused heteroaromatic rings.

The currently developed metal complexes still have various deficiencies in performance when used in electroluminescent devices. To meet the increasing requirements of the industry such as higher current efficiency, higher power efficiency and a longer device lifetime, the research and development related to metal complexes still needs to be deepened.

### SUMMARY

The present disclosure aims to provide a series of new metal complexes to solve at least part of the above-mentioned problems. The metal complex comprises a metal M and a ligand Lₐ having a structure of Formula 1. When the metal complex is applied to an organic electroluminescent device as a light-emitting material, the metal complex, while maintaining a very narrow full width at half maximum, can effectively adjust a light emission wavelength to better meet a requirement of saturated red light emission and obtain higher device efficiency at a lower voltage, thereby providing better device performance.

According to an embodiment of the present disclosure, disclosed is a metal complex, which comprises a metal M and a ligand Lₐ coordinated to the metal M, wherein the metal M is selected from a metal with a relative atomic mass greater than 40, and the ligand Lₐ has a structure represented by Formula 1:

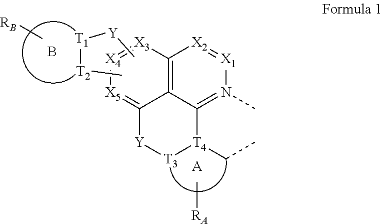

wherein the ring A and the ring B are each independently selected from a five-membered unsaturated carbocyclic ring, an aromatic ring having 6 to 30 carbon atoms or a heteroaromatic ring having 3 to 30 carbon atoms, and when the ring A is a monocyclic ring, the ring A is selected from a five-membered unsaturated carbocyclic ring, a benzene ring or a six-membered heteroaromatic ring;
Y is, at each occurrence identically or differently, selected from CR_{y}R_{y}, SiR_{y}R_{y}, GeR_{y}R_{y}, NR_{y}, PR_{y}, O, S or Se; when a plurality of R_{y} are present at the same time, the plurality of R_{y} are identical or different;
R_{A} and R_{B} represent, at each occurrence identically or differently, mono-substitution, multiple substitutions or non-substitution;
T₁ to T₄ are, at each occurrence identically or differently, selected from C or N;
X₁ and X₂ are, at each occurrence identically or differently, selected from CRₓ or N; X₃ to X₅ are, at each occurrence identically or differently, selected from C, CRₓ or N, and any adjacent two of X₃ to X₅ are C and joined to Y and T₂, respectively;
R_{A}, R_{B}, Rₓ and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R_{A}, R_{B}, Rₓ and R_{y} can be optionally joined to form a ring.

According to another embodiment of the present disclosure, disclosed is an electroluminescent device, which comprises an anode, a cathode and an organic layer disposed between the anode and the cathode, wherein the organic layer comprises the metal complex in the preceding embodiment.

According to another embodiment of the present disclosure, further disclosed is a compound composition, which comprises the metal complex in the preceding embodiment.

The present disclosure discloses a type of metal complex comprising the metal M and the ligand Lₐ having the structure of Formula 1. When this type of metal complex is used as the light-emitting material of the organic electroluminescent device, the device can have a very narrow full width at half maximum and saturated red light emission, and the current efficiency, power efficiency and external quantum efficiency of the device are improved at a low voltage, thereby significantly improving the overall performance of the device.

### BRIEF DESCRIPTION OF DRAWINGS

FIG. 1 is a schematic diagram of an organic light-emitting apparatus that may comprise a metal complex and a compound composition disclosed herein.

FIG. 2 is a schematic diagram of another organic light-emitting apparatus that may comprise a metal complex and a compound composition disclosed herein.

### DETAILED DESCRIPTION

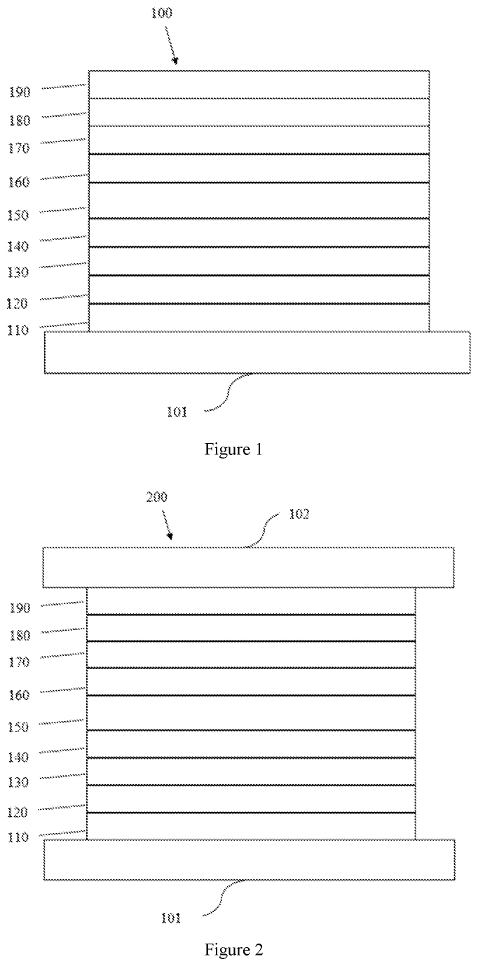

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (Δ_{ES-T}). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small Δ_{ES-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, a n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butylmethylgermanylmethyl, triethylgermanylmethyl, triethylgermanylethyl, triisopropylgermanylmethyl, triisopropylgermanylethyl, trimethylsilylmethyl, trimethylsilylethyl, and trimethylsilylisopropyl, triisopropylsilylmethyl, triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups includes saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more moieties selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl having 3 to 20 carbon atoms, unsubstituted arylgermanyl having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitution refers to a range that includes a di-substitution, up to the maximum available substitution. When substitution in the compounds mentioned in the present disclosure represents multiple substitution (including di-, tri-, and tetra-substitutions, etc.), that means the substituent may exist at a plurality of available substitution positions on its linking structure, the substituents present at a plurality of available substitution positions may be the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

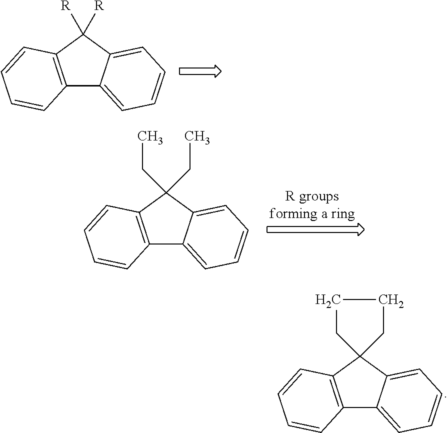

The expression that adjacent substituents can be optionally joined to form a ring is also intended to mean that two substituents bonded to carbon atoms which are directly bonded to each other are joined to each other via a chemical bond to form a ring, which can be exemplified by the following formula:

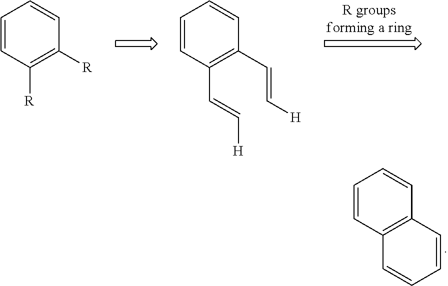

The expression that adjacent substituents can be optionally joined to form a ring is also intended to mean that two substituents bonded to a further distant carbon atom are joined to each other via a chemical bond to form a ring, which can be exemplified by the following formula:

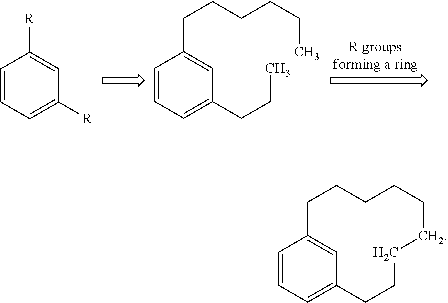

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

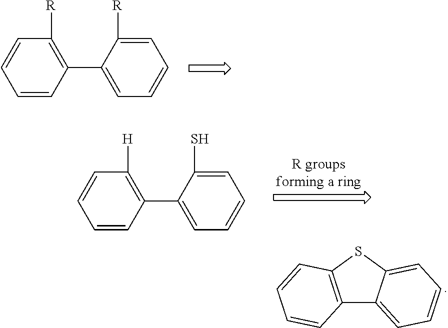

According to an embodiment of the present disclosure, disclosed is a metal complex, which comprises a metal M and a ligand Lₐ coordinated to the metal M, wherein the metal M is selected from a metal with a relative atomic mass greater than 40, and the ligand Lₐ has a structure represented by Formula 1:

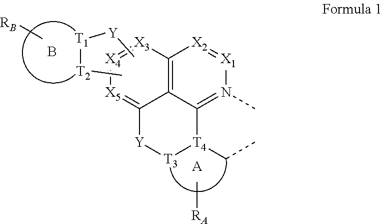

wherein the ring A and the ring B are each independently selected from a five-membered unsaturated carbocyclic ring, an aromatic ring having 6 to 30 carbon atoms or a heteroaromatic ring having 3 to 30 carbon atoms, and when the ring A is a monocyclic ring, the ring A is selected from a five-membered unsaturated carbocyclic ring, a benzene ring or a six-membered heteroaromatic ring;
Y is, at each occurrence identically or differently, selected from CR_{y}R_{y}, SiR_{y}R_{y}, GeR_{y}R_{y}, NR_{y}, PR_{y}, O, S or Se; when a plurality of R_{y} are present at the same time, the plurality of R_{y} are identical or different;
R_{A} and R_{B} represent, at each occurrence identically or differently, mono-substitution, multiple substitutions or non-substitution;
T₁ to T₄ are, at each occurrence identically or differently, selected from C or N;
X₁ and X₂ are, at each occurrence identically or differently, selected from CRₓ or N; X₃ to X₅ are, at each occurrence identically or differently, selected from C, CRₓ or N, and any adjacent two of X₃ to X₅ are C and joined to Y and T₂, respectively (for example, X₃ and X₄ are selected from C and joined to Y and T₂ respectively, X₅ is selected from CRₓ or N; for another example, X₄ and X₅ are selected from C and joined to Y and T₂ respectively, X₃ is selected from CRₓ or N);
R_{A}, R_{B}, Rₓ and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R_{A}, R_{B}, Rₓ and R_{y} can be optionally joined to form a ring.

In this embodiment, the expression that “adjacent substituents R_{A}, R_{B}, Rₓ and R_{y} can be optionally joined to form a ring” is intended to mean that any one or more of groups of adjacent substituents, such as adjacent substituents R_{A}, adjacent substituents R_{B}, adjacent substituents Rₓ, adjacent substituents R_{y}, adjacent substituents Rₓ and R_{y}, adjacent substituents Rₓ and R_{B}, adjacent substituents R_{y} and R_{B}, and adjacent substituents R_{y} and R_{A}, can be joined to form a ring. Obviously, it is also possible that none of these groups of substituents are joined to form a ring.

In this embodiment, “the ring A and the ring B are each independently selected from a five-membered unsaturated carbocyclic ring, an aromatic ring having 6 to 30 carbon atoms or a heteroaromatic ring having 3 to 30 carbon atoms, and when the ring A is a monocyclic ring, the ring A is selected from a five-membered unsaturated carbocyclic ring, a benzene ring or a six-membered heteroaromatic ring”, wherein “an aromatic ring having 6 to 30 carbon atoms or a heteroaromatic ring having 3 to 30 carbon atoms” includes a plurality of cases such as a monocyclic ring, a polycyclic ring and a fusedcyclic ring, for example, both a benzene ring and a pyridine ring belong to the monocyclic ring, both biphenyl and bipyridine belong to the polycyclic ring, and both a naphthalene ring and a quinoline ring belong to the fusedcyclic ring.

According an embodiment of the present disclosure, in Formula 1, the ring A and the ring B are each independently selected from a five-membered unsaturated carbocyclic ring, an aromatic ring having 6 to 18 carbon atoms or a heteroaromatic ring having 3 to 18 carbon atoms, and when the ring A is a monocyclic ring, the ring A is selected from a five-membered unsaturated carbocyclic ring, a benzene ring or a six-membered heteroaromatic ring.

According an embodiment of the present disclosure, in Formula 1, the ring A or the ring B is each independently selected from a five-membered unsaturated carbocyclic ring, an aromatic ring having 6 to 18 carbon atoms or a heteroaromatic ring having 3 to 18 carbon atoms, and when the ring A is a monocyclic ring, the ring A is selected from a five-membered unsaturated carbocyclic ring, a benzene ring or a six-membered heteroaromatic ring.

According an embodiment of the present disclosure, in Formula 1, the ring A and the ring B are each independently selected from a five-membered unsaturated carbocyclic ring, an aromatic ring having 6 to 10 carbon atoms or a heteroaromatic ring having 3 to 10 carbon atoms, and when the ring A is a monocyclic ring, the ring A is selected from a five-membered unsaturated carbocyclic ring, a benzene ring or a six-membered heteroaromatic ring.

According an embodiment of the present disclosure, in Formula 1, the ring A or the ring B is each independently selected from a five-membered unsaturated carbocyclic ring, an aromatic ring having 6 to 10 carbon atoms or a heteroaromatic ring having 3 to 10 carbon atoms, and when the ring A is a monocyclic ring, the ring A is selected from a five-membered unsaturated carbocyclic ring, a benzene ring or a six-membered heteroaromatic ring.

According to an embodiment of the present disclosure, T₁ to T₄ are all selected from C.

According to an embodiment of the present disclosure, the ligand Lₐ is selected from a structure represented by any one of Formula 2 to Formula 40:

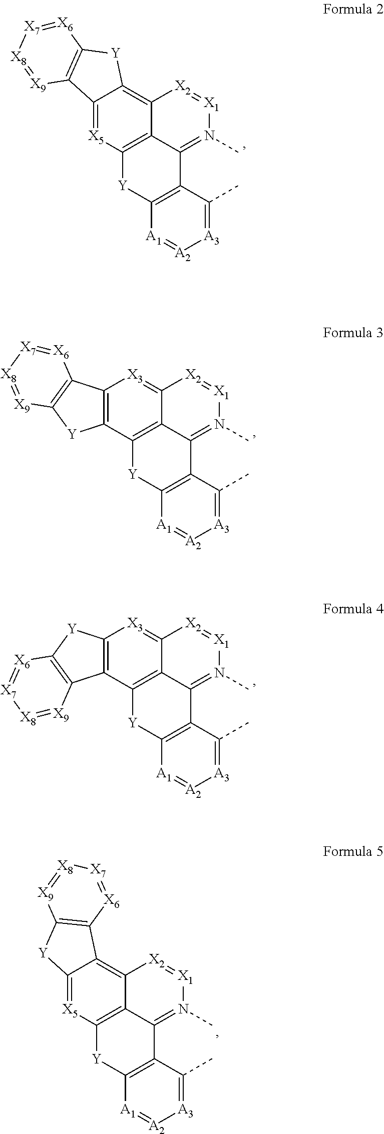

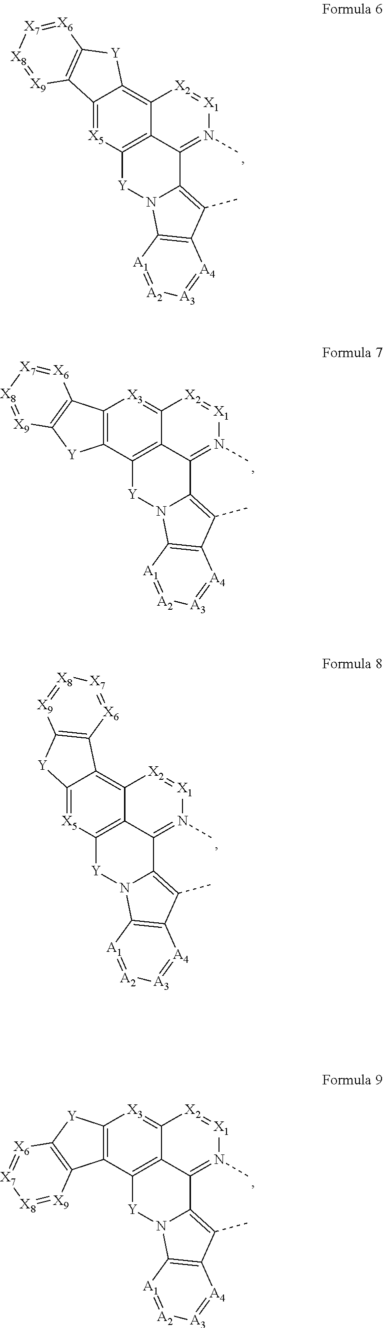

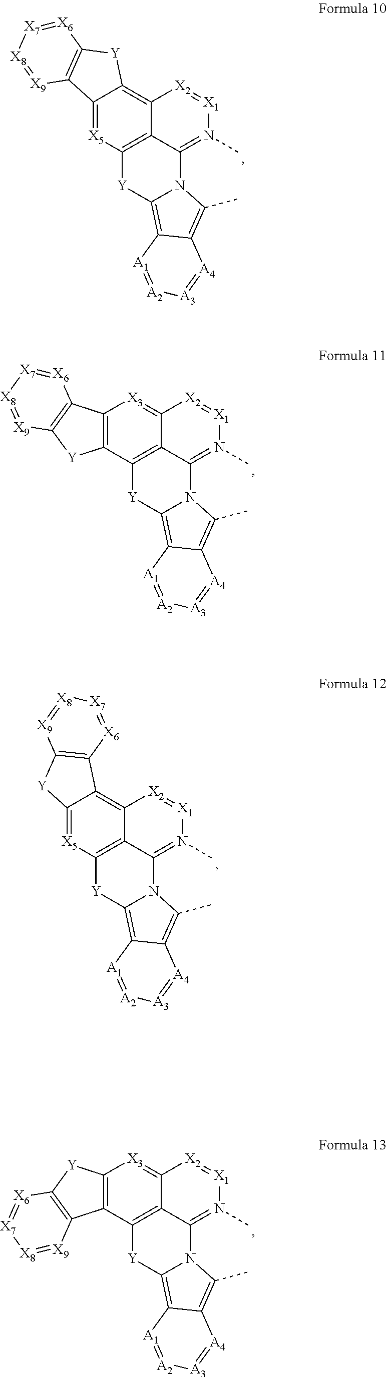

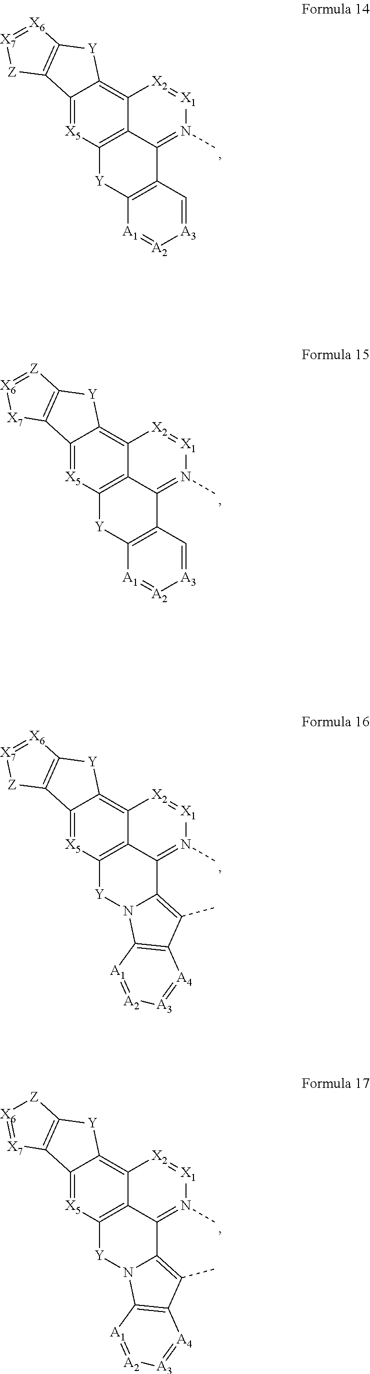

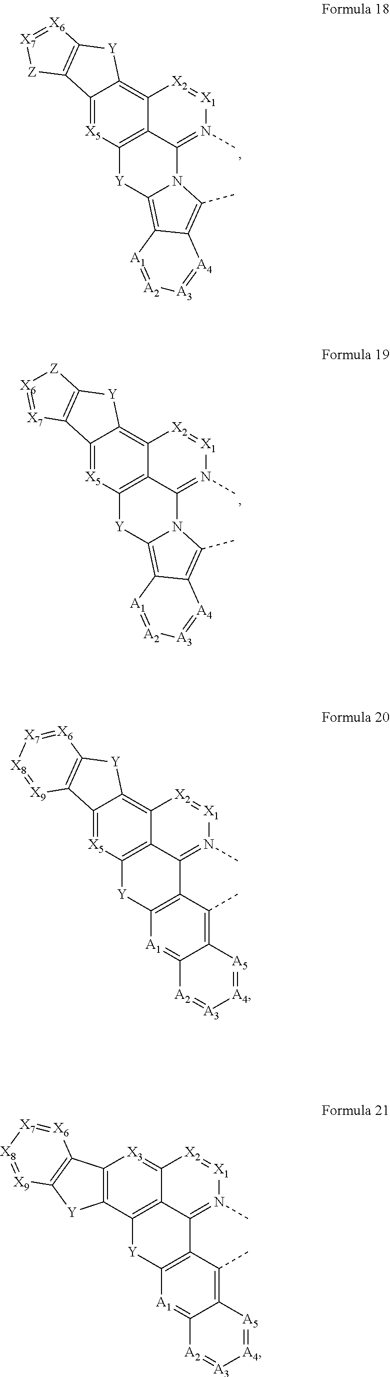

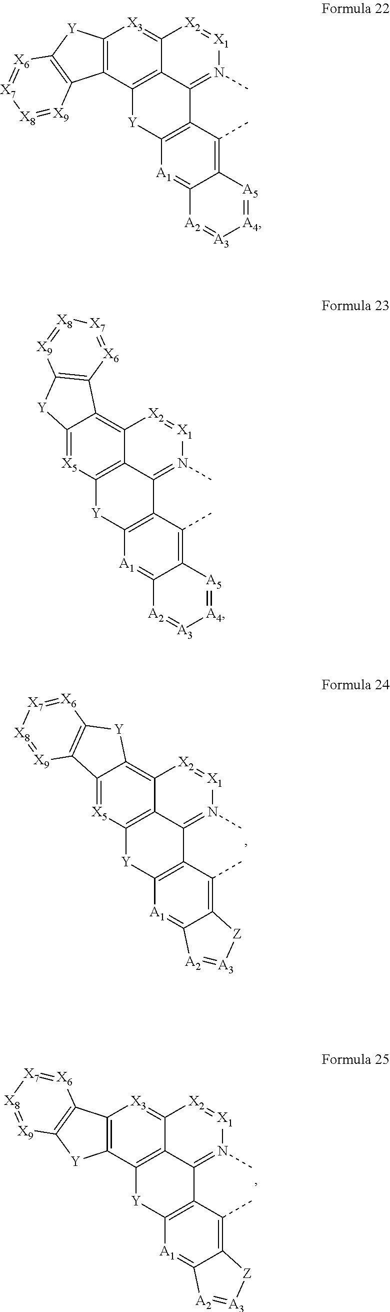

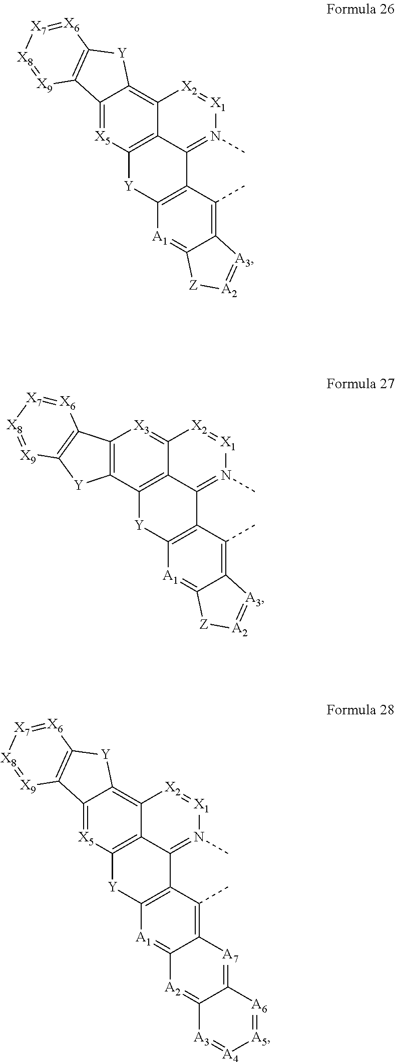

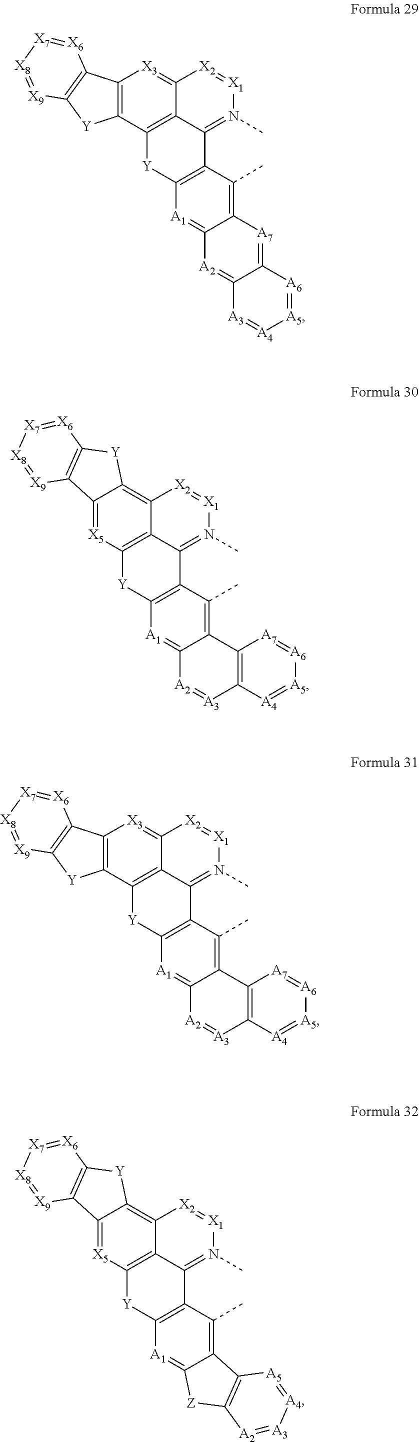

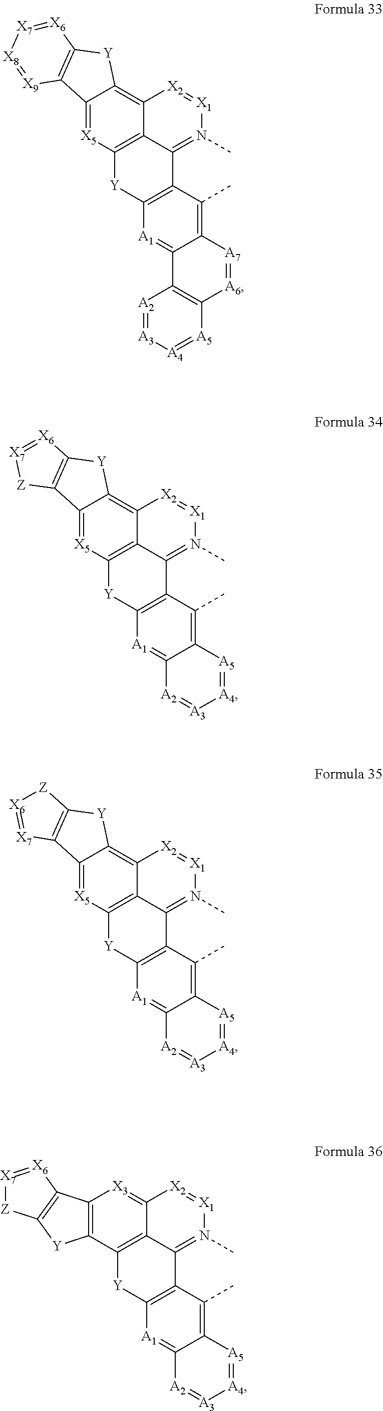

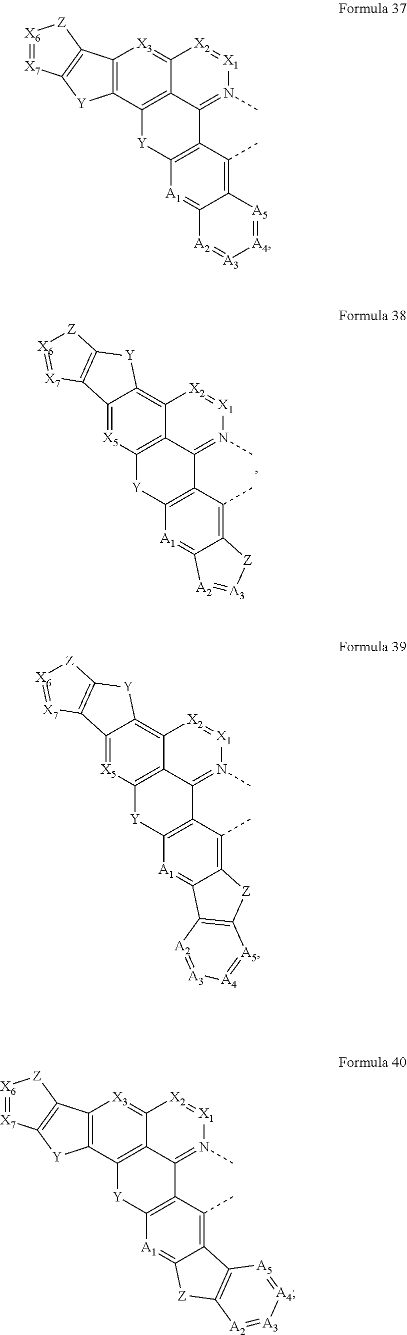

wherein X₁ to X₃ and X₅ to X₉ are, at each occurrence identically or differently, selected from CRₓ or N; A₁ to A₇ are, at each occurrence identically or differently, selected from CR_{A} or N;
Y is, at each occurrence identically or differently, selected from CR_{y}R_{y}, SiR_{y}R_{y}, GeR_{y}R_{y}, NR_{y}, PR_{y}, O, S or Se; when a plurality of R_{y} are present at the same time, the plurality of R_{y} are identical or different;
Z is, at each occurrence identically or differently, selected from CR_{z}R_{z}, SiR_{z}R_{z}, PR_{z}, O, S or NR_{z}; when a plurality of R_{z} are present at the same time, the plurality of R_{z} are identical or different;
Rₓ, R_{y}, R_{A} and R_{z} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₓ, R_{y}, R_{A} and R_{z} can be optionally joined to form a ring.

In the present disclosure, the expression that “adjacent substituents Rₓ, R_{y}, R_{A} and R_{z} can be optionally joined to form a ring” is intended to mean that any one or more of groups of adjacent substituents, such as adjacent substituents Rₓ, adjacent substituents R_{y}, adjacent substituents R_{z}, adjacent substituents R_{A}, adjacent substituents R_{A} and R_{y}, adjacent substituents Rₓ and R_{y}, adjacent substituents R_{A} and R_{z}, and adjacent substituents R_{y} and R_{z}, can be joined to form a ring. Obviously, it is also possible that none of these groups of substituents are joined to form a ring.

According to an embodiment of the present disclosure, the ligand Lₐ is selected from a structure represented by Formula 2, Formula 3, Formula 20 or Formula 21.

According to an embodiment of the present disclosure, the ligand Lₐ is selected from a structure represented by Formula 20 or Formula 21.

According to an embodiment of the present disclosure, in Formula 2 to Formula 40, at least one of X₁ to Xₙ and/or A₁ to Aₘ is selected from N, wherein the Xₙ corresponds to the one with the largest serial number among X₁ to X₉ in any one of Formula 2 to Formula 40, and the Aₘ corresponds to the one with the largest serial number among A₁ to A₇ in any one of Formula 2 to Formula 40. For example, in Formula 2, the Xₙ corresponds to X₉ whose serial number is the largest among X₁ to X₉ in Formula 2, and the Aₘ corresponds to A₃ whose serial number is the largest among A₁ to A₇ in Formula 2, that is, in Formula 2, at least one of X₁, X₂, X₃, X₅, X₆, X₇, X₈ and X₉ and/or A₁ to A₃ is selected from N.

According to an embodiment of the present disclosure, in Formula 2 to Formula 40, at least one of X₁ to Xₙ is selected from N, wherein the Xₙ corresponds to the one with the largest serial number among X₁ to X₉ in any one of Formula 2 to Formula 40.

According to an embodiment of the present disclosure, in Formula 2 to Formula 40, X₂ is N.

According to an embodiment of the present disclosure, in Formula 2 to Formula 40, X₁ to X₃ and X₅ to X₉ are each independently selected from CRₓ; A₁ to A₇ are each independently selected from CR_{A}; and the Rₓ and R_{A} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof, adjacent substituents Rₓ and R_{A} can be optionally joined to form a ring.

In the present disclosure, the expression that “adjacent substituents Rₓ and R_{A} can be optionally joined to form a ring” is intended to mean that any one or more of groups of adjacent substituents, such as adjacent substituents Rₓ, and adjacent substituents R_{A}, can be joined to form a ring. Obviously, it is also possible that none of these groups of substituents are joined to form a ring.

According to an embodiment of the present disclosure, in Formula 2 to Formula 40, X₁ to X₃ and X₅ to X₉ are each independently selected from CRₓ; A₁ to A₇ are each independently selected from CR_{A}; and the Rₓ and R_{A} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group and combinations thereof.

According to an embodiment of the present disclosure, in Formula 2 to Formula 40, X₁ to X₃ and X₅ to X₉ are each independently selected from CRₓ; A₁ to A₇ are each independently selected from CR_{A}; at least one, two or three of the Rₓ and R_{A} is(are), at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group and combinations thereof.

In this embodiment, the expression that at least one, two or three of the Rₓ and R_{A} is(are), at each occurrence identically or differently, selected from the group of consisting of these substituents is intended to mean that at least one, two or three substituents in the group consisting of all substituents Rₓ and all substituents R_{A} is(are), at each occurrence identically or differently, selected from the group of consisting of these substituents.

According to an embodiment of the present disclosure, in Formula 2 to Formula 40, X₁ to X₃ and X₅ to X₉ are each independently selected from CRₓ; A₁ to A₇ are each independently selected from CR_{A}; at least one, two or three of the Rₓ and/or at least one, two or three of the R_{A} is(are), at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group and combinations thereof.

According to an embodiment of the present disclosure, in Formula 2 to Formula 40, X₁ and X₂ are each independently selected from CRₓ; and the Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof.

According to an embodiment of the present disclosure, in Formula 2 to Formula 40, X₁ and X₂ are each independently selected from CRₓ; the Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof.

According to an embodiment of the present disclosure, in Formula 2 to Formula 40, X₁ is selected from CRₓ, X₂ is N, and the Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof.

According to an embodiment of the present disclosure, in Formula 2 to Formula 40, X₁ is selected from CRₓ, X₂ is N, and the Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof.

According to an embodiment of the present disclosure, in Formula 2 to Formula 13 and Formula 20 to Formula 33, X₇ and/or X₈ is selected from CRₓ; in Formula 14 to Formula 19 and Formula 34 to Formula 40, X₆ and/or X₇ is selected from CRₓ; and the Rₓ is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, a substituted or unsubstituted heterocyclic group having 3 to 20 ring atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group, a hydroxyl group, a sulfanyl group, a phosphino group and combinations thereof.

According to an embodiment of the present disclosure, in Formula 2 to Formula 13 and Formula 20 to Formula 33, X₇ and/or X₈ is selected from CRₓ; in Formula 14 to Formula 19 and Formula 34 to Formula 40, X₆ and/or X₇ is selected from CRₓ; and the Rₓ is, at each occurrence identically or differently, selected from the group consisting of: deuterium, fluorine, methyl, ethyl, isopropyl, isobutyl, t-butyl, neopentyl, cyclopentyl, cyclopentylmethyl, cyclohexyl, tetrahydrofuranyl, tetrahydropyranyl, deuterated methyl, deuterated ethyl, deuterated isopropyl, deuterated isobutyl, deuterated t-butyl, deuterated neopentyl, deuterated cyclopentyl, deuterated cyclopentylmethyl, deuterated cyclohexyl, norbornyl, adamantyl, trimethylsilyl, isopropyldimethylsilyl, phenyldimethylsilyl, trifluoromethyl, a cyano group, phenyl, 2,4,6-trimethylphenyl, 2,4,6-triisopropylphenyl, pyridyl, triazinyl, thienyl, carbazolyl, a hydroxyl group, a sulfanyl group, a phosphino group and combinations thereof.

According to an embodiment of the present disclosure, in Formula 2 to Formula 5, Formula 14, Formula 15, Formula 24 to Formula 27 and Formula 38, at least one of A₁ to A₃ is selected from CR_{A}, in Formula 6 to Formula 13 and Formula 16 to Formula 19, at least one of A₁ to A₄ is selected from CR_{A}, in Formula 20 to Formula 23, Formula 32, Formula 34 to Formula 37, Formula 39 and Formula 40, at least one of A₁ to A₅ is selected from CR_{A}, and in Formula 28 to Formula 31 and Formula 33, at least one of A₁ to A₇ is selected from CR_{A}; and the R_{A} is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof.

According to an embodiment of the present disclosure, in Formula 2 to Formula 40, A₁ is selected from CR_{A}; and the R_{A} is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, a substituted or unsubstituted heterocyclic group having 3 to 20 ring atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group and combinations thereof.

According to an embodiment of the present disclosure, the R_{A} is, at each occurrence identically or differently, selected from the group consisting of: deuterium, fluorine, methyl, ethyl, isopropyl, isobutyl, t-butyl, neopentyl, cyclopentyl, cyclopentylmethyl, cyclohexyl, tetrahydrofuranyl, tetrahydropyranyl, deuterated methyl, deuterated ethyl, deuterated isopropyl, deuterated isobutyl, deuterated t-butyl, deuterated neopentyl, deuterated cyclopentyl, deuterated cyclopentylmethyl, deuterated cyclohexyl, norbornyl, adamantyl, trimethylsilyl, isopropyldimethylsilyl, phenyldimethylsilyl, trifluoromethyl, a cyano group, phenyl, 2,4,6-trimethylphenyl, 2,4,6-triisopropylphenyl and combinations thereof.

According to an embodiment of the present disclosure, in Formula 2 to Formula 40, A₁ is selected from CR_{A}, and at least one or two of A₂ to A₅ is(are) selected from CR_{A}; and the R_{A} is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof.

According to an embodiment of the present disclosure, in Formula 2 to Formula 40, A₁ is selected from CR_{A}, and in Formula 2 to Formula 5, Formula 14, Formula 15 and Formula 20 to Formula 40, at least one or two of A₂ to A₅ is(are) selected from CR_{A}; and the R_{A} is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, a substituted or unsubstituted heterocyclic group having 3 to 20 ring atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group and combinations thereof.

According to an embodiment of the present disclosure, in Formula 2 to Formula 40, A₁ is selected from CR_{A}, and in Formula 2 to Formula 5, Formula 14, Formula 15 and Formula 20 to Formula 40, at least one or two of A₂ to A₅ is(are) selected from CR_{A}; and the R_{A} is, at each occurrence identically or differently, selected from the group consisting of: deuterium, fluorine, methyl, ethyl, isopropyl, isobutyl, t-butyl, neopentyl, cyclopentyl, cyclopentylmethyl, cyclohexyl, tetrahydrofuranyl, tetrahydropyranyl, deuterated methyl, deuterated ethyl, deuterated isopropyl, deuterated isobutyl, deuterated t-butyl, deuterated neopentyl, deuterated cyclopentyl, deuterated cyclopentylmethyl, deuterated cyclohexyl, norbornyl, adamantyl, trimethylsilyl, isopropyldimethylsilyl, phenyldimethylsilyl, trifluoromethyl, a cyano group, phenyl, 2,4,6-trimethylphenyl, 2,4,6-triisopropylphenyl and combinations thereof.

According to an embodiment of the present disclosure, in Formula 2 to Formula 40, Y is, at each occurrence identically or differently, selected from CR_{y}R_{y}, O or S.

According to an embodiment of the present disclosure, in Formula 2 to Formula 40, Y is, at each occurrence identically or differently, selected from O or S.

According to an embodiment of the present disclosure, the ligand Lₐ has a structure represented by one of Formula 41 to Formula 44:

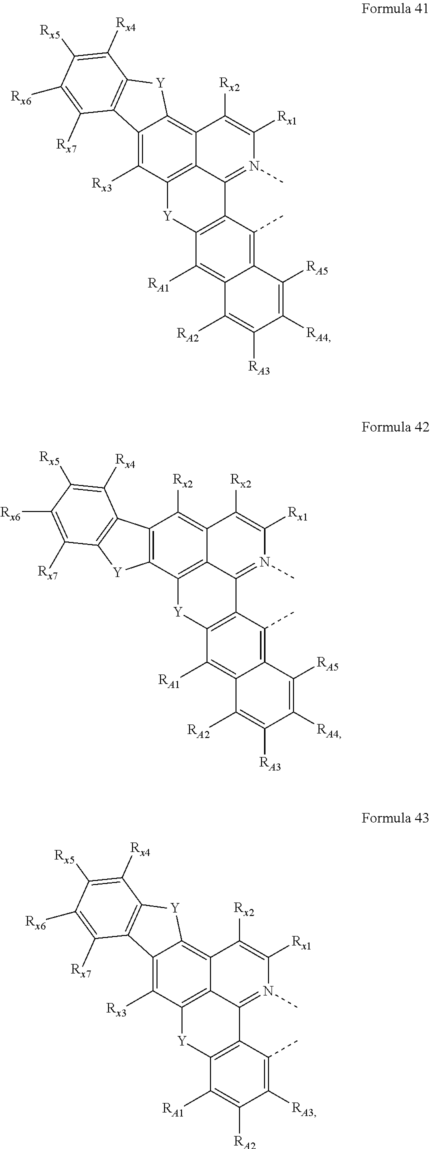

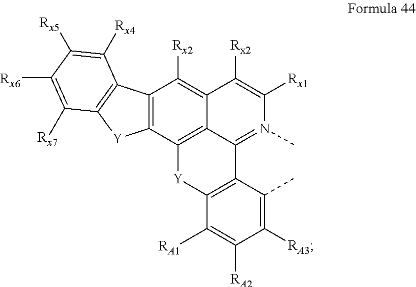

wherein in Formula 41 to Formula 44, Y is, at each occurrence identically or differently, selected from 0 or S; and
Rₓ₁ to Rₓ₇ and R_{A1} to R_{A5} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof.

According to an embodiment of the present disclosure, in Formula 41 to Formula 44, at least one of Rₓ₁ to Rₓ₇ and R_{A1} to R_{A5} is, at each occurrence identically or differently, selected from the group consisting of: deuterium, halogen, substituted or unsubstituted alkyl having 1 to carbon atoms, substituted or unsubstituted cycloalkyl having 3 to 20 ring carbon atoms, a substituted or unsubstituted heterocyclic group having 3 to 20 ring atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group and combinations thereof.

According to an embodiment of the present disclosure, in Formula 41 to Formula 44, at least one of Rₓ₁ to Rₓ₇ and R_{A1} to R_{A5} is, at each occurrence identically or differently, selected from the group consisting of: deuterium, fluorine, methyl, ethyl, isopropyl, isobutyl, t-butyl, neopentyl, cyclopentyl, cyclopentylmethyl, cyclohexyl, tetrahydrofuranyl, tetrahydropyranyl, deuterated methyl, deuterated ethyl, deuterated isopropyl, deuterated isobutyl, deuterated t-butyl, deuterated neopentyl, deuterated cyclopentyl, deuterated cyclopentylmethyl, deuterated cyclohexyl, norbornyl, adamantyl, trimethylsilyl, isopropyldimethylsilyl, phenyldimethylsilyl, trifluoromethyl, a cyano group, phenyl, 2,4,6-trimethylphenyl, 2,4,6-triisopropylphenyl and combinations thereof.

According to an embodiment of the present disclosure, in Formula 41 to Formula 44, at least one or two of Rₓ₁ to Rₓ₇ and/or at least one or two of R_{A1} to R_{A5} is(are), at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof.

According to an embodiment of the present disclosure, in Formula 41 and Formula 44, at least one or two of Rₓ₁ to Rₓ₇ and/or at least one or two of R_{A1} to R_{A5} is(are), at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof.

According to an embodiment of the present disclosure, in Formula 41 to Formula 44, Rₓ₅ and/or Rₓ₆ is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof; R_{A1} is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof; at least one or two of R_{A2} to R_{A5} is(are), at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof.

According to an embodiment of the present disclosure, in Formula 41 to Formula 44, Rₓ₅ and/or Rₓ₆ is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof; R_{A1} is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof at least one or two of R_{A2} to R_{A5} is(are), at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof.

According to an embodiment of the present disclosure, the ligand Lₐ is, at each occurrence identically or differently, selected from the group consisting of Lₐ₁ to Lₐ₄₄₈₉, wherein the specific structures of Lₐ₁ to Lₐ₄₄₈₉ are referred to claim 15.

According to an embodiment of the present disclosure, the metal complex has a structure of M(Lₐ)ₘ(L_{b})ₙ(L_{c})_{q};
wherein the metal M is selected from a metal with a relative atomic mass greater than 40; Lₐ, L_{b} and L_{c} are a first ligand, a second ligand and a third ligand of the complex, respectively; m is 1, 2 or 3, n is 0, 1 or 2, q is 0, 1 or 2, and m+n+q is equal to an oxidation state of the metal M; when m is greater than 1, a plurality of Lₐ are identical or different; when n is 2, two L_{b} are identical or different; when q is 2, two L_{c} are identical or different;
Lₐ, L_{b} and L_{c} can be optionally joined to form a multidentate ligand;
L_{b} and L_{c} are, at each occurrence identically or differently, selected from the group consisting of the following structures:

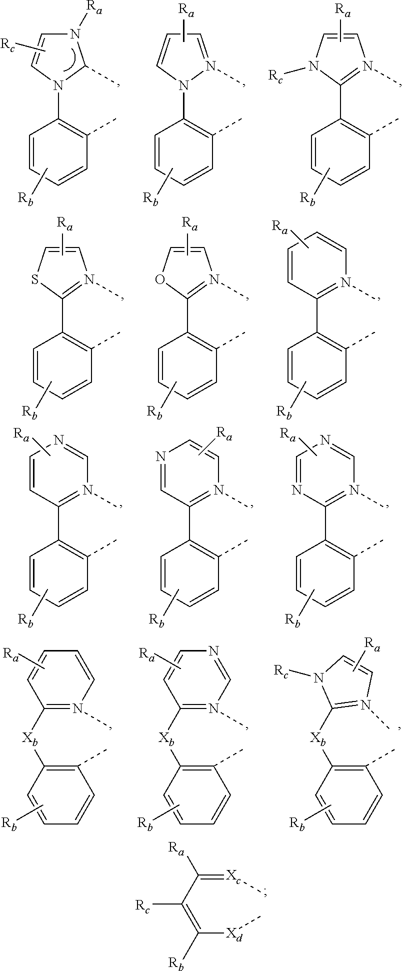

wherein Rₐ, R_{b}, and R_{c} represent, at each occurrence identically or differently, mono-substitution, multiple substitutions or non-substitution;
X_{b} is, at each occurrence identically or differently, selected from the group consisting of: O, S, Se, NR_{N1} and CR_{C1}R_{C2};
X_{c} and X_{d} are, at each occurrence identically or differently, selected from the group consisting of: O, S, Se and NR_{N2};
Rₐ, R_{b}, R_{c}, R_{N1}, R_{N2}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₐ, R_{b}, R_{c}, R_{N1}, R_{N2}, R_{C1} and R_{C2} can be optionally joined to form a ring.

In this embodiment, the expression that adjacent substituents Rₐ, R_{b}, R_{c}, R_{N1}, R_{N2}, R_{C1} and R_{C2} can be optionally joined to form a ring is intended to mean that any one or more of groups of adjacent substituents, such as two substituents Rₐ, two substituents R_{b}, two substituents R_{c}, substituents Rₐ and R_{b}, substituents Rₐ and R_{c}, substituents R_{b} and R_{c}, substituents Rₐ and R_{N1}, substituents R_{b} and R_{N11}, substituents Rₐ and R_{C1}, substituents Rₐ and R_{C2}, substituents R_{b} and R_{C1}, substituents R_{b} and R_{C2}, substituents Rₐ and R_{N2}, substituents R_{b} and R_{N2}, and substituents R_{C1} and R_{C2}, can be joined to form a ring. For example, adjacent substituents Rₐ and R_{b} in

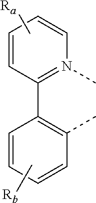

can be optionally joined to form a ring, which can form one or more of the following structures including but not limited to:

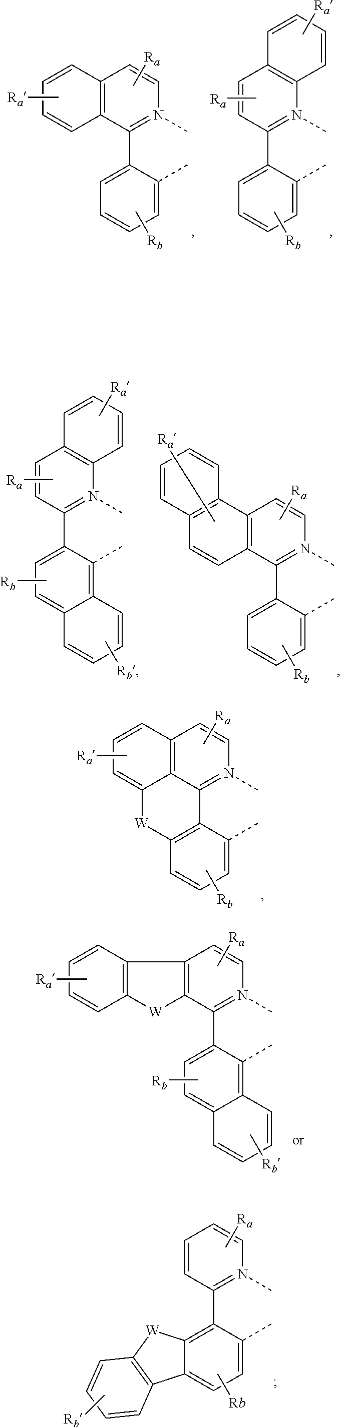

wherein W is selected from O, S, Se, NR′ or CR′R′, and the definition of each of the R′, Rₐ′ and R_{b}′ is the same as that of the Rₐ. Obviously, it is also possible that none of these substituents are joined to form a ring.

According to an embodiment of the present disclosure, the metal M is selected from Ir, Rh, Re, Os, Pt, Au or Cu.

According to an embodiment of the present disclosure, the metal M is selected from Ir, Pt or Os.

According to an embodiment of the present disclosure, the metal M is Ir.

According to an embodiment of the present disclosure, L_{b} is, at each occurrence identically or differently, selected from the following structure:

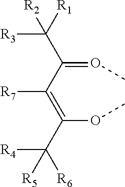

wherein R₁ to R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R₁, R₂, R₃, R₄, R₅, R₆ and R₇ can be optionally joined to form a ring.

In this embodiment, the expression that “adjacent substituents R₁, R₂, R₃, R₄, R₅, R₆ and R₇ can be optionally joined to form a ring” is intended to mean that any one or more of groups of adjacent substituents, such as substituents R₁ and R₂, substituents R₁ and R₃, substituents R₂ and R₃, substituents R₄ and R₅, substituents R₄ and R₆, substituents R₅ and R₆, substituents R₁ and R₇, substituents R₂ and R₇, substituents R₃ and R₇, substituents R₄ and R₇, substituents R₅ and R₇, and substituents R₆ and R₇, can be joined to form a ring. Obviously, it is also possible that none of these substituents are joined to form a ring.

According to an embodiment of the present disclosure, at least one or two of R₁ to R₃ is(are), at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or a combination thereof; and/or at least one or two of R₄ to R₆ is(are), at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or a combination thereof.

According to an embodiment of the present disclosure, at least two of R₁ to R₃ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or a combination thereof; and/or at least two of R₄ to R₆ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or a combination thereof.

According to an embodiment of the present disclosure, L_{b} is, at each occurrence identically or differently, selected from the group consisting of L_{b1} to L_{b322}, wherein the specific structures of L_{b1} to L_{b322} are referred to claim 19.

According to an embodiment of the present disclosure, L_{c} is, at each occurrence identically or differently, selected from the group consisting of L_{c1} to L_{c231}, wherein the specific structures of L_{c1} to L_{c231} are referred to claim 19.

According to an embodiment of the present disclosure, the metal complex has a structure of Ir(Lₐ)₂(L_{b}) or Ir(Lₐ)₂(L_{c}) or Ir(Lₐ)(L_{c})₂ or Ir(Lₐ)(L_{b})(L);
wherein when the metal complex has a structure of Ir(Lₐ)₂(L_{b}), Lₐ is, at each occurrence identically or differently, selected from any one or any two of the group consisting of Lₐ₁ to Lₐ₄₄₈₉, and L_{b} is selected from any one of the group consisting of L_{b1} to L_{b322}; when the metal complex has a structure of Ir(Lₐ)₂(L_{c}), Lₐ is, at each occurrence identically or differently, selected from any one or any two of the group consisting of Lₐ₁ to Lₐ₄₄₈₉, and L_{c} is selected from any one of the group consisting of L_{c1} to L_{c231}; when the metal complex has a structure of Ir(Lₐ)(L_{c})₂, Lₐ is selected from any one of the group consisting of Lₐ₁ to Lₐ₄₄₈₉, and L_{c} is, at each occurrence identically or differently, selected from any one or any two of the group consisting of L_{c1} to L_{c231}; when the metal complex has a structure of Ir(Lₐ)(L_{b})(L_{c}), Lₐ is selected from any one of the group consisting of Lₐ₁ to Lₐ₄₄₈₉, L_{b} is selected from any one of the group consisting of L_{b1} to L_{b322}, and L_{c} is selected from any one of the group consisting of L_{c1} to L_{c231}.

According to an embodiment of the present disclosure, the metal complex is selected from the group consisting of Compound 1 to Compound 1646, wherein the specific structures of Compound 1 to Compound 1646 are referred to claim 20.

According to an embodiment of the present disclosure, disclosed is an electroluminescent device, which comprises:
an anode,
a cathode, and
an organic layer disposed between the anode and the cathode, wherein the organic layer comprises the metal complex in any one of the preceding embodiments.

According to an embodiment of the present disclosure, the organic layer is a light-emitting layer, and the metal complex is a light-emitting material.

According to an embodiment of the present disclosure, the electroluminescent device emits red light or white light.

According to an embodiment of the present disclosure, the light-emitting layer further comprises at least one host material.

According to an embodiment of the present disclosure, the at least one host material comprises at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene and combinations thereof.

According to an embodiment of the present disclosure, the at least one host material may be a conventional host material in the related art. For example, the at least one host material may typically include the following host materials without limitation:

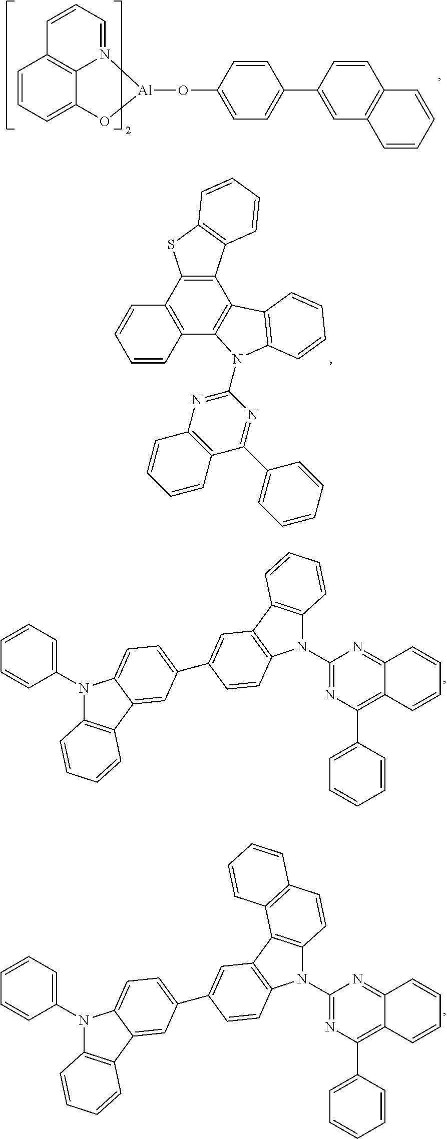

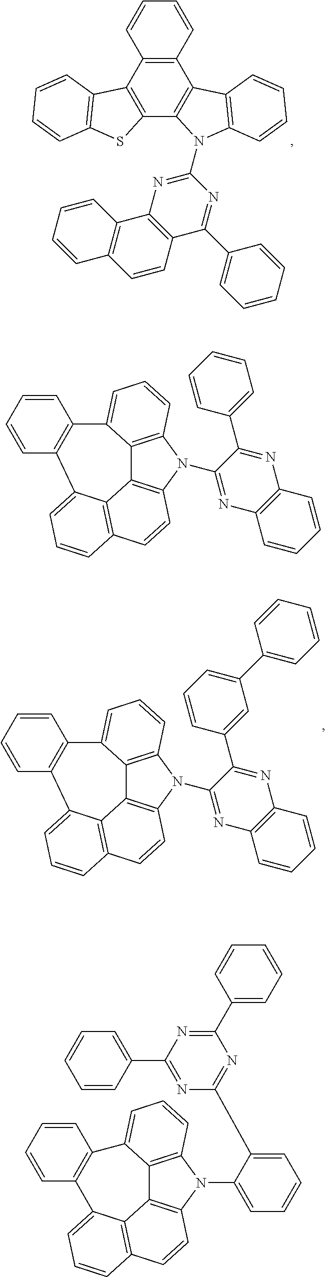 [SMILES: c1ccc(-c2nc(-n3c4ccccc4c4c5ccccc5c5c6ccccc6sc5c43)nc3c2ccc2ccccc23)cc1 ; c1ccc(-c2nc3ccccc3nc2-n2c3cccc4c3c3c5c(cccc5ccc32)-c2ccccc2-4)cc1 ; c1ccc(-c2cccc(-c3nc4ccccc4nc3-n3c4cccc5c4c4c6c(cccc6ccc43)-c3ccccc3-5)c2)cc1 ; c1ccc(-c2nc(-c3ccccc3)nc(-c3ccccc3-n3c4cccc5c4c4c6c(cccc6ccc43)-c3ccccc3-5)n2)cc1]

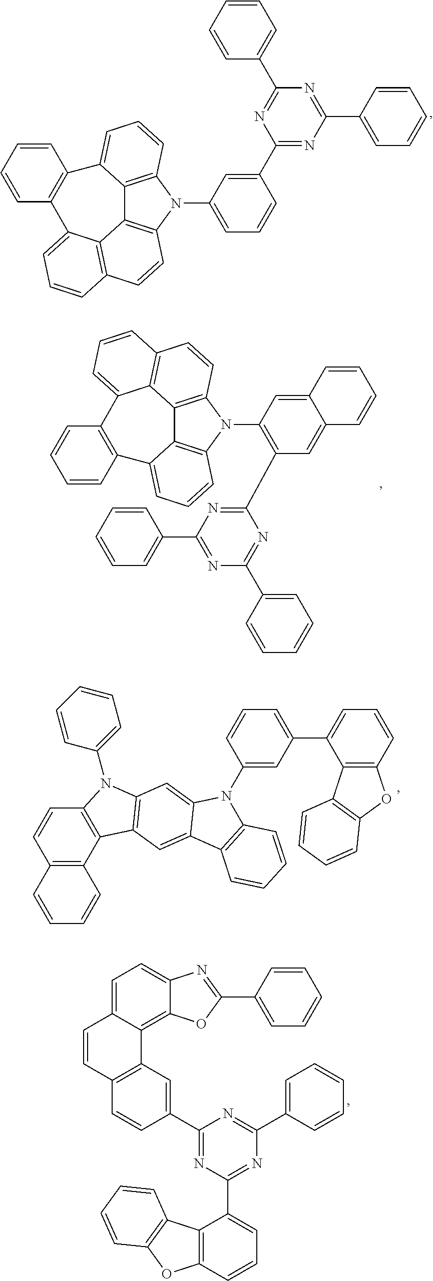

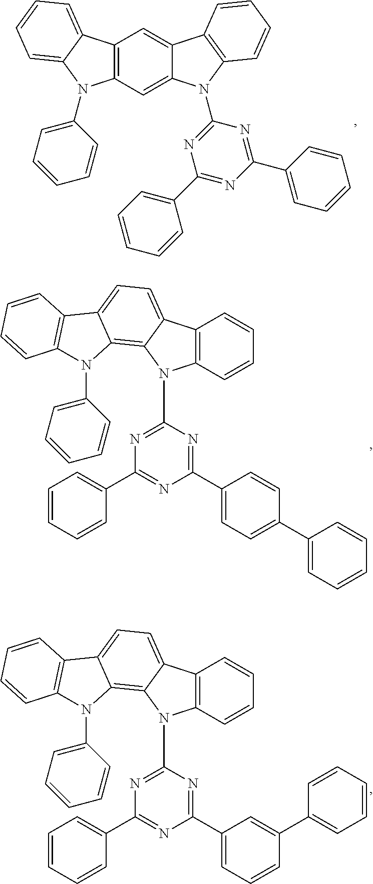

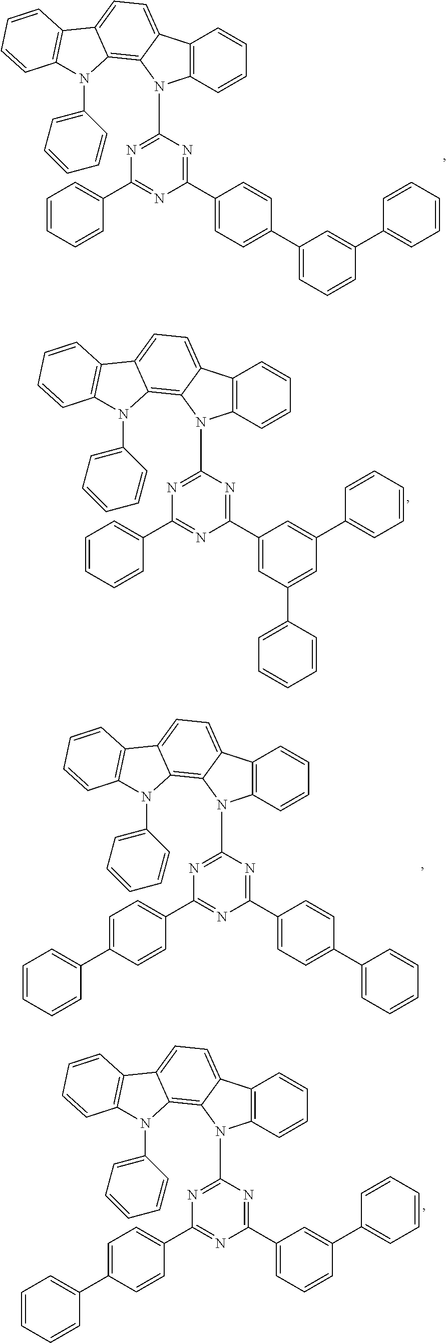 [SMILES: c1ccc(-c2cccc(-c3ccc(-c4nc(-c5ccccc5)nc(-n5c6ccccc6c6ccc7c8ccccc8n(-c8ccccc8)c7c65)n4)cc3)c2)cc1 ; c1ccc(-c2cc(-c3ccccc3)cc(-c3nc(-c4ccccc4)nc(-n4c5ccccc5c5ccc6c7ccccc7n(-c7ccccc7)c6c54)n3)c2)cc1 ; c1ccc(-c2ccc(-c3nc(-c4ccc(-c5ccccc5)cc4)nc(-n4c5ccccc5c5ccc6c7ccccc7n(-c7ccccc7)c6c54)n3)cc2)cc1 ; c1ccc(-c2ccc(-c3nc(-c4cccc(-c5ccccc5)c4)nc(-n4c5ccccc5c5ccc6c7ccccc7n(-c7ccccc7)c6c54)n3)cc2)cc1]

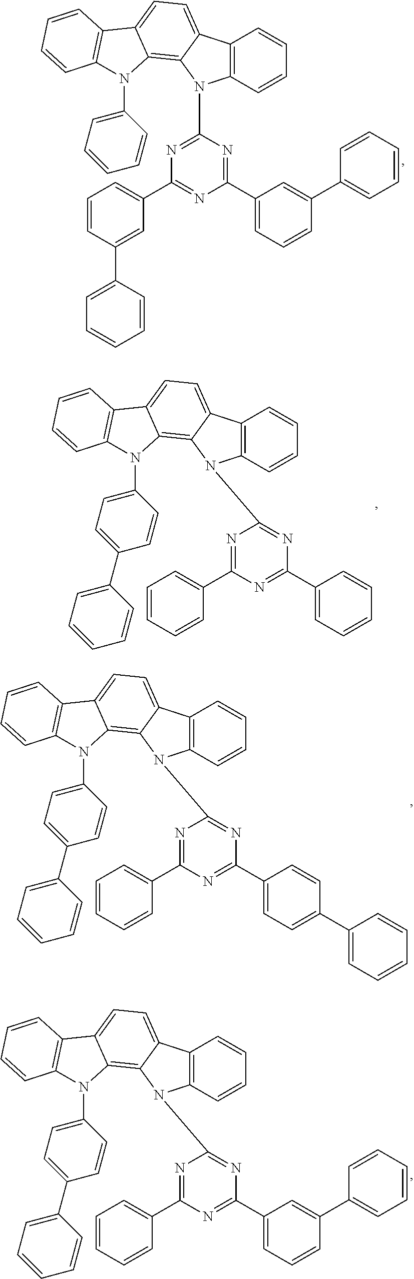

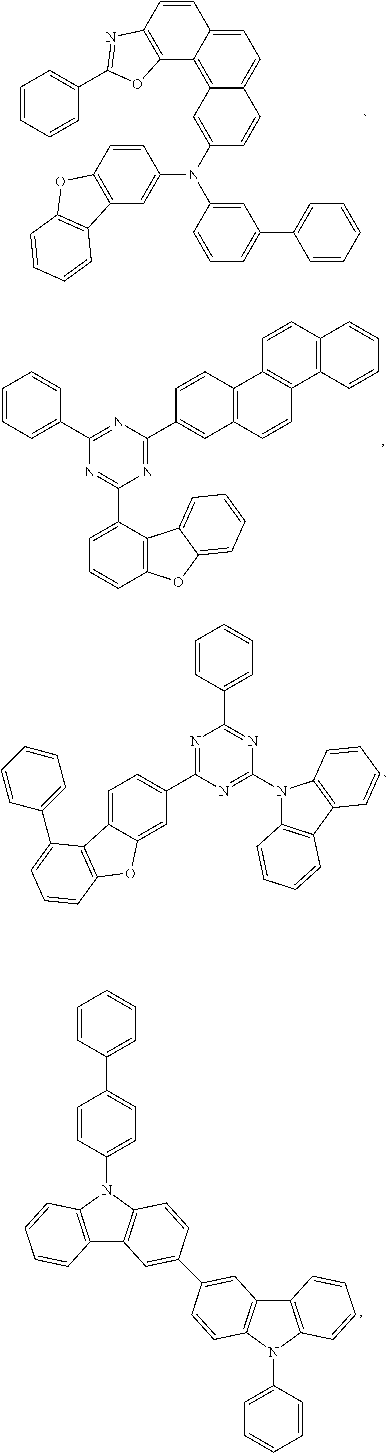 [SMILES: c1ccc(-c2cccc(N(c3ccc4oc5ccccc5c4c3)c3ccc4ccc5ccc6nc(-c7ccccc7)oc6c5c4c3)c2)cc1 ; c1ccc(-c2nc(-c3ccc4c(ccc5c6ccccc6ccc45)c3)nc(-c3cccc4oc5ccccc5c34)n2)cc1 ; c1ccc(-c2nc(-c3ccc4c(c3)oc3cccc(-c5ccccc5)c34)nc(-n3c4ccccc4c4ccccc43)n2)cc1 ; c1ccc(-c2ccc(-n3c4ccccc4c4cc(-c5ccc6c(c5)c5ccccc5n6-c5ccccc5)ccc43)cc2)cc1]

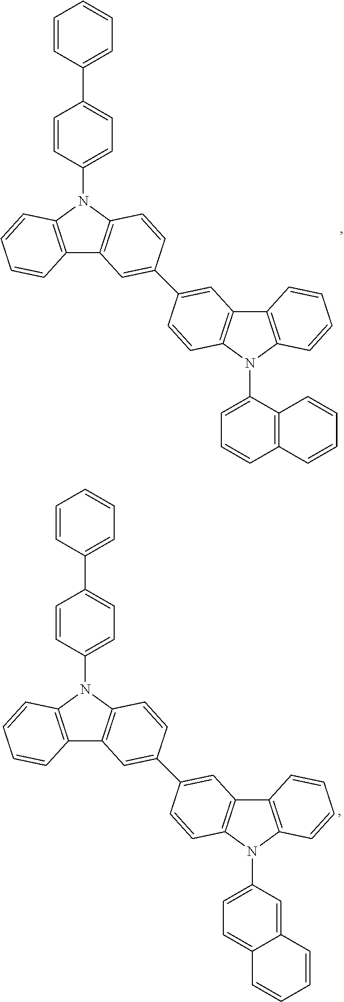 [SMILES: c1ccc(-c2ccc(-n3c4ccccc4c4cc(-c5ccc6c(c5)c5ccccc5n6-c5cccc6ccccc56)ccc43)cc2)cc1 ; c1ccc(-c2ccc(-n3c4ccccc4c4cc(-c5ccc6c(c5)c5ccccc5n6-c5ccc6ccccc6c5)ccc43)cc2)cc1]

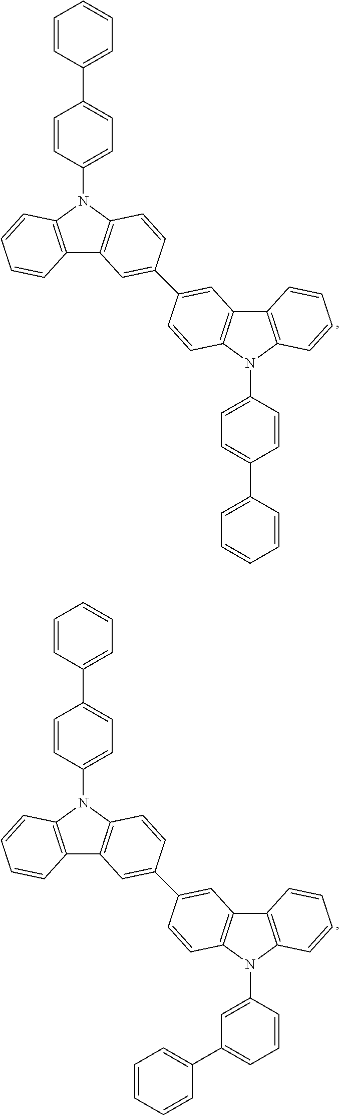 [SMILES: c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(-n3c4ccccc4c4cc(-c5ccc6c(c5)c5ccccc5n6-c5cccc(-c6ccccc6)c5)ccc43)cc2)cc1]

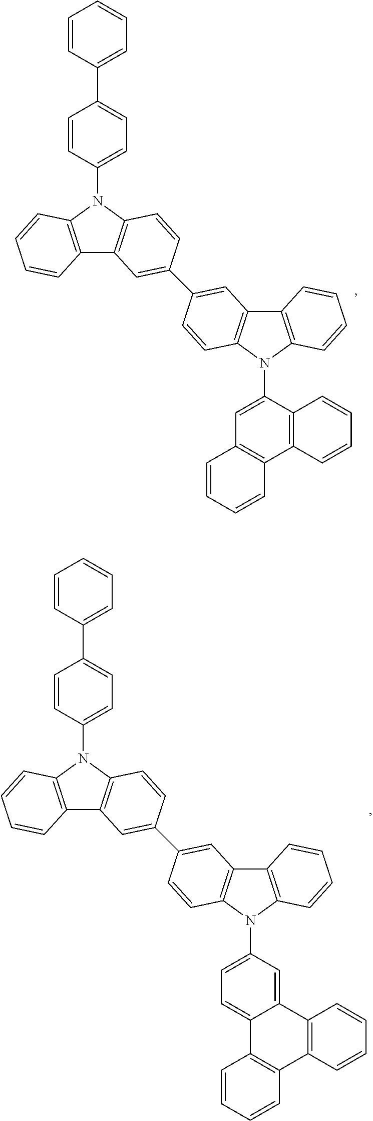 [SMILES: c1ccc(-c2ccc(-n3c4ccccc4c4cc(-c5ccc6c(c5)c5ccccc5n6-c5cc6ccccc6c6ccccc56)ccc43)cc2)cc1 ; c1ccc(-c2ccc(-n3c4ccccc4c4cc(-c5ccc6c(c5)c5ccccc5n6-c5ccc6c7ccccc7c7ccccc7c6c5)ccc43)cc2)cc1]

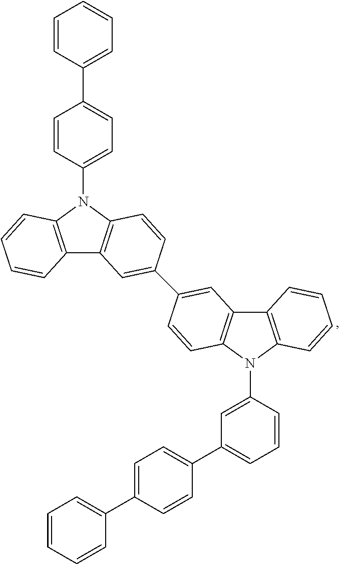 [SMILES: c1ccc(-c2ccc(-c3cccc(-n4c5ccccc5c5cc(-c6ccc7c(c6)c6ccccc6n7-c6ccc(-c7ccccc7)cc6)ccc54)c3)cc2)cc1]

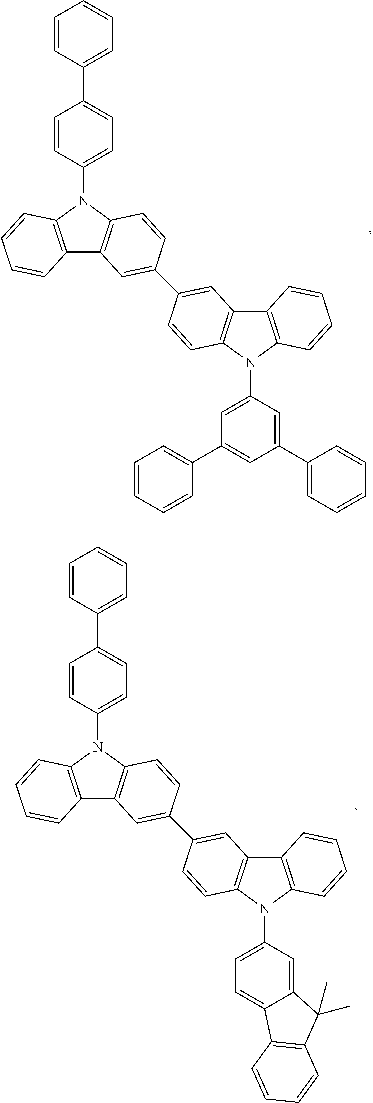 [SMILES: c1ccc(-c2ccc(-n3c4ccccc4c4cc(-c5ccc6c(c5)c5ccccc5n6-c5cc(-c6ccccc6)cc(-c6ccccc6)c5)ccc43)cc2)cc1 ; CC1(C)c2ccccc2-c2ccc(-n3c4ccccc4c4cc(-c5ccc6c(c5)c5ccccc5n6-c5ccc(-c6ccccc6)cc5)ccc43)cc21]

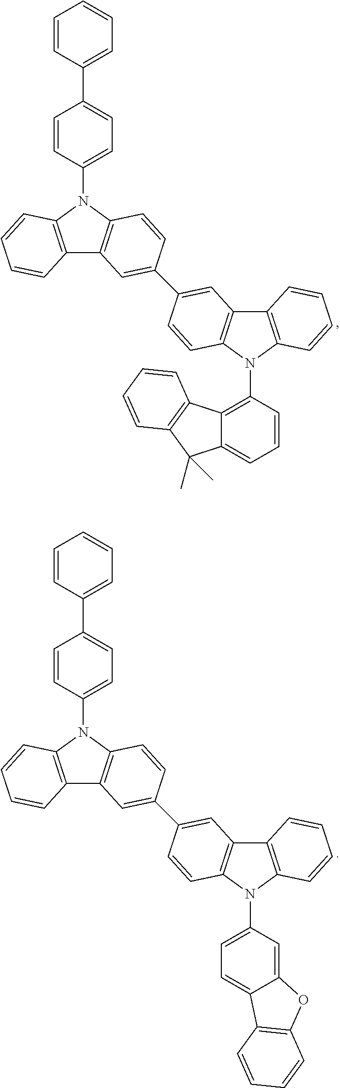 [SMILES: CC1(C)c2ccccc2-c2c(-n3c4ccccc4c4cc(-c5ccc6c(c5)c5ccccc5n6-c5ccc(-c6ccccc6)cc5)ccc43)cccc21 ; c1ccc(-c2ccc(-n3c4ccccc4c4cc(-c5ccc6c(c5)c5ccccc5n6-c5ccc6c(c5)oc5ccccc56)ccc43)cc2)cc1]

According to an embodiment of the present disclosure, disclosed is a compound composition, which comprises the metal complex in any one of the preceding embodiments.

Combination with Other Materials

The materials described in the present disclosure for a particular layer in an organic light-emitting device can be used in combination with various other materials present in the device. The combinations of these materials are described in more detail in U.S. Pat. Pub. No. US20160359122A1 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light-emitting device may be used in combination with a variety of other materials present in the device. For example, dopants disclosed herein may be used in combination with a wide variety of hosts, transport layers, blocking layers, injection layers, electrodes and other layers that may be present. The combination of these materials is described in detail in paragraphs 0080-0101 of U.S. Pat. Pub. No. US20150349273A1, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING, optical testing system produced by SUZHOU FATAR, life testing system produced by SUZHOU FATAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this patent.

### Material Synthesis Example

The method for preparing a compound in the present disclosure is not limited herein. Typically, the following compounds are used as examples without limitation, and synthesis routes and preparation methods thereof are described below.

### Synthesis Example 1: Synthesis of Compound 557

Step 1: Synthesis of Intermediate 3

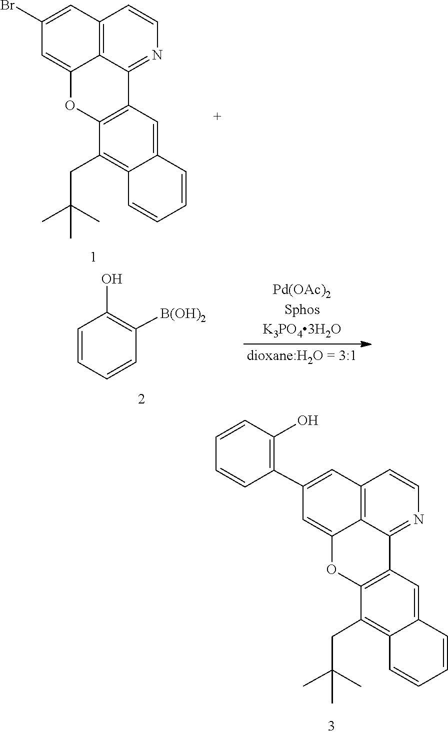 [SMILES: CC(C)(C)Cc1c2c(cc3ccccc13)-c1nccc3cc(Br)cc(c13)O2 ; OB(O)c1ccccc1O ; CC(C)(C)Cc1c2c(cc3ccccc13)-c1nccc3cc(-c4ccccc4O)cc(c13)O2]

A mixture of Intermediate 1 (1.0 g, 2.39 mmol), Intermediate 2 (0.66 g, 4.78 mmol), Pd(OAc)₂ (27.8 mg, 0.12 mmol), Sphos (2-dicyclohexylphosphino-2′,6′-dimethoxybiphenyl) (98 mg, 0.24 mmol), K₃PO₄·3H₂O (1.91 g, 7.17 mmol), 1,4-dioxane (12 mL) and water (4 mL) was added to a reaction flask. The reaction system underwent a refluxing reaction under a nitrogen atmosphere, and the reaction was monitored through TLC. Intermediate 1 disappeared, and the reaction system was cooled to room temperature. Water and ethyl acetate were added to the reaction system to extract a product, and the organic phases were collected and concentrated, and isolated and purified through column chromatography to obtain Intermediate 3 (0.64 g, with a yield of 62%).

Step 2: Synthesis of Intermediate 4

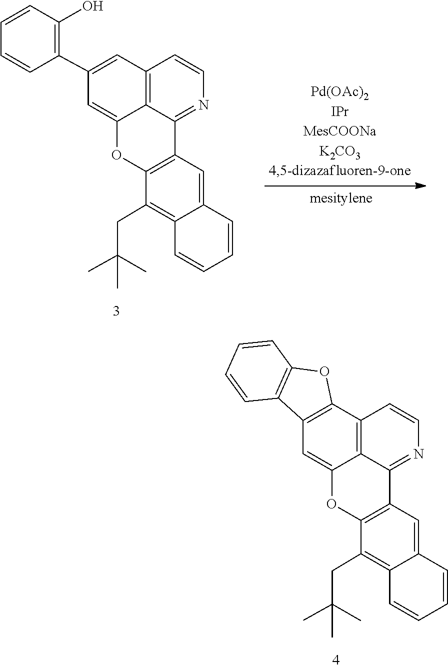 [SMILES: CC(C)(C)Cc1c2c(cc3ccccc13)-c1nccc3cc(-c4ccccc4O)cc(c13)O2 ; CC(C)(C)Cc1c2c(cc3ccccc13)-c1nccc3c1c(cc1c4ccccc4oc31)O2]

A mixture of Intermediate 3 (0.2 g, 0.46 mmol), Pd(OAc)₂ (5.2 mg, 0.023 mmol), IPr (1,3-bis(2,6-diisopropylphenyl)imidazol-2-ylidene) (16 mg, 0.046 mmol), MesCOONa (sodium 2,4,6-trimethylbenzoate) (43 mg, 0.23 mmol), K₂CO₃ (0.13 g, 0.93 mmol), 4,5-diazafluoren-9-one (8.4 mg, 0.046 mmol) and mesitylene (20 mL) was added to a reaction flask. The reaction system was evacuated, purged with nitrogen, heated to a reaction temperature of 140° C. under a nitrogen atmosphere and reacted overnight. The reaction system was cooled to room temperature and concentrated, and isolated and purified through column chromatography to obtain Intermediate 4 (58 mg, with a yield of 29%).

Step 3: Synthesis of an Iridium Dimer

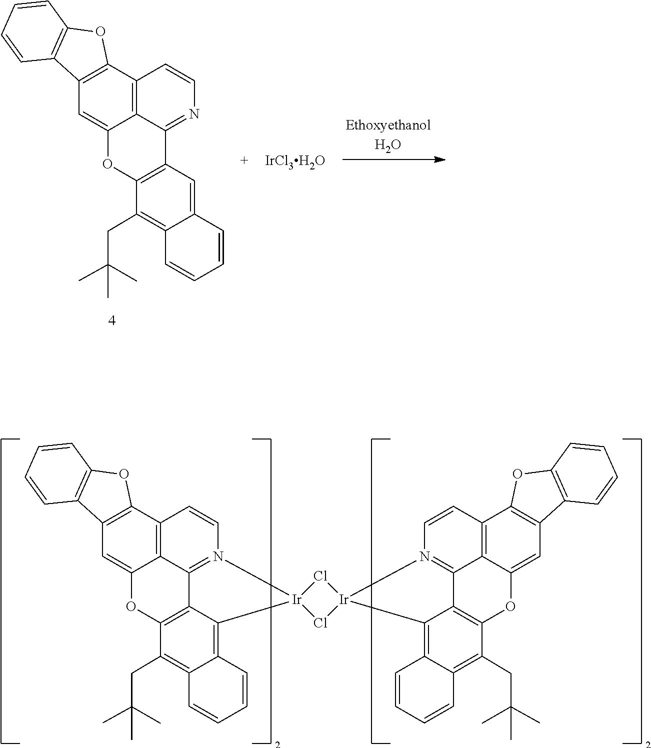

A mixture of Intermediate 4 (0.17 g, 0.4 mmol), iridium trichloride trihydrate (48 mg, 0.14 mmol), ethylene glycol monoethyl ether (12 mL) and water (4 mL) was added to a reaction flask and refluxed at 130° C. for 24 h under a nitrogen atmosphere. The reaction system was cooled to room temperature and filtered. The obtained solids were washed several times with methanol and dried so that an iridium dimer was obtained.

Step 4: Synthesis of Compound 557

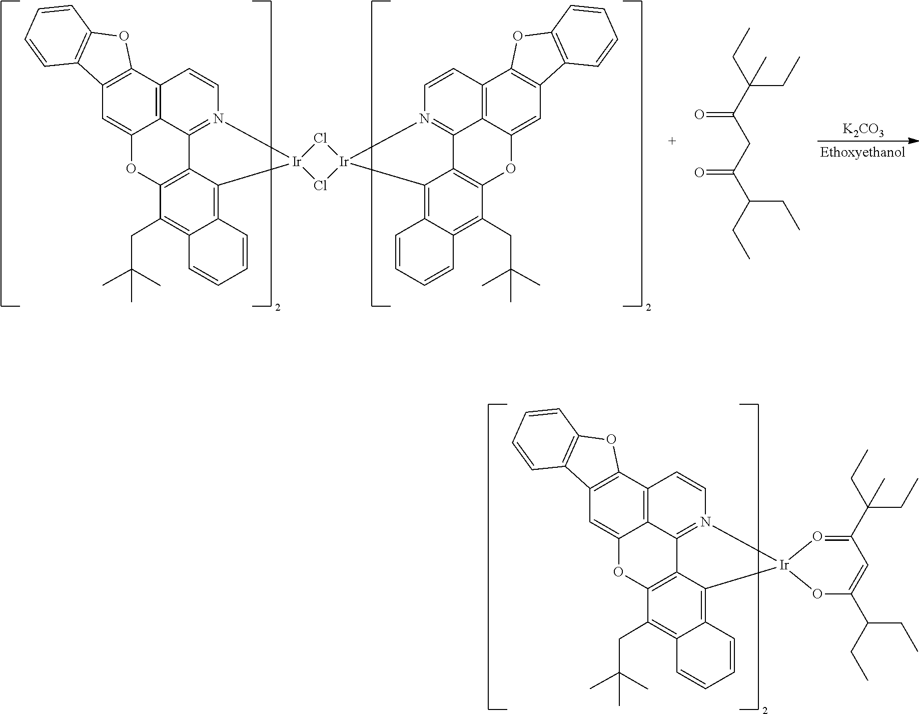

A mixture of the iridium dimer obtained in the previous step, 3,7-diethyl-3-methylnonane-4,6-dione (50 mg, 0.2 mmol), K₂CO₃ (95 mg, 0.68 mmol) and ethylene glycol monoethyl ether (12 mL) was stirred at 45° C. for 24 h under a nitrogen atmosphere. After the reaction was finished, the precipitate was filtered by Celite and washed with ethanol. The obtained solids were added with dichloromethane and the filtrate was collected. Ethanol was added and the resulting solution was concentrated, but not to dryness. The residue was filtered to obtain Compound 557 (90 mg, with a yield of 52%). The structure was confirmed through NMR. ¹H NMR (400 MHz, CDCl₃): δ 8.14 (d, J=7.7 Hz, 2H), 7.98-7.92 (m, 6H), 7.74 (d, J=8.2 Hz, 2H), 7.64-7.57 (m, 4H), 7.50 (dd, J=13.2, 5.7 Hz, 2H), 7.20-7.17 (m, 2H), 6.90 (dd, J=20.9, 7.9 Hz, 2H), 6.63-6.58 (m, 2H), 5.23 (s, 1H), 3.30 (dt, J=26.9, 13.8 Hz, 4H), 2.24-2.20 (m, 1H), 1.12 (d, J=4.6 Hz, 18H), 0.97-0.80 (m, 8H), 0.68 (s, 3H), 0.62 (t, J=7.4 Hz, 3H), 0.32 (t, J=7.4 Hz, 3H), 0.22 (t, J=7.3 Hz, 3H), 0.11 (t, J=7.4 Hz, 3H).

### Synthesis Example 2: Synthesis of Compound 553

Step 1: Synthesis of Intermediate 6

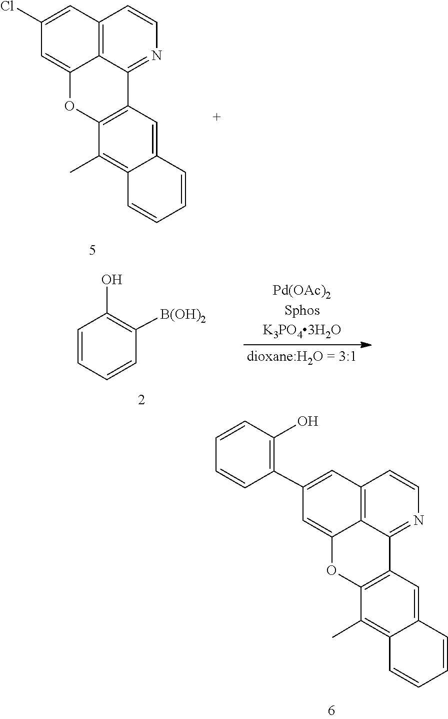 [SMILES: Cc1c2c(cc3ccccc13)-c1nccc3cc(Cl)cc(c13)O2 ; OB(O)c1ccccc1O ; Cc1c2c(cc3ccccc13)-c1nccc3cc(-c4ccccc4O)cc(c13)O2]

A mixture of Intermediate 5 (0.2 g, 0.63 mmol), Intermediate 2 (0.11 g, 0.82 mmol), Pd(OAc)₂ (8 mg, 0.03 mmol), Sphos (26 mg, 0.06 mmol), K₃PO₄·3H₂O (0.5 g, 1.9 mmol), 1,4-dioxane (9 mL) and water (3 mL) was added to a reaction flask. The reaction system was evacuated, purged with nitrogen and underwent a refluxing reaction under a nitrogen atmosphere, and the reaction was monitored through TLC. Intermediate 5 disappeared, and the reaction system was cooled to room temperature. Water and ethyl acetate were added to the reaction system to extract a product, and the organic phases were collected and concentrated, and isolated and purified through column chromatography to obtain Intermediate 6 (0.14 g, with a yield of 58%).

Step 2: Synthesis of Intermediate 7

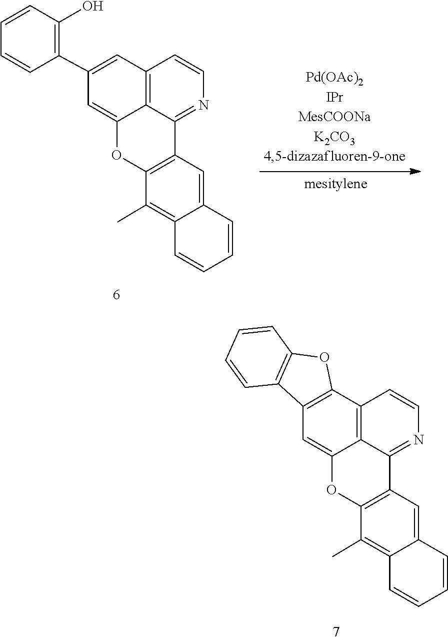 [SMILES: Cc1c2c(cc3ccccc13)-c1nccc3cc(-c4ccccc4O)cc(c13)O2 ; Cc1c2c(cc3ccccc13)-c1nccc3c1c(cc1c4ccccc4oc31)O2]

A mixture of Intermediate 6 (0.14 g, 0.37 mmol), Pd(OAc)₂ (4 mg, 0.018 mmol), IPr (13 mg, 0.037 mmol), MesCOONa (34 mg, 0.18 mmol), K₂CO₃ (0.10 g, 0.74 mmol), 4,5-diazafluoren-9-one (7 mg, 0.037 mmol) and mesitylene (12 mL) was added to a reaction flask. The reaction system was evacuated, purged with nitrogen, heated to 140° C. under a nitrogen atmosphere and reacted overnight. The reaction system was cooled to room temperature and concentrated, and isolated and purified through column chromatography to obtain Intermediate 7 (40 mg, with a yield of 29%).

Step 3: Synthesis of an Iridium Dimer

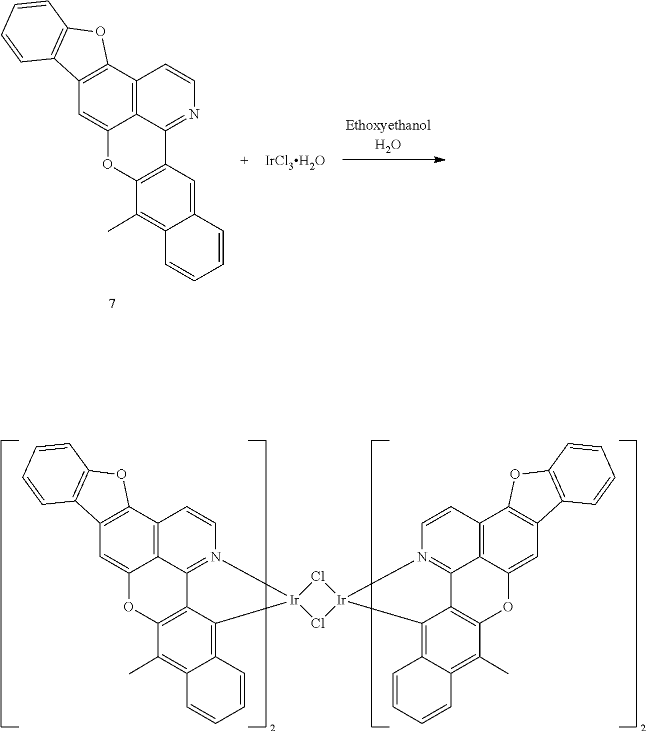

A mixture of Intermediate 7 (70 mg, 0.18 mmol), iridium trichloride trihydrate (22 mg, 0.06 mmol), ethylene glycol monoethyl ether (9 mL) and water (3 mL) was added to a reaction flask and refluxed at 130° C. for 24 h under a nitrogen atmosphere. The reaction system was cooled to room temperature and filtered. The obtained solids were washed several times with methanol and dried so that an iridium dimer was obtained.

Step 4 Synthesis of Compound 553

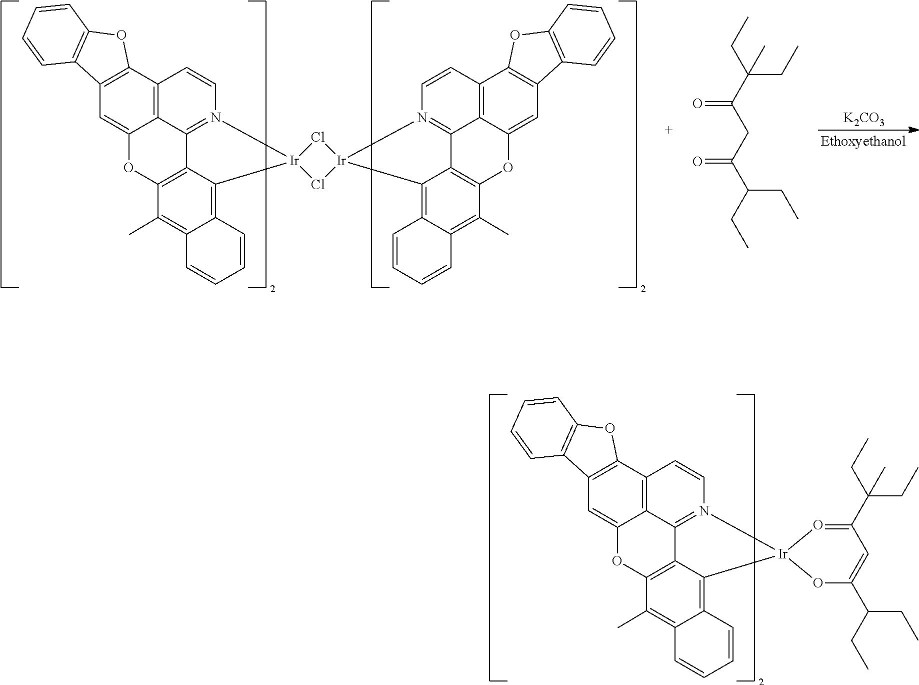

A mixture of the iridium dimer obtained in the previous step, 3,7-diethyl-3-methylnonane-4,6-dione (23 mg, 0.093 mmol), K₂CO₃ (43 mg, 0.31 mmol) and ethylene glycol monoethyl ether (10 mL) was stirred at 45° C. for 24 h under a nitrogen atmosphere. After the reaction was finished, the precipitate was filtered by Celite and washed with ethanol. The obtained solids were added with dichloromethane and the filtrate was collected. Ethanol was added and the resulting solution was concentrated, but not to dryness. The residue was filtered to obtain Compound 553 (20 mg, with a yield of 27%). The structure was confirmed through NMR. H NMR (400 MHz, CDCl₃): δ 8.14 (d, J=7.6 Hz, 2H), 7.98 (m, 4H), 7.82 (d, J=8.3 Hz, 2H), 7.74 (d, J=8.2 Hz, 2H), 7.65 (dd, J=6.6, 4.2 Hz, 2H), 7.60 (t, J=7.8 Hz, 2H), 7.49 (t, J=7.6 Hz, 2H), 7.24-7.20 (m, 2H), 6.85 (dd, J=8.5, 3.7 Hz, 2H), 6.64-6.60 (m, 2H), 5.28 (s, 1H), 2.74 (s, 6H), 2.22 (m, 1H), 0.9-0.83 (m, 8H), 0.72 (s, 3H), 0.60 (t, J=7.4 Hz, 3H), 0.38 (t, J=7.4 Hz, 3H), 0.20 (dt, J=14.9, 7.3 Hz, 6H).

Those skilled in the art will appreciate that the above preparation methods are merely exemplary. Those skilled in the art can obtain the compound structures of the present disclosure through the modifications of the preparation methods.

The method for preparing an electroluminescent device is not limited. The preparation methods in the following examples are merely examples and are not to be construed as limitations. Those skilled in the art can make reasonable improvements on the preparation methods in the following examples based on the related art. For example, the proportions of various materials in a light-emitting layer are not particularly limited. Those skilled in the art can reasonably select the proportions within a certain range based on the related art. For example, taking the total weight of the materials in the light-emitting layer for reference, a host material may account for 80% to 99% and a light-emitting material may account for 1% to 20%; or the host material may account for 90% to 99% and the light-emitting material may account for 1% to 10%; or the host material may account for 95% to 99% and the light-emitting material may account for 1% to 5%. Further, the host material may include one material or two materials, where the ratio of two host materials may be 100:0 to 1:99; or the ratio may be 80:20 to 20:80; or the ratio may be 60:40 to 40:60.

Measurement of Photoluminescence Spectroscopy of Compound 557 and Compound 553

The photoluminescence (PL) spectroscopy data of Compound 557 and Compound 553 of the present disclosure was measured using a fluorescence spectrophotometer LENGGUANG F98 produced by SHANGHAI LENGGUANG TECHNOLOGY CO., LTD. A sample of Compound 557 or a sample of Compound 553 was prepared into a solution with a concentration of 1×10⁻⁶ mol/L by using an HPLC-grade toluene solution and then excited at room temperature (298 K) using light with a wavelength of 500 nm, and its emission spectrum was measured. The light emission wavelength λₘₐₓ (nm) and the full width at half maximum FWHM (nm) of the photoluminescence spectroscopy were recorded and shown in Table 1.

TABLE 1
Photoluminescence spectroscopy data of
Compound 557 and Compound 553

| | λₘₐₓ | FWHM |
|---|---|---|
| Compound No. | (nm) | (nm) |
| Compound 557 | 625 | 29.3 |
| Compound 553 | 629 | 30.1 |

As can be seen from the data in Table 1, the light emission wavelengths of Compound 557 and Compound 553 each comprising a ligand having a structure of Formula 1 disclosed in the present disclosure are 625 nm and 629 nm, respectively, and the full widths at half maximum are both extremely narrow, which are only 29.3 nm and 30.1 nm, respectively, so that very saturated light emission can be achieved, indicating that Compound 557 and Compound 553 of the present disclosure have very excellent light emission performance and have the potential to become excellent red light-emitting materials.

### Device Example

### Example 1

Firstly, a glass substrate having an indium tin oxide (ITO) anode with a thickness of 120 nm was cleaned and then treated with oxygen plasma and UV ozone. After the treatment, the substrate was dried in a glovebox to remove moisture. Then, the substrate was mounted on a substrate holder and placed in a vacuum chamber. Organic layers specified below were sequentially deposited through vacuum thermal evaporation on the ITO anode at a rate of 0.06 to 2 Angstroms per second and a vacuum degree of about 10⁻⁸ torr. Compounds HT and HI were co-deposited at a weight ratio of 97:3 for use as a hole injection layer (HIL) with a thickness of 100 Å. Compound HT was used as a hole transport layer (HTL) with a thickness of 400 Å. Compound EB was used as an electron blocking layer (EBL) with a thickness of 50 Å. Compound 557 of the present disclosure was doped in a host compound RH at a weight ratio of 3:97 for use as an emissive layer (EML) with a thickness of 400 Å. Compound HB was used as a hole blocking layer (HBL) with a thickness of 50 Å. On the HBL, Compound ET and 8-hydroxyquinolinolato-lithium (Liq) were co-deposited at a weight ratio of 40:60 as an electron transport layer (ETL) with a thickness of 350 Å. Finally, Liq was deposited as an electron injection layer with a thickness of 1 nm, and Al was deposited as a cathode with a thickness of 120 nm. The device was transferred back to the glovebox and encapsulated with a glass lid and a moisture getter to complete the device.

### Comparative Example 1

The preparation method in Comparative Example 1 was the same as that in Example 1, except that in the emissive layer (EML), Compound 557 of the present disclosure was replaced with Compound RD.

Structures and thicknesses of part of layers of the devices are shown in the following Table 2. A layer using more than one material is obtained by doping different compounds at their weight ratio as recorded.

TABLE 2
Part of device structures in Device Example 1 and Comparative Example 1

| Device No. | HIL | HTL | EBL | EML | HBL | ETL |
|---|---|---|---|---|---|---|
| Example 1 | Compound | Compound | Compound | Compound | Compound | Compound |
| | HT:HI (97:3) | HT | EB | RH:Compound | HB | ET:Liq |
| | (100 Å) | (400 Å) | (50 Å) | 557 (97:3) | (50 Å) | (40:60) |
| | | | | (400 Å) | | (350 Å) |
| Comparative | Compound | Compound | Compound | Compound | Compound | Compound |
| Example 1 | HT:HI (97:3) | HT | EB | RH:Compound RD | HB | ET:Liq |
| | (100 Å) | (400 Å) | (50 Å) | (97:3) | (50 Å) | (40:60) |
| | | | | (400 Å) | | (350 Å) |

The structures of the materials used in the devices are shown as follows:

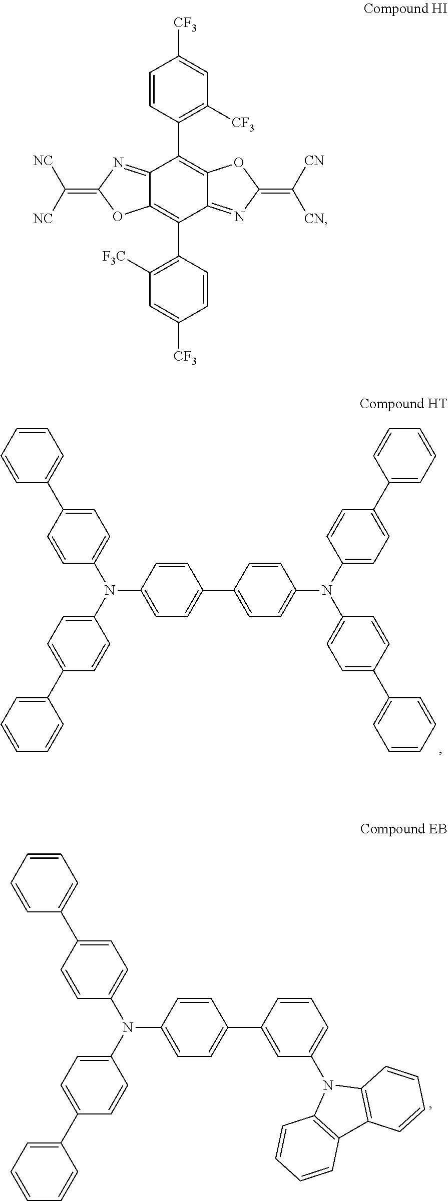 [SMILES: N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(N(c3ccc(-c4ccccc4)cc3)c3ccc(-c4cccc(-n5c6ccccc6c6ccccc65)c4)cc3)cc2)cc1]

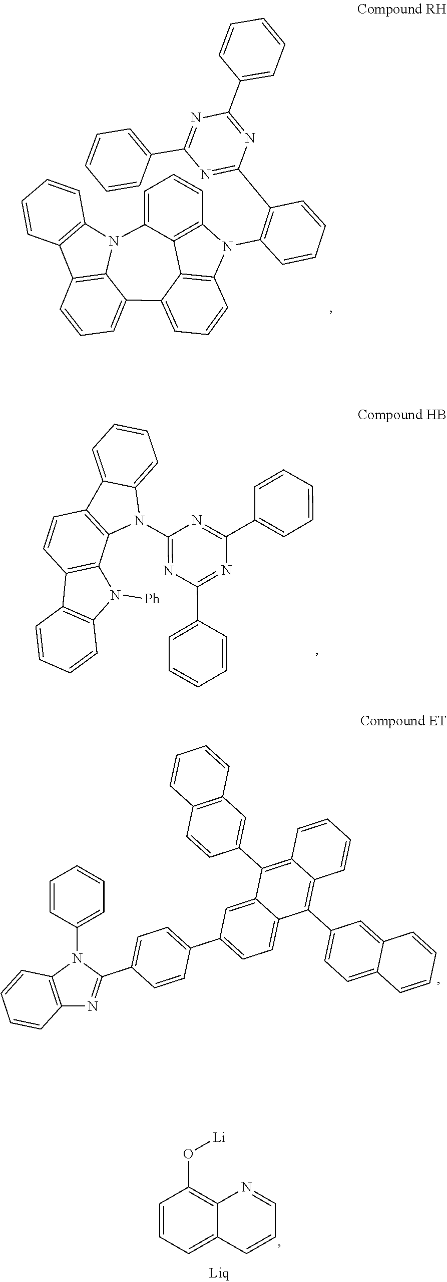

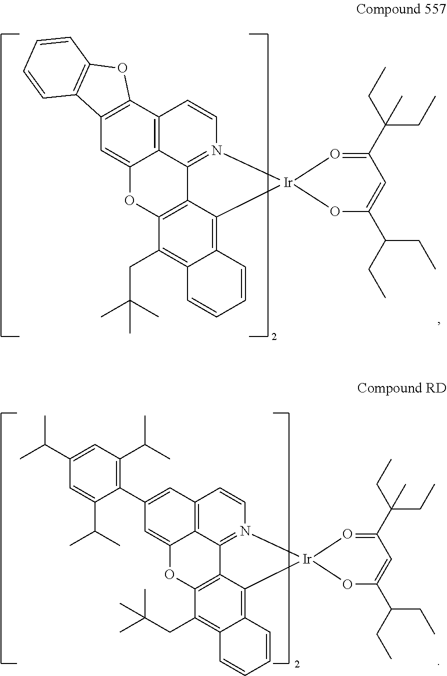

Table 3 shows the color coordinate (CIE), drive voltage (Voltage), maximum emission wavelength (λₘₐₓ), full width at half maximum (FWHM), current efficiency (CE), power efficiency (PE) and external quantum efficiency (EQE) data of Example 1 and Comparative Example 1 measured at a constant current of 15 mA/cm².

TABLE 3
Device data of Example 1 and Comparative Example 1

| | | FWHM | λₘₐₓ | Voltage | CE | PE | EQE |
|---|---|---|---|---|---|---|---|
| Device No. | CIE | (nm) | (nm) | (V) | (cd/A) | (lm/W) | (%) |
| Example 1 | (0.692, 0.307) | 33.4 | 628 | 3.37 | 21.3 | 19.8 | 24.38 |
| Comparative Example 1 | (0.684, 0.314) | 32.5 | 623 | 3.52 | 20.5 | 18.3 | 20.33 |

### DISCUSSION

As can be seen from the data in Table 3, the maximum emission wavelength of Example 1 reached 628 nm, which was 5 nm red-shifted compared to the maximum emission wavelength (623 nm) of Comparative Example 1, and the full width at half maximum of Example 1 was substantially the same as that of Comparative Example 1, both of which had an extremely narrow full width at half maximum. It can be seen that in Example 1, such a narrow full width at half maximum can be maintained while the maximum emission wavelength is red-shifted. Therefore, very saturated light emission can be achieved in Example 1. In addition, compared to Comparative Example 1, the drive voltage of Example 1 was reduced by 0.15 V, the current efficiency (CE) was improved by 4%, and the power efficiency (PE) was improved by 8.2%. More surprisingly, on the basis of the fact that Comparative Example 1 had already had a very high level of EQE (20.33%), the external quantum efficiency of Example 1 was further significantly improved by 20%, which is very rare. All the above data proves that the compound disclosed in the present disclosure has very excellent performance.

In conclusion, the compound disclosed in the present disclosure, while maintaining a very narrow full width at half maximum, can effectively adjust the emission wavelength to better meet the requirement of saturated red light emission, reduce the drive voltage and significantly improve the device efficiency. These advantages highlight the uniqueness of the present disclosure and the commercial application potential as a red light-emitting material.

It should be understood that various embodiments described herein are merely examples and not intended to limit the scope of the present disclosure. Therefore, it is apparent to the persons skilled in the art that the present disclosure as claimed may include variations from specific embodiments and preferred embodiments described herein. Many of materials and structures described herein may be substituted with other materials and structures without departing from the spirit of the present disclosure. It should be understood that various theories as to why the present disclosure works are not intended to be limitative.

What is claimed is:

1. A metal complex, comprising a metal M and a ligand Lₐ coordinated to the metal M, wherein the metal M is selected from a metal with a relative atomic mass greater than 40, and the ligand Lₐ has a structure represented by Formula 1: 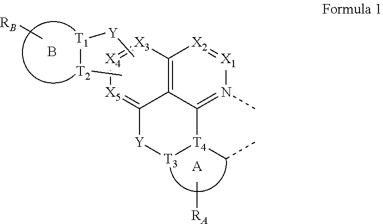
wherein the ring A and the ring B are each independently selected from a five-membered unsaturated carbocyclic ring, an aromatic ring having 6 to 30 carbon atoms or a heteroaromatic ring having 3 to 30 carbon atoms, and when the ring A is a monocyclic ring, the ring A is selected from a five-membered unsaturated carbocyclic ring, a benzene ring or a six-membered heteroaromatic ring;
Y is, at each occurrence identically or differently, selected from CR_{y}R_{y}, SiR_{y}R_{y}, GeR_{y}R_{y}, NR_{y}, PR_{y}, O, S or Se; when a plurality of R_{y} are present at the same time, the plurality of R_{y} are identical or different;
R_{A} and R_{B} represent, at each occurrence identically or differently, mono-substitution, multiple substitutions or non-substitution;
T₁ to T₄ are, at each occurrence identically or differently, selected from C or N;
X₁ and X₂ are, at each occurrence identically or differently, selected from CRₓ or N; X₃ to X₅ are, at each occurrence identically or differently, selected from C, CRₓ or N, and any adjacent two of X₃ to X₅ are C and joined to Y and T₂, respectively;
R_{A}, R_{B}, Rₓ and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R_{A}, R_{B}, Rₓ and R_{y} can be optionally joined to form a ring.

2. The metal complex according to claim 1, wherein the ring A and/or the ring B are each independently selected from a five-membered unsaturated carbocyclic ring, an aromatic ring having 6 to 18 carbon atoms or a heteroaromatic ring having 3 to 18 carbon atoms, and when the ring A is a monocyclic ring, the ring A is selected from a five-membered unsaturated carbocyclic ring, a benzene ring or a six-membered heteroaromatic ring; and
preferably, the ring A and/or the ring B are each independently selected from a five-membered unsaturated carbocyclic ring, an aromatic ring having 6 to 10 carbon atoms or a heteroaromatic ring having 3 to 10 carbon atoms, and when the ring A is a monocyclic ring, the ring A is selected from a five-membered unsaturated carbocyclic ring, a benzene ring or a six-membered heteroaromatic ring.

3. The metal complex according to claim 1, wherein T₁ to T₄ are all selected from C.

4. The metal complex according to claim 1, wherein the ligand Lₐ has a structure represented by any one of Formula 2 to Formula 40: 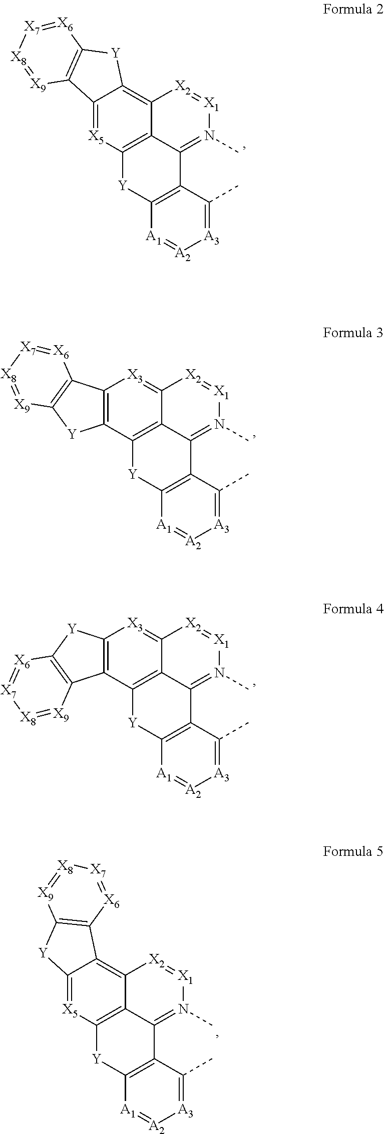 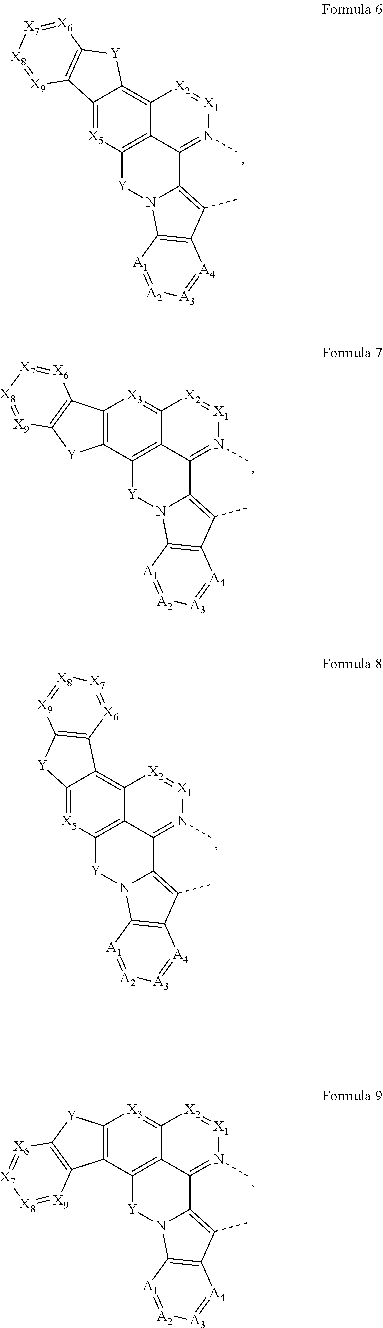 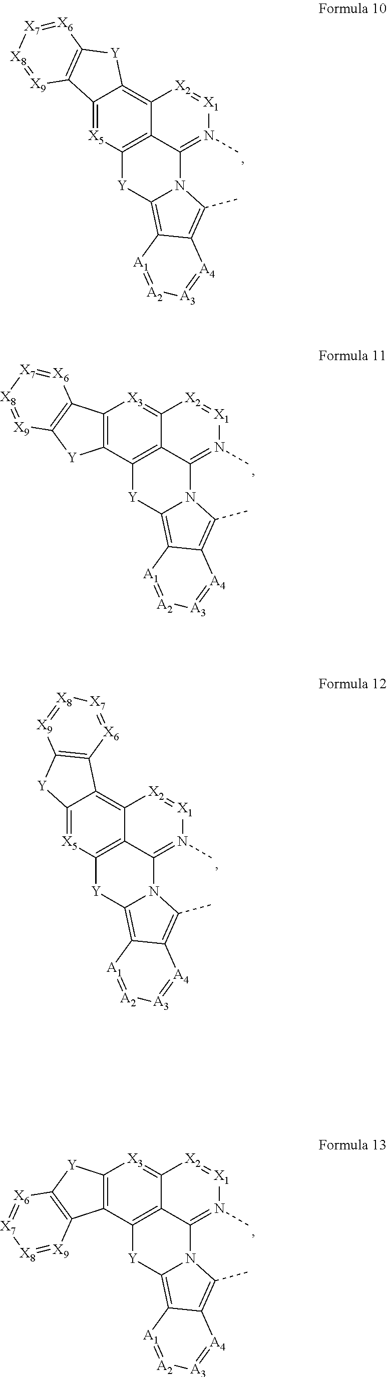 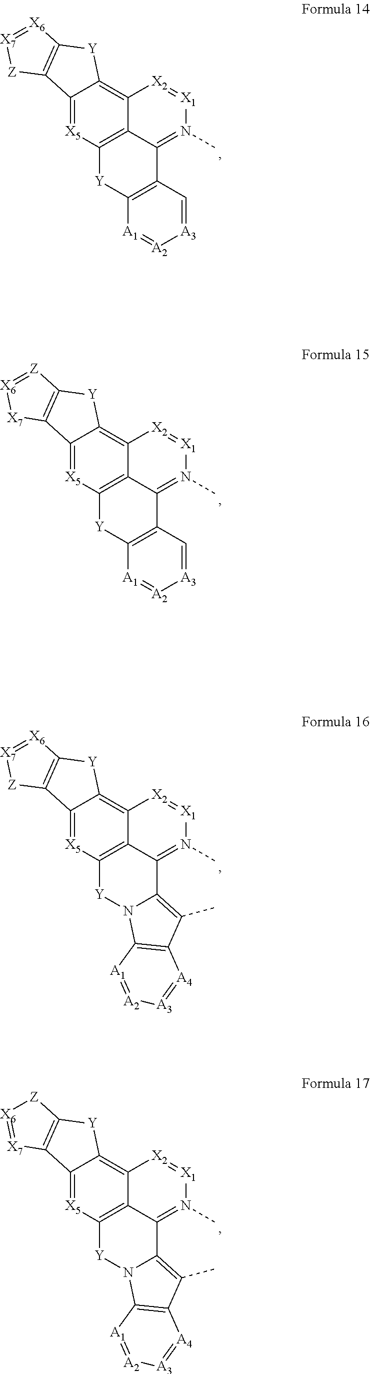 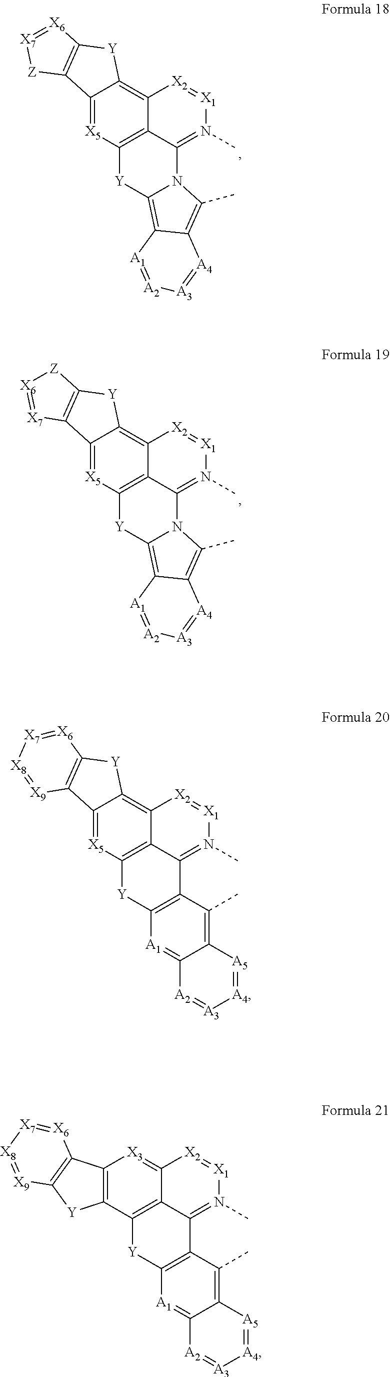 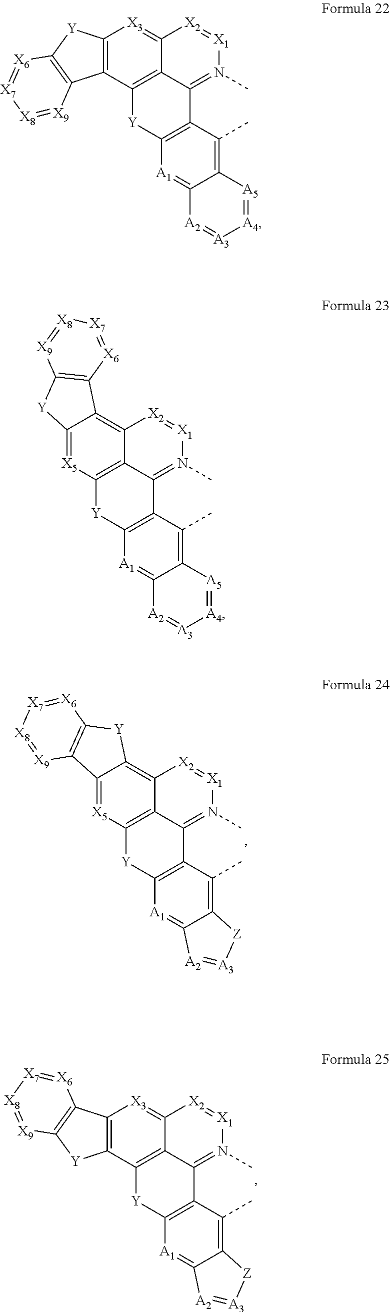 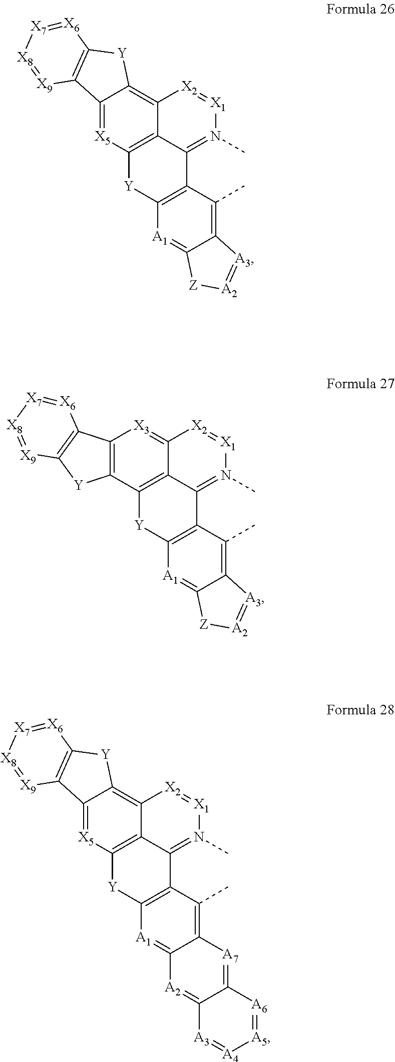 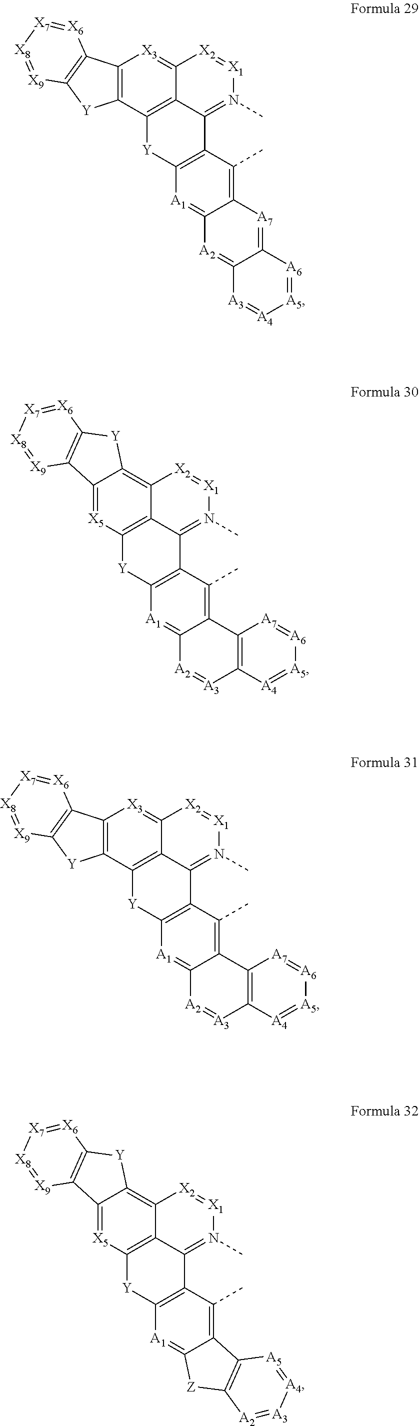 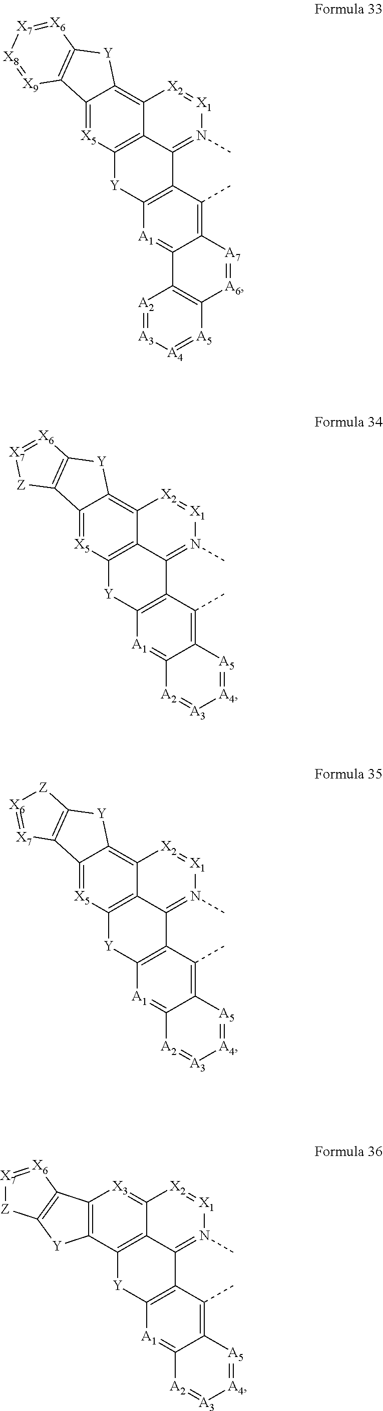 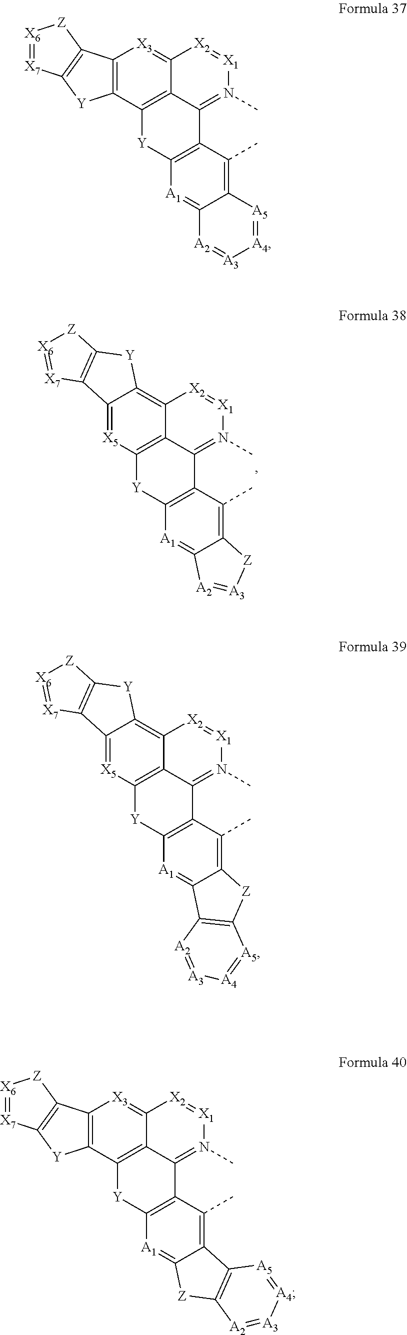
wherein X₁ to X₃ and X₅ to X₉ are, at each occurrence identically or differently, selected from CRₓ or N; A₁ to A₇ are, at each occurrence identically or differently, selected from CR_{A} or N;
Y is, at each occurrence identically or differently, selected from CR_{y}R_{y}, SiR_{y}R_{y}, GeR_{y}R_{y}, NR_{y}, PR_{y}, O, S or Se; when a plurality of R_{y} are present at the same time, the plurality of R_{y} are identical or different;
Z is, at each occurrence identically or differently, selected from CR_{z}R_{z}, SiR_{z}R_{z}, PR_{z}, O, S or NR_{z}; when a plurality of R_{z} are present at the same time, the plurality of R_{z} are identical or different;
Rₓ, R_{y}, R_{A} and R_{z} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents Rₓ, R_{y}, R_{A} and R_{z} can be optionally joined to form a ring;
preferably, the ligand Lₐ is selected from a structure represented by Formula 2, Formula 3, Formula 20 or Formula 21; and
more preferably, the ligand Lₐ is selected from a structure represented by Formula 20 or Formula 21.

5. The metal complex according to claim 4, wherein in Formula 2 to Formula 40, at least one of X₁ to Xₙ and/or A₁ to Aₘ is selected from N, wherein the Xₙ corresponds to the one with the largest serial number among X₁ to X₉ in any one of Formula 2 to Formula 40, and the Aₘ corresponds to the one with the largest serial number among A₁ to A₇ in any one of Formula 2 to Formula 40;
preferably, in Formula 2 to Formula 40, at least one of X₁ to Xₙ is selected from N, wherein the Xₙ corresponds to the one with the largest serial number among X₁ to X₉ in any one of Formula 2 to Formula 40; and
more preferably, X₂ is N.

6. The metal complex according to claim 4, wherein in Formula 2 to Formula 40, X₁ to X₃ and X₅ to X₉ are each independently selected from CRₓ; A₁ to A₇ are each independently selected from CR_{A}; and the Rₓ and R_{A} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof, adjacent substituents Rₓ and R_{A} can be optionally joined to form a ring;
preferably, the Rₓ and R_{A} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group and combinations thereof; and
more preferably, at least one, two or three of the Rₓ and R_{A} is(are), at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group and combinations thereof.

7. The metal complex according to claim 4, wherein in Formula 2 to Formula 40, X₁ and X₂ are each independently selected from CRₓ; and
preferably, the Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof.

8. The metal complex according to claim 4, wherein in Formula 2 to Formula 13 and Formula 20 to Formula 33, X₇ and/or X₈ is selected from CRₓ; in Formula 14 to Formula 19 and Formula 34 to Formula 40, X₆ and/or X₇ is selected from CRₓ; and the Rₓ is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, a substituted or unsubstituted heterocyclic group having 3 to 20 ring atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group, a hydroxyl group, a sulfanyl group, a phosphino group and combinations thereof; and
preferably, the Rₓ is, at each occurrence identically or differently, selected from the group consisting of: deuterium, fluorine, methyl, ethyl, isopropyl, isobutyl, t-butyl, neopentyl, cyclopentyl, cyclopentylmethyl, cyclohexyl, tetrahydrofuranyl, tetrahydropyranyl, deuterated methyl, deuterated ethyl, deuterated isopropyl, deuterated isobutyl, deuterated t-butyl, deuterated neopentyl, deuterated cyclopentyl, deuterated cyclopentylmethyl, deuterated cyclohexyl, norbornyl, adamantyl, trimethylsilyl, isopropyldimethylsilyl, phenyldimethylsilyl, trifluoromethyl, a cyano group, phenyl, 2,4,6-trimethylphenyl, 2,4,6-triisopropylphenyl, pyridyl, triazinyl, thienyl, carbazolyl, a hydroxyl group, a sulfanyl group, a phosphino group and combinations thereof.

9. The metal complex according to claim 4, wherein in Formula 2 to Formula 40, at least one of A₁ to A₇ is selected from CR_{A}; and the R_{A} is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
preferably, in Formula 2 to Formula 40, A₁ is selected from CR_{A}; and the R_{A} is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, a substituted or unsubstituted heterocyclic group having 3 to 20 ring atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group and combinations thereof; and
more preferably, the R_{A} is, at each occurrence identically or differently, selected from the group consisting of: deuterium, fluorine, methyl, ethyl, isopropyl, isobutyl, t-butyl, neopentyl, cyclopentyl, cyclopentylmethyl, cyclohexyl, tetrahydrofuranyl, tetrahydropyranyl, deuterated methyl, deuterated ethyl, deuterated isopropyl, deuterated isobutyl, deuterated t-butyl, deuterated neopentyl, deuterated cyclopentyl, deuterated cyclopentylmethyl, deuterated cyclohexyl, norbornyl, adamantyl, trimethylsilyl, isopropyldimethylsilyl, phenyldimethylsilyl, trifluoromethyl, a cyano group, phenyl, 2,4,6-trimethylphenyl, 2,4,6-triisopropylphenyl and combinations thereof.

10. The metal complex according to claim 4, wherein in Formula 2 to Formula 40, A₁ is selected from CR_{A}, and/or at least one or two of A₂ to A₅ is(are) selected from CR_{A}; and the R_{A} is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
preferably, the R_{A} is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, a substituted or unsubstituted heterocyclic group having 3 to 20 ring atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group and combinations thereof; and
more preferably, the R_{A} is, at each occurrence identically or differently, selected from the group consisting of: deuterium, fluorine, methyl, ethyl, isopropyl, isobutyl, t-butyl, neopentyl, cyclopentyl, cyclopentylmethyl, cyclohexyl, tetrahydrofuranyl, tetrahydropyranyl, deuterated methyl, deuterated ethyl, deuterated isopropyl, deuterated isobutyl, deuterated t-butyl, deuterated neopentyl, deuterated cyclopentyl, deuterated cyclopentylmethyl, deuterated cyclohexyl, norbornyl, adamantyl, trimethylsilyl, isopropyldimethylsilyl, phenyldimethylsilyl, trifluoromethyl, a cyano group, phenyl, 2,4,6-trimethylphenyl, 2,4,6-triisopropylphenyl and combinations thereof.

11. The metal complex according to claim 4, wherein in Formula 2 to Formula 40, Y is, at each occurrence identically or differently, selected from CR_{y}R_{y}, O or S; and
preferably, Y is, at each occurrence identically or differently, selected from O or S.

12. The metal complex according to claim 1, wherein the ligand Lₐ has a structure represented by one of Formula 41 to Formula 44: 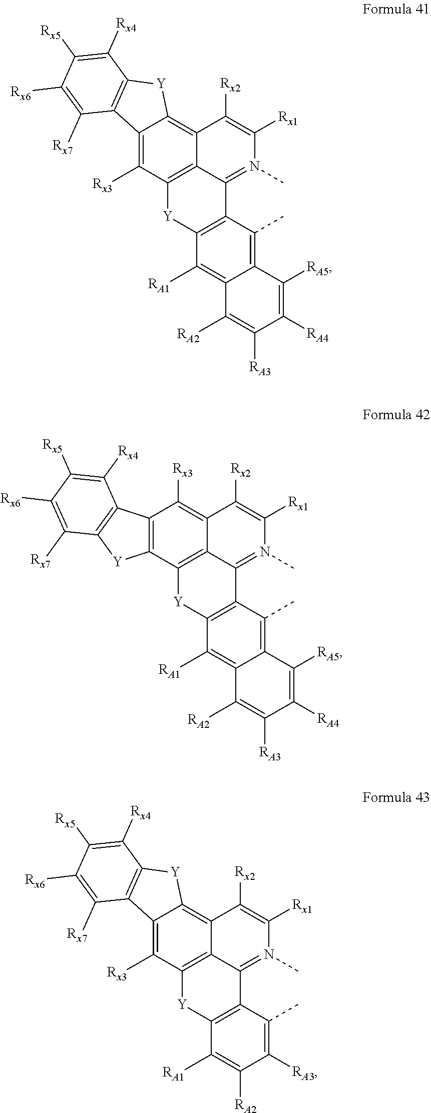 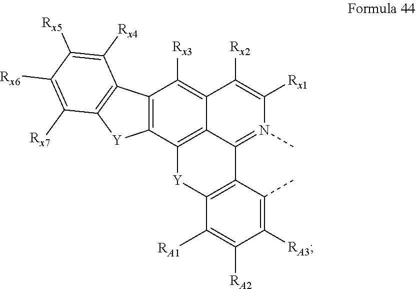
wherein in Formula 41 to Formula 44, Y is, at each occurrence identically or differently, selected from O or S;
Rₓ₁ to Rₓ₇ and R_{A1} to R_{A5} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
preferably, at least one of Rₓ₁ to Rₓ₇ and R_{A1} to R_{A5} is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, a substituted or unsubstituted heterocyclic group having 3 to 20 ring atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group and combinations thereof; and
more preferably, at least one of Rₓ₁ to Rₓ₇ and R_{A1} to R_{A5} is, at each occurrence identically or differently, selected from the group consisting of: deuterium, fluorine, methyl, ethyl, isopropyl, isobutyl, t-butyl, neopentyl, cyclopentyl, cyclopentylmethyl, cyclohexyl, tetrahydrofuranyl, tetrahydropyranyl, deuterated methyl, deuterated ethyl, deuterated isopropyl, deuterated isobutyl, deuterated t-butyl, deuterated neopentyl, deuterated cyclopentyl, deuterated cyclopentylmethyl, deuterated cyclohexyl, norbornyl, adamantyl, trimethylsilyl, isopropyldimethylsilyl, phenyldimethylsilyl, trifluoromethyl, a cyano group, phenyl, 2,4,6-trimethylphenyl, 2,4,6-triisopropylphenyl and combinations thereof.

13. The metal complex according to claim 12, wherein in Formula 41 to Formula 44, at least one or two of Rₓ₁ to Rₓ₇ and/or at least one or two of R_{A1} to R_{A5} is(are), at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof; and
preferably, at least one or two of Rₓ₁ to Rₓ₇ and/or at least one or two of R_{A1} to R_{A5} is(are), at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof.

14. The metal complex according to claim 12, wherein in Formula 41 to Formula 44, Rₓ₅ and/or Rₓ₆ is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof, R_{A1} is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof; at least one or two of R_{A2} to R_{A5} is(are), at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof; and
preferably, Rₓ₅ and/or Rₓ₆ is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof, R_{A1} is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof; at least one or two of R_{A2} to R_{A5} is(are), at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms and combinations thereof.

15. The metal complex according to claim 1, wherein the ligand Lₐ is, at each occurrence identically or differently, selected from the group consisting of Lₐ₁ to Lₐ₄₄₈₉;
wherein Lₐ₁ to Lₐ₉₇₀ each have a structure represented by Formula 45: 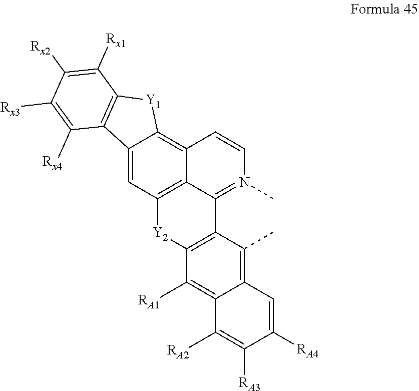
wherein Y₁, Y₂, Rₓ₁ to Rₓ₄ and R_{A1} to R_{A4} are selected from the groups listed in the following table, respectively:

| Ligand No. | Y₁ | Rₓ₁ | Rₓ₂ | Rₓ₃ | Rₓ₄ | Y₂ | R_{A1} | R_{A2} | R_{A3} | R_{A4} |
|---|---|---|---|---|---|---|---|---|---|---|
| Lₐ₁ | O | Q₁ | Q₁ | Q₁ | Q₁ | O | Q₁ | Q₁ | Q₁ | Q₁ |
| Lₐ₂ | O | Q₂ | Q₁ | Q₁ | Q₁ | O | Q₁ | Q₁ | Q₁ | Q₁ |
| Lₐ₃ | O | Q₃ | Q₁ | Q₁ | Q₁ | O | Q₁ | Q₁ | Q₁ | Q₁ |
| Lₐ₄ | O | Q₄ | Q₁ | Q₁ | Q₁ | O | Q₁ | Q₁ | Q₁ | Q₁ |
| Lₐ₅ | O | Q₅ | Q₁ | Q₁ | Q₁ | O | Q₁ | Q₁ | Q₁ | Q₁ |
| Lₐ₆ | O | Q₆ | Q₁ | Q₁ | Q₁ | O | Q₁ | Q₁ | Q₁ | Q₁ |
| Lₐ₇ | O | Q₇ | Q₁ | Q₁ | Q₁ | O | Q₁ | Q₁ | Q₁ | Q₁ |
| Lₐ₈ | O | Q₈ | Q₁ | Q₁ | Q₁ | O | Q₁ | Q₁ | Q₁ | Q₁ |
| Lₐ₉ | O | Q₉ | Q₁ | Q₁ | Q₁ | O | Q₁ | Q₁ | Q₁ | Q₁ |
| Lₐ₁₀ | O | Q₁₀ | Q₁ | Q₁ | Q₁ | O | Q₁ | Q₁ | Q₁ | Q₁ |
| Lₐ₁₁ | O | Q₁₁ | Q₁ | Q₁ | Q₁ | O | Q₁ | Q₁ | Q₁ | Q₁ |
| Lₐ₁₂ | O | Q₁₂ | Q₁ | Q₁ | Q₁ | O | Q₁ | Q₁ | Q₁ | Q₁ |
| Lₐ₁₃ | O | Q₁₃ | Q₁ | Q₁ | Q₁ | O | Q₁ | Q₁ | Q₁ | Q₁ |
| Lₐ₁₄ | O | Q₁₄ | Q₁ | Q₁ | Q₁ | O | Q₁ | Q₁ | Q₁ | Q₁ |
| Lₐ₁₅ | O | Q₁₅ | Q₁ | Q₁ | Q₁ | O | Q₁ | Q₁ | Q₁ | Q₁ |
| Lₐ₁₆ | O | Q₁₆ | Q₁ | Q₁ | Q₁ | O | Q₁ | Q₁ | Q₁ | Q₁ |
| Lₐ₁₇ | O | Q₁₇ | Q₁ | Q₁ | Q₁ | O | Q₁ | Q₁ | Q₁ | Q₁ |
| Lₐ₁₈ | O | Q₁₈ | Q₁ | Q₁ | Q₁ | O | Q₁ | Q₁ | Q₁ | Q₁ |
| Lₐ₁₉ | O | Q₁₉ | Q₁ | Q₁ | Q₁ | O | Q₁ | Q₁ | Q₁ | Q₁ |
| Lₐ₂₀ | O | Q₂₀ | Q₁ | Q₁ | Q₁ | O | Q₁ | Q₁ | Q₁ | Q₁ |
| Lₐ₂₁ | O | Q₂₁ | Q₁ | Q₁ | Q₁ | O | Q₁ | Q₁ | Q₁ | Q₁ |
| Lₐ₂₂ | O | Q₂₂ | Q₁ | Q₁ | Q₁ | O | Q₁ | Q₁ | Q₁ | Q₁ |
| Lₐ₂₃ | O | Q₂₃ | Q₁ | Q₁ | Q₁ | O | Q₁ | Q₁ | Q₁ | Q₁ |
| Lₐ₂₄ | O | Q₁ | Q₂ | Q₁ | Q₁ | O | Q₁ | Q₁ | Q₁ | Q₁ |
| Lₐ₂₅ | O | Q₁ | Q₃ | Q₁ | Q₁ | O | Q₁ | Q₁ | Q₁ | Q₁ |
| Lₐ₂₆ | O | Q₁ | Q₄ | Q₁ | Q₁ | O | Q₁ | Q₁ | Q₁ | Q₁ |
| Lₐ₂₇ | O | Q₁ | Q₅ | Q₁ | Q₁ | O | Q₁ | Q₁ | Q₁ | Q₁ |
| Lₐ₂₈ | O | Q₁ | Q₆ | Q₁ | Q₁ | O | Q₁ | Q₁ | Q₁ | Q₁ |
| Lₐ₂₉ | O | Q₁ | Q₇ | Q₁ | Q₁ | O | Q₁ | Q₁ | Q₁ | Q₁ |
| Lₐ₃₀ | O | Q₁ | Q₈ | Q₁ | Q₁ | O | Q₁ | Q₁ | Q₁ | Q₁ |
| Lₐ₃₁ | O | Q₁ | Q₉ | Q₁ | Q₁ | O | Q₁ | Q₁ | Q₁ | Q₁ |
| Lₐ₃₂ | O | Q₁ | Q₁₀ | Q₁ | Q₁ | O | Q₁ | Q₁ | Q₁ | Q₁ |
| Lₐ₃₃ | O | Q₁ | Q₁₁ | Q₁ | Q₁ | O | Q₁ | Q₁ | Q₁ | Q₁ |
| Lₐ₃₄ | O | Q₁ | Q₁₂ | Q₁ | Q₁ | O | Q₁ | Q₁ | Q₁ | Q₁ |
| Lₐ₃₅ | O | Q₁ | Q₁₃ | Q₁ | Q₁ | O | Q₁ | Q₁ | Q₁ | Q₁ |
| Lₐ₃₆ | O | Q₁ | Q₁₄ | Q₁ | Q₁ | O | Q₁ | Q₁ | Q₁ | Q₁ |
| Lₐ₃₇ | O | Q₁ | Q₁₅ | Q₁ | Q₁ | O | Q₁ | Q₁ | Q₁ | Q₁ |
| Lₐ₃₈ | O | Q₁ | Q₁₆ | Q₁ | Q₁ | O | Q₁ | Q₁ | Q₁ | Q₁ |
| Lₐ₃₉ | O | Q₁ | Q₁₇ | Q₁ | Q₁ | O | Q₁ | Q₁ | Q₁ | Q₁ |
| Lₐ₄₀ | O | Q₁ | Q₁₈ | Q₁ | Q₁ | O | Q₁ | Q₁ | Q₁ | Q₁ |
| Lₐ₄₁ | O | Q₁ | Q₁₉ | Q₁ | Q₁ | O | Q₁ | Q₁ | Q₁ | Q₁ |
| Lₐ₄₂ | O | Q₁ | Q₂₀ | Q₁ | Q₁ | O | Q₁ | Q₁ | Q₁ | Q₁ |
| Lₐ₄₃ | O | Q₁ | Q₂₁ | Q₁ | Q₁ | O | Q₁ | Q₁ | Q₁ | Q₁ |
| Lₐ₄₄ | O | Q₁ | Q₂₂ | Q₁ | Q₁ | O | Q₁ | Q₁ | Q₁ | Q₁ |
| Lₐ₄₅ | O | Q₁ | Q₂₃ | Q₁ | Q₁ | O | Q₁ | Q₁ | Q₁ | Q₁ |
| Lₐ₄₆ | O | Q₁ | Q₁ | Q₂ | Q₁ | O | Q₁ | Q₁ | Q₁ | Q₁ |
| Lₐ₄₇ | O | Q₁ | Q₁ | Q₃ | Q₁ | O | Q₁ | Q₁ | Q₁ | Q₁ |
| Lₐ₄₈ | O | Q₁ | Q₁ | Q₄ | Q₁ | O | Q₁ | Q₁ | Q₁ | Q₁ |
| Lₐ₄₉ | O | Q₁ | Q₁ | Q₅ | Q₁ | O | Q₁ | Q₁ | Q₁ | Q₁ |
| Lₐ₅₀ | O | Q₁ | Q₁ | Q₆ | Q₁ | O | Q₁ | Q₁ | Q₁ | Q₁ |
| Lₐ₅₁ | O | Q₁ | Q₁ | Q₇ | Q₁ | O | Q₁ | Q₁ | Q₁ | Q₁ |
| Lₐ₅₂ | O | Q₁ | Q₁ | Q₈ | Q₁ | O | Q₁ | Q₁ | Q₁ | Q₁ |
| Lₐ₅₃ | O | Q₁ | Q₁ | Q₉ | Q₁ | O | Q₁ | Q₁ | Q₁ | Q₁ |
| Lₐ₅₄ | O | Q₁ | Q₁ | Q₁₀ | Q₁ | O | Q₁ | Q₁ | Q₁ | Q₁ |
| Lₐ₅₅ | O | Q₁ | Q₁ | Q₁₁ | Q₁ | O | Q₁ | Q₁ | Q₁ | Q₁ |
| Lₐ₅₆ | O | Q₁ | Q₁ | Q₁₂ | Q₁ | O | Q₁ | Q₁ | Q₁ | Q₁ |
| Lₐ₅₇ | O | Q₁ | Q₁ | Q₁₃ | Q₁ | O | Q₁ | Q₁ | Q₁ | Q₁ |
| Lₐ₅₈ | O | Q₁ | Q₁ | Q₁₄ | Q₁ | O | Q₁ | Q₁ | Q₁ | Q₁ |
| Lₐ₅₉ | O | Q₁ | Q₁ | Q₁₅ | Q₁ | O | Q₁ | Q₁ | Q₁ | Q₁ |
| Lₐ₆₀ | O | Q₁ | Q₁ | Q₁₆ | Q₁ | O | Q₁ | Q₁ | Q₁ | Q₁ |
| Lₐ₆₁ | O | Q₁ | Q₁ | Q₁₇ | Q₁ | O | Q₁ | Q₁ | Q₁ | Q₁ |
| Lₐ₆₂ | O | Q₁ | Q₁ | Q₁₈ | Q₁ | O | Q₁ | Q₁ | Q₁ | Q₁ |
| Lₐ₆₃ | O | Q₁ | Q₁ | Q₁₉ | Q₁ | O | Q₁ | Q₁ | Q₁ | Q₁ |
| Lₐ₆₄ | O | Q₁ | Q₁ | Q₂₀ | Q₁ | O | Q₁ | Q₁ | Q₁ | Q₁ |
| Lₐ₆₅ | O | Q₁ | Q₁ | Q₂₁ | Q₁ | O | Q₁ | Q₁ | Q₁ | Q₁ |
| Lₐ₆₆ | O | Q₁ | Q₁ | Q₂₂ | Q₁ | O | Q₁ | Q₁ | Q₁ | Q₁ |
| Lₐ₆₇ | O | Q₁ | Q₁ | Q₂₃ | Q₁ | O | Q₁ | Q₁ | Q₁ | Q₁ |
| Lₐ₆₈ | O | Q₁ | Q₁ | Q₁ | Q₂ | O | Q₁ | Q₁ | Q₁ | Q₁ |
| Lₐ₆₉ | O | Q₁ | Q₁ | Q₁ | Q₃ | O | Q₁ | Q₁ | Q₁ | Q₁ |
| Lₐ₇₀ | O | Q₁ | Q₁ | Q₁ | Q₄ | O | Q₁ | Q₁ | Q₁ | Q₁ |
| Lₐ₇₁ | O | Q₁ | Q₁ | Q₁ | Q₅ | O | Q₁ | Q₁ | Q₁ | Q₁ |
| Lₐ₇₂ | O | Q₁ | Q₁ | Q₁ | Q₆ | O | Q₁ | Q₁ | Q₁ | Q₁ |
| Lₐ₇₃ | O | Q₁ | Q₁ | Q₁ | Q₇ | O | Q₁ | Q₁ | Q₁ | Q₁ |
| Lₐ₇₄ | O | Q₁ | Q₁ | Q₁ | Q₈ | O | Q₁ | Q₁ | Q₁ | Q₁ |
| Lₐ₇₅ | O | Q₁ | Q₁ | Q₁ | Q₉ | O | Q₁ | Q₁ | Q₁ | Q₁ |
| Lₐ₇₆ | O | Q₁ | Q₁ | Q₁ | Q₁₀ | O | Q₁ | Q₁ | Q₁ | Q₁ |
| Lₐ₇₇ | O | Q₁ | Q₁ | Q₁ | Q₁₁ | O | Q₁ | Q₁ | Q₁ | Q₁ |
| Lₐ₇₈ | O | Q₁ | Q₁ | Q₁ | Q₁₂ | O | Q₁ | Q₁ | Q₁ | Q₁ |
| Lₐ₇₉ | O | Q₁ | Q₁ | Q₁ | Q₁₃ | O | Q₁ | Q₁ | Q₁ | Q₁ |
| Lₐ₈₀ | O | Q₁ | Q₁ | Q₁ | Q₁₄ | O | Q₁ | Q₁ | Q₁ | Q₁ |
| Lₐ₈₁ | O | Q₁ | Q₁ | Q₁ | Q₁₅ | O | Q₁ | Q₁ | Q₁ | Q₁ |
| Lₐ₈₂ | O | Q₁ | Q₁ | Q₁ | Q₁₆ | O | Q₁ | Q₁ | Q₁ | Q₁ |
| Lₐ₈₃ | O | Q₁ | Q₁ | Q₁ | Q₁₇ | O | Q₁ | Q₁ | Q₁ | Q₁ |
| Lₐ₈₄ | O | Q₁ | Q₁ | Q₁ | Q₁₈ | O | Q₁ | Q₁ | Q₁ | Q₁ |
| Lₐ₈₅ | O | Q₁ | Q₁ | Q₁ | Q₁₉ | O | Q₁ | Q₁ | Q₁ | Q₁ |
| Lₐ₈₆ | O | Q₁ | Q₁ | Q₁ | Q₂₀ | O | Q₁ | Q₁ | Q₁ | Q₁ |
| Lₐ₈₇ | O | Q₁ | Q₁ | Q₁ | Q₂₁ | O | Q₁ | Q₁ | Q₁ | Q₁ |
| Lₐ₈₈ | O | Q₁ | Q₁ | Q₁ | Q₂₂ | O | Q₁ | Q₁ | Q₁ | Q₁ |
| Lₐ₈₉ | O | Q₁ | Q₁ | Q₁ | Q₂₃ | O | Q₁ | Q₁ | Q₁ | Q₁ |
| Lₐ₉₀ | O | Q₁ | Q₁ | Q₁ | Q₁ | O | Q₂ | Q₁ | Q₁ | Q₁ |
| Lₐ₉₁ | O | Q₁ | Q₁ | Q₁ | Q₁ | O | Q₃ | Q₁ | Q₁ | Q₁ |
| Lₐ₉₂ | O | Q₁ | Q₁ | Q₁ | Q₁ | O | Q₄ | Q₁ | Q₁ | Q₁ |
| Lₐ₉₃ | O | Q₁ | Q₁ | Q₁ | Q₁ | O | Q₅ | Q₁ | Q₁ | Q₁ |
| Lₐ₉₄ | O | Q₁ | Q₁ | Q₁ | Q₁ | O | Q₆ | Q₁ | Q₁ | Q₁ |
| Lₐ₉₅ | O | Q₁ | Q₁ | Q₁ | Q₁ | O | Q₇ | Q₁ | Q₁ | Q₁ |
| Lₐ₉₆ | O | Q₁ | Q₁ | Q₁ | Q₁ | O | Q₈ | Q₁ | Q₁ | Q₁ |
| Lₐ₉₇ | O | Q₁ | Q₁ | Q₁ | Q₁ | O | Q₉ | Q₁ | Q₁ | Q₁ |
| Lₐ₉₈ | O | Q₁ | Q₁ | Q₁ | Q₁ | O | Q₁₀ | Q₁ | Q₁ | Q₁ |
| Lₐ₉₉ | O | Q₁ | Q₁ | Q₁ | Q₁ | O | Q₁₁ | Q₁ | Q₁ | Q₁ |
| Lₐ₁₀₀ | O | Q₁ | Q₁ | Q₁ | Q₁ | O | Q₁₂ | Q₁ | Q₁ | Q₁ |
| Lₐ₁₀₁ | O | Q₁ | Q₁ | Q₁ | Q₁ | O | Q₁₃ | Q₁ | Q₁ | Q₁ |
| Lₐ₁₀₂ | O | Q₁ | Q₁ | Q₁ | Q₁ | O | Q₁₄ | Q₁ | Q₁ | Q₁ |
| Lₐ₁₀₃ | O | Q₁ | Q₁ | Q₁ | Q₁ | O | Q₁₅ | Q₁ | Q₁ | Q₁ |
| Lₐ₁₀₄ | O | Q₁ | Q₁ | Q₁ | Q₁ | O | Q₁₆ | Q₁ | Q₁ | Q₁ |
| Lₐ₁₀₅ | O | Q₁ | Q₁ | Q₁ | Q₁ | O | Q₁₇ | Q₁ | Q₁ | Q₁ |
| Lₐ₁₀₆ | O | Q₁ | Q₁ | Q₁ | Q₁ | O | Q₁₈ | Q₁ | Q₁ | Q₁ |
| Lₐ₁₀₇ | O | Q₁ | Q₁ | Q₁ | Q₁ | O | Q₁₉ | Q₁ | Q₁ | Q₁ |
| Lₐ₁₀₈ | O | Q₁ | Q₁ | Q₁ | Q₁ | O | Q₂₀ | Q₁ | Q₁ | Q₁ |
| Lₐ₁₀₉ | O | Q₁ | Q₁ | Q₁ | Q₁ | O | Q₂₁ | Q₁ | Q₁ | Q₁ |
| Lₐ₁₁₀ | O | Q₁ | Q₁ | Q₁ | Q₁ | O | Q₂₂ | Q₁ | Q₁ | Q₁ |
| Lₐ₁₁₁ | O | Q₁ | Q₁ | Q₁ | Q₁ | O | Q₂₃ | Q₁ | Q₁ | Q₁ |
| Lₐ₁₁₂ | O | Q₁ | Q₁ | Q₁ | Q₁ | O | Q₁ | Q₂ | Q₁ | Q₁ |
| Lₐ₁₁₃ | O | Q₁ | Q₁ | Q₁ | Q₁ | O | Q₁ | Q₃ | Q₁ | Q₁ |
| Lₐ₁₁₄ | O | Q₁ | Q₁ | Q₁ | Q₁ | O | Q₁ | Q₄ | Q₁ | Q₁ |
| Lₐ₁₁₅ | O | Q₁ | Q₁ | Q₁ | Q₁ | O | Q₁ | Q₅ | Q₁ | Q₁ |
| Lₐ₁₁₆ | O | Q₁ | Q₁ | Q₁ | Q₁ | O | Q₁ | Q₆ | Q₁ | Q₁ |
| Lₐ₁₁₇ | O | Q₁ | Q₁ | Q₁ | Q₁ | O | Q₁ | Q₇ | Q₁ | Q₁ |
| Lₐ₁₁₈ | O | Q₁ | Q₁ | Q₁ | Q₁ | O | Q₁ | Q₈ | Q₁ | Q₁ |
| Lₐ₁₁₉ | O | Q₁ | Q₁ | Q₁ | Q₁ | O | Q₁ | Q₉ | Q₁ | Q₁ |
| Lₐ₁₂₀ | O | Q₁ | Q₁ | Q₁ | Q₁ | O | Q₁ | Q₁₀ | Q₁ | Q₁ |
| Lₐ₁₂₁ | O | Q₁ | Q₁ | Q₁ | Q₁ | O | Q₁ | Q₁₁ | Q₁ | Q₁ |
| Lₐ₁₂₂ | O | Q₁ | Q₁ | Q₁ | Q₁ | O | Q₁ | Q₁₂ | Q₁ | Q₁ |
| Lₐ₁₂₃ | O | Q₁ | Q₁ | Q₁ | Q₁ | O | Q₁ | Q₁₃ | Q₁ | Q₁ |
| Lₐ₁₂₄ | O | Q₁ | Q₁ | Q₁ | Q₁ | O | Q₁ | Q₁₄ | Q₁ | Q₁ |
| Lₐ₁₂₅ | O | Q₁ | Q₁ | Q₁ | Q₁ | O | Q₁ | Q₁₅ | Q₁ | Q₁ |
| Lₐ₁₂₆ | O | Q₁ | Q₁ | Q₁ | Q₁ | O | Q₁ | Q₁₆ | Q₁ | Q₁ |
| Lₐ₁₂₇ | O | Q₁ | Q₁ | Q₁ | Q₁ | O | Q₁ | Q₁₇ | Q₁ | Q₁ |
| Lₐ₁₂₈ | O | Q₁ | Q₁ | Q₁ | Q₁ | O | Q₁ | Q₁₈ | Q₁ | Q₁ |
| Lₐ₁₂₉ | O | Q₁ | Q₁ | Q₁ | Q₁ | O | Q₁ | Q₁₉ | Q₁ | Q₁ |
| Lₐ₁₃₀ | O | Q₁ | Q₁ | Q₁ | Q₁ | O | Q₁ | Q₂₀ | Q₁ | Q₁ |
| Lₐ₁₃₁ | O | Q₁ | Q₁ | Q₁ | Q₁ | O | Q₁ | Q₂₁ | Q₁ | Q₁ |
| Lₐ₁₃₂ | O | Q₁ | Q₁ | Q₁ | Q₁ | O | Q₁ | Q₂₂ | Q₁ | Q₁ |
| Lₐ₁₃₃ | O | Q₁ | Q₁ | Q₁ | Q₁ | O | Q₁ | Q₂₃ | Q₁ | Q₁ |
| Lₐ₁₃₄ | O | Q₁ | Q₁ | Q₁ | Q₁ | O | Q₁ | Q₁ | Q₂ | Q₁ |
| Lₐ₁₃₅ | O | Q₁ | Q₁ | Q₁ | Q₁ | O | Q₁ | Q₁ | Q₃ | Q₁ |
| Lₐ₁₃₆ | O | Q₁ | Q₁ | Q₁ | Q₁ | O | Q₁ | Q₁ | Q₄ | Q₁ |
| Lₐ₁₃₇ | O | Q₁ | Q₁ | Q₁ | Q₁ | O | Q₁ | Q₁ | Q₅ | Q₁ |
| Lₐ₁₃₈ | O | Q₁ | Q₁ | Q₁ | Q₁ | O | Q₁ | Q₁ | Q₆ | Q₁ |
| Lₐ₁₃₉ | O | Q₁ | Q₁ | Q₁ | Q₁ | O | Q₁ | Q₁ | Q₇ | Q₁ |
| Lₐ₁₄₀ | O | Q₁ | Q₁ | Q₁ | Q₁ | O | Q₁ | Q₁ | Q₈ | Q₁ |
| Lₐ₁₄₁ | O | Q₁ | Q₁ | Q₁ | Q₁ | O | Q₁ | Q₁ | Q₉ | Q₁ |
| Lₐ₁₄₂ | O | Q₁ | Q₁ | Q₁ | Q₁ | O | Q₁ | Q₁ | Q₁₀ | Q₁ |
| Lₐ₁₄₃ | O | Q₁ | Q₁ | Q₁ | Q₁ | O | Q₁ | Q₁ | Q₁₁ | Q₁ |
| Lₐ₁₄₄ | O | Q₁ | Q₁ | Q₁ | Q₁ | O | Q₁ | Q₁ | Q₁₂ | Q₁ |
| Lₐ₁₄₅ | O | Q₁ | Q₁ | Q₁ | Q₁ | O | Q₁ | Q₁ | Q₁₃ | Q₁ |
| Lₐ₁₄₆ | O | Q₁ | Q₁ | Q₁ | Q₁ | O | Q₁ | Q₁ | Q₁₄ | Q₁ |
| Lₐ₁₄₇ | O | Q₁ | Q₁ | Q₁ | Q₁ | O | Q₁ | Q₁ | Q₁₅ | Q₁ |
| Lₐ₁₄₈ | O | Q₁ | Q₁ | Q₁ | Q₁ | O | Q₁ | Q₁ | Q₁₆ | Q₁ |
| Lₐ₁₄₉ | O | Q₁ | Q₁ | Q₁ | Q₁ | O | Q₁ | Q₁ | Q₁₇ | Q₁ |
| Lₐ₁₅₀ | O | Q₁ | Q₁ | Q₁ | Q₁ | O | Q₁ | Q₁ | Q₁₈ | Q₁ |
| Lₐ₁₅₁ | O | Q₁ | Q₁ | Q₁ | Q₁ | O | Q₁ | Q₁ | Q₁₉ | Q₁ |
| Lₐ₁₅₂ | O | Q₁ | Q₁ | Q₁ | Q₁ | O | Q₁ | Q₁ | Q₂₀ | Q₁ |
| Lₐ₁₅₃ | O | Q₁ | Q₁ | Q₁ | Q₁ | O | Q₁ | Q₁ | Q₂₁ | Q₁ |
| Lₐ₁₅₄ | O | Q₁ | Q₁ | Q₁ | Q₁ | O | Q₁ | Q₁ | Q₂₂ | Q₁ |
| Lₐ₁₅₅ | O | Q₁ | Q₁ | Q₁ | Q₁ | O | Q₁ | Q₁ | Q₂₃ | Q₁ |
| Lₐ₁₅₆ | O | Q₁ | Q₁ | Q₁ | Q₁ | O | Q₁ | Q₁ | Q₁ | Q₂ |
| Lₐ₁₅₇ | O | Q₁ | Q₁ | Q₁ | Q₁ | O | Q₁ | Q₁ | Q₁ | Q₃ |
| Lₐ₁₅₈ | O | Q₁ | Q₁ | Q₁ | Q₁ | O | Q₁ | Q₁ | Q₁ | Q₄ |
| Lₐ₁₅₉ | O | Q₁ | Q₁ | Q₁ | Q₁ | O | Q₁ | Q₁ | Q₁ | Q₅ |
| Lₐ₁₆₀ | O | Q₁ | Q₁ | Q₁ | Q₁ | O | Q₁ | Q₁ | Q₁ | Q₆ |
| Lₐ₁₆₁ | O | Q₁ | Q₁ | Q₁ | Q₁ | O | Q₁ | Q₁ | Q₁ | Q₇ |
| Lₐ₁₆₂ | O | Q₁ | Q₁ | Q₁ | Q₁ | O | Q₁ | Q₁ | Q₁ | Q₈ |
| Lₐ₁₆₃ | O | Q₁ | Q₁ | Q₁ | Q₁ | O | Q₁ | Q₁ | Q₁ | Q₉ |
| Lₐ₁₆₄ | O | Q₁ | Q₁ | Q₁ | Q₁ | O | Q₁ | Q₁ | Q₁ | Q₁₀ |
| Lₐ₁₆₅ | O | Q₁ | Q₁ | Q₁ | Q₁ | O | Q₁ | Q₁ | Q₁ | Q₁₁ |
| Lₐ₁₆₆ | O | Q₁ | Q₁ | Q₁ | Q₁ | O | Q₁ | Q₁ | Q₁ | Q₁₂ |
| Lₐ₁₆₇ | O | Q₁ | Q₁ | Q₁ | Q₁ | O | Q₁ | Q₁ | Q₁ | Q₁₃ |
| Lₐ₁₆₈ | O | Q₁ | Q₁ | Q₁ | Q₁ | O | Q₁ | Q₁ | Q₁ | Q₁₄ |
| Lₐ₁₆₉ | O | Q₁ | Q₁ | Q₁ | Q₁ | O | Q₁ | Q₁ | Q₁ | Q₁₅ |
| Lₐ₁₇₀ | O | Q₁ | Q₁ | Q₁ | Q₁ | O | Q₁ | Q₁ | Q₁ | Q₁₆ |
| Lₐ₁₇₁ | O | Q₁ | Q₁ | Q₁ | Q₁ | O | Q₁ | Q₁ | Q₁ | Q₁₇ |
| Lₐ₁₇₂ | O | Q₁ | Q₁ | Q₁ | Q₁ | O | Q₁ | Q₁ | Q₁ | Q₁₈ |
| Lₐ₁₇₃ | O | Q₁ | Q₁ | Q₁ | Q₁ | O | Q₁ | Q₁ | Q₁ | Q₁₉ |
| Lₐ₁₇₄ | O | Q₁ | Q₁ | Q₁ | Q₁ | O | Q₁ | Q₁ | Q₁ | Q₂₀ |
| Lₐ₁₇₅ | O | Q₁ | Q₁ | Q₁ | Q₁ | O | Q₁ | Q₁ | Q₁ | Q₂₁ |
| Lₐ₁₇₆ | O | Q₁ | Q₁ | Q₁ | Q₁ | O | Q₁ | Q₁ | Q₁ | Q₂₂ |
| Lₐ₁₇₇ | O | Q₁ | Q₁ | Q₁ | Q₁ | O | Q₁ | Q₁ | Q₁ | Q₂₃ |
| Lₐ₁₇₈ | O | Q₁ | Q₂ | Q₁ | Q₁ | O | Q₄ | Q₁ | Q₁ | Q₁ |
| Lₐ₁₇₉ | O | Q₁ | Q₃ | Q₁ | Q₁ | O | Q₄ | Q₁ | Q₁ | Q₁ |
| Lₐ₁₈₀ | O | Q₁ | Q₄ | Q₁ | Q₁ | O | Q₄ | Q₁ | Q₁ | Q₁ |
| Lₐ₁₈₁ | O | Q₁ | Q₅ | Q₁ | Q₁ | O | Q₄ | Q₁ | Q₁ | Q₁ |
| Lₐ₁₈₂ | O | Q₁ | Q₆ | Q₁ | Q₁ | O | Q₄ | Q₁ | Q₁ | Q₁ |
| Lₐ₁₈₃ | O | Q₁ | Q₇ | Q₁ | Q₁ | O | Q₄ | Q₁ | Q₁ | Q₁ |
| Lₐ₁₈₄ | O | Q₁ | Q₈ | Q₁ | Q₁ | O | Q₄ | Q₁ | Q₁ | Q₁ |
| Lₐ₁₈₅ | O | Q₁ | Q₉ | Q₁ | Q₁ | O | Q₄ | Q₁ | Q₁ | Q₁ |
| Lₐ₁₈₆ | O | Q₁ | Q₁₀ | Q₁ | Q₁ | O | Q₄ | Q₁ | Q₁ | Q₁ |
| Lₐ₁₈₇ | O | Q₁ | Q₁₁ | Q₁ | Q₁ | O | Q₄ | Q₁ | Q₁ | Q₁ |
| Lₐ₁₈₈ | O | Q₁ | Q₁₂ | Q₁ | Q₁ | O | Q₄ | Q₁ | Q₁ | Q₁ |
| Lₐ₁₈₉ | O | Q₁ | Q₁₃ | Q₁ | Q₁ | O | Q₄ | Q₁ | Q₁ | Q₁ |
| Lₐ₁₉₀ | O | Q₁ | Q₁₄ | Q₁ | Q₁ | O | Q₄ | Q₁ | Q₁ | Q₁ |
| Lₐ₁₉₁ | O | Q₁ | Q₁₅ | Q₁ | Q₁ | O | Q₄ | Q₁ | Q₁ | Q₁ |
| Lₐ₁₉₂ | O | Q₁ | Q₁₆ | Q₁ | Q₁ | O | Q₄ | Q₁ | Q₁ | Q₁ |
| Lₐ₁₉₃ | O | Q₁ | Q₁₇ | Q₁ | Q₁ | O | Q₄ | Q₁ | Q₁ | Q₁ |
| Lₐ₁₉₄ | O | Q₁ | Q₁₈ | Q₁ | Q₁ | O | Q₄ | Q₁ | Q₁ | Q₁ |
| Lₐ₁₉₅ | O | Q₁ | Q₁₉ | Q₁ | Q₁ | O | Q₄ | Q₁ | Q₁ | Q₁ |
| Lₐ₁₉₆ | O | Q₁ | Q₂₀ | Q₁ | Q₁ | O | Q₄ | Q₁ | Q₁ | Q₁ |
| Lₐ₁₉₇ | O | Q₁ | Q₂₁ | Q₁ | Q₁ | O | Q₄ | Q₁ | Q₁ | Q₁ |
| Lₐ₁₉₈ | O | Q₁ | Q₂₂ | Q₁ | Q₁ | O | Q₄ | Q₁ | Q₁ | Q₁ |
| Lₐ₁₉₉ | O | Q₁ | Q₂₃ | Q₁ | Q₁ | O | Q₄ | Q₁ | Q₁ | Q₁ |
| Lₐ₂₀₀ | O | Q₁ | Q₁ | Q₂ | Q₁ | O | Q₄ | Q₁ | Q₁ | Q₁ |
| Lₐ₂₀₁ | O | Q₁ | Q₁ | Q₃ | Q₁ | O | Q₄ | Q₁ | Q₁ | Q₁ |
| Lₐ₂₀₂ | O | Q₁ | Q₁ | Q₄ | Q₁ | O | Q₄ | Q₁ | Q₁ | Q₁ |
| Lₐ₂₀₃ | O | Q₁ | Q₁ | Q₅ | Q₁ | O | Q₄ | Q₁ | Q₁ | Q₁ |
| Lₐ₂₀₄ | O | Q₁ | Q₁ | Q₆ | Q₁ | O | Q₄ | Q₁ | Q₁ | Q₁ |
| Lₐ₂₀₅ | O | Q₁ | Q₁ | Q₇ | Q₁ | O | Q₄ | Q₁ | Q₁ | Q₁ |
| Lₐ₂₀₆ | O | Q₁ | Q₁ | Q₈ | Q₁ | O | Q₄ | Q₁ | Q₁ | Q₁ |
| Lₐ₂₀₇ | O | Q₁ | Q₁ | Q₉ | Q₁ | O | Q₄ | Q₁ | Q₁ | Q₁ |
| Lₐ₂₀₈ | O | Q₁ | Q₁ | Q₁₀ | Q₁ | O | Q₄ | Q₁ | Q₁ | Q₁ |
| Lₐ₂₀₉ | O | Q₁ | Q₁ | Q₁₁ | Q₁ | O | Q₄ | Q₁ | Q₁ | Q₁ |
| Lₐ₂₁₀ | O | Q₁ | Q₁ | Q₁₂ | Q₁ | O | Q₄ | Q₁ | Q₁ | Q₁ |
| Lₐ₂₁₁ | O | Q₁ | Q₁ | Q₁₃ | Q₁ | O | Q₄ | Q₁ | Q₁ | Q₁ |
| Lₐ₂₁₂ | O | Q₁ | Q₁ | Q₁₄ | Q₁ | O | Q₄ | Q₁ | Q₁ | Q₁ |
| Lₐ₂₁₃ | O | Q₁ | Q₁ | Q₁₅ | Q₁ | O | Q₄ | Q₁ | Q₁ | Q₁ |
| Lₐ₂₁₄ | O | Q₁ | Q₁ | Q₁₆ | Q₁ | O | Q₄ | Q₁ | Q₁ | Q₁ |
| Lₐ₂₁₅ | O | Q₁ | Q₁ | Q₁₇ | Q₁ | O | Q₄ | Q₁ | Q₁ | Q₁ |
| Lₐ₂₁₆ | O | Q₁ | Q₁ | Q₁₈ | Q₁ | O | Q₄ | Q₁ | Q₁ | Q₁ |
| Lₐ₂₁₇ | O | Q₁ | Q₁ | Q₁₉ | Q₁ | O | Q₄ | Q₁ | Q₁ | Q₁ |
| Lₐ₂₁₈ | O | Q₁ | Q₁ | Q₂₀ | Q₁ | O | Q₄ | Q₁ | Q₁ | Q₁ |
| Lₐ₂₁₉ | O | Q₁ | Q₁ | Q₂₁ | Q₁ | O | Q₄ | Q₁ | Q₁ | Q₁ |
| Lₐ₂₂₀ | O | Q₁ | Q₁ | Q₂₂ | Q₁ | O | Q₄ | Q₁ | Q₁ | Q₁ |
| Lₐ₂₂₁ | O | Q₁ | Q₁ | Q₂₃ | Q₁ | O | Q₄ | Q₁ | Q₁ | Q₁ |
| Lₐ₂₂₂ | O | Q₁ | Q₂ | Q₁ | Q₁ | O | Q₆ | Q₁ | Q₁ | Q₁ |
| Lₐ₂₂₃ | O | Q₁ | Q₃ | Q₁ | Q₁ | O | Q₆ | Q₁ | Q₁ | Q₁ |
| Lₐ₂₂₄ | O | Q₁ | Q₄ | Q₁ | Q₁ | O | Q₆ | Q₁ | Q₁ | Q₁ |
| Lₐ₂₂₅ | O | Q₁ | Q₅ | Q₁ | Q₁ | O | Q₆ | Q₁ | Q₁ | Q₁ |
| Lₐ₂₂₆ | O | Q₁ | Q₆ | Q₁ | Q₁ | O | Q₆ | Q₁ | Q₁ | Q₁ |
| Lₐ₂₂₇ | O | Q₁ | Q₇ | Q₁ | Q₁ | O | Q₆ | Q₁ | Q₁ | Q₁ |
| Lₐ₂₂₈ | O | Q₁ | Q₈ | Q₁ | Q₁ | O | Q₆ | Q₁ | Q₁ | Q₁ |
| Lₐ₂₂₉ | O | Q₁ | Q₉ | Q₁ | Q₁ | O | Q₆ | Q₁ | Q₁ | Q₁ |
| Lₐ₂₃₀ | O | Q₁ | Q₁₀ | Q₁ | Q₁ | O | Q₆ | Q₁ | Q₁ | Q₁ |
| Lₐ₂₃₁ | O | Q₁ | Q₁₁ | Q₁ | Q₁ | O | Q₆ | Q₁ | Q₁ | Q₁ |
| Lₐ₂₃₂ | O | Q₁ | Q₁₂ | Q₁ | Q₁ | O | Q₆ | Q₁ | Q₁ | Q₁ |
| Lₐ₂₃₃ | O | Q₁ | Q₁₃ | Q₁ | Q₁ | O | Q₆ | Q₁ | Q₁ | Q₁ |
| Lₐ₂₃₄ | O | Q₁ | Q₁₄ | Q₁ | Q₁ | O | Q₆ | Q₁ | Q₁ | Q₁ |
| Lₐ₂₃₅ | O | Q₁ | Q₁₅ | Q₁ | Q₁ | O | Q₆ | Q₁ | Q₁ | Q₁ |
| Lₐ₂₃₆ | O | Q₁ | Q₁₆ | Q₁ | Q₁ | O | Q₆ | Q₁ | Q₁ | Q₁ |
| Lₐ₂₃₇ | O | Q₁ | Q₁₇ | Q₁ | Q₁ | O | Q₆ | Q₁ | Q₁ | Q₁ |
| Lₐ₂₃₈ | O | Q₁ | Q₁₈ | Q₁ | Q₁ | O | Q₆ | Q₁ | Q₁ | Q₁ |
| Lₐ₂₃₉ | O | Q₁ | Q₁₉ | Q₁ | Q₁ | O | Q₆ | Q₁ | Q₁ | Q₁ |
| Lₐ₂₄₀ | O | Q₁ | Q₂₀ | Q₁ | Q₁ | O | Q₆ | Q₁ | Q₁ | Q₁ |
| Lₐ₂₄₁ | O | Q₁ | Q₂₁ | Q₁ | Q₁ | O | Q₆ | Q₁ | Q₁ | Q₁ |
| Lₐ₂₄₂ | O | Q₁ | Q₂₂ | Q₁ | Q₁ | O | Q₆ | Q₁ | Q₁ | Q₁ |
| Lₐ₂₄₃ | O | Q₁ | Q₂₃ | Q₁ | Q₁ | O | Q₆ | Q₁ | Q₁ | Q₁ |
| Lₐ₂₄₄ | O | Q₁ | Q₁ | Q₁ | Q₁ | O | Q₆ | Q₁ | Q₁ | Q₁ |
| Lₐ₂₄₅ | O | Q₁ | Q₁ | Q₃ | Q₁ | O | Q₆ | Q₁ | Q₁ | Q₁ |
| Lₐ₂₄₆ | O | Q₁ | Q₁ | Q₄ | Q₁ | O | Q₆ | Q₁ | Q₁ | Q₁ |
| Lₐ₂₄₇ | O | Q₁ | Q₁ | Q₅ | Q₁ | O | Q₆ | Q₁ | Q₁ | Q₁ |
| Lₐ₂₄₈ | O | Q₁ | Q₁ | Q₆ | Q₁ | O | Q₆ | Q₁ | Q₁ | Q₁ |
| Lₐ₂₄₉ | O | Q₁ | Q₁ | Q₇ | Q₁ | O | Q₆ | Q₁ | Q₁ | Q₁ |
| Lₐ₂₅₀ | O | Q₁ | Q₁ | Q₈ | Q₁ | O | Q₆ | Q₁ | Q₁ | Q₁ |
| Lₐ₂₅₁ | O | Q₁ | Q₁ | Q₉ | Q₁ | O | Q₆ | Q₁ | Q₁ | Q₁ |
| Lₐ₂₅₂ | O | Q₁ | Q₁ | Q₁₀ | Q₁ | O | Q₆ | Q₁ | Q₁ | Q₁ |
| Lₐ₂₅₃ | O | Q₁ | Q₁ | Q₁₁ | Q₁ | O | Q₆ | Q₁ | Q₁ | Q₁ |
| Lₐ₂₅₄ | O | Q₁ | Q₁ | Q₁₂ | Q₁ | O | Q₆ | Q₁ | Q₁ | Q₁ |
| Lₐ₂₅₅ | O | Q₁ | Q₁ | Q₁₃ | Q₁ | O | Q₆ | Q₁ | Q₁ | Q₁ |
| Lₐ₂₅₆ | O | Q₁ | Q₁ | Q₁₄ | Q₁ | O | Q₆ | Q₁ | Q₁ | Q₁ |
| Lₐ₂₅₇ | O | Q₁ | Q₁ | Q₁₅ | Q₁ | O | Q₆ | Q₁ | Q₁ | Q₁ |
| Lₐ₂₅₈ | O | Q₁ | Q₁ | Q₁₆ | Q₁ | O | Q₆ | Q₁ | Q₁ | Q₁ |
| Lₐ₂₅₉ | O | Q₁ | Q₁ | Q₁₇ | Q₁ | O | Q₆ | Q₁ | Q₁ | Q₁ |
| Lₐ₂₆₀ | O | Q₁ | Q₁ | Q₁₈ | Q₁ | O | Q₆ | Q₁ | Q₁ | Q₁ |
| Lₐ₂₆₁ | O | Q₁ | Q₁ | Q₁₉ | Q₁ | O | Q₆ | Q₁ | Q₁ | Q₁ |
| Lₐ₂₆₂ | O | Q₁ | Q₁ | Q₂₀ | Q₁ | O | Q₆ | Q₁ | Q₁ | Q₁ |
| Lₐ₂₆₃ | O | Q₁ | Q₁ | Q₂₁ | Q₁ | O | Q₆ | Q₁ | Q₁ | Q₁ |
| Lₐ₂₆₄ | O | Q₁ | Q₁ | Q₂₂ | Q₁ | O | Q₆ | Q₁ | Q₁ | Q₁ |
| Lₐ₂₆₅ | O | Q₁ | Q₁ | Q₂₃ | Q₁ | O | Q₆ | Q₁ | Q₁ | Q₁ |
| Lₐ₂₆₆ | O | Q₁ | Q₂ | Q₁ | Q₁ | O | Q₇ | Q₁ | Q₁ | Q₁ |
| Lₐ₂₆₇ | O | Q₁ | Q₃ | Q₁ | Q₁ | O | Q₇ | Q₁ | Q₁ | Q₁ |
| Lₐ₂₆₈ | O | Q₁ | Q₄ | Q₁ | Q₁ | O | Q₇ | Q₁ | Q₁ | Q₁ |
| Lₐ₂₆₉ | O | Q₁ | Q₅ | Q₁ | Q₁ | O | Q₇ | Q₁ | Q₁ | Q₁ |
| Lₐ₂₇₀ | O | Q₁ | Q₆ | Q₁ | Q₁ | O | Q₇ | Q₁ | Q₁ | Q₁ |
| Lₐ₂₇₁ | O | Q₁ | Q₇ | Q₁ | Q₁ | O | Q₇ | Q₁ | Q₁ | Q₁ |
| Lₐ₂₇₂ | O | Q₁ | Q₈ | Q₁ | Q₁ | O | Q₇ | Q₁ | Q₁ | Q₁ |
| Lₐ₂₇₃ | O | Q₁ | Q₉ | Q₁ | Q₁ | O | Q₇ | Q₁ | Q₁ | Q₁ |
| Lₐ₂₇₄ | O | Q₁ | Q₁₀ | Q₁ | Q₁ | O | Q₇ | Q₁ | Q₁ | Q₁ |
| Lₐ₂₇₅ | O | Q₁ | Q₁₁ | Q₁ | Q₁ | O | Q₇ | Q₁ | Q₁ | Q₁ |
| Lₐ₂₇₆ | O | Q₁ | Q₁₂ | Q₁ | Q₁ | O | Q₇ | Q₁ | Q₁ | Q₁ |
| Lₐ₂₇₇ | O | Q₁ | Q₁₃ | Q₁ | Q₁ | O | Q₇ | Q₁ | Q₁ | Q₁ |
| Lₐ₂₇₈ | O | Q₁ | Q₁₄ | Q₁ | Q₁ | O | Q₇ | Q₁ | Q₁ | Q₁ |
| Lₐ₂₇₉ | O | Q₁ | Q₁₅ | Q₁ | Q₁ | O | Q₇ | Q₁ | Q₁ | Q₁ |
| Lₐ₂₈₀ | O | Q₁ | Q₁₆ | Q₁ | Q₁ | O | Q₇ | Q₁ | Q₁ | Q₁ |
| Lₐ₂₈₁ | O | Q₁ | Q₁₇ | Q₁ | Q₁ | O | Q₇ | Q₁ | Q₁ | Q₁ |
| Lₐ₂₈₂ | O | Q₁ | Q₁₈ | Q₁ | Q₁ | O | Q₇ | Q₁ | Q₁ | Q₁ |
| Lₐ₂₈₃ | O | Q₁ | Q₁₉ | Q₁ | Q₁ | O | Q₇ | Q₁ | Q₁ | Q₁ |
| Lₐ₂₈₄ | O | Q₁ | Q₂₀ | Q₁ | Q₁ | O | Q₇ | Q₁ | Q₁ | Q₁ |
| Lₐ₂₈₅ | O | Q₁ | Q₂₁ | Q₁ | Q₁ | O | Q₇ | Q₁ | Q₁ | Q₁ |
| Lₐ₂₈₆ | O | Q₁ | Q₂₂ | Q₁ | Q₁ | O | Q₇ | Q₁ | Q₁ | Q₁ |
| Lₐ₂₈₇ | O | Q₁ | Q₂₃ | Q₁ | Q₁ | O | Q₇ | Q₁ | Q₁ | Q₁ |
| Lₐ₂₈₈ | O | Q₁ | Q₁ | Q₂ | Q₁ | O | Q₇ | Q₁ | Q₁ | Q₁ |
| Lₐ₂₈₉ | O | Q₁ | Q₁ | Q₃ | Q₁ | O | Q₇ | Q₁ | Q₁ | Q₁ |
| Lₐ₂₉₀ | O | Q₁ | Q₁ | Q₄ | Q₁ | O | Q₇ | Q₁ | Q₁ | Q₁ |
| Lₐ₂₉₁ | O | Q₁ | Q₁ | Q₅ | Q₁ | O | Q₇ | Q₁ | Q₁ | Q₁ |
| Lₐ₂₉₂ | O | Q₁ | Q₁ | Q₆ | Q₁ | O | Q₇ | Q₁ | Q₁ | Q₁ |
| Lₐ₂₉₃ | O | Q₁ | Q₁ | Q₇ | Q₁ | O | Q₇ | Q₁ | Q₁ | Q₁ |
| Lₐ₂₉₄ | O | Q₁ | Q₁ | Q₈ | Q₁ | O | Q₇ | Q₁ | Q₁ | Q₁ |
| Lₐ₂₉₅ | O | Q₁ | Q₁ | Q₉ | Q₁ | O | Q₇ | Q₁ | Q₁ | Q₁ |
| Lₐ₂₉₆ | O | Q₁ | Q₁ | Q₁₀ | Q₁ | O | Q₇ | Q₁ | Q₁ | Q₁ |
| Lₐ₂₉₇ | O | Q₁ | Q₁ | Q₁₁ | Q₁ | O | Q₇ | Q₁ | Q₁ | Q₁ |
| Lₐ₂₉₈ | O | Q₁ | Q₁ | Q₁₂ | Q₁ | O | Q₇ | Q₁ | Q₁ | Q₁ |
| Lₐ₂₉₉ | O | Q₁ | Q₁ | Q₁₃ | Q₁ | O | Q₇ | Q₁ | Q₁ | Q₁ |
| Lₐ₃₀₀ | O | Q₁ | Q₁ | Q₁₄ | Q₁ | O | Q₇ | Q₁ | Q₁ | Q₁ |
| Lₐ₃₀₁ | O | Q₁ | Q₁ | Q₁₅ | Q₁ | O | Q₇ | Q₁ | Q₁ | Q₁ |
| Lₐ₃₀₂ | O | Q₁ | Q₁ | Q₁₆ | Q₁ | O | Q₇ | Q₁ | Q₁ | Q₁ |
| Lₐ₃₀₃ | O | Q₁ | Q₁ | Q₁₇ | Q₁ | O | Q₇ | Q₁ | Q₁ | Q₁ |
| Lₐ₃₀₄ | O | Q₁ | Q₁ | Q₁₈ | Q₁ | O | Q₇ | Q₁ | Q₁ | Q₁ |
| Lₐ₃₀₅ | O | Q₁ | Q₁ | Q₁₉ | Q₁ | O | Q₇ | Q₁ | Q₁ | Q₁ |
| Lₐ₃₀₆ | O | Q₁ | Q₁ | Q₂₀ | Q₁ | O | Q₇ | Q₁ | Q₁ | Q₁ |
| Lₐ₃₀₇ | O | Q₁ | Q₁ | Q₂₁ | Q₁ | O | Q₇ | Q₁ | Q₁ | Q₁ |
| Lₐ₃₀₈ | O | Q₁ | Q₁ | Q₂₂ | Q₁ | O | Q₇ | Q₁ | Q₁ | Q₁ |
| Lₐ₃₀₉ | O | Q₁ | Q₁ | Q₂₃ | Q₁ | O | Q₇ | Q₁ | Q₁ | Q₁ |
| Lₐ₃₁₀ | O | Q₁ | Q₂ | Q₁ | Q₁ | O | Q₈ | Q₁ | Q₁ | Q₁ |
| Lₐ₃₁₁ | O | Q₁ | Q₃ | Q₁ | Q₁ | O | Q₈ | Q₁ | Q₁ | Q₁ |
| Lₐ₃₁₂ | O | Q₁ | Q₄ | Q₁ | Q₁ | O | Q₈ | Q₁ | Q₁ | Q₁ |
| Lₐ₃₁₃ | O | Q₁ | Q₅ | Q₁ | Q₁ | O | Q₈ | Q₁ | Q₁ | Q₁ |
| Lₐ₃₁₄ | O | Q₁ | Q₆ | Q₁ | Q₁ | O | Q₈ | Q₁ | Q₁ | Q₁ |
| Lₐ₃₁₅ | O | Q₁ | Q₇ | Q₁ | Q₁ | O | Q₈ | Q₁ | Q₁ | Q₁ |
| Lₐ₃₁₆ | O | Q₁ | Q₈ | Q₁ | Q₁ | O | Q₈ | Q₁ | Q₁ | Q₁ |
| Lₐ₃₁₇ | O | Q₁ | Q₉ | Q₁ | Q₁ | O | Q₈ | Q₁ | Q₁ | Q₁ |
| Lₐ₃₁₈ | O | Q₁ | Q₁₀ | Q₁ | Q₁ | O | Q₈ | Q₁ | Q₁ | Q₁ |
| Lₐ₃₁₉ | O | Q₁ | Q₁₁ | Q₁ | Q₁ | O | Q₈ | Q₁ | Q₁ | Q₁ |
| Lₐ₃₂₀ | O | Q₁ | Q₁₂ | Q₁ | Q₁ | O | Q₈ | Q₁ | Q₁ | Q₁ |
| Lₐ₃₂₁ | O | Q₁ | Q₁₃ | Q₁ | Q₁ | O | Q₈ | Q₁ | Q₁ | Q₁ |
| Lₐ₃₂₂ | O | Q₁ | Q₁₄ | Q₁ | Q₁ | O | Q₈ | Q₁ | Q₁ | Q₁ |
| Lₐ₃₂₃ | O | Q₁ | Q₁₅ | Q₁ | Q₁ | O | Q₈ | Q₁ | Q₁ | Q₁ |
| Lₐ₃₂₄ | O | Q₁ | Q₁₆ | Q₁ | Q₁ | O | Q₈ | Q₁ | Q₁ | Q₁ |
| Lₐ₃₂₅ | O | Q₁ | Q₁₇ | Q₁ | Q₁ | O | Q₈ | Q₁ | Q₁ | Q₁ |
| Lₐ₃₂₆ | O | Q₁ | Q₁₈ | Q₁ | Q₁ | O | Q₈ | Q₁ | Q₁ | Q₁ |
| Lₐ₃₂₇ | O | Q₁ | Q₁₉ | Q₁ | Q₁ | O | Q₈ | Q₁ | Q₁ | Q₁ |
| Lₐ₃₂₈ | O | Q₁ | Q₂₀ | Q₁ | Q₁ | O | Q₈ | Q₁ | Q₁ | Q₁ |
| Lₐ₃₂₉ | O | Q₁ | Q₂₁ | Q₁ | Q₁ | O | Q₈ | Q₁ | Q₁ | Q₁ |
| Lₐ₃₃₀ | O | Q₁ | Q₂₂ | Q₁ | Q₁ | O | Q₈ | Q₁ | Q₁ | Q₁ |
| Lₐ₃₃₁ | O | Q₁ | Q₂₃ | Q₁ | Q₁ | O | Q₈ | Q₁ | Q₁ | Q₁ |
| Lₐ₃₃₂ | O | Q₁ | Q₁ | Q₂ | Q₁ | O | Q₈ | Q₁ | Q₁ | Q₁ |
| Lₐ₃₃₃ | O | Q₁ | Q₁ | Q₃ | Q₁ | O | Q₈ | Q₁ | Q₁ | Q₁ |
| Lₐ₃₃₄ | O | Q₁ | Q₁ | Q₄ | Q₁ | O | Q₈ | Q₁ | Q₁ | Q₁ |
| Lₐ₃₃₅ | O | Q₁ | Q₁ | Q₅ | Q₁ | O | Q₈ | Q₁ | Q₁ | Q₁ |
| Lₐ₃₃₆ | O | Q₁ | Q₁ | Q₆ | Q₁ | O | Q₈ | Q₁ | Q₁ | Q₁ |
| Lₐ₃₃₇ | O | Q₁ | Q₁ | Q₇ | Q₁ | O | Q₈ | Q₁ | Q₁ | Q₁ |
| Lₐ₃₃₈ | O | Q₁ | Q₁ | Q₈ | Q₁ | O | Q₈ | Q₁ | Q₁ | Q₁ |
| Lₐ₃₃₉ | O | Q₁ | Q₁ | Q₉ | Q₁ | O | Q₈ | Q₁ | Q₁ | Q₁ |
| Lₐ₃₄₀ | O | Q₁ | Q₁ | Q₁₀ | Q₁ | O | Q₈ | Q₁ | Q₁ | Q₁ |
| Lₐ₃₄₁ | O | Q₁ | Q₁ | Q₁₁ | Q₁ | O | Q₈ | Q₁ | Q₁ | Q₁ |
| Lₐ₃₄₂ | O | Q₁ | Q₁ | Q₁₂ | Q₁ | O | Q₈ | Q₁ | Q₁ | Q₁ |
| Lₐ₃₄₃ | O | Q₁ | Q₁ | Q₁₃ | Q₁ | O | Q₈ | Q₁ | Q₁ | Q₁ |
| Lₐ₃₄₄ | O | Q₁ | Q₁ | Q₁₄ | Q₁ | O | Q₈ | Q₁ | Q₁ | Q₁ |
| Lₐ₃₄₅ | O | Q₁ | Q₁ | Q₁₅ | Q₁ | O | Q₈ | Q₁ | Q₁ | Q₁ |
| Lₐ₃₄₆ | O | Q₁ | Q₁ | Q₁₆ | Q₁ | O | Q₈ | Q₁ | Q₁ | Q₁ |
| Lₐ₃₄₇ | O | Q₁ | Q₁ | Q₁₇ | Q₁ | O | Q₈ | Q₁ | Q₁ | Q₁ |
| Lₐ₃₄₈ | O | Q₁ | Q₁ | Q₁₈ | Q₁ | O | Q₈ | Q₁ | Q₁ | Q₁ |
| Lₐ₃₄₉ | O | Q₁ | Q₁ | Q₁₉ | Q₁ | O | Q₈ | Q₁ | Q₁ | Q₁ |
| Lₐ₃₅₀ | O | Q₁ | Q₁ | Q₂₀ | Q₁ | O | Q₈ | Q₁ | Q₁ | Q₁ |
| Lₐ₃₅₁ | O | Q₁ | Q₁ | Q₂₁ | Q₁ | O | Q₈ | Q₁ | Q₁ | Q₁ |
| Lₐ₃₅₂ | O | Q₁ | Q₁ | Q₂₂ | Q₁ | O | Q₈ | Q₁ | Q₁ | Q₁ |
| Lₐ₃₅₃ | O | Q₁ | Q₁ | Q₂₃ | Q₁ | O | Q₈ | Q₁ | Q₁ | Q₁ |
| Lₐ₃₅₄ | O | Q₁ | Q₂ | Q₁ | Q₁ | O | Q₈ | Q₄ | Q₁ | Q₁ |
| Lₐ₃₅₅ | O | Q₁ | Q₃ | Q₁ | Q₁ | O | Q₈ | Q₄ | Q₁ | Q₁ |
| Lₐ₃₅₆ | O | Q₁ | Q₄ | Q₁ | Q₁ | O | Q₈ | Q₄ | Q₁ | Q₁ |
| Lₐ₃₅₇ | O | Q₁ | Q₅ | Q₁ | Q₁ | O | Q₈ | Q₄ | Q₁ | Q₁ |
| Lₐ₃₅₈ | O | Q₁ | Q₆ | Q₁ | Q₁ | O | Q₈ | Q₄ | Q₁ | Q₁ |
| Lₐ₃₅₉ | O | Q₁ | Q₇ | Q₁ | Q₁ | O | Q₈ | Q₄ | Q₁ | Q₁ |
| Lₐ₃₆₀ | O | Q₁ | Q₈ | Q₁ | Q₁ | O | Q₈ | Q₄ | Q₁ | Q₁ |
| Lₐ₃₆₁ | O | Q₁ | Q₉ | Q₁ | Q₁ | O | Q₈ | Q₄ | Q₁ | Q₁ |
| Lₐ₃₆₂ | O | Q₁ | Q₁₀ | Q₁ | Q₁ | O | Q₈ | Q₄ | Q₁ | Q₁ |
| Lₐ₃₆₃ | O | Q₁ | Q₁₁ | Q₁ | Q₁ | O | Q₈ | Q₄ | Q₁ | Q₁ |
| Lₐ₃₆₄ | O | Q₁ | Q₁₂ | Q₁ | Q₁ | O | Q₈ | Q₄ | Q₁ | Q₁ |
| Lₐ₃₆₅ | O | Q₁ | Q₁₃ | Q₁ | Q₁ | O | Q₈ | Q₄ | Q₁ | Q₁ |
| Lₐ₃₆₆ | O | Q₁ | Q₁₄ | Q₁ | Q₁ | O | Q₈ | Q₄ | Q₁ | Q₁ |
| Lₐ₃₆₇ | O | Q₁ | Q₁₅ | Q₁ | Q₁ | O | Q₈ | Q₄ | Q₁ | Q₁ |
| Lₐ₃₆₈ | O | Q₁ | Q₁₆ | Q₁ | Q₁ | O | Q₈ | Q₄ | Q₁ | Q₁ |
| Lₐ₃₆₉ | O | Q₁ | Q₁₇ | Q₁ | Q₁ | O | Q₈ | Q₄ | Q₁ | Q₁ |
| Lₐ₃₇₀ | O | Q₁ | Q₁₈ | Q₁ | Q₁ | O | Q₈ | Q₄ | Q₁ | Q₁ |
| Lₐ₃₇₁ | O | Q₁ | Q₁₉ | Q₁ | Q₁ | O | Q₈ | Q₄ | Q₁ | Q₁ |
| Lₐ₃₇₂ | O | Q₁ | Q₂₀ | Q₁ | Q₁ | O | Q₈ | Q₄ | Q₁ | Q₁ |
| Lₐ₃₇₃ | O | Q₁ | Q₂₁ | Q₁ | Q₁ | O | Q₈ | Q₄ | Q₁ | Q₁ |
| Lₐ₃₇₄ | O | Q₁ | Q₂₂ | Q₁ | Q₁ | O | Q₈ | Q₄ | Q₁ | Q₁ |
| Lₐ₃₇₅ | O | Q₁ | Q₂₃ | Q₁ | Q₁ | O | Q₈ | Q₄ | Q₁ | Q₁ |
| Lₐ₃₇₆ | O | Q₁ | Q₁ | Q₂ | Q₁ | O | Q₈ | Q₄ | Q₁ | Q₁ |
| Lₐ₃₇₇ | O | Q₁ | Q₁ | Q₃ | Q₁ | O | Q₈ | Q₄ | Q₁ | Q₁ |
| Lₐ₃₇₈ | O | Q₁ | Q₁ | Q₄ | Q₁ | O | Q₈ | Q₄ | Q₁ | Q₁ |
| Lₐ₃₇₉ | O | Q₁ | Q₁ | Q₅ | Q₁ | O | Q₈ | Q₄ | Q₁ | Q₁ |
| Lₐ₃₈₀ | O | Q₁ | Q₁ | Q₆ | Q₁ | O | Q₈ | Q₄ | Q₁ | Q₁ |
| Lₐ₃₈₁ | O | Q₁ | Q₁ | Q₇ | Q₁ | O | Q₈ | Q₄ | Q₁ | Q₁ |
| Lₐ₃₈₂ | O | Q₁ | Q₁ | Q₈ | Q₁ | O | Q₈ | Q₄ | Q₁ | Q₁ |
| Lₐ₃₈₃ | O | Q₁ | Q₁ | Q₉ | Q₁ | O | Q₈ | Q₄ | Q₁ | Q₁ |
| Lₐ₃₈₄ | O | Q₁ | Q₁ | Q₁₀ | Q₁ | O | Q₈ | Q₄ | Q₁ | Q₁ |
| Lₐ₃₈₅ | O | Q₁ | Q₁ | Q₁₁ | Q₁ | O | Q₈ | Q₄ | Q₁ | Q₁ |
| Lₐ₃₈₆ | O | Q₁ | Q₁ | Q₁₂ | Q₁ | O | Q₈ | Q₄ | Q₁ | Q₁ |
| Lₐ₃₈₇ | O | Q₁ | Q₁ | Q₁₃ | Q₁ | O | Q₈ | Q₄ | Q₁ | Q₁ |
| Lₐ₃₈₈ | O | Q₁ | Q₁ | Q₁₄ | Q₁ | O | Q₈ | Q₄ | Q₁ | Q₁ |
| Lₐ₃₈₉ | O | Q₁ | Q₁ | Q₁₅ | Q₁ | O | Q₈ | Q₄ | Q₁ | Q₁ |
| Lₐ₃₉₀ | O | Q₁ | Q₁ | Q₁₆ | Q₁ | O | Q₈ | Q₄ | Q₁ | Q₁ |
| Lₐ₃₉₁ | O | Q₁ | Q₁ | Q₁₇ | Q₁ | O | Q₈ | Q₄ | Q₁ | Q₁ |
| Lₐ₃₉₂ | O | Q₁ | Q₁ | Q₁₈ | Q₁ | O | Q₈ | Q₄ | Q₁ | Q₁ |
| Lₐ₃₉₃ | O | Q₁ | Q₁ | Q₁₉ | Q₁ | O | Q₈ | Q₄ | Q₁ | Q₁ |
| Lₐ₃₉₄ | O | Q₁ | Q₁ | Q₂₀ | Q₁ | O | Q₈ | Q₄ | Q₁ | Q₁ |
| Lₐ₃₉₅ | O | Q₁ | Q₁ | Q₂₁ | Q₁ | O | Q₈ | Q₄ | Q₁ | Q₁ |
| Lₐ₃₉₆ | O | Q₁ | Q₁ | Q₂₂ | Q₁ | O | Q₈ | Q₄ | Q₁ | Q₁ |
| Lₐ₃₉₇ | O | Q₁ | Q₁ | Q₂₃ | Q₁ | O | Q₈ | Q₄ | Q₁ | Q₁ |
| Lₐ₃₉₈ | O | Q₁ | Q₂ | Q₁ | Q₁ | O | Q₈ | Q₁ | Q₄ | Q₁ |
| Lₐ₃₉₉ | O | Q₁ | Q₃ | Q₁ | Q₁ | O | Q₈ | Q₁ | Q₄ | Q₁ |
| Lₐ₄₀₀ | O | Q₁ | Q₄ | Q₁ | Q₁ | O | Q₈ | Q₁ | Q₄ | Q₁ |
| Lₐ₄₀₁ | O | Q₁ | Q₅ | Q₁ | Q₁ | O | Q₈ | Q₁ | Q₄ | Q₁ |
| Lₐ₄₀₂ | O | Q₁ | Q₆ | Q₁ | Q₁ | O | Q₈ | Q₁ | Q₄ | Q₁ |
| Lₐ₄₀₃ | O | Q₁ | Q₇ | Q₁ | Q₁ | O | Q₈ | Q₁ | Q₄ | Q₁ |
| Lₐ₄₀₄ | O | Q₁ | Q₈ | Q₁ | Q₁ | O | Q₈ | Q₁ | Q₄ | Q₁ |
| Lₐ₄₀₅ | O | Q₁ | Q₉ | Q₁ | Q₁ | O | Q₈ | Q₁ | Q₄ | Q₁ |
| Lₐ₄₀₆ | O | Q₁ | Q₁₀ | Q₁ | Q₁ | O | Q₈ | Q₁ | Q₄ | Q₁ |
| Lₐ₄₀₇ | O | Q₁ | Q₁₁ | Q₁ | Q₁ | O | Q₈ | Q₁ | Q₄ | Q₁ |
| Lₐ₄₀₈ | O | Q₁ | Q₁₂ | Q₁ | Q₁ | O | Q₈ | Q₁ | Q₄ | Q₁ |
| Lₐ₄₀₉ | O | Q₁ | Q₁₃ | Q₁ | Q₁ | O | Q₈ | Q₁ | Q₄ | Q₁ |
| Lₐ₄₁₀ | O | Q₁ | Q₁₄ | Q₁ | Q₁ | O | Q₈ | Q₁ | Q₄ | Q₁ |
| Lₐ₄₁₁ | O | Q₁ | Q₁₅ | Q₁ | Q₁ | O | Q₈ | Q₁ | Q₄ | Q₁ |
| Lₐ₄₁₂ | O | Q₁ | Q₁₆ | Q₁ | Q₁ | O | Q₈ | Q₁ | Q₄ | Q₁ |
| Lₐ₄₁₃ | O | Q₁ | Q₁₇ | Q₁ | Q₁ | O | Q₈ | Q₁ | Q₄ | Q₁ |
| Lₐ₄₁₄ | O | Q₁ | Q₁₈ | Q₁ | Q₁ | O | Q₈ | Q₁ | Q₄ | Q₁ |
| Lₐ₄₁₅ | O | Q₁ | Q₁₉ | Q₁ | Q₁ | O | Q₈ | Q₁ | Q₄ | Q₁ |
| Lₐ₄₁₆ | O | Q₁ | Q₂₀ | Q₁ | Q₁ | O | Q₈ | Q₁ | Q₄ | Q₁ |
| Lₐ₄₁₇ | O | Q₁ | Q₂₁ | Q₁ | Q₁ | O | Q₈ | Q₁ | Q₄ | Q₁ |
| Lₐ₄₁₈ | O | Q₁ | Q₂₂ | Q₁ | Q₁ | O | Q₈ | Q₁ | Q₄ | Q₁ |
| Lₐ₄₁₉ | O | Q₁ | Q₂₃ | Q₁ | Q₁ | O | Q₈ | Q₁ | Q₄ | Q₁ |
| Lₐ₄₂₀ | O | Q₁ | Q₁ | Q₂ | Q₁ | O | Q₈ | Q₁ | Q₄ | Q₁ |
| Lₐ₄₂₁ | O | Q₁ | Q₁ | Q₃ | Q₁ | O | Q₈ | Q₁ | Q₄ | Q₁ |
| Lₐ₄₂₂ | O | Q₁ | Q₁ | Q₄ | Q₁ | O | Q₈ | Q₁ | Q₄ | Q₁ |
| Lₐ₄₂₃ | O | Q₁ | Q₁ | Q₅ | Q₁ | O | Q₈ | Q₁ | Q₄ | Q₁ |
| Lₐ₄₂₄ | O | Q₁ | Q₁ | Q₆ | Q₁ | O | Q₈ | Q₁ | Q₄ | Q₁ |
| Lₐ₄₂₅ | O | Q₁ | Q₁ | Q₇ | Q₁ | O | Q₈ | Q₁ | Q₄ | Q₁ |
| Lₐ₄₂₆ | O | Q₁ | Q₁ | Q₈ | Q₁ | O | Q₈ | Q₁ | Q₄ | Q₁ |
| Lₐ₄₂₇ | O | Q₁ | Q₁ | Q₉ | Q₁ | O | Q₈ | Q₁ | Q₄ | Q₁ |
| Lₐ₄₂₈ | O | Q₁ | Q₁ | Q₁₀ | Q₁ | O | Q₈ | Q₁ | Q₄ | Q₁ |
| Lₐ₄₂₉ | O | Q₁ | Q₁ | Q₁₁ | Q₁ | O | Q₈ | Q₁ | Q₄ | Q₁ |
| Lₐ₄₃₀ | O | Q₁ | Q₁ | Q₁₂ | Q₁ | O | Q₈ | Q₁ | Q₄ | Q₁ |
| Lₐ₄₃₁ | O | Q₁ | Q₁ | Q₁₃ | Q₁ | O | Q₈ | Q₁ | Q₄ | Q₁ |
| Lₐ₄₃₂ | O | Q₁ | Q₁ | Q₁₄ | Q₁ | O | Q₈ | Q₁ | Q₄ | Q₁ |
| Lₐ₄₃₃ | O | Q₁ | Q₁ | Q₁₅ | Q₁ | O | Q₈ | Q₁ | Q₄ | Q₁ |
| Lₐ₄₃₄ | O | Q₁ | Q₁ | Q₁₆ | Q₁ | O | Q₈ | Q₁ | Q₄ | Q₁ |
| Lₐ₄₃₅ | O | Q₁ | Q₁ | Q₁₇ | Q₁ | O | Q₈ | Q₁ | Q₄ | Q₁ |
| Lₐ₄₃₆ | O | Q₁ | Q₁ | Q₁₈ | Q₁ | O | Q₈ | Q₁ | Q₄ | Q₁ |
| Lₐ₄₃₇ | O | Q₁ | Q₁ | Q₁₉ | Q₁ | O | Q₈ | Q₁ | Q₄ | Q₁ |
| Lₐ₄₃₈ | O | Q₁ | Q₁ | Q₂₀ | Q₁ | O | Q₈ | Q₁ | Q₄ | Q₁ |
| Lₐ₄₃₉ | O | Q₁ | Q₁ | Q₂₁ | Q₁ | O | Q₈ | Q₁ | Q₄ | Q₁ |
| Lₐ₄₄₀ | O | Q₁ | Q₁ | Q₂₂ | Q₁ | O | Q₈ | Q₁ | Q₄ | Q₁ |
| Lₐ₄₄₁ | O | Q₁ | Q₁ | Q₂₃ | Q₁ | O | Q₈ | Q₁ | Q₄ | Q₁ |
| Lₐ₄₄₂ | O | Q₁ | Q₂ | Q₁ | Q₁ | O | Q₈ | Q₁ | Q₁ | Q₄ |
| Lₐ₄₄₃ | O | Q₁ | Q₃ | Q₁ | Q₁ | O | Q₈ | Q₁ | Q₁ | Q₄ |
| Lₐ₄₄₄ | O | Q₁ | Q₄ | Q₁ | Q₁ | O | Q₈ | Q₁ | Q₁ | Q₄ |
| Lₐ₄₄₅ | O | Q₁ | Q₅ | Q₁ | Q₁ | O | Q₈ | Q₁ | Q₁ | Q₄ |
| Lₐ₄₄₆ | O | Q₁ | Q₆ | Q₁ | Q₁ | O | Q₈ | Q₁ | Q₁ | Q₄ |
| Lₐ₄₄₇ | O | Q₁ | Q₇ | Q₁ | Q₁ | O | Q₈ | Q₁ | Q₁ | Q₄ |
| Lₐ₄₄₈ | O | Q₁ | Q₈ | Q₁ | Q₁ | O | Q₈ | Q₁ | Q₁ | Q₄ |
| Lₐ₄₄₉ | O | Q₁ | Q₉ | Q₁ | Q₁ | O | Q₈ | Q₁ | Q₁ | Q₄ |
| Lₐ₄₅₀ | O | Q₁ | Q₁₀ | Q₁ | Q₁ | O | Q₈ | Q₁ | Q₁ | Q₄ |
| Lₐ₄₅₁ | O | Q₁ | Q₁₁ | Q₁ | Q₁ | O | Q₈ | Q₁ | Q₁ | Q₄ |
| Lₐ₄₅₂ | O | Q₁ | Q₁₂ | Q₁ | Q₁ | O | Q₈ | Q₁ | Q₁ | Q₄ |
| Lₐ₄₅₃ | O | Q₁ | Q₁₃ | Q₁ | Q₁ | O | Q₈ | Q₁ | Q₁ | Q₄ |
| Lₐ₄₅₄ | O | Q₁ | Q₁₄ | Q₁ | Q₁ | O | Q₈ | Q₁ | Q₁ | Q₄ |
| Lₐ₄₅₅ | O | Q₁ | Q₁₅ | Q₁ | Q₁ | O | Q₈ | Q₁ | Q₁ | Q₄ |
| Lₐ₄₅₆ | O | Q₁ | Q₁₆ | Q₁ | Q₁ | O | Q₈ | Q₁ | Q₁ | Q₄ |
| Lₐ₄₅₇ | O | Q₁ | Q₁₇ | Q₁ | Q₁ | O | Q₈ | Q₁ | Q₁ | Q₄ |
| Lₐ₄₅₈ | O | Q₁ | Q₁₈ | Q₁ | Q₁ | O | Q₈ | Q₁ | Q₁ | Q₄ |
| Lₐ₄₅₉ | O | Q₁ | Q₁₉ | Q₁ | Q₁ | O | Q₈ | Q₁ | Q₁ | Q₄ |
| Lₐ₄₆₀ | O | Q₁ | Q₂₀ | Q₁ | Q₁ | O | Q₈ | Q₁ | Q₁ | Q₄ |
| Lₐ₄₆₁ | O | Q₁ | Q₂₁ | Q₁ | Q₁ | O | Q₈ | Q₁ | Q₁ | Q₄ |
| Lₐ₄₆₂ | O | Q₁ | Q₂₂ | Q₁ | Q₁ | O | Q₈ | Q₁ | Q₁ | Q₄ |
| Lₐ₄₆₃ | O | Q₁ | Q₂₃ | Q₁ | Q₁ | O | Q₈ | Q₁ | Q₁ | Q₄ |
| Lₐ₄₆₄ | O | Q₁ | Q₁ | Q₂ | Q₁ | O | Q₈ | Q₁ | Q₁ | Q₄ |
| Lₐ₄₆₅ | O | Q₁ | Q₁ | Q₃ | Q₁ | O | Q₈ | Q₁ | Q₁ | Q₄ |
| Lₐ₄₆₆ | O | Q₁ | Q₁ | Q₄ | Q₁ | O | Q₈ | Q₁ | Q₁ | Q₄ |
| Lₐ₄₆₇ | O | Q₁ | Q₁ | Q₅ | Q₁ | O | Q₈ | Q₁ | Q₁ | Q₄ |
| Lₐ₄₆₈ | O | Q₁ | Q₁ | Q₆ | Q₁ | O | Q₈ | Q₁ | Q₁ | Q₄ |
| Lₐ₄₆₉ | O | Q₁ | Q₁ | Q₇ | Q₁ | O | Q₈ | Q₁ | Q₁ | Q₄ |
| Lₐ₄₇₀ | O | Q₁ | Q₁ | Q₈ | Q₁ | O | Q₈ | Q₁ | Q₁ | Q₄ |
| Lₐ₄₇₁ | O | Q₁ | Q₁ | Q₉ | Q₁ | O | Q₈ | Q₁ | Q₁ | Q₄ |
| Lₐ₄₇₂ | O | Q₁ | Q₁ | Q₁₀ | Q₁ | O | Q₈ | Q₁ | Q₁ | Q₄ |
| Lₐ₄₇₃ | O | Q₁ | Q₁ | Q₁₁ | Q₁ | O | Q₈ | Q₁ | Q₁ | Q₄ |
| Lₐ₄₇₄ | O | Q₁ | Q₁ | Q₁₂ | Q₁ | O | Q₈ | Q₁ | Q₁ | Q₄ |
| Lₐ₄₇₅ | O | Q₁ | Q₁ | Q₁₃ | Q₁ | O | Q₈ | Q₁ | Q₁ | Q₄ |
| Lₐ₄₇₆ | O | Q₁ | Q₁ | Q₁₄ | Q₁ | O | Q₈ | Q₁ | Q₁ | Q₄ |
| Lₐ₄₇₇ | O | Q₁ | Q₁ | Q₁₅ | Q₁ | O | Q₈ | Q₁ | Q₁ | Q₄ |
| Lₐ₄₇₈ | O | Q₁ | Q₁ | Q₁₆ | Q₁ | O | Q₈ | Q₁ | Q₁ | Q₄ |
| Lₐ₄₇₉ | O | Q₁ | Q₁ | Q₁₇ | Q₁ | O | Q₈ | Q₁ | Q₁ | Q₄ |
| Lₐ₄₈₀ | O | Q₁ | Q₁ | Q₁₈ | Q₁ | O | Q₈ | Q₁ | Q₁ | Q₄ |
| Lₐ₄₈₁ | O | Q₁ | Q₁ | Q₁₉ | Q₁ | O | Q₈ | Q₁ | Q₁ | Q₄ |
| Lₐ₄₈₂ | O | Q₁ | Q₁ | Q₂₀ | Q₁ | O | Q₈ | Q₁ | Q₁ | Q₄ |
| Lₐ₄₈₃ | O | Q₁ | Q₁ | Q₂₁ | Q₁ | O | Q₈ | Q₁ | Q₁ | Q₄ |
| Lₐ₄₈₄ | O | Q₁ | Q₁ | Q₂₂ | Q₁ | O | Q₈ | Q₁ | Q₁ | Q₄ |
| Lₐ₄₈₅ | O | Q₁ | Q₁ | Q₂₃ | Q₁ | O | Q₈ | Q₁ | Q₁ | Q₄ |
| Lₐ₄₈₆ | O | Q₁ | Q₁ | Q₁ | Q₁ | S | Q₁ | Q₁ | Q₁ | Q₁ |
| Lₐ₄₈₇ | O | Q₂ | Q₁ | Q₁ | Q₁ | S | Q₁ | Q₁ | Q₁ | Q₁ |
| Lₐ₄₈₈ | O | Q₃ | Q₁ | Q₁ | Q₁ | S | Q₁ | Q₁ | Q₁ | Q₁ |
| Lₐ₄₈₉ | O | Q₄ | Q₁ | Q₁ | Q₁ | S | Q₁ | Q₁ | Q₁ | Q₁ |
| Lₐ₄₉₀ | O | Q₅ | Q₁ | Q₁ | Q₁ | S | Q₁ | Q₁ | Q₁ | Q₁ |
| Lₐ₄₉₁ | O | Q₆ | Q₁ | Q₁ | Q₁ | S | Q₁ | Q₁ | Q₁ | Q₁ |
| Lₐ₄₉₂ | O | Q₇ | Q₁ | Q₁ | Q₁ | S | Q₁ | Q₁ | Q₁ | Q₁ |
| Lₐ₄₉₃ | O | Q₈ | Q₁ | Q₁ | Q₁ | S | Q₁ | Q₁ | Q₁ | Q₁ |
| Lₐ₄₉₄ | O | Q₉ | Q₁ | Q₁ | Q₁ | S | Q₁ | Q₁ | Q₁ | Q₁ |
| Lₐ₄₉₅ | O | Q₁₀ | Q₁ | Q₁ | Q₁ | S | Q₁ | Q₁ | Q₁ | Q₁ |
| Lₐ₄₉₆ | O | Q₁₁ | Q₁ | Q₁ | Q₁ | S | Q₁ | Q₁ | Q₁ | Q₁ |
| Lₐ₄₉₇ | O | Q₁₂ | Q₁ | Q₁ | Q₁ | S | Q₁ | Q₁ | Q₁ | Q₁ |
| Lₐ₄₉₈ | O | Q₁₃ | Q₁ | Q₁ | Q₁ | S | Q₁ | Q₁ | Q₁ | Q₁ |
| Lₐ₄₉₉ | O | Q₁₄ | Q₁ | Q₁ | Q₁ | S | Q₁ | Q₁ | Q₁ | Q₁ |
| Lₐ₅₀₀ | O | Q₁₅ | Q₁ | Q₁ | Q₁ | S | Q₁ | Q₁ | Q₁ | Q₁ |
| Lₐ₅₀₁ | O | Q₁₆ | Q₁ | Q₁ | Q₁ | S | Q₁ | Q₁ | Q₁ | Q₁ |
| Lₐ₅₀₂ | O | Q₁₇ | Q₁ | Q₁ | Q₁ | S | Q₁ | Q₁ | Q₁ | Q₁ |
| Lₐ₅₀₃ | O | Q₁₈ | Q₁ | Q₁ | Q₁ | S | Q₁ | Q₁ | Q₁ | Q₁ |
| Lₐ₅₀₄ | O | Q₁₉ | Q₁ | Q₁ | Q₁ | S | Q₁ | Q₁ | Q₁ | Q₁ |
| Lₐ₅₀₅ | O | Q₂₀ | Q₁ | Q₁ | Q₁ | S | Q₁ | Q₁ | Q₁ | Q₁ |
| Lₐ₅₀₆ | O | Q₂₁ | Q₁ | Q₁ | Q₁ | S | Q₁ | Q₁ | Q₁ | Q₁ |
| Lₐ₅₀₇ | O | Q₂₂ | Q₁ | Q₁ | Q₁ | S | Q₁ | Q₁ | Q₁ | Q₁ |
| Lₐ₅₀₈ | O | Q₂₃ | Q₁ | Q₁ | Q₁ | S | Q₁ | Q₁ | Q₁ | Q₁ |
| Lₐ₅₀₉ | O | Q₁ | Q₂ | Q₁ | Q₁ | S | Q₁ | Q₁ | Q₁ | Q₁ |
| Lₐ₅₁₀ | O | Q₁ | Q₃ | Q₁ | Q₁ | S | Q₁ | Q₁ | Q₁ | Q₁ |
| Lₐ₅₁₁ | O | Q₁ | Q₄ | Q₁ | Q₁ | S | Q₁ | Q₁ | Q₁ | Q₁ |
| Lₐ₅₁₂ | O | Q₁ | Q₅ | Q₁ | Q₁ | S | Q₁ | Q₁ | Q₁ | Q₁ |
| Lₐ₅₁₃ | O | Q₁ | Q₆ | Q₁ | Q₁ | S | Q₁ | Q₁ | Q₁ | Q₁ |
| Lₐ₅₁₄ | O | Q₁ | Q₇ | Q₁ | Q₁ | S | Q₁ | Q₁ | Q₁ | Q₁ |
| Lₐ₅₁₅ | O | Q₁ | Q₈ | Q₁ | Q₁ | S | Q₁ | Q₁ | Q₁ | Q₁ |
| Lₐ₅₁₆ | O | Q₁ | Q₉ | Q₁ | Q₁ | S | Q₁ | Q₁ | Q₁ | Q₁ |
| Lₐ₅₁₇ | O | Q₁ | Q₁₀ | Q₁ | Q₁ | S | Q₁ | Q₁ | Q₁ | Q₁ |
| Lₐ₅₁₈ | O | Q₁ | Q₁₁ | Q₁ | Q₁ | S | Q₁ | Q₁ | Q₁ | Q₁ |
| Lₐ₅₁₉ | O | Q₁ | Q₁₂ | Q₁ | Q₁ | S | Q₁ | Q₁ | Q₁ | Q₁ |
| Lₐ₅₂₀ | O | Q₁ | Q₁₃ | Q₁ | Q₁ | S | Q₁ | Q₁ | Q₁ | Q₁ |
| Lₐ₅₂₁ | O | Q₁ | Q₁₄ | Q₁ | Q₁ | S | Q₁ | Q₁ | Q₁ | Q₁ |
| Lₐ₅₂₂ | O | Q₁ | Q₁₅ | Q₁ | Q₁ | S | Q₁ | Q₁ | Q₁ | Q₁ |
| Lₐ₅₂₃ | O | Q₁ | Q₁₆ | Q₁ | Q₁ | S | Q₁ | Q₁ | Q₁ | Q₁ |
| Lₐ₅₂₄ | O | Q₁ | Q₁₇ | Q₁ | Q₁ | S | Q₁ | Q₁ | Q₁ | Q₁ |
| Lₐ₅₂₅ | O | Q₁ | Q₁₈ | Q₁ | Q₁ | S | Q₁ | Q₁ | Q₁ | Q₁ |
| Lₐ₅₂₆ | O | Q₁ | Q₁₉ | Q₁ | Q₁ | S | Q₁ | Q₁ | Q₁ | Q₁ |
| Lₐ₅₂₇ | O | Q₁ | Q₂₀ | Q₁ | Q₁ | S | Q₁ | Q₁ | Q₁ | Q₁ |
| Lₐ₅₂₈ | O | Q₁ | Q₂₁ | Q₁ | Q₁ | S | Q₁ | Q₁ | Q₁ | Q₁ |
| Lₐ₅₂₉ | O | Q₁ | Q₂₂ | Q₁ | Q₁ | S | Q₁ | Q₁ | Q₁ | Q₁ |
| Lₐ₅₃₀ | O | Q₁ | Q₂₃ | Q₁ | Q₁ | S | Q₁ | Q₁ | Q₁ | Q₁ |
| Lₐ₅₃₁ | O | Q₁ | Q₁ | Q₂ | Q₁ | S | Q₁ | Q₁ | Q₁ | Q₁ |
| Lₐ₅₃₂ | O | Q₁ | Q₁ | Q₃ | Q₁ | S | Q₁ | Q₁ | Q₁ | Q₁ |
| Lₐ₅₃₃ | O | Q₁ | Q₁ | Q₄ | Q₁ | S | Q₁ | Q₁ | Q₁ | Q₁ |
| Lₐ₅₃₄ | O | Q₁ | Q₁ | Q₅ | Q₁ | S | Q₁ | Q₁ | Q₁ | Q₁ |
| Lₐ₅₃₅ | O | Q₁ | Q₁ | Q₆ | Q₁ | S | Q₁ | Q₁ | Q₁ | Q₁ |
| Lₐ₅₃₆ | O | Q₁ | Q₁ | Q₇ | Q₁ | S | Q₁ | Q₁ | Q₁ | Q₁ |
| Lₐ₅₃₇ | O | Q₁ | Q₁ | Q₈ | Q₁ | S | Q₁ | Q₁ | Q₁ | Q₁ |
| Lₐ₅₃₈ | O | Q₁ | Q₁ | Q₉ | Q₁ | S | Q₁ | Q₁ | Q₁ | Q₁ |
| Lₐ₅₃₉ | O | Q₁ | Q₁ | Q₁₀ | Q₁ | S | Q₁ | Q₁ | Q₁ | Q₁ |
| Lₐ₅₄₀ | O | Q₁ | Q₁ | Q₁₁ | Q₁ | S | Q₁ | Q₁ | Q₁ | Q₁ |
| Lₐ₅₄₁ | O | Q₁ | Q₁ | Q₁₂ | Q₁ | S | Q₁ | Q₁ | Q₁ | Q₁ |
| Lₐ₅₄₂ | O | Q₁ | Q₁ | Q₁₃ | Q₁ | S | Q₁ | Q₁ | Q₁ | Q₁ |
| Lₐ₅₄₃ | O | Q₁ | Q₁ | Q₁₄ | Q₁ | S | Q₁ | Q₁ | Q₁ | Q₁ |
| Lₐ₅₄₄ | O | Q₁ | Q₁ | Q₁₅ | Q₁ | S | Q₁ | Q₁ | Q₁ | Q₁ |
| Lₐ₅₄₅ | O | Q₁ | Q₁ | Q₁₆ | Q₁ | S | Q₁ | Q₁ | Q₁ | Q₁ |
| Lₐ₅₄₆ | O | Q₁ | Q₁ | Q₁₇ | Q₁ | S | Q₁ | Q₁ | Q₁ | Q₁ |
| Lₐ₅₄₇ | O | Q₁ | Q₁ | Q₁₈ | Q₁ | S | Q₁ | Q₁ | Q₁ | Q₁ |
| Lₐ₅₄₈ | O | Q₁ | Q₁ | Q₁₉ | Q₁ | S | Q₁ | Q₁ | Q₁ | Q₁ |
| Lₐ₅₄₉ | O | Q₁ | Q₁ | Q₂₀ | Q₁ | S | Q₁ | Q₁ | Q₁ | Q₁ |
| Lₐ₅₅₀ | O | Q₁ | Q₁ | Q₂₁ | Q₁ | S | Q₁ | Q₁ | Q₁ | Q₁ |
| Lₐ₅₅₁ | O | Q₁ | Q₁ | Q₂₂ | Q₁ | S | Q₁ | Q₁ | Q₁ | Q₁ |
| Lₐ₅₅₂ | O | Q₁ | Q₁ | Q₂₃ | Q₁ | S | Q₁ | Q₁ | Q₁ | Q₁ |
| Lₐ₅₅₃ | O | Q₁ | Q₁ | Q₁ | Q₂ | S | Q₁ | Q₁ | Q₁ | Q₁ |
| Lₐ₅₅₄ | O | Q₁ | Q₁ | Q₁ | Q₃ | S | Q₁ | Q₁ | Q₁ | Q₁ |
| Lₐ₅₅₅ | O | Q₁ | Q₁ | Q₁ | Q₄ | S | Q₁ | Q₁ | Q₁ | Q₁ |
| Lₐ₅₅₆ | O | Q₁ | Q₁ | Q₁ | Q₅ | S | Q₁ | Q₁ | Q₁ | Q₁ |
| Lₐ₅₅₇ | O | Q₁ | Q₁ | Q₁ | Q₆ | S | Q₁ | Q₁ | Q₁ | Q₁ |
| Lₐ₅₅₈ | O | Q₁ | Q₁ | Q₁ | Q₇ | S | Q₁ | Q₁ | Q₁ | Q₁ |
| Lₐ₅₅₉ | O | Q₁ | Q₁ | Q₁ | Q₈ | S | Q₁ | Q₁ | Q₁ | Q₁ |
| Lₐ₅₆₀ | O | Q₁ | Q₁ | Q₁ | Q₉ | S | Q₁ | Q₁ | Q₁ | Q₁ |
| Lₐ₅₆₁ | O | Q₁ | Q₁ | Q₁ | Q₁₀ | S | Q₁ | Q₁ | Q₁ | Q₁ |
| Lₐ₅₆₂ | O | Q₁ | Q₁ | Q₁ | Q₁₁ | S | Q₁ | Q₁ | Q₁ | Q₁ |
| Lₐ₅₆₃ | O | Q₁ | Q₁ | Q₁ | Q₁₂ | S | Q₁ | Q₁ | Q₁ | Q₁ |
| Lₐ₅₆₄ | O | Q₁ | Q₁ | Q₁ | Q₁₃ | S | Q₁ | Q₁ | Q₁ | Q₁ |
| Lₐ₅₆₅ | O | Q₁ | Q₁ | Q₁ | Q₁₄ | S | Q₁ | Q₁ | Q₁ | Q₁ |
| Lₐ₅₆₆ | O | Q₁ | Q₁ | Q₁ | Q₁₅ | S | Q₁ | Q₁ | Q₁ | Q₁ |
| Lₐ₅₆₇ | O | Q₁ | Q₁ | Q₁ | Q₁₆ | S | Q₁ | Q₁ | Q₁ | Q₁ |
| Lₐ₅₆₈ | O | Q₁ | Q₁ | Q₁ | Q₁₇ | S | Q₁ | Q₁ | Q₁ | Q₁ |
| Lₐ₅₆₉ | O | Q₁ | Q₁ | Q₁ | Q₁₈ | S | Q₁ | Q₁ | Q₁ | Q₁ |
| Lₐ₅₇₀ | O | Q₁ | Q₁ | Q₁ | Q₁₉ | S | Q₁ | Q₁ | Q₁ | Q₁ |
| Lₐ₅₇₁ | O | Q₁ | Q₁ | Q₁ | Q₂₀ | S | Q₁ | Q₁ | Q₁ | Q₁ |
| Lₐ₅₇₂ | O | Q₁ | Q₁ | Q₁ | Q₂₁ | S | Q₁ | Q₁ | Q₁ | Q₁ |
| Lₐ₅₇₃ | O | Q₁ | Q₁ | Q₁ | Q₂₂ | S | Q₁ | Q₁ | Q₁ | Q₁ |
| Lₐ₅₇₄ | O | Q₁ | Q₁ | Q₁ | Q₂₃ | S | Q₁ | Q₁ | Q₁ | Q₁ |
| Lₐ₅₇₅ | O | Q₁ | Q₁ | Q₁ | Q₁ | S | Q₂ | Q₁ | Q₁ | Q₁ |
| Lₐ₅₇₆ | O | Q₁ | Q₁ | Q₁ | Q₁ | S | Q₃ | Q₁ | Q₁ | Q₁ |
| Lₐ₅₇₇ | O | Q₁ | Q₁ | Q₁ | Q₁ | S | Q₄ | Q₁ | Q₁ | Q₁ |
| Lₐ₅₇₈ | O | Q₁ | Q₁ | Q₁ | Q₁ | S | Q₅ | Q₁ | Q₁ | Q₁ |
| Lₐ₅₇₉ | O | Q₁ | Q₁ | Q₁ | Q₁ | S | Q₆ | Q₁ | Q₁ | Q₁ |
| Lₐ₅₈₀ | O | Q₁ | Q₁ | Q₁ | Q₁ | S | Q₇ | Q₁ | Q₁ | Q₁ |
| Lₐ₅₈₁ | O | Q₁ | Q₁ | Q₁ | Q₁ | S | Q₈ | Q₁ | Q₁ | Q₁ |
| Lₐ₅₈₂ | O | Q₁ | Q₁ | Q₁ | Q₁ | S | Q₉ | Q₁ | Q₁ | Q₁ |
| Lₐ₅₈₃ | O | Q₁ | Q₁ | Q₁ | Q₁ | S | Q₁₀ | Q₁ | Q₁ | Q₁ |
| Lₐ₅₈₄ | O | Q₁ | Q₁ | Q₁ | Q₁ | S | Q₁₁ | Q₁ | Q₁ | Q₁ |
| Lₐ₅₈₅ | O | Q₁ | Q₁ | Q₁ | Q₁ | S | Q₁₂ | Q₁ | Q₁ | Q₁ |
| Lₐ₅₈₆ | O | Q₁ | Q₁ | Q₁ | Q₁ | S | Q₁₃ | Q₁ | Q₁ | Q₁ |
| Lₐ₅₈₇ | O | Q₁ | Q₁ | Q₁ | Q₁ | S | Q₁₄ | Q₁ | Q₁ | Q₁ |
| Lₐ₅₈₈ | O | Q₁ | Q₁ | Q₁ | Q₁ | S | Q₁₅ | Q₁ | Q₁ | Q₁ |
| Lₐ₅₈₉ | O | Q₁ | Q₁ | Q₁ | Q₁ | S | Q₁₆ | Q₁ | Q₁ | Q₁ |
| Lₐ₅₉₀ | O | Q₁ | Q₁ | Q₁ | Q₁ | S | Q₁₇ | Q₁ | Q₁ | Q₁ |
| Lₐ₅₉₁ | O | Q₁ | Q₁ | Q₁ | Q₁ | S | Q₁₈ | Q₁ | Q₁ | Q₁ |
| Lₐ₅₉₂ | O | Q₁ | Q₁ | Q₁ | Q₁ | S | Q₁₉ | Q₁ | Q₁ | Q₁ |
| Lₐ₅₉₃ | O | Q₁ | Q₁ | Q₁ | Q₁ | S | Q₂₀ | Q₁ | Q₁ | Q₁ |
| Lₐ₅₉₄ | O | Q₁ | Q₁ | Q₁ | Q₁ | S | Q₂₁ | Q₁ | Q₁ | Q₁ |
| Lₐ₅₉₅ | O | Q₁ | Q₁ | Q₁ | Q₁ | S | Q₂₂ | Q₁ | Q₁ | Q₁ |
| Lₐ₅₉₆ | O | Q₁ | Q₁ | Q₁ | Q₁ | S | Q₂₃ | Q₁ | Q₁ | Q₁ |
| Lₐ₅₉₇ | O | Q₁ | Q₁ | Q₁ | Q₁ | S | Q₁ | Q₂ | Q₁ | Q₁ |
| Lₐ₅₉₈ | O | Q₁ | Q₁ | Q₁ | Q₁ | S | Q₁ | Q₃ | Q₁ | Q₁ |
| Lₐ₅₉₉ | O | Q₁ | Q₁ | Q₁ | Q₁ | S | Q₁ | Q₄ | Q₁ | Q₁ |
| Lₐ₆₀₀ | O | Q₁ | Q₁ | Q₁ | Q₁ | S | Q₁ | Q₅ | Q₁ | Q₁ |
| Lₐ₆₀₁ | O | Q₁ | Q₁ | Q₁ | Q₁ | S | Q₁ | Q₆ | Q₁ | Q₁ |
| Lₐ₆₀₂ | O | Q₁ | Q₁ | Q₁ | Q₁ | S | Q₁ | Q₇ | Q₁ | Q₁ |
| Lₐ₆₀₃ | O | Q₁ | Q₁ | Q₁ | Q₁ | S | Q₁ | Q₈ | Q₁ | Q₁ |
| Lₐ₆₀₄ | O | Q₁ | Q₁ | Q₁ | Q₁ | S | Q₁ | Q₉ | Q₁ | Q₁ |
| Lₐ₆₀₅ | O | Q₁ | Q₁ | Q₁ | Q₁ | S | Q₁ | Q₁₀ | Q₁ | Q₁ |
| Lₐ₆₀₆ | O | Q₁ | Q₁ | Q₁ | Q₁ | S | Q₁ | Q₁₁ | Q₁ | Q₁ |
| Lₐ₆₀₇ | O | Q₁ | Q₁ | Q₁ | Q₁ | S | Q₁ | Q₁₂ | Q₁ | Q₁ |
| Lₐ₆₀₈ | O | Q₁ | Q₁ | Q₁ | Q₁ | S | Q₁ | Q₁₃ | Q₁ | Q₁ |
| Lₐ₆₀₉ | O | Q₁ | Q₁ | Q₁ | Q₁ | S | Q₁ | Q₁₄ | Q₁ | Q₁ |
| Lₐ₆₁₀ | O | Q₁ | Q₁ | Q₁ | Q₁ | S | Q₁ | Q₁₅ | Q₁ | Q₁ |
| Lₐ₆₁₁ | O | Q₁ | Q₁ | Q₁ | Q₁ | S | Q₁ | Q₁₆ | Q₁ | Q₁ |
| Lₐ₆₁₂ | O | Q₁ | Q₁ | Q₁ | Q₁ | S | Q₁ | Q₁₇ | Q₁ | Q₁ |
| Lₐ₆₁₃ | O | Q₁ | Q₁ | Q₁ | Q₁ | S | Q₁ | Q₁₈ | Q₁ | Q₁ |
| Lₐ₆₁₄ | O | Q₁ | Q₁ | Q₁ | Q₁ | S | Q₁ | Q₁₉ | Q₁ | Q₁ |
| Lₐ₆₁₅ | O | Q₁ | Q₁ | Q₁ | Q₁ | S | Q₁ | Q₂₀ | Q₁ | Q₁ |
| Lₐ₆₁₆ | 0 | Q₁ | Q₁ | Q₁ | Q₁ | S | Q₁ | Q₂₁ | Q₁ | Q₁ |
| Lₐ₆₁₇ | O | Q₁ | Q₁ | Q₁ | Q₁ | S | Q₁ | Q₂₂ | Q₁ | Q₁ |
| Lₐ₆₁₈ | O | Q₁ | Q₁ | Q₁ | Q₁ | S | Q₁ | Q₂₃ | Q₁ | Q₁ |
| Lₐ₆₁₉ | O | Q₁ | Q₁ | Q₁ | Q₁ | S | Q₁ | Q₁ | Q₂ | Q₁ |
| Lₐ₆₂₀ | O | Q₁ | Q₁ | Q₁ | Q₁ | S | Q₁ | Q₁ | Q₃ | Q₁ |
| Lₐ₆₂₁ | O | Q₁ | Q₁ | Q₁ | Q₁ | S | Q₁ | Q₁ | Q₄ | Q₁ |
| Lₐ₆₂₂ | O | Q₁ | Q₁ | Q₁ | Q₁ | S | Q₁ | Q₁ | Q₅ | Q₁ |
| Lₐ₆₂₃ | O | Q₁ | Q₁ | Q₁ | Q₁ | S | Q₁ | Q₁ | Q₆ | Q₁ |
| Lₐ₆₂₄ | O | Q₁ | Q₁ | Q₁ | Q₁ | S | Q₁ | Q₁ | Q₇ | Q₁ |
| Lₐ₆₂₅ | O | Q₁ | Q₁ | Q₁ | Q₁ | S | Q₁ | Q₁ | Q₈ | Q₁ |
| Lₐ₆₂₆ | O | Q₁ | Q₁ | Q₁ | Q₁ | S | Q₁ | Q₁ | Q₉ | Q₁ |
| Lₐ₆₂₇ | O | Q₁ | Q₁ | Q₁ | Q₁ | S | Q₁ | Q₁ | Q₁₀ | Q₁ |
| Lₐ₆₂₈ | O | Q₁ | Q₁ | Q₁ | Q₁ | S | Q₁ | Q₁ | Q₁₁ | Q₁ |
| Lₐ₆₂₉ | O | Q₁ | Q₁ | Q₁ | Q₁ | S | Q₁ | Q₁ | Q₁₂ | Q₁ |
| Lₐ₆₃₀ | O | Q₁ | Q₁ | Q₁ | Q₁ | S | Q₁ | Q₁ | Q₁₃ | Q₁ |
| Lₐ₆₃₁ | O | Q₁ | Q₁ | Q₁ | Q₁ | S | Q₁ | Q₁ | Q₁₄ | Q₁ |
| Lₐ₆₃₂ | O | Q₁ | Q₁ | Q₁ | Q₁ | S | Q₁ | Q₁ | Q₁₅ | Q₁ |
| Lₐ₆₃₃ | O | Q₁ | Q₁ | Q₁ | Q₁ | S | Q₁ | Q₁ | Q₁₆ | Q₁ |
| Lₐ₆₃₄ | O | Q₁ | Q₁ | Q₁ | Q₁ | S | Q₁ | Q₁ | Q₁₇ | Q₁ |
| Lₐ₆₃₅ | O | Q₁ | Q₁ | Q₁ | Q₁ | S | Q₁ | Q₁ | Q₁₈ | Q₁ |
| Lₐ₆₃₆ | O | Q₁ | Q₁ | Q₁ | Q₁ | S | Q₁ | Q₁ | Q₁₉ | Q₁ |
| Lₐ₆₃₇ | O | Q₁ | Q₁ | Q₁ | Q₁ | S | Q₁ | Q₁ | Q₂₀ | Q₁ |
| Lₐ₆₃₈ | O | Q₁ | Q₁ | Q₁ | Q₁ | S | Q₁ | Q₁ | Q₂₁ | Q₁ |
| Lₐ₆₃₉ | O | Q₁ | Q₁ | Q₁ | Q₁ | S | Q₁ | Q₁ | Q₂₂ | Q₁ |
| Lₐ₆₄₀ | O | Q₁ | Q₁ | Q₁ | Q₁ | S | Q₁ | Q₁ | Q₂₃ | Q₁ |
| Lₐ₆₄₁ | O | Q₁ | Q₁ | Q₁ | Q₁ | S | Q₁ | Q₁ | Q₁ | Q₂ |
| Lₐ₆₄₂ | O | Q₁ | Q₁ | Q₁ | Q₁ | S | Q₁ | Q₁ | Q₁ | Q₃ |
| Lₐ₆₄₃ | O | Q₁ | Q₁ | Q₁ | Q₁ | S | Q₁ | Q₁ | Q₁ | Q₄ |
| Lₐ₆₄₄ | O | Q₁ | Q₁ | Q₁ | Q₁ | S | Q₁ | Q₁ | Q₁ | Q₅ |
| Lₐ₆₄₅ | O | Q₁ | Q₁ | Q₁ | Q₁ | S | Q₁ | Q₁ | Q₁ | Q₆ |
| Lₐ₆₄₆ | O | Q₁ | Q₁ | Q₁ | Q₁ | S | Q₁ | Q₁ | Q₁ | Q₇ |
| Lₐ₆₄₇ | O | Q₁ | Q₁ | Q₁ | Q₁ | S | Q₁ | Q₁ | Q₁ | Q₈ |
| Lₐ₆₄₈ | O | Q₁ | Q₁ | Q₁ | Q₁ | S | Q₁ | Q₁ | Q₁ | Q₉ |
| Lₐ₆₄₉ | O | Q₁ | Q₁ | Q₁ | Q₁ | S | Q₁ | Q₁ | Q₁ | Q₁₀ |
| Lₐ₆₅₀ | O | Q₁ | Q₁ | Q₁ | Q₁ | S | Q₁ | Q₁ | Q₁ | Q₁₁ |
| Lₐ₆₅₁ | O | Q₁ | Q₁ | Q₁ | Q₁ | S | Q₁ | Q₁ | Q₁ | Q₁₂ |
| Lₐ₆₅₂ | O | Q₁ | Q₁ | Q₁ | Q₁ | S | Q₁ | Q₁ | Q₁ | Q₁₃ |
| Lₐ₆₅₃ | O | Q₁ | Q₁ | Q₁ | Q₁ | S | Q₁ | Q₁ | Q₁ | Q₁₄ |
| Lₐ₆₅₄ | O | Q₁ | Q₁ | Q₁ | Q₁ | S | Q₁ | Q₁ | Q₁ | Q₁₅ |
| Lₐ₆₅₅ | O | Q₁ | Q₁ | Q₁ | Q₁ | S | Q₁ | Q₁ | Q₁ | Q₁₆ |
| Lₐ₆₅₆ | O | Q₁ | Q₁ | Q₁ | Q₁ | S | Q₁ | Q₁ | Q₁ | Q₁₇ |
| Lₐ₆₅₇ | O | Q₁ | Q₁ | Q₁ | Q₁ | S | Q₁ | Q₁ | Q₁ | Q₁₈ |
| Lₐ₆₅₈ | O | Q₁ | Q₁ | Q₁ | Q₁ | S | Q₁ | Q₁ | Q₁ | Q₁₉ |
| Lₐ₆₅₉ | O | Q₁ | Q₁ | Q₁ | Q₁ | S | Q₁ | Q₁ | Q₁ | Q₂₀ |
| Lₐ₆₆₀ | O | Q₁ | Q₁ | Q₁ | Q₁ | S | Q₁ | Q₁ | Q₁ | Q₂₁ |
| Lₐ₆₆₁ | O | Q₁ | Q₁ | Q₁ | Q₁ | S | Q₁ | Q₁ | Q₁ | Q₂₂ |
| Lₐ₆₆₂ | O | Q₁ | Q₁ | Q₁ | Q₁ | S | Q₁ | Q₁ | Q₁ | Q₂₃ |
| Lₐ₆₆₃ | O | Q₁ | Q₂ | Q₁ | Q₁ | S | Q₄ | Q₁ | Q₁ | Q₁ |
| Lₐ₆₆₄ | O | Q₁ | Q₃ | Q₁ | Q₁ | S | Q₄ | Q₁ | Q₁ | Q₁ |
| Lₐ₆₆₅ | O | Q₁ | Q₄ | Q₁ | Q₁ | S | Q₄ | Q₁ | Q₁ | Q₁ |
| Lₐ₆₆₆ | O | Q₁ | Q₅ | Q₁ | Q₁ | S | Q₄ | Q₁ | Q₁ | Q₁ |
| Lₐ₆₆₇ | O | Q₁ | Q₆ | Q₁ | Q₁ | S | Q₄ | Q₁ | Q₁ | Q₁ |
| Lₐ₆₆₈ | O | Q₁ | Q₇ | Q₁ | Q₁ | S | Q₄ | Q₁ | Q₁ | Q₁ |
| Lₐ₆₆₉ | O | Q₁ | Q₈ | Q₁ | Q₁ | S | Q₄ | Q₁ | Q₁ | Q₁ |
| Lₐ₆₇₀ | O | Q₁ | Q₉ | Q₁ | Q₁ | S | Q₄ | Q₁ | Q₁ | Q₁ |
| Lₐ₆₇₁ | O | Q₁ | Q₁₀ | Q₁ | Q₁ | S | Q₄ | Q₁ | Q₁ | Q₁ |
| Lₐ₆₇₂ | O | Q₁ | Q₁₁ | Q₁ | Q₁ | S | Q₄ | Q₁ | Q₁ | Q₁ |
| Lₐ₆₇₃ | O | Q₁ | Q₁₂ | Q₁ | Q₁ | S | Q₄ | Q₁ | Q₁ | Q₁ |
| Lₐ₆₇₄ | O | Q₁ | Q₁₃ | Q₁ | Q₁ | S | Q₄ | Q₁ | Q₁ | Q₁ |
| Lₐ₆₇₅ | O | Q₁ | Q₁₄ | Q₁ | Q₁ | S | Q₄ | Q₁ | Q₁ | Q₁ |
| Lₐ₆₇₆ | O | Q₁ | Q₁₅ | Q₁ | Q₁ | S | Q₄ | Q₁ | Q₁ | Q₁ |
| Lₐ₆₇₇ | O | Q₁ | Q₁₆ | Q₁ | Q₁ | S | Q₄ | Q₁ | Q₁ | Q₁ |
| Lₐ₆₇₈ | O | Q₁ | Q₁₇ | Q₁ | Q₁ | S | Q₄ | Q₁ | Q₁ | Q₁ |
| Lₐ₆₇₉ | O | Q₁ | Q₁₈ | Q₁ | Q₁ | S | Q₄ | Q₁ | Q₁ | Q₁ |
| Lₐ₆₈₀ | O | Q₁ | Q₁₉ | Q₁ | Q₁ | S | Q₄ | Q₁ | Q₁ | Q₁ |
| Lₐ₆₈₁ | O | Q₁ | Q₂₀ | Q₁ | Q₁ | S | Q₄ | Q₁ | Q₁ | Q₁ |
| Lₐ₆₈₂ | O | Q₁ | Q₂₁ | Q₁ | Q₁ | S | Q₄ | Q₁ | Q₁ | Q₁ |
| Lₐ₆₈₃ | O | Q₁ | Q₂₂ | Q₁ | Q₁ | S | Q₄ | Q₁ | Q₁ | Q₁ |
| Lₐ₆₈₄ | O | Q₁ | Q₂₃ | Q₁ | Q₁ | S | Q₄ | Q₁ | Q₁ | Q₁ |
| Lₐ₆₈₅ | O | Q₁ | Q₁ | Q₂ | Q₁ | S | Q₄ | Q₁ | Q₁ | Q₁ |
| Lₐ₆₈₆ | O | Q₁ | Q₁ | Q₃ | Q₁ | S | Q₄ | Q₁ | Q₁ | Q₁ |
| Lₐ₆₈₇ | O | Q₁ | Q₁ | Q₄ | Q₁ | S | Q₄ | Q₁ | Q₁ | Q₁ |
| Lₐ₆₈₈ | O | Q₁ | Q₁ | Q₅ | Q₁ | S | Q₄ | Q₁ | Q₁ | Q₁ |
| Lₐ₆₈₉ | O | Q₁ | Q₁ | Q₆ | Q₁ | S | Q₄ | Q₁ | Q₁ | Q₁ |
| Lₐ₆₉₀ | O | Q₁ | Q₁ | Q₇ | Q₁ | S | Q₄ | Q₁ | Q₁ | Q₁ |
| Lₐ₆₉₁ | O | Q₁ | Q₁ | Q₈ | Q₁ | S | Q₄ | Q₁ | Q₁ | Q₁ |
| Lₐ₆₉₂ | O | Q₁ | Q₁ | Q₉ | Q₁ | S | Q₄ | Q₁ | Q₁ | Q₁ |
| Lₐ₆₉₃ | O | Q₁ | Q₁ | Q₁₀ | Q₁ | S | Q₄ | Q₁ | Q₁ | Q₁ |
| Lₐ₆₉₄ | O | Q₁ | Q₁ | Q₁₁ | Q₁ | S | Q₄ | Q₁ | Q₁ | Q₁ |
| Lₐ₆₉₅ | O | Q₁ | Q₁ | Q₁₂ | Q₁ | S | Q₄ | Q₁ | Q₁ | Q₁ |
| Lₐ₆₉₆ | O | Q₁ | Q₁ | Q₁₃ | Q₁ | S | Q₄ | Q₁ | Q₁ | Q₁ |
| Lₐ₆₉₇ | O | Q₁ | Q₁ | Q₁₄ | Q₁ | S | Q₄ | Q₁ | Q₁ | Q₁ |
| Lₐ₆₉₈ | O | Q₁ | Q₁ | Q₁₅ | Q₁ | S | Q₄ | Q₁ | Q₁ | Q₁ |
| Lₐ₆₉₉ | O | Q₁ | Q₁ | Q₁₆ | Q₁ | S | Q₄ | Q₁ | Q₁ | Q₁ |
| Lₐ₇₀₀ | O | Q₁ | Q₁ | Q₁₇ | Q₁ | S | Q₄ | Q₁ | Q₁ | Q₁ |
| Lₐ₇₀₁ | O | Q₁ | Q₁ | Q₁₈ | Q₁ | S | Q₄ | Q₁ | Q₁ | Q₁ |
| Lₐ₇₀₂ | O | Q₁ | Q₁ | Q₁₉ | Q₁ | S | Q₄ | Q₁ | Q₁ | Q₁ |
| Lₐ₇₀₃ | O | Q₁ | Q₁ | Q₂₀ | Q₁ | S | Q₄ | Q₁ | Q₁ | Q₁ |
| Lₐ₇₀₄ | O | Q₁ | Q₁ | Q₂₁ | Q₁ | S | Q₄ | Q₁ | Q₁ | Q₁ |
| Lₐ₇₀₅ | O | Q₁ | Q₁ | Q₂₂ | Q₁ | S | Q₄ | Q₁ | Q₁ | Q₁ |
| Lₐ₇₀₆ | O | Q₁ | Q₁ | Q₂₃ | Q₁ | S | Q₄ | Q₁ | Q₁ | Q₁ |
| Lₐ₇₀₇ | O | Q₁ | Q₂ | Q₁ | Q₁ | S | Q₆ | Q₁ | Q₁ | Q₁ |
| Lₐ₇₀₈ | O | Q₁ | Q₃ | Q₁ | Q₁ | S | Q₆ | Q₁ | Q₁ | Q₁ |
| Lₐ₇₀₉ | O | Q₁ | Q₄ | Q₁ | Q₁ | S | Q₆ | Q₁ | Q₁ | Q₁ |
| Lₐ₇₁₀ | O | Q₁ | Q₅ | Q₁ | Q₁ | S | Q₆ | Q₁ | Q₁ | Q₁ |
| Lₐ₇₁₁ | O | Q₁ | Q₆ | Q₁ | Q₁ | S | Q₆ | Q₁ | Q₁ | Q₁ |
| Lₐ₇₁₂ | O | Q₁ | Q₇ | Q₁ | Q₁ | S | Q₆ | Q₁ | Q₁ | Q₁ |
| Lₐ₇₁₃ | O | Q₁ | Q₈ | Q₁ | Q₁ | S | Q₆ | Q₁ | Q₁ | Q₁ |
| Lₐ₇₁₄ | O | Q₁ | Q₉ | Q₁ | Q₁ | S | Q₆ | Q₁ | Q₁ | Q₁ |
| Lₐ₇₁₅ | O | Q₁ | Q₁₀ | Q₁ | Q₁ | S | Q₆ | Q₁ | Q₁ | Q₁ |
| Lₐ₇₁₆ | O | Q₁ | Q₁₁ | Q₁ | Q₁ | S | Q₆ | Q₁ | Q₁ | Q₁ |
| Lₐ₇₁₇ | O | Q₁ | Q₁₂ | Q₁ | Q₁ | S | Q₆ | Q₁ | Q₁ | Q₁ |
| Lₐ₇₁₈ | O | Q₁ | Q₁₃ | Q₁ | Q₁ | S | Q₆ | Q₁ | Q₁ | Q₁ |
| Lₐ₇₁₉ | O | Q₁ | Q₁₄ | Q₁ | Q₁ | S | Q₆ | Q₁ | Q₁ | Q₁ |
| Lₐ₇₂₀ | O | Q₁ | Q₁₅ | Q₁ | Q₁ | S | Q₆ | Q₁ | Q₁ | Q₁ |
| Lₐ₇₂₁ | O | Q₁ | Q₁₆ | Q₁ | Q₁ | S | Q₆ | Q₁ | Q₁ | Q₁ |
| Lₐ₇₂₂ | O | Q₁ | Q₁₇ | Q₁ | Q₁ | S | Q₆ | Q₁ | Q₁ | Q₁ |
| Lₐ₇₂₃ | O | Q₁ | Q₁₈ | Q₁ | Q₁ | S | Q₆ | Q₁ | Q₁ | Q₁ |
| Lₐ₇₂₄ | O | Q₁ | Q₁₉ | Q₁ | Q₁ | S | Q₆ | Q₁ | Q₁ | Q₁ |
| Lₐ₇₂₅ | O | Q₁ | Q₂₀ | Q₁ | Q₁ | S | Q₆ | Q₁ | Q₁ | Q₁ |
| Lₐ₇₂₆ | O | Q₁ | Q₂₁ | Q₁ | Q₁ | S | Q₆ | Q₁ | Q₁ | Q₁ |
| Lₐ₇₂₇ | O | Q₁ | Q₂₂ | Q₁ | Q₁ | S | Q₆ | Q₁ | Q₁ | Q₁ |
| Lₐ₇₂₈ | O | Q₁ | Q₂₃ | Q₁ | Q₁ | S | Q₆ | Q₁ | Q₁ | Q₁ |
| Lₐ₇₂₉ | O | Q₁ | Q₁ | Q₂ | Q₁ | S | Q₆ | Q₁ | Q₁ | Q₁ |
| Lₐ₇₃₀ | O | Q₁ | Q₁ | Q₃ | Q₁ | S | Q₆ | Q₁ | Q₁ | Q₁ |
| Lₐ₇₃₁ | O | Q₁ | Q₁ | Q₄ | Q₁ | S | Q₆ | Q₁ | Q₁ | Q₁ |
| Lₐ₇₃₂ | O | Q₁ | Q₁ | Q₅ | Q₁ | S | Q₆ | Q₁ | Q₁ | Q₁ |
| Lₐ₇₃₃ | O | Q₁ | Q₁ | Q₆ | Q₁ | S | Q₆ | Q₁ | Q₁ | Q₁ |
| Lₐ₇₃₄ | O | Q₁ | Q₁ | Q₇ | Q₁ | S | Q₆ | Q₁ | Q₁ | Q₁ |
| Lₐ₇₃₅ | O | Q₁ | Q₁ | Q₈ | Q₁ | S | Q₆ | Q₁ | Q₁ | Q₁ |
| Lₐ₇₃₆ | O | Q₁ | Q₁ | Q₉ | Q₁ | S | Q₆ | Q₁ | Q₁ | Q₁ |
| Lₐ₇₃₇ | O | Q₁ | Q₁ | Q₁₀ | Q₁ | S | Q₆ | Q₁ | Q₁ | Q₁ |
| Lₐ₇₃₈ | O | Q₁ | Q₁ | Q₁₁ | Q₁ | S | Q₆ | Q₁ | Q₁ | Q₁ |
| Lₐ₇₃₉ | O | Q₁ | Q₁ | Q₁₂ | Q₁ | S | Q₆ | Q₁ | Q₁ | Q₁ |
| Lₐ₇₄₀ | O | Q₁ | Q₁ | Q₁₃ | Q₁ | S | Q₆ | Q₁ | Q₁ | Q₁ |
| Lₐ₇₄₁ | O | Q₁ | Q₁ | Q₁₄ | Q₁ | S | Q₆ | Q₁ | Q₁ | Q₁ |
| Lₐ₇₄₂ | O | Q₁ | Q₁ | Q₁₅ | Q₁ | S | Q₆ | Q₁ | Q₁ | Q₁ |
| Lₐ₇₄₃ | O | Q₁ | Q₁ | Q₁₆ | Q₁ | S | Q₆ | Q₁ | Q₁ | Q₁ |
| Lₐ₇₄₄ | O | Q₁ | Q₁ | Q₁₇ | Q₁ | S | Q₆ | Q₁ | Q₁ | Q₁ |
| Lₐ₇₄₅ | O | Q₁ | Q₁ | Q₁₈ | Q₁ | S | Q₆ | Q₁ | Q₁ | Q₁ |
| Lₐ₇₄₆ | O | Q₁ | Q₁ | Q₁₉ | Q₁ | S | Q₆ | Q₁ | Q₁ | Q₁ |
| Lₐ₇₄₇ | O | Q₁ | Q₁ | Q₂₀ | Q₁ | S | Q₆ | Q₁ | Q₁ | Q₁ |
| Lₐ₇₄₈ | O | Q₁ | Q₁ | Q₂₁ | Q₁ | S | Q₆ | Q₁ | Q₁ | Q₁ |
| Lₐ₇₄₉ | O | Q₁ | Q₁ | Q₂₂ | Q₁ | S | Q₆ | Q₁ | Q₁ | Q₁ |
| Lₐ₇₅₀ | O | Q₁ | Q₁ | Q₂₃ | Q₁ | S | Q₆ | Q₁ | Q₁ | Q₁ |
| Lₐ₇₅1 | O | Q₁ | Q₂ | Q₁ | Q₁ | S | Q₇ | Q₁ | Q₁ | Q₁ |
| Lₐ₇₅₂ | O | Q₁ | Q₃ | Q₁ | Q₁ | S | Q₇ | Q₁ | Q₁ | Q₁ |
| Lₐ₇₅₃ | O | Q₁ | Q₄ | Q₁ | Q₁ | S | Q₇ | Q₁ | Q₁ | Q₁ |
| Lₐ₇₅₄ | O | Q₁ | Q₅ | Q₁ | Q₁ | S | Q₇ | Q₁ | Q₁ | Q₁ |
| Lₐ₇₅₅ | O | Q₁ | Q₆ | Q₁ | Q₁ | S | Q₇ | Q₁ | Q₁ | Q₁ |
| Lₐ₇₅₆ | O | Q₁ | Q₇ | Q₁ | Q₁ | S | Q₇ | Q₁ | Q₁ | Q₁ |
| Lₐ₇₅₇ | O | Q₁ | Q₈ | Q₁ | Q₁ | S | Q₇ | Q₁ | Q₁ | Q₁ |
| Lₐ₇₅₈ | O | Q₁ | Q₉ | Q₁ | Q₁ | S | Q₇ | Q₁ | Q₁ | Q₁ |
| Lₐ₇₅₉ | O | Q₁ | Q₁₀ | Q₁ | Q₁ | S | Q₇ | Q₁ | Q₁ | Q₁ |
| Lₐ₇₆₀ | O | Q₁ | Q₁₁ | Q₁ | Q₁ | S | Q₇ | Q₁ | Q₁ | Q₁ |
| Lₐ₇₆₁ | O | Q₁ | Q₁₂ | Q₁ | Q₁ | S | Q₇ | Q₁ | Q₁ | Q₁ |
| Lₐ₇₆₂ | O | Q₁ | Q₁₃ | Q₁ | Q₁ | S | Q₇ | Q₁ | Q₁ | Q₁ |
| Lₐ₇₆₃ | O | Q₁ | Q₁₄ | Q₁ | Q₁ | S | Q₇ | Q₁ | Q₁ | Q₁ |
| Lₐ₇₆₄ | O | Q₁ | Q₁₅ | Q₁ | Q₁ | S | Q₇ | Q₁ | Q₁ | Q₁ |
| Lₐ₇₆₅ | O | Q₁ | Q₁₆ | Q₁ | Q₁ | S | Q₇ | Q₁ | Q₁ | Q₁ |
| Lₐ₇₆₆ | O | Q₁ | Q₁₇ | Q₁ | Q₁ | S | Q₇ | Q₁ | Q₁ | Q₁ |
| Lₐ₇₆₇ | O | Q₁ | Q₁₈ | Q₁ | Q₁ | S | Q₇ | Q₁ | Q₁ | Q₁ |
| Lₐ₇₆₈ | O | Q₁ | Q₁₉ | Q₁ | Q₁ | S | Q₇ | Q₁ | Q₁ | Q₁ |
| Lₐ₇₆₉ | O | Q₁ | Q₂₀ | Q₁ | Q₁ | S | Q₇ | Q₁ | Q₁ | Q₁ |
| Lₐ₇₇₀ | O | Q₁ | Q₂₁ | Q₁ | Q₁ | S | Q₇ | Q₁ | Q₁ | Q₁ |
| Lₐ₇₇₁ | O | Q₁ | Q₂₂ | Q₁ | Q₁ | S | Q₇ | Q₁ | Q₁ | Q₁ |
| Lₐ₇₇₂ | O | Q₁ | Q₂₃ | Q₁ | Q₁ | S | Q₇ | Q₁ | Q₁ | Q₁ |
| Lₐ₇₇₃ | O | Q₁ | Q₁ | Q₂ | Q₁ | S | Q₇ | Q₁ | Q₁ | Q₁ |
| Lₐ₇₇₄ | O | Q₁ | Q₁ | Q₃ | Q₁ | S | Q₇ | Q₁ | Q₁ | Q₁ |
| Lₐ₇₇₅ | O | Q₁ | Q₁ | Q₄ | Q₁ | S | Q₇ | Q₁ | Q₁ | Q₁ |
| Lₐ₇₇₆ | O | Q₁ | Q₁ | Q₅ | Q₁ | S | Q₇ | Q₁ | Q₁ | Q₁ |
| Lₐ₇₇₇ | O | Q₁ | Q₁ | Q₆ | Q₁ | S | Q₇ | Q₁ | Q₁ | Q₁ |
| Lₐ₇₇₈ | O | Q₁ | Q₁ | Q₇ | Q₁ | S | Q₇ | Q₁ | Q₁ | Q₁ |
| Lₐ₇₇₉ | O | Q₁ | Q₁ | Q₈ | Q₁ | S | Q₇ | Q₁ | Q₁ | Q₁ |
| Lₐ₇₈₀ | O | Q₁ | Q₁ | Q₉ | Q₁ | S | Q₇ | Q₁ | Q₁ | Q₁ |
| Lₐ₇₈₁ | O | Q₁ | Q₁ | Q₁₀ | Q₁ | S | Q₇ | Q₁ | Q₁ | Q₁ |
| Lₐ₇₈₂ | O | Q₁ | Q₁ | Q₁₁ | Q₁ | S | Q₇ | Q₁ | Q₁ | Q₁ |
| Lₐ₇₈₃ | O | Q₁ | Q₁ | Q₁₂ | Q₁ | S | Q₇ | Q₁ | Q₁ | Q₁ |
| Lₐ₇₈₄ | O | Q₁ | Q₁ | Q₁₃ | Q₁ | S | Q₇ | Q₁ | Q₁ | Q₁ |
| Lₐ₇₈₅ | O | Q₁ | Q₁ | Q₁₄ | Q₁ | S | Q₇ | Q₁ | Q₁ | Q₁ |
| Lₐ₇₈₆ | O | Q₁ | Q₁ | Q₁₅ | Q₁ | S | Q₇ | Q₁ | Q₁ | Q₁ |
| Lₐ₇₈₇ | O | Q₁ | Q₁ | Q₁₆ | Q₁ | S | Q₇ | Q₁ | Q₁ | Q₁ |
| Lₐ₇₈₈ | O | Q₁ | Q₁ | Q₁₇ | Q₁ | S | Q₇ | Q₁ | Q₁ | Q₁ |
| Lₐ₇₈₉ | O | Q₁ | Q₁ | Q₁₈ | Q₁ | S | Q₇ | Q₁ | Q₁ | Q₁ |
| Lₐ₇₉₀ | O | Q₁ | Q₁ | Q₁₉ | Q₁ | S | Q₇ | Q₁ | Q₁ | Q₁ |
| Lₐ₇₉₁ | O | Q₁ | Q₁ | Q₂₀ | Q₁ | S | Q₇ | Q₁ | Q₁ | Q₁ |
| Lₐ₇₉₂ | O | Q₁ | Q₁ | Q₂₁ | Q₁ | S | Q₇ | Q₁ | Q₁ | Q₁ |
| Lₐ₇₉₃ | O | Q₁ | Q₁ | Q₂₂ | Q₁ | S | Q₇ | Q₁ | Q₁ | Q₁ |
| Lₐ₇₉₄ | O | Q₁ | Q₁ | Q₂₃ | Q₁ | S | Q₇ | Q₁ | Q₁ | Q₁ |
| Lₐ₇₉₅ | O | Q₁ | Q₂ | Q₁ | Q₁ | S | Q₈ | Q₁ | Q₁ | Q₁ |
| Lₐ₇₉₆ | O | Q₁ | Q₃ | Q₁ | Q₁ | S | Q₈ | Q₁ | Q₁ | Q₁ |
| Lₐ₇₉₇ | O | Q₁ | Q₄ | Q₁ | Q₁ | S | Q₈ | Q₁ | Q₁ | Q₁ |
| Lₐ₇₉₈ | O | Q₁ | Q₅ | Q₁ | Q₁ | S | Q₈ | Q₁ | Q₁ | Q₁ |
| Lₐ₇₉₉ | O | Q₁ | Q₆ | Q₁ | Q₁ | S | Q₈ | Q₁ | Q₁ | Q₁ |
| Lₐ₈₀₀ | O | Q₁ | Q₇ | Q₁ | Q₁ | S | Q₈ | Q₁ | Q₁ | Q₁ |
| Lₐ₈₀₁ | O | Q₁ | Q₈ | Q₁ | Q₁ | S | Q₈ | Q₁ | Q₁ | Q₁ |
| Lₐ₈₀₂ | O | Q₁ | Q₉ | Q₁ | Q₁ | S | Q₈ | Q₁ | Q₁ | Q₁ |
| Lₐ₈₀₃ | O | Q₁ | Q₁₀ | Q₁ | Q₁ | S | Q₈ | Q₁ | Q₁ | Q₁ |
| Lₐ₈₀₄ | O | Q₁ | Q₁₁ | Q₁ | Q₁ | S | Q₈ | Q₁ | Q₁ | Q₁ |
| Lₐ₈₀₅ | O | Q₁ | Q₁₂ | Q₁ | Q₁ | S | Q₈ | Q₁ | Q₁ | Q₁ |
| Lₐ₈₀₆ | O | Q₁ | Q₁₃ | Q₁ | Q₁ | S | Q₈ | Q₁ | Q₁ | Q₁ |
| Lₐ₈₀₇ | O | Q₁ | Q₁₄ | Q₁ | Q₁ | S | Q₈ | Q₁ | Q₁ | Q₁ |
| Lₐ₈₀₈ | O | Q₁ | Q₁₅ | Q₁ | Q₁ | S | Q₈ | Q₁ | Q₁ | Q₁ |
| Lₐ₈₀₉ | O | Q₁ | Q₁₆ | Q₁ | Q₁ | S | Q₈ | Q₁ | Q₁ | Q₁ |
| Lₐ₈₁₀ | O | Q₁ | Q₁₇ | Q₁ | Q₁ | S | Q₈ | Q₁ | Q₁ | Q₁ |
| Lₐ₈₁₁ | O | Q₁ | Q₁₈ | Q₁ | Q₁ | S | Q₈ | Q₁ | Q₁ | Q₁ |
| Lₐ₈₁₂ | O | Q₁ | Q₁₉ | Q₁ | Q₁ | S | Q₈ | Q₁ | Q₁ | Q₁ |
| Lₐ₈₁₃ | O | Q₁ | Q₂₀ | Q₁ | Q₁ | S | Q₈ | Q₁ | Q₁ | Q₁ |
| Lₐ₈₁₄ | O | Q₁ | Q₂₁ | Q₁ | Q₁ | S | Q₈ | Q₁ | Q₁ | Q₁ |
| Lₐ₈₁₅ | O | Q₁ | Q₂₂ | Q₁ | Q₁ | S | Q₈ | Q₁ | Q₁ | Q₁ |
| Lₐ₈₁₆ | O | Q₁ | Q₂₃ | Q₁ | Q₁ | S | Q₈ | Q₁ | Q₁ | Q₁ |
| Lₐ₈₁₇ | O | Q₁ | Q₁ | Q₂ | Q₁ | S | Q₈ | Q₁ | Q₁ | Q₁ |
| Lₐ₈₁₈ | O | Q₁ | Q₁ | Q₃ | Q₁ | S | Q₈ | Q₁ | Q₁ | Q₁ |
| Lₐ₈₁₉ | O | Q₁ | Q₁ | Q₄ | Q₁ | S | Q₈ | Q₁ | Q₁ | Q₁ |
| Lₐ₈₂₀ | O | Q₁ | Q₁ | Q₅ | Q₁ | S | Q₈ | Q₁ | Q₁ | Q₁ |
| Lₐ₈₂₁ | O | Q₁ | Q₁ | Q₆ | Q₁ | S | Q₈ | Q₁ | Q₁ | Q₁ |
| Lₐ₈₂₂ | O | Q₁ | Q₁ | Q₇ | Q₁ | S | Q₈ | Q₁ | Q₁ | Q₁ |
| Lₐ₈₂₃ | O | Q₁ | Q₁ | Q₈ | Q₁ | S | Q₈ | Q₁ | Q₁ | Q₁ |
| Lₐ₈₂₄ | O | Q₁ | Q₁ | Q₉ | Q₁ | S | Q₈ | Q₁ | Q₁ | Q₁ |
| Lₐ₈₂₅ | O | Q₁ | Q₁ | Q₁₀ | Q₁ | S | Q₈ | Q₁ | Q₁ | Q₁ |
| Lₐ₈₂₆ | O | Q₁ | Q₁ | Q₁₁ | Q₁ | S | Q₈ | Q₁ | Q₁ | Q₁ |
| Lₐ₈₂₇ | O | Q₁ | Q₁ | Q₁₂ | Q₁ | S | Q₈ | Q₁ | Q₁ | Q₁ |
| Lₐ₈₂₈ | O | Q₁ | Q₁ | Q₁₃ | Q₁ | S | Q₈ | Q₁ | Q₁ | Q₁ |
| Lₐ₈₂₉ | O | Q₁ | Q₁ | Q₁₄ | Q₁ | S | Q₈ | Q₁ | Q₁ | Q₁ |
| Lₐ₈₃₀ | O | Q₁ | Q₁ | Q₁₅ | Q₁ | S | Q₈ | Q₁ | Q₁ | Q₁ |
| Lₐ₈₃₁ | O | Q₁ | Q₁ | Q₁₆ | Q₁ | S | Q₈ | Q₁ | Q₁ | Q₁ |
| Lₐ₈₃₂ | O | Q₁ | Q₁ | Q₁₇ | Q₁ | S | Q₈ | Q₁ | Q₁ | Q₁ |
| Lₐ₈₃₃ | O | Q₁ | Q₁ | Q₁₈ | Q₁ | S | Q₈ | Q₁ | Q₁ | Q₁ |
| Lₐ₈₃₄ | O | Q₁ | Q₁ | Q₁₉ | Q₁ | S | Q₈ | Q₁ | Q₁ | Q₁ |
| Lₐ₈₃₅ | O | Q₁ | Q₁ | Q₂₀ | Q₁ | S | Q₈ | Q₁ | Q₁ | Q₁ |
| Lₐ₈₃₆ | O | Q₁ | Q₁ | Q₂₁ | Q₁ | S | Q₈ | Q₁ | Q₁ | Q₁ |
| Lₐ₈₃₇ | O | Q₁ | Q₁ | Q₂₂ | Q₁ | S | Q₈ | Q₁ | Q₁ | Q₁ |
| Lₐ₈₃₈ | O | Q₁ | Q₁ | Q₂₃ | Q₁ | S | Q₈ | Q₁ | Q₁ | Q₁ |
| Lₐ₈₃₉ | O | Q₁ | Q₂ | Q₁ | Q₁ | S | Q₈ | Q₄ | Q₁ | Q₁ |
| Lₐ₈₄₀ | O | Q₁ | Q₃ | Q₁ | Q₁ | S | Q₈ | Q₄ | Q₁ | Q₁ |
| Lₐ₈₄₁ | O | Q₁ | Q₄ | Q₁ | Q₁ | S | Q₈ | Q₄ | Q₁ | Q₁ |
| Lₐ₈₄₂ | O | Q₁ | Q₅ | Q₁ | Q₁ | S | Q₈ | Q₄ | Q₁ | Q₁ |
| Lₐ₈₄₃ | O | Q₁ | Q₆ | Q₁ | Q₁ | S | Q₈ | Q₄ | Q₁ | Q₁ |
| Lₐ₈₄₄ | O | Q₁ | Q₇ | Q₁ | Q₁ | S | Q₈ | Q₄ | Q₁ | Q₁ |
| Lₐ₈₄₅ | O | Q₁ | Q₈ | Q₁ | Q₁ | S | Q₈ | Q₄ | Q₁ | Q₁ |
| Lₐ₈₄₆ | O | Q₁ | Q₉ | Q₁ | Q₁ | S | Q₈ | Q₄ | Q₁ | Q₁ |
| Lₐ₈₄₇ | O | Q₁ | Q₁₀ | Q₁ | Q₁ | S | Q₈ | Q₄ | Q₁ | Q₁ |
| Lₐ₈₄₈ | O | Q₁ | Q₁₁ | Q₁ | Q₁ | S | Q₈ | Q₄ | Q₁ | Q₁ |
| Lₐ₈₄₉ | O | Q₁ | Q₁₂ | Q₁ | Q₁ | S | Q₈ | Q₄ | Q₁ | Q₁ |
| Lₐ₈₅₀ | O | Q₁ | Q₁₃ | Q₁ | Q₁ | S | Q₈ | Q₄ | Q₁ | Q₁ |
| Lₐ₈₅₁ | O | Q₁ | Q₁₄ | Q₁ | Q₁ | S | Q₈ | Q₄ | Q₁ | Q₁ |
| Lₐ₈₅₂ | O | Q₁ | Q₁₅ | Q₁ | Q₁ | S | Q₈ | Q₄ | Q₁ | Q₁ |
| Lₐ₈₅₃ | O | Q₁ | Q₁₆ | Q₁ | Q₁ | S | Q₈ | Q₄ | Q₁ | Q₁ |
| Lₐ₈₅₄ | O | Q₁ | Q₁₇ | Q₁ | Q₁ | S | Q₈ | Q₄ | Q₁ | Q₁ |
| Lₐ₈₅₅ | O | Q₁ | Q₁₈ | Q₁ | Q₁ | S | Q₈ | Q₄ | Q₁ | Q₁ |
| Lₐ₈₅₆ | O | Q₁ | Q₁₉ | Q₁ | Q₁ | S | Q₈ | Q₄ | Q₁ | Q₁ |
| Lₐ₈₅₇ | O | Q₁ | Q₂₀ | Q₁ | Q₁ | S | Q₈ | Q₄ | Q₁ | Q₁ |
| Lₐ₈₅₈ | O | Q₁ | Q₂₁ | Q₁ | Q₁ | S | Q₈ | Q₄ | Q₁ | Q₁ |
| Lₐ₈₅₉ | O | Q₁ | Q₂₂ | Q₁ | Q₁ | S | Q₈ | Q₄ | Q₁ | Q₁ |
| Lₐ₈₆₀ | O | Q₁ | Q₂₃ | Q₁ | Q₁ | S | Q₈ | Q₄ | Q₁ | Q₁ |
| Lₐ₈₆₁ | O | Q₁ | Q₁ | Q₂ | Q₁ | S | Q₈ | Q₄ | Q₁ | Q₁ |
| Lₐ₈₆₂ | O | Q₁ | Q₁ | Q₃ | Q₁ | S | Q₈ | Q₄ | Q₁ | Q₁ |
| Lₐ₈₆₃ | O | Q₁ | Q₁ | Q₄ | Q₁ | S | Q₈ | Q₄ | Q₁ | Q₁ |
| Lₐ₈₆₄ | O | Q₁ | Q₁ | Q₅ | Q₁ | S | Q₈ | Q₄ | Q₁ | Q₁ |
| Lₐ₈₆₅ | O | Q₁ | Q₁ | Q₆ | Q₁ | S | Q₈ | Q₄ | Q₁ | Q₁ |
| Lₐ₈₆₆ | O | Q₁ | Q₁ | Q₇ | Q₁ | S | Q₈ | Q₄ | Q₁ | Q₁ |
| Lₐ₈₆₇ | O | Q₁ | Q₁ | Q₈ | Q₁ | S | Q₈ | Q₄ | Q₁ | Q₁ |
| Lₐ₈₆₈ | O | Q₁ | Q₁ | Q₉ | Q₁ | S | Q₈ | Q₄ | Q₁ | Q₁ |
| Lₐ₈₆₉ | O | Q₁ | Q₁ | Q₁₀ | Q₁ | S | Q₈ | Q₄ | Q₁ | Q₁ |
| Lₐ₈₇₀ | O | Q₁ | Q₁ | Q₁₁ | Q₁ | S | Q₈ | Q₄ | Q₁ | Q₁ |
| Lₐ₈₇₁ | O | Q₁ | Q₁ | Q₁₂ | Q₁ | S | Q₈ | Q₄ | Q₁ | Q₁ |
| Lₐ₈₇₂ | O | Q₁ | Q₁ | Q₁₃ | Q₁ | S | Q₈ | Q₄ | Q₁ | Q₁ |
| Lₐ₈₇₃ | O | Q₁ | Q₁ | Q₁₄ | Q₁ | S | Q₈ | Q₄ | Q₁ | Q₁ |
| Lₐ₈₇₄ | O | Q₁ | Q₁ | Q₁₅ | Q₁ | S | Q₈ | Q₄ | Q₁ | Q₁ |
| Lₐ₈₇₅ | O | Q₁ | Q₁ | Q₁₆ | Q₁ | S | Q₈ | Q₄ | Q₁ | Q₁ |
| Lₐ₈₇₆ | O | Q₁ | Q₁ | Q₁₇ | Q₁ | S | Q₈ | Q₄ | Q₁ | Q₁ |
| Lₐ₈₇₇ | O | Q₁ | Q₁ | Q₁₈ | Q₁ | S | Q₈ | Q₄ | Q₁ | Q₁ |
| Lₐ₈₇₈ | O | Q₁ | Q₁ | Q₁₉ | Q₁ | S | Q₈ | Q₄ | Q₁ | Q₁ |
| Lₐ₈₇₉ | O | Q₁ | Q₁ | Q₂₀ | Q₁ | S | Q₈ | Q₄ | Q₁ | Q₁ |
| Lₐ₈₈₀ | O | Q₁ | Q₁ | Q₂₁ | Q₁ | S | Q₈ | Q₄ | Q₁ | Q₁ |
| Lₐ₈₈₁ | O | Q₁ | Q₁ | Q₂₂ | Q₁ | S | Q₈ | Q₄ | Q₁ | Q₁ |
| Lₐ₈₈₂ | O | Q₁ | Q₁ | Q₂₃ | Q₁ | S | Q₈ | Q₄ | Q₁ | Q₁ |
| Lₐ₈₈₃ | O | Q₁ | Q₂ | Q₁ | Q₁ | S | Q₈ | Q₁ | Q₄ | Q₁ |
| Lₐ₈₈₄ | O | Q₁ | Q₃ | Q₁ | Q₁ | S | Q₈ | Q₁ | Q₄ | Q₁ |
| Lₐ₈₈₅ | O | Q₁ | Q₄ | Q₁ | Q₁ | S | Q₈ | Q₁ | Q₄ | Q₁ |
| Lₐ₈₈₆ | O | Q₁ | Q₅ | Q₁ | Q₁ | S | Q₈ | Q₁ | Q₄ | Q₁ |
| Lₐ₈₈₇ | O | Q₁ | Q₆ | Q₁ | Q₁ | S | Q₈ | Q₁ | Q₄ | Q₁ |
| Lₐ₈₈₈ | O | Q₁ | Q₇ | Q₁ | Q₁ | S | Q₈ | Q₁ | Q₄ | Q₁ |
| Lₐ₈₈₉ | O | Q₁ | Q₈ | Q₁ | Q₁ | S | Q₈ | Q₁ | Q₄ | Q₁ |
| Lₐ₈₉₀ | O | Q₁ | Q₉ | Q₁ | Q₁ | S | Q₈ | Q₁ | Q₄ | Q₁ |
| Lₐ₈₉₁ | O | Q₁ | Q₁₀ | Q₁ | Q₁ | S | Q₈ | Q₁ | Q₄ | Q₁ |
| Lₐ₈₉₂ | O | Q₁ | Q₁₁ | Q₁ | Q₁ | S | Q₈ | Q₁ | Q₄ | Q₁ |
| Lₐ₈₉₃ | O | Q₁ | Q₁₂ | Q₁ | Q₁ | S | Q₈ | Q₁ | Q₄ | Q₁ |
| Lₐ₈₉₄ | O | Q₁ | Q₁₃ | Q₁ | Q₁ | S | Q₈ | Q₁ | Q₄ | Q₁ |
| Lₐ₈₉₅ | O | Q₁ | Q₁₄ | Q₁ | Q₁ | S | Q₈ | Q₁ | Q₄ | Q₁ |
| Lₐ₈₉₆ | O | Q₁ | Q₁₅ | Q₁ | Q₁ | S | Q₈ | Q₁ | Q₄ | Q₁ |
| Lₐ₈₉₇ | O | Q₁ | Q₁₆ | Q₁ | Q₁ | S | Q₈ | Q₁ | Q₄ | Q₁ |
| Lₐ₈₉₈ | O | Q₁ | Q₁₇ | Q₁ | Q₁ | S | Q₈ | Q₁ | Q₄ | Q₁ |
| Lₐ₈₉₉ | O | Q₁ | Q₁₈ | Q₁ | Q₁ | S | Q₈ | Q₁ | Q₄ | Q₁ |
| Lₐ₉₀₀ | O | Q₁ | Q₁₉ | Q₁ | Q₁ | S | Q₈ | Q₁ | Q₄ | Q₁ |
| Lₐ₉₀₁ | O | Q₁ | Q₂₀ | Q₁ | Q₁ | S | Q₈ | Q₁ | Q₄ | Q₁ |
| Lₐ₉₀₂ | O | Q₁ | Q₂₁ | Q₁ | Q₁ | S | Q₈ | Q₁ | Q₄ | Q₁ |
| Lₐ₉₀₃ | O | Q₁ | Q₂₂ | Q₁ | Q₁ | S | Q₈ | Q₁ | Q₄ | Q₁ |
| Lₐ₉₀₄ | O | Q₁ | Q₂₃ | Q₁ | Q₁ | S | Q₈ | Q₁ | Q₄ | Q₁ |
| Lₐ₉₀₅ | O | Q₁ | Q₁ | Q₂ | Q₁ | S | Q₈ | Q₁ | Q₄ | Q₁ |
| Lₐ₉₀₆ | O | Q₁ | Q₁ | Q₃ | Q₁ | S | Q₈ | Q₁ | Q₄ | Q₁ |
| Lₐ₉₀₇ | O | Q₁ | Q₁ | Q₄ | Q₁ | S | Q₈ | Q₁ | Q₄ | Q₁ |
| Lₐ₉₀₈ | O | Q₁ | Q₁ | Q₅ | Q₁ | S | Q₈ | Q₁ | Q₄ | Q₁ |
| Lₐ₉₀₉ | O | Q₁ | Q₁ | Q₆ | Q₁ | S | Q₈ | Q₁ | Q₄ | Q₁ |
| Lₐ₉₁₀ | O | Q₁ | Q₁ | Q₇ | Q₁ | S | Q₈ | Q₁ | Q₄ | Q₁ |
| Lₐ₉₁₁ | O | Q₁ | Q₁ | Q₈ | Q₁ | S | Q₈ | Q₁ | Q₄ | Q₁ |
| Lₐ₉₁₂ | O | Q₁ | Q₁ | Q₉ | Q₁ | S | Q₈ | Q₁ | Q₄ | Q₁ |
| Lₐ₉₁₃ | O | Q₁ | Q₁ | Q₁₀ | Q₁ | S | Q₈ | Q₁ | Q₄ | Q₁ |
| Lₐ₉₁₄ | O | Q₁ | Q₁ | Q₁₁ | Q₁ | S | Q₈ | Q₁ | Q₄ | Q₁ |
| Lₐ₉₁₅ | O | Q₁ | Q₁ | Q₁₂ | Q₁ | S | Q₈ | Q₁ | Q₄ | Q₁ |
| Lₐ₉₁₆ | O | Q₁ | Q₁ | Q₁₃ | Q₁ | S | Q₈ | Q₁ | Q₄ | Q₁ |
| Lₐ₉₁₇ | O | Q₁ | Q₁ | Q₁₄ | Q₁ | S | Q₈ | Q₁ | Q₄ | Q₁ |
| Lₐ₉₁₈ | O | Q₁ | Q₁ | Q₁₅ | Q₁ | S | Q₈ | Q₁ | Q₄ | Q₁ |
| Lₐ₉₁₉ | O | Q₁ | Q₁ | Q₁₆ | Q₁ | S | Q₈ | Q₁ | Q₄ | Q₁ |
| Lₐ₉₂₀ | O | Q₁ | Q₁ | Q₁₇ | Q₁ | S | Q₈ | Q₁ | Q₄ | Q₁ |
| Lₐ₉₂₁ | O | Q₁ | Q₁ | Q₁₈ | Q₁ | S | Q₈ | Q₁ | Q₄ | Q₁ |
| Lₐ₉₂₂ | O | Q₁ | Q₁ | Q₁₉ | Q₁ | S | Q₈ | Q₁ | Q₄ | Q₁ |
| Lₐ₉₂₃ | O | Q₁ | Q₁ | Q₂₀ | Q₁ | S | Q₈ | Q₁ | Q₄ | Q₁ |
| Lₐ₉₂₄ | O | Q₁ | Q₁ | Q₂₁ | Q₁ | S | Q₈ | Q₁ | Q₄ | Q₁ |
| Lₐ₉₂₅ | O | Q₁ | Q₁ | Q₂₂ | Q₁ | S | Q₈ | Q₁ | Q₄ | Q₁ |
| Lₐ₉₂₆ | O | Q₁ | Q₁ | Q₂₃ | Q₁ | S | Q₈ | Q₁ | Q₄ | Q₁ |
| Lₐ₉₂₇ | O | Q₁ | Q₂ | Q₁ | Q₁ | S | Q₈ | Q₁ | Q₁ | Q₄ |
| Lₐ₉₂₈ | O | Q₁ | Q₃ | Q₁ | Q₁ | S | Q₈ | Q₁ | Q₁ | Q₄ |
| Lₐ₉₂₉ | O | Q₁ | Q₄ | Q₁ | Q₁ | S | Q₈ | Q₁ | Q₁ | Q₄ |
| Lₐ₉₃₀ | O | Q₁ | Q₅ | Q₁ | Q₁ | S | Q₈ | Q₁ | Q₁ | Q₄ |
| Lₐ₉₃₁ | O | Q₁ | Q₆ | Q₁ | Q₁ | S | Q₈ | Q₁ | Q₁ | Q₄ |
| Lₐ₉₃₂ | O | Q₁ | Q₇ | Q₁ | Q₁ | S | Q₈ | Q₁ | Q₁ | Q₄ |
| Lₐ₉₃₃ | O | Q₁ | Q₈ | Q₁ | Q₁ | S | Q₈ | Q₁ | Q₁ | Q₄ |
| Lₐ₉₃₄ | O | Q₁ | Q₉ | Q₁ | Q₁ | S | Q₈ | Q₁ | Q₁ | Q₄ |
| Lₐ₉₃₅ | O | Q₁ | Q₁₀ | Q₁ | Q₁ | S | Q₈ | Q₁ | Q₁ | Q₄ |
| Lₐ₉₃₆ | O | Q₁ | Q₁₁ | Q₁ | Q₁ | S | Q₈ | Q₁ | Q₁ | Q₄ |
| Lₐ₉₃₇ | O | Q₁ | Q₁₂ | Q₁ | Q₁ | S | Q₈ | Q₁ | Q₁ | Q₄ |
| Lₐ₉₃₈ | O | Q₁ | Q₁₃ | Q₁ | Q₁ | S | Q₈ | Q₁ | Q₁ | Q₄ |
| Lₐ₉₃₉ | O | Q₁ | Q₁₄ | Q₁ | Q₁ | S | Q₈ | Q₁ | Q₁ | Q₄ |
| Lₐ₉₄₀ | O | Q₁ | Q₁₅ | Q₁ | Q₁ | S | Q₈ | Q₁ | Q₁ | Q₄ |
| Lₐ₉₄₁ | O | Q₁ | Q₁₆ | Q₁ | Q₁ | S | Q₈ | Q₁ | Q₁ | Q₄ |
| Lₐ₉₄₂ | O | Q₁ | Q₁₇ | Q₁ | Q₁ | S | Q₈ | Q₁ | Q₁ | Q₄ |
| Lₐ₉₄₃ | O | Q₁ | Q₁₈ | Q₁ | Q₁ | S | Q₈ | Q₁ | Q₁ | Q₄ |
| Lₐ₉₄₄ | O | Q₁ | Q₁₉ | Q₁ | Q₁ | S | Q₈ | Q₁ | Q₁ | Q₄ |
| Lₐ₉₄₅ | O | Q₁ | Q₂₀ | Q₁ | Q₁ | S | Q₈ | Q₁ | Q₁ | Q₄ |
| Lₐ₉₄₆ | O | Q₁ | Q₂₁ | Q₁ | Q₁ | S | Q₈ | Q₁ | Q₁ | Q₄ |
| Lₐ₉₄₇ | O | Q₁ | Q₂₂ | Q₁ | Q₁ | S | Q₈ | Q₁ | Q₁ | Q₄ |
| Lₐ₉₄₈ | O | Q₁ | Q₂₃ | Q₁ | Q₁ | S | Q₈ | Q₁ | Q₁ | Q₄ |
| Lₐ₉₄₉ | O | Q₁ | Q₁ | Q₂ | Q₁ | S | Q₈ | Q₁ | Q₁ | Q₄ |
| Lₐ₉₅₀ | O | Q₁ | Q₁ | Q₃ | Q₁ | S | Q₈ | Q₁ | Q₁ | Q₄ |
| Lₐ₉₅₁ | O | Q₁ | Q₁ | Q₄ | Q₁ | S | Q₈ | Q₁ | Q₁ | Q₄ |
| Lₐ₉₅₂ | O | Q₁ | Q₁ | Q₅ | Q₁ | S | Q₈ | Q₁ | Q₁ | Q₄ |
| Lₐ₉₅₃ | O | Q₁ | Q₁ | Q₆ | Q₁ | S | Q₈ | Q₁ | Q₁ | Q₄ |
| Lₐ₉₅₄ | O | Q₁ | Q₁ | Q₇ | Q₁ | S | Q₈ | Q₁ | Q₁ | Q₄ |
| Lₐ₉₅₅ | O | Q₁ | Q₁ | Q₈ | Q₁ | S | Q₈ | Q₁ | Q₁ | Q₄ |
| Lₐ₉₅₆ | O | Q₁ | Q₁ | Q₉ | Q₁ | S | Q₈ | Q₁ | Q₁ | Q₄ |
| Lₐ₉₅₇ | O | Q₁ | Q₁ | Q₁₀ | Q₁ | S | Q₈ | Q₁ | Q₁ | Q₄ |
| Lₐ₉₅₈ | O | Q₁ | Q₁ | Q₁₁ | Q₁ | S | Q₈ | Q₁ | Q₁ | Q₄ |
| Lₐ₉₅₉ | O | Q₁ | Q₁ | Q₁₂ | Q₁ | S | Q₈ | Q₁ | Q₁ | Q₄ |
| Lₐ₉₆₀ | O | Q₁ | Q₁ | Q₁₃ | Q₁ | S | Q₈ | Q₁ | Q₁ | Q₄ |
| Lₐ₉₆₁ | O | Q₁ | Q₁ | Q₁₄ | Q₁ | S | Q₈ | Q₁ | Q₁ | Q₄ |
| Lₐ₉₆₂ | O | Q₁ | Q₁ | Q₁₅ | Q₁ | S | Q₈ | Q₁ | Q₁ | Q₄ |
| Lₐ₉₆₃ | O | Q₁ | Q₁ | Q₁₆ | Q₁ | S | Q₈ | Q₁ | Q₁ | Q₄ |
| Lₐ₉₆₄ | O | Q₁ | Q₁ | Q₁₇ | Q₁ | S | Q₈ | Q₁ | Q₁ | Q₄ |
| Lₐ₉₆₅ | O | Q₁ | Q₁ | Q₁₈ | Q₁ | S | Q₈ | Q₁ | Q₁ | Q₄ |
| Lₐ₉₆₆ | O | Q₁ | Q₁ | Q₁₉ | Q₁ | S | Q₈ | Q₁ | Q₁ | Q₄ |
| Lₐ₉₆₇ | O | Q₁ | Q₁ | Q₂₀ | Q₁ | S | Q₈ | Q₁ | Q₁ | Q₄ |
| Lₐ₉₆₈ | O | Q₁ | Q₁ | Q₂₁ | Q₁ | S | Q₈ | Q₁ | Q₁ | Q₄ |
| Lₐ₉₆₉ | O | Q₁ | Q₁ | Q₂₂ | Q₁ | S | Q₈ | Q₁ | Q₁ | Q₄ |
| Lₐ₉₇₀ | O | Q₁ | Q₁ | Q₂₃ | Q₁ | S | Q₈ | Q₁ | Q₁ | Q₄ |

wherein Lₐ₉₇₁ to Lₐ₁₉₄₀ each have a structure represented by Formula 46: 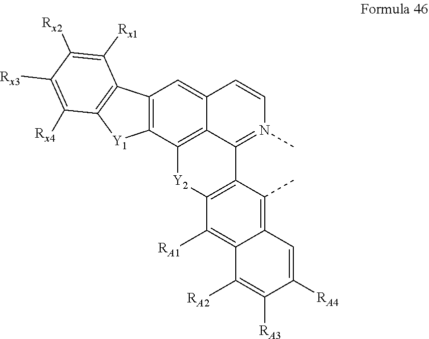
wherein Y₁, Y₂, Rₓ₁ to Rₓ₄ and R_{A1} to R_{A4} are selected from the groups listed in the following table, respectively:

| Ligand No. | Y₁ | Rₓ₁ | Rₓ₂ | Rₓ₃ | Rₓ₄ | Y₂ | R_{A1} | R_{A2} | R_{A3} | R_{A4} |
|---|---|---|---|---|---|---|---|---|---|---|
| Lₐ₉₇₁ | O | Q₁ | Q₁ | Q₁ | Q₁ | O | Q₁ | Q₁ | Q₁ | Q₁ |
| Lₐ₉₇₂ | O | Q₂ | Q₁ | Q₁ | Q₁ | O | Q₁ | Q₁ | Q₁ | Q₁ |
| Lₐ₉₇₃ | O | Q₃ | Q₁ | Q₁ | Q₁ | O | Q₁ | Q₁ | Q₁ | Q₁ |
| Lₐ₉₇₄ | O | Q₄ | Q₁ | Q₁ | Q₁ | O | Q₁ | Q₁ | Q₁ | Q₁ |
| Lₐ₉₇₅ | O | Q₅ | Q₁ | Q₁ | Q₁ | O | Q₁ | Q₁ | Q₁ | Q₁ |
| Lₐ₉₇₆ | O | Q₆ | Q₁ | Q₁ | Q₁ | O | Q₁ | Q₁ | Q₁ | Q₁ |
| Lₐ₉₇₇ | O | Q₇ | Q₁ | Q₁ | Q₁ | O | Q₁ | Q₁ | Q₁ | Q₁ |
| Lₐ₉₇₈ | O | Q₈ | Q₁ | Q₁ | Q₁ | O | Q₁ | Q₁ | Q₁ | Q₁ |
| Lₐ₉₇₉ | O | Q₉ | Q₁ | Q₁ | Q₁ | O | Q₁ | Q₁ | Q₁ | Q₁ |
| Lₐ₉₈₀ | O | Q₁₀ | Q₁ | Q₁ | Q₁ | O | Q₁ | Q₁ | Q₁ | Q₁ |
| Lₐ₉₈₁ | O | Q₁₁ | Q₁ | Q₁ | Q₁ | O | Q₁ | Q₁ | Q₁ | Q₁ |
| Lₐ₉₈₂ | O | Q₁₂ | Q₁ | Q₁ | Q₁ | O | Q₁ | Q₁ | Q₁ | Q₁ |
| Lₐ₉₈₃ | O | Q₁₃ | Q₁ | Q₁ | Q₁ | O | Q₁ | Q₁ | Q₁ | Q₁ |
| Lₐ₉₈₄ | O | Q₁₄ | Q₁ | Q₁ | Q₁ | O | Q₁ | Q₁ | Q₁ | Q₁ |
| Lₐ₉₈₅ | O | Q₁₅ | Q₁ | Q₁ | Q₁ | O | Q₁ | Q₁ | Q₁ | Q₁ |
| Lₐ₉₈₆ | O | Q₁₆ | Q₁ | Q₁ | Q₁ | O | Q₁ | Q₁ | Q₁ | Q₁ |
| Lₐ₉₈₇ | O | Q₁₇ | Q₁ | Q₁ | Q₁ | O | Q₁ | Q₁ | Q₁ | Q₁ |
| Lₐ₉₈₈ | O | Q₁₈ | Q₁ | Q₁ | Q₁ | O | Q₁ | Q₁ | Q₁ | Q₁ |
| Lₐ₉₈₉ | O | Q₁₉ | Q₁ | Q₁ | Q₁ | O | Q₁ | Q₁ | Q₁ | Q₁ |
| Lₐ₉₉₀ | O | Q₂₀ | Q₁ | Q₁ | Q₁ | O | Q₁ | Q₁ | Q₁ | Q₁ |
| Lₐ₉₉₁ | O | Q₂₁ | Q₁ | Q₁ | Q₁ | O | Q₁ | Q₁ | Q₁ | Q₁ |
| Lₐ₉₉₂ | O | Q₂₂ | Q₁ | Q₁ | Q₁ | O | Q₁ | Q₁ | Q₁ | Q₁ |
| Lₐ₉₉₃ | O | Q₂₃ | Q₁ | Q₁ | Q₁ | O | Q₁ | Q₁ | Q₁ | Q₁ |
| Lₐ₉₉₄ | O | Q₁ | Q₂ | Q₁ | Q₁ | O | Q₁ | Q₁ | Q₁ | Q₁ |
| Lₐ₉₉₅ | O | Q₁ | Q₃ | Q₁ | Q₁ | O | Q₁ | Q₁ | Q₁ | Q₁ |
| Lₐ₉₉₆ | O | Q₁ | Q₄ | Q₁ | Q₁ | O | Q₁ | Q₁ | Q₁ | Q₁ |
| Lₐ₉₉₇ | O | Q₁ | Q₅ | Q₁ | Q₁ | O | Q₁ | Q₁ | Q₁ | Q₁ |
| Lₐ₉₉₈ | O | Q₁ | Q₆ | Q₁ | Q₁ | O | Q₁ | Q₁ | Q₁ | Q₁ |
| Lₐ₉₉₉ | O | Q₁ | Q₇ | Q₁ | Q₁ | O | Q₁ | Q₁ | Q₁ | Q₁ |
| Lₐ₁₀₀₀ | O | Q₁ | Q₈ | Q₁ | Q₁ | O | Q₁ | Q₁ | Q₁ | Q₁ |
| Lₐ₁₀₀₁ | O | Q₁ | Q₉ | Q₁ | Q₁ | O | Q₁ | Q₁ | Q₁ | Q₁ |
| Lₐ₁₀₀₂ | O | Q₁ | Q₁₀ | Q₁ | Q₁ | O | Q₁ | Q₁ | Q₁ | Q₁ |
| Lₐ₁₀₀₃ | O | Q₁ | Q₁₁ | Q₁ | Q₁ | O | Q₁ | Q₁ | Q₁ | Q₁ |
| Lₐ₁₀₀₄ | O | Q₁ | Q₁₂ | Q₁ | Q₁ | O | Q₁ | Q₁ | Q₁ | Q₁ |
| Lₐ₁₀₀₅ | O | Q₁ | Q₁₃ | Q₁ | Q₁ | O | Q₁ | Q₁ | Q₁ | Q₁ |
| Lₐ₁₀₀₆ | O | Q₁ | Q₁₄ | Q₁ | Q₁ | O | Q₁ | Q₁ | Q₁ | Q₁ |
| Lₐ₁₀₀₇ | O | Q₁ | Q₁₅ | Q₁ | Q₁ | O | Q₁ | Q₁ | Q₁ | Q₁ |
| Lₐ₁₀₀₈ | O | Q₁ | Q₁₆ | Q₁ | Q₁ | O | Q₁ | Q₁ | Q₁ | Q₁ |
| Lₐ₁₀₀₉ | O | Q₁ | Q₁₇ | Q₁ | Q₁ | O | Q₁ | Q₁ | Q₁ | Q₁ |
| Lₐ₁₀₁₀ | O | Q₁ | Q₁₈ | Q₁ | Q₁ | O | Q₁ | Q₁ | Q₁ | Q₁ |
| Lₐ₁₀₁₁ | O | Q₁ | Q₁₉ | Q₁ | Q₁ | O | Q₁ | Q₁ | Q₁ | Q₁ |
| Lₐ₁₀₁₂ | O | Q₁ | Q₂₀ | Q₁ | Q₁ | O | Q₁ | Q₁ | Q₁ | Q₁ |
| Lₐ₁₀₁₃ | O | Q₁ | Q₂₁ | Q₁ | Q₁ | O | Q₁ | Q₁ | Q₁ | Q₁ |
| Lₐ₁₀₁₄ | O | Q₁ | Q₂₂ | Q₁ | Q₁ | O | Q₁ | Q₁ | Q₁ | Q₁ |
| Lₐ₁₀₁₅ | O | Q₁ | Q₂₃ | Q₁ | Q₁ | O | Q₁ | Q₁ | Q₁ | Q₁ |
| Lₐ₁₀₁₆ | O | Q₁ | Q₁ | Q₂ | Q₁ | O | Q₁ | Q₁ | Q₁ | Q₁ |
| Lₐ₁₀₁₇ | O | Q₁ | Q₁ | Q₃ | Q₁ | O | Q₁ | Q₁ | Q₁ | Q₁ |
| Lₐ₁₀₁₈ | O | Q₁ | Q₁ | Q₄ | Q₁ | O | Q₁ | Q₁ | Q₁ | Q₁ |
| Lₐ₁₀₁₉ | O | Q₁ | Q₁ | Q₅ | Q₁ | O | Q₁ | Q₁ | Q₁ | Q₁ |
| Lₐ₁₀₂₀ | O | Q₁ | Q₁ | Q₆ | Q₁ | O | Q₁ | Q₁ | Q₁ | Q₁ |
| Lₐ₁₀₂₁ | O | Q₁ | Q₁ | Q₇ | Q₁ | O | Q₁ | Q₁ | Q₁ | Q₁ |
| Lₐ₁₀₂₂ | O | Q₁ | Q₁ | Q₈ | Q₁ | O | Q₁ | Q₁ | Q₁ | Q₁ |
| Lₐ₁₀₂₃ | O | Q₁ | Q₁ | Q₉ | Q₁ | O | Q₁ | Q₁ | Q₁ | Q₁ |
| Lₐ₁₀₂₄ | O | Q₁ | Q₁ | Q₁₀ | Q₁ | O | Q₁ | Q₁ | Q₁ | Q₁ |
| Lₐ₁₀₂₅ | O | Q₁ | Q₁ | Q₁₁ | Q₁ | O | Q₁ | Q₁ | Q₁ | Q₁ |
| Lₐ₁₀₂₆ | O | Q₁ | Q₁ | Q₁₂ | Q₁ | O | Q₁ | Q₁ | Q₁ | Q₁ |
| Lₐ₁₀₂₇ | O | Q₁ | Q₁ | Q₁₃ | Q₁ | O | Q₁ | Q₁ | Q₁ | Q₁ |
| Lₐ₁₀₂₈ | O | Q₁ | Q₁ | Q₁₄ | Q₁ | O | Q₁ | Q₁ | Q₁ | Q₁ |
| Lₐ₁₀₂₉ | O | Q₁ | Q₁ | Q₁₅ | Q₁ | O | Q₁ | Q₁ | Q₁ | Q₁ |
| Lₐ₁₀₃₀ | O | Q₁ | Q₁ | Q₁₆ | Q₁ | O | Q₁ | Q₁ | Q₁ | Q₁ |
| Lₐ₁₀₃₁ | O | Q₁ | Q₁ | Q₁₇ | Q₁ | O | Q₁ | Q₁ | Q₁ | Q₁ |
| Lₐ₁₀₃₂ | O | Q₁ | Q₁ | Q₁₈ | Q₁ | O | Q₁ | Q₁ | Q₁ | Q₁ |
| Lₐ₁₀₃₃ | O | Q₁ | Q₁ | Q₁₉ | Q₁ | O | Q₁ | Q₁ | Q₁ | Q₁ |
| Lₐ₁₀₃₄ | O | Q₁ | Q₁ | Q₂₀ | Q₁ | O | Q₁ | Q₁ | Q₁ | Q₁ |
| Lₐ₁₀₃₅ | O | Q₁ | Q₁ | Q₂₁ | Q₁ | O | Q₁ | Q₁ | Q₁ | Q₁ |
| Lₐ₁₀₃₆ | O | Q₁ | Q₁ | Q₂₂ | Q₁ | O | Q₁ | Q₁ | Q₁ | Q₁ |
| Lₐ₁₀₃₇ | O | Q₁ | Q₁ | Q₂₃ | Q₁ | O | Q₁ | Q₁ | Q₁ | Q₁ |
| Lₐ₁₀₃₈ | O | Q₁ | Q₁ | Q₁ | Q₂ | O | Q₁ | Q₁ | Q₁ | Q₁ |
| Lₐ₁₀₃₉ | O | Q₁ | Q₁ | Q₁ | Q₃ | O | Q₁ | Q₁ | Q₁ | Q₁ |
| Lₐ₁₀₄₀ | O | Q₁ | Q₁ | Q₁ | Q₄ | O | Q₁ | Q₁ | Q₁ | Q₁ |
| Lₐ₁₀₄₁ | O | Q₁ | Q₁ | Q₁ | Q₅ | O | Q₁ | Q₁ | Q₁ | Q₁ |
| Lₐ₁₀₄₂ | O | Q₁ | Q₁ | Q₁ | Q₆ | O | Q₁ | Q₁ | Q₁ | Q₁ |
| Lₐ₁₀₄₃ | O | Q₁ | Q₁ | Q₁ | Q₇ | O | Q₁ | Q₁ | Q₁ | Q₁ |
| Lₐ₁₀₄₄ | O | Q₁ | Q₁ | Q₁ | Q₈ | O | Q₁ | Q₁ | Q₁ | Q₁ |
| Lₐ₁₀₄₅ | O | Q₁ | Q₁ | Q₁ | Q₉ | O | Q₁ | Q₁ | Q₁ | Q₁ |
| Lₐ₁₀₄₆ | O | Q₁ | Q₁ | Q₁ | Q₁₀ | O | Q₁ | Q₁ | Q₁ | Q₁ |
| Lₐ₁₀₄₇ | O | Q₁ | Q₁ | Q₁ | Q₁₁ | O | Q₁ | Q₁ | Q₁ | Q₁ |
| Lₐ₁₀₄₈ | O | Q₁ | Q₁ | Q₁ | Q₁₂ | O | Q₁ | Q₁ | Q₁ | Q₁ |
| Lₐ₁₀₄₉ | O | Q₁ | Q₁ | Q₁ | Q₁₃ | O | Q₁ | Q₁ | Q₁ | Q₁ |
| Lₐ₁₀₅₀ | O | Q₁ | Q₁ | Q₁ | Q₁₄ | O | Q₁ | Q₁ | Q₁ | Q₁ |
| Lₐ₁₀₅₁ | O | Q₁ | Q₁ | Q₁ | Q₁₅ | O | Q₁ | Q₁ | Q₁ | Q₁ |
| Lₐ₁₀₅₂ | O | Q₁ | Q₁ | Q₁ | Q₁₆ | O | Q₁ | Q₁ | Q₁ | Q₁ |
| Lₐ₁₀₅₃ | O | Q₁ | Q₁ | Q₁ | Q₁₇ | O | Q₁ | Q₁ | Q₁ | Q₁ |
| Lₐ₁₀₅₄ | O | Q₁ | Q₁ | Q₁ | Q₁₈ | O | Q₁ | Q₁ | Q₁ | Q₁ |
| Lₐ₁₀₅₅ | O | Q₁ | Q₁ | Q₁ | Q₁₉ | O | Q₁ | Q₁ | Q₁ | Q₁ |
| Lₐ₁₀₅₆ | O | Q₁ | Q₁ | Q₁ | Q₂₀ | O | Q₁ | Q₁ | Q₁ | Q₁ |
| Lₐ₁₀₅₇ | O | Q₁ | Q₁ | Q₁ | Q₂₁ | O | Q₁ | Q₁ | Q₁ | Q₁ |
| Lₐ₁₀₅₈ | O | Q₁ | Q₁ | Q₁ | Q₂₂ | O | Q₁ | Q₁ | Q₁ | Q₁ |
| Lₐ₁₀₅₉ | O | Q₁ | Q₁ | Q₁ | Q₂₃ | O | Q₁ | Q₁ | Q₁ | Q₁ |
| Lₐ₁₀₆₀ | O | Q₁ | Q₁ | Q₁ | Q₁ | O | Q₂ | Q₁ | Q₁ | Q₁ |
| Lₐ₁₀₆₁ | O | Q₁ | Q₁ | Q₁ | Q₁ | O | Q₃ | Q₁ | Q₁ | Q₁ |
| Lₐ₁₀₆₂ | O | Q₁ | Q₁ | Q₁ | Q₁ | O | Q₄ | Q₁ | Q₁ | Q₁ |
| Lₐ₁₀₆₃ | O | Q₁ | Q₁ | Q₁ | Q₁ | O | Q₅ | Q₁ | Q₁ | Q₁ |
| Lₐ₁₀₆₄ | O | Q₁ | Q₁ | Q₁ | Q₁ | O | Q₆ | Q₁ | Q₁ | Q₁ |
| Lₐ₁₀₆₅ | O | Q₁ | Q₁ | Q₁ | Q₁ | O | Q₇ | Q₁ | Q₁ | Q₁ |
| Lₐ₁₀₆₆ | O | Q₁ | Q₁ | Q₁ | Q₁ | O | Q₈ | Q₁ | Q₁ | Q₁ |
| Lₐ₁₀₆₇ | O | Q₁ | Q₁ | Q₁ | Q₁ | O | Q₉ | Q₁ | Q₁ | Q₁ |
| Lₐ₁₀₆₈ | O | Q₁ | Q₁ | Q₁ | Q₁ | O | Q₁₀ | Q₁ | Q₁ | Q₁ |
| Lₐ₁₀₆₉ | O | Q₁ | Q₁ | Q₁ | Q₁ | O | Q₁₁ | Q₁ | Q₁ | Q₁ |
| Lₐ₁₀₇₀ | O | Q₁ | Q₁ | Q₁ | Q₁ | O | Q₁₂ | Q₁ | Q₁ | Q₁ |
| Lₐ₁₀₇₁ | O | Q₁ | Q₁ | Q₁ | Q₁ | O | Q₁₃ | Q₁ | Q₁ | Q₁ |
| Lₐ₁₀₇₂ | O | Q₁ | Q₁ | Q₁ | Q₁ | O | Q₁₄ | Q₁ | Q₁ | Q₁ |
| Lₐ₁₀₇₃ | O | Q₁ | Q₁ | Q₁ | Q₁ | O | Q₁₅ | Q₁ | Q₁ | Q₁ |
| Lₐ₁₀₇₄ | O | Q₁ | Q₁ | Q₁ | Q₁ | O | Q₁₆ | Q₁ | Q₁ | Q₁ |
| Lₐ₁₀₇₅ | O | Q₁ | Q₁ | Q₁ | Q₁ | O | Q₁₇ | Q₁ | Q₁ | Q₁ |
| Lₐ₁₀₇₆ | O | Q₁ | Q₁ | Q₁ | Q₁ | O | Q₁₈ | Q₁ | Q₁ | Q₁ |
| Lₐ₁₀₇₇ | O | Q₁ | Q₁ | Q₁ | Q₁ | O | Q₁₉ | Q₁ | Q₁ | Q₁ |
| Lₐ₁₀₇₈ | O | Q₁ | Q₁ | Q₁ | Q₁ | O | Q₂₀ | Q₁ | Q₁ | Q₁ |
| Lₐ₁₀₇₉ | O | Q₁ | Q₁ | Q₁ | Q₁ | O | Q₂₁ | Q₁ | Q₁ | Q₁ |
| Lₐ₁₀₈₀ | O | Q₁ | Q₁ | Q₁ | Q₁ | O | Q₂₂ | Q₁ | Q₁ | Q₁ |
| Lₐ₁₀₈₁ | O | Q₁ | Q₁ | Q₁ | Q₁ | O | Q₂₃ | Q₁ | Q₁ | Q₁ |
| Lₐ₁₀₈₂ | O | Q₁ | Q₁ | Q₁ | Q₁ | O | Q₁ | Q₂ | Q₁ | Q₁ |
| Lₐ₁₀₈₃ | O | Q₁ | Q₁ | Q₁ | Q₁ | O | Q₁ | Q₃ | Q₁ | Q₁ |
| Lₐ₁₀₈₄ | O | Q₁ | Q₁ | Q₁ | Q₁ | O | Q₁ | Q₄ | Q₁ | Q₁ |
| Lₐ₁₀₈₅ | O | Q₁ | Q₁ | Q₁ | Q₁ | O | Q₁ | Q₅ | Q₁ | Q₁ |
| Lₐ₁₀₈₆ | O | Q₁ | Q₁ | Q₁ | Q₁ | O | Q₁ | Q₆ | Q₁ | Q₁ |
| Lₐ₁₀₈₇ | O | Q₁ | Q₁ | Q₁ | Q₁ | O | Q₁ | Q₇ | Q₁ | Q₁ |
| Lₐ₁₀₈₈ | O | Q₁ | Q₁ | Q₁ | Q₁ | O | Q₁ | Q₈ | Q₁ | Q₁ |
| Lₐ₁₀₈₉ | O | Q₁ | Q₁ | Q₁ | Q₁ | O | Q₁ | Q₉ | Q₁ | Q₁ |
| Lₐ₁₀₉₀ | O | Q₁ | Q₁ | Q₁ | Q₁ | O | Q₁ | Q₁₀ | Q₁ | Q₁ |
| Lₐ₁₀₉₁ | O | Q₁ | Q₁ | Q₁ | Q₁ | O | Q₁ | Q₁₁ | Q₁ | Q₁ |
| Lₐ₁₀₉₂ | O | Q₁ | Q₁ | Q₁ | Q₁ | O | Q₁ | Q₁₂ | Q₁ | Q₁ |
| Lₐ₁₀₉₃ | O | Q₁ | Q₁ | Q₁ | Q₁ | O | Q₁ | Q₁₃ | Q₁ | Q₁ |
| Lₐ₁₀₉₄ | O | Q₁ | Q₁ | Q₁ | Q₁ | O | Q₁ | Q₁₄ | Q₁ | Q₁ |
| Lₐ₁₀₉₅ | O | Q₁ | Q₁ | Q₁ | Q₁ | O | Q₁ | Q₁₅ | Q₁ | Q₁ |
| Lₐ₁₀₉₆ | O | Q₁ | Q₁ | Q₁ | Q₁ | O | Q₁ | Q₁₆ | Q₁ | Q₁ |
| Lₐ₁₀₉₇ | O | Q₁ | Q₁ | Q₁ | Q₁ | O | Q₁ | Q₁₇ | Q₁ | Q₁ |
| Lₐ₁₀₉₈ | O | Q₁ | Q₁ | Q₁ | Q₁ | O | Q₁ | Q₁₈ | Q₁ | Q₁ |
| Lₐ₁₀₉₉ | O | Q₁ | Q₁ | Q₁ | Q₁ | O | Q₁ | Q₁₉ | Q₁ | Q₁ |
| Lₐ₁₁₀₀ | O | Q₁ | Q₁ | Q₁ | Q₁ | O | Q₁ | Q₂₀ | Q₁ | Q₁ |
| Lₐ₁₁₀₁ | O | Q₁ | Q₁ | Q₁ | Q₁ | O | Q₁ | Q₂₁ | Q₁ | Q₁ |
| Lₐ₁₁₀₂ | O | Q₁ | Q₁ | Q₁ | Q₁ | O | Q₁ | Q₂₂ | Q₁ | Q₁ |
| Lₐ₁₁₀₃ | O | Q₁ | Q₁ | Q₁ | Q₁ | O | Q₁ | Q₂₃ | Q₁ | Q₁ |
| Lₐ₁₁₀₄ | O | Q₁ | Q₁ | Q₁ | Q₁ | O | Q₁ | Q₁ | Q₂ | Q₁ |
| Lₐ₁₁₀₅ | O | Q₁ | Q₁ | Q₁ | Q₁ | O | Q₁ | Q₁ | Q₃ | Q₁ |
| Lₐ₁₁₀₆ | O | Q₁ | Q₁ | Q₁ | Q₁ | O | Q₁ | Q₁ | Q₄ | Q₁ |
| Lₐ₁₁₀₇ | O | Q₁ | Q₁ | Q₁ | Q₁ | O | Q₁ | Q₁ | Q₅ | Q₁ |
| Lₐ₁₁₀₈ | O | Q₁ | Q₁ | Q₁ | Q₁ | O | Q₁ | Q₁ | Q₆ | Q₁ |
| Lₐ₁₁₀₉ | O | Q₁ | Q₁ | Q₁ | Q₁ | O | Q₁ | Q₁ | Q₇ | Q₁ |
| Lₐ₁₁₁₀ | O | Q₁ | Q₁ | Q₁ | Q₁ | O | Q₁ | Q₁ | Q₈ | Q₁ |
| Lₐ₁₁₁₁ | O | Q₁ | Q₁ | Q₁ | Q₁ | O | Q₁ | Q₁ | Q₉ | Q₁ |
| Lₐ₁₁₁₂ | O | Q₁ | Q₁ | Q₁ | Q₁ | O | Q₁ | Q₁ | Q₁₀ | Q₁ |
| Lₐ₁₁₁₃ | O | Q₁ | Q₁ | Q₁ | Q₁ | O | Q₁ | Q₁ | Q₁₁ | Q₁ |
| Lₐ₁₁₁₄ | O | Q₁ | Q₁ | Q₁ | Q₁ | O | Q₁ | Q₁ | Q₁₂ | Q₁ |
| Lₐ₁₁₁₅ | O | Q₁ | Q₁ | Q₁ | Q₁ | O | Q₁ | Q₁ | Q₁₃ | Q₁ |
| Lₐ₁₁₁₆ | O | Q₁ | Q₁ | Q₁ | Q₁ | O | Q₁ | Q₁ | Q₁₄ | Q₁ |
| Lₐ₁₁₁₇ | O | Q₁ | Q₁ | Q₁ | Q₁ | O | Q₁ | Q₁ | Q₁₅ | Q₁ |
| Lₐ₁₁₁₈ | O | Q₁ | Q₁ | Q₁ | Q₁ | O | Q₁ | Q₁ | Q₁₆ | Q₁ |
| Lₐ₁₁₁₉ | O | Q₁ | Q₁ | Q₁ | Q₁ | O | Q₁ | Q₁ | Q₁₇ | Q₁ |
| Lₐ₁₁₂₀ | O | Q₁ | Q₁ | Q₁ | Q₁ | O | Q₁ | Q₁ | Q₁₈ | Q₁ |
| Lₐ₁₁₂₁ | O | Q₁ | Q₁ | Q₁ | Q₁ | O | Q₁ | Q₁ | Q₁₉ | Q₁ |
| Lₐ₁₁₂₂ | O | Q₁ | Q₁ | Q₁ | Q₁ | O | Q₁ | Q₁ | Q₂₀ | Q₁ |
| Lₐ₁₁₂₃ | O | Q₁ | Q₁ | Q₁ | Q₁ | O | Q₁ | Q₁ | Q₂₁ | Q₁ |
| Lₐ₁₁₂₄ | O | Q₁ | Q₁ | Q₁ | Q₁ | O | Q₁ | Q₁ | Q₂₂ | Q₁ |
| Lₐ₁₁₂₅ | O | Q₁ | Q₁ | Q₁ | Q₁ | O | Q₁ | Q₁ | Q₂₃ | Q₁ |
| Lₐ₁₁₂₆ | O | Q₁ | Q₁ | Q₁ | Q₁ | O | Q₁ | Q₁ | Q₁ | Q₂ |
| Lₐ₁₁₂₇ | O | Q₁ | Q₁ | Q₁ | Q₁ | O | Q₁ | Q₁ | Q₁ | Q₃ |
| Lₐ₁₁₂₈ | O | Q₁ | Q₁ | Q₁ | Q₁ | O | Q₁ | Q₁ | Q₁ | Q₄ |
| Lₐ₁₁₂₉ | O | Q₁ | Q₁ | Q₁ | Q₁ | O | Q₁ | Q₁ | Q₁ | Q₅ |
| Lₐ₁₁₃₀ | O | Q₁ | Q₁ | Q₁ | Q₁ | O | Q₁ | Q₁ | Q₁ | Q₆ |
| Lₐ₁₁₃₁ | O | Q₁ | Q₁ | Q₁ | Q₁ | O | Q₁ | Q₁ | Q₁ | Q₇ |
| Lₐ₁₁₃₂ | O | Q₁ | Q₁ | Q₁ | Q₁ | O | Q₁ | Q₁ | Q₁ | Q₈ |
| Lₐ₁₁₃₃ | O | Q₁ | Q₁ | Q₁ | Q₁ | O | Q₁ | Q₁ | Q₁ | Q₉ |
| Lₐ₁₁₃₄ | O | Q₁ | Q₁ | Q₁ | Q₁ | O | Q₁ | Q₁ | Q₁ | Q₁₀ |
| Lₐ₁₁₃₅ | O | Q₁ | Q₁ | Q₁ | Q₁ | O | Q₁ | Q₁ | Q₁ | Q₁₁ |
| Lₐ₁₁₃₆ | O | Q₁ | Q₁ | Q₁ | Q₁ | O | Q₁ | Q₁ | Q₁ | Q₁₂ |
| Lₐ₁₁₃₇ | O | Q₁ | Q₁ | Q₁ | Q₁ | O | Q₁ | Q₁ | Q₁ | Q₁₃ |
| Lₐ₁₁₃₈ | O | Q₁ | Q₁ | Q₁ | Q₁ | O | Q₁ | Q₁ | Q₁ | Q₁₄ |
| Lₐ₁₁₃₉ | O | Q₁ | Q₁ | Q₁ | Q₁ | O | Q₁ | Q₁ | Q₁ | Q₁₅ |
| Lₐ₁₁₄₀ | O | Q₁ | Q₁ | Q₁ | Q₁ | O | Q₁ | Q₁ | Q₁ | Q₁₆ |
| Lₐ₁₁₄₁ | O | Q₁ | Q₁ | Q₁ | Q₁ | O | Q₁ | Q₁ | Q₁ | Q₁₇ |
| Lₐ₁₁₄₂ | O | Q₁ | Q₁ | Q₁ | Q₁ | O | Q₁ | Q₁ | Q₁ | Q₁₈ |
| Lₐ₁₁₄₃ | O | Q₁ | Q₁ | Q₁ | Q₁ | O | Q₁ | Q₁ | Q₁ | Q₁₉ |
| Lₐ₁₁₄₄ | O | Q₁ | Q₁ | Q₁ | Q₁ | O | Q₁ | Q₁ | Q₁ | Q₂₀ |
| Lₐ₁₁₄₅ | O | Q₁ | Q₁ | Q₁ | Q₁ | O | Q₁ | Q₁ | Q₁ | Q₂₁ |
| Lₐ₁₁₄₆ | O | Q₁ | Q₁ | Q₁ | Q₁ | O | Q₁ | Q₁ | Q₁ | Q₂₂ |
| Lₐ₁₁₄₇ | O | Q₁ | Q₁ | Q₁ | Q₁ | O | Q₁ | Q₁ | Q₁ | Q₂₃ |
| Lₐ₁₁₄₈ | O | Q₁ | Q₂ | Q₁ | Q₁ | O | Q₄ | Q₁ | Q₁ | Q₁ |
| Lₐ₁₁₄₉ | O | Q₁ | Q₃ | Q₁ | Q₁ | O | Q₄ | Q₁ | Q₁ | Q₁ |
| Lₐ₁₁₅₀ | O | Q₁ | Q₄ | Q₁ | Q₁ | O | Q₄ | Q₁ | Q₁ | Q₁ |
| Lₐ₁₁₅₁ | O | Q₁ | Q₅ | Q₁ | Q₁ | O | Q₄ | Q₁ | Q₁ | Q₁ |
| Lₐ₁₁₅₂ | O | Q₁ | Q₆ | Q₁ | Q₁ | O | Q₄ | Q₁ | Q₁ | Q₁ |
| Lₐ₁₁₅₃ | O | Q₁ | Q₇ | Q₁ | Q₁ | O | Q₄ | Q₁ | Q₁ | Q₁ |
| Lₐ₁₁₅₄ | O | Q₁ | Q₈ | Q₁ | Q₁ | O | Q₄ | Q₁ | Q₁ | Q₁ |
| Lₐ₁₁₅₅ | O | Q₁ | Q₉ | Q₁ | Q₁ | O | Q₄ | Q₁ | Q₁ | Q₁ |
| Lₐ₁₁₅₆ | O | Q₁ | Q₁₀ | Q₁ | Q₁ | O | Q₄ | Q₁ | Q₁ | Q₁ |
| Lₐ₁₁₅₇ | O | Q₁ | Q₁₁ | Q₁ | Q₁ | O | Q₄ | Q₁ | Q₁ | Q₁ |
| Lₐ₁₁₅₈ | O | Q₁ | Q₁₂ | Q₁ | Q₁ | O | Q₄ | Q₁ | Q₁ | Q₁ |
| Lₐ₁₁₅₉ | O | Q₁ | Q₁₃ | Q₁ | Q₁ | O | Q₄ | Q₁ | Q₁ | Q₁ |
| Lₐ₁₁₆₀ | O | Q₁ | Q₁₄ | Q₁ | Q₁ | O | Q₄ | Q₁ | Q₁ | Q₁ |
| Lₐ₁₁₆₁ | O | Q₁ | Q₁₅ | Q₁ | Q₁ | O | Q₄ | Q₁ | Q₁ | Q₁ |
| Lₐ₁₁₆₂ | O | Q₁ | Q₁₆ | Q₁ | Q₁ | O | Q₄ | Q₁ | Q₁ | Q₁ |
| Lₐ₁₁₆₃ | O | Q₁ | Q₁₇ | Q₁ | Q₁ | O | Q₄ | Q₁ | Q₁ | Q₁ |
| Lₐ₁₁₆₄ | O | Q₁ | Q₁₈ | Q₁ | Q₁ | O | Q₄ | Q₁ | Q₁ | Q₁ |
| Lₐ₁₁₆₅ | O | Q₁ | Q₁₉ | Q₁ | Q₁ | O | Q₄ | Q₁ | Q₁ | Q₁ |
| Lₐ₁₁₆₆ | O | Q₁ | Q₂₀ | Q₁ | Q₁ | O | Q₄ | Q₁ | Q₁ | Q₁ |
| Lₐ₁₁₆₇ | O | Q₁ | Q₂₁ | Q₁ | Q₁ | O | Q₄ | Q₁ | Q₁ | Q₁ |
| Lₐ₁₁₆₈ | O | Q₁ | Q₂₂ | Q₁ | Q₁ | O | Q₄ | Q₁ | Q₁ | Q₁ |
| Lₐ₁₁₆₉ | O | Q₁ | Q₂₃ | Q₁ | Q₁ | O | Q₄ | Q₁ | Q₁ | Q₁ |
| Lₐ₁₁₇₀ | O | Q₁ | Q₁ | Q₂ | Q₁ | O | Q₄ | Q₁ | Q₁ | Q₁ |
| Lₐ₁₁₇₁ | O | Q₁ | Q₁ | Q₃ | Q₁ | O | Q₄ | Q₁ | Q₁ | Q₁ |
| Lₐ₁₁₇₂ | O | Q₁ | Q₁ | Q₄ | Q₁ | O | Q₄ | Q₁ | Q₁ | Q₁ |
| Lₐ₁₁₇₃ | O | Q₁ | Q₁ | Q₅ | Q₁ | O | Q₄ | Q₁ | Q₁ | Q₁ |
| Lₐ₁₁₇₄ | O | Q₁ | Q₁ | Q₆ | Q₁ | O | Q₄ | Q₁ | Q₁ | Q₁ |
| Lₐ₁₁₇₅ | O | Q₁ | Q₁ | Q₇ | Q₁ | O | Q₄ | Q₁ | Q₁ | Q₁ |
| Lₐ₁₁₇₆ | O | Q₁ | Q₁ | Q₈ | Q₁ | O | Q₄ | Q₁ | Q₁ | Q₁ |
| Lₐ₁₁₇₇ | O | Q₁ | Q₁ | Q₉ | Q₁ | O | Q₄ | Q₁ | Q₁ | Q₁ |
| Lₐ₁₁₇₈ | O | Q₁ | Q₁ | Q₁₀ | Q₁ | O | Q₄ | Q₁ | Q₁ | Q₁ |
| Lₐ₁₁₇₉ | O | Q₁ | Q₁ | Q₁₁ | Q₁ | O | Q₄ | Q₁ | Q₁ | Q₁ |
| Lₐ₁₁₈₀ | O | Q₁ | Q₁ | Q₁₂ | Q₁ | O | Q₄ | Q₁ | Q₁ | Q₁ |
| Lₐ₁₁₈₁ | O | Q₁ | Q₁ | Q₁₃ | Q₁ | O | Q₄ | Q₁ | Q₁ | Q₁ |
| Lₐ₁₁₈₂ | O | Q₁ | Q₁ | Q₁₄ | Q₁ | O | Q₄ | Q₁ | Q₁ | Q₁ |
| Lₐ₁₁₈₃ | O | Q₁ | Q₁ | Q₁₅ | Q₁ | O | Q₄ | Q₁ | Q₁ | Q₁ |
| Lₐ₁₁₈₄ | O | Q₁ | Q₁ | Q₁₆ | Q₁ | O | Q₄ | Q₁ | Q₁ | Q₁ |
| Lₐ₁₁₈₅ | O | Q₁ | Q₁ | Q₁₇ | Q₁ | O | Q₄ | Q₁ | Q₁ | Q₁ |
| Lₐ₁₁₈₆ | O | Q₁ | Q₁ | Q₁₈ | Q₁ | O | Q₄ | Q₁ | Q₁ | Q₁ |
| Lₐ₁₁₈₇ | O | Q₁ | Q₁ | Q₁₉ | Q₁ | O | Q₄ | Q₁ | Q₁ | Q₁ |
| Lₐ₁₁₈₈ | O | Q₁ | Q₁ | Q₂₀ | Q₁ | O | Q₄ | Q₁ | Q₁ | Q₁ |
| Lₐ₁₁₈₉ | O | Q₁ | Q₁ | Q₂₁ | Q₁ | O | Q₄ | Q₁ | Q₁ | Q₁ |
| Lₐ₁₁₉₀ | O | Q₁ | Q₁ | Q₂₂ | Q₁ | O | Q₄ | Q₁ | Q₁ | Q₁ |
| Lₐ₁₁₉₁ | O | Q₁ | Q₁ | Q₂₃ | Q₁ | O | Q₄ | Q₁ | Q₁ | Q₁ |
| Lₐ₁₁₉₂ | O | Q₁ | Q₂ | Q₁ | Q₁ | O | Q₆ | Q₁ | Q₁ | Q₁ |
| Lₐ₁₁₉₃ | O | Q₁ | Q₃ | Q₁ | Q₁ | O | Q₆ | Q₁ | Q₁ | Q₁ |
| Lₐ₁₁₉₄ | O | Q₁ | Q₄ | Q₁ | Q₁ | O | Q₆ | Q₁ | Q₁ | Q₁ |
| Lₐ₁₁₉₅ | O | Q₁ | Q₅ | Q₁ | Q₁ | O | Q₆ | Q₁ | Q₁ | Q₁ |
| Lₐ₁₁₉₆ | O | Q₁ | Q₆ | Q₁ | Q₁ | O | Q₆ | Q₁ | Q₁ | Q₁ |
| Lₐ₁₁₉₇ | O | Q₁ | Q₇ | Q₁ | Q₁ | O | Q₆ | Q₁ | Q₁ | Q₁ |
| Lₐ₁₁₉₈ | O | Q₁ | Q₈ | Q₁ | Q₁ | O | Q₆ | Q₁ | Q₁ | Q₁ |
| Lₐ₁₁₉₉ | O | Q₁ | Q₉ | Q₁ | Q₁ | O | Q₆ | Q₁ | Q₁ | Q₁ |
| Lₐ₁₂₀₀ | O | Q₁ | Q₁₀ | Q₁ | Q₁ | O | Q₆ | Q₁ | Q₁ | Q₁ |
| Lₐ₁₂₀₁ | O | Q₁ | Q₁₁ | Q₁ | Q₁ | O | Q₆ | Q₁ | Q₁ | Q₁ |
| Lₐ₁₂₀₂ | O | Q₁ | Q₁₂ | Q₁ | Q₁ | O | Q₆ | Q₁ | Q₁ | Q₁ |
| Lₐ₁₂₀₃ | O | Q₁ | Q₁₃ | Q₁ | Q₁ | O | Q₆ | Q₁ | Q₁ | Q₁ |
| Lₐ₁₂₀₄ | O | Q₁ | Q₁₄ | Q₁ | Q₁ | O | Q₆ | Q₁ | Q₁ | Q₁ |
| Lₐ₁₂₀₅ | O | Q₁ | Q₁₅ | Q₁ | Q₁ | O | Q₆ | Q₁ | Q₁ | Q₁ |
| Lₐ₁₂₀₆ | O | Q₁ | Q₁₆ | Q₁ | Q₁ | O | Q₆ | Q₁ | Q₁ | Q₁ |
| Lₐ₁₂₀₇ | O | Q₁ | Q₁₇ | Q₁ | Q₁ | O | Q₆ | Q₁ | Q₁ | Q₁ |
| Lₐ₁₂₀₈ | O | Q₁ | Q₁₈ | Q₁ | Q₁ | O | Q₆ | Q₁ | Q₁ | Q₁ |
| Lₐ₁₂₀₉ | O | Q₁ | Q₁₉ | Q₁ | Q₁ | O | Q₆ | Q₁ | Q₁ | Q₁ |
| Lₐ₁₂₁₀ | O | Q₁ | Q₂₀ | Q₁ | Q₁ | O | Q₆ | Q₁ | Q₁ | Q₁ |
| Lₐ₁₂₁₁ | O | Q₁ | Q₂₁ | Q₁ | Q₁ | O | Q₆ | Q₁ | Q₁ | Q₁ |
| Lₐ₁₂₁₂ | O | Q₁ | Q₂₂ | Q₁ | Q₁ | O | Q₆ | Q₁ | Q₁ | Q₁ |
| Lₐ₁₂₁₃ | O | Q₁ | Q₂₃ | Q₁ | Q₁ | O | Q₆ | Q₁ | Q₁ | Q₁ |
| Lₐ₁₂₁₄ | O | Q₁ | Q₁ | Q₁ | Q₁ | O | Q₆ | Q | Q | Q₁ |
| Lₐ₁₂₁₅ | O | Q₁ | Q₁ | Q₃ | Q₁ | O | Q₆ | Q₁ | Q₁ | Q₁ |
| Lₐ₁₂₁₆ | O | Q₁ | Q₁ | Q₄ | Q₁ | O | Q₆ | Q₁ | Q₁ | Q₁ |
| Lₐ₁₂₁₇ | O | Q₁ | Q₁ | Q₅ | Q₁ | O | Q₆ | Q₁ | Q₁ | Q₁ |
| Lₐ₁₂₁₈ | O | Q₁ | Q₁ | Q₆ | Q₁ | O | Q₆ | Q₁ | Q₁ | Q₁ |
| Lₐ₁₂₁₉ | O | Q₁ | Q₁ | Q₇ | Q₁ | O | Q₆ | Q₁ | Q₁ | Q₁ |
| Lₐ₁₂₂₀ | O | Q₁ | Q₁ | Q₈ | Q₁ | O | Q₆ | Q₁ | Q₁ | Q₁ |
| Lₐ₁₂₂₁ | O | Q₁ | Q₁ | Q₉ | Q₁ | O | Q₆ | Q₁ | Q₁ | Q₁ |
| Lₐ₁₂₂₂ | O | Q₁ | Q₁ | Q₁₀ | Q₁ | O | Q₆ | Q₁ | Q₁ | Q₁ |
| Lₐ₁₂₂₃ | O | Q₁ | Q₁ | Q₁₁ | Q₁ | O | Q₆ | Q₁ | Q₁ | Q₁ |
| Lₐ₁₂₂₄ | O | Q₁ | Q₁ | Q₁₂ | Q₁ | O | Q₆ | Q₁ | Q₁ | Q₁ |
| Lₐ₁₂₂₅ | O | Q₁ | Q₁ | Q₁₃ | Q₁ | O | Q₆ | Q₁ | Q₁ | Q₁ |
| Lₐ₁₂₂₆ | O | Q₁ | Q₁ | Q₁₄ | Q₁ | O | Q₆ | Q₁ | Q₁ | Q₁ |
| Lₐ₁₂₂₇ | O | Q₁ | Q₁ | Q₁₅ | Q₁ | O | Q₆ | Q₁ | Q₁ | Q₁ |
| Lₐ₁₂₂₈ | O | Q₁ | Q₁ | Q₁₆ | Q₁ | O | Q₆ | Q₁ | Q₁ | Q₁ |
| Lₐ₁₂₂₉ | O | Q₁ | Q₁ | Q₁₇ | Q₁ | O | Q₆ | Q₁ | Q₁ | Q₁ |
| Lₐ₁₂₃₀ | O | Q₁ | Q₁ | Q₁₈ | Q₁ | O | Q₆ | Q₁ | Q₁ | Q₁ |
| Lₐ₁₂₃₁ | O | Q₁ | Q₁ | Q₁₉ | Q₁ | O | Q₆ | Q₁ | Q₁ | Q₁ |
| Lₐ₁₂₃₂ | O | Q₁ | Q₁ | Q₂₀ | Q₁ | O | Q₆ | Q₁ | Q₁ | Q₁ |
| Lₐ₁₂₃₃ | O | Q₁ | Q₁ | Q₂₁ | Q₁ | O | Q₆ | Q₁ | Q₁ | Q₁ |
| Lₐ₁₂₃₄ | O | Q₁ | Q₁ | Q₂₂ | Q₁ | O | Q₆ | Q₁ | Q₁ | Q₁ |
| Lₐ₁₂₃₅ | O | Q₁ | Q₁ | Q₂₃ | Q₁ | O | Q₆ | Q₁ | Q₁ | Q₁ |
| Lₐ₁₂₃₆ | O | Q₁ | Q₂ | Q₁ | Q₁ | O | Q₇ | Q₁ | Q₁ | Q₁ |
| Lₐ₁₂₃₇ | O | Q₁ | Q₃ | Q₁ | Q₁ | O | Q₇ | Q₁ | Q₁ | Q₁ |
| Lₐ₁₂₃₈ | O | Q₁ | Q₄ | Q₁ | Q₁ | O | Q₇ | Q₁ | Q₁ | Q₁ |
| Lₐ₁₂₃₉ | O | Q₁ | Q₅ | Q₁ | Q₁ | O | Q₇ | Q₁ | Q₁ | Q₁ |
| Lₐ₁₂₄₀ | O | Q₁ | Q₆ | Q₁ | Q₁ | O | Q₇ | Q₁ | Q₁ | Q₁ |
| Lₐ₁₂₄₁ | O | Q₁ | Q₇ | Q₁ | Q₁ | O | Q₇ | Q₁ | Q₁ | Q₁ |
| Lₐ₁₂₄₂ | O | Q₁ | Q₈ | Q₁ | Q₁ | O | Q₇ | Q₁ | Q₁ | Q₁ |
| Lₐ₁₂₄₃ | O | Q₁ | Q₉ | Q₁ | Q₁ | O | Q₇ | Q₁ | Q₁ | Q₁ |
| Lₐ₁₂₄₄ | O | Q₁ | Q₁₀ | Q₁ | Q₁ | O | Q₇ | Q₁ | Q₁ | Q₁ |
| Lₐ₁₂₄₅ | O | Q₁ | Q₁₁ | Q₁ | Q₁ | O | Q₇ | Q₁ | Q₁ | Q₁ |
| Lₐ₁₂₄₆ | O | Q₁ | Q₁₂ | Q₁ | Q₁ | O | Q₇ | Q₁ | Q₁ | Q₁ |
| Lₐ₁₂₄₇ | O | Q₁ | Q₁₃ | Q₁ | Q₁ | O | Q₇ | Q₁ | Q₁ | Q₁ |
| Lₐ₁₂₄₈ | O | Q₁ | Q₁₄ | Q₁ | Q₁ | O | Q₇ | Q₁ | Q₁ | Q₁ |
| Lₐ₁₂₄₉ | O | Q₁ | Q₁₅ | Q₁ | Q₁ | O | Q₇ | Q₁ | Q₁ | Q₁ |
| Lₐ₁₂₅₀ | O | Q₁ | Q₁₆ | Q₁ | Q₁ | O | Q₇ | Q₁ | Q₁ | Q₁ |
| Lₐ₁₂₅₁ | O | Q₁ | Q₁₇ | Q₁ | Q₁ | O | Q₇ | Q₁ | Q₁ | Q₁ |
| Lₐ₁₂₅₂ | O | Q₁ | Q₁₈ | Q₁ | Q₁ | O | Q₇ | Q₁ | Q₁ | Q₁ |
| Lₐ₁₂₅₃ | O | Q₁ | Q₁₉ | Q₁ | Q₁ | O | Q₇ | Q₁ | Q₁ | Q₁ |
| Lₐ₁₂₅₄ | O | Q₁ | Q₂₀ | Q₁ | Q₁ | O | Q₇ | Q₁ | Q₁ | Q₁ |
| Lₐ₁₂₅₅ | O | Q₁ | Q₂₁ | Q₁ | Q₁ | O | Q₇ | Q₁ | Q₁ | Q₁ |
| Lₐ₁₂₅₆ | O | Q₁ | Q₂₂ | Q₁ | Q₁ | O | Q₇ | Q₁ | Q₁ | Q₁ |
| Lₐ₁₂₅₇ | O | Q₁ | Q₂₃ | Q₁ | Q₁ | O | Q₇ | Q₁ | Q₁ | Q₁ |
| Lₐ₁₂₅₈ | O | Q₁ | Q₁ | Q₂ | Q₁ | O | Q₇ | Q₁ | Q₁ | Q₁ |
| Lₐ₁₂₅₉ | O | Q₁ | Q₁ | Q₃ | Q₁ | O | Q₇ | Q₁ | Q₁ | Q₁ |
| Lₐ₁₂₆₀ | O | Q₁ | Q₁ | Q₄ | Q₁ | O | Q₇ | Q₁ | Q₁ | Q₁ |
| Lₐ₁₂₆₁ | O | Q₁ | Q₁ | Q₅ | Q₁ | O | Q₇ | Q₁ | Q₁ | Q₁ |
| Lₐ₁₂₆₂ | O | Q₁ | Q₁ | Q₆ | Q₁ | O | Q₇ | Q₁ | Q₁ | Q₁ |
| Lₐ₁₂₆₃ | O | Q₁ | Q₁ | Q₇ | Q₁ | O | Q₇ | Q₁ | Q₁ | Q₁ |
| Lₐ₁₂₆₄ | O | Q₁ | Q₁ | Q₈ | Q₁ | O | Q₇ | Q₁ | Q₁ | Q₁ |
| Lₐ₁₂₆₅ | O | Q₁ | Q₁ | Q₉ | Q₁ | O | Q₇ | Q₁ | Q₁ | Q₁ |
| Lₐ₁₂₆₆ | O | Q₁ | Q₁ | Q₁₀ | Q₁ | O | Q₇ | Q₁ | Q₁ | Q₁ |
| Lₐ₁₂₆₇ | O | Q₁ | Q₁ | Q₁₁ | Q₁ | O | Q₇ | Q₁ | Q₁ | Q₁ |
| Lₐ₁₂₆₈ | O | Q₁ | Q₁ | Q₁₂ | Q₁ | O | Q₇ | Q₁ | Q₁ | Q₁ |
| Lₐ₁₂₆₉ | O | Q₁ | Q₁ | Q₁₃ | Q₁ | O | Q₇ | Q₁ | Q₁ | Q₁ |
| Lₐ₁₂₇₀ | O | Q₁ | Q₁ | Q₁₄ | Q₁ | O | Q₇ | Q₁ | Q₁ | Q₁ |
| Lₐ₁₂₇₁ | O | Q₁ | Q₁ | Q₁₅ | Q₁ | O | Q₇ | Q₁ | Q₁ | Q₁ |
| Lₐ₁₂₇₂ | O | Q₁ | Q₁ | Q₁₆ | Q₁ | O | Q₇ | Q₁ | Q₁ | Q₁ |
| Lₐ₁₂₇₃ | O | Q₁ | Q₁ | Q₁₇ | Q₁ | O | Q₇ | Q₁ | Q₁ | Q₁ |
| Lₐ₁₂₇₄ | O | Q₁ | Q₁ | Q₁₈ | Q₁ | O | Q₇ | Q₁ | Q₁ | Q₁ |
| Lₐ₁₂₇₅ | O | Q₁ | Q₁ | Q₁₉ | Q₁ | O | Q₇ | Q₁ | Q₁ | Q₁ |
| Lₐ₁₂₇₆ | O | Q₁ | Q₁ | Q₂₀ | Q₁ | O | Q₇ | Q₁ | Q₁ | Q₁ |
| Lₐ₁₂₇₇ | O | Q₁ | Q₁ | Q₂₁ | Q₁ | O | Q₇ | Q₁ | Q₁ | Q₁ |
| Lₐ₁₂₇₈ | O | Q₁ | Q₁ | Q₂₂ | Q₁ | O | Q₇ | Q₁ | Q₁ | Q₁ |
| Lₐ₁₂₇₉ | O | Q₁ | Q₁ | Q₂₃ | Q₁ | O | Q₇ | Q₁ | Q₁ | Q₁ |
| Lₐ₁₂₈₀ | O | Q₁ | Q₂ | Q₁ | Q₁ | O | Q₈ | Q₁ | Q₁ | Q₁ |
| Lₐ₁₂₈₁ | O | Q₁ | Q₃ | Q₁ | Q₁ | O | Q₈ | Q₁ | Q₁ | Q₁ |
| Lₐ₁₂₈₂ | O | Q₁ | Q₄ | Q₁ | Q₁ | O | Q₈ | Q₁ | Q₁ | Q₁ |
| Lₐ₁₂₈₃ | O | Q₁ | Q₅ | Q₁ | Q₁ | O | Q₈ | Q₁ | Q₁ | Q₁ |
| Lₐ₁₂₈₄ | O | Q₁ | Q₆ | Q₁ | Q₁ | O | Q₈ | Q₁ | Q₁ | Q₁ |
| Lₐ₁₂₈₅ | O | Q₁ | Q₇ | Q₁ | Q₁ | O | Q₈ | Q₁ | Q₁ | Q₁ |
| Lₐ₁₂₈₆ | O | Q₁ | Q₈ | Q₁ | Q₁ | O | Q₈ | Q₁ | Q₁ | Q₁ |
| Lₐ₁₂₈₇ | O | Q₁ | Q₉ | Q₁ | Q₁ | O | Q₈ | Q₁ | Q₁ | Q₁ |
| Lₐ₁₂₈₈ | O | Q₁ | Q₁₀ | Q₁ | Q₁ | O | Q₈ | Q₁ | Q₁ | Q₁ |
| Lₐ₁₂₈₉ | O | Q₁ | Q₁₁ | Q₁ | Q₁ | O | Q₈ | Q₁ | Q₁ | Q₁ |
| Lₐ₁₂₉₀ | O | Q₁ | Q₁₂ | Q₁ | Q₁ | O | Q₈ | Q₁ | Q₁ | Q₁ |
| Lₐ₁₂₉₁ | O | Q₁ | Q₁₃ | Q₁ | Q₁ | O | Q₈ | Q₁ | Q₁ | Q₁ |
| Lₐ₁₂₉₂ | O | Q₁ | Q₁₄ | Q₁ | Q₁ | O | Q₈ | Q₁ | Q₁ | Q₁ |
| Lₐ₁₂₉₃ | O | Q₁ | Q₁₅ | Q₁ | Q₁ | O | Q₈ | Q₁ | Q₁ | Q₁ |
| Lₐ₁₂₉₄ | O | Q₁ | Q₁₆ | Q₁ | Q₁ | O | Q₈ | Q₁ | Q₁ | Q₁ |
| Lₐ₁₂₉₅ | O | Q₁ | Q₁₇ | Q₁ | Q₁ | O | Q₈ | Q₁ | Q₁ | Q₁ |
| Lₐ₁₂₉₆ | O | Q₁ | Q₁₈ | Q₁ | Q₁ | O | Q₈ | Q₁ | Q₁ | Q₁ |
| Lₐ₁₂₉₇ | O | Q₁ | Q₁₉ | Q₁ | Q₁ | O | Q₈ | Q₁ | Q₁ | Q₁ |
| Lₐ₁₂₉₈ | O | Q₁ | Q₂₀ | Q₁ | Q₁ | O | Q₈ | Q₁ | Q₁ | Q₁ |
| Lₐ₁₂₉₉ | O | Q₁ | Q₂₁ | Q₁ | Q₁ | O | Q₈ | Q₁ | Q₁ | Q₁ |
| Lₐ₁₃₀₀ | O | Q₁ | Q₂₂ | Q₁ | Q₁ | O | Q₈ | Q₁ | Q₁ | Q₁ |
| Lₐ₁₃₀₁ | O | Q₁ | Q₂₃ | Q₁ | Q₁ | O | Q₈ | Q₁ | Q₁ | Q₁ |
| Lₐ₁₃₀₂ | O | Q₁ | Q₁ | Q₂ | Q₁ | O | Q₈ | Q₁ | Q₁ | Q₁ |
| Lₐ₁₃₀₃ | O | Q₁ | Q₁ | Q₃ | Q₁ | O | Q₈ | Q₁ | Q₁ | Q₁ |
| Lₐ₁₃₀₄ | O | Q₁ | Q₁ | Q₄ | Q₁ | O | Q₈ | Q₁ | Q₁ | Q₁ |
| Lₐ₁₃₀₅ | O | Q₁ | Q₁ | Q₅ | Q₁ | O | Q₈ | Q₁ | Q₁ | Q₁ |
| Lₐ₁₃₀₆ | O | Q₁ | Q₁ | Q₆ | Q₁ | O | Q₈ | Q₁ | Q₁ | Q₁ |
| Lₐ₁₃₀₇ | O | Q₁ | Q₁ | Q₇ | Q₁ | O | Q₈ | Q₁ | Q₁ | Q₁ |
| Lₐ₁₃₀₈ | O | Q₁ | Q₁ | Q₈ | Q₁ | O | Q₈ | Q₁ | Q₁ | Q₁ |
| Lₐ₁₃₀₉ | O | Q₁ | Q₁ | Q₉ | Q₁ | O | Q₈ | Q₁ | Q₁ | Q₁ |
| Lₐ₁₃₁₀ | O | Q₁ | Q₁ | Q₁₀ | Q₁ | O | Q₈ | Q₁ | Q₁ | Q₁ |
| Lₐ₁₃₁₁ | O | Q₁ | Q₁ | Q₁₁ | Q₁ | O | Q₈ | Q₁ | Q₁ | Q₁ |
| Lₐ₁₃₁₂ | O | Q₁ | Q₁ | Q₁₂ | Q₁ | O | Q₈ | Q₁ | Q₁ | Q₁ |
| Lₐ₁₃₁₃ | O | Q₁ | Q₁ | Q₁₃ | Q₁ | O | Q₈ | Q₁ | Q₁ | Q₁ |
| Lₐ₁₃₁₄ | O | Q₁ | Q₁ | Q₁₄ | Q₁ | O | Q₈ | Q₁ | Q₁ | Q₁ |
| Lₐ₁₃₁₅ | O | Q₁ | Q₁ | Q₁₅ | Q₁ | O | Q₈ | Q₁ | Q₁ | Q₁ |
| Lₐ₁₃₁₆ | O | Q₁ | Q₁ | Q₁₆ | Q₁ | O | Q₈ | Q₁ | Q₁ | Q₁ |
| Lₐ₁₃₁₇ | O | Q₁ | Q₁ | Q₁₇ | Q₁ | O | Q₈ | Q₁ | Q₁ | Q₁ |
| Lₐ₁₃₁₈ | O | Q₁ | Q₁ | Q₁₈ | Q₁ | O | Q₈ | Q₁ | Q₁ | Q₁ |
| Lₐ₁₃₁₉ | O | Q₁ | Q₁ | Q₁₉ | Q₁ | O | Q₈ | Q₁ | Q₁ | Q₁ |
| Lₐ₁₃₂₀ | O | Q₁ | Q₁ | Q₂₀ | Q₁ | O | Q₈ | Q₁ | Q₁ | Q₁ |
| Lₐ₁₃₂₁ | O | Q₁ | Q₁ | Q₂₁ | Q₁ | O | Q₈ | Q₁ | Q₁ | Q₁ |
| Lₐ₁₃₂₂ | O | Q₁ | Q₁ | Q₂₂ | Q₁ | O | Q₈ | Q₁ | Q₁ | Q₁ |
| Lₐ₁₃₂₃ | O | Q₁ | Q₁ | Q₂₃ | Q₁ | O | Q₈ | Q₁ | Q₁ | Q₁ |
| Lₐ₁₃₂₄ | O | Q₁ | Q₂ | Q₁ | Q₁ | O | Q₈ | Q₄ | Q₁ | Q₁ |
| Lₐ₁₃₂₅ | O | Q₁ | Q₃ | Q₁ | Q₁ | O | Q₈ | Q₄ | Q₁ | Q₁ |
| Lₐ₁₃₂₆ | O | Q₁ | Q₄ | Q₁ | Q₁ | O | Q₈ | Q₄ | Q₁ | Q₁ |
| Lₐ₁₃₂₇ | O | Q₁ | Q₅ | Q₁ | Q₁ | O | Q₈ | Q₄ | Q₁ | Q₁ |
| Lₐ₁₃₂₈ | O | Q₁ | Q₆ | Q₁ | Q₁ | O | Q₈ | Q₄ | Q₁ | Q₁ |
| Lₐ₁₃₂₉ | O | Q₁ | Q₇ | Q₁ | Q₁ | O | Q₈ | Q₄ | Q₁ | Q₁ |
| Lₐ₁₃₃₀ | O | Q₁ | Q₈ | Q₁ | Q₁ | O | Q₈ | Q₄ | Q₁ | Q₁ |
| Lₐ₁₃₃₁ | O | Q₁ | Q₉ | Q₁ | Q₁ | O | Q₈ | Q₄ | Q₁ | Q₁ |
| Lₐ₁₃₃₂ | O | Q₁ | Q₁₀ | Q₁ | Q₁ | O | Q₈ | Q₄ | Q₁ | Q₁ |
| Lₐ₁₃₃₃ | O | Q₁ | Q₁₁ | Q₁ | Q₁ | O | Q₈ | Q₄ | Q₁ | Q₁ |
| Lₐ₁₃₃₄ | O | Q₁ | Q₁₂ | Q₁ | Q₁ | O | Q₈ | Q₄ | Q₁ | Q₁ |
| Lₐ₁₃₃₅ | O | Q₁ | Q₁₃ | Q₁ | Q₁ | O | Q₈ | Q₄ | Q₁ | Q₁ |
| Lₐ₁₃₃₆ | O | Q₁ | Q₁₄ | Q₁ | Q₁ | O | Q₈ | Q₄ | Q₁ | Q₁ |
| Lₐ₁₃₃₇ | O | Q₁ | Q₁₅ | Q₁ | Q₁ | O | Q₈ | Q₄ | Q₁ | Q₁ |
| Lₐ₁₃₃₈ | O | Q₁ | Q₁₆ | Q₁ | Q₁ | O | Q₈ | Q₄ | Q₁ | Q₁ |
| Lₐ₁₃₃₉ | O | Q₁ | Q₁₇ | Q₁ | Q₁ | O | Q₈ | Q₄ | Q₁ | Q₁ |
| Lₐ₁₃₄₀ | O | Q₁ | Q₁₈ | Q₁ | Q₁ | O | Q₈ | Q₄ | Q₁ | Q₁ |
| Lₐ₁₃₄₁ | O | Q₁ | Q₁₉ | Q₁ | Q₁ | O | Q₈ | Q₄ | Q₁ | Q₁ |
| Lₐ₁₃₄₂ | O | Q₁ | Q₂₀ | Q₁ | Q₁ | O | Q₈ | Q₄ | Q₁ | Q₁ |
| Lₐ₁₃₄₃ | O | Q₁ | Q₂₁ | Q₁ | Q₁ | O | Q₈ | Q₄ | Q₁ | Q₁ |
| Lₐ₁₃₄₄ | O | Q₁ | Q₂₂ | Q₁ | Q₁ | O | Q₈ | Q₄ | Q₁ | Q₁ |
| Lₐ₁₃₄₅ | O | Q₁ | Q₂₃ | Q₁ | Q₁ | O | Q₈ | Q₄ | Q₁ | Q₁ |
| Lₐ₁₃₄₆ | O | Q₁ | Q₁ | Q₂ | Q₁ | O | Q₈ | Q₄ | Q₁ | Q₁ |
| Lₐ₁₃₄₇ | O | Q₁ | Q₁ | Q₃ | Q₁ | O | Q₈ | Q₄ | Q₁ | Q₁ |
| Lₐ₁₃₄₈ | O | Q₁ | Q₁ | Q₄ | Q₁ | O | Q₈ | Q₄ | Q₁ | Q₁ |
| Lₐ₁₃₄₉ | O | Q₁ | Q₁ | Q₅ | Q₁ | O | Q₈ | Q₄ | Q₁ | Q₁ |
| Lₐ₁₃₅₀ | O | Q₁ | Q₁ | Q₆ | Q₁ | O | Q₈ | Q₄ | Q₁ | Q₁ |
| Lₐ₁₃₅₁ | O | Q₁ | Q₁ | Q₇ | Q₁ | O | Q₈ | Q₄ | Q₁ | Q₁ |
| Lₐ₁₃₅₂ | O | Q₁ | Q₁ | Q₈ | Q₁ | O | Q₈ | Q₄ | Q₁ | Q₁ |
| Lₐ₁₃₅₃ | O | Q₁ | Q₁ | Q₉ | Q₁ | O | Q₈ | Q₄ | Q₁ | Q₁ |
| Lₐ₁₃₅₄ | O | Q₁ | Q₁ | Q₁₀ | Q₁ | O | Q₈ | Q₄ | Q₁ | Q₁ |
| Lₐ₁₃₅₅ | O | Q₁ | Q₁ | Q₁₁ | Q₁ | O | Q₈ | Q₄ | Q₁ | Q₁ |
| Lₐ₁₃₅₆ | O | Q₁ | Q₁ | Q₁₂ | Q₁ | O | Q₈ | Q₄ | Q₁ | Q₁ |
| Lₐ₁₃₅₇ | O | Q₁ | Q₁ | Q₁₃ | Q₁ | O | Q₈ | Q₄ | Q₁ | Q₁ |
| Lₐ₁₃₅₈ | O | Q₁ | Q₁ | Q₁₄ | Q₁ | O | Q₈ | Q₄ | Q₁ | Q₁ |
| Lₐ₁₃₅₉ | O | Q₁ | Q₁ | Q₁₅ | Q₁ | O | Q₈ | Q₄ | Q₁ | Q₁ |
| Lₐ₁₃₆₀ | O | Q₁ | Q₁ | Q₁₆ | Q₁ | O | Q₈ | Q₄ | Q₁ | Q₁ |
| Lₐ₁₃₆₁ | O | Q₁ | Q₁ | Q₁₇ | Q₁ | O | Q₈ | Q₄ | Q₁ | Q₁ |
| Lₐ₁₃₆₂ | O | Q₁ | Q₁ | Q₁₈ | Q₁ | O | Q₈ | Q₄ | Q₁ | Q₁ |
| Lₐ₁₃₆₃ | O | Q₁ | Q₁ | Q₁₉ | Q₁ | O | Q₈ | Q₄ | Q₁ | Q₁ |
| Lₐ₁₃₆₄ | O | Q₁ | Q₁ | Q₂₀ | Q₁ | O | Q₈ | Q₄ | Q₁ | Q₁ |
| Lₐ₁₃₆₅ | O | Q₁ | Q₁ | Q₂₁ | Q₁ | O | Q₈ | Q₄ | Q₁ | Q₁ |
| Lₐ₁₃₆₆ | O | Q₁ | Q₁ | Q₂₂ | Q₁ | O | Q₈ | Q₄ | Q₁ | Q₁ |
| Lₐ₁₃₆₇ | O | Q₁ | Q₁ | Q₂₃ | Q₁ | O | Q₈ | Q₄ | Q₁ | Q₁ |
| Lₐ₁₃₆₈ | O | Q₁ | Q₂ | Q₁ | Q₁ | O | Q₈ | Q₁ | Q₄ | Q₁ |
| Lₐ₁₃₆₉ | O | Q₁ | Q₃ | Q₁ | Q₁ | O | Q₈ | Q₁ | Q₄ | Q₁ |
| Lₐ₁₃₇₀ | O | Q₁ | Q₄ | Q₁ | Q₁ | O | Q₈ | Q₁ | Q₄ | Q₁ |
| Lₐ₁₃₇₁ | O | Q₁ | Q₅ | Q₁ | Q₁ | O | Q₈ | Q₁ | Q₄ | Q₁ |
| Lₐ₁₃₇₂ | O | Q₁ | Q₆ | Q₁ | Q₁ | O | Q₈ | Q₁ | Q₄ | Q₁ |
| Lₐ₁₃₇₃ | O | Q₁ | Q₇ | Q₁ | Q₁ | O | Q₈ | Q₁ | Q₄ | Q₁ |
| Lₐ₁₃₇₄ | O | Q₁ | Q₈ | Q₁ | Q₁ | O | Q₈ | Q₁ | Q₄ | Q₁ |
| Lₐ₁₃₇₅ | O | Q₁ | Q₉ | Q₁ | Q₁ | O | Q₈ | Q₁ | Q₄ | Q₁ |
| Lₐ₁₃₇₆ | O | Q₁ | Q₁₀ | Q₁ | Q₁ | O | Q₈ | Q₁ | Q₄ | Q₁ |
| Lₐ₁₃₇₇ | O | Q₁ | Q₁₁ | Q₁ | Q₁ | O | Q₈ | Q₁ | Q₄ | Q₁ |
| Lₐ₁₃₇₈ | O | Q₁ | Q₁₂ | Q₁ | Q₁ | O | Q₈ | Q₁ | Q₄ | Q₁ |
| Lₐ₁₃₇₉ | O | Q₁ | Q₁₃ | Q₁ | Q₁ | O | Q₈ | Q₁ | Q₄ | Q₁ |
| Lₐ₁₃₈₀ | O | Q₁ | Q₁₄ | Q₁ | Q₁ | O | Q₈ | Q₁ | Q₄ | Q₁ |
| Lₐ₁₃₈₁ | O | Q₁ | Q₁₅ | Q₁ | Q₁ | O | Q₈ | Q₁ | Q₄ | Q₁ |
| Lₐ₁₃₈₂ | O | Q₁ | Q₁₆ | Q₁ | Q₁ | O | Q₈ | Q₁ | Q₄ | Q₁ |
| Lₐ₁₃₈₃ | O | Q₁ | Q₁₇ | Q₁ | Q₁ | O | Q₈ | Q₁ | Q₄ | Q₁ |
| Lₐ₁₃₈₄ | O | Q₁ | Q₁₈ | Q₁ | Q₁ | O | Q₈ | Q₁ | Q₄ | Q₁ |
| Lₐ₁₃₈₅ | O | Q₁ | Q₁₉ | Q₁ | Q₁ | O | Q₈ | Q₁ | Q₄ | Q₁ |
| Lₐ₁₃₈₆ | O | Q₁ | Q₂₀ | Q₁ | Q₁ | O | Q₈ | Q₁ | Q₄ | Q₁ |
| Lₐ₁₃₈₇ | O | Q₁ | Q₂₁ | Q₁ | Q₁ | O | Q₈ | Q₁ | Q₄ | Q₁ |
| Lₐ₁₃₈₈ | O | Q₁ | Q₂₂ | Q₁ | Q₁ | O | Q₈ | Q₁ | Q₄ | Q₁ |
| Lₐ₁₃₈₉ | O | Q₁ | Q₂₃ | Q₁ | Q₁ | O | Q₈ | Q₁ | Q₄ | Q₁ |
| Lₐ₁₃₉₀ | O | Q₁ | Q₁ | Q₂ | Q₁ | O | Q₈ | Q₁ | Q₄ | Q₁ |
| Lₐ₁₃₉₁ | O | Q₁ | Q₁ | Q₃ | Q₁ | O | Q₈ | Q₁ | Q₄ | Q₁ |
| Lₐ₁₃₉₂ | O | Q₁ | Q₁ | Q₄ | Q₁ | O | Q₈ | Q₁ | Q₄ | Q₁ |
| Lₐ₁₃₉₃ | O | Q₁ | Q₁ | Q₅ | Q₁ | O | Q₈ | Q₁ | Q₄ | Q₁ |
| Lₐ₁₃₉₄ | O | Q₁ | Q₁ | Q₆ | Q₁ | O | Q₈ | Q₁ | Q₄ | Q₁ |
| Lₐ₁₃₉₅ | O | Q₁ | Q₁ | Q₇ | Q₁ | O | Q₈ | Q₁ | Q₄ | Q₁ |
| Lₐ₁₃₉₆ | O | Q₁ | Q₁ | Q₈ | Q₁ | O | Q₈ | Q₁ | Q₄ | Q₁ |
| Lₐ₁₃₉₇ | O | Q₁ | Q₁ | Q₉ | Q₁ | O | Q₈ | Q₁ | Q₄ | Q₁ |
| Lₐ₁₃₉₈ | O | Q₁ | Q₁ | Q₁₀ | Q₁ | O | Q₈ | Q₁ | Q₄ | Q₁ |
| Lₐ₁₃₉₉ | O | Q₁ | Q₁ | Q₁₁ | Q₁ | O | Q₈ | Q₁ | Q₄ | Q₁ |
| Lₐ₁₄₀₀ | O | Q₁ | Q₁ | Q₁₂ | Q₁ | O | Q₈ | Q₁ | Q₄ | Q₁ |
| Lₐ₁₄₀₁ | O | Q₁ | Q₁ | Q₁₃ | Q₁ | O | Q₈ | Q₁ | Q₄ | Q₁ |
| Lₐ₁₄₀₂ | O | Q₁ | Q₁ | Q₁₄ | Q₁ | O | Q₈ | Q₁ | Q₄ | Q₁ |
| Lₐ₁₄₀₃ | O | Q₁ | Q₁ | Q₁₅ | Q₁ | O | Q₈ | Q₁ | Q₄ | Q₁ |
| Lₐ₁₄₀₄ | O | Q₁ | Q₁ | Q₁₆ | Q₁ | O | Q₈ | Q₁ | Q₄ | Q₁ |
| Lₐ₁₄₀₅ | O | Q₁ | Q₁ | Q₁₇ | Q₁ | O | Q₈ | Q₁ | Q₄ | Q₁ |
| Lₐ₁₄₀₆ | O | Q₁ | Q₁ | Q₁₈ | Q₁ | O | Q₈ | Q₁ | Q₄ | Q₁ |
| Lₐ₁₄₀₇ | O | Q₁ | Q₁ | Q₁₉ | Q₁ | O | Q₈ | Q₁ | Q₄ | Q₁ |
| Lₐ₁₄₀₈ | O | Q₁ | Q₁ | Q₂₀ | Q₁ | O | Q₈ | Q₁ | Q₄ | Q₁ |
| Lₐ₁₄₀₉ | O | Q₁ | Q₁ | Q₂₁ | Q₁ | O | Q₈ | Q₁ | Q₄ | Q₁ |
| Lₐ₁₄₁₀ | O | Q₁ | Q₁ | Q₂₂ | Q₁ | O | Q₈ | Q₁ | Q₄ | Q₁ |
| Lₐ₁₄₁₁ | O | Q₁ | Q₁ | Q₂₃ | Q₁ | O | Q₈ | Q₁ | Q₄ | Q₁ |
| Lₐ₁₄₁₂ | O | Q₁ | Q₂ | Q₁ | Q₁ | O | Q₈ | Q₁ | Q₁ | Q₄ |
| Lₐ₁₄₁₃ | O | Q₁ | Q₃ | Q₁ | Q₁ | O | Q₈ | Q₁ | Q₁ | Q₄ |
| Lₐ₁₄₁₄ | O | Q₁ | Q₄ | Q₁ | Q₁ | O | Q₈ | Q₁ | Q₁ | Q₄ |
| Lₐ₁₄₁₅ | O | Q₁ | Q₅ | Q₁ | Q₁ | O | Q₈ | Q₁ | Q₁ | Q₄ |
| Lₐ₁₄₁₆ | O | Q₁ | Q₆ | Q₁ | Q₁ | O | Q₈ | Q₁ | Q₁ | Q₄ |
| Lₐ₁₄₁₇ | O | Q₁ | Q₇ | Q₁ | Q₁ | O | Q₈ | Q₁ | Q₁ | Q₄ |
| Lₐ₁₄₁₈ | O | Q₁ | Q₈ | Q₁ | Q₁ | O | Q₈ | Q₁ | Q₁ | Q₄ |
| Lₐ₁₄₁₉ | O | Q₁ | Q₉ | Q₁ | Q₁ | O | Q₈ | Q₁ | Q₁ | Q₄ |
| Lₐ₁₄₂₀ | O | Q₁ | Q₁₀ | Q₁ | Q₁ | O | Q₈ | Q₁ | Q₁ | Q₄ |
| Lₐ₁₄₂₁ | O | Q₁ | Q₁₁ | Q₁ | Q₁ | O | Q₈ | Q₁ | Q₁ | Q₄ |
| Lₐ₁₄₂₂ | O | Q₁ | Q₁₂ | Q₁ | Q₁ | O | Q₈ | Q₁ | Q₁ | Q₄ |
| Lₐ₁₄₂₃ | O | Q₁ | Q₁₃ | Q₁ | Q₁ | O | Q₈ | Q₁ | Q₁ | Q₄ |
| Lₐ₁₄₂₄ | O | Q₁ | Q₁₄ | Q₁ | Q₁ | O | Q₈ | Q₁ | Q₁ | Q₄ |
| Lₐ₁₄₂₅ | O | Q₁ | Q₁₅ | Q₁ | Q₁ | O | Q₈ | Q₁ | Q₁ | Q₄ |
| Lₐ₁₄₂₆ | O | Q₁ | Q₁₆ | Q₁ | Q₁ | O | Q₈ | Q₁ | Q₁ | Q₄ |
| Lₐ₁₄₂₇ | O | Q₁ | Q₁₇ | Q₁ | Q₁ | O | Q₈ | Q₁ | Q₁ | Q₄ |
| Lₐ₁₄₂₈ | O | Q₁ | Q₁₈ | Q₁ | Q₁ | O | Q₈ | Q₁ | Q₁ | Q₄ |
| Lₐ₁₄₂₉ | O | Q₁ | Q₁₉ | Q₁ | Q₁ | O | Q₈ | Q₁ | Q₁ | Q₄ |
| Lₐ₁₄₃₀ | O | Q₁ | Q₂₀ | Q₁ | Q₁ | O | Q₈ | Q₁ | Q₁ | Q₄ |
| Lₐ₁₄₃₁ | O | Q₁ | Q₂₁ | Q₁ | Q₁ | O | Q₈ | Q₁ | Q₁ | Q₄ |
| Lₐ₁₄₃₂ | O | Q₁ | Q₂₂ | Q₁ | Q₁ | O | Q₈ | Q₁ | Q₁ | Q₄ |
| Lₐ₁₄₃₃ | O | Q₁ | Q₂₃ | Q₁ | Q₁ | O | Q₈ | Q₁ | Q₁ | Q₄ |
| Lₐ₁₄₃₄ | O | Q₁ | Q₁ | Q₂ | Q₁ | O | Q₈ | Q₁ | Q₁ | Q₄ |
| Lₐ₁₄₃₅ | O | Q₁ | Q₁ | Q₃ | Q₁ | O | Q₈ | Q₁ | Q₁ | Q₄ |
| Lₐ₁₄₃₆ | O | Q₁ | Q₁ | Q₄ | Q₁ | O | Q₈ | Q₁ | Q₁ | Q₄ |
| Lₐ₁₄₃₇ | O | Q₁ | Q₁ | Q₅ | Q₁ | O | Q₈ | Q₁ | Q₁ | Q₄ |
| Lₐ₁₄₃₈ | O | Q₁ | Q₁ | Q₆ | Q₁ | O | Q₈ | Q₁ | Q₁ | Q₄ |
| Lₐ₁₄₃₉ | O | Q₁ | Q₁ | Q₇ | Q₁ | O | Q₈ | Q₁ | Q₁ | Q₄ |
| Lₐ₁₄₄₀ | O | Q₁ | Q₁ | Q₈ | Q₁ | O | Q₈ | Q₁ | Q₁ | Q₄ |
| Lₐ₁₄₄₁ | O | Q₁ | Q₁ | Q₉ | Q₁ | O | Q₈ | Q₁ | Q₁ | Q₄ |
| Lₐ₁₄₄₂ | O | Q₁ | Q₁ | Q₁₀ | Q₁ | O | Q₈ | Q₁ | Q₁ | Q₄ |
| Lₐ₁₄₄₃ | O | Q₁ | Q₁ | Q₁₁ | Q₁ | O | Q₈ | Q₁ | Q₁ | Q₄ |
| Lₐ₁₄₄₄ | O | Q₁ | Q₁ | Q₁₂ | Q₁ | O | Q₈ | Q₁ | Q₁ | Q₄ |
| Lₐ₁₄₄₅ | O | Q₁ | Q₁ | Q₁₃ | Q₁ | O | Q₈ | Q₁ | Q₁ | Q₄ |
| Lₐ₁₄₄₆ | O | Q₁ | Q₁ | Q₁₄ | Q₁ | O | Q₈ | Q₁ | Q₁ | Q₄ |
| Lₐ₁₄₄₇ | O | Q₁ | Q₁ | Q₁₅ | Q₁ | O | Q₈ | Q₁ | Q₁ | Q₄ |
| Lₐ₁₄₄₈ | O | Q₁ | Q₁ | Q₁₆ | Q₁ | O | Q₈ | Q₁ | Q₁ | Q₄ |
| Lₐ₁₄₄₉ | O | Q₁ | Q₁ | Q₁₇ | Q₁ | O | Q₈ | Q₁ | Q₁ | Q₄ |
| Lₐ₁₄₅₀ | O | Q₁ | Q₁ | Q₁₈ | Q₁ | O | Q₈ | Q₁ | Q₁ | Q₄ |
| Lₐ₁₄₅₁ | O | Q₁ | Q₁ | Q₁₉ | Q₁ | O | Q₈ | Q₁ | Q₁ | Q₄ |
| Lₐ₁₄₅₂ | O | Q₁ | Q₁ | Q₂₀ | Q₁ | O | Q₈ | Q₁ | Q₁ | Q₄ |
| Lₐ₁₄₅₃ | O | Q₁ | Q₁ | Q₂₁ | Q₁ | O | Q₈ | Q₁ | Q₁ | Q₄ |
| Lₐ₁₄₅₄ | O | Q₁ | Q₁ | Q₂₂ | Q₁ | O | Q₈ | Q₁ | Q₁ | Q₄ |
| Lₐ₁₄₅₅ | O | Q₁ | Q₁ | Q₂₃ | Q₁ | O | Q₈ | Q₁ | Q₁ | Q₄ |
| Lₐ₁₄₅₆ | O | Q₁ | Q₁ | Q₁ | Q₁ | S | Q₁ | Q₁ | Q₁ | Q₁ |
| Lₐ₁₄₅₇ | O | Q₂ | Q₁ | Q₁ | Q₁ | S | Q₁ | Q₁ | Q₁ | Q₁ |
| Lₐ₁₄₅₈ | O | Q₃ | Q₁ | Q₁ | Q₁ | S | Q₁ | Q₁ | Q₁ | Q₁ |
| Lₐ₁₄₅₉ | O | Q₄ | Q₁ | Q₁ | Q₁ | S | Q₁ | Q₁ | Q₁ | Q₁ |
| Lₐ₁₄₆₀ | O | Q₅ | Q₁ | Q₁ | Q₁ | S | Q₁ | Q₁ | Q₁ | Q₁ |
| Lₐ₁₄₆₁ | O | Q₆ | Q₁ | Q₁ | Q₁ | S | Q₁ | Q₁ | Q₁ | Q₁ |
| Lₐ₁₄₆₂ | O | Q₇ | Q₁ | Q₁ | Q₁ | S | Q₁ | Q₁ | Q₁ | Q₁ |
| Lₐ₁₄₆₃ | O | Q₈ | Q₁ | Q₁ | Q₁ | S | Q₁ | Q₁ | Q₁ | Q₁ |
| Lₐ₁₄₆₄ | O | Q₉ | Q₁ | Q₁ | Q₁ | S | Q₁ | Q₁ | Q₁ | Q₁ |
| Lₐ₁₄₆₅ | O | Q₁₀ | Q₁ | Q₁ | Q₁ | S | Q₁ | Q₁ | Q₁ | Q₁ |
| Lₐ₁₄₆₆ | O | Q₁₁ | Q₁ | Q₁ | Q₁ | S | Q₁ | Q₁ | Q₁ | Q₁ |
| Lₐ₁₄₆₇ | O | Q₁₂ | Q₁ | Q₁ | Q₁ | S | Q₁ | Q₁ | Q₁ | Q₁ |
| Lₐ₁₄₆₈ | O | Q₁₃ | Q₁ | Q₁ | Q₁ | S | Q₁ | Q₁ | Q₁ | Q₁ |
| Lₐ₁₄₆₉ | O | Q₁₄ | Q₁ | Q₁ | Q₁ | S | Q₁ | Q₁ | Q₁ | Q₁ |
| Lₐ₁₄₇₀ | O | Q₁₅ | Q₁ | Q₁ | Q₁ | S | Q₁ | Q₁ | Q₁ | Q₁ |
| Lₐ₁₄₇₁ | O | Q₁₆ | Q₁ | Q₁ | Q₁ | S | Q₁ | Q₁ | Q₁ | Q₁ |
| Lₐ₁₄₇₂ | O | Q₁₇ | Q₁ | Q₁ | Q₁ | S | Q₁ | Q₁ | Q₁ | Q₁ |
| Lₐ₁₄₇₃ | O | Q₁₈ | Q₁ | Q₁ | Q₁ | S | Q₁ | Q₁ | Q₁ | Q₁ |
| Lₐ₁₄₇₄ | O | Q₁₉ | Q₁ | Q₁ | Q₁ | S | Q₁ | Q₁ | Q₁ | Q₁ |
| Lₐ₁₄₇₅ | O | Q₂₀ | Q₁ | Q₁ | Q₁ | S | Q₁ | Q₁ | Q₁ | Q₁ |
| Lₐ₁₄₇₆ | O | Q₂₁ | Q₁ | Q₁ | Q₁ | S | Q₁ | Q₁ | Q₁ | Q₁ |
| Lₐ₁₄₇₇ | O | Q₂₂ | Q₁ | Q₁ | Q₁ | S | Q₁ | Q₁ | Q₁ | Q₁ |
| Lₐ₁₄₇₈ | O | Q₂₃ | Q₁ | Q₁ | Q₁ | S | Q₁ | Q₁ | Q₁ | Q₁ |
| Lₐ₁₄₇₉ | O | Q₁ | Q₂ | Q₁ | Q₁ | S | Q₁ | Q₁ | Q₁ | Q₁ |
| Lₐ₁₄₈₀ | O | Q₁ | Q₃ | Q₁ | Q₁ | S | Q₁ | Q₁ | Q₁ | Q₁ |
| Lₐ₁₄₈₁ | O | Q₁ | Q₄ | Q₁ | Q₁ | S | Q₁ | Q₁ | Q₁ | Q₁ |
| Lₐ₁₄₈₂ | O | Q₁ | Q₅ | Q₁ | Q₁ | S | Q₁ | Q₁ | Q₁ | Q₁ |
| Lₐ₁₄₈₃ | O | Q₁ | Q₆ | Q₁ | Q₁ | S | Q₁ | Q₁ | Q₁ | Q₁ |
| Lₐ₁₄₈₄ | O | Q₁ | Q₇ | Q₁ | Q₁ | S | Q₁ | Q₁ | Q₁ | Q₁ |
| Lₐ₁₄₈₅ | O | Q₁ | Q₈ | Q₁ | Q₁ | S | Q₁ | Q₁ | Q₁ | Q₁ |
| Lₐ₁₄₈₆ | O | Q₁ | Q₉ | Q₁ | Q₁ | S | Q₁ | Q₁ | Q₁ | Q₁ |
| Lₐ₁₄₈₇ | O | Q₁ | Q₁₀ | Q₁ | Q₁ | S | Q₁ | Q₁ | Q₁ | Q₁ |
| Lₐ₁₄₈₈ | O | Q₁ | Q₁₁ | Q₁ | Q₁ | S | Q₁ | Q₁ | Q₁ | Q₁ |
| Lₐ₁₄₈₉ | O | Q₁ | Q₁₂ | Q₁ | Q₁ | S | Q₁ | Q₁ | Q₁ | Q₁ |
| Lₐ₁₄₉₀ | O | Q₁ | Q₁₃ | Q₁ | Q₁ | S | Q₁ | Q₁ | Q₁ | Q₁ |
| Lₐ₁₄₉₁ | O | Q₁ | Q₁₄ | Q₁ | Q₁ | S | Q₁ | Q₁ | Q₁ | Q₁ |
| Lₐ₁₄₉₂ | O | Q₁ | Q₁₅ | Q₁ | Q₁ | S | Q₁ | Q₁ | Q₁ | Q₁ |
| Lₐ₁₄₉₃ | O | Q₁ | Q₁₆ | Q₁ | Q₁ | S | Q₁ | Q₁ | Q₁ | Q₁ |
| Lₐ₁₄₉₄ | O | Q₁ | Q₁₇ | Q₁ | Q₁ | S | Q₁ | Q₁ | Q₁ | Q₁ |
| Lₐ₁₄₉₅ | O | Q₁ | Q₁₈ | Q₁ | Q₁ | S | Q₁ | Q₁ | Q₁ | Q₁ |
| Lₐ₁₄₉₆ | O | Q₁ | Q₁₉ | Q₁ | Q₁ | S | Q₁ | Q₁ | Q₁ | Q₁ |
| Lₐ₁₄₉₇ | O | Q₁ | Q₂₀ | Q₁ | Q₁ | S | Q₁ | Q₁ | Q₁ | Q₁ |
| Lₐ₁₄₉₈ | O | Q₁ | Q₂₁ | Q₁ | Q₁ | S | Q₁ | Q₁ | Q₁ | Q₁ |
| Lₐ₁₄₉₉ | O | Q₁ | Q₂₂ | Q₁ | Q₁ | S | Q₁ | Q₁ | Q₁ | Q₁ |
| Lₐ₁₅₀₀ | O | Q₁ | Q₂₃ | Q₁ | Q₁ | S | Q₁ | Q₁ | Q₁ | Q₁ |
| Lₐ₁₅₀₁ | O | Q₁ | Q₁ | Q₂ | Q₁ | S | Q₁ | Q₁ | Q₁ | Q₁ |
| Lₐ₁₅₀₂ | O | Q₁ | Q₁ | Q₃ | Q₁ | S | Q₁ | Q₁ | Q₁ | Q₁ |
| Lₐ₁₅₀₃ | O | Q₁ | Q₁ | Q₄ | Q₁ | S | Q₁ | Q₁ | Q₁ | Q₁ |
| Lₐ₁₅₀₄ | O | Q₁ | Q₁ | Q₅ | Q₁ | S | Q₁ | Q₁ | Q₁ | Q₁ |
| Lₐ₁₅₀₅ | O | Q₁ | Q₁ | Q₆ | Q₁ | S | Q₁ | Q₁ | Q₁ | Q₁ |
| Lₐ₁₅₀₆ | O | Q₁ | Q₁ | Q₇ | Q₁ | S | Q₁ | Q₁ | Q₁ | Q₁ |
| Lₐ₁₅₀₇ | O | Q₁ | Q₁ | Q₈ | Q₁ | S | Q₁ | Q₁ | Q₁ | Q₁ |
| Lₐ₁₅₀₈ | O | Q₁ | Q₁ | Q₉ | Q₁ | S | Q₁ | Q₁ | Q₁ | Q₁ |
| Lₐ₁₅₀₉ | O | Q₁ | Q₁ | Q₁₀ | Q₁ | S | Q₁ | Q₁ | Q₁ | Q₁ |
| Lₐ₁₅₁₀ | O | Q₁ | Q₁ | Q₁₁ | Q₁ | S | Q₁ | Q₁ | Q₁ | Q₁ |
| Lₐ₁₅₁₁ | O | Q₁ | Q₁ | Q₁₂ | Q₁ | S | Q₁ | Q₁ | Q₁ | Q₁ |
| Lₐ₁₅₁₂ | O | Q₁ | Q₁ | Q₁₃ | Q₁ | S | Q₁ | Q₁ | Q₁ | Q₁ |
| Lₐ₁₅₁₃ | O | Q₁ | Q₁ | Q₁₄ | Q₁ | S | Q₁ | Q₁ | Q₁ | Q₁ |
| Lₐ₁₅₁₄ | O | Q₁ | Q₁ | Q₁₅ | Q₁ | S | Q₁ | Q₁ | Q₁ | Q₁ |
| Lₐ₁₅₁₅ | O | Q₁ | Q₁ | Q₁₆ | Q₁ | S | Q₁ | Q₁ | Q₁ | Q₁ |
| Lₐ₁₅₁₆ | O | Q₁ | Q₁ | Q₁₇ | Q₁ | S | Q₁ | Q₁ | Q₁ | Q₁ |
| Lₐ₁₅₁₇ | O | Q₁ | Q₁ | Q₁₈ | Q₁ | S | Q₁ | Q₁ | Q₁ | Q₁ |
| Lₐ₁₅₁₈ | O | Q₁ | Q₁ | Q₁₉ | Q₁ | S | Q₁ | Q₁ | Q₁ | Q₁ |
| Lₐ₁₅₁₉ | O | Q₁ | Q₁ | Q₂₀ | Q₁ | S | Q₁ | Q₁ | Q₁ | Q₁ |
| Lₐ₁₅₂₀ | O | Q₁ | Q₁ | Q₂₁ | Q₁ | S | Q₁ | Q₁ | Q₁ | Q₁ |
| Lₐ₁₅₂₁ | O | Q₁ | Q₁ | Q₂₂ | Q₁ | S | Q₁ | Q₁ | Q₁ | Q₁ |
| Lₐ₁₅₂₂ | O | Q₁ | Q₁ | Q₂₃ | Q₁ | S | Q₁ | Q₁ | Q₁ | Q₁ |
| Lₐ₁₅₂₃ | O | Q₁ | Q₁ | Q₁ | Q₂ | S | Q₁ | Q₁ | Q₁ | Q₁ |
| Lₐ₁₅₂₄ | O | Q₁ | Q₁ | Q₁ | Q₃ | S | Q₁ | Q₁ | Q₁ | Q₁ |
| Lₐ₁₅₂₅ | O | Q₁ | Q₁ | Q₁ | Q₄ | S | Q₁ | Q₁ | Q₁ | Q₁ |
| Lₐ₁₅₂₆ | O | Q₁ | Q₁ | Q₁ | Q₅ | S | Q₁ | Q₁ | Q₁ | Q₁ |
| Lₐ₁₅₂₇ | O | Q₁ | Q₁ | Q₁ | Q₆ | S | Q₁ | Q₁ | Q₁ | Q₁ |
| Lₐ₁₅₂₈ | O | Q₁ | Q₁ | Q₁ | Q₇ | S | Q₁ | Q₁ | Q₁ | Q₁ |
| Lₐ₁₅₂₉ | O | Q₁ | Q₁ | Q₁ | Q₈ | S | Q₁ | Q₁ | Q₁ | Q₁ |
| Lₐ₁₅₃₀ | O | Q₁ | Q₁ | Q₁ | Q₉ | S | Q₁ | Q₁ | Q₁ | Q₁ |
| Lₐ₁₅₃₁ | O | Q₁ | Q₁ | Q₁ | Q₁₀ | S | Q₁ | Q₁ | Q₁ | Q₁ |
| Lₐ₁₅₃₂ | O | Q₁ | Q₁ | Q₁ | Q₁₁ | S | Q₁ | Q₁ | Q₁ | Q₁ |
| Lₐ₁₅₃₃ | O | Q₁ | Q₁ | Q₁ | Q₁₂ | S | Q₁ | Q₁ | Q₁ | Q₁ |
| Lₐ₁₅₃₄ | O | Q₁ | Q₁ | Q₁ | Q₁₃ | S | Q₁ | Q₁ | Q₁ | Q₁ |
| Lₐ₁₅₃₅ | O | Q₁ | Q₁ | Q₁ | Q₁₄ | S | Q₁ | Q₁ | Q₁ | Q₁ |
| Lₐ₁₅₃₆ | O | Q₁ | Q₁ | Q₁ | Q₁₅ | S | Q₁ | Q₁ | Q₁ | Q₁ |
| Lₐ₁₅₃₇ | O | Q₁ | Q₁ | Q₁ | Q₁₆ | S | Q₁ | Q₁ | Q₁ | Q₁ |
| Lₐ₁₅₃₈ | O | Q₁ | Q₁ | Q₁ | Q₁₇ | S | Q₁ | Q₁ | Q₁ | Q₁ |
| Lₐ₁₅₃₉ | O | Q₁ | Q₁ | Q₁ | Q₁₈ | S | Q₁ | Q₁ | Q₁ | Q₁ |
| Lₐ₁₅₄₀ | O | Q₁ | Q₁ | Q₁ | Q₁₉ | S | Q₁ | Q₁ | Q₁ | Q₁ |
| Lₐ₁₅₄₁ | O | Q₁ | Q₁ | Q₁ | Q₂₀ | S | Q₁ | Q₁ | Q₁ | Q₁ |
| Lₐ₁₅₄₂ | O | Q₁ | Q₁ | Q₁ | Q₂₁ | S | Q₁ | Q₁ | Q₁ | Q₁ |
| Lₐ₁₅₄₃ | O | Q₁ | Q₁ | Q₁ | Q₂₂ | S | Q₁ | Q₁ | Q₁ | Q₁ |
| Lₐ₁₅₄₄ | O | Q₁ | Q₁ | Q₁ | Q₂₃ | S | Q₁ | Q₁ | Q₁ | Q₁ |
| Lₐ₁₅₄₅ | O | Q₁ | Q₁ | Q₁ | Q₁ | S | Q₂ | Q₁ | Q₁ | Q₁ |
| Lₐ₁₅₄₆ | O | Q₁ | Q₁ | Q₁ | Q₁ | S | Q₃ | Q₁ | Q₁ | Q₁ |
| Lₐ₁₅₄₇ | O | Q₁ | Q₁ | Q₁ | Q₁ | S | Q₄ | Q₁ | Q₁ | Q₁ |
| Lₐ₁₅₄₈ | O | Q₁ | Q₁ | Q₁ | Q₁ | S | Q₅ | Q₁ | Q₁ | Q₁ |
| Lₐ₁₅₄₉ | O | Q₁ | Q₁ | Q₁ | Q₁ | S | Q₆ | Q₁ | Q₁ | Q₁ |
| Lₐ₁₅₅₀ | O | Q₁ | Q₁ | Q₁ | Q₁ | S | Q₇ | Q₁ | Q₁ | Q₁ |
| Lₐ₁₅₅₁ | O | Q₁ | Q₁ | Q₁ | Q₁ | S | Q₈ | Q₁ | Q₁ | Q₁ |
| Lₐ₁₅₅₂ | O | Q₁ | Q₁ | Q₁ | Q₁ | S | Q₉ | Q₁ | Q₁ | Q₁ |
| Lₐ₁₅₅₃ | O | Q₁ | Q₁ | Q₁ | Q₁ | S | Q₁₀ | Q₁ | Q₁ | Q₁ |
| Lₐ₁₅₅₄ | O | Q₁ | Q₁ | Q₁ | Q₁ | S | Q₁₁ | Q₁ | Q₁ | Q₁ |
| Lₐ₁₅₅₅ | O | Q₁ | Q₁ | Q₁ | Q₁ | S | Q₁₂ | Q₁ | Q₁ | Q₁ |
| Lₐ₁₅₅₆ | O | Q₁ | Q₁ | Q₁ | Q₁ | S | Q₁₃ | Q₁ | Q₁ | Q₁ |
| Lₐ₁₅₅₇ | O | Q₁ | Q₁ | Q₁ | Q₁ | S | Q₁₄ | Q₁ | Q₁ | Q₁ |
| Lₐ₁₅₅₈ | O | Q₁ | Q₁ | Q₁ | Q₁ | S | Q₁₅ | Q₁ | Q₁ | Q₁ |
| Lₐ₁₅₅₉ | O | Q₁ | Q₁ | Q₁ | Q₁ | S | Q₁₆ | Q₁ | Q₁ | Q₁ |
| Lₐ₁₅₆₀ | O | Q₁ | Q₁ | Q₁ | Q₁ | S | Q₁₇ | Q₁ | Q₁ | Q₁ |
| Lₐ₁₅₆₁ | O | Q₁ | Q₁ | Q₁ | Q₁ | S | Q₁₈ | Q₁ | Q₁ | Q₁ |
| Lₐ₁₅₆₂ | O | Q₁ | Q₁ | Q₁ | Q₁ | S | Q₁₉ | Q₁ | Q₁ | Q₁ |
| Lₐ₁₅₆₃ | O | Q₁ | Q₁ | Q₁ | Q₁ | S | Q₂₀ | Q₁ | Q₁ | Q₁ |
| Lₐ₁₅₆₄ | O | Q₁ | Q₁ | Q₁ | Q₁ | S | Q₂₁ | Q₁ | Q₁ | Q₁ |
| Lₐ₁₅₆₅ | O | Q₁ | Q₁ | Q₁ | Q₁ | S | Q₂₂ | Q₁ | Q₁ | Q₁ |
| Lₐ₁₅₆₆ | O | Q₁ | Q₁ | Q₁ | Q₁ | S | Q₂₃ | Q₁ | Q₁ | Q₁ |
| Lₐ₁₅₆₇ | O | Q₁ | Q₁ | Q₁ | Q₁ | S | Q₁ | Q₂ | Q₁ | Q₁ |
| Lₐ₁₅₆₈ | O | Q₁ | Q₁ | Q₁ | Q₁ | S | Q₁ | Q₃ | Q₁ | Q₁ |
| Lₐ₁₅₆₉ | O | Q₁ | Q₁ | Q₁ | Q₁ | S | Q₁ | Q₄ | Q₁ | Q₁ |
| Lₐ₁₅₇₀ | O | Q₁ | Q₁ | Q₁ | Q₁ | S | Q₁ | Q₅ | Q₁ | Q₁ |
| Lₐ₁₅₇₁ | O | Q₁ | Q₁ | Q₁ | Q₁ | S | Q₁ | Q₆ | Q₁ | Q₁ |
| Lₐ₁₅₇₂ | O | Q₁ | Q₁ | Q₁ | Q₁ | S | Q₁ | Q₇ | Q₁ | Q₁ |
| Lₐ₁₅₇₃ | O | Q₁ | Q₁ | Q₁ | Q₁ | S | Q₁ | Q₈ | Q₁ | Q₁ |
| Lₐ₁₅₇₄ | O | Q₁ | Q₁ | Q₁ | Q₁ | S | Q₁ | Q₉ | Q₁ | Q₁ |
| Lₐ₁₅₇₅ | O | Q₁ | Q₁ | Q₁ | Q₁ | S | Q₁ | Q₁₀ | Q₁ | Q₁ |
| Lₐ₁₅₇₆ | O | Q₁ | Q₁ | Q₁ | Q₁ | S | Q₁ | Q₁₁ | Q₁ | Q₁ |
| Lₐ₁₅₇₇ | O | Q₁ | Q₁ | Q₁ | Q₁ | S | Q₁ | Q₁₂ | Q₁ | Q₁ |
| Lₐ₁₅₇₈ | O | Q₁ | Q₁ | Q₁ | Q₁ | S | Q₁ | Q₁₃ | Q₁ | Q₁ |
| Lₐ₁₅₇₉ | O | Q₁ | Q₁ | Q₁ | Q₁ | S | Q₁ | Q₁₄ | Q₁ | Q₁ |
| Lₐ₁₅₈₀ | O | Q₁ | Q₁ | Q₁ | Q₁ | S | Q₁ | Q₁₅ | Q₁ | Q₁ |
| Lₐ₁₅₈₁ | O | Q₁ | Q₁ | Q₁ | Q₁ | S | Q₁ | Q₁₆ | Q₁ | Q₁ |
| Lₐ₁₅₈₂ | O | Q₁ | Q₁ | Q₁ | Q₁ | S | Q₁ | Q₁₇ | Q₁ | Q₁ |
| Lₐ₁₅₈₃ | O | Q₁ | Q₁ | Q₁ | Q₁ | S | Q₁ | Q₁₈ | Q₁ | Q₁ |
| Lₐ₁₅₈₄ | O | Q₁ | Q₁ | Q₁ | Q₁ | S | Q₁ | Q₁₉ | Q₁ | Q₁ |
| Lₐ₁₅₈₅ | O | Q₁ | Q₁ | Q₁ | Q₁ | S | Q₁ | Q₂₀ | Q₁ | Q₁ |
| Lₐ₁₅₈₆ | O | Q₁ | Q₁ | Q₁ | Q₁ | S | Q₁ | Q₂₁ | Q₁ | Q₁ |
| Lₐ₁₅₈₇ | O | Q₁ | Q₁ | Q₁ | Q₁ | S | Q₁ | Q₂₂ | Q₁ | Q₁ |
| Lₐ₁₅₈₈ | O | Q₁ | Q₁ | Q₁ | Q₁ | S | Q₁ | Q₂₃ | Q₁ | Q₁ |
| Lₐ₁₅₈₉ | O | Q₁ | Q₁ | Q₁ | Q₁ | S | Q₁ | Q₁ | Q₂ | Q₁ |
| Lₐ₁₅₉₀ | O | Q₁ | Q₁ | Q₁ | Q₁ | S | Q₁ | Q₁ | Q₃ | Q₁ |
| Lₐ₁₅₉₁ | O | Q₁ | Q₁ | Q₁ | Q₁ | S | Q₁ | Q₁ | Q₄ | Q₁ |
| Lₐ₁₅₉₂ | O | Q₁ | Q₁ | Q₁ | Q₁ | S | Q₁ | Q₁ | Q₅ | Q₁ |
| Lₐ₁₅₉₃ | O | Q₁ | Q₁ | Q₁ | Q₁ | S | Q₁ | Q₁ | Q₆ | Q₁ |
| Lₐ₁₅₉₄ | O | Q₁ | Q₁ | Q₁ | Q₁ | S | Q₁ | Q₁ | Q₇ | Q₁ |
| Lₐ₁₅₉₅ | O | Q₁ | Q₁ | Q₁ | Q₁ | S | Q₁ | Q₁ | Q₈ | Q₁ |
| Lₐ₁₅₉₆ | O | Q₁ | Q₁ | Q₁ | Q₁ | S | Q₁ | Q₁ | Q₉ | Q₁ |
| Lₐ₁₅₉₇ | O | Q₁ | Q₁ | Q₁ | Q₁ | S | Q₁ | Q₁ | Q₁₀ | Q₁ |
| Lₐ₁₅₉₈ | O | Q₁ | Q₁ | Q₁ | Q₁ | S | Q₁ | Q₁ | Q₁₁ | Q₁ |
| Lₐ₁₅₉₉ | O | Q₁ | Q₁ | Q₁ | Q₁ | S | Q₁ | Q₁ | Q₁₂ | Q₁ |
| Lₐ₁₆₀₀ | O | Q₁ | Q₁ | Q₁ | Q₁ | S | Q₁ | Q₁ | Q₁₃ | Q₁ |
| Lₐ₁₆₀₁ | O | Q₁ | Q₁ | Q₁ | Q₁ | S | Q₁ | Q₁ | Q₁₄ | Q₁ |
| Lₐ₁₆₀₂ | O | Q₁ | Q₁ | Q₁ | Q₁ | S | Q₁ | Q₁ | Q₁₅ | Q₁ |
| Lₐ₁₆₀₃ | O | Q₁ | Q₁ | Q₁ | Q₁ | S | Q₁ | Q₁ | Q₁₆ | Q₁ |
| Lₐ₁₆₀₄ | O | Q₁ | Q₁ | Q₁ | Q₁ | S | Q₁ | Q₁ | Q₁₇ | Q₁ |
| Lₐ₁₆₀₅ | O | Q₁ | Q₁ | Q₁ | Q₁ | S | Q₁ | Q₁ | Q₁₈ | Q₁ |
| Lₐ₁₆₀₆ | O | Q₁ | Q₁ | Q₁ | Q₁ | S | Q₁ | Q₁ | Q₁₉ | Q₁ |
| Lₐ₁₆₀₇ | O | Q₁ | Q₁ | Q₁ | Q₁ | S | Q₁ | Q₁ | Q₂₀ | Q₁ |
| Lₐ₁₆₀₈ | O | Q₁ | Q₁ | Q₁ | Q₁ | S | Q₁ | Q₁ | Q₂₁ | Q₁ |
| Lₐ₁₆₀₉ | O | Q₁ | Q₁ | Q₁ | Q₁ | S | Q₁ | Q₁ | Q₂₂ | Q₁ |
| Lₐ₁₆₁₀ | O | Q₁ | Q₁ | Q₁ | Q₁ | S | Q₁ | Q₁ | Q₂₃ | Q₁ |
| Lₐ₁₆₁₁ | O | Q₁ | Q₁ | Q₁ | Q₁ | S | Q₁ | Q₁ | Q₁ | Q₂ |
| Lₐ₁₆₁₂ | O | Q₁ | Q₁ | Q₁ | Q₁ | S | Q₁ | Q₁ | Q₁ | Q₃ |
| Lₐ₁₆₁₃ | O | Q₁ | Q₁ | Q₁ | Q₁ | S | Q₁ | Q₁ | Q₁ | Q₄ |
| Lₐ₁₆₁₄ | O | Q₁ | Q₁ | Q₁ | Q₁ | S | Q₁ | Q₁ | Q₁ | Q₅ |
| Lₐ₁₆₁₅ | O | Q₁ | Q₁ | Q₁ | Q₁ | S | Q₁ | Q₁ | Q₁ | Q₆ |
| Lₐ₁₆₁₆ | O | Q₁ | Q₁ | Q₁ | Q₁ | S | Q₁ | Q₁ | Q₁ | Q₇ |
| Lₐ₁₆₁₇ | O | Q₁ | Q₁ | Q₁ | Q₁ | S | Q₁ | Q₁ | Q₁ | Q₈ |
| Lₐ₁₆₁₈ | O | Q₁ | Q₁ | Q₁ | Q₁ | S | Q₁ | Q₁ | Q₁ | Q₉ |
| Lₐ₁₆₁₉ | O | Q₁ | Q₁ | Q₁ | Q₁ | S | Q₁ | Q₁ | Q₁ | Q₁₀ |
| Lₐ₁₆₂₀ | O | Q₁ | Q₁ | Q₁ | Q₁ | S | Q₁ | Q₁ | Q₁ | Q₁₁ |
| Lₐ₁₆₂₁ | O | Q₁ | Q₁ | Q₁ | Q₁ | S | Q₁ | Q₁ | Q₁ | Q₁₂ |
| Lₐ₁₆₂₂ | O | Q₁ | Q₁ | Q₁ | Q₁ | S | Q₁ | Q₁ | Q₁ | Q₁₃ |
| Lₐ₁₆₂₃ | O | Q₁ | Q₁ | Q₁ | Q₁ | S | Q₁ | Q₁ | Q₁ | Q₁₄ |
| Lₐ₁₆₂₄ | O | Q₁ | Q₁ | Q₁ | Q₁ | S | Q₁ | Q₁ | Q₁ | Q₁₅ |
| Lₐ₁₆₂₅ | O | Q₁ | Q₁ | Q₁ | Q₁ | S | Q₁ | Q₁ | Q₁ | Q₁₆ |
| Lₐ₁₆₂₆ | O | Q₁ | Q₁ | Q₁ | Q₁ | S | Q₁ | Q₁ | Q₁ | Q₁₇ |
| Lₐ₁₆₂₇ | O | Q₁ | Q₁ | Q₁ | Q₁ | S | Q₁ | Q₁ | Q₁ | Q₁₈ |
| Lₐ₁₆₂₈ | O | Q₁ | Q₁ | Q₁ | Q₁ | S | Q₁ | Q₁ | Q₁ | Q₁₉ |
| Lₐ₁₆₂₉ | O | Q₁ | Q₁ | Q₁ | Q₁ | S | Q₁ | Q₁ | Q₁ | Q₂₀ |
| Lₐ₁₆₃₀ | O | Q₁ | Q₁ | Q₁ | Q₁ | S | Q₁ | Q₁ | Q₁ | Q₂₁ |
| Lₐ₁₆₃₁ | O | Q₁ | Q₁ | Q₁ | Q₁ | S | Q₁ | Q₁ | Q₁ | Q₂₂ |
| Lₐ₁₆₃₂ | O | Q₁ | Q₁ | Q₁ | Q₁ | S | Q₁ | Q₁ | Q₁ | Q₂₃ |
| Lₐ₁₆₃₃ | O | Q₁ | Q₂ | Q₁ | Q₁ | S | Q₄ | Q₁ | Q₁ | Q₁ |
| Lₐ₁₆₃₄ | O | Q₁ | Q₃ | Q₁ | Q₁ | S | Q₄ | Q₁ | Q₁ | Q₁ |
| Lₐ₁₆₃₅ | O | Q₁ | Q₄ | Q₁ | Q₁ | S | Q₄ | Q₁ | Q₁ | Q₁ |
| Lₐ₁₆₃₆ | O | Q₁ | Q₅ | Q₁ | Q₁ | S | Q₄ | Q₁ | Q₁ | Q₁ |
| Lₐ₁₆₃₇ | O | Q₁ | Q₆ | Q₁ | Q₁ | S | Q₄ | Q₁ | Q₁ | Q₁ |
| Lₐ₁₆₃₈ | O | Q₁ | Q₇ | Q₁ | Q₁ | S | Q₄ | Q₁ | Q₁ | Q₁ |
| Lₐ₁₆₃₉ | O | Q₁ | Q₈ | Q₁ | Q₁ | S | Q₄ | Q₁ | Q₁ | Q₁ |
| Lₐ₁₆₄₀ | O | Q₁ | Q₉ | Q₁ | Q₁ | S | Q₄ | Q₁ | Q₁ | Q₁ |
| Lₐ₁₆₄₁ | O | Q₁ | Q₁₀ | Q₁ | Q₁ | S | Q₄ | Q₁ | Q₁ | Q₁ |
| Lₐ₁₆₄₂ | O | Q₁ | Q₁₁ | Q₁ | Q₁ | S | Q₄ | Q₁ | Q₁ | Q₁ |
| Lₐ₁₆₄₃ | O | Q₁ | Q₁₂ | Q₁ | Q₁ | S | Q₄ | Q₁ | Q₁ | Q₁ |
| Lₐ₁₆₄₄ | O | Q₁ | Q₁₃ | Q₁ | Q₁ | S | Q₄ | Q₁ | Q₁ | Q₁ |
| Lₐ₁₆₄₅ | O | Q₁ | Q₁₄ | Q₁ | Q₁ | S | Q₄ | Q₁ | Q₁ | Q₁ |
| Lₐ₁₆₄₆ | O | Q₁ | Q₁₅ | Q₁ | Q₁ | S | Q₄ | Q₁ | Q₁ | Q₁ |
| Lₐ₁₆₄₇ | O | Q₁ | Q₁₆ | Q₁ | Q₁ | S | Q₄ | Q₁ | Q₁ | Q₁ |
| Lₐ₁₆₄₈ | O | Q₁ | Q₁₇ | Q₁ | Q₁ | S | Q₄ | Q₁ | Q₁ | Q₁ |
| Lₐ₁₆₄₉ | O | Q₁ | Q₁₈ | Q₁ | Q₁ | S | Q₄ | Q₁ | Q₁ | Q₁ |
| Lₐ₁₆₅₀ | O | Q₁ | Q₁₉ | Q₁ | Q₁ | S | Q₄ | Q₁ | Q₁ | Q₁ |
| Lₐ₁₆₅₁ | O | Q₁ | Q₂₀ | Q₁ | Q₁ | S | Q₄ | Q₁ | Q₁ | Q₁ |
| Lₐ₁₆₅₂ | O | Q₁ | Q₂₁ | Q₁ | Q₁ | S | Q₄ | Q₁ | Q₁ | Q₁ |
| Lₐ₁₆₅₃ | O | Q₁ | Q₂₂ | Q₁ | Q₁ | S | Q₄ | Q₁ | Q₁ | Q₁ |
| Lₐ₁₆₅₄ | O | Q₁ | Q₂₃ | Q₁ | Q₁ | S | Q₄ | Q₁ | Q₁ | Q₁ |
| Lₐ₁₆₅₅ | O | Q₁ | Q₁ | Q₂ | Q₁ | S | Q₄ | Q₁ | Q₁ | Q₁ |
| Lₐ₁₆₅₆ | O | Q₁ | Q₁ | Q₃ | Q₁ | S | Q₄ | Q₁ | Q₁ | Q₁ |
| Lₐ₁₆₅₇ | O | Q₁ | Q₁ | Q₄ | Q₁ | S | Q₄ | Q₁ | Q₁ | Q₁ |
| Lₐ₁₆₅₈ | O | Q₁ | Q₁ | Q₅ | Q₁ | S | Q₄ | Q₁ | Q₁ | Q₁ |
| Lₐ₁₆₅₉ | O | Q₁ | Q₁ | Q₆ | Q₁ | S | Q₄ | Q₁ | Q₁ | Q₁ |
| Lₐ₁₆₆₀ | O | Q₁ | Q₁ | Q₇ | Q₁ | S | Q₄ | Q₁ | Q₁ | Q₁ |
| Lₐ₁₆₆₁ | O | Q₁ | Q₁ | Q₈ | Q₁ | S | Q₄ | Q₁ | Q₁ | Q₁ |
| Lₐ₁₆₆₂ | O | Q₁ | Q₁ | Q₉ | Q₁ | S | Q₄ | Q₁ | Q₁ | Q₁ |
| Lₐ₁₆₆₃ | O | Q₁ | Q₁ | Q₁₀ | Q₁ | S | Q₄ | Q₁ | Q₁ | Q₁ |
| Lₐ₁₆₆₄ | O | Q₁ | Q₁ | Q₁₁ | Q₁ | S | Q₄ | Q₁ | Q₁ | Q₁ |
| Lₐ₁₆₆₅ | O | Q₁ | Q₁ | Q₁₂ | Q₁ | S | Q₄ | Q₁ | Q₁ | Q₁ |
| Lₐ₁₆₆₆ | O | Q₁ | Q₁ | Q₁₃ | Q₁ | S | Q₄ | Q₁ | Q₁ | Q₁ |
| Lₐ₁₆₆₇ | O | Q₁ | Q₁ | Q₁₄ | Q₁ | S | Q₄ | Q₁ | Q₁ | Q₁ |
| Lₐ₁₆₆₈ | O | Q₁ | Q₁ | Q₁₅ | Q₁ | S | Q₄ | Q₁ | Q₁ | Q₁ |
| Lₐ₁₆₆₉ | O | Q₁ | Q₁ | Q₁₆ | Q₁ | S | Q₄ | Q₁ | Q₁ | Q₁ |
| Lₐ₁₆₇₀ | O | Q₁ | Q₁ | Q₁₇ | Q₁ | S | Q₄ | Q₁ | Q₁ | Q₁ |
| Lₐ₁₆₇₁ | O | Q₁ | Q₁ | Q₁₈ | Q₁ | S | Q₄ | Q₁ | Q₁ | Q₁ |
| Lₐ₁₆₇₂ | O | Q₁ | Q₁ | Q₁₉ | Q₁ | S | Q₄ | Q₁ | Q₁ | Q₁ |
| Lₐ₁₆₇₃ | O | Q₁ | Q₁ | Q₂₀ | Q₁ | S | Q₄ | Q₁ | Q₁ | Q₁ |
| Lₐ₁₆₇₄ | O | Q₁ | Q₁ | Q₂₁ | Q₁ | S | Q₄ | Q₁ | Q₁ | Q₁ |
| Lₐ₁₆₇₅ | O | Q₁ | Q₁ | Q₂₂ | Q₁ | S | Q₄ | Q₁ | Q₁ | Q₁ |
| Lₐ₁₆₇₆ | O | Q₁ | Q₁ | Q₂₃ | Q₁ | S | Q₄ | Q₁ | Q₁ | Q₁ |
| Lₐ₁₆₇₇ | O | Q₁ | Q₂ | Q₁ | Q₁ | S | Q₆ | Q₁ | Q₁ | Q₁ |
| Lₐ₁₆₇₈ | O | Q₁ | Q₃ | Q₁ | Q₁ | S | Q₆ | Q₁ | Q₁ | Q₁ |
| Lₐ₁₆₇₉ | O | Q₁ | Q₄ | Q₁ | Q₁ | S | Q₆ | Q₁ | Q₁ | Q₁ |
| Lₐ₁₆₈₀ | O | Q₁ | Q₅ | Q₁ | Q₁ | S | Q₆ | Q₁ | Q₁ | Q₁ |
| Lₐ₁₆₈₁ | O | Q₁ | Q₆ | Q₁ | Q₁ | S | Q₆ | Q₁ | Q₁ | Q₁ |
| Lₐ₁₆₈₂ | O | Q₁ | Q₇ | Q₁ | Q₁ | S | Q₆ | Q₁ | Q₁ | Q₁ |
| Lₐ₁₆₈₃ | O | Q₁ | Q₈ | Q₁ | Q₁ | S | Q₆ | Q₁ | Q₁ | Q₁ |
| Lₐ₁₆₈₄ | O | Q₁ | Q₉ | Q₁ | Q₁ | S | Q₆ | Q₁ | Q₁ | Q₁ |
| Lₐ₁₆₈₅ | O | Q₁ | Q₁₀ | Q₁ | Q₁ | S | Q₆ | Q₁ | Q₁ | Q₁ |
| Lₐ₁₆₈₆ | O | Q₁ | Q₁₁ | Q₁ | Q₁ | S | Q₆ | Q₁ | Q₁ | Q₁ |
| Lₐ₁₆₈₇ | O | Q₁ | Q₁₂ | Q₁ | Q₁ | S | Q₆ | Q₁ | Q₁ | Q₁ |
| Lₐ₁₆₈₈ | O | Q₁ | Q₁₃ | Q₁ | Q₁ | S | Q₆ | Q₁ | Q₁ | Q₁ |
| Lₐ₁₆₈₉ | O | Q₁ | Q₁₄ | Q₁ | Q₁ | S | Q₆ | Q₁ | Q₁ | Q₁ |
| Lₐ₁₆₉₀ | O | Q₁ | Q₁₅ | Q₁ | Q₁ | S | Q₆ | Q₁ | Q₁ | Q₁ |
| Lₐ₁₆₉₁ | O | Q₁ | Q₁₆ | Q₁ | Q₁ | S | Q₆ | Q₁ | Q₁ | Q₁ |
| Lₐ₁₆₉₂ | O | Q₁ | Q₁₇ | Q₁ | Q₁ | S | Q₆ | Q₁ | Q₁ | Q₁ |
| Lₐ₁₆₉₃ | O | Q₁ | Q₁₈ | Q₁ | Q₁ | S | Q₆ | Q₁ | Q₁ | Q₁ |
| Lₐ₁₆₉₄ | O | Q₁ | Q₁₉ | Q₁ | Q₁ | S | Q₆ | Q₁ | Q₁ | Q₁ |
| Lₐ₁₆₉₅ | O | Q₁ | Q₂₀ | Q₁ | Q₁ | S | Q₆ | Q₁ | Q₁ | Q₁ |
| Lₐ₁₆₉₆ | O | Q₁ | Q₂₁ | Q₁ | Q₁ | S | Q₆ | Q₁ | Q₁ | Q₁ |
| Lₐ₁₆₉₇ | O | Q₁ | Q₂₂ | Q₁ | Q₁ | S | Q₆ | Q₁ | Q₁ | Q₁ |
| Lₐ₁₆₉₈ | O | Q₁ | Q₂₃ | Q₁ | Q₁ | S | Q₆ | Q₁ | Q₁ | Q₁ |
| Lₐ₁₆₉₉ | O | Q₁ | Q₁ | Q₁ | Q₁ | S | Q₆ | Q₁ | Q₁ | Q₁ |
| Lₐ₁₇₀₀ | O | Q₁ | Q₁ | Q₃ | Q₁ | S | Q₆ | Q₁ | Q₁ | Q₁ |
| Lₐ₁₇₀₁ | O | Q₁ | Q₁ | Q₄ | Q₁ | S | Q₆ | Q₁ | Q₁ | Q₁ |
| Lₐ₁₇₀₂ | O | Q₁ | Q₁ | Q₅ | Q₁ | S | Q₆ | Q₁ | Q₁ | Q₁ |
| Lₐ₁₇₀₃ | O | Q₁ | Q₁ | Q₆ | Q₁ | S | Q₆ | Q₁ | Q₁ | Q₁ |
| Lₐ₁₇₀₄ | O | Q₁ | Q₁ | Q₇ | Q₁ | S | Q₆ | Q₁ | Q₁ | Q₁ |
| Lₐ₁₇₀₅ | O | Q₁ | Q₁ | Q₈ | Q₁ | S | Q₆ | Q₁ | Q₁ | Q₁ |
| Lₐ₁₇₀₆ | O | Q₁ | Q₁ | Q₉ | Q₁ | S | Q₆ | Q₁ | Q₁ | Q₁ |
| Lₐ₁₇₀₇ | O | Q₁ | Q₁ | Q₁₀ | Q₁ | S | Q₆ | Q₁ | Q₁ | Q₁ |
| Lₐ₁₇₀₈ | O | Q₁ | Q₁ | Q₁₁ | Q₁ | S | Q₆ | Q₁ | Q₁ | Q₁ |
| Lₐ₁₇₀₉ | O | Q₁ | Q₁ | Q₁₂ | Q₁ | S | Q₆ | Q₁ | Q₁ | Q₁ |
| Lₐ₁₇₁₀ | O | Q₁ | Q₁ | Q₁₃ | Q₁ | S | Q₆ | Q₁ | Q₁ | Q₁ |
| Lₐ₁₇₁₁ | O | Q₁ | Q₁ | Q₁₄ | Q₁ | S | Q₆ | Q₁ | Q₁ | Q₁ |
| Lₐ₁₇₁₂ | O | Q₁ | Q₁ | Q₁₅ | Q₁ | S | Q₆ | Q₁ | Q₁ | Q₁ |
| Lₐ₁₇₁₃ | O | Q₁ | Q₁ | Q₁₆ | Q₁ | S | Q₆ | Q₁ | Q₁ | Q₁ |
| Lₐ₁₇₁₄ | O | Q₁ | Q₁ | Q₁₇ | Q₁ | S | Q₆ | Q₁ | Q₁ | Q₁ |
| Lₐ₁₇₁₅ | O | Q₁ | Q₁ | Q₁₈ | Q₁ | S | Q₆ | Q₁ | Q₁ | Q₁ |
| Lₐ₁₇₁₆ | O | Q₁ | Q₁ | Q₁₉ | Q₁ | S | Q₆ | Q₁ | Q₁ | Q₁ |
| Lₐ₁₇₁₇ | O | Q₁ | Q₁ | Q₂₀ | Q₁ | S | Q₆ | Q₁ | Q₁ | Q₁ |
| Lₐ₁₇₁₈ | O | Q₁ | Q₁ | Q₂₁ | Q₁ | S | Q₆ | Q₁ | Q₁ | Q₁ |
| Lₐ₁₇₁₉ | O | Q₁ | Q₁ | Q₂₂ | Q₁ | S | Q₆ | Q₁ | Q₁ | Q₁ |
| Lₐ₁₇₂₀ | O | Q₁ | Q₁ | Q₂₃ | Q₁ | S | Q₆ | Q₁ | Q₁ | Q₁ |
| Lₐ₁₇₂₁ | O | Q₁ | Q₂ | Q₁ | Q₁ | S | Q₇ | Q₁ | Q₁ | Q₁ |
| Lₐ₁₇₂₂ | O | Q₁ | Q₃ | Q₁ | Q₁ | S | Q₇ | Q₁ | Q₁ | Q₁ |
| Lₐ₁₇₂₃ | O | Q₁ | Q₄ | Q₁ | Q₁ | S | Q₇ | Q₁ | Q₁ | Q₁ |
| Lₐ₁₇₂₄ | O | Q₁ | Q₅ | Q₁ | Q₁ | S | Q₇ | Q₁ | Q₁ | Q₁ |
| Lₐ₁₇₂₅ | O | Q₁ | Q₆ | Q₁ | Q₁ | S | Q₇ | Q₁ | Q₁ | Q₁ |
| Lₐ₁₇₂₆ | O | Q₁ | Q₇ | Q₁ | Q₁ | S | Q₇ | Q₁ | Q₁ | Q₁ |
| Lₐ₁₇₂₇ | O | Q₁ | Q₈ | Q₁ | Q₁ | S | Q₇ | Q₁ | Q₁ | Q₁ |
| Lₐ₁₇₂₈ | O | Q₁ | Q₉ | Q₁ | Q₁ | S | Q₇ | Q₁ | Q₁ | Q₁ |
| Lₐ₁₇₂₉ | O | Q₁ | Q₁₀ | Q₁ | Q₁ | S | Q₇ | Q₁ | Q₁ | Q₁ |
| Lₐ₁₇₃₀ | O | Q₁ | Q₁₁ | Q₁ | Q₁ | S | Q₇ | Q₁ | Q₁ | Q₁ |
| Lₐ₁₇₃₁ | O | Q₁ | Q₁₂ | Q₁ | Q₁ | S | Q₇ | Q₁ | Q₁ | Q₁ |
| Lₐ₁₇₃₂ | O | Q₁ | Q₁₃ | Q₁ | Q₁ | S | Q₇ | Q₁ | Q₁ | Q₁ |
| Lₐ₁₇₃₃ | O | Q₁ | Q₁₄ | Q₁ | Q₁ | S | Q₇ | Q₁ | Q₁ | Q₁ |
| Lₐ₁₇₃₄ | O | Q₁ | Q₁₅ | Q₁ | Q₁ | S | Q₇ | Q₁ | Q₁ | Q₁ |
| Lₐ₁₇₃₅ | O | Q₁ | Q₁₆ | Q₁ | Q₁ | S | Q₇ | Q₁ | Q₁ | Q₁ |
| Lₐ₁₇₃₆ | O | Q₁ | Q₁₇ | Q₁ | Q₁ | S | Q₇ | Q₁ | Q₁ | Q₁ |
| Lₐ₁₇₃₇ | O | Q₁ | Q₁₈ | Q₁ | Q₁ | S | Q₇ | Q₁ | Q₁ | Q₁ |
| Lₐ₁₇₃₈ | O | Q₁ | Q₁₉ | Q₁ | Q₁ | S | Q₇ | Q₁ | Q₁ | Q₁ |
| Lₐ₁₇₃₉ | O | Q₁ | Q₂₀ | Q₁ | Q₁ | S | Q₇ | Q₁ | Q₁ | Q₁ |
| Lₐ₁₇₄₀ | O | Q₁ | Q₂₁ | Q₁ | Q₁ | S | Q₇ | Q₁ | Q₁ | Q₁ |
| Lₐ₁₇₄₁ | O | Q₁ | Q₂₂ | Q₁ | Q₁ | S | Q₇ | Q₁ | Q₁ | Q₁ |
| Lₐ₁₇₄₂ | O | Q₁ | Q₂₃ | Q₁ | Q₁ | S | Q₇ | Q₁ | Q₁ | Q₁ |
| Lₐ₁₇₄₃ | O | Q₁ | Q₁ | Q₂ | Q₁ | S | Q₇ | Q₁ | Q₁ | Q₁ |
| Lₐ₁₇₄₄ | O | Q₁ | Q₁ | Q₃ | Q₁ | S | Q₇ | Q₁ | Q₁ | Q₁ |
| Lₐ₁₇₄₅ | O | Q₁ | Q₁ | Q₄ | Q₁ | S | Q₇ | Q₁ | Q₁ | Q₁ |
| Lₐ₁₇₄₆ | O | Q₁ | Q₁ | Q₅ | Q₁ | S | Q₇ | Q₁ | Q₁ | Q₁ |
| Lₐ₁₇₄₇ | O | Q₁ | Q₁ | Q₆ | Q₁ | S | Q₇ | Q₁ | Q₁ | Q₁ |
| Lₐ₁₇₄₈ | O | Q₁ | Q₁ | Q₇ | Q₁ | S | Q₇ | Q₁ | Q₁ | Q₁ |
| Lₐ₁₇₄₉ | O | Q₁ | Q₁ | Q₈ | Q₁ | S | Q₇ | Q₁ | Q₁ | Q₁ |
| Lₐ₁₇₅₀ | O | Q₁ | Q₁ | Q₉ | Q₁ | S | Q₇ | Q₁ | Q₁ | Q₁ |
| Lₐ₁₇₅₁ | O | Q₁ | Q₁ | Q₁₀ | Q₁ | S | Q₇ | Q₁ | Q₁ | Q₁ |
| Lₐ₁₇₅₂ | O | Q₁ | Q₁ | Q₁₁ | Q₁ | S | Q₇ | Q₁ | Q₁ | Q₁ |
| Lₐ₁₇₅₃ | O | Q₁ | Q₁ | Q₁₂ | Q₁ | S | Q₇ | Q₁ | Q₁ | Q₁ |
| Lₐ₁₇₅₄ | O | Q₁ | Q₁ | Q₁₃ | Q₁ | S | Q₇ | Q₁ | Q₁ | Q₁ |
| Lₐ₁₇₅₅ | O | Q₁ | Q₁ | Q₁₄ | Q₁ | S | Q₇ | Q₁ | Q₁ | Q₁ |
| Lₐ₁₇₅₆ | O | Q₁ | Q₁ | Q₁₅ | Q₁ | S | Q₇ | Q₁ | Q₁ | Q₁ |
| Lₐ₁₇₅₇ | O | Q₁ | Q₁ | Q₁₆ | Q₁ | S | Q₇ | Q₁ | Q₁ | Q₁ |
| Lₐ₁₇₅₈ | O | Q₁ | Q₁ | Q₁₇ | Q₁ | S | Q₇ | Q₁ | Q₁ | Q₁ |
| Lₐ₁₇₅₉ | O | Q₁ | Q₁ | Q₁₈ | Q₁ | S | Q₇ | Q₁ | Q₁ | Q₁ |
| Lₐ₁₇₆₀ | O | Q₁ | Q₁ | Q₁₉ | Q₁ | S | Q₇ | Q₁ | Q₁ | Q₁ |
| Lₐ₁₇₆₁ | O | Q₁ | Q₁ | Q₂₀ | Q₁ | S | Q₇ | Q₁ | Q₁ | Q₁ |
| Lₐ₁₇₆₂ | O | Q₁ | Q₁ | Q₂₁ | Q₁ | S | Q₇ | Q₁ | Q₁ | Q₁ |
| Lₐ₁₇₆₃ | O | Q₁ | Q₁ | Q₂₂ | Q₁ | S | Q₇ | Q₁ | Q₁ | Q₁ |
| Lₐ₁₇₆₄ | O | Q₁ | Q₁ | Q₂₃ | Q₁ | S | Q₇ | Q₁ | Q₁ | Q₁ |
| Lₐ₁₇₆₅ | O | Q₁ | Q₂ | Q₁ | Q₁ | S | Q₈ | Q₁ | Q₁ | Q₁ |
| Lₐ₁₇₆₆ | O | Q₁ | Q₃ | Q₁ | Q₁ | S | Q₈ | Q₁ | Q₁ | Q₁ |
| Lₐ₁₇₆₇ | O | Q₁ | Q₄ | Q₁ | Q₁ | S | Q₈ | Q₁ | Q₁ | Q₁ |
| Lₐ₁₇₆₈ | O | Q₁ | Q₅ | Q₁ | Q₁ | S | Q₈ | Q₁ | Q₁ | Q₁ |
| Lₐ₁₇₆₉ | O | Q₁ | Q₆ | Q₁ | Q₁ | S | Q₈ | Q₁ | Q₁ | Q₁ |
| Lₐ₁₇₇₀ | O | Q₁ | Q₇ | Q₁ | Q₁ | S | Q₈ | Q₁ | Q₁ | Q₁ |
| Lₐ₁₇₇₁ | O | Q₁ | Q₈ | Q₁ | Q₁ | S | Q₈ | Q₁ | Q₁ | Q₁ |
| Lₐ₁₇₇₂ | O | Q₁ | Q₉ | Q₁ | Q₁ | S | Q₈ | Q₁ | Q₁ | Q₁ |
| Lₐ₁₇₇₃ | O | Q₁ | Q₁₀ | Q₁ | Q₁ | S | Q₈ | Q₁ | Q₁ | Q₁ |
| Lₐ₁₇₇₄ | O | Q₁ | Q₁₁ | Q₁ | Q₁ | S | Q₈ | Q₁ | Q₁ | Q₁ |
| Lₐ₁₇₇₅ | O | Q₁ | Q₁₂ | Q₁ | Q₁ | S | Q₈ | Q₁ | Q₁ | Q₁ |
| Lₐ₁₇₇₆ | O | Q₁ | Q₁₃ | Q₁ | Q₁ | S | Q₈ | Q₁ | Q₁ | Q₁ |
| Lₐ₁₇₇₇ | O | Q₁ | Q₁₄ | Q₁ | Q₁ | S | Q₈ | Q₁ | Q₁ | Q₁ |
| Lₐ₁₇₇₈ | O | Q₁ | Q₁₅ | Q₁ | Q₁ | S | Q₈ | Q₁ | Q₁ | Q₁ |
| Lₐ₁₇₇₉ | O | Q₁ | Q₁₆ | Q₁ | Q₁ | S | Q₈ | Q₁ | Q₁ | Q₁ |
| Lₐ₁₇₈₀ | O | Q₁ | Q₁₇ | Q₁ | Q₁ | S | Q₈ | Q₁ | Q₁ | Q₁ |
| Lₐ₁₇₈₁ | O | Q₁ | Q₁₈ | Q₁ | Q₁ | S | Q₈ | Q₁ | Q₁ | Q₁ |
| Lₐ₁₇₈₂ | O | Q₁ | Q₁₉ | Q₁ | Q₁ | S | Q₈ | Q₁ | Q₁ | Q₁ |
| Lₐ₁₇₈₃ | O | Q₁ | Q₂₀ | Q₁ | Q₁ | S | Q₈ | Q₁ | Q₁ | Q₁ |
| Lₐ₁₇₈₄ | O | Q₁ | Q₂₁ | Q₁ | Q₁ | S | Q₈ | Q₁ | Q₁ | Q₁ |
| Lₐ₁₇₈₅ | O | Q₁ | Q₂₂ | Q₁ | Q₁ | S | Q₈ | Q₁ | Q₁ | Q₁ |
| Lₐ₁₇₈₆ | O | Q₁ | Q₂₃ | Q₁ | Q₁ | S | Q₈ | Q₁ | Q₁ | Q₁ |
| Lₐ₁₇₈₇ | O | Q₁ | Q₁ | Q₂ | Q₁ | S | Q₈ | Q₁ | Q₁ | Q₁ |
| Lₐ₁₇₈₈ | O | Q₁ | Q₁ | Q₃ | Q₁ | S | Q₈ | Q₁ | Q₁ | Q₁ |
| Lₐ₁₇₈₉ | O | Q₁ | Q₁ | Q₄ | Q₁ | S | Q₈ | Q₁ | Q₁ | Q₁ |
| Lₐ₁₇₉₀ | O | Q₁ | Q₁ | Q₅ | Q₁ | S | Q₈ | Q₁ | Q₁ | Q₁ |
| Lₐ₁₇₉₁ | O | Q₁ | Q₁ | Q₆ | Q₁ | S | Q₈ | Q₁ | Q₁ | Q₁ |
| Lₐ₁₇₉₂ | O | Q₁ | Q₁ | Q₇ | Q₁ | S | Q₈ | Q₁ | Q₁ | Q₁ |
| Lₐ₁₇₉₃ | O | Q₁ | Q₁ | Q₈ | Q₁ | S | Q₈ | Q₁ | Q₁ | Q₁ |
| Lₐ₁₇₉₄ | O | Q₁ | Q₁ | Q₉ | Q₁ | S | Q₈ | Q₁ | Q₁ | Q₁ |
| Lₐ₁₇₉₅ | O | Q₁ | Q₁ | Q₁₀ | Q₁ | S | Q₈ | Q₁ | Q₁ | Q₁ |
| Lₐ₁₇₉₆ | O | Q₁ | Q₁ | Q₁₁ | Q₁ | S | Q₈ | Q₁ | Q₁ | Q₁ |
| Lₐ₁₇₉₇ | O | Q₁ | Q₁ | Q₁₂ | Q₁ | S | Q₈ | Q₁ | Q₁ | Q₁ |
| Lₐ₁₇₉₈ | O | Q₁ | Q₁ | Q₁₃ | Q₁ | S | Q₈ | Q₁ | Q₁ | Q₁ |
| Lₐ₁₇₉₉ | O | Q₁ | Q₁ | Q₁₄ | Q₁ | S | Q₈ | Q₁ | Q₁ | Q₁ |
| Lₐ₁₈₀₀ | O | Q₁ | Q₁ | Q₁₅ | Q₁ | S | Q₈ | Q₁ | Q₁ | Q₁ |
| Lₐ₁₈₀₁ | O | Q₁ | Q₁ | Q₁₆ | Q₁ | S | Q₈ | Q₁ | Q₁ | Q₁ |
| Lₐ₁₈₀₂ | O | Q₁ | Q₁ | Q₁₇ | Q₁ | S | Q₈ | Q₁ | Q₁ | Q₁ |
| Lₐ₁₈₀₃ | O | Q₁ | Q₁ | Q₁₈ | Q₁ | S | Q₈ | Q₁ | Q₁ | Q₁ |
| Lₐ₁₈₀₄ | O | Q₁ | Q₁ | Q₁₉ | Q₁ | S | Q₈ | Q₁ | Q₁ | Q₁ |
| Lₐ₁₈₀₅ | O | Q₁ | Q₁ | Q₂₀ | Q₁ | S | Q₈ | Q₁ | Q₁ | Q₁ |
| Lₐ₁₈₀₆ | O | Q₁ | Q₁ | Q₂₁ | Q₁ | S | Q₈ | Q₁ | Q₁ | Q₁ |
| Lₐ₁₈₀₇ | O | Q₁ | Q₁ | Q₂₂ | Q₁ | S | Q₈ | Q₁ | Q₁ | Q₁ |
| Lₐ₁₈₀₈ | O | Q₁ | Q₁ | Q₂₃ | Q₁ | S | Q₈ | Q₁ | Q₁ | Q₁ |
| Lₐ₁₈₀₉ | O | Q₁ | Q₂ | Q₁ | Q₁ | S | Q₈ | Q₄ | Q₁ | Q₁ |
| Lₐ₁₈₁₀ | O | Q₁ | Q₃ | Q₁ | Q₁ | S | Q₈ | Q₄ | Q₁ | Q₁ |
| Lₐ₁₈₁₁ | O | Q₁ | Q₄ | Q₁ | Q₁ | S | Q₈ | Q₄ | Q₁ | Q₁ |
| Lₐ₁₈₁₂ | O | Q₁ | Q₅ | Q₁ | Q₁ | S | Q₈ | Q₄ | Q₁ | Q₁ |
| Lₐ₁₈₁₃ | O | Q₁ | Q₆ | Q₁ | Q₁ | S | Q₈ | Q₄ | Q₁ | Q₁ |
| Lₐ₁₈₁₄ | O | Q₁ | Q₇ | Q₁ | Q₁ | S | Q₈ | Q₄ | Q₁ | Q₁ |
| Lₐ₁₈₁₅ | O | Q₁ | Q₈ | Q₁ | Q₁ | S | Q₈ | Q₄ | Q₁ | Q₁ |
| Lₐ₁₈₁₆ | O | Q₁ | Q₉ | Q₁ | Q₁ | S | Q₈ | Q₄ | Q₁ | Q₁ |
| Lₐ₁₈₁₇ | O | Q₁ | Q₁₀ | Q₁ | Q₁ | S | Q₈ | Q₄ | Q₁ | Q₁ |
| Lₐ₁₈₁₈ | O | Q₁ | Q₁₁ | Q₁ | Q₁ | S | Q₈ | Q₄ | Q₁ | Q₁ |
| Lₐ₁₈₁₉ | O | Q₁ | Q₁₂ | Q₁ | Q₁ | S | Q₈ | Q₄ | Q₁ | Q₁ |
| Lₐ₁₈₂₀ | O | Q₁ | Q₁₃ | Q₁ | Q₁ | S | Q₈ | Q₄ | Q₁ | Q₁ |
| Lₐ₁₈₂₁ | O | Q₁ | Q₁₄ | Q₁ | Q₁ | S | Q₈ | Q₄ | Q₁ | Q₁ |
| Lₐ₁₈₂₂ | O | Q₁ | Q₁₅ | Q₁ | Q₁ | S | Q₈ | Q₄ | Q₁ | Q₁ |
| Lₐ₁₈₂₃ | O | Q₁ | Q₁₆ | Q₁ | Q₁ | S | Q₈ | Q₄ | Q₁ | Q₁ |
| Lₐ₁₈₂₄ | O | Q₁ | Q₁₇ | Q₁ | Q₁ | S | Q₈ | Q₄ | Q₁ | Q₁ |
| Lₐ₁₈₂₅ | O | Q₁ | Q₁₈ | Q₁ | Q₁ | S | Q₈ | Q₄ | Q₁ | Q₁ |
| Lₐ₁₈₂₆ | O | Q₁ | Q₁₉ | Q₁ | Q₁ | S | Q₈ | Q₄ | Q₁ | Q₁ |
| Lₐ₁₈₂₇ | O | Q₁ | Q₂₀ | Q₁ | Q₁ | S | Q₈ | Q₄ | Q₁ | Q₁ |
| Lₐ₁₈₂₈ | O | Q₁ | Q₂₁ | Q₁ | Q₁ | S | Q₈ | Q₄ | Q₁ | Q₁ |
| Lₐ₁₈₂₉ | O | Q₁ | Q₂₂ | Q₁ | Q₁ | S | Q₈ | Q₄ | Q₁ | Q₁ |
| Lₐ₁₈₃₀ | O | Q₁ | Q₂₃ | Q₁ | Q₁ | S | Q₈ | Q₄ | Q₁ | Q₁ |
| Lₐ₁₈₃₁ | O | Q₁ | Q₁ | Q₂ | Q₁ | S | Q₈ | Q₄ | Q₁ | Q₁ |
| Lₐ₁₈₃₂ | O | Q₁ | Q₁ | Q₃ | Q₁ | S | Q₈ | Q₄ | Q₁ | Q₁ |
| Lₐ₁₈₃₃ | O | Q₁ | Q₁ | Q₄ | Q₁ | S | Q₈ | Q₄ | Q₁ | Q₁ |
| Lₐ₁₈₃₄ | O | Q₁ | Q₁ | Q₅ | Q₁ | S | Q₈ | Q₄ | Q₁ | Q₁ |
| Lₐ₁₈₃₅ | O | Q₁ | Q₁ | Q₆ | Q₁ | S | Q₈ | Q₄ | Q₁ | Q₁ |
| Lₐ₁₈₃₆ | O | Q₁ | Q₁ | Q₇ | Q₁ | S | Q₈ | Q₄ | Q₁ | Q₁ |
| Lₐ₁₈₃₇ | O | Q₁ | Q₁ | Q₈ | Q₁ | S | Q₈ | Q₄ | Q₁ | Q₁ |
| Lₐ₁₈₃₈ | O | Q₁ | Q₁ | Q₉ | Q₁ | S | Q₈ | Q₄ | Q₁ | Q₁ |
| Lₐ₁₈₃₉ | O | Q₁ | Q₁ | Q₁₀ | Q₁ | S | Q₈ | Q₄ | Q₁ | Q₁ |
| Lₐ₁₈₄₀ | O | Q₁ | Q₁ | Q₁₁ | Q₁ | S | Q₈ | Q₄ | Q₁ | Q₁ |
| Lₐ₁₈₄₁ | O | Q₁ | Q₁ | Q₁₂ | Q₁ | S | Q₈ | Q₄ | Q₁ | Q₁ |
| Lₐ₁₈₄₂ | O | Q₁ | Q₁ | Q₁₃ | Q₁ | S | Q₈ | Q₄ | Q₁ | Q₁ |
| Lₐ₁₈₄₃ | O | Q₁ | Q₁ | Q₁₄ | Q₁ | S | Q₈ | Q₄ | Q₁ | Q₁ |
| Lₐ₁₈₄₄ | O | Q₁ | Q₁ | Q₁₅ | Q₁ | S | Q₈ | Q₄ | Q₁ | Q₁ |
| Lₐ₁₈₄₅ | O | Q₁ | Q₁ | Q₁₆ | Q₁ | S | Q₈ | Q₄ | Q₁ | Q₁ |
| Lₐ₁₈₄₆ | O | Q₁ | Q₁ | Q₁₇ | Q₁ | S | Q₈ | Q₄ | Q₁ | Q₁ |
| Lₐ₁₈₄₇ | O | Q₁ | Q₁ | Q₁₈ | Q₁ | S | Q₈ | Q₄ | Q₁ | Q₁ |
| Lₐ₁₈₄₈ | O | Q₁ | Q₁ | Q₁₉ | Q₁ | S | Q₈ | Q₄ | Q₁ | Q₁ |
| Lₐ₁₈₄₉ | O | Q₁ | Q₁ | Q₂₀ | Q₁ | S | Q₈ | Q₄ | Q₁ | Q₁ |
| Lₐ₁₈₅₀ | O | Q₁ | Q₁ | Q₂₁ | Q₁ | S | Q₈ | Q₄ | Q₁ | Q₁ |
| Lₐ₁₈₅₁ | O | Q₁ | Q₁ | Q₂₂ | Q₁ | S | Q₈ | Q₄ | Q₁ | Q₁ |
| Lₐ₁₈₅₂ | O | Q₁ | Q₁ | Q₂₃ | Q₁ | S | Q₈ | Q₄ | Q₁ | Q₁ |
| Lₐ₁₈₅₃ | O | Q₁ | Q₂ | Q₁ | Q₁ | S | Q₈ | Q₁ | Q₄ | Q₁ |
| Lₐ₁₈₅₄ | O | Q₁ | Q₃ | Q₁ | Q₁ | S | Q₈ | Q₁ | Q₄ | Q₁ |
| Lₐ₁₈₅₅ | O | Q₁ | Q₄ | Q₁ | Q₁ | S | Q₈ | Q₁ | Q₄ | Q₁ |
| Lₐ₁₈₅₆ | O | Q₁ | Q₅ | Q₁ | Q₁ | S | Q₈ | Q₁ | Q₄ | Q₁ |
| Lₐ₁₈₅₇ | O | Q₁ | Q₆ | Q₁ | Q₁ | S | Q₈ | Q₁ | Q₄ | Q₁ |
| Lₐ₁₈₅₈ | O | Q₁ | Q₇ | Q₁ | Q₁ | S | Q₈ | Q₁ | Q₄ | Q₁ |
| Lₐ₁₈₅₉ | O | Q₁ | Q₈ | Q₁ | Q₁ | S | Q₈ | Q₁ | Q₄ | Q₁ |
| Lₐ₁₈₆₀ | O | Q₁ | Q₉ | Q₁ | Q₁ | S | Q₈ | Q₁ | Q₄ | Q₁ |
| Lₐ₁₈₆₁ | O | Q₁ | Q₁₀ | Q₁ | Q₁ | S | Q₈ | Q₁ | Q₄ | Q₁ |
| Lₐ₁₈₆₂ | O | Q₁ | Q₁₁ | Q₁ | Q₁ | S | Q₈ | Q₁ | Q₄ | Q₁ |
| Lₐ₁₈₆₃ | O | Q₁ | Q₁₂ | Q₁ | Q₁ | S | Q₈ | Q₁ | Q₄ | Q₁ |
| Lₐ₁₈₆₄ | O | Q₁ | Q₁₃ | Q₁ | Q₁ | S | Q₈ | Q₁ | Q₄ | Q₁ |
| Lₐ₁₈₆₅ | O | Q₁ | Q₁₄ | Q₁ | Q₁ | S | Q₈ | Q₁ | Q₄ | Q₁ |
| Lₐ₁₈₆₆ | O | Q₁ | Q₁₅ | Q₁ | Q₁ | S | Q₈ | Q₁ | Q₄ | Q₁ |
| Lₐ₁₈₆₇ | O | Q₁ | Q₁₆ | Q₁ | Q₁ | S | Q₈ | Q₁ | Q₄ | Q₁ |
| Lₐ₁₈₆₈ | O | Q₁ | Q₁₇ | Q₁ | Q₁ | S | Q₈ | Q₁ | Q₄ | Q₁ |
| Lₐ₁₈₆₉ | O | Q₁ | Q₁₈ | Q₁ | Q₁ | S | Q₈ | Q₁ | Q₄ | Q₁ |
| Lₐ₁₈₇₀ | O | Q₁ | Q₁₉ | Q₁ | Q₁ | S | Q₈ | Q₁ | Q₄ | Q₁ |
| Lₐ₁₈₇₁ | O | Q₁ | Q₂₀ | Q₁ | Q₁ | S | Q₈ | Q₁ | Q₄ | Q₁ |
| Lₐ₁₈₇₂ | O | Q₁ | Q₂₁ | Q₁ | Q₁ | S | Q₈ | Q₁ | Q₄ | Q₁ |
| Lₐ₁₈₇₃ | O | Q₁ | Q₂₂ | Q₁ | Q₁ | S | Q₈ | Q₁ | Q₄ | Q₁ |
| Lₐ₁₈₇₄ | O | Q₁ | Q₂₃ | Q₁ | Q₁ | S | Q₈ | Q₁ | Q₄ | Q₁ |
| Lₐ₁₈₇₅ | O | Q₁ | Q₁ | Q₂ | Q₁ | S | Q₈ | Q₁ | Q₄ | Q₁ |
| Lₐ₁₈₇₆ | O | Q₁ | Q₁ | Q₃ | Q₁ | S | Q₈ | Q₁ | Q₄ | Q₁ |
| Lₐ₁₈₇₇ | O | Q₁ | Q₁ | Q₄ | Q₁ | S | Q₈ | Q₁ | Q₄ | Q₁ |
| Lₐ₁₈₇₈ | O | Q₁ | Q₁ | Q₅ | Q₁ | S | Q₈ | Q₁ | Q₄ | Q₁ |
| Lₐ₁₈₇₉ | O | Q₁ | Q₁ | Q₆ | Q₁ | S | Q₈ | Q₁ | Q₄ | Q₁ |
| Lₐ₁₈₈₀ | O | Q₁ | Q₁ | Q₇ | Q₁ | S | Q₈ | Q₁ | Q₄ | Q₁ |
| Lₐ₁₈₈₁ | O | Q₁ | Q₁ | Q₈ | Q₁ | S | Q₈ | Q₁ | Q₄ | Q₁ |
| Lₐ₁₈₈₂ | O | Q₁ | Q₁ | Q₉ | Q₁ | S | Q₈ | Q₁ | Q₄ | Q₁ |
| Lₐ₁₈₈₃ | O | Q₁ | Q₁ | Q₁₀ | Q₁ | S | Q₈ | Q₁ | Q₄ | Q₁ |
| Lₐ₁₈₈₄ | O | Q₁ | Q₁ | Q₁₁ | Q₁ | S | Q₈ | Q₁ | Q₄ | Q₁ |
| Lₐ₁₈₈₅ | O | Q₁ | Q₁ | Q₁₂ | Q₁ | S | Q₈ | Q₁ | Q₄ | Q₁ |
| Lₐ₁₈₈₆ | O | Q₁ | Q₁ | Q₁₃ | Q₁ | S | Q₈ | Q₁ | Q₄ | Q₁ |
| Lₐ₁₈₈₇ | O | Q₁ | Q₁ | Q₁₄ | Q₁ | S | Q₈ | Q₁ | Q₄ | Q₁ |
| Lₐ₁₈₈₈ | O | Q₁ | Q₁ | Q₁₅ | Q₁ | S | Q₈ | Q₁ | Q₄ | Q₁ |
| Lₐ₁₈₈₉ | O | Q₁ | Q₁ | Q₁₆ | Q₁ | S | Q₈ | Q₁ | Q₄ | Q₁ |
| Lₐ₁₈₉₀ | O | Q₁ | Q₁ | Q₁₇ | Q₁ | S | Q₈ | Q₁ | Q₄ | Q₁ |
| Lₐ₁₈₉₁ | O | Q₁ | Q₁ | Q₁₈ | Q₁ | S | Q₈ | Q₁ | Q₄ | Q₁ |
| Lₐ₁₈₉₂ | O | Q₁ | Q₁ | Q₁₉ | Q₁ | S | Q₈ | Q₁ | Q₄ | Q₁ |
| Lₐ₁₈₉₃ | O | Q₁ | Q₁ | Q₂₀ | Q₁ | S | Q₈ | Q₁ | Q₄ | Q₁ |
| Lₐ₁₈₉₄ | O | Q₁ | Q₁ | Q₂₁ | Q₁ | S | Q₈ | Q₁ | Q₄ | Q₁ |
| Lₐ₁₈₉₅ | O | Q₁ | Q₁ | Q₂₂ | Q₁ | S | Q₈ | Q₁ | Q₄ | Q₁ |
| Lₐ₁₈₉₆ | O | Q₁ | Q₁ | Q₂₃ | Q₁ | S | Q₈ | Q₁ | Q₄ | Q₁ |
| Lₐ₁₈₉₇ | O | Q₁ | Q₂ | Q₁ | Q₁ | S | Q₈ | Q₁ | Q₁ | Q₄ |
| Lₐ₁₈₉₈ | O | Q₁ | Q₃ | Q₁ | Q₁ | S | Q₈ | Q₁ | Q₁ | Q₄ |
| Lₐ₁₈₉₉ | O | Q₁ | Q₄ | Q₁ | Q₁ | S | Q₈ | Q₁ | Q₁ | Q₄ |
| Lₐ₁₉₀₀ | O | Q₁ | Q₅ | Q₁ | Q₁ | S | Q₈ | Q₁ | Q₁ | Q₄ |
| Lₐ₁₉₀₁ | O | Q₁ | Q₆ | Q₁ | Q₁ | S | Q₈ | Q₁ | Q₁ | Q₄ |
| Lₐ₁₉₀₂ | O | Q₁ | Q₇ | Q₁ | Q₁ | S | Q₈ | Q₁ | Q₁ | Q₄ |
| Lₐ₁₉₀₃ | O | Q₁ | Q₈ | Q₁ | Q₁ | S | Q₈ | Q₁ | Q₁ | Q₄ |
| Lₐ₁₉₀₄ | O | Q₁ | Q₉ | Q₁ | Q₁ | S | Q₈ | Q₁ | Q₁ | Q₄ |
| Lₐ₁₉₀₅ | O | Q₁ | Q₁₀ | Q₁ | Q₁ | S | Q₈ | Q₁ | Q₁ | Q₄ |
| Lₐ₁₉₀₆ | O | Q₁ | Q₁₁ | Q₁ | Q₁ | S | Q₈ | Q₁ | Q₁ | Q₄ |
| Lₐ₁₉₀₇ | O | Q₁ | Q₁₂ | Q₁ | Q₁ | S | Q₈ | Q₁ | Q₁ | Q₄ |
| Lₐ₁₉₀₈ | O | Q₁ | Q₁₃ | Q₁ | Q₁ | S | Q₈ | Q₁ | Q₁ | Q₄ |
| Lₐ₁₉₀₉ | O | Q₁ | Q₁₄ | Q₁ | Q₁ | S | Q₈ | Q₁ | Q₁ | Q₄ |
| Lₐ₁₉₁₀ | O | Q₁ | Q₁₅ | Q₁ | Q₁ | S | Q₈ | Q₁ | Q₁ | Q₄ |
| Lₐ₁₉₁₁ | O | Q₁ | Q₁₆ | Q₁ | Q₁ | S | Q₈ | Q₁ | Q₁ | Q₄ |
| Lₐ₁₉₁₂ | O | Q₁ | Q₁₇ | Q₁ | Q₁ | S | Q₈ | Q₁ | Q₁ | Q₄ |
| Lₐ₁₉₁₃ | O | Q₁ | Q₁₈ | Q₁ | Q₁ | S | Q₈ | Q₁ | Q₁ | Q₄ |
| Lₐ₁₉₁₄ | O | Q₁ | Q₁₉ | Q₁ | Q₁ | S | Q₈ | Q₁ | Q₁ | Q₄ |
| Lₐ₁₉₁₅ | O | Q₁ | Q₂₀ | Q₁ | Q₁ | S | Q₈ | Q₁ | Q₁ | Q₄ |
| Lₐ₁₉₁₆ | O | Q₁ | Q₂₁ | Q₁ | Q₁ | S | Q₈ | Q₁ | Q₁ | Q₄ |
| Lₐ₁₉₁₇ | O | Q₁ | Q₂₂ | Q₁ | Q₁ | S | Q₈ | Q₁ | Q₁ | Q₄ |
| Lₐ₁₉₁₈ | O | Q₁ | Q₂₃ | Q₁ | Q₁ | S | Q₈ | Q₁ | Q₁ | Q₄ |
| Lₐ₁₉₁₉ | O | Q₁ | Q₁ | Q₂ | Q₁ | S | Q₈ | Q₁ | Q₁ | Q₄ |
| Lₐ₁₉₂₀ | O | Q₁ | Q₁ | Q₃ | Q₁ | S | Q₈ | Q₁ | Q₁ | Q₄ |
| Lₐ₁₉₂₁ | O | Q₁ | Q₁ | Q₄ | Q₁ | S | Q₈ | Q₁ | Q₁ | Q₄ |
| Lₐ₁₉₂₂ | O | Q₁ | Q₁ | Q₅ | Q₁ | S | Q₈ | Q₁ | Q₁ | Q₄ |
| Lₐ₁₉₂₃ | O | Q₁ | Q₁ | Q₆ | Q₁ | S | Q₈ | Q₁ | Q₁ | Q₄ |
| Lₐ₁₉₂₄ | O | Q₁ | Q₁ | Q₇ | Q₁ | S | Q₈ | Q₁ | Q₁ | Q₄ |
| Lₐ₁₉₂₅ | O | Q₁ | Q₁ | Q₈ | Q₁ | S | Q₈ | Q₁ | Q₁ | Q₄ |
| Lₐ₁₉₂₆ | O | Q₁ | Q₁ | Q₉ | Q₁ | S | Q₈ | Q₁ | Q₁ | Q₄ |
| Lₐ₁₉₂₇ | O | Q₁ | Q₁ | Q₁₀ | Q₁ | S | Q₈ | Q₁ | Q₁ | Q₄ |
| Lₐ₁₉₂₈ | O | Q₁ | Q₁ | Q₁₁ | Q₁ | S | Q₈ | Q₁ | Q₁ | Q₄ |
| Lₐ₁₉₂₉ | O | Q₁ | Q₁ | Q₁₂ | Q₁ | S | Q₈ | Q₁ | Q₁ | Q₄ |
| Lₐ₁₉₃₀ | O | Q₁ | Q₁ | Q₁₃ | Q₁ | S | Q₈ | Q₁ | Q₁ | Q₄ |
| Lₐ₁₉₃₁ | O | Q₁ | Q₁ | Q₁₄ | Q₁ | S | Q₈ | Q₁ | Q₁ | Q₄ |
| Lₐ₁₉₃₂ | O | Q₁ | Q₁ | Q₁₅ | Q₁ | S | Q₈ | Q₁ | Q₁ | Q₄ |
| Lₐ₁₉₃₃ | O | Q₁ | Q₁ | Q₁₆ | Q₁ | S | Q₈ | Q₁ | Q₁ | Q₄ |
| Lₐ₁₉₃₄ | O | Q₁ | Q₁ | Q₁₇ | Q₁ | S | Q₈ | Q₁ | Q₁ | Q₄ |
| Lₐ₁₉₃₅ | O | Q₁ | Q₁ | Q₁₈ | Q₁ | S | Q₈ | Q₁ | Q₁ | Q₄ |
| Lₐ₁₉₃₆ | O | Q₁ | Q₁ | Q₁₉ | Q₁ | S | Q₈ | Q₁ | Q₁ | Q₄ |
| Lₐ₁₉₃₇ | O | Q₁ | Q₁ | Q₂₀ | Q₁ | S | Q₈ | Q₁ | Q₁ | Q₄ |
| Lₐ₁₉₃₈ | O | Q₁ | Q₁ | Q₂₁ | Q₁ | S | Q₈ | Q₁ | Q₁ | Q₄ |
| Lₐ₁₉₃₉ | O | Q₁ | Q₁ | Q₂₂ | Q₁ | S | Q₈ | Q₁ | Q₁ | Q₄ |
| Lₐ₁₉₄₀ | O | Q₁ | Q₁ | Q₂₃ | Q₁ | S | Q₈ | Q₁ | Q₁ | Q₄ |

wherein Lₐ₁₉₄₁ to Lₐ₂₉₉₈ each have a structure represented by Formula 47: 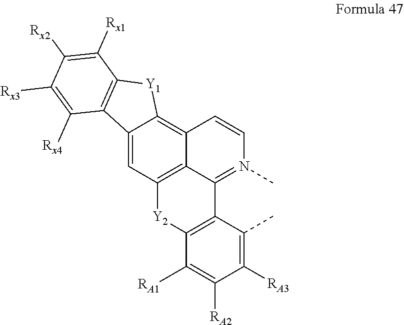
wherein Y₁, Y₂, Rₓ₁ to Rₓ₄ and R_{A1} to R_{A3} are selected from the groups listed in the following table, respectively:

| Ligand No. | Y₁ | Rₓ₁ | Rₓ₂ | Rₓ₃ | Rₓ₄ | Y₂ | R_{A1} | R_{A2} | R_{A3} |
|---|---|---|---|---|---|---|---|---|---|
| Lₐ₁₉₄₁ | O | Q₁ | Q₁ | Q₁ | Q₁ | O | Q₁ | Q₁ | Q₁ |
| Lₐ₁₉₄₂ | O | Q₂ | Q₁ | Q₁ | Q₁ | O | Q₁ | Q₁ | Q₁ |
| Lₐ₁₉₄₃ | O | Q₃ | Q₁ | Q₁ | Q₁ | O | Q₁ | Q₁ | Q₁ |
| Lₐ₁₉₄₄ | O | Q₄ | Q₁ | Q₁ | Q₁ | O | Q₁ | Q₁ | Q₁ |
| Lₐ₁₉₄₅ | O | Q₅ | Q₁ | Q₁ | Q₁ | O | Q₁ | Q₁ | Q₁ |
| Lₐ₁₉₄₆ | O | Q₆ | Q₁ | Q₁ | Q₁ | O | Q₁ | Q₁ | Q₁ |
| Lₐ₁₉₄₇ | O | Q₇ | Q₁ | Q₁ | Q₁ | O | Q₁ | Q₁ | Q₁ |
| Lₐ₁₉₄₈ | O | Q₈ | Q₁ | Q₁ | Q₁ | O | Q₁ | Q₁ | Q₁ |
| Lₐ₁₉₄₉ | O | Q₉ | Q₁ | Q₁ | Q₁ | O | Q₁ | Q₁ | Q₁ |
| Lₐ₁₉₅₀ | O | Q₁₀ | Q₁ | Q₁ | Q₁ | O | Q₁ | Q₁ | Q₁ |
| Lₐ₁₉₅₁ | O | Q₁₁ | Q₁ | Q₁ | Q₁ | O | Q₁ | Q₁ | Q₁ |
| Lₐ₁₉₅₂ | O | Q₁₂ | Q₁ | Q₁ | Q₁ | O | Q₁ | Q₁ | Q₁ |
| Lₐ₁₉₅₃ | O | Q₁₃ | Q₁ | Q₁ | Q₁ | O | Q₁ | Q₁ | Q₁ |
| Lₐ₁₉₅₄ | O | Q₁₄ | Q₁ | Q₁ | Q₁ | O | Q₁ | Q₁ | Q₁ |
| Lₐ₁₉₅₅ | O | Q₁₅ | Q₁ | Q₁ | Q₁ | O | Q₁ | Q₁ | Q₁ |
| Lₐ₁₉₅₆ | O | Q₁₆ | Q₁ | Q₁ | Q₁ | O | Q₁ | Q₁ | Q₁ |
| Lₐ₁₉₅₇ | O | Q₁₇ | Q₁ | Q₁ | Q₁ | O | Q₁ | Q₁ | Q₁ |
| Lₐ₁₉₅₈ | O | Q₁₈ | Q₁ | Q₁ | Q₁ | O | Q₁ | Q₁ | Q₁ |
| Lₐ₁₉₅₉ | O | Q₁₉ | Q₁ | Q₁ | Q₁ | O | Q₁ | Q₁ | Q₁ |
| Lₐ₁₉₆₀ | O | Q₂₀ | Q₁ | Q₁ | Q₁ | O | Q₁ | Q₁ | Q₁ |
| Lₐ₁₉₆₁ | O | Q₂₁ | Q₁ | Q₁ | Q₁ | O | Q₁ | Q₁ | Q₁ |
| Lₐ₁₉₆₂ | O | Q₂₂ | Q₁ | Q₁ | Q₁ | O | Q₁ | Q₁ | Q₁ |
| Lₐ₁₉₆₃ | O | Q₂₃ | Q₁ | Q₁ | Q₁ | O | Q₁ | Q₁ | Q₁ |
| Lₐ₁₉₆₄ | O | Q₁ | Q₂ | Q₁ | Q₁ | O | Q₁ | Q₁ | Q₁ |
| Lₐ₁₉₆₅ | O | Q₁ | Q₃ | Q₁ | Q₁ | O | Q₁ | Q₁ | Q₁ |
| Lₐ₁₉₆₆ | O | Q₁ | Q₄ | Q₁ | Q₁ | O | Q₁ | Q₁ | Q₁ |
| Lₐ₁₉₆₇ | O | Q₁ | Q₅ | Q₁ | Q₁ | O | Q₁ | Q₁ | Q₁ |
| Lₐ₁₉₆₈ | O | Q₁ | Q₆ | Q₁ | Q₁ | O | Q₁ | Q₁ | Q₁ |
| Lₐ₁₉₆₉ | O | Q₁ | Q₇ | Q₁ | Q₁ | O | Q₁ | Q₁ | Q₁ |
| Lₐ₁₉₇₀ | O | Q₁ | Q₈ | Q₁ | Q₁ | O | Q₁ | Q₁ | Q₁ |
| Lₐ₁₉₇₁ | O | Q₁ | Q₉ | Q₁ | Q₁ | O | Q₁ | Q₁ | Q₁ |
| Lₐ₁₉₇₂ | O | Q₁ | Q₁₀ | Q₁ | Q₁ | O | Q₁ | Q₁ | Q₁ |
| Lₐ₁₉₇₃ | O | Q₁ | Q₁₁ | Q₁ | Q₁ | O | Q₁ | Q₁ | Q₁ |
| Lₐ₁₉₇₄ | O | Q₁ | Q₁₂ | Q₁ | Q₁ | O | Q₁ | Q₁ | Q₁ |
| Lₐ₁₉₇₅ | O | Q₁ | Q₁₃ | Q₁ | Q₁ | O | Q₁ | Q₁ | Q₁ |
| Lₐ₁₉₇₆ | O | Q₁ | Q₁₄ | Q₁ | Q₁ | O | Q₁ | Q₁ | Q₁ |
| Lₐ₁₉₇₇ | O | Q₁ | Q₁₅ | Q₁ | Q₁ | O | Q₁ | Q₁ | Q₁ |
| Lₐ₁₉₇₈ | O | Q₁ | Q₁₆ | Q₁ | Q₁ | O | Q₁ | Q₁ | Q₁ |
| Lₐ₁₉₇₉ | O | Q₁ | Q₁₇ | Q₁ | Q₁ | O | Q₁ | Q₁ | Q₁ |
| Lₐ₁₉₈₀ | O | Q₁ | Q₁₈ | Q₁ | Q₁ | O | Q₁ | Q₁ | Q₁ |
| Lₐ₁₉₈₁ | O | Q₁ | Q₁₉ | Q₁ | Q₁ | O | Q₁ | Q₁ | Q₁ |
| Lₐ₁₉₈₂ | O | Q₁ | Q₂₀ | Q₁ | Q₁ | O | Q₁ | Q₁ | Q₁ |
| Lₐ₁₉₈₃ | O | Q₁ | Q₂₁ | Q₁ | Q₁ | O | Q₁ | Q₁ | Q₁ |
| Lₐ₁₉₈₄ | O | Q₁ | Q₂₂ | Q₁ | Q₁ | O | Q₁ | Q₁ | Q₁ |
| Lₐ₁₉₈₅ | O | Q₁ | Q₂₃ | Q₁ | Q₁ | O | Q₁ | Q₁ | Q₁ |
| Lₐ₁₉₈₆ | O | Q₁ | Q₁ | Q₂ | Q₁ | O | Q₁ | Q₁ | Q₁ |
| Lₐ₁₉₈₇ | O | Q₁ | Q₁ | Q₃ | Q₁ | O | Q₁ | Q₁ | Q₁ |
| Lₐ₁₉₈₈ | O | Q₁ | Q₁ | Q₄ | Q₁ | O | Q₁ | Q₁ | Q₁ |
| Lₐ₁₉₈₉ | O | Q₁ | Q₁ | Q₅ | Q₁ | O | Q₁ | Q₁ | Q₁ |
| Lₐ₁₉₉₀ | O | Q₁ | Q₁ | Q₆ | Q₁ | O | Q₁ | Q₁ | Q₁ |
| Lₐ₁₉₉₁ | O | Q₁ | Q₁ | Q₇ | Q₁ | O | Q₁ | Q₁ | Q₁ |
| Lₐ₁₉₉₂ | O | Q₁ | Q₁ | Q₈ | Q₁ | O | Q₁ | Q₁ | Q₁ |
| Lₐ₁₉₉₃ | O | Q₁ | Q₁ | Q₉ | Q₁ | O | Q₁ | Q₁ | Q₁ |
| Lₐ₁₉₉₄ | O | Q₁ | Q₁ | Q₁₀ | Q₁ | O | Q₁ | Q₁ | Q₁ |
| Lₐ₁₉₉₅ | O | Q₁ | Q₁ | Q₁₁ | Q₁ | O | Q₁ | Q₁ | Q₁ |
| Lₐ₁₉₉₆ | O | Q₁ | Q₁ | Q₁₂ | Q₁ | O | Q₁ | Q₁ | Q₁ |
| Lₐ₁₉₉₇ | O | Q₁ | Q₁ | Q₁₃ | Q₁ | O | Q₁ | Q₁ | Q₁ |
| Lₐ₁₉₉₈ | O | Q₁ | Q₁ | Q₁₄ | Q₁ | O | Q₁ | Q₁ | Q₁ |
| Lₐ₁₉₉₉ | O | Q₁ | Q₁ | Q₁₅ | Q₁ | O | Q₁ | Q₁ | Q₁ |
| Lₐ₂₀₀₀ | O | Q₁ | Q₁ | Q₁₆ | Q₁ | O | Q₁ | Q₁ | Q₁ |
| Lₐ₂₀₀₁ | O | Q₁ | Q₁ | Q₁₇ | Q₁ | O | Q₁ | Q₁ | Q₁ |
| Lₐ₂₀₀₂ | O | Q₁ | Q₁ | Q₁₈ | Q₁ | O | Q₁ | Q₁ | Q₁ |
| Lₐ₂₀₀₃ | O | Q₁ | Q₁ | Q₁₉ | Q₁ | O | Q₁ | Q₁ | Q₁ |
| Lₐ₂₀₀₄ | O | Q₁ | Q₁ | Q₂₀ | Q₁ | O | Q₁ | Q₁ | Q₁ |
| Lₐ₂₀₀₅ | O | Q₁ | Q₁ | Q₂₁ | Q₁ | O | Q₁ | Q₁ | Q₁ |
| Lₐ₂₀₀₆ | O | Q₁ | Q₁ | Q₂₂ | Q₁ | O | Q₁ | Q₁ | Q₁ |
| Lₐ₂₀₀₇ | O | Q₁ | Q₁ | Q₂₃ | Q₁ | O | Q₁ | Q₁ | Q₁ |
| Lₐ₂₀₀₈ | O | Q₁ | Q₁ | Q₁ | Q₂ | O | Q₁ | Q₁ | Q₁ |
| Lₐ₂₀₀₉ | O | Q₁ | Q₁ | Q₁ | Q₃ | O | Q₁ | Q₁ | Q₁ |
| Lₐ₂₀₁₀ | O | Q₁ | Q₁ | Q₁ | Q₄ | O | Q₁ | Q₁ | Q₁ |
| Lₐ₂₀₁₁ | O | Q₁ | Q₁ | Q₁ | Q₅ | O | Q₁ | Q₁ | Q₁ |
| Lₐ₂₀₁₂ | O | Q₁ | Q₁ | Q₁ | Q₆ | O | Q₁ | Q₁ | Q₁ |
| Lₐ₂₀₁₃ | O | Q₁ | Q₁ | Q₁ | Q₇ | O | Q₁ | Q₁ | Q₁ |
| Lₐ₂₀₁₄ | O | Q₁ | Q₁ | Q₁ | Q₈ | O | Q₁ | Q₁ | Q₁ |
| Lₐ₂₀₁₅ | O | Q₁ | Q₁ | Q₁ | Q₉ | O | Q₁ | Q₁ | Q₁ |
| Lₐ₂₀₁₆ | O | Q₁ | Q₁ | Q₁ | Q₁₀ | O | Q₁ | Q₁ | Q₁ |
| Lₐ₂₀₁₇ | O | Q₁ | Q₁ | Q₁ | Q₁₁ | O | Q₁ | Q₁ | Q₁ |
| Lₐ₂₀₁₈ | O | Q₁ | Q₁ | Q₁ | Q₁₂ | O | Q₁ | Q₁ | Q₁ |
| Lₐ₂₀₁₉ | O | Q₁ | Q₁ | Q₁ | Q₁₃ | O | Q₁ | Q₁ | Q₁ |
| Lₐ₂₀₂₀ | O | Q₁ | Q₁ | Q₁ | Q₁₄ | O | Q₁ | Q₁ | Q₁ |
| Lₐ₂₀₂₁ | O | Q₁ | Q₁ | Q₁ | Q₁₅ | O | Q₁ | Q₁ | Q₁ |
| Lₐ₂₀₂₂ | O | Q₁ | Q₁ | Q₁ | Q₁₆ | O | Q₁ | Q₁ | Q₁ |
| Lₐ₂₀₂₃ | O | Q₁ | Q₁ | Q₁ | Q₁₇ | O | Q₁ | Q₁ | Q₁ |
| Lₐ₂₀₂₄ | O | Q₁ | Q₁ | Q₁ | Q₁₈ | O | Q₁ | Q₁ | Q₁ |
| Lₐ₂₀₂₅ | O | Q₁ | Q₁ | Q₁ | Q₁₉ | O | Q₁ | Q₁ | Q₁ |
| Lₐ₂₀₂₆ | O | Q₁ | Q₁ | Q₁ | Q₂₀ | O | Q₁ | Q₁ | Q₁ |
| Lₐ₂₀₂₇ | O | Q₁ | Q₁ | Q₁ | Q₂₁ | O | Q₁ | Q₁ | Q₁ |
| Lₐ₂₀₂₈ | O | Q₁ | Q₁ | Q₁ | Q₂₂ | O | Q₁ | Q₁ | Q₁ |
| Lₐ₂₀₂₉ | O | Q₁ | Q₁ | Q₁ | Q₂₃ | O | Q₁ | Q₁ | Q₁ |
| Lₐ₂₀₃₀ | O | Q₁ | Q₁ | Q₁ | Q₁ | O | Q₂ | Q₁ | Q₁ |
| Lₐ₂₀₃₁ | O | Q₁ | Q₁ | Q₁ | Q₁ | O | Q₃ | Q₁ | Q₁ |
| Lₐ₂₀₃₂ | O | Q₁ | Q₁ | Q₁ | Q₁ | O | Q₄ | Q₁ | Q₁ |
| Lₐ₂₀₃₃ | O | Q₁ | Q₁ | Q₁ | Q₁ | O | Q₅ | Q₁ | Q₁ |
| Lₐ₂₀₃₄ | O | Q₁ | Q₁ | Q₁ | Q₁ | O | Q₆ | Q₁ | Q₁ |
| Lₐ₂₀₃₅ | O | Q₁ | Q₁ | Q₁ | Q₁ | O | Q₇ | Q₁ | Q₁ |
| Lₐ₂₀₃₆ | O | Q₁ | Q₁ | Q₁ | Q₁ | O | Q₈ | Q₁ | Q₁ |
| Lₐ₂₀₃₇ | O | Q₁ | Q₁ | Q₁ | Q₁ | O | Q₉ | Q₁ | Q₁ |
| Lₐ₂₀₃₈ | O | Q₁ | Q₁ | Q₁ | Q₁ | O | Q₁₀ | Q₁ | Q₁ |
| Lₐ₂₀₃₉ | O | Q₁ | Q₁ | Q₁ | Q₁ | O | Q₁₁ | Q₁ | Q₁ |
| Lₐ₂₀₄₀ | O | Q₁ | Q₁ | Q₁ | Q₁ | O | Q₁₂ | Q₁ | Q₁ |
| Lₐ₂₀₄₁ | O | Q₁ | Q₁ | Q₁ | Q₁ | O | Q₁₃ | Q₁ | Q₁ |
| Lₐ₂₀₄₂ | O | Q₁ | Q₁ | Q₁ | Q₁ | O | Q₁₄ | Q₁ | Q₁ |
| Lₐ₂₀₄₃ | O | Q₁ | Q₁ | Q₁ | Q₁ | O | Q₁₅ | Q₁ | Q₁ |
| Lₐ₂₀₄₄ | O | Q₁ | Q₁ | Q₁ | Q₁ | O | Q₁₆ | Q₁ | Q₁ |
| Lₐ₂₀₄₅ | O | Q₁ | Q₁ | Q₁ | Q₁ | O | Q₁₇ | Q₁ | Q₁ |
| Lₐ₂₀₄₆ | O | Q₁ | Q₁ | Q₁ | Q₁ | O | Q₁₈ | Q₁ | Q₁ |
| Lₐ₂₀₄₇ | O | Q₁ | Q₁ | Q₁ | Q₁ | O | Q₁₉ | Q₁ | Q₁ |
| Lₐ₂₀₄₈ | O | Q₁ | Q₁ | Q₁ | Q₁ | O | Q₂₀ | Q₁ | Q₁ |
| Lₐ₂₀₄₉ | O | Q₁ | Q₁ | Q₁ | Q₁ | O | Q₂₁ | Q₁ | Q₁ |
| Lₐ₂₀₅₀ | O | Q₁ | Q₁ | Q₁ | Q₁ | O | Q₂₂ | Q₁ | Q₁ |
| Lₐ₂₀₅₁ | O | Q₁ | Q₁ | Q₁ | Q₁ | O | Q₂₃ | Q₁ | Q₁ |
| Lₐ₂₀₅₂ | O | Q₁ | Q₁ | Q₁ | Q₁ | O | Q₁ | Q₂ | Q₁ |
| Lₐ₂₀₅₃ | O | Q₁ | Q₁ | Q₁ | Q₁ | O | Q₁ | Q₃ | Q₁ |
| Lₐ₂₀₅₄ | O | Q₁ | Q₁ | Q₁ | Q₁ | O | Q₁ | Q₄ | Q₁ |
| Lₐ₂₀₅₅ | O | Q₁ | Q₁ | Q₁ | Q₁ | O | Q₁ | Q₅ | Q₁ |
| Lₐ₂₀₅₆ | O | Q₁ | Q₁ | Q₁ | Q₁ | O | Q₁ | Q₆ | Q₁ |
| Lₐ₂₀₅₇ | O | Q₁ | Q₁ | Q₁ | Q₁ | O | Q₁ | Q₇ | Q₁ |
| Lₐ₂₀₅₈ | O | Q₁ | Q₁ | Q₁ | Q₁ | O | Q₁ | Q₈ | Q₁ |
| Lₐ₂₀₅₉ | O | Q₁ | Q₁ | Q₁ | Q₁ | O | Q₁ | Q₉ | Q₁ |
| Lₐ₂₀₆₀ | O | Q₁ | Q₁ | Q₁ | Q₁ | O | Q₁ | Q₁₀ | Q₁ |
| Lₐ₂₀₆₁ | O | Q₁ | Q₁ | Q₁ | Q₁ | O | Q₁ | Q₁₁ | Q₁ |
| Lₐ₂₀₆₂ | O | Q₁ | Q₁ | Q₁ | Q₁ | O | Q₁ | Q₁₂ | Q₁ |
| Lₐ₂₀₆₃ | O | Q₁ | Q₁ | Q₁ | Q₁ | O | Q₁ | Q₁₃ | Q₁ |
| Lₐ₂₀₆₄ | O | Q₁ | Q₁ | Q₁ | Q₁ | O | Q₁ | Q₁₄ | Q₁ |
| Lₐ₂₀₆₅ | O | Q₁ | Q₁ | Q₁ | Q₁ | O | Q₁ | Q₁₅ | Q₁ |
| Lₐ₂₀₆₆ | O | Q₁ | Q₁ | Q₁ | Q₁ | O | Q₁ | Q₁₆ | Q₁ |
| Lₐ₂₀₆₇ | O | Q₁ | Q₁ | Q₁ | Q₁ | O | Q₁ | Q₁₇ | Q₁ |
| Lₐ₂₀₆₈ | O | Q₁ | Q₁ | Q₁ | Q₁ | O | Q₁ | Q₁₈ | Q₁ |
| Lₐ₂₀₆₉ | O | Q₁ | Q₁ | Q₁ | Q₁ | O | Q₁ | Q₁₉ | Q₁ |
| Lₐ₂₀₇₀ | O | Q₁ | Q₁ | Q₁ | Q₁ | O | Q₁ | Q₂₀ | Q₁ |
| Lₐ₂₀₇₁ | O | Q₁ | Q₁ | Q₁ | Q₁ | O | Q₁ | Q₂₁ | Q₁ |
| Lₐ₂₀₇₂ | O | Q₁ | Q₁ | Q₁ | Q₁ | O | Q₁ | Q₂₂ | Q₁ |
| Lₐ₂₀₇₃ | O | Q₁ | Q₁ | Q₁ | Q₁ | O | Q₁ | Q₂₃ | Q₁ |
| Lₐ₂₀₇₄ | O | Q₁ | Q₁ | Q₁ | Q₁ | O | Q₁ | Q₁ | Q₂ |
| Lₐ₂₀₇₅ | O | Q₁ | Q₁ | Q₁ | Q₁ | O | Q₁ | Q₁ | Q₃ |
| Lₐ₂₀₇₆ | O | Q₁ | Q₁ | Q₁ | Q₁ | O | Q₁ | Q₁ | Q₄ |
| Lₐ₂₀₇₇ | O | Q₁ | Q₁ | Q₁ | Q₁ | O | Q₁ | Q₁ | Q₅ |
| Lₐ₂₀₇₈ | O | Q₁ | Q₁ | Q₁ | Q₁ | O | Q₁ | Q₁ | Q₆ |
| Lₐ₂₀₇₉ | O | Q₁ | Q₁ | Q₁ | Q₁ | O | Q₁ | Q₁ | Q₇ |
| Lₐ₂₀₈₀ | O | Q₁ | Q₁ | Q₁ | Q₁ | O | Q₁ | Q₁ | Q₈ |
| Lₐ₂₀₈₁ | O | Q₁ | Q₁ | Q₁ | Q₁ | O | Q₁ | Q₁ | Q₉ |
| Lₐ₂₀₈₂ | O | Q₁ | Q₁ | Q₁ | Q₁ | O | Q₁ | Q₁ | Q₁₀ |
| Lₐ₂₀₈₃ | O | Q₁ | Q₁ | Q₁ | Q₁ | O | Q₁ | Q₁ | Q₁₁ |
| Lₐ₂₀₈₄ | O | Q₁ | Q₁ | Q₁ | Q₁ | O | Q₁ | Q₁ | Q₁₂ |
| Lₐ₂₀₈₅ | O | Q₁ | Q₁ | Q₁ | Q₁ | O | Q₁ | Q₁ | Q₁₃ |
| Lₐ₂₀₈₆ | O | Q₁ | Q₁ | Q₁ | Q₁ | O | Q₁ | Q₁ | Q₁₄ |
| Lₐ₂₀₈₇ | O | Q₁ | Q₁ | Q₁ | Q₁ | O | Q₁ | Q₁ | Q₁₅ |
| Lₐ₂₀₈₈ | O | Q₁ | Q₁ | Q₁ | Q₁ | O | Q₁ | Q₁ | Q₁₆ |
| Lₐ₂₀₈₉ | O | Q₁ | Q₁ | Q₁ | Q₁ | O | Q₁ | Q₁ | Q₁₇ |
| Lₐ₂₀₉₀ | O | Q₁ | Q₁ | Q₁ | Q₁ | O | Q₁ | Q₁ | Q₁₈ |
| Lₐ₂₀₉₁ | O | Q₁ | Q₁ | Q₁ | Q₁ | O | Q₁ | Q₁ | Q₁₉ |
| Lₐ₂₀₉₂ | O | Q₁ | Q₁ | Q₁ | Q₁ | O | Q₁ | Q₁ | Q₂₀ |
| Lₐ₂₀₉₃ | O | Q₁ | Q₁ | Q₁ | Q₁ | O | Q₁ | Q₁ | Q₂₁ |
| Lₐ₂₀₉₄ | O | Q₁ | Q₁ | Q₁ | Q₁ | O | Q₁ | Q₁ | Q₂₂ |
| Lₐ₂₀₉₅ | O | Q₁ | Q₁ | Q₁ | Q₁ | O | Q₁ | Q₁ | Q₂₃ |
| Lₐ₂₀₉₆ | O | Q₁ | Q₂ | Q₁ | Q₁ | O | Q₄ | Q₁ | Q₁ |
| Lₐ₂₀₉₇ | O | Q₁ | Q₃ | Q₁ | Q₁ | O | Q₄ | Q₁ | Q₁ |
| Lₐ₂₀₉₈ | O | Q₁ | Q₄ | Q₁ | Q₁ | O | Q₄ | Q₁ | Q₁ |
| Lₐ₂₀₉₉ | O | Q₁ | Q₅ | Q₁ | Q₁ | O | Q₄ | Q₁ | Q₁ |
| Lₐ₂₁₀₀ | O | Q₁ | Q₆ | Q₁ | Q₁ | O | Q₄ | Q₁ | Q₁ |
| Lₐ₂₁₀₁ | O | Q₁ | Q₇ | Q₁ | Q₁ | O | Q₄ | Q₁ | Q₁ |
| Lₐ₂₁₀₂ | O | Q₁ | Q₈ | Q₁ | Q₁ | O | Q₄ | Q₁ | Q₁ |
| Lₐ₂₁₀₃ | O | Q₁ | Q₉ | Q₁ | Q₁ | O | Q₄ | Q₁ | Q₁ |
| Lₐ₂₁₀₄ | O | Q₁ | Q₁₀ | Q₁ | Q₁ | O | Q₄ | Q₁ | Q₁ |
| Lₐ₂₁₀₅ | O | Q₁ | Q₁₁ | Q₁ | Q₁ | O | Q₄ | Q₁ | Q₁ |
| Lₐ₂₁₀₆ | O | Q₁ | Q₁₂ | Q₁ | Q₁ | O | Q₄ | Q₁ | Q₁ |
| Lₐ₂₁₀₇ | O | Q₁ | Q₁₃ | Q₁ | Q₁ | O | Q₄ | Q₁ | Q₁ |
| Lₐ₂₁₀₈ | O | Q₁ | Q₁₄ | Q₁ | Q₁ | O | Q₄ | Q₁ | Q₁ |
| Lₐ₂₁₀₉ | O | Q₁ | Q₁₅ | Q₁ | Q₁ | O | Q₄ | Q₁ | Q₁ |
| Lₐ₂₁₁₀ | O | Q₁ | Q₁₆ | Q₁ | Q₁ | O | Q₄ | Q₁ | Q₁ |
| Lₐ₂₁₁₁ | O | Q₁ | Q₁₇ | Q₁ | Q₁ | O | Q₄ | Q₁ | Q₁ |
| Lₐ₂₁₁₂ | O | Q₁ | Q₁₈ | Q₁ | Q₁ | O | Q₄ | Q₁ | Q₁ |
| Lₐ₂₁₁₃ | O | Q₁ | Q₁₉ | Q₁ | Q₁ | O | Q₄ | Q₁ | Q₁ |
| Lₐ₂₁₁₄ | O | Q₁ | Q₂₀ | Q₁ | Q₁ | O | Q₄ | Q₁ | Q₁ |
| Lₐ₂₁₁₅ | O | Q₁ | Q₂₁ | Q₁ | Q₁ | O | Q₄ | Q₁ | Q₁ |
| Lₐ₂₁₁₆ | O | Q₁ | Q₂₂ | Q₁ | Q₁ | O | Q₄ | Q₁ | Q₁ |
| Lₐ₂₁₁₇ | O | Q₁ | Q₂₃ | Q₁ | Q₁ | O | Q₄ | Q₁ | Q₁ |
| Lₐ₂₁₁₈ | O | Q₁ | Q₁ | Q₂ | Q₁ | O | Q₄ | Q₁ | Q₁ |
| Lₐ₂₁₁₉ | O | Q₁ | Q₁ | Q₃ | Q₁ | O | Q₄ | Q₁ | Q₁ |
| Lₐ₂₁₂₀ | O | Q₁ | Q₁ | Q₄ | Q₁ | O | Q₄ | Q₁ | Q₁ |
| Lₐ₂₁₂₁ | O | Q₁ | Q₁ | Q₅ | Q₁ | O | Q₄ | Q₁ | Q₁ |
| Lₐ₂₁₂₂ | O | Q₁ | Q₁ | Q₆ | Q₁ | O | Q₄ | Q₁ | Q₁ |
| Lₐ₂₁₂₃ | O | Q₁ | Q₁ | Q₇ | Q₁ | O | Q₄ | Q₁ | Q₁ |
| Lₐ₂₁₂₄ | O | Q₁ | Q₁ | Q₈ | Q₁ | O | Q₄ | Q₁ | Q₁ |
| Lₐ₂₁₂₅ | O | Q₁ | Q₁ | Q₉ | Q₁ | O | Q₄ | Q₁ | Q₁ |
| Lₐ₂₁₂₆ | O | Q₁ | Q₁ | Q₁₀ | Q₁ | O | Q₄ | Q₁ | Q₁ |
| Lₐ₂₁₂₇ | O | Q₁ | Q₁ | Q₁₁ | Q₁ | O | Q₄ | Q₁ | Q₁ |
| Lₐ₂₁₂₈ | O | Q₁ | Q₁ | Q₁₂ | Q₁ | O | Q₄ | Q₁ | Q₁ |
| Lₐ₂₁₂₉ | O | Q₁ | Q₁ | Q₁₃ | Q₁ | O | Q₄ | Q₁ | Q₁ |
| Lₐ₂₁₃₀ | O | Q₁ | Q₁ | Q₁₄ | Q₁ | O | Q₄ | Q₁ | Q₁ |
| Lₐ₂₁₃₁ | O | Q₁ | Q₁ | Q₁₅ | Q₁ | O | Q₄ | Q₁ | Q₁ |
| Lₐ₂₁₃₂ | O | Q₁ | Q₁ | Q₁₆ | Q₁ | O | Q₄ | Q₁ | Q₁ |
| Lₐ₂₁₃₃ | O | Q₁ | Q₁ | Q₁₇ | Q₁ | O | Q₄ | Q₁ | Q₁ |
| Lₐ₂₁₃₄ | O | Q₁ | Q₁ | Q₁₈ | Q₁ | O | Q₄ | Q₁ | Q₁ |
| Lₐ₂₁₃₅ | O | Q₁ | Q₁ | Q₁₉ | Q₁ | O | Q₄ | Q₁ | Q₁ |
| Lₐ₂₁₃₆ | O | Q₁ | Q₁ | Q₂₀ | Q₁ | O | Q₄ | Q₁ | Q₁ |
| Lₐ₂₁₃₇ | O | Q₁ | Q₁ | Q₂₁ | Q₁ | O | Q₄ | Q₁ | Q₁ |
| Lₐ₂₁₃₈ | O | Q₁ | Q₁ | Q₂₂ | Q₁ | O | Q₄ | Q₁ | Q₁ |
| Lₐ₂₁₃₉ | O | Q₁ | Q₁ | Q₂₃ | Q₁ | O | Q₄ | Q₁ | Q₁ |
| Lₐ₂₁₄₀ | O | Q₁ | Q₂ | Q₁ | Q₁ | O | Q₆ | Q₁ | Q₁ |
| Lₐ₂₁₄₁ | O | Q₁ | Q₃ | Q₁ | Q₁ | O | Q₆ | Q₁ | Q₁ |
| Lₐ₂₁₄₂ | O | Q₁ | Q₄ | Q₁ | Q₁ | O | Q₆ | Q₁ | Q₁ |
| Lₐ₂₁₄₃ | O | Q₁ | Q₅ | Q₁ | Q₁ | O | Q₆ | Q₁ | Q₁ |
| Lₐ₂₁₄₄ | O | Q₁ | Q₆ | Q₁ | Q₁ | O | Q₆ | Q₁ | Q₁ |
| Lₐ₂₁₄₅ | O | Q₁ | Q₇ | Q₁ | Q₁ | O | Q₆ | Q₁ | Q₁ |
| Lₐ₂₁₄₆ | O | Q₁ | Q₈ | Q₁ | Q₁ | O | Q₆ | Q₁ | Q₁ |
| Lₐ₂₁₄₇ | O | Q₁ | Q₉ | Q₁ | Q₁ | O | Q₆ | Q₁ | Q₁ |
| Lₐ₂₁₄₈ | O | Q₁ | Q₁₀ | Q₁ | Q₁ | O | Q₆ | Q₁ | Q₁ |
| Lₐ₂₁₄₉ | O | Q₁ | Q₁₁ | Q₁ | Q₁ | O | Q₆ | Q₁ | Q₁ |
| Lₐ₂₁₅₀ | O | Q₁ | Q₁₂ | Q₁ | Q₁ | O | Q₆ | Q₁ | Q₁ |
| Lₐ₂₁₅₁ | O | Q₁ | Q₁₃ | Q₁ | Q₁ | O | Q₆ | Q₁ | Q₁ |
| Lₐ₂₁₅₂ | O | Q₁ | Q₁₄ | Q₁ | Q₁ | O | Q₆ | Q₁ | Q₁ |
| Lₐ₂₁₅₃ | O | Q₁ | Q₁₅ | Q₁ | Q₁ | O | Q₆ | Q₁ | Q₁ |
| Lₐ₂₁₅₄ | O | Q₁ | Q₁₆ | Q₁ | Q₁ | O | Q₆ | Q₁ | Q₁ |
| Lₐ₂₁₅₅ | O | Q₁ | Q₁₇ | Q₁ | Q₁ | O | Q₆ | Q₁ | Q₁ |
| Lₐ₂₁₅₆ | O | Q₁ | Q₁₈ | Q₁ | Q₁ | O | Q₆ | Q₁ | Q₁ |
| Lₐ₂₁₅₇ | O | Q₁ | Q₁₉ | Q₁ | Q₁ | O | Q₆ | Q₁ | Q₁ |
| Lₐ₂₁₅₈ | O | Q₁ | Q₂₀ | Q₁ | Q₁ | O | Q₆ | Q₁ | Q₁ |
| Lₐ₂₁₅₉ | O | Q₁ | Q₂₁ | Q₁ | Q₁ | O | Q₆ | Q₁ | Q₁ |
| Lₐ₂₁₆₀ | O | Q₁ | Q₂₂ | Q₁ | Q₁ | O | Q₆ | Q₁ | Q₁ |
| Lₐ₂₁₆₁ | O | Q₁ | Q₂₃ | Q₁ | Q₁ | O | Q₆ | Q₁ | Q₁ |
| Lₐ₂₁₆₂ | O | Q₁ | Q₁ | Q₁ | Q₁ | O | Q₆ | Q₁ | Q₁ |
| Lₐ₂₁₆₃ | O | Q₁ | Q₁ | Q₃ | Q₁ | O | Q₆ | Q₁ | Q₁ |
| Lₐ₂₁₆₄ | O | Q₁ | Q₁ | Q₄ | Q₁ | O | Q₆ | Q₁ | Q₁ |
| Lₐ₂₁₆₅ | O | Q₁ | Q₁ | Q₅ | Q₁ | O | Q₆ | Q₁ | Q₁ |
| Lₐ₂₁₆₆ | O | Q₁ | Q₁ | Q₆ | Q₁ | O | Q₆ | Q₁ | Q₁ |
| Lₐ₂₁₆₇ | O | Q₁ | Q₁ | Q₇ | Q₁ | O | Q₆ | Q₁ | Q₁ |
| Lₐ₂₁₆₈ | O | Q₁ | Q₁ | Q₈ | Q₁ | O | Q₆ | Q₁ | Q₁ |
| Lₐ₂₁₆₉ | O | Q₁ | Q₁ | Q₉ | Q₁ | O | Q₆ | Q₁ | Q₁ |
| Lₐ₂₁₇₀ | O | Q₁ | Q₁ | Q₁₀ | Q₁ | O | Q₆ | Q₁ | Q₁ |
| Lₐ₂₁₇₁ | O | Q₁ | Q₁ | Q₁₁ | Q₁ | O | Q₆ | Q₁ | Q₁ |
| Lₐ₂₁₇₂ | O | Q₁ | Q₁ | Q₁₂ | Q₁ | O | Q₆ | Q₁ | Q₁ |
| Lₐ₂₁₇₃ | O | Q₁ | Q₁ | Q₁₃ | Q₁ | O | Q₆ | Q₁ | Q₁ |
| Lₐ₂₁₇₄ | O | Q₁ | Q₁ | Q₁₄ | Q₁ | O | Q₆ | Q₁ | Q₁ |
| Lₐ₂₁₇₅ | O | Q₁ | Q₁ | Q₁₅ | Q₁ | O | Q₆ | Q₁ | Q₁ |
| Lₐ₂₁₇₆ | O | Q₁ | Q₁ | Q₁₆ | Q₁ | O | Q₆ | Q₁ | Q₁ |
| Lₐ₂₁₇₇ | O | Q₁ | Q₁ | Q₁₇ | Q₁ | O | Q₆ | Q₁ | Q₁ |
| Lₐ₂₁₇₈ | O | Q₁ | Q₁ | Q₁₈ | Q₁ | O | Q₆ | Q₁ | Q₁ |
| Lₐ₂₁₇₉ | O | Q₁ | Q₁ | Q₁₉ | Q₁ | O | Q₆ | Q₁ | Q₁ |
| Lₐ₂₁₈₀ | O | Q₁ | Q₁ | Q₂₀ | Q₁ | O | Q₆ | Q₁ | Q₁ |
| Lₐ₂₁₈₁ | O | Q₁ | Q₁ | Q₂₁ | Q₁ | O | Q₆ | Q₁ | Q₁ |
| Lₐ₂₁₈₂ | O | Q₁ | Q₁ | Q₂₂ | Q₁ | O | Q₆ | Q₁ | Q₁ |
| Lₐ₂₁₈₃ | O | Q₁ | Q₁ | Q₂₃ | Q₁ | O | Q₆ | Q₁ | Q₁ |
| Lₐ₂₁₈₄ | O | Q₁ | Q₂ | Q₁ | Q₁ | O | Q₇ | Q₁ | Q₁ |
| Lₐ₂₁₈₅ | O | Q₁ | Q₃ | Q₁ | Q₁ | O | Q₇ | Q₁ | Q₁ |
| Lₐ₂₁₈₆ | O | Q₁ | Q₄ | Q₁ | Q₁ | O | Q₇ | Q₁ | Q₁ |
| Lₐ₂₁₈₇ | O | Q₁ | Q₅ | Q₁ | Q₁ | O | Q₇ | Q₁ | Q₁ |
| Lₐ₂₁₈₈ | O | Q₁ | Q₆ | Q₁ | Q₁ | O | Q₇ | Q₁ | Q₁ |
| Lₐ₂₁₈₉ | O | Q₁ | Q₇ | Q₁ | Q₁ | O | Q₇ | Q₁ | Q₁ |
| Lₐ₂₁₉₀ | O | Q₁ | Q₈ | Q₁ | Q₁ | O | Q₇ | Q₁ | Q₁ |
| Lₐ₂₁₉₁ | O | Q₁ | Q₉ | Q₁ | Q₁ | O | Q₇ | Q₁ | Q₁ |
| Lₐ₂₁₉₂ | O | Q₁ | Q₁₀ | Q₁ | Q₁ | O | Q₇ | Q₁ | Q₁ |
| Lₐ₂₁₉₃ | O | Q₁ | Q₁₁ | Q₁ | Q₁ | O | Q₇ | Q₁ | Q₁ |
| Lₐ₂₁₉₄ | O | Q₁ | Q₁₂ | Q₁ | Q₁ | O | Q₇ | Q₁ | Q₁ |
| Lₐ₂₁₉₅ | O | Q₁ | Q₁₃ | Q₁ | Q₁ | O | Q₇ | Q₁ | Q₁ |
| Lₐ₂₁₉₆ | O | Q₁ | Q₁₄ | Q₁ | Q₁ | O | Q₇ | Q₁ | Q₁ |
| Lₐ₂₁₉₇ | O | Q₁ | Q₁₅ | Q₁ | Q₁ | O | Q₇ | Q₁ | Q₁ |
| Lₐ₂₁₉₈ | O | Q₁ | Q₁₆ | Q₁ | Q₁ | O | Q₇ | Q₁ | Q₁ |
| Lₐ₂₁₉₉ | O | Q₁ | Q₁₇ | Q₁ | Q₁ | O | Q₇ | Q₁ | Q₁ |
| Lₐ₂₂₀₀ | O | Q₁ | Q₁₈ | Q₁ | Q₁ | O | Q₇ | Q₁ | Q₁ |
| Lₐ₂₂₀₁ | O | Q₁ | Q₁₉ | Q₁ | Q₁ | O | Q₇ | Q₁ | Q₁ |
| Lₐ₂₂₀₂ | O | Q₁ | Q₂₀ | Q₁ | Q₁ | O | Q₇ | Q₁ | Q₁ |
| Lₐ₂₂₀₃ | O | Q₁ | Q₂₁ | Q₁ | Q₁ | O | Q₇ | Q₁ | Q₁ |
| Lₐ₂₂₀₄ | O | Q₁ | Q₂₂ | Q₁ | Q₁ | O | Q₇ | Q₁ | Q₁ |
| Lₐ₂₂₀₅ | O | Q₁ | Q₂₃ | Q₁ | Q₁ | O | Q₇ | Q₁ | Q₁ |
| Lₐ₂₂₀₆ | O | Q₁ | Q₁ | Q₂ | Q₁ | O | Q₇ | Q₁ | Q₁ |
| Lₐ₂₂₀₇ | O | Q₁ | Q₁ | Q₃ | Q₁ | O | Q₇ | Q₁ | Q₁ |
| Lₐ₂₂₀₈ | O | Q₁ | Q₁ | Q₄ | Q₁ | O | Q₇ | Q₁ | Q₁ |
| Lₐ₂₂₀₉ | O | Q₁ | Q₁ | Q₅ | Q₁ | O | Q₇ | Q₁ | Q₁ |
| Lₐ₂₂₁₀ | O | Q₁ | Q₁ | Q₆ | Q₁ | O | Q₇ | Q₁ | Q₁ |
| Lₐ₂₂₁₁ | O | Q₁ | Q₁ | Q₇ | Q₁ | O | Q₇ | Q₁ | Q₁ |
| Lₐ₂₂₁₂ | O | Q₁ | Q₁ | Q₈ | Q₁ | O | Q₇ | Q₁ | Q₁ |
| Lₐ₂₂₁₃ | O | Q₁ | Q₁ | Q₉ | Q₁ | O | Q₇ | Q₁ | Q₁ |
| Lₐ₂₂₁₄ | O | Q₁ | Q₁ | Q₁₀ | Q₁ | O | Q₇ | Q₁ | Q₁ |
| Lₐ₂₂₁₅ | O | Q₁ | Q₁ | Q₁₁ | Q₁ | O | Q₇ | Q₁ | Q₁ |
| Lₐ₂₂₁₆ | O | Q₁ | Q₁ | Q₁₂ | Q₁ | O | Q₇ | Q₁ | Q₁ |
| Lₐ₂₂₁₇ | O | Q₁ | Q₁ | Q₁₃ | Q₁ | O | Q₇ | Q₁ | Q₁ |
| Lₐ₂₂₁₈ | O | Q₁ | Q₁ | Q₁₄ | Q₁ | O | Q₇ | Q₁ | Q₁ |
| Lₐ₂₂₁₉ | O | Q₁ | Q₁ | Q₁₅ | Q₁ | O | Q₇ | Q₁ | Q₁ |
| Lₐ₂₂₂₀ | O | Q₁ | Q₁ | Q₁₆ | Q₁ | O | Q₇ | Q₁ | Q₁ |
| Lₐ₂₂₂₁ | O | Q₁ | Q₁ | Q₁₇ | Q₁ | O | Q₇ | Q₁ | Q₁ |
| Lₐ₂₂₂₂ | O | Q₁ | Q₁ | Q₁₈ | Q₁ | O | Q₇ | Q₁ | Q₁ |
| Lₐ₂₂₂₃ | O | Q₁ | Q₁ | Q₁₉ | Q₁ | O | Q₇ | Q₁ | Q₁ |
| Lₐ₂₂₂₄ | O | Q₁ | Q₁ | Q₂₀ | Q₁ | O | Q₇ | Q₁ | Q₁ |
| Lₐ₂₂₂₅ | O | Q₁ | Q₁ | Q₂₁ | Q₁ | O | Q₇ | Q₁ | Q₁ |
| Lₐ₂₂₂₆ | O | Q₁ | Q₁ | Q₂₂ | Q₁ | O | Q₇ | Q₁ | Q₁ |
| Lₐ₂₂₂₇ | O | Q₁ | Q₁ | Q₂₃ | Q₁ | O | Q₇ | Q₁ | Q₁ |
| Lₐ₂₂₂₈ | O | Q₁ | Q₂ | Q₁ | Q₁ | O | Q₈ | Q₁ | Q₁ |
| Lₐ₂₂₂₉ | O | Q₁ | Q₃ | Q₁ | Q₁ | O | Q₈ | Q₁ | Q₁ |
| Lₐ₂₂₃₀ | O | Q₁ | Q₄ | Q₁ | Q₁ | O | Q₈ | Q₁ | Q₁ |
| Lₐ₂₂₃₁ | O | Q₁ | Q₅ | Q₁ | Q₁ | O | Q₈ | Q₁ | Q₁ |
| Lₐ₂₂₃₂ | O | Q₁ | Q₆ | Q₁ | Q₁ | O | Q₈ | Q₁ | Q₁ |
| Lₐ₂₂₃₃ | O | Q₁ | Q₇ | Q₁ | Q₁ | O | Q₈ | Q₁ | Q₁ |
| Lₐ₂₂₃₄ | O | Q₁ | Q₈ | Q₁ | Q₁ | O | Q₈ | Q₁ | Q₁ |
| Lₐ₂₂₃₅ | O | Q₁ | Q₉ | Q₁ | Q₁ | O | Q₈ | Q₁ | Q₁ |
| Lₐ₂₂₃₆ | O | Q₁ | Q₁₀ | Q₁ | Q₁ | O | Q₈ | Q₁ | Q₁ |
| Lₐ₂₂₃₇ | O | Q₁ | Q₁₁ | Q₁ | Q₁ | O | Q₈ | Q₁ | Q₁ |
| Lₐ₂₂₃₈ | O | Q₁ | Q₁₂ | Q₁ | Q₁ | O | Q₈ | Q₁ | Q₁ |
| Lₐ₂₂₃₉ | O | Q₁ | Q₁₃ | Q₁ | Q₁ | O | Q₈ | Q₁ | Q₁ |
| Lₐ₂₂₄₀ | O | Q₁ | Q₁₄ | Q₁ | Q₁ | O | Q₈ | Q₁ | Q₁ |
| Lₐ₂₂₄₁ | O | Q₁ | Q₁₅ | Q₁ | Q₁ | O | Q₈ | Q₁ | Q₁ |
| Lₐ₂₂₄₂ | O | Q₁ | Q₁₆ | Q₁ | Q₁ | O | Q₈ | Q₁ | Q₁ |
| Lₐ₂₂₄₃ | O | Q₁ | Q₁₇ | Q₁ | Q₁ | O | Q₈ | Q₁ | Q₁ |
| Lₐ₂₂₄₄ | O | Q₁ | Q₁₈ | Q₁ | Q₁ | O | Q₈ | Q₁ | Q₁ |
| Lₐ₂₂₄₅ | O | Q₁ | Q₁₉ | Q₁ | Q₁ | O | Q₈ | Q₁ | Q₁ |
| Lₐ₂₂₄₆ | O | Q₁ | Q₂₀ | Q₁ | Q₁ | O | Q₈ | Q₁ | Q₁ |
| Lₐ₂₂₄₇ | O | Q₁ | Q₂₁ | Q₁ | Q₁ | O | Q₈ | Q₁ | Q₁ |
| Lₐ₂₂₄₈ | O | Q₁ | Q₂₂ | Q₁ | Q₁ | O | Q₈ | Q₁ | Q₁ |
| Lₐ₂₂₄₉ | O | Q₁ | Q₂₃ | Q₁ | Q₁ | O | Q₈ | Q₁ | Q₁ |
| Lₐ₂₂₅₀ | O | Q₁ | Q₁ | Q₂ | Q₁ | O | Q₈ | Q₁ | Q₁ |
| Lₐ₂₂₅₁ | O | Q₁ | Q₁ | Q₃ | Q₁ | O | Q₈ | Q₁ | Q₁ |
| Lₐ₂₂₅₂ | O | Q₁ | Q₁ | Q₄ | Q₁ | O | Q₈ | Q₁ | Q₁ |
| Lₐ₂₂₅₃ | O | Q₁ | Q₁ | Q₅ | Q₁ | O | Q₈ | Q₁ | Q₁ |
| Lₐ₂₂₅₄ | O | Q₁ | Q₁ | Q₆ | Q₁ | O | Q₈ | Q₁ | Q₁ |
| Lₐ₂₂₅₅ | O | Q₁ | Q₁ | Q₇ | Q₁ | O | Q₈ | Q₁ | Q₁ |
| Lₐ₂₂₅₆ | O | Q₁ | Q₁ | Q₈ | Q₁ | O | Q₈ | Q₁ | Q₁ |
| Lₐ₂₂₅₇ | O | Q₁ | Q₁ | Q₉ | Q₁ | O | Q₈ | Q₁ | Q₁ |
| Lₐ₂₂₅₈ | O | Q₁ | Q₁ | Q₁₀ | Q₁ | O | Q₈ | Q₁ | Q₁ |
| Lₐ₂₂₅₉ | O | Q₁ | Q₁ | Q₁₁ | Q₁ | O | Q₈ | Q₁ | Q₁ |
| Lₐ₂₂₆₀ | O | Q₁ | Q₁ | Q₁₂ | Q₁ | O | Q₈ | Q₁ | Q₁ |
| Lₐ₂₂₆₁ | O | Q₁ | Q₁ | Q₁₃ | Q₁ | O | Q₈ | Q₁ | Q₁ |
| Lₐ₂₂₆₂ | O | Q₁ | Q₁ | Q₁₄ | Q₁ | O | Q₈ | Q₁ | Q₁ |
| Lₐ₂₂₆₃ | O | Q₁ | Q₁ | Q₁₅ | Q₁ | O | Q₈ | Q₁ | Q₁ |
| Lₐ₂₂₆₄ | O | Q₁ | Q₁ | Q₁₆ | Q₁ | O | Q₈ | Q₁ | Q₁ |
| Lₐ₂₂₆₅ | O | Q₁ | Q₁ | Q₁₇ | Q₁ | O | Q₈ | Q₁ | Q₁ |
| Lₐ₂₂₆₆ | O | Q₁ | Q₁ | Q₁₈ | Q₁ | O | Q₈ | Q₁ | Q₁ |
| Lₐ₂₂₆₇ | O | Q₁ | Q₁ | Q₁₉ | Q₁ | O | Q₈ | Q₁ | Q₁ |
| Lₐ₂₂₆₈ | O | Q₁ | Q₁ | Q₂₀ | Q₁ | O | Q₈ | Q₁ | Q₁ |
| Lₐ₂₂₆₉ | O | Q₁ | Q₁ | Q₂₁ | Q₁ | O | Q₈ | Q₁ | Q₁ |
| Lₐ₂₂₇₀ | O | Q₁ | Q₁ | Q₂₂ | Q₁ | O | Q₈ | Q₁ | Q₁ |
| Lₐ₂₂₇₁ | O | Q₁ | Q₁ | Q₂₃ | Q₁ | O | Q₈ | Q₁ | Q₁ |
| Lₐ₂₂₇₂ | O | Q₁ | Q₂ | Q₁ | Q₁ | O | Q₈ | Q₄ | Q₁ |
| Lₐ₂₂₇₃ | O | Q₁ | Q₃ | Q₁ | Q₁ | O | Q₈ | Q₄ | Q₁ |
| Lₐ₂₂₇₄ | O | Q₁ | Q₄ | Q₁ | Q₁ | O | Q₈ | Q₄ | Q₁ |
| Lₐ₂₂₇₅ | O | Q₁ | Q₅ | Q₁ | Q₁ | O | Q₈ | Q₄ | Q₁ |
| Lₐ₂₂₇₆ | O | Q₁ | Q₆ | Q₁ | Q₁ | O | Q₈ | Q₄ | Q₁ |
| Lₐ₂₂₇₇ | O | Q₁ | Q₇ | Q₁ | Q₁ | O | Q₈ | Q₄ | Q₁ |
| Lₐ₂₂₇₈ | O | Q₁ | Q₈ | Q₁ | Q₁ | O | Q₈ | Q₄ | Q₁ |
| Lₐ₂₂₇₉ | O | Q₁ | Q₉ | Q₁ | Q₁ | O | Q₈ | Q₄ | Q₁ |
| Lₐ₂₂₈₀ | O | Q₁ | Q₁₀ | Q₁ | Q₁ | O | Q₈ | Q₄ | Q₁ |
| Lₐ₂₂₈₁ | O | Q₁ | Q₁₁ | Q₁ | Q₁ | O | Q₈ | Q₄ | Q₁ |
| Lₐ₂₂₈₂ | O | Q₁ | Q₁₂ | Q₁ | Q₁ | O | Q₈ | Q₄ | Q₁ |
| Lₐ₂₂₈₃ | O | Q₁ | Q₁₃ | Q₁ | Q₁ | O | Q₈ | Q₄ | Q₁ |
| Lₐ₂₂₈₄ | O | Q₁ | Q₁₄ | Q₁ | Q₁ | O | Q₈ | Q₄ | Q₁ |
| Lₐ₂₂₈₅ | O | Q₁ | Q₁₅ | Q₁ | Q₁ | O | Q₈ | Q₄ | Q₁ |
| Lₐ₂₂₈₆ | O | Q₁ | Q₁₆ | Q₁ | Q₁ | O | Q₈ | Q₄ | Q₁ |
| Lₐ₂₂₈₇ | O | Q₁ | Q₁₇ | Q₁ | Q₁ | O | Q₈ | Q₄ | Q₁ |
| Lₐ₂₂₈₈ | O | Q₁ | Q₁₈ | Q₁ | Q₁ | O | Q₈ | Q₄ | Q₁ |
| Lₐ₂₂₈₉ | O | Q₁ | Q₁₉ | Q₁ | Q₁ | O | Q₈ | Q₄ | Q₁ |
| Lₐ₂₂₉₀ | O | Q₁ | Q₂₀ | Q₁ | Q₁ | O | Q₈ | Q₄ | Q₁ |
| Lₐ₂₂₉₁ | O | Q₁ | Q₂₁ | Q₁ | Q₁ | O | Q₈ | Q₄ | Q₁ |
| Lₐ₂₂₉₂ | O | Q₁ | Q₂₂ | Q₁ | Q₁ | O | Q₈ | Q₄ | Q₁ |
| Lₐ₂₂₉₃ | O | Q₁ | Q₂₃ | Q₁ | Q₁ | O | Q₈ | Q₄ | Q₁ |
| Lₐ₂₂₉₄ | O | Q₁ | Q₁ | Q₂ | Q₁ | O | Q₈ | Q₄ | Q₁ |
| Lₐ₂₂₉₅ | O | Q₁ | Q₁ | Q₃ | Q₁ | O | Q₈ | Q₄ | Q₁ |
| Lₐ₂₂₉₆ | O | Q₁ | Q₁ | Q₄ | Q₁ | O | Q₈ | Q₄ | Q₁ |
| Lₐ₂₂₉₇ | O | Q₁ | Q₁ | Q₅ | Q₁ | O | Q₈ | Q₄ | Q₁ |
| Lₐ₂₂₉₈ | O | Q₁ | Q₁ | Q₆ | Q₁ | O | Q₈ | Q₄ | Q₁ |
| Lₐ₂₂₉₉ | O | Q₁ | Q₁ | Q₇ | Q₁ | O | Q₈ | Q₄ | Q₁ |
| Lₐ₂₃₀₀ | O | Q₁ | Q₁ | Q₈ | Q₁ | O | Q₈ | Q₄ | Q₁ |
| Lₐ₂₃₀₁ | O | Q₁ | Q₁ | Q₉ | Q₁ | O | Q₈ | Q₄ | Q₁ |
| Lₐ₂₃₀₂ | O | Q₁ | Q₁ | Q₁₀ | Q₁ | O | Q₈ | Q₄ | Q₁ |
| Lₐ₂₃₀₃ | O | Q₁ | Q₁ | Q₁₁ | Q₁ | O | Q₈ | Q₄ | Q₁ |
| Lₐ₂₃₀₄ | O | Q₁ | Q₁ | Q₁₂ | Q₁ | O | Q₈ | Q₄ | Q₁ |
| Lₐ₂₃₀₅ | O | Q₁ | Q₁ | Q₁₃ | Q₁ | O | Q₈ | Q₄ | Q₁ |
| Lₐ₂₃₀₆ | O | Q₁ | Q₁ | Q₁₄ | Q₁ | O | Q₈ | Q₄ | Q₁ |
| Lₐ₂₃₀₇ | O | Q₁ | Q₁ | Q₁₅ | Q₁ | O | Q₈ | Q₄ | Q₁ |
| Lₐ₂₃₀₈ | O | Q₁ | Q₁ | Q₁₆ | Q₁ | O | Q₈ | Q₄ | Q₁ |
| Lₐ₂₃₀₉ | O | Q₁ | Q₁ | Q₁₇ | Q₁ | O | Q₈ | Q₄ | Q₁ |
| Lₐ₂₃₁₀ | O | Q₁ | Q₁ | Q₁₈ | Q₁ | O | Q₈ | Q₄ | Q₁ |
| Lₐ₂₃₁₁ | O | Q₁ | Q₁ | Q₁₉ | Q₁ | O | Q₈ | Q₄ | Q₁ |
| Lₐ₂₃₁₂ | O | Q₁ | Q₁ | Q₂₀ | Q₁ | O | Q₈ | Q₄ | Q₁ |
| Lₐ₂₃₁₃ | O | Q₁ | Q₁ | Q₂₁ | Q₁ | O | Q₈ | Q₄ | Q₁ |
| Lₐ₂₃₁₄ | O | Q₁ | Q₁ | Q₂₂ | Q₁ | O | Q₈ | Q₄ | Q₁ |
| Lₐ₂₃₁₅ | O | Q₁ | Q₁ | Q₂₃ | Q₁ | O | Q₈ | Q₄ | Q₁ |
| Lₐ₂₃₁₆ | O | Q₁ | Q₂ | Q₁ | Q₁ | O | Q₈ | Q₁ | Q₄ |
| Lₐ₂₃₁₇ | O | Q₁ | Q₃ | Q₁ | Q₁ | O | Q₈ | Q₁ | Q₄ |
| Lₐ₂₃₁₈ | O | Q₁ | Q₄ | Q₁ | Q₁ | O | Q₈ | Q₁ | Q₄ |
| Lₐ₂₃₁₉ | O | Q₁ | Q₅ | Q₁ | Q₁ | O | Q₈ | Q₁ | Q₄ |
| Lₐ₂₃₂₀ | O | Q₁ | Q₆ | Q₁ | Q₁ | O | Q₈ | Q₁ | Q₄ |
| Lₐ₂₃₂₁ | O | Q₁ | Q₇ | Q₁ | Q₁ | O | Q₈ | Q₁ | Q₄ |
| Lₐ₂₃₂₂ | O | Q₁ | Q₈ | Q₁ | Q₁ | O | Q₈ | Q₁ | Q₄ |
| Lₐ₂₃₂₃ | O | Q₁ | Q₉ | Q₁ | Q₁ | O | Q₈ | Q₁ | Q₄ |
| Lₐ₂₃₂₄ | O | Q₁ | Q₁₀ | Q₁ | Q₁ | O | Q₈ | Q₁ | Q₄ |
| Lₐ₂₃₂₅ | O | Q₁ | Q₁₁ | Q₁ | Q₁ | O | Q₈ | Q₁ | Q₄ |
| Lₐ₂₃₂₆ | O | Q₁ | Q₁₂ | Q₁ | Q₁ | O | Q₈ | Q₁ | Q₄ |
| Lₐ₂₃₂₇ | O | Q₁ | Q₁₃ | Q₁ | Q₁ | O | Q₈ | Q₁ | Q₄ |
| Lₐ₂₃₂₈ | O | Q₁ | Q₁₄ | Q₁ | Q₁ | O | Q₈ | Q₁ | Q₄ |
| Lₐ₂₃₂₉ | O | Q₁ | Q₁₅ | Q₁ | Q₁ | O | Q₈ | Q₁ | Q₄ |
| Lₐ₂₃₃₀ | O | Q₁ | Q₁₆ | Q₁ | Q₁ | O | Q₈ | Q₁ | Q₄ |
| Lₐ₂₃₃₁ | O | Q₁ | Q₁₇ | Q₁ | Q₁ | O | Q₈ | Q₁ | Q₄ |
| Lₐ₂₃₃₂ | O | Q₁ | Q₁₈ | Q₁ | Q₁ | O | Q₈ | Q₁ | Q₄ |
| Lₐ₂₃₃₃ | O | Q₁ | Q₁₉ | Q₁ | Q₁ | O | Q₈ | Q₁ | Q₄ |
| Lₐ₂₃₃₄ | O | Q₁ | Q₂₀ | Q₁ | Q₁ | O | Q₈ | Q₁ | Q₄ |
| Lₐ₂₃₃₅ | O | Q₁ | Q₂₁ | Q₁ | Q₁ | O | Q₈ | Q₁ | Q₄ |
| Lₐ₂₃₃₆ | O | Q₁ | Q₂₂ | Q₁ | Q₁ | O | Q₈ | Q₁ | Q₄ |
| Lₐ₂₃₃₇ | O | Q₁ | Q₂₃ | Q₁ | Q₁ | O | Q₈ | Q₁ | Q₄ |
| Lₐ₂₃₃₈ | O | Q₁ | Q₁ | Q₂ | Q₁ | O | Q₈ | Q₁ | Q₄ |
| Lₐ₂₃₃₉ | O | Q₁ | Q₁ | Q₃ | Q₁ | O | Q₈ | Q₁ | Q₄ |
| Lₐ₂₃₄₀ | O | Q₁ | Q₁ | Q₄ | Q₁ | O | Q₈ | Q₁ | Q₄ |
| Lₐ₂₃₄₁ | O | Q₁ | Q₁ | Q₅ | Q₁ | O | Q₈ | Q₁ | Q₄ |
| Lₐ₂₃₄₂ | O | Q₁ | Q₁ | Q₆ | Q₁ | O | Q₈ | Q₁ | Q₄ |
| Lₐ₂₃₄₃ | O | Q₁ | Q₁ | Q₇ | Q₁ | O | Q₈ | Q₁ | Q₄ |
| Lₐ₂₃₄₄ | O | Q₁ | Q₁ | Q₈ | Q₁ | O | Q₈ | Q₁ | Q₄ |
| Lₐ₂₃₄₅ | O | Q₁ | Q₁ | Q₉ | Q₁ | O | Q₈ | Q₁ | Q₄ |
| Lₐ₂₃₄₆ | O | Q₁ | Q₁ | Q₁₀ | Q₁ | O | Q₈ | Q₁ | Q₄ |
| Lₐ₂₃₄₇ | O | Q₁ | Q₁ | Q₁₁ | Q₁ | O | Q₈ | Q₁ | Q₄ |
| Lₐ₂₃₄₈ | O | Q₁ | Q₁ | Q₁₂ | Q₁ | O | Q₈ | Q₁ | Q₄ |
| Lₐ₂₃₄₉ | O | Q₁ | Q₁ | Q₁₃ | Q₁ | O | Q₈ | Q₁ | Q₄ |
| Lₐ₂₃₅₀ | O | Q₁ | Q₁ | Q₁₄ | Q₁ | O | Q₈ | Q₁ | Q₄ |
| Lₐ₂₃₅₁ | O | Q₁ | Q₁ | Q₁₅ | Q₁ | O | Q₈ | Q₁ | Q₄ |
| Lₐ₂₃₅₂ | O | Q₁ | Q₁ | Q₁₆ | Q₁ | O | Q₈ | Q₁ | Q₄ |
| Lₐ₂₃₅₃ | O | Q₁ | Q₁ | Q₁₇ | Q₁ | O | Q₈ | Q₁ | Q₄ |
| Lₐ₂₃₅₄ | O | Q₁ | Q₁ | Q₁₈ | Q₁ | O | Q₈ | Q₁ | Q₄ |
| Lₐ₂₃₅₅ | O | Q₁ | Q₁ | Q₁₉ | Q₁ | O | Q₈ | Q₁ | Q₄ |
| Lₐ₂₃₅₆ | O | Q₁ | Q₁ | Q₂₀ | Q₁ | O | Q₈ | Q₁ | Q₄ |
| Lₐ₂₃₅₇ | O | Q₁ | Q₁ | Q₂₁ | Q₁ | O | Q₈ | Q₁ | Q₄ |
| Lₐ₂₃₅₈ | O | Q₁ | Q₁ | Q₂₂ | Q₁ | O | Q₈ | Q₁ | Q₄ |
| Lₐ₂₃₅₉ | O | Q₁ | Q₁ | Q₂₃ | Q₁ | O | Q₈ | Q₁ | Q₄ |
| Lₐ₂₃₆₀ | O | Q₁ | Q₂ | Q₁ | Q₁ | O | Q₈ | Q₁ | Q₁ |
| Lₐ₂₃₆₁ | O | Q₁ | Q₃ | Q₁ | Q₁ | O | Q₈ | Q₁ | Q₁ |
| Lₐ₂₃₆₂ | O | Q₁ | Q₄ | Q₁ | Q₁ | O | Q₈ | Q₁ | Q₁ |
| Lₐ₂₃₆₃ | O | Q₁ | Q₅ | Q₁ | Q₁ | O | Q₈ | Q₁ | Q₁ |
| Lₐ₂₃₆₄ | O | Q₁ | Q₆ | Q₁ | Q₁ | O | Q₈ | Q₁ | Q₁ |
| Lₐ₂₃₆₅ | O | Q₁ | Q₇ | Q₁ | Q₁ | O | Q₈ | Q₁ | Q₁ |
| Lₐ₂₃₆₆ | O | Q₁ | Q₈ | Q₁ | Q₁ | O | Q₈ | Q₁ | Q₁ |
| Lₐ₂₃₆₇ | O | Q₁ | Q₉ | Q₁ | Q₁ | O | Q₈ | Q₁ | Q₁ |
| Lₐ₂₃₆₈ | O | Q₁ | Q₁₀ | Q₁ | Q₁ | O | Q₈ | Q₁ | Q₁ |
| Lₐ₂₃₆₉ | O | Q₁ | Q₁₁ | Q₁ | Q₁ | O | Q₈ | Q₁ | Q₁ |
| Lₐ₂₃₇₀ | O | Q₁ | Q₁₂ | Q₁ | Q₁ | O | Q₈ | Q₁ | Q₁ |
| Lₐ₂₃₇₁ | O | Q₁ | Q₁₃ | Q₁ | Q₁ | O | Q₈ | Q₁ | Q₁ |
| Lₐ₂₃₇₂ | O | Q₁ | Q₁₄ | Q₁ | Q₁ | O | Q₈ | Q₁ | Q₁ |
| Lₐ₂₃₇₃ | O | Q₁ | Q₁₅ | Q₁ | Q₁ | O | Q₈ | Q₁ | Q₁ |
| Lₐ₂₃₇₄ | O | Q₁ | Q₁₆ | Q₁ | Q₁ | O | Q₈ | Q₁ | Q₁ |
| Lₐ₂₃₇₅ | O | Q₁ | Q₁₇ | Q₁ | Q₁ | O | Q₈ | Q₁ | Q₁ |
| Lₐ₂₃₇₆ | O | Q₁ | Q₁₈ | Q₁ | Q₁ | O | Q₈ | Q₁ | Q₁ |
| Lₐ₂₃₇₇ | O | Q₁ | Q₁₉ | Q₁ | Q₁ | O | Q₈ | Q₁ | Q₁ |
| Lₐ₂₃₇₈ | O | Q₁ | Q₂₀ | Q₁ | Q₁ | O | Q₈ | Q₁ | Q₁ |
| Lₐ₂₃₇₉ | O | Q₁ | Q₂₁ | Q₁ | Q₁ | O | Q₈ | Q₁ | Q₁ |
| Lₐ₂₃₈₀ | O | Q₁ | Q₂₂ | Q₁ | Q₁ | O | Q₈ | Q₁ | Q₁ |
| Lₐ₂₃₈₁ | O | Q₁ | Q₂₃ | Q₁ | Q₁ | O | Q₈ | Q₁ | Q₁ |
| Lₐ₂₃₈₂ | O | Q₁ | Q₁ | Q₂ | Q₁ | O | Q₈ | Q₁ | Q₁ |
| Lₐ₂₃₈₃ | O | Q₁ | Q₁ | Q₃ | Q₁ | O | Q₈ | Q₁ | Q₁ |
| Lₐ₂₃₈₄ | O | Q₁ | Q₁ | Q₄ | Q₁ | O | Q₈ | Q₁ | Q₁ |
| Lₐ₂₃₈₅ | O | Q₁ | Q₁ | Q₅ | Q₁ | O | Q₈ | Q₁ | Q₁ |
| Lₐ₂₃₈₆ | O | Q₁ | Q₁ | Q₆ | Q₁ | O | Q₈ | Q₁ | Q₁ |
| Lₐ₂₃₈₇ | O | Q₁ | Q₁ | Q₇ | Q₁ | O | Q₈ | Q₁ | Q₁ |
| Lₐ₂₃₈₈ | O | Q₁ | Q₁ | Q₈ | Q₁ | O | Q₈ | Q₁ | Q₁ |
| Lₐ₂₃₈₉ | O | Q₁ | Q₁ | Q₉ | Q₁ | O | Q₈ | Q₁ | Q₁ |
| Lₐ₂₃₉₀ | O | Q₁ | Q₁ | Q₁₀ | Q₁ | O | Q₈ | Q₁ | Q₁ |
| Lₐ₂₃₉₁ | O | Q₁ | Q₁ | Q₁₁ | Q₁ | O | Q₈ | Q₁ | Q₁ |
| Lₐ₂₃₉₂ | O | Q₁ | Q₁ | Q₁₂ | Q₁ | O | Q₈ | Q₁ | Q₁ |
| Lₐ₂₃₉₃ | O | Q₁ | Q₁ | Q₁₃ | Q₁ | O | Q₈ | Q₁ | Q₁ |
| Lₐ₂₃₉₄ | O | Q₁ | Q₁ | Q₁₄ | Q₁ | O | Q₈ | Q₁ | Q₁ |
| Lₐ₂₃₉₅ | O | Q₁ | Q₁ | Q₁₅ | Q₁ | O | Q₈ | Q₁ | Q₁ |
| Lₐ₂₃₉₆ | O | Q₁ | Q₁ | Q₁₆ | Q₁ | O | Q₈ | Q₁ | Q₁ |
| Lₐ₂₃₉₇ | O | Q₁ | Q₁ | Q₁₇ | Q₁ | O | Q₈ | Q₁ | Q₁ |
| Lₐ₂₃₉₈ | O | Q₁ | Q₁ | Q₁₈ | Q₁ | O | Q₈ | Q₁ | Q₁ |
| Lₐ₂₃₉₉ | O | Q₁ | Q₁ | Q₁₉ | Q₁ | O | Q₈ | Q₁ | Q₁ |
| Lₐ₂₄₀₀ | O | Q₁ | Q₁ | Q₂₀ | Q₁ | O | Q₈ | Q₁ | Q₁ |
| Lₐ₂₄₀₁ | O | Q₁ | Q₁ | Q₂₁ | Q₁ | O | Q₈ | Q₁ | Q₁ |
| Lₐ₂₄₀₂ | O | Q₁ | Q₁ | Q₂₂ | Q₁ | O | Q₈ | Q₁ | Q₁ |
| Lₐ₂₄₀₃ | O | Q₁ | Q₁ | Q₂₃ | Q₁ | O | Q₈ | Q₁ | Q₁ |
| Lₐ₂₄₀₄ | O | Q₁ | Q₂ | Q₁ | Q₁ | O | Q₄ | Q₁ | Q₄ |
| Lₐ₂₄₀₅ | O | Q₁ | Q₃ | Q₁ | Q₁ | O | Q₄ | Q₁ | Q₄ |
| Lₐ₂₄₀₆ | O | Q₁ | Q₄ | Q₁ | Q₁ | O | Q₄ | Q₁ | Q₄ |
| Lₐ₂₄₀₇ | O | Q₁ | Q₅ | Q₁ | Q₁ | O | Q₄ | Q₁ | Q₄ |
| Lₐ₂₄₀₈ | O | Q₁ | Q₆ | Q₁ | Q₁ | O | Q₄ | Q₁ | Q₄ |
| Lₐ₂₄₀₉ | O | Q₁ | Q₇ | Q₁ | Q₁ | O | Q₄ | Q₁ | Q₄ |
| Lₐ₂₄₁₀ | O | Q₁ | Q₈ | Q₁ | Q₁ | O | Q₄ | Q₁ | Q₄ |
| Lₐ₂₄₁₁ | O | Q₁ | Q₉ | Q₁ | Q₁ | O | Q₄ | Q₁ | Q₄ |
| Lₐ₂₄₁₂ | O | Q₁ | Q₁₀ | Q₁ | Q₁ | O | Q₄ | Q₁ | Q₄ |
| Lₐ₂₄₁₃ | O | Q₁ | Q₁₁ | Q₁ | Q₁ | O | Q₄ | Q₁ | Q₄ |
| Lₐ₂₄₁₄ | O | Q₁ | Q₁₂ | Q₁ | Q₁ | O | Q₄ | Q₁ | Q₄ |
| Lₐ₂₄₁₅ | O | Q₁ | Q₁₃ | Q₁ | Q₁ | O | Q₄ | Q₁ | Q₄ |
| Lₐ₂₄₁₆ | O | Q₁ | Q₁₄ | Q₁ | Q₁ | O | Q₄ | Q₁ | Q₄ |
| Lₐ₂₄₁₇ | O | Q₁ | Q₁₅ | Q₁ | Q₁ | O | Q₄ | Q₁ | Q₄ |
| Lₐ₂₄₁₈ | O | Q₁ | Q₁₆ | Q₁ | Q₁ | O | Q₄ | Q₁ | Q₄ |
| Lₐ₂₄₁₉ | O | Q₁ | Q₁₇ | Q₁ | Q₁ | O | Q₄ | Q₁ | Q₄ |
| Lₐ₂₄₂₀ | O | Q₁ | Q₁₈ | Q₁ | Q₁ | O | Q₄ | Q₁ | Q₄ |
| Lₐ₂₄₂₁ | O | Q₁ | Q₁₉ | Q₁ | Q₁ | O | Q₄ | Q₁ | Q₄ |
| Lₐ₂₄₂₂ | O | Q₁ | Q₂₀ | Q₁ | Q₁ | O | Q₄ | Q₁ | Q₄ |
| Lₐ₂₄₂₃ | O | Q₁ | Q₂₁ | Q₁ | Q₁ | O | Q₄ | Q₁ | Q₄ |
| Lₐ₂₄₂₄ | O | Q₁ | Q₂₂ | Q₁ | Q₁ | O | Q₄ | Q₁ | Q₄ |
| Lₐ₂₄₂₅ | O | Q₁ | Q₂₃ | Q₁ | Q₁ | O | Q₄ | Q₁ | Q₄ |
| Lₐ₂₄₂₆ | O | Q₁ | Q₁ | Q₂ | Q₁ | O | Q₄ | Q₁ | Q₄ |
| Lₐ₂₄₂₇ | O | Q₁ | Q₁ | Q₃ | Q₁ | O | Q₄ | Q₁ | Q₄ |
| Lₐ₂₄₂₈ | O | Q₁ | Q₁ | Q₄ | Q₁ | O | Q₄ | Q₁ | Q₄ |
| Lₐ₂₄₂₉ | O | Q₁ | Q₁ | Q₅ | Q₁ | O | Q₄ | Q₁ | Q₄ |
| Lₐ₂₄₃₀ | O | Q₁ | Q₁ | Q₆ | Q₁ | O | Q₄ | Q₁ | Q₄ |
| Lₐ₂₄₃₁ | O | Q₁ | Q₁ | Q₇ | Q₁ | O | Q₄ | Q₁ | Q₄ |
| Lₐ₂₄₃₂ | O | Q₁ | Q₁ | Q₈ | Q₁ | O | Q₄ | Q₁ | Q₄ |
| Lₐ₂₄₃₃ | O | Q₁ | Q₁ | Q₉ | Q₁ | O | Q₄ | Q₁ | Q₄ |
| Lₐ₂₄₃₄ | O | Q₁ | Q₁ | Q₁₀ | Q₁ | O | Q₄ | Q₁ | Q₄ |
| Lₐ₂₄₃₅ | O | Q₁ | Q₁ | Q₁₁ | Q₁ | O | Q₄ | Q₁ | Q₄ |
| Lₐ₂₄₃₆ | O | Q₁ | Q₁ | Q₁₂ | Q₁ | O | Q₄ | Q₁ | Q₄ |
| Lₐ₂₄₃₇ | O | Q₁ | Q₁ | Q₁₃ | Q₁ | O | Q₄ | Q₁ | Q₄ |
| Lₐ₂₄₃₈ | O | Q₁ | Q₁ | Q₁₄ | Q₁ | O | Q₄ | Q₁ | Q₄ |
| Lₐ₂₄₃₉ | O | Q₁ | Q₁ | Q₁₅ | Q₁ | O | Q₄ | Q₁ | Q₄ |
| Lₐ₂₄₄₀ | O | Q₁ | Q₁ | Q₁₆ | Q₁ | O | Q₄ | Q₁ | Q₄ |
| Lₐ₂₄₄₁ | O | Q₁ | Q₁ | Q₁₇ | Q₁ | O | Q₄ | Q₁ | Q₄ |
| Lₐ₂₄₄₂ | O | Q₁ | Q₁ | Q₁₈ | Q₁ | O | Q₄ | Q₁ | Q₄ |
| Lₐ₂₄₄₃ | O | Q₁ | Q₁ | Q₁₉ | Q₁ | O | Q₄ | Q₁ | Q₄ |
| Lₐ₂₄₄₄ | O | Q₁ | Q₁ | Q₂₀ | Q₁ | O | Q₄ | Q₁ | Q₄ |
| Lₐ₂₄₄₅ | O | Q₁ | Q₁ | Q₂₁ | Q₁ | O | Q₄ | Q₁ | Q₄ |
| Lₐ₂₄₄₆ | O | Q₁ | Q₁ | Q₂₂ | Q₁ | O | Q₄ | Q₁ | Q₄ |
| Lₐ₂₄₄₇ | O | Q₁ | Q₁ | Q₂₃ | Q₁ | O | Q₄ | Q₁ | Q₄ |
| Lₐ₂₄₄₈ | O | Q₁ | Q₁ | Q₁ | Q₂ | O | Q₄ | Q₁ | Q₄ |
| Lₐ₂₄₄₉ | O | Q₁ | Q₁ | Q₁ | Q₃ | O | Q₄ | Q₁ | Q₄ |
| Lₐ₂₄₅₀ | O | Q₁ | Q₁ | Q₁ | Q₄ | O | Q₄ | Q₁ | Q₄ |
| Lₐ₂₄₅₁ | O | Q₁ | Q₁ | Q₁ | Q₅ | O | Q₄ | Q₁ | Q₄ |
| Lₐ₂₄₅₂ | O | Q₁ | Q₁ | Q₁ | Q₆ | O | Q₄ | Q₁ | Q₄ |
| Lₐ₂₄₅₃ | O | Q₁ | Q₁ | Q₁ | Q₇ | O | Q₄ | Q₁ | Q₄ |
| Lₐ₂₄₅₄ | O | Q₁ | Q₁ | Q₁ | Q₈ | O | Q₄ | Q₁ | Q₄ |
| Lₐ₂₄₅₅ | O | Q₁ | Q₁ | Q₁ | Q₉ | O | Q₄ | Q₁ | Q₄ |
| Lₐ₂₄₅₆ | O | Q₁ | Q₁ | Q₁ | Q₁₀ | O | Q₄ | Q₁ | Q₄ |
| Lₐ₂₄₅₇ | O | Q₁ | Q₁ | Q₁ | Q₁₁ | O | Q₄ | Q₁ | Q₄ |
| Lₐ₂₄₅₈ | O | Q₁ | Q₁ | Q₁ | Q₁₂ | O | Q₄ | Q₁ | Q₄ |
| Lₐ₂₄₅₉ | O | Q₁ | Q₁ | Q₁ | Q₁₃ | O | Q₄ | Q₁ | Q₄ |
| Lₐ₂₄₆₀ | O | Q₁ | Q₁ | Q₁ | Q₁₄ | O | Q₄ | Q₁ | Q₄ |
| Lₐ₂₄₆₁ | O | Q₁ | Q₁ | Q₁ | Q₁₅ | O | Q₄ | Q₁ | Q₄ |
| Lₐ₂₄₆₂ | O | Q₁ | Q₁ | Q₁ | Q₁₆ | O | Q₄ | Q₁ | Q₄ |
| Lₐ₂₄₆₃ | O | Q₁ | Q₁ | Q₁ | Q₁₇ | O | Q₄ | Q₁ | Q₄ |
| Lₐ₂₄₆₄ | O | Q₁ | Q₁ | Q₁ | Q₁₈ | O | Q₄ | Q₁ | Q₄ |
| Lₐ₂₄₆₅ | O | Q₁ | Q₁ | Q₁ | Q₁₉ | O | Q₄ | Q₁ | Q₄ |
| Lₐ₂₄₆₆ | O | Q₁ | Q₁ | Q₁ | Q₂₀ | O | Q₄ | Q₁ | Q₄ |
| Lₐ₂₄₆₇ | O | Q₁ | Q₁ | Q₁ | Q₂₁ | O | Q₄ | Q₁ | Q₄ |
| Lₐ₂₄₆₈ | O | Q₁ | Q₁ | Q₁ | Q₂₂ | O | Q₄ | Q₁ | Q₄ |
| Lₐ₂₄₆₉ | O | Q₁ | Q₁ | Q₁ | Q₂₃ | O | Q₄ | Q₁ | Q₄ |
| Lₐ₂₄₇₀ | O | Q₁ | Q₁ | Q₁ | Q₁ | S | Q₁ | Q₁ | Q₁ |
| Lₐ₂₄₇₁ | O | Q₂ | Q₁ | Q₁ | Q₁ | S | Q₁ | Q₁ | Q₁ |
| Lₐ₂₄₇₂ | O | Q₃ | Q₁ | Q₁ | Q₁ | S | Q₁ | Q₁ | Q₁ |
| Lₐ₂₄₇₃ | O | Q₄ | Q₁ | Q₁ | Q₁ | S | Q₁ | Q₁ | Q₁ |
| Lₐ₂₄₇₄ | O | Q₅ | Q₁ | Q₁ | Q₁ | S | Q₁ | Q₁ | Q₁ |
| Lₐ₂₄₇₅ | O | Q₆ | Q₁ | Q₁ | Q₁ | S | Q₁ | Q₁ | Q₁ |
| Lₐ₂₄₇₆ | O | Q₇ | Q₁ | Q₁ | Q₁ | S | Q₁ | Q₁ | Q₁ |
| Lₐ₂₄₇₇ | O | Q₈ | Q₁ | Q₁ | Q₁ | S | Q₁ | Q₁ | Q₁ |
| Lₐ₂₄₇₈ | O | Q₉ | Q₁ | Q₁ | Q₁ | S | Q₁ | Q₁ | Q₁ |
| Lₐ₂₄₇₉ | O | Q₁₀ | Q₁ | Q₁ | Q₁ | S | Q₁ | Q₁ | Q₁ |
| Lₐ₂₄₈₀ | O | Q₁₁ | Q₁ | Q₁ | Q₁ | S | Q₁ | Q₁ | Q₁ |
| Lₐ₂₄₈₁ | O | Q₁₂ | Q₁ | Q₁ | Q₁ | S | Q₁ | Q₁ | Q₁ |
| Lₐ₂₄₈₂ | O | Q₁₃ | Q₁ | Q₁ | Q₁ | S | Q₁ | Q₁ | Q₁ |
| Lₐ₂₄₈₃ | O | Q₁₄ | Q₁ | Q₁ | Q₁ | S | Q₁ | Q₁ | Q₁ |
| Lₐ₂₄₈₄ | O | Q₁₅ | Q₁ | Q₁ | Q₁ | S | Q₁ | Q₁ | Q₁ |
| Lₐ₂₄₈₅ | O | Q₁₆ | Q₁ | Q₁ | Q₁ | S | Q₁ | Q₁ | Q₁ |
| Lₐ₂₄₈₆ | O | Q₁₇ | Q₁ | Q₁ | Q₁ | S | Q₁ | Q₁ | Q₁ |
| Lₐ₂₄₈₇ | O | Q₁₈ | Q₁ | Q₁ | Q₁ | S | Q₁ | Q₁ | Q₁ |
| Lₐ₂₄₈₈ | O | Q₁₉ | Q₁ | Q₁ | Q₁ | S | Q₁ | Q₁ | Q₁ |
| Lₐ₂₄₈₉ | O | Q₂₀ | Q₁ | Q₁ | Q₁ | S | Q₁ | Q₁ | Q₁ |
| Lₐ₂₄₉₀ | O | Q₂₁ | Q₁ | Q₁ | Q₁ | S | Q₁ | Q₁ | Q₁ |
| Lₐ₂₄₉₁ | O | Q₂₂ | Q₁ | Q₁ | Q₁ | S | Q₁ | Q₁ | Q₁ |
| Lₐ₂₄₉₂ | O | Q₂₃ | Q₁ | Q₁ | Q₁ | S | Q₁ | Q₁ | Q₁ |
| Lₐ₂₄₉₃ | O | Q₁ | Q₂ | Q₁ | Q₁ | S | Q₁ | Q₁ | Q₁ |
| Lₐ₂₄₉₄ | O | Q₁ | Q₃ | Q₁ | Q₁ | S | Q₁ | Q₁ | Q₁ |
| Lₐ₂₄₉₅ | O | Q₁ | Q₄ | Q₁ | Q₁ | S | Q₁ | Q₁ | Q₁ |
| Lₐ₂₄₉₆ | O | Q₁ | Q₅ | Q₁ | Q₁ | S | Q₁ | Q₁ | Q₁ |
| Lₐ₂₄₉₇ | O | Q₁ | Q₆ | Q₁ | Q₁ | S | Q₁ | Q₁ | Q₁ |
| Lₐ₂₄₉₈ | O | Q₁ | Q₇ | Q₁ | Q₁ | S | Q₁ | Q₁ | Q₁ |
| Lₐ₂₄₉₉ | O | Q₁ | Q₈ | Q₁ | Q₁ | S | Q₁ | Q₁ | Q₁ |
| Lₐ₂₅₀₀ | O | Q₁ | Q₉ | Q₁ | Q₁ | S | Q₁ | Q₁ | Q₁ |
| Lₐ₂₅₀₁ | O | Q₁ | Q₁₀ | Q₁ | Q₁ | S | Q₁ | Q₁ | Q₁ |
| Lₐ₂₅₀₂ | O | Q₁ | Q₁₁ | Q₁ | Q₁ | S | Q₁ | Q₁ | Q₁ |
| Lₐ₂₅₀₃ | O | Q₁ | Q₁₂ | Q₁ | Q₁ | S | Q₁ | Q₁ | Q₁ |
| Lₐ₂₅₀₄ | O | Q₁ | Q₁₃ | Q₁ | Q₁ | S | Q₁ | Q₁ | Q₁ |
| Lₐ₂₅₀₅ | O | Q₁ | Q₁₄ | Q₁ | Q₁ | S | Q₁ | Q₁ | Q₁ |
| Lₐ₂₅₀₆ | O | Q₁ | Q₁₅ | Q₁ | Q₁ | S | Q₁ | Q₁ | Q₁ |
| Lₐ₂₅₀₇ | O | Q₁ | Q₁₆ | Q₁ | Q₁ | S | Q₁ | Q₁ | Q₁ |
| Lₐ₂₅₀₈ | O | Q₁ | Q₁₇ | Q₁ | Q₁ | S | Q₁ | Q₁ | Q₁ |
| Lₐ₂₅₀₉ | O | Q₁ | Q₁₈ | Q₁ | Q₁ | S | Q₁ | Q₁ | Q₁ |
| Lₐ₂₅₁₀ | O | Q₁ | Q₁₉ | Q₁ | Q₁ | S | Q₁ | Q₁ | Q₁ |
| Lₐ₂₅₁₁ | O | Q₁ | Q₂₀ | Q₁ | Q₁ | S | Q₁ | Q₁ | Q₁ |
| Lₐ₂₅₁₂ | O | Q₁ | Q₂₁ | Q₁ | Q₁ | S | Q₁ | Q₁ | Q₁ |
| Lₐ₂₅₁₃ | O | Q₁ | Q₂₂ | Q₁ | Q₁ | S | Q₁ | Q₁ | Q₁ |
| Lₐ₂₅₁₄ | O | Q₁ | Q₂₃ | Q₁ | Q₁ | S | Q₁ | Q₁ | Q₁ |
| Lₐ₂₅₁₅ | O | Q₁ | Q₁ | Q₂ | Q₁ | S | Q₁ | Q₁ | Q₁ |
| Lₐ₂₅₁₆ | O | Q₁ | Q₁ | Q₃ | Q₁ | S | Q₁ | Q₁ | Q₁ |
| Lₐ₂₅₁₇ | O | Q₁ | Q₁ | Q₄ | Q₁ | S | Q₁ | Q₁ | Q₁ |
| Lₐ₂₅₁₈ | O | Q₁ | Q₁ | Q₅ | Q₁ | S | Q₁ | Q₁ | Q₁ |
| Lₐ₂₅₁₉ | O | Q₁ | Q₁ | Q₆ | Q₁ | S | Q₁ | Q₁ | Q₁ |
| Lₐ₂₅₂₀ | O | Q₁ | Q₁ | Q₇ | Q₁ | S | Q₁ | Q₁ | Q₁ |
| Lₐ₂₅₂₁ | O | Q₁ | Q₁ | Q₈ | Q₁ | S | Q₁ | Q₁ | Q₁ |
| Lₐ₂₅₂₂ | O | Q₁ | Q₁ | Q₉ | Q₁ | S | Q₁ | Q₁ | Q₁ |
| Lₐ₂₅₂₃ | O | Q₁ | Q₁ | Q₁₀ | Q₁ | S | Q₁ | Q₁ | Q₁ |
| Lₐ₂₅₂₄ | O | Q₁ | Q₁ | Q₁₁ | Q₁ | S | Q₁ | Q₁ | Q₁ |
| Lₐ₂₅₂₅ | O | Q₁ | Q₁ | Q₁₂ | Q₁ | S | Q₁ | Q₁ | Q₁ |
| Lₐ₂₅₂₆ | O | Q₁ | Q₁ | Q₁₃ | Q₁ | S | Q₁ | Q₁ | Q₁ |
| Lₐ₂₅₂₇ | O | Q₁ | Q₁ | Q₁₄ | Q₁ | S | Q₁ | Q₁ | Q₁ |
| Lₐ₂₅₂₈ | O | Q₁ | Q₁ | Q₁₅ | Q₁ | S | Q₁ | Q₁ | Q₁ |
| Lₐ₂₅₂₉ | O | Q₁ | Q₁ | Q₁₆ | Q₁ | S | Q₁ | Q₁ | Q₁ |
| Lₐ₂₅₃₀ | O | Q₁ | Q₁ | Q₁₇ | Q₁ | S | Q₁ | Q₁ | Q₁ |
| Lₐ₂₅₃₁ | O | Q₁ | Q₁ | Q₁₈ | Q₁ | S | Q₁ | Q₁ | Q₁ |
| Lₐ₂₅₃₂ | O | Q₁ | Q₁ | Q₁₉ | Q₁ | S | Q₁ | Q₁ | Q₁ |
| Lₐ₂₅₃₃ | O | Q₁ | Q₁ | Q₂₀ | Q₁ | S | Q₁ | Q₁ | Q₁ |
| Lₐ₂₅₃₄ | O | Q₁ | Q₁ | Q₂₁ | Q₁ | S | Q₁ | Q₁ | Q₁ |
| Lₐ₂₅₃₅ | O | Q₁ | Q₁ | Q₂₂ | Q₁ | S | Q₁ | Q₁ | Q₁ |
| Lₐ₂₅₃₆ | O | Q₁ | Q₁ | Q₂₃ | Q₁ | S | Q₁ | Q₁ | Q₁ |
| Lₐ₂₅₃₇ | O | Q₁ | Q₁ | Q₁ | Q₂ | S | Q₁ | Q₁ | Q₁ |
| Lₐ₂₅₃₈ | O | Q₁ | Q₁ | Q₁ | Q₃ | S | Q₁ | Q₁ | Q₁ |
| Lₐ₂₅₃₉ | O | Q₁ | Q₁ | Q₁ | Q₄ | S | Q₁ | Q₁ | Q₁ |
| Lₐ₂₅₄₀ | O | Q₁ | Q₁ | Q₁ | Q₅ | S | Q₁ | Q₁ | Q₁ |
| Lₐ₂₅₄₁ | O | Q₁ | Q₁ | Q₁ | Q₆ | S | Q₁ | Q₁ | Q₁ |
| Lₐ₂₅₄₂ | O | Q₁ | Q₁ | Q₁ | Q₇ | S | Q₁ | Q₁ | Q₁ |
| Lₐ₂₅₄₃ | O | Q₁ | Q₁ | Q₁ | Q₈ | S | Q₁ | Q₁ | Q₁ |
| Lₐ₂₅₄₄ | O | Q₁ | Q₁ | Q₁ | Q₉ | S | Q₁ | Q₁ | Q₁ |
| Lₐ₂₅₄₅ | O | Q₁ | Q₁ | Q₁ | Q₁₀ | S | Q₁ | Q₁ | Q₁ |
| Lₐ₂₅₄₆ | O | Q₁ | Q₁ | Q₁ | Q₁₁ | S | Q₁ | Q₁ | Q₁ |
| Lₐ₂₅₄₇ | O | Q₁ | Q₁ | Q₁ | Q₁₂ | S | Q₁ | Q₁ | Q₁ |
| Lₐ₂₅₄₈ | O | Q₁ | Q₁ | Q₁ | Q₁₃ | S | Q₁ | Q₁ | Q₁ |
| Lₐ₂₅₄₉ | O | Q₁ | Q₁ | Q₁ | Q₁₄ | S | Q₁ | Q₁ | Q₁ |
| Lₐ₂₅₅₀ | O | Q₁ | Q₁ | Q₁ | Q₁₅ | S | Q₁ | Q₁ | Q₁ |
| Lₐ₂₅₅₁ | O | Q₁ | Q₁ | Q₁ | Q₁₆ | S | Q₁ | Q₁ | Q₁ |
| Lₐ₂₅₅₂ | O | Q₁ | Q₁ | Q₁ | Q₁₇ | S | Q₁ | Q₁ | Q₁ |
| Lₐ₂₅₅₃ | O | Q₁ | Q₁ | Q₁ | Q₁₈ | S | Q₁ | Q₁ | Q₁ |
| Lₐ₂₅₅₄ | O | Q₁ | Q₁ | Q₁ | Q₁₉ | S | Q₁ | Q₁ | Q₁ |
| Lₐ₂₅₅₅ | O | Q₁ | Q₁ | Q₁ | Q₂₀ | S | Q₁ | Q₁ | Q₁ |
| Lₐ₂₅₅₆ | O | Q₁ | Q₁ | Q₁ | Q₂₁ | S | Q₁ | Q₁ | Q₁ |
| Lₐ₂₅₅₇ | O | Q₁ | Q₁ | Q₁ | Q₂₂ | S | Q₁ | Q₁ | Q₁ |
| Lₐ₂₅₅₈ | O | Q₁ | Q₁ | Q₁ | Q₂₃ | S | Q₁ | Q₁ | Q₁ |
| Lₐ₂₅₅₉ | O | Q₁ | Q₁ | Q₁ | Q₁ | S | Q₂ | Q₁ | Q₁ |
| Lₐ₂₅₆₀ | O | Q₁ | Q₁ | Q₁ | Q₁ | S | Q₃ | Q₁ | Q₁ |
| Lₐ₂₅₆₁ | O | Q₁ | Q₁ | Q₁ | Q₁ | S | Q₄ | Q₁ | Q₁ |
| Lₐ₂₅₆₂ | O | Q₁ | Q₁ | Q₁ | Q₁ | S | Q₅ | Q₁ | Q₁ |
| Lₐ₂₅₆₃ | O | Q₁ | Q₁ | Q₁ | Q₁ | S | Q₆ | Q₁ | Q₁ |
| Lₐ₂₅₆₄ | O | Q₁ | Q₁ | Q₁ | Q₁ | S | Q₇ | Q₁ | Q₁ |
| Lₐ₂₅₆₅ | O | Q₁ | Q₁ | Q₁ | Q₁ | S | Q₈ | Q₁ | Q₁ |
| Lₐ₂₅₆₆ | O | Q₁ | Q₁ | Q₁ | Q₁ | S | Q₉ | Q₁ | Q₁ |
| Lₐ₂₅₆₇ | O | Q₁ | Q₁ | Q₁ | Q₁ | S | Q₁₀ | Q₁ | Q₁ |
| Lₐ₂₅₆₈ | O | Q₁ | Q₁ | Q₁ | Q₁ | S | Q₁₁ | Q₁ | Q₁ |
| Lₐ₂₅₆₉ | O | Q₁ | Q₁ | Q₁ | Q₁ | S | Q₁₂ | Q₁ | Q₁ |
| Lₐ₂₅₇₀ | O | Q₁ | Q₁ | Q₁ | Q₁ | S | Q₁₃ | Q₁ | Q₁ |
| Lₐ₂₅₇₁ | O | Q₁ | Q₁ | Q₁ | Q₁ | S | Q₁₄ | Q₁ | Q₁ |
| Lₐ₂₅₇₂ | O | Q₁ | Q₁ | Q₁ | Q₁ | S | Q₁₅ | Q₁ | Q₁ |
| Lₐ₂₅₇₃ | O | Q₁ | Q₁ | Q₁ | Q₁ | S | Q₁₆ | Q₁ | Q₁ |
| Lₐ₂₅₇₄ | O | Q₁ | Q₁ | Q₁ | Q₁ | S | Q₁₇ | Q₁ | Q₁ |
| Lₐ₂₅₇₅ | O | Q₁ | Q₁ | Q₁ | Q₁ | S | Q₁₈ | Q₁ | Q₁ |
| Lₐ₂₅₇₆ | O | Q₁ | Q₁ | Q₁ | Q₁ | S | Q₁₉ | Q₁ | Q₁ |
| Lₐ₂₅₇₇ | O | Q₁ | Q₁ | Q₁ | Q₁ | S | Q₂₀ | Q₁ | Q₁ |
| Lₐ₂₅₇₈ | O | Q₁ | Q₁ | Q₁ | Q₁ | S | Q₂₁ | Q₁ | Q₁ |
| Lₐ₂₅₇₉ | O | Q₁ | Q₁ | Q₁ | Q₁ | S | Q₂₂ | Q₁ | Q₁ |
| Lₐ₂₅₈₀ | O | Q₁ | Q₁ | Q₁ | Q₁ | S | Q₂₃ | Q₁ | Q₁ |
| Lₐ₂₅₈₁ | O | Q₁ | Q₁ | Q₁ | Q₁ | S | Q₁ | Q₂ | Q₁ |
| Lₐ₂₅₈₂ | O | Q₁ | Q₁ | Q₁ | Q₁ | S | Q₁ | Q₃ | Q₁ |
| Lₐ₂₅₈₃ | O | Q₁ | Q₁ | Q₁ | Q₁ | S | Q₁ | Q₄ | Q₁ |
| Lₐ₂₅₈₄ | O | Q₁ | Q₁ | Q₁ | Q₁ | S | Q₁ | Q₅ | Q₁ |
| Lₐ₂₅₈₅ | O | Q₁ | Q₁ | Q₁ | Q₁ | S | Q₁ | Q₆ | Q₁ |
| Lₐ₂₅₈₆ | O | Q₁ | Q₁ | Q₁ | Q₁ | S | Q₁ | Q₇ | Q₁ |
| Lₐ₂₅₈₇ | O | Q₁ | Q₁ | Q₁ | Q₁ | S | Q₁ | Q₈ | Q₁ |
| Lₐ₂₅₈₈ | O | Q₁ | Q₁ | Q₁ | Q₁ | S | Q₁ | Q₉ | Q₁ |
| Lₐ₂₅₈₉ | O | Q₁ | Q₁ | Q₁ | Q₁ | S | Q₁ | Q₁₀ | Q₁ |
| Lₐ₂₅₉₀ | O | Q₁ | Q₁ | Q₁ | Q₁ | S | Q₁ | Q₁₁ | Q₁ |
| Lₐ₂₅₉₁ | O | Q₁ | Q₁ | Q₁ | Q₁ | S | Q₁ | Q₁₂ | Q₁ |
| Lₐ₂₅₉₂ | O | Q₁ | Q₁ | Q₁ | Q₁ | S | Q₁ | Q₁₃ | Q₁ |
| Lₐ₂₅₉₃ | O | Q₁ | Q₁ | Q₁ | Q₁ | S | Q₁ | Q₁₄ | Q₁ |
| Lₐ₂₅₉₄ | O | Q₁ | Q₁ | Q₁ | Q₁ | S | Q₁ | Q₁₅ | Q₁ |
| Lₐ₂₅₉₅ | O | Q₁ | Q₁ | Q₁ | Q₁ | S | Q₁ | Q₁₆ | Q₁ |
| Lₐ₂₅₉₆ | O | Q₁ | Q₁ | Q₁ | Q₁ | S | Q₁ | Q₁₇ | Q₁ |
| Lₐ₂₅₉₇ | O | Q₁ | Q₁ | Q₁ | Q₁ | S | Q₁ | Q₁₈ | Q₁ |
| Lₐ₂₅₉₈ | O | Q₁ | Q₁ | Q₁ | Q₁ | S | Q₁ | Q₁₉ | Q₁ |
| Lₐ₂₅₉₉ | O | Q₁ | Q₁ | Q₁ | Q₁ | S | Q₁ | Q₂₀ | Q₁ |
| Lₐ₂₆₀₀ | O | Q₁ | Q₁ | Q₁ | Q₁ | S | Q₁ | Q₂₁ | Q₁ |
| Lₐ₂₆₀₁ | O | Q₁ | Q₁ | Q₁ | Q₁ | S | Q₁ | Q₂₂ | Q₁ |
| Lₐ₂₆₀₂ | O | Q₁ | Q₁ | Q₁ | Q₁ | S | Q₁ | Q₂₃ | Q₁ |
| Lₐ₂₆₀₃ | O | Q₁ | Q₁ | Q₁ | Q₁ | S | Q₁ | Q₁ | Q₂ |
| Lₐ₂₆₀₄ | O | Q₁ | Q₁ | Q₁ | Q₁ | S | Q₁ | Q₁ | Q₃ |
| Lₐ₂₆₀₅ | O | Q₁ | Q₁ | Q₁ | Q₁ | S | Q₁ | Q₁ | Q₄ |
| Lₐ₂₆₀₆ | O | Q₁ | Q₁ | Q₁ | Q₁ | S | Q₁ | Q₁ | Q₅ |
| Lₐ₂₆₀₇ | O | Q₁ | Q₁ | Q₁ | Q₁ | S | Q₁ | Q₁ | Q₆ |
| Lₐ₂₆₀₈ | O | Q₁ | Q₁ | Q₁ | Q₁ | S | Q₁ | Q₁ | Q₇ |
| Lₐ₂₆₀₉ | O | Q₁ | Q₁ | Q₁ | Q₁ | S | Q₁ | Q₁ | Q₈ |
| Lₐ₂₆₁₀ | O | Q₁ | Q₁ | Q₁ | Q₁ | S | Q₁ | Q₁ | Q₉ |
| Lₐ₂₆₁₁ | O | Q₁ | Q₁ | Q₁ | Q₁ | S | Q₁ | Q₁ | Q₁₀ |
| Lₐ₂₆₁₂ | O | Q₁ | Q₁ | Q₁ | Q₁ | S | Q₁ | Q₁ | Q₁₁ |
| Lₐ₂₆₁₃ | O | Q₁ | Q₁ | Q₁ | Q₁ | S | Q₁ | Q₁ | Q₁₂ |
| Lₐ₂₆₁₄ | O | Q₁ | Q₁ | Q₁ | Q₁ | S | Q₁ | Q₁ | Q₁₃ |
| Lₐ₂₆₁₅ | O | Q₁ | Q₁ | Q₁ | Q₁ | S | Q₁ | Q₁ | Q₁₄ |
| Lₐ₂₆₁₆ | O | Q₁ | Q₁ | Q₁ | Q₁ | S | Q₁ | Q₁ | Q₁₅ |
| Lₐ₂₆₁₇ | O | Q₁ | Q₁ | Q₁ | Q₁ | S | Q₁ | Q₁ | Q₁₆ |
| Lₐ₂₆₁₈ | O | Q₁ | Q₁ | Q₁ | Q₁ | S | Q₁ | Q₁ | Q₁₇ |
| Lₐ₂₆₁₉ | O | Q₁ | Q₁ | Q₁ | Q₁ | S | Q₁ | Q₁ | Q₁₈ |
| Lₐ₂₆₂₀ | O | Q₁ | Q₁ | Q₁ | Q₁ | S | Q₁ | Q₁ | Q₁₉ |
| Lₐ₂₆₂₁ | O | Q₁ | Q₁ | Q₁ | Q₁ | S | Q₁ | Q₁ | Q₂₀ |
| Lₐ₂₆₂₂ | O | Q₁ | Q₁ | Q₁ | Q₁ | S | Q₁ | Q₁ | Q₂₁ |
| Lₐ₂₆₂₃ | O | Q₁ | Q₁ | Q₁ | Q₁ | S | Q₁ | Q₁ | Q₂₂ |
| Lₐ₂₆₂₄ | O | Q₁ | Q₁ | Q₁ | Q₁ | S | Q₁ | Q₁ | Q₂₃ |
| Lₐ₂₆₂₅ | O | Q₁ | Q₂ | Q₁ | Q₁ | S | Q₄ | Q₁ | Q₁ |
| Lₐ₂₆₂₆ | O | Q₁ | Q₃ | Q₁ | Q₁ | S | Q₄ | Q₁ | Q₁ |
| Lₐ₂₆₂₇ | O | Q₁ | Q₄ | Q₁ | Q₁ | S | Q₄ | Q₁ | Q₁ |
| Lₐ₂₆₂₈ | O | Q₁ | Q₅ | Q₁ | Q₁ | S | Q₄ | Q₁ | Q₁ |
| Lₐ₂₆₂₉ | O | Q₁ | Q₆ | Q₁ | Q₁ | S | Q₄ | Q₁ | Q₁ |
| Lₐ₂₆₃₀ | O | Q₁ | Q₇ | Q₁ | Q₁ | S | Q₄ | Q₁ | Q₁ |
| Lₐ₂₆₃₁ | O | Q₁ | Q₈ | Q₁ | Q₁ | S | Q₄ | Q₁ | Q₁ |
| Lₐ₂₆₃₂ | O | Q₁ | Q₉ | Q₁ | Q₁ | S | Q₄ | Q₁ | Q₁ |
| Lₐ₂₆₃₃ | O | Q₁ | Q₁₀ | Q₁ | Q₁ | S | Q₄ | Q₁ | Q₁ |
| Lₐ₂₆₃₄ | O | Q₁ | Q₁₁ | Q₁ | Q₁ | S | Q₄ | Q₁ | Q₁ |
| Lₐ₂₆₃₅ | O | Q₁ | Q₁₂ | Q₁ | Q₁ | S | Q₄ | Q₁ | Q₁ |
| Lₐ₂₆₃₆ | O | Q₁ | Q₁₃ | Q₁ | Q₁ | S | Q₄ | Q₁ | Q₁ |
| Lₐ₂₆₃₇ | O | Q₁ | Q₁₄ | Q₁ | Q₁ | S | Q₄ | Q₁ | Q₁ |
| Lₐ₂₆₃₈ | O | Q₁ | Q₁₅ | Q₁ | Q₁ | S | Q₄ | Q₁ | Q₁ |
| Lₐ₂₆₃₉ | O | Q₁ | Q₁₆ | Q₁ | Q₁ | S | Q₄ | Q₁ | Q₁ |
| Lₐ₂₆₄₀ | O | Q₁ | Q₁₇ | Q₁ | Q₁ | S | Q₄ | Q₁ | Q₁ |
| Lₐ₂₆₄₁ | O | Q₁ | Q₁₈ | Q₁ | Q₁ | S | Q₄ | Q₁ | Q₁ |
| Lₐ₂₆₄₂ | O | Q₁ | Q₁₉ | Q₁ | Q₁ | S | Q₄ | Q₁ | Q₁ |
| Lₐ₂₆₄₃ | O | Q₁ | Q₂₀ | Q₁ | Q₁ | S | Q₄ | Q₁ | Q₁ |
| Lₐ₂₆₄₄ | O | Q₁ | Q₂₁ | Q₁ | Q₁ | S | Q₄ | Q₁ | Q₁ |
| Lₐ₂₆₄₅ | O | Q₁ | Q₂₂ | Q₁ | Q₁ | S | Q₄ | Q₁ | Q₁ |
| Lₐ₂₆₄₆ | O | Q₁ | Q₂₃ | Q₁ | Q₁ | S | Q₄ | Q₁ | Q₁ |
| Lₐ₂₆₄₇ | O | Q₁ | Q₁ | Q₂ | Q₁ | S | Q₄ | Q₁ | Q₁ |
| Lₐ₂₆₄₈ | O | Q₁ | Q₁ | Q₃ | Q₁ | S | Q₄ | Q₁ | Q₁ |
| Lₐ₂₆₄₉ | O | Q₁ | Q₁ | Q₄ | Q₁ | S | Q₄ | Q₁ | Q₁ |
| Lₐ₂₆₅₀ | O | Q₁ | Q₁ | Q₅ | Q₁ | S | Q₄ | Q₁ | Q₁ |
| Lₐ₂₆₅₁ | O | Q₁ | Q₁ | Q₆ | Q₁ | S | Q₄ | Q₁ | Q₁ |
| Lₐ₂₆₅₂ | O | Q₁ | Q₁ | Q₇ | Q₁ | S | Q₄ | Q₁ | Q₁ |
| Lₐ₂₆₅₃ | O | Q₁ | Q₁ | Q₈ | Q₁ | S | Q₄ | Q₁ | Q₁ |
| Lₐ₂₆₅₄ | O | Q₁ | Q₁ | Q₉ | Q₁ | S | Q₄ | Q₁ | Q₁ |
| Lₐ₂₆₅₅ | O | Q₁ | Q₁ | Q₁₀ | Q₁ | S | Q₄ | Q₁ | Q₁ |
| Lₐ₂₆₅₆ | O | Q₁ | Q₁ | Q₁₁ | Q₁ | S | Q₄ | Q₁ | Q₁ |
| Lₐ₂₆₅₇ | O | Q₁ | Q₁ | Q₁₂ | Q₁ | S | Q₄ | Q₁ | Q₁ |
| Lₐ₂₆₅₈ | O | Q₁ | Q₁ | Q₁₃ | Q₁ | S | Q₄ | Q₁ | Q₁ |
| Lₐ₂₆₅₉ | O | Q₁ | Q₁ | Q₁₄ | Q₁ | S | Q₄ | Q₁ | Q₁ |
| Lₐ₂₆₆₀ | O | Q₁ | Q₁ | Q₁₅ | Q₁ | S | Q₄ | Q₁ | Q₁ |
| Lₐ₂₆₆₁ | O | Q₁ | Q₁ | Q₁₆ | Q₁ | S | Q₄ | Q₁ | Q₁ |
| Lₐ₂₆₆₂ | O | Q₁ | Q₁ | Q₁₇ | Q₁ | S | Q₄ | Q₁ | Q₁ |
| Lₐ₂₆₆₃ | O | Q₁ | Q₁ | Q₁₈ | Q₁ | S | Q₄ | Q₁ | Q₁ |
| Lₐ₂₆₆₄ | O | Q₁ | Q₁ | Q₁₉ | Q₁ | S | Q₄ | Q₁ | Q₁ |
| Lₐ₂₆₆₅ | O | Q₁ | Q₁ | Q₂₀ | Q₁ | S | Q₄ | Q₁ | Q₁ |
| Lₐ₂₆₆₆ | O | Q₁ | Q₁ | Q₂₁ | Q₁ | S | Q₄ | Q₁ | Q₁ |
| Lₐ₂₆₆₇ | O | Q₁ | Q₁ | Q₂₂ | Q₁ | S | Q₄ | Q₁ | Q₁ |
| Lₐ₂₆₆₈ | O | Q₁ | Q₁ | Q₂₃ | Q₁ | S | Q₄ | Q₁ | Q₁ |
| Lₐ₂₆₆₉ | O | Q₁ | Q₂ | Q₁ | Q₁ | S | Q₆ | Q₁ | Q₁ |
| Lₐ₂₆₇₀ | O | Q₁ | Q₃ | Q₁ | Q₁ | S | Q₆ | Q₁ | Q₁ |
| Lₐ₂₆₇₁ | O | Q₁ | Q₄ | Q₁ | Q₁ | S | Q₆ | Q₁ | Q₁ |
| Lₐ₂₆₇₂ | O | Q₁ | Q₅ | Q₁ | Q₁ | S | Q₆ | Q₁ | Q₁ |
| Lₐ₂₆₇₃ | O | Q₁ | Q₆ | Q₁ | Q₁ | S | Q₆ | Q₁ | Q₁ |
| Lₐ₂₆₇₄ | O | Q₁ | Q₇ | Q₁ | Q₁ | S | Q₆ | Q₁ | Q₁ |
| Lₐ₂₆₇₅ | O | Q₁ | Q₈ | Q₁ | Q₁ | S | Q₆ | Q₁ | Q₁ |
| Lₐ₂₆₇₆ | O | Q₁ | Q₉ | Q₁ | Q₁ | S | Q₆ | Q₁ | Q₁ |
| Lₐ₂₆₇₇ | O | Q₁ | Q₁₀ | Q₁ | Q₁ | S | Q₆ | Q₁ | Q₁ |
| Lₐ₂₆₇₈ | O | Q₁ | Q₁₁ | Q₁ | Q₁ | S | Q₆ | Q₁ | Q₁ |
| Lₐ₂₆₇₉ | O | Q₁ | Q₁₂ | Q₁ | Q₁ | S | Q₆ | Q₁ | Q₁ |
| Lₐ₂₆₈₀ | O | Q₁ | Q₁₃ | Q₁ | Q₁ | S | Q₆ | Q₁ | Q₁ |
| Lₐ₂₆₈₁ | O | Q₁ | Q₁₄ | Q₁ | Q₁ | S | Q₆ | Q₁ | Q₁ |
| Lₐ₂₆₈₂ | O | Q₁ | Q₁₅ | Q₁ | Q₁ | S | Q₆ | Q₁ | Q₁ |
| Lₐ₂₆₈₃ | O | Q₁ | Q₁₆ | Q₁ | Q₁ | S | Q₆ | Q₁ | Q₁ |
| Lₐ₂₆₈₄ | O | Q₁ | Q₁₇ | Q₁ | Q₁ | S | Q₆ | Q₁ | Q₁ |
| Lₐ₂₆₈₅ | O | Q₁ | Q₁₈ | Q₁ | Q₁ | S | Q₆ | Q₁ | Q₁ |
| Lₐ₂₆₈₆ | O | Q₁ | Q₁₉ | Q₁ | Q₁ | S | Q₆ | Q₁ | Q₁ |
| Lₐ₂₆₈₇ | O | Q₁ | Q₂₀ | Q₁ | Q₁ | S | Q₆ | Q₁ | Q₁ |
| Lₐ₂₆₈₈ | O | Q₁ | Q₂₁ | Q₁ | Q₁ | S | Q₆ | Q₁ | Q₁ |
| Lₐ₂₆₈₉ | O | Q₁ | Q₂₂ | Q₁ | Q₁ | S | Q₆ | Q₁ | Q₁ |
| Lₐ₂₆₉₀ | O | Q₁ | Q₂₃ | Q₁ | Q₁ | S | Q₆ | Q₁ | Q₁ |
| Lₐ₂₆₉₁ | O | Q₁ | Q₁ | Q₁ | Q₁ | S | Q₆ | Q₁ | Q₁ |
| Lₐ₂₆₉₂ | O | Q₁ | Q₁ | Q₃ | Q₁ | S | Q₆ | Q₁ | Q₁ |
| Lₐ₂₆₉₃ | O | Q₁ | Q₁ | Q₄ | Q₁ | S | Q₆ | Q₁ | Q₁ |
| Lₐ₂₆₉₄ | O | Q₁ | Q₁ | Q₅ | Q₁ | S | Q₆ | Q₁ | Q₁ |
| Lₐ₂₆₉₅ | O | Q₁ | Q₁ | Q₆ | Q₁ | S | Q₆ | Q₁ | Q₁ |
| Lₐ₂₆₉₆ | O | Q₁ | Q₁ | Q₇ | Q₁ | S | Q₆ | Q₁ | Q₁ |
| Lₐ₂₆₉₇ | O | Q₁ | Q₁ | Q₈ | Q₁ | S | Q₆ | Q₁ | Q₁ |
| Lₐ₂₆₉₈ | O | Q₁ | Q₁ | Q₉ | Q₁ | S | Q₆ | Q₁ | Q₁ |
| Lₐ₂₆₉₉ | O | Q₁ | Q₁ | Q₁₀ | Q₁ | S | Q₆ | Q₁ | Q₁ |
| Lₐ₂₇₀₀ | O | Q₁ | Q₁ | Q₁₁ | Q₁ | S | Q₆ | Q₁ | Q₁ |
| Lₐ₂₇₀₁ | O | Q₁ | Q₁ | Q₁₂ | Q₁ | S | Q₆ | Q₁ | Q₁ |
| Lₐ₂₇₀₂ | O | Q₁ | Q₁ | Q₁₃ | Q₁ | S | Q₆ | Q₁ | Q₁ |
| Lₐ₂₇₀₃ | O | Q₁ | Q₁ | Q₁₄ | Q₁ | S | Q₆ | Q₁ | Q₁ |
| Lₐ₂₇₀₄ | O | Q₁ | Q₁ | Q₁₅ | Q₁ | S | Q₆ | Q₁ | Q₁ |
| Lₐ₂₇₀₅ | O | Q₁ | Q₁ | Q₁₆ | Q₁ | S | Q₆ | Q₁ | Q₁ |
| Lₐ₂₇₀₆ | O | Q₁ | Q₁ | Q₁₇ | Q₁ | S | Q₆ | Q₁ | Q₁ |
| Lₐ₂₇₀₇ | O | Q₁ | Q₁ | Q₁₈ | Q₁ | S | Q₆ | Q₁ | Q₁ |
| Lₐ₂₇₀₈ | O | Q₁ | Q₁ | Q₁₉ | Q₁ | S | Q₆ | Q₁ | Q₁ |
| Lₐ₂₇₀₉ | O | Q₁ | Q₁ | Q₂₀ | Q₁ | S | Q₆ | Q₁ | Q₁ |
| Lₐ₂₇₁₀ | O | Q₁ | Q₁ | Q₂₁ | Q₁ | S | Q₆ | Q₁ | Q₁ |
| Lₐ₂₇₁₁ | O | Q₁ | Q₁ | Q₂₂ | Q₁ | S | Q₆ | Q₁ | Q₁ |
| Lₐ₂₇₁₂ | O | Q₁ | Q₁ | Q₂₃ | Q₁ | S | Q₆ | Q₁ | Q₁ |
| Lₐ₂₇₁₃ | O | Q₁ | Q₂ | Q₁ | Q₁ | S | Q₇ | Q₁ | Q₁ |
| Lₐ₂₇₁₄ | O | Q₁ | Q₃ | Q₁ | Q₁ | S | Q₇ | Q₁ | Q₁ |
| Lₐ₂₇₁₅ | O | Q₁ | Q₄ | Q₁ | Q₁ | S | Q₇ | Q₁ | Q₁ |
| Lₐ₂₇₁₆ | O | Q₁ | Q₅ | Q₁ | Q₁ | S | Q₇ | Q₁ | Q₁ |
| Lₐ₂₇₁₇ | O | Q₁ | Q₆ | Q₁ | Q₁ | S | Q₇ | Q₁ | Q₁ |
| Lₐ₂₇₁₈ | O | Q₁ | Q₇ | Q₁ | Q₁ | S | Q₇ | Q₁ | Q₁ |
| Lₐ₂₇₁₉ | O | Q₁ | Q₈ | Q₁ | Q₁ | S | Q₇ | Q₁ | Q₁ |
| Lₐ₂₇₂₀ | O | Q₁ | Q₉ | Q₁ | Q₁ | S | Q₇ | Q₁ | Q₁ |
| Lₐ₂₇₂₁ | O | Q₁ | Q₁₀ | Q₁ | Q₁ | S | Q₇ | Q₁ | Q₁ |
| Lₐ₂₇₂₂ | O | Q₁ | Q₁₁ | Q₁ | Q₁ | S | Q₇ | Q₁ | Q₁ |
| Lₐ₂₇₂₃ | O | Q₁ | Q₁₂ | Q₁ | Q₁ | S | Q₇ | Q₁ | Q₁ |
| Lₐ₂₇₂₄ | O | Q₁ | Q₁₃ | Q₁ | Q₁ | S | Q₇ | Q₁ | Q₁ |
| Lₐ₂₇₂₅ | O | Q₁ | Q₁₄ | Q₁ | Q₁ | S | Q₇ | Q₁ | Q₁ |
| Lₐ₂₇₂₆ | O | Q₁ | Q₁₅ | Q₁ | Q₁ | S | Q₇ | Q₁ | Q₁ |
| Lₐ₂₇₂₇ | O | Q₁ | Q₁₆ | Q₁ | Q₁ | S | Q₇ | Q₁ | Q₁ |
| Lₐ₂₇₂₈ | O | Q₁ | Q₁₇ | Q₁ | Q₁ | S | Q₇ | Q₁ | Q₁ |
| Lₐ₂₇₂₉ | O | Q₁ | Q₁₈ | Q₁ | Q₁ | S | Q₇ | Q₁ | Q₁ |
| Lₐ₂₇₃₀ | O | Q₁ | Q₁₉ | Q₁ | Q₁ | S | Q₇ | Q₁ | Q₁ |
| Lₐ₂₇₃₁ | O | Q₁ | Q₂₀ | Q₁ | Q₁ | S | Q₇ | Q₁ | Q₁ |
| Lₐ₂₇₃₂ | O | Q₁ | Q₂₁ | Q₁ | Q₁ | S | Q₇ | Q₁ | Q₁ |
| Lₐ₂₇₃₃ | O | Q₁ | Q₂₂ | Q₁ | Q₁ | S | Q₇ | Q₁ | Q₁ |
| Lₐ₂₇₃₄ | O | Q₁ | Q₂₃ | Q₁ | Q₁ | S | Q₇ | Q₁ | Q₁ |
| Lₐ₂₇₃₅ | O | Q₁ | Q₁ | Q₂ | Q₁ | S | Q₇ | Q₁ | Q₁ |
| Lₐ₂₇₃₆ | O | Q₁ | Q₁ | Q₃ | Q₁ | S | Q₇ | Q₁ | Q₁ |
| Lₐ₂₇₃₇ | O | Q₁ | Q₁ | Q₄ | Q₁ | S | Q₇ | Q₁ | Q₁ |
| Lₐ₂₇₃₈ | O | Q₁ | Q₁ | Q₅ | Q₁ | S | Q₇ | Q₁ | Q₁ |
| Lₐ₂₇₃₉ | O | Q₁ | Q₁ | Q₆ | Q₁ | S | Q₇ | Q₁ | Q₁ |
| Lₐ₂₇₄₀ | O | Q₁ | Q₁ | Q₇ | Q₁ | S | Q₇ | Q₁ | Q₁ |
| Lₐ₂₇₄₁ | O | Q₁ | Q₁ | Q₈ | Q₁ | S | Q₇ | Q₁ | Q₁ |
| Lₐ₂₇₄₂ | O | Q₁ | Q₁ | Q₉ | Q₁ | S | Q₇ | Q₁ | Q₁ |
| Lₐ₂₇₄₃ | O | Q₁ | Q₁ | Q₁₀ | Q₁ | S | Q₇ | Q₁ | Q₁ |
| Lₐ₂₇₄₄ | O | Q₁ | Q₁ | Q₁₁ | Q₁ | S | Q₇ | Q₁ | Q₁ |
| Lₐ₂₇₄₅ | O | Q₁ | Q₁ | Q₁₂ | Q₁ | S | Q₇ | Q₁ | Q₁ |
| Lₐ₂₇₄₆ | O | Q₁ | Q₁ | Q₁₃ | Q₁ | S | Q₇ | Q₁ | Q₁ |
| Lₐ₂₇₄₇ | O | Q₁ | Q₁ | Q₁₄ | Q₁ | S | Q₇ | Q₁ | Q₁ |
| Lₐ₂₇₄₈ | O | Q₁ | Q₁ | Q₁₅ | Q₁ | S | Q₇ | Q₁ | Q₁ |
| Lₐ₂₇₄₉ | O | Q₁ | Q₁ | Q₁₆ | Q₁ | S | Q₇ | Q₁ | Q₁ |
| Lₐ₂₇₅₀ | O | Q₁ | Q₁ | Q₁₇ | Q₁ | S | Q₇ | Q₁ | Q₁ |
| Lₐ₂₇₅₁ | O | Q₁ | Q₁ | Q₁₈ | Q₁ | S | Q₇ | Q₁ | Q₁ |
| Lₐ₂₇₅₂ | O | Q₁ | Q₁ | Q₁₉ | Q₁ | S | Q₇ | Q₁ | Q₁ |
| Lₐ₂₇₅₃ | O | Q₁ | Q₁ | Q₂₀ | Q₁ | S | Q₇ | Q₁ | Q₁ |
| Lₐ₂₇₅₄ | O | Q₁ | Q₁ | Q₂₁ | Q₁ | S | Q₇ | Q₁ | Q₁ |
| Lₐ₂₇₅₅ | O | Q₁ | Q₁ | Q₂₂ | Q₁ | S | Q₇ | Q₁ | Q₁ |
| Lₐ₂₇₅₆ | O | Q₁ | Q₁ | Q₂₃ | Q₁ | S | Q₇ | Q₁ | Q₁ |
| Lₐ₂₇₅₇ | O | Q₁ | Q₂ | Q₁ | Q₁ | S | Q₈ | Q₁ | Q₁ |
| Lₐ₂₇₅₈ | O | Q₁ | Q₃ | Q₁ | Q₁ | S | Q₈ | Q₁ | Q₁ |
| Lₐ₂₇₅₉ | O | Q₁ | Q₄ | Q₁ | Q₁ | S | Q₈ | Q₁ | Q₁ |
| Lₐ₂₇₆₀ | O | Q₁ | Q₅ | Q₁ | Q₁ | S | Q₈ | Q₁ | Q₁ |
| Lₐ₂₇₆₁ | O | Q₁ | Q₆ | Q₁ | Q₁ | S | Q₈ | Q₁ | Q₁ |
| Lₐ₂₇₆₂ | O | Q₁ | Q₇ | Q₁ | Q₁ | S | Q₈ | Q₁ | Q₁ |
| Lₐ₂₇₆₃ | O | Q₁ | Q₈ | Q₁ | Q₁ | S | Q₈ | Q₁ | Q₁ |
| Lₐ₂₇₆₄ | O | Q₁ | Q₉ | Q₁ | Q₁ | S | Q₈ | Q₁ | Q₁ |
| Lₐ₂₇₆₅ | O | Q₁ | Q₁₀ | Q₁ | Q₁ | S | Q₈ | Q₁ | Q₁ |
| Lₐ₂₇₆₆ | O | Q₁ | Q₁₁ | Q₁ | Q₁ | S | Q₈ | Q₁ | Q₁ |
| Lₐ₂₇₆₇ | O | Q₁ | Q₁₂ | Q₁ | Q₁ | S | Q₈ | Q₁ | Q₁ |
| Lₐ₂₇₆₈ | O | Q₁ | Q₁₃ | Q₁ | Q₁ | S | Q₈ | Q₁ | Q₁ |
| Lₐ₂₇₆₉ | O | Q₁ | Q₁₄ | Q₁ | Q₁ | S | Q₈ | Q₁ | Q₁ |
| Lₐ₂₇₇₀ | O | Q₁ | Q₁₅ | Q₁ | Q₁ | S | Q₈ | Q₁ | Q₁ |
| Lₐ₂₇₇₁ | O | Q₁ | Q₁₆ | Q₁ | Q₁ | S | Q₈ | Q₁ | Q₁ |
| Lₐ₂₇₇₂ | O | Q₁ | Q₁₇ | Q₁ | Q₁ | S | Q₈ | Q₁ | Q₁ |
| Lₐ₂₇₇₃ | O | Q₁ | Q₁₈ | Q₁ | Q₁ | S | Q₈ | Q₁ | Q₁ |
| Lₐ₂₇₇₄ | O | Q₁ | Q₁₉ | Q₁ | Q₁ | S | Q₈ | Q₁ | Q₁ |
| Lₐ₂₇₇₅ | O | Q₁ | Q₂₀ | Q₁ | Q₁ | S | Q₈ | Q₁ | Q₁ |
| Lₐ₂₇₇₆ | O | Q₁ | Q₂₁ | Q₁ | Q₁ | S | Q₈ | Q₁ | Q₁ |
| Lₐ₂₇₇₇ | O | Q₁ | Q₂₂ | Q₁ | Q₁ | S | Q₈ | Q₁ | Q₁ |
| Lₐ₂₇₇₈ | O | Q₁ | Q₂₃ | Q₁ | Q₁ | S | Q₈ | Q₁ | Q₁ |
| Lₐ₂₇₇₉ | O | Q₁ | Q₁ | Q₂ | Q₁ | S | Q₈ | Q₁ | Q₁ |
| Lₐ₂₇₈₀ | O | Q₁ | Q₁ | Q₃ | Q₁ | S | Q₈ | Q₁ | Q₁ |
| Lₐ₂₇₈₁ | O | Q₁ | Q₁ | Q₄ | Q₁ | S | Q₈ | Q₁ | Q₁ |
| Lₐ₂₇₈₂ | O | Q₁ | Q₁ | Q₅ | Q₁ | S | Q₈ | Q₁ | Q₁ |
| Lₐ₂₇₈₃ | O | Q₁ | Q₁ | Q₆ | Q₁ | S | Q₈ | Q₁ | Q₁ |
| Lₐ₂₇₈₄ | O | Q₁ | Q₁ | Q₇ | Q₁ | S | Q₈ | Q₁ | Q₁ |
| Lₐ₂₇₈₅ | O | Q₁ | Q₁ | Q₈ | Q₁ | S | Q₈ | Q₁ | Q₁ |
| Lₐ₂₇₈₆ | O | Q₁ | Q₁ | Q₉ | Q₁ | S | Q₈ | Q₁ | Q₁ |
| Lₐ₂₇₈₇ | O | Q₁ | Q₁ | Q₁₀ | Q₁ | S | Q₈ | Q₁ | Q₁ |
| Lₐ₂₇₈₈ | O | Q₁ | Q₁ | Q₁₁ | Q₁ | S | Q₈ | Q₁ | Q₁ |
| Lₐ₂₇₈₉ | O | Q₁ | Q₁ | Q₁₂ | Q₁ | S | Q₈ | Q₁ | Q₁ |
| Lₐ₂₇₉₀ | O | Q₁ | Q₁ | Q₁₃ | Q₁ | S | Q₈ | Q₁ | Q₁ |
| Lₐ₂₇₉₁ | O | Q₁ | Q₁ | Q₁₄ | Q₁ | S | Q₈ | Q₁ | Q₁ |
| Lₐ₂₇₉₂ | O | Q₁ | Q₁ | Q₁₅ | Q₁ | S | Q₈ | Q₁ | Q₁ |
| Lₐ₂₇₉₃ | O | Q₁ | Q₁ | Q₁₆ | Q₁ | S | Q₈ | Q₁ | Q₁ |
| Lₐ₂₇₉₄ | O | Q₁ | Q₁ | Q₁₇ | Q₁ | S | Q₈ | Q₁ | Q₁ |
| Lₐ₂₇₉₅ | O | Q₁ | Q₁ | Q₁₈ | Q₁ | S | Q₈ | Q₁ | Q₁ |
| Lₐ₂₇₉₆ | O | Q₁ | Q₁ | Q₁₉ | Q₁ | S | Q₈ | Q₁ | Q₁ |
| Lₐ₂₇₉₇ | O | Q₁ | Q₁ | Q₂₀ | Q₁ | S | Q₈ | Q₁ | Q₁ |
| Lₐ₂₇₉₈ | O | Q₁ | Q₁ | Q₂₁ | Q₁ | S | Q₈ | Q₁ | Q₁ |
| Lₐ₂₇₉₉ | O | Q₁ | Q₁ | Q₂₂ | Q₁ | S | Q₈ | Q₁ | Q₁ |
| Lₐ₂₈₀₀ | O | Q₁ | Q₁ | Q₂₃ | Q₁ | S | Q₈ | Q₁ | Q₁ |
| Lₐ₂₈₀₁ | O | Q₁ | Q₂ | Q₁ | Q₁ | S | Q₈ | Q₄ | Q₁ |
| Lₐ₂₈₀₂ | O | Q₁ | Q₃ | Q₁ | Q₁ | S | Q₈ | Q₄ | Q₁ |
| Lₐ₂₈₀₃ | O | Q₁ | Q₄ | Q₁ | Q₁ | S | Q₈ | Q₄ | Q₁ |
| Lₐ₂₈₀₄ | O | Q₁ | Q₅ | Q₁ | Q₁ | S | Q₈ | Q₄ | Q₁ |
| Lₐ₂₈₀₅ | O | Q₁ | Q₆ | Q₁ | Q₁ | S | Q₈ | Q₄ | Q₁ |
| Lₐ₂₈₀₆ | O | Q₁ | Q₇ | Q₁ | Q₁ | S | Q₈ | Q₄ | Q₁ |
| Lₐ₂₈₀₇ | O | Q₁ | Q₈ | Q₁ | Q₁ | S | Q₈ | Q₄ | Q₁ |
| Lₐ₂₈₀₈ | O | Q₁ | Q₉ | Q₁ | Q₁ | S | Q₈ | Q₄ | Q₁ |
| Lₐ₂₈₀₉ | O | Q₁ | Q₁₀ | Q₁ | Q₁ | S | Q₈ | Q₄ | Q₁ |
| Lₐ₂₈₁₀ | O | Q₁ | Q₁₁ | Q₁ | Q₁ | S | Q₈ | Q₄ | Q₁ |
| Lₐ₂₈₁₁ | O | Q₁ | Q₁₂ | Q₁ | Q₁ | S | Q₈ | Q₄ | Q₁ |
| Lₐ₂₈₁₂ | O | Q₁ | Q₁₃ | Q₁ | Q₁ | S | Q₈ | Q₄ | Q₁ |
| Lₐ₂₈₁₃ | O | Q₁ | Q₁₄ | Q₁ | Q₁ | S | Q₈ | Q₄ | Q₁ |
| Lₐ₂₈₁₄ | O | Q₁ | Q₁₅ | Q₁ | Q₁ | S | Q₈ | Q₄ | Q₁ |
| Lₐ₂₈₁₅ | O | Q₁ | Q₁₆ | Q₁ | Q₁ | S | Q₈ | Q₄ | Q₁ |
| Lₐ₂₈₁₆ | O | Q₁ | Q₁₇ | Q₁ | Q₁ | S | Q₈ | Q₄ | Q₁ |
| Lₐ₂₈₁₇ | O | Q₁ | Q₁₈ | Q₁ | Q₁ | S | Q₈ | Q₄ | Q₁ |
| Lₐ₂₈₁₈ | O | Q₁ | Q₁₉ | Q₁ | Q₁ | S | Q₈ | Q₄ | Q₁ |
| Lₐ₂₈₁₉ | O | Q₁ | Q₂₀ | Q₁ | Q₁ | S | Q₈ | Q₄ | Q₁ |
| Lₐ₂₈₂₀ | O | Q₁ | Q₂₁ | Q₁ | Q₁ | S | Q₈ | Q₄ | Q₁ |
| Lₐ₂₈₂₁ | O | Q₁ | Q₂₂ | Q₁ | Q₁ | S | Q₈ | Q₄ | Q₁ |
| Lₐ₂₈₂₂ | O | Q₁ | Q₂₃ | Q₁ | Q₁ | S | Q₈ | Q₄ | Q₁ |
| Lₐ₂₈₂₃ | O | Q₁ | Q₁ | Q₂ | Q₁ | S | Q₈ | Q₄ | Q₁ |
| Lₐ₂₈₂₄ | O | Q₁ | Q₁ | Q₃ | Q₁ | S | Q₈ | Q₄ | Q₁ |
| Lₐ₂₈₂₅ | O | Q₁ | Q₁ | Q₄ | Q₁ | S | Q₈ | Q₄ | Q₁ |
| Lₐ₂₈₂₆ | O | Q₁ | Q₁ | Q₅ | Q₁ | S | Q₈ | Q₄ | Q₁ |
| Lₐ₂₈₂₇ | O | Q₁ | Q₁ | Q₆ | Q₁ | S | Q₈ | Q₄ | Q₁ |
| Lₐ₂₈₂₈ | O | Q₁ | Q₁ | Q₇ | Q₁ | S | Q₈ | Q₄ | Q₁ |
| Lₐ₂₈₂₉ | O | Q₁ | Q₁ | Q₈ | Q₁ | S | Q₈ | Q₄ | Q₁ |
| Lₐ₂₈₃₀ | O | Q₁ | Q₁ | Q₉ | Q₁ | S | Q₈ | Q₄ | Q₁ |
| Lₐ₂₈₃₁ | O | Q₁ | Q₁ | Q₁₀ | Q₁ | S | Q₈ | Q₄ | Q₁ |
| Lₐ₂₈₃₂ | O | Q₁ | Q₁ | Q₁₁ | Q₁ | S | Q₈ | Q₄ | Q₁ |
| Lₐ₂₈₃₃ | O | Q₁ | Q₁ | Q₁₂ | Q₁ | S | Q₈ | Q₄ | Q₁ |
| Lₐ₂₈₃₄ | O | Q₁ | Q₁ | Q₁₃ | Q₁ | S | Q₈ | Q₄ | Q₁ |
| Lₐ₂₈₃₅ | O | Q₁ | Q₁ | Q₁₄ | Q₁ | S | Q₈ | Q₄ | Q₁ |
| Lₐ₂₈₃₆ | O | Q₁ | Q₁ | Q₁₅ | Q₁ | S | Q₈ | Q₄ | Q₁ |
| Lₐ₂₈₃₇ | O | Q₁ | Q₁ | Q₁₆ | Q₁ | S | Q₈ | Q₄ | Q₁ |
| Lₐ₂₈₃₈ | O | Q₁ | Q₁ | Q₁₇ | Q₁ | S | Q₈ | Q₄ | Q₁ |
| Lₐ₂₈₃₉ | O | Q₁ | Q₁ | Q₁₈ | Q₁ | S | Q₈ | Q₄ | Q₁ |
| Lₐ₂₈₄₀ | O | Q₁ | Q₁ | Q₁₉ | Q₁ | S | Q₈ | Q₄ | Q₁ |
| Lₐ₂₈₄₁ | O | Q₁ | Q₁ | Q₂₀ | Q₁ | S | Q₈ | Q₄ | Q₁ |
| Lₐ₂₈₄₂ | O | Q₁ | Q₁ | Q₂₁ | Q₁ | S | Q₈ | Q₄ | Q₁ |
| Lₐ₂₈₄₃ | O | Q₁ | Q₁ | Q₂₂ | Q₁ | S | Q₈ | Q₄ | Q₁ |
| Lₐ₂₈₄₄ | O | Q₁ | Q₁ | Q₂₃ | Q₁ | S | Q₈ | Q₄ | Q₁ |
| Lₐ₂₈₄₅ | O | Q₁ | Q₂ | Q₁ | Q₁ | S | Q₈ | Q₁ | Q₄ |
| Lₐ₂₈₄₆ | O | Q₁ | Q₃ | Q₁ | Q₁ | S | Q₈ | Q₁ | Q₄ |
| Lₐ₂₈₄₇ | O | Q₁ | Q₄ | Q₁ | Q₁ | S | Q₈ | Q₁ | Q₄ |
| Lₐ₂₈₄₈ | O | Q₁ | Q₅ | Q₁ | Q₁ | S | Q₈ | Q₁ | Q₄ |
| Lₐ₂₈₄₉ | O | Q₁ | Q₆ | Q₁ | Q₁ | S | Q₈ | Q₁ | Q₄ |
| Lₐ₂₈₅₀ | O | Q₁ | Q₇ | Q₁ | Q₁ | S | Q₈ | Q₁ | Q₄ |
| Lₐ₂₈₅₁ | O | Q₁ | Q₈ | Q₁ | Q₁ | S | Q₈ | Q₁ | Q₄ |
| Lₐ₂₈₅₂ | O | Q₁ | Q₉ | Q₁ | Q₁ | S | Q₈ | Q₁ | Q₄ |
| Lₐ₂₈₅₃ | O | Q₁ | Q₁₀ | Q₁ | Q₁ | S | Q₈ | Q₁ | Q₄ |
| Lₐ₂₈₅₄ | O | Q₁ | Q₁₁ | Q₁ | Q₁ | S | Q₈ | Q₁ | Q₄ |
| Lₐ₂₈₅₅ | O | Q₁ | Q₁₂ | Q₁ | Q₁ | S | Q₈ | Q₁ | Q₄ |
| Lₐ₂₈₅₆ | O | Q₁ | Q₁₃ | Q₁ | Q₁ | S | Q₈ | Q₁ | Q₄ |
| Lₐ₂₈₅₇ | O | Q₁ | Q₁₄ | Q₁ | Q₁ | S | Q₈ | Q₁ | Q₄ |
| Lₐ₂₈₅₈ | O | Q₁ | Q₁₅ | Q₁ | Q₁ | S | Q₈ | Q₁ | Q₄ |
| Lₐ₂₈₅₉ | O | Q₁ | Q₁₆ | Q₁ | Q₁ | S | Q₈ | Q₁ | Q₄ |
| Lₐ₂₈₆₀ | O | Q₁ | Q₁₇ | Q₁ | Q₁ | S | Q₈ | Q₁ | Q₄ |
| Lₐ₂₈₆₁ | O | Q₁ | Q₁₈ | Q₁ | Q₁ | S | Q₈ | Q₁ | Q₄ |
| Lₐ₂₈₆₂ | O | Q₁ | Q₁₉ | Q₁ | Q₁ | S | Q₈ | Q₁ | Q₄ |
| Lₐ₂₈₆₃ | O | Q₁ | Q₂₀ | Q₁ | Q₁ | S | Q₈ | Q₁ | Q₄ |
| Lₐ₂₈₆₄ | O | Q₁ | Q₂₁ | Q₁ | Q₁ | S | Q₈ | Q₁ | Q₄ |
| Lₐ₂₈₆₅ | O | Q₁ | Q₂₂ | Q₁ | Q₁ | S | Q₈ | Q₁ | Q₄ |
| Lₐ₂₈₆₆ | O | Q₁ | Q₂₃ | Q₁ | Q₁ | S | Q₈ | Q₁ | Q₄ |
| Lₐ₂₈₆₇ | O | Q₁ | Q₁ | Q₂ | Q₁ | S | Q₈ | Q₁ | Q₄ |
| Lₐ₂₈₆₈ | O | Q₁ | Q₁ | Q₃ | Q₁ | S | Q₈ | Q₁ | Q₄ |
| Lₐ₂₈₆₉ | O | Q₁ | Q₁ | Q₄ | Q₁ | S | Q₈ | Q₁ | Q₄ |
| Lₐ₂₈₇₀ | O | Q₁ | Q₁ | Q₅ | Q₁ | S | Q₈ | Q₁ | Q₄ |
| Lₐ₂₈₇₁ | O | Q₁ | Q₁ | Q₆ | Q₁ | S | Q₈ | Q₁ | Q₄ |
| Lₐ₂₈₇₂ | O | Q₁ | Q₁ | Q₇ | Q₁ | S | Q₈ | Q₁ | Q₄ |
| Lₐ₂₈₇₃ | O | Q₁ | Q₁ | Q₈ | Q₁ | S | Q₈ | Q₁ | Q₄ |
| Lₐ₂₈₇₄ | O | Q₁ | Q₁ | Q₉ | Q₁ | S | Q₈ | Q₁ | Q₄ |
| Lₐ₂₈₇₅ | O | Q₁ | Q₁ | Q₁₀ | Q₁ | S | Q₈ | Q₁ | Q₄ |
| Lₐ₂₈₇₆ | O | Q₁ | Q₁ | Q₁₁ | Q₁ | S | Q₈ | Q₁ | Q₄ |
| Lₐ₂₈₇₇ | O | Q₁ | Q₁ | Q₁₂ | Q₁ | S | Q₈ | Q₁ | Q₄ |
| Lₐ₂₈₇₈ | O | Q₁ | Q₁ | Q₁₃ | Q₁ | S | Q₈ | Q₁ | Q₄ |
| Lₐ₂₈₇₉ | O | Q₁ | Q₁ | Q₁₄ | Q₁ | S | Q₈ | Q₁ | Q₄ |
| Lₐ₂₈₈₀ | O | Q₁ | Q₁ | Q₁₅ | Q₁ | S | Q₈ | Q₁ | Q₄ |
| Lₐ₂₈₈₁ | O | Q₁ | Q₁ | Q₁₆ | Q₁ | S | Q₈ | Q₁ | Q₄ |
| Lₐ₂₈₈₂ | O | Q₁ | Q₁ | Q₁₇ | Q₁ | S | Q₈ | Q₁ | Q₄ |
| Lₐ₂₈₈₃ | O | Q₁ | Q₁ | Q₁₈ | Q₁ | S | Q₈ | Q₁ | Q₄ |
| Lₐ₂₈₈₄ | O | Q₁ | Q₁ | Q₁₉ | Q₁ | S | Q₈ | Q₁ | Q₄ |
| Lₐ₂₈₈₅ | O | Q₁ | Q₁ | Q₂₀ | Q₁ | S | Q₈ | Q₁ | Q₄ |
| Lₐ₂₈₈₆ | O | Q₁ | Q₁ | Q₂₁ | Q₁ | S | Q₈ | Q₁ | Q₄ |
| Lₐ₂₈₈₇ | O | Q₁ | Q₁ | Q₂₂ | Q₁ | S | Q₈ | Q₁ | Q₄ |
| Lₐ₂₈₈₈ | O | Q₁ | Q₁ | Q₂₃ | Q₁ | S | Q₈ | Q₁ | Q₄ |
| Lₐ₂₈₈₉ | O | Q₁ | Q₂ | Q₁ | Q₁ | S | Q₈ | Q₁ | Q₁ |
| Lₐ₂₈₉₀ | O | Q₁ | Q₃ | Q₁ | Q₁ | S | Q₈ | Q₁ | Q₁ |
| Lₐ₂₈₉₁ | O | Q₁ | Q₄ | Q₁ | Q₁ | S | Q₈ | Q₁ | Q₁ |
| Lₐ₂₈₉₂ | O | Q₁ | Q₅ | Q₁ | Q₁ | S | Q₈ | Q₁ | Q₁ |
| Lₐ₂₈₉₃ | O | Q₁ | Q₆ | Q₁ | Q₁ | S | Q₈ | Q₁ | Q₁ |
| Lₐ₂₈₉₄ | O | Q₁ | Q₇ | Q₁ | Q₁ | S | Q₈ | Q₁ | Q₁ |
| Lₐ₂₈₉₅ | O | Q₁ | Q₈ | Q₁ | Q₁ | S | Q₈ | Q₁ | Q₁ |
| Lₐ₂₈₉₆ | O | Q₁ | Q₉ | Q₁ | Q₁ | S | Q₈ | Q₁ | Q₁ |
| Lₐ₂₈₉₇ | O | Q₁ | Q₁₀ | Q₁ | Q₁ | S | Q₈ | Q₁ | Q₁ |
| Lₐ₂₈₉₈ | O | Q₁ | Q₁₁ | Q₁ | Q₁ | S | Q₈ | Q₁ | Q₁ |
| Lₐ₂₈₉₉ | O | Q₁ | Q₁₂ | Q₁ | Q₁ | S | Q₈ | Q₁ | Q₁ |
| Lₐ₂₉₀₀ | O | Q₁ | Q₁₃ | Q₁ | Q₁ | S | Q₈ | Q₁ | Q₁ |
| Lₐ₂₉₀₁ | O | Q₁ | Q₁₄ | Q₁ | Q₁ | S | Q₈ | Q₁ | Q₁ |
| Lₐ₂₉₀₂ | O | Q₁ | Q₁₅ | Q₁ | Q₁ | S | Q₈ | Q₁ | Q₁ |
| Lₐ₂₉₀₃ | O | Q₁ | Q₁₆ | Q₁ | Q₁ | S | Q₈ | Q₁ | Q₁ |
| Lₐ₂₉₀₄ | O | Q₁ | Q₁₇ | Q₁ | Q₁ | S | Q₈ | Q₁ | Q₁ |
| Lₐ₂₉₀₅ | O | Q₁ | Q₁₈ | Q₁ | Q₁ | S | Q₈ | Q₁ | Q₁ |
| Lₐ₂₉₀₆ | O | Q₁ | Q₁₉ | Q₁ | Q₁ | S | Q₈ | Q₁ | Q₁ |
| Lₐ₂₉₀₇ | O | Q₁ | Q₂₀ | Q₁ | Q₁ | S | Q₈ | Q₁ | Q₁ |
| Lₐ₂₉₀₈ | O | Q₁ | Q₂₁ | Q₁ | Q₁ | S | Q₈ | Q₁ | Q₁ |
| Lₐ₂₉₀₉ | O | Q₁ | Q₂₂ | Q₁ | Q₁ | S | Q₈ | Q₁ | Q₁ |
| Lₐ₂₉₁₀ | O | Q₁ | Q₂₃ | Q₁ | Q₁ | S | Q₈ | Q₁ | Q₁ |
| Lₐ₂₉₁₁ | O | Q₁ | Q₁ | Q₂ | Q₁ | S | Q₈ | Q₁ | Q₁ |
| Lₐ₂₉₁₂ | O | Q₁ | Q₁ | Q₃ | Q₁ | S | Q₈ | Q₁ | Q₁ |
| Lₐ₂₉₁₃ | O | Q₁ | Q₁ | Q₄ | Q₁ | S | Q₈ | Q₁ | Q₁ |
| Lₐ₂₉₁₄ | O | Q₁ | Q₁ | Q₅ | Q₁ | S | Q₈ | Q₁ | Q₁ |
| Lₐ₂₉₁₅ | O | Q₁ | Q₁ | Q₆ | Q₁ | S | Q₈ | Q₁ | Q₁ |
| Lₐ₂₉₁₆ | O | Q₁ | Q₁ | Q₇ | Q₁ | S | Q₈ | Q₁ | Q₁ |
| Lₐ₂₉₁₇ | O | Q₁ | Q₁ | Q₈ | Q₁ | S | Q₈ | Q₁ | Q₁ |
| Lₐ₂₉₁₈ | O | Q₁ | Q₁ | Q₉ | Q₁ | S | Q₈ | Q₁ | Q₁ |
| Lₐ₂₉₁₉ | O | Q₁ | Q₁ | Q₁₀ | Q₁ | S | Q₈ | Q₁ | Q₁ |
| Lₐ₂₉₂₀ | O | Q₁ | Q₁ | Q₁₁ | Q₁ | S | Q₈ | Q₁ | Q₁ |
| Lₐ₂₉₂₁ | O | Q₁ | Q₁ | Q₁₂ | Q₁ | S | Q₈ | Q₁ | Q₁ |
| Lₐ₂₉₂₂ | O | Q₁ | Q₁ | Q₁₃ | Q₁ | S | Q₈ | Q₁ | Q₁ |
| Lₐ₂₉₂₃ | O | Q₁ | Q₁ | Q₁₄ | Q₁ | S | Q₈ | Q₁ | Q₁ |
| Lₐ₂₉₂₄ | O | Q₁ | Q₁ | Q₁₅ | Q₁ | S | Q₈ | Q₁ | Q₁ |
| Lₐ₂₉₂₅ | O | Q₁ | Q₁ | Q₁₆ | Q₁ | S | Q₈ | Q₁ | Q₁ |
| Lₐ₂₉₂₆ | O | Q₁ | Q₁ | Q₁₇ | Q₁ | S | Q₈ | Q₁ | Q₁ |
| Lₐ₂₉₂₇ | O | Q₁ | Q₁ | Q₁₈ | Q₁ | S | Q₈ | Q₁ | Q₁ |
| Lₐ₂₉₂₈ | O | Q₁ | Q₁ | Q₁₉ | Q₁ | S | Q₈ | Q₁ | Q₁ |
| Lₐ₂₉₂₉ | O | Q₁ | Q₁ | Q₂₀ | Q₁ | S | Q₈ | Q₁ | Q₁ |
| Lₐ₂₉₃₀ | O | Q₁ | Q₁ | Q₂₁ | Q₁ | S | Q₈ | Q₁ | Q₁ |
| Lₐ₂₉₃₁ | O | Q₁ | Q₁ | Q₂₂ | Q₁ | S | Q₈ | Q₁ | Q₁ |
| Lₐ₂₉₃₂ | O | Q₁ | Q₁ | Q₂₃ | Q₁ | S | Q₈ | Q₁ | Q₁ |
| Lₐ₂₉₃₃ | O | Q₁ | Q₂ | Q₁ | Q₁ | S | Q₄ | Q₁ | Q₄ |
| Lₐ₂₉₃₄ | O | Q₁ | Q₃ | Q₁ | Q₁ | S | Q₄ | Q₁ | Q₄ |
| Lₐ₂₉₃₅ | O | Q₁ | Q₄ | Q₁ | Q₁ | S | Q₄ | Q₁ | Q₄ |
| Lₐ₂₉₃₆ | O | Q₁ | Q₅ | Q₁ | Q₁ | S | Q₄ | Q₁ | Q₄ |
| Lₐ₂₉₃₇ | O | Q₁ | Q₆ | Q₁ | Q₁ | S | Q₄ | Q₁ | Q₄ |
| Lₐ₂₉₃₈ | O | Q₁ | Q₇ | Q₁ | Q₁ | S | Q₄ | Q₁ | Q₄ |
| Lₐ₂₉₃₉ | O | Q₁ | Q₈ | Q₁ | Q₁ | S | Q₄ | Q₁ | Q₄ |
| Lₐ₂₉₄₀ | O | Q₁ | Q₉ | Q₁ | Q₁ | S | Q₄ | Q₁ | Q₄ |
| Lₐ₂₉₄₁ | O | Q₁ | Q₁₀ | Q₁ | Q₁ | S | Q₄ | Q₁ | Q₄ |
| Lₐ₂₉₄₂ | O | Q₁ | Q₁₁ | Q₁ | Q₁ | S | Q₄ | Q₁ | Q₄ |
| Lₐ₂₉₄₃ | O | Q₁ | Q₁₂ | Q₁ | Q₁ | S | Q₄ | Q₁ | Q₄ |
| Lₐ₂₉₄₄ | O | Q₁ | Q₁₃ | Q₁ | Q₁ | S | Q₄ | Q₁ | Q₄ |
| Lₐ₂₉₄₅ | O | Q₁ | Q₁₄ | Q₁ | Q₁ | S | Q₄ | Q₁ | Q₄ |
| Lₐ₂₉₄₆ | O | Q₁ | Q₁₅ | Q₁ | Q₁ | S | Q₄ | Q₁ | Q₄ |
| Lₐ₂₉₄₇ | O | Q₁ | Q₁₆ | Q₁ | Q₁ | S | Q₄ | Q₁ | Q₄ |
| Lₐ₂₉₄₈ | O | Q₁ | Q₁₇ | Q₁ | Q₁ | S | Q₄ | Q₁ | Q₄ |
| Lₐ₂₉₄₉ | O | Q₁ | Q₁₈ | Q₁ | Q₁ | S | Q₄ | Q₁ | Q₄ |
| Lₐ₂₉₅₀ | O | Q₁ | Q₁₉ | Q₁ | Q₁ | S | Q₄ | Q₁ | Q₄ |
| Lₐ₂₉₅₁ | O | Q₁ | Q₂₀ | Q₁ | Q₁ | S | Q₄ | Q₁ | Q₄ |
| Lₐ₂₉₅₂ | O | Q₁ | Q₂₁ | Q₁ | Q₁ | S | Q₄ | Q₁ | Q₄ |
| Lₐ₂₉₅₃ | O | Q₁ | Q₂₂ | Q₁ | Q₁ | S | Q₄ | Q₁ | Q₄ |
| Lₐ₂₉₅₄ | O | Q₁ | Q₂₃ | Q₁ | Q₁ | S | Q₄ | Q₁ | Q₄ |
| Lₐ₂₉₅₅ | O | Q₁ | Q₁ | Q₂ | Q₁ | S | Q₄ | Q₁ | Q₄ |
| Lₐ₂₉₅₆ | O | Q₁ | Q₁ | Q₃ | Q₁ | S | Q₄ | Q₁ | Q₄ |
| Lₐ₂₉₅₇ | O | Q₁ | Q₁ | Q₄ | Q₁ | S | Q₄ | Q₁ | Q₄ |
| Lₐ₂₉₅₈ | O | Q₁ | Q₁ | Q₅ | Q₁ | S | Q₄ | Q₁ | Q₄ |
| Lₐ₂₉₅₉ | O | Q₁ | Q₁ | Q₆ | Q₁ | S | Q₄ | Q₁ | Q₄ |
| Lₐ₂₉₆₀ | O | Q₁ | Q₁ | Q₇ | Q₁ | S | Q₄ | Q₁ | Q₄ |
| Lₐ₂₉₆₁ | O | Q₁ | Q₁ | Q₈ | Q₁ | S | Q₄ | Q₁ | Q₄ |
| Lₐ₂₉₆₂ | O | Q₁ | Q₁ | Q₉ | Q₁ | S | Q₄ | Q₁ | Q₄ |
| Lₐ₂₉₆₃ | O | Q₁ | Q₁ | Q₁₀ | Q₁ | S | Q₄ | Q₁ | Q₄ |
| Lₐ₂₉₆₄ | O | Q₁ | Q₁ | Q₁₁ | Q₁ | S | Q₄ | Q₁ | Q₄ |
| Lₐ₂₉₆₅ | O | Q₁ | Q₁ | Q₁₂ | Q₁ | S | Q₄ | Q₁ | Q₄ |
| Lₐ₂₉₆₆ | O | Q₁ | Q₁ | Q₁₃ | Q₁ | S | Q₄ | Q₁ | Q₄ |
| Lₐ₂₉₆₇ | O | Q₁ | Q₁ | Q₁₄ | Q₁ | S | Q₄ | Q₁ | Q₄ |
| Lₐ₂₉₆₈ | O | Q₁ | Q₁ | Q₁₅ | Q₁ | S | Q₄ | Q₁ | Q₄ |
| Lₐ₂₉₆₉ | O | Q₁ | Q₁ | Q₁₆ | Q₁ | S | Q₄ | Q₁ | Q₄ |
| Lₐ₂₉₇₀ | O | Q₁ | Q₁ | Q₁₇ | Q₁ | S | Q₄ | Q₁ | Q₄ |
| Lₐ₂₉₇₁ | O | Q₁ | Q₁ | Q₁₈ | Q₁ | S | Q₄ | Q₁ | Q₄ |
| Lₐ₂₉₇₂ | O | Q₁ | Q₁ | Q₁₉ | Q₁ | S | Q₄ | Q₁ | Q₄ |
| Lₐ₂₉₇₃ | O | Q₁ | Q₁ | Q₂₀ | Q₁ | S | Q₄ | Q₁ | Q₄ |
| Lₐ₂₉₇₄ | O | Q₁ | Q₁ | Q₂₁ | Q₁ | S | Q₄ | Q₁ | Q₄ |
| Lₐ₂₉₇₅ | O | Q₁ | Q₁ | Q₂₂ | Q₁ | S | Q₄ | Q₁ | Q₄ |
| Lₐ₂₉₇₆ | O | Q₁ | Q₁ | Q₂₃ | Q₁ | S | Q₄ | Q₁ | Q₄ |
| Lₐ₂₉₇₇ | O | Q₁ | Q₁ | Q₁ | Q₂ | S | Q₄ | Q₁ | Q₄ |
| Lₐ₂₉₇₈ | O | Q₁ | Q₁ | Q₁ | Q₃ | S | Q₄ | Q₁ | Q₄ |
| Lₐ₂₉₇₉ | O | Q₁ | Q₁ | Q₁ | Q₄ | S | Q₄ | Q₁ | Q₄ |
| Lₐ₂₉₈₀ | O | Q₁ | Q₁ | Q₁ | Q₅ | S | Q₄ | Q₁ | Q₄ |
| Lₐ₂₉₈₁ | O | Q₁ | Q₁ | Q₁ | Q₆ | S | Q₄ | Q₁ | Q₄ |
| Lₐ₂₉₈₂ | O | Q₁ | Q₁ | Q₁ | Q₇ | S | Q₄ | Q₁ | Q₄ |
| Lₐ₂₉₈₃ | O | Q₁ | Q₁ | Q₁ | Q₈ | S | Q₄ | Q₁ | Q₄ |
| Lₐ₂₉₈₄ | O | Q₁ | Q₁ | Q₁ | Q₉ | S | Q₄ | Q₁ | Q₄ |
| Lₐ₂₉₈₅ | O | Q₁ | Q₁ | Q₁ | Q₁₀ | S | Q₄ | Q₁ | Q₄ |
| Lₐ₂₉₈₆ | O | Q₁ | Q₁ | Q₁ | Q₁₁ | S | Q₄ | Q₁ | Q₄ |
| Lₐ₂₉₈₇ | O | Q₁ | Q₁ | Q₁ | Q₁₂ | S | Q₄ | Q₁ | Q₄ |
| Lₐ₂₉₈₈ | O | Q₁ | Q₁ | Q₁ | Q₁₃ | S | Q₄ | Q₁ | Q₄ |
| Lₐ₂₉₈₉ | O | Q₁ | Q₁ | Q₁ | Q₁₄ | S | Q₄ | Q₁ | Q₄ |
| Lₐ₂₉₉₀ | O | Q₁ | Q₁ | Q₁ | Q₁₅ | S | Q₄ | Q₁ | Q₄ |
| Lₐ₂₉₉₁ | O | Q₁ | Q₁ | Q₁ | Q₁₆ | S | Q₄ | Q₁ | Q₄ |
| Lₐ₂₉₉₂ | O | Q₁ | Q₁ | Q₁ | Q₁₇ | S | Q₄ | Q₁ | Q₄ |
| Lₐ₂₉₉₃ | O | Q₁ | Q₁ | Q₁ | Q₁₈ | S | Q₄ | Q₁ | Q₄ |
| Lₐ₂₉₉₄ | O | Q₁ | Q₁ | Q₁ | Q₁₉ | S | Q₄ | Q₁ | Q₄ |
| Lₐ₂₉₉₅ | O | Q₁ | Q₁ | Q₁ | Q₂₀ | S | Q₄ | Q₁ | Q₄ |
| Lₐ₂₉₉₆ | O | Q₁ | Q₁ | Q₁ | Q₂₁ | S | Q₄ | Q₁ | Q₄ |
| Lₐ₂₉₉₇ | O | Q₁ | Q₁ | Q₁ | Q₂₂ | S | Q₄ | Q₁ | Q₄ |
| Lₐ₂₉₉₈ | O | Q₁ | Q₁ | Q₁ | Q₂₃ | S | Q₄ | Q₁ | Q₄ |

wherein Lₐ₂₉₉₉ to Lₐ₄₀₅₆ each have a structure represented by Formula 48: 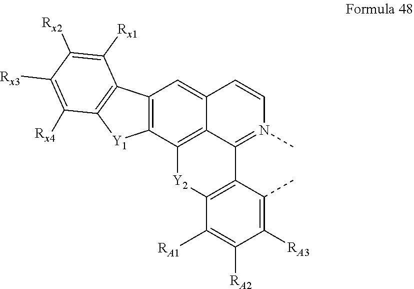
wherein Y₁, Y₂, Rₓ₁ to Rₓ₄ and R_{A1} to R_{A3} are selected from the groups listed in the following table, respectively:

| Ligand No. | Rₓ₁ | Rₓ₂ | Rₓ₃ | Rₓ₄ | Y₁ | Y₂ | R_{A1} | R_{A2} | R_{A3} |
|---|---|---|---|---|---|---|---|---|---|
| Lₐ₂₉₉₉ | Q₁ | Q₁ | Q₁ | Q₁ | O | O | Q₁ | Q₁ | Q₁ |
| Lₐ₃₀₀₀ | Q₂ | Q₁ | Q₁ | Q₁ | O | O | Q₁ | Q₁ | Q₁ |
| Lₐ₃₀₀₁ | Q₃ | Q₁ | Q₁ | Q₁ | O | O | Q₁ | Q₁ | Q₁ |
| Lₐ₃₀₀₂ | Q₄ | Q₁ | Q₁ | Q₁ | O | O | Q₁ | Q₁ | Q₁ |
| Lₐ₃₀₀₃ | Q₅ | Q₁ | Q₁ | Q₁ | O | O | Q₁ | Q₁ | Q₁ |
| Lₐ₃₀₀₄ | Q₆ | Q₁ | Q₁ | Q₁ | O | O | Q₁ | Q₁ | Q₁ |
| Lₐ₃₀₀₅ | Q₇ | Q₁ | Q₁ | Q₁ | O | O | Q₁ | Q₁ | Q₁ |
| Lₐ₃₀₀₆ | Q₈ | Q₁ | Q₁ | Q₁ | O | O | Q₁ | Q₁ | Q₁ |
| Lₐ₃₀₀₇ | Q₉ | Q₁ | Q₁ | Q₁ | O | O | Q₁ | Q₁ | Q₁ |
| Lₐ₃₀₀₈ | Q₁₀ | Q₁ | Q₁ | Q₁ | O | O | Q₁ | Q₁ | Q₁ |
| Lₐ₃₀₀₉ | Q₁₁ | Q₁ | Q₁ | Q₁ | O | O | Q₁ | Q₁ | Q₁ |
| Lₐ₃₀₁₀ | Q₁₂ | Q₁ | Q₁ | Q₁ | O | O | Q₁ | Q₁ | Q₁ |
| Lₐ₃₀₁₁ | Q₁₃ | Q₁ | Q₁ | Q₁ | O | O | Q₁ | Q₁ | Q₁ |
| Lₐ₃₀₁₂ | Q₁₄ | Q₁ | Q₁ | Q₁ | O | O | Q₁ | Q₁ | Q₁ |
| Lₐ₃₀₁₃ | Q₁₅ | Q₁ | Q₁ | Q₁ | O | O | Q₁ | Q₁ | Q₁ |
| Lₐ₃₀₁₄ | Q₁₆ | Q₁ | Q₁ | Q₁ | O | O | Q₁ | Q₁ | Q₁ |
| Lₐ₃₀₁₅ | Q₁₇ | Q₁ | Q₁ | Q₁ | O | O | Q₁ | Q₁ | Q₁ |
| Lₐ₃₀₁₆ | Q₁₈ | Q₁ | Q₁ | Q₁ | O | O | Q₁ | Q₁ | Q₁ |
| Lₐ₃₀₁₇ | Q₁₉ | Q₁ | Q₁ | Q₁ | O | O | Q₁ | Q₁ | Q₁ |
| Lₐ₃₀₁₈ | Q₂₀ | Q₁ | Q₁ | Q₁ | O | O | Q₁ | Q₁ | Q₁ |
| Lₐ₃₀₁₉ | Q₂₁ | Q₁ | Q₁ | Q₁ | O | O | Q₁ | Q₁ | Q₁ |
| Lₐ₃₀₂₀ | Q₂₂ | Q₁ | Q₁ | Q₁ | O | O | Q₁ | Q₁ | Q₁ |
| Lₐ₃₀₂₁ | Q₂₃ | Q₁ | Q₁ | Q₁ | O | O | Q₁ | Q₁ | Q₁ |
| Lₐ₃₀₂₂ | Q₁ | Q₂ | Q₁ | Q₁ | O | O | Q₁ | Q₁ | Q₁ |
| Lₐ₃₀₂₃ | Q₁ | Q₃ | Q₁ | Q₁ | O | O | Q₁ | Q₁ | Q₁ |
| Lₐ₃₀₂₄ | Q₁ | Q₄ | Q₁ | Q₁ | O | O | Q₁ | Q₁ | Q₁ |
| Lₐ₃₀₂₅ | Q₁ | Q₅ | Q₁ | Q₁ | O | O | Q₁ | Q₁ | Q₁ |
| Lₐ₃₀₂₆ | Q₁ | Q₆ | Q₁ | Q₁ | O | O | Q₁ | Q₁ | Q₁ |
| Lₐ₃₀₂₇ | Q₁ | Q₇ | Q₁ | Q₁ | O | O | Q₁ | Q₁ | Q₁ |
| Lₐ₃₀₂₈ | Q₁ | Q₈ | Q₁ | Q₁ | O | O | Q₁ | Q₁ | Q₁ |
| Lₐ₃₀₂₉ | Q₁ | Q₉ | Q₁ | Q₁ | O | O | Q₁ | Q₁ | Q₁ |
| Lₐ₃₀₃₀ | Q₁ | Q₁₀ | Q₁ | Q₁ | O | O | Q₁ | Q₁ | Q₁ |
| Lₐ₃₀₃₁ | Q₁ | Q₁₁ | Q₁ | Q₁ | O | O | Q₁ | Q₁ | Q₁ |
| Lₐ₃₀₃₂ | Q₁ | Q₁₂ | Q₁ | Q₁ | O | O | Q₁ | Q₁ | Q₁ |
| Lₐ₃₀₃₃ | Q₁ | Q₁₃ | Q₁ | Q₁ | O | O | Q₁ | Q₁ | Q₁ |
| Lₐ₃₀₃₄ | Q₁ | Q₁₄ | Q₁ | Q₁ | O | O | Q₁ | Q₁ | Q₁ |
| Lₐ₃₀₃₅ | Q₁ | Q₁₅ | Q₁ | Q₁ | O | O | Q₁ | Q₁ | Q₁ |
| Lₐ₃₀₃₆ | Q₁ | Q₁₆ | Q₁ | Q₁ | O | O | Q₁ | Q₁ | Q₁ |
| Lₐ₃₀₃₇ | Q₁ | Q₁₇ | Q₁ | Q₁ | O | O | Q₁ | Q₁ | Q₁ |
| Lₐ₃₀₃₈ | Q₁ | Q₁₈ | Q₁ | Q₁ | O | O | Q₁ | Q₁ | Q₁ |
| Lₐ₃₀₃₉ | Q₁ | Q₁₉ | Q₁ | Q₁ | O | O | Q₁ | Q₁ | Q₁ |
| Lₐ₃₀₄₀ | Q₁ | Q₂₀ | Q₁ | Q₁ | O | O | Q₁ | Q₁ | Q₁ |
| Lₐ₃₀₄₁ | Q₁ | Q₂₁ | Q₁ | Q₁ | O | O | Q₁ | Q₁ | Q₁ |
| Lₐ₃₀₄₂ | Q₁ | Q₂₂ | Q₁ | Q₁ | O | O | Q₁ | Q₁ | Q₁ |
| Lₐ₃₀₄₃ | Q₁ | Q₂₃ | Q₁ | Q₁ | O | O | Q₁ | Q₁ | Q₁ |
| Lₐ₃₀₄₄ | Q₁ | Q₁ | Q₂ | Q₁ | O | O | Q₁ | Q₁ | Q₁ |
| Lₐ₃₀₄₅ | Q₁ | Q₁ | Q₃ | Q₁ | O | O | Q₁ | Q₁ | Q₁ |
| Lₐ₃₀₄₆ | Q₁ | Q₁ | Q₄ | Q₁ | O | O | Q₁ | Q₁ | Q₁ |
| Lₐ₃₀₄₇ | Q₁ | Q₁ | Q₅ | Q₁ | O | O | Q₁ | Q₁ | Q₁ |
| Lₐ₃₀₄₈ | Q₁ | Q₁ | Q₆ | Q₁ | O | O | Q₁ | Q₁ | Q₁ |
| Lₐ₃₀₄₉ | Q₁ | Q₁ | Q₇ | Q₁ | O | O | Q₁ | Q₁ | Q₁ |
| Lₐ₃₀₅₀ | Q₁ | Q₁ | Q₈ | Q₁ | O | O | Q₁ | Q₁ | Q₁ |
| Lₐ₃₀₅₁ | Q₁ | Q₁ | Q₉ | Q₁ | O | O | Q₁ | Q₁ | Q₁ |
| Lₐ₃₀₅₂ | Q₁ | Q₁ | Q₁₀ | Q₁ | O | O | Q₁ | Q₁ | Q₁ |
| Lₐ₃₀₅₃ | Q₁ | Q₁ | Q₁₁ | Q₁ | O | O | Q₁ | Q₁ | Q₁ |
| Lₐ₃₀₅₄ | Q₁ | Q₁ | Q₁₂ | Q₁ | O | O | Q₁ | Q₁ | Q₁ |
| Lₐ₃₀₅₅ | Q₁ | Q₁ | Q₁₃ | Q₁ | O | O | Q₁ | Q₁ | Q₁ |
| Lₐ₃₀₅₆ | Q₁ | Q₁ | Q₁₄ | Q₁ | O | O | Q₁ | Q₁ | Q₁ |
| Lₐ₃₀₅₇ | Q₁ | Q₁ | Q₁₅ | Q₁ | O | O | Q₁ | Q₁ | Q₁ |
| Lₐ₃₀₅₈ | Q₁ | Q₁ | Q₁₆ | Q₁ | O | O | Q₁ | Q₁ | Q₁ |
| Lₐ₃₀₅₉ | Q₁ | Q₁ | Q₁₇ | Q₁ | O | O | Q₁ | Q₁ | Q₁ |
| Lₐ₃₀₆₀ | Q₁ | Q₁ | Q₁₈ | Q₁ | O | O | Q₁ | Q₁ | Q₁ |
| Lₐ₃₀₆₁ | Q₁ | Q₁ | Q₁₉ | Q₁ | O | O | Q₁ | Q₁ | Q₁ |
| Lₐ₃₀₆₂ | Q₁ | Q₁ | Q₂₀ | Q₁ | O | O | Q₁ | Q₁ | Q₁ |
| Lₐ₃₀₆₃ | Q₁ | Q₁ | Q₂₁ | Q₁ | O | O | Q₁ | Q₁ | Q₁ |
| Lₐ₃₀₆₄ | Q₁ | Q₁ | Q₂₂ | Q₁ | O | O | Q₁ | Q₁ | Q₁ |
| Lₐ₃₀₆₅ | Q₁ | Q₁ | Q₂₃ | Q₁ | O | O | Q₁ | Q₁ | Q₁ |
| Lₐ₃₀₆₆ | Q₁ | Q₁ | Q₁ | Q₂ | O | O | Q₁ | Q₁ | Q₁ |
| Lₐ₃₀₆₇ | Q₁ | Q₁ | Q₁ | Q₃ | O | O | Q₁ | Q₁ | Q₁ |
| Lₐ₃₀₆₈ | Q₁ | Q₁ | Q₁ | Q₄ | O | O | Q₁ | Q₁ | Q₁ |
| Lₐ₃₀₆₉ | Q₁ | Q₁ | Q₁ | Q₅ | O | O | Q₁ | Q₁ | Q₁ |
| Lₐ₃₀₇₀ | Q₁ | Q₁ | Q₁ | Q₆ | O | O | Q₁ | Q₁ | Q₁ |
| Lₐ₃₀₇₁ | Q₁ | Q₁ | Q₁ | Q₇ | O | O | Q₁ | Q₁ | Q₁ |
| Lₐ₃₀₇₂ | Q₁ | Q₁ | Q₁ | Q₈ | O | O | Q₁ | Q₁ | Q₁ |
| Lₐ₃₀₇₃ | Q₁ | Q₁ | Q₁ | Q₉ | O | O | Q₁ | Q₁ | Q₁ |
| Lₐ₃₀₇₄ | Q₁ | Q₁ | Q₁ | Q₁₀ | O | O | Q₁ | Q₁ | Q₁ |
| Lₐ₃₀₇₅ | Q₁ | Q₁ | Q₁ | Q₁₁ | O | O | Q₁ | Q₁ | Q₁ |
| Lₐ₃₀₇₆ | Q₁ | Q₁ | Q₁ | Q₁₂ | O | O | Q₁ | Q₁ | Q₁ |
| Lₐ₃₀₇₇ | Q₁ | Q₁ | Q₁ | Q₁₃ | O | O | Q₁ | Q₁ | Q₁ |
| Lₐ₃₀₇₈ | Q₁ | Q₁ | Q₁ | Q₁₄ | O | O | Q₁ | Q₁ | Q₁ |
| Lₐ₃₀₇₉ | Q₁ | Q₁ | Q₁ | Q₁₅ | O | O | Q₁ | Q₁ | Q₁ |
| Lₐ₃₀₈₀ | Q₁ | Q₁ | Q₁ | Q₁₆ | O | O | Q₁ | Q₁ | Q₁ |
| Lₐ₃₀₈₁ | Q₁ | Q₁ | Q₁ | Q₁₇ | O | O | Q₁ | Q₁ | Q₁ |
| Lₐ₃₀₈₂ | Q₁ | Q₁ | Q₁ | Q₁₈ | O | O | Q₁ | Q₁ | Q₁ |
| Lₐ₃₀₈₃ | Q₁ | Q₁ | Q₁ | Q₁₉ | O | O | Q₁ | Q₁ | Q₁ |
| Lₐ₃₀₈₄ | Q₁ | Q₁ | Q₁ | Q₂₀ | O | O | Q₁ | Q₁ | Q₁ |
| Lₐ₃₀₈₅ | Q₁ | Q₁ | Q₁ | Q₂₁ | O | O | Q₁ | Q₁ | Q₁ |
| Lₐ₃₀₈₆ | Q₁ | Q₁ | Q₁ | Q₂₂ | O | O | Q₁ | Q₁ | Q₁ |
| Lₐ₃₀₈₇ | Q₁ | Q₁ | Q₁ | Q₂₃ | O | O | Q₁ | Q₁ | Q₁ |
| Lₐ₃₀₈₈ | Q₁ | Q₁ | Q₁ | Q₁ | O | O | Q₂ | Q₁ | Q₁ |
| Lₐ₃₀₈₉ | Q₁ | Q₁ | Q₁ | Q₁ | O | O | Q₃ | Q₁ | Q₁ |
| Lₐ₃₀₉₀ | Q₁ | Q₁ | Q₁ | Q₁ | O | O | Q₄ | Q₁ | Q₁ |
| Lₐ₃₀₉₁ | Q₁ | Q₁ | Q₁ | Q₁ | O | O | Q₅ | Q₁ | Q₁ |
| Lₐ₃₀₉₂ | Q₁ | Q₁ | Q₁ | Q₁ | O | O | Q₆ | Q₁ | Q₁ |
| Lₐ₃₀₉₃ | Q₁ | Q₁ | Q₁ | Q₁ | O | O | Q₇ | Q₁ | Q₁ |
| Lₐ₃₀₉₄ | Q₁ | Q₁ | Q₁ | Q₁ | O | O | Q₈ | Q₁ | Q₁ |
| Lₐ₃₀₉₅ | Q₁ | Q₁ | Q₁ | Q₁ | O | O | Q₉ | Q₁ | Q₁ |
| Lₐ₃₀₉₆ | Q₁ | Q₁ | Q₁ | Q₁ | O | O | Q₁₀ | Q₁ | Q₁ |
| Lₐ₃₀₉₇ | Q₁ | Q₁ | Q₁ | Q₁ | O | O | Q₁₁ | Q₁ | Q₁ |
| Lₐ₃₀₉₈ | Q₁ | Q₁ | Q₁ | Q₁ | O | O | Q₁₂ | Q₁ | Q₁ |
| Lₐ₃₀₉₉ | Q₁ | Q₁ | Q₁ | Q₁ | O | O | Q₁₃ | Q₁ | Q₁ |
| Lₐ₃₁₀₀ | Q₁ | Q₁ | Q₁ | Q₁ | O | O | Q₁₄ | Q₁ | Q₁ |
| Lₐ₃₁₀₁ | Q₁ | Q₁ | Q₁ | Q₁ | O | O | Q₁₅ | Q₁ | Q₁ |
| Lₐ₃₁₀₂ | Q₁ | Q₁ | Q₁ | Q₁ | O | O | Q₁₆ | Q₁ | Q₁ |
| Lₐ₃₁₀₃ | Q₁ | Q₁ | Q₁ | Q₁ | O | O | Q₁₇ | Q₁ | Q₁ |
| Lₐ₃₁₀₄ | Q₁ | Q₁ | Q₁ | Q₁ | O | O | Q₁₈ | Q₁ | Q₁ |
| Lₐ₃₁₀₅ | Q₁ | Q₁ | Q₁ | Q₁ | O | O | Q₁₉ | Q₁ | Q₁ |
| Lₐ₃₁₀₆ | Q₁ | Q₁ | Q₁ | Q₁ | O | O | Q₂₀ | Q₁ | Q₁ |
| Lₐ₃₁₀₇ | Q₁ | Q₁ | Q₁ | Q₁ | O | O | Q₂₁ | Q₁ | Q₁ |
| Lₐ₃₁₀₈ | Q₁ | Q₁ | Q₁ | Q₁ | O | O | Q₂₂ | Q₁ | Q₁ |
| Lₐ₃₁₀₉ | Q₁ | Q₁ | Q₁ | Q₁ | O | O | Q₂₃ | Q₁ | Q₁ |
| Lₐ₃₁₁₀ | Q₁ | Q₁ | Q₁ | Q₁ | O | O | Q₁ | Q₂ | Q₁ |
| Lₐ₃₁₁₁ | Q₁ | Q₁ | Q₁ | Q₁ | O | O | Q₁ | Q₃ | Q₁ |
| Lₐ₃₁₁₂ | Q₁ | Q₁ | Q₁ | Q₁ | O | O | Q₁ | Q₄ | Q₁ |
| Lₐ₃₁₁₃ | Q₁ | Q₁ | Q₁ | Q₁ | O | O | Q₁ | Q₅ | Q₁ |
| Lₐ₃₁₁₄ | Q₁ | Q₁ | Q₁ | Q₁ | O | O | Q₁ | Q₆ | Q₁ |
| Lₐ₃₁₁₅ | Q₁ | Q₁ | Q₁ | Q₁ | O | O | Q₁ | Q₇ | Q₁ |
| Lₐ₃₁₁₆ | Q₁ | Q₁ | Q₁ | Q₁ | O | O | Q₁ | Q₈ | Q₁ |
| Lₐ₃₁₁₇ | Q₁ | Q₁ | Q₁ | Q₁ | O | O | Q₁ | Q₉ | Q₁ |
| Lₐ₃₁₁₈ | Q₁ | Q₁ | Q₁ | Q₁ | O | O | Q₁ | Q₁₀ | Q₁ |
| Lₐ₃₁₁₉ | Q₁ | Q₁ | Q₁ | Q₁ | O | O | Q₁ | Q₁₁ | Q₁ |
| Lₐ₃₁₂₀ | Q₁ | Q₁ | Q₁ | Q₁ | O | O | Q₁ | Q₁₂ | Q₁ |
| Lₐ₃₁₂₁ | Q₁ | Q₁ | Q₁ | Q₁ | O | O | Q₁ | Q₁₃ | Q₁ |
| Lₐ₃₁₂₂ | Q₁ | Q₁ | Q₁ | Q₁ | O | O | Q₁ | Q₁₄ | Q₁ |
| Lₐ₃₁₂₃ | Q₁ | Q₁ | Q₁ | Q₁ | O | O | Q₁ | Q₁₅ | Q₁ |
| Lₐ₃₁₂₄ | Q₁ | Q₁ | Q₁ | Q₁ | O | O | Q₁ | Q₁₆ | Q₁ |
| Lₐ₃₁₂₅ | Q₁ | Q₁ | Q₁ | Q₁ | O | O | Q₁ | Q₁₇ | Q₁ |
| Lₐ₃₁₂₆ | Q₁ | Q₁ | Q₁ | Q₁ | O | O | Q₁ | Q₁₈ | Q₁ |
| Lₐ₃₁₂₇ | Q₁ | Q₁ | Q₁ | Q₁ | O | O | Q₁ | Q₁₉ | Q₁ |
| Lₐ₃₁₂₈ | Q₁ | Q₁ | Q₁ | Q₁ | O | O | Q₁ | Q₂₀ | Q₁ |
| Lₐ₃₁₂₉ | Q₁ | Q₁ | Q₁ | Q₁ | O | O | Q₁ | Q₂₁ | Q₁ |
| Lₐ₃₁₃₀ | Q₁ | Q₁ | Q₁ | Q₁ | O | O | Q₁ | Q₂₂ | Q₁ |
| Lₐ₃₁₃₁ | Q₁ | Q₁ | Q₁ | Q₁ | O | O | Q₁ | Q₂₃ | Q₁ |
| Lₐ₃₁₃₂ | Q₁ | Q₁ | Q₁ | Q₁ | O | O | Q₁ | Q₁ | Q₂ |
| Lₐ₃₁₃₃ | Q₁ | Q₁ | Q₁ | Q₁ | O | O | Q₁ | Q₁ | Q₃ |
| Lₐ₃₁₃₄ | Q₁ | Q₁ | Q₁ | Q₁ | O | O | Q₁ | Q₁ | Q₄ |
| Lₐ₃₁₃₅ | Q₁ | Q₁ | Q₁ | Q₁ | O | O | Q₁ | Q₁ | Q₅ |
| Lₐ₃₁₃₆ | Q₁ | Q₁ | Q₁ | Q₁ | O | O | Q₁ | Q₁ | Q₆ |
| Lₐ₃₁₃₇ | Q₁ | Q₁ | Q₁ | Q₁ | O | O | Q₁ | Q₁ | Q₇ |
| Lₐ₃₁₃₈ | Q₁ | Q₁ | Q₁ | Q₁ | O | O | Q₁ | Q₁ | Q₈ |
| Lₐ₃₁₃₉ | Q₁ | Q₁ | Q₁ | Q₁ | O | O | Q₁ | Q₁ | Q₉ |
| Lₐ₃₁₄₀ | Q₁ | Q₁ | Q₁ | Q₁ | O | O | Q₁ | Q₁ | Q₁₀ |
| Lₐ₃₁₄₁ | Q₁ | Q₁ | Q₁ | Q₁ | O | O | Q₁ | Q₁ | Q₁₁ |
| Lₐ₃₁₄₂ | Q₁ | Q₁ | Q₁ | Q₁ | O | O | Q₁ | Q₁ | Q₁₂ |
| Lₐ₃₁₄₃ | Q₁ | Q₁ | Q₁ | Q₁ | O | O | Q₁ | Q₁ | Q₁₃ |
| Lₐ₃₁₄₄ | Q₁ | Q₁ | Q₁ | Q₁ | O | O | Q₁ | Q₁ | Q₁₄ |
| Lₐ₃₁₄₅ | Q₁ | Q₁ | Q₁ | Q₁ | O | O | Q₁ | Q₁ | Q₁₅ |
| Lₐ₃₁₄₆ | Q₁ | Q₁ | Q₁ | Q₁ | O | O | Q₁ | Q₁ | Q₁₆ |
| Lₐ₃₁₄₇ | Q₁ | Q₁ | Q₁ | Q₁ | O | O | Q₁ | Q₁ | Q₁₇ |
| Lₐ₃₁₄₈ | Q₁ | Q₁ | Q₁ | Q₁ | O | O | Q₁ | Q₁ | Q₁₈ |
| Lₐ₃₁₄₉ | Q₁ | Q₁ | Q₁ | Q₁ | O | O | Q₁ | Q₁ | Q₁₉ |
| Lₐ₃₁₅₀ | Q₁ | Q₁ | Q₁ | Q₁ | O | O | Q₁ | Q₁ | Q₂₀ |
| Lₐ₃₁₅₁ | Q₁ | Q₁ | Q₁ | Q₁ | O | O | Q₁ | Q₁ | Q₂₁ |
| Lₐ₃₁₅₂ | Q₁ | Q₁ | Q₁ | Q₁ | O | O | Q₁ | Q₁ | Q₂₂ |
| Lₐ₃₁₅₃ | Q₁ | Q₁ | Q₁ | Q₁ | O | O | Q₁ | Q₁ | Q₂₃ |
| Lₐ₃₁₅₄ | Q₁ | Q₂ | Q₁ | Q₁ | O | O | Q₄ | Q₁ | Q₁ |
| Lₐ₃₁₅₅ | Q₁ | Q₃ | Q₁ | Q₁ | O | O | Q₄ | Q₁ | Q₁ |
| Lₐ₃₁₅₆ | Q₁ | Q₄ | Q₁ | Q₁ | O | O | Q₄ | Q₁ | Q₁ |
| Lₐ₃₁₅₇ | Q₁ | Q₅ | Q₁ | Q₁ | O | O | Q₄ | Q₁ | Q₁ |
| Lₐ₃₁₅₈ | Q₁ | Q₆ | Q₁ | Q₁ | O | O | Q₄ | Q₁ | Q₁ |
| Lₐ₃₁₅₉ | Q₁ | Q₇ | Q₁ | Q₁ | O | O | Q₄ | Q₁ | Q₁ |
| Lₐ₃₁₆₀ | Q₁ | Q₈ | Q₁ | Q₁ | O | O | Q₄ | Q₁ | Q₁ |
| Lₐ₃₁₆₁ | Q₁ | Q₉ | Q₁ | Q₁ | O | O | Q₄ | Q₁ | Q₁ |
| Lₐ₃₁₆₂ | Q₁ | Q₁₀ | Q₁ | Q₁ | O | O | Q₄ | Q₁ | Q₁ |
| Lₐ₃₁₆₃ | Q₁ | Q₁₁ | Q₁ | Q₁ | O | O | Q₄ | Q₁ | Q₁ |
| Lₐ₃₁₆₄ | Q₁ | Q₁₂ | Q₁ | Q₁ | O | O | Q₄ | Q₁ | Q₁ |
| Lₐ₃₁₆₅ | Q₁ | Q₁₃ | Q₁ | Q₁ | O | O | Q₄ | Q₁ | Q₁ |
| Lₐ₃₁₆₆ | Q₁ | Q₁₄ | Q₁ | Q₁ | O | O | Q₄ | Q₁ | Q₁ |
| Lₐ₃₁₆₇ | Q₁ | Q₁₅ | Q₁ | Q₁ | O | O | Q₄ | Q₁ | Q₁ |
| Lₐ₃₁₆₈ | Q₁ | Q₁₆ | Q₁ | Q₁ | O | O | Q₄ | Q₁ | Q₁ |
| Lₐ₃₁₆₉ | Q₁ | Q₁₇ | Q₁ | Q₁ | O | O | Q₄ | Q₁ | Q₁ |
| Lₐ₃₁₇₀ | Q₁ | Q₁₈ | Q₁ | Q₁ | O | O | Q₄ | Q₁ | Q₁ |
| Lₐ₃₁₇₁ | Q₁ | Q₁₉ | Q₁ | Q₁ | O | O | Q₄ | Q₁ | Q₁ |
| Lₐ₃₁₇₂ | Q₁ | Q₂₀ | Q₁ | Q₁ | O | O | Q₄ | Q₁ | Q₁ |
| Lₐ₃₁₇₃ | Q₁ | Q₂₁ | Q₁ | Q₁ | O | O | Q₄ | Q₁ | Q₁ |
| Lₐ₃₁₇₄ | Q₁ | Q₂₂ | Q₁ | Q₁ | O | O | Q₄ | Q₁ | Q₁ |
| Lₐ₃₁₇₅ | Q₁ | Q₂₃ | Q₁ | Q₁ | O | O | Q₄ | Q₁ | Q₁ |
| Lₐ₃₁₇₆ | Q₁ | Q₁ | Q₂ | Q₁ | O | O | Q₄ | Q₁ | Q₁ |
| Lₐ₃₁₇₇ | Q₁ | Q₁ | Q₃ | Q₁ | O | O | Q₄ | Q₁ | Q₁ |
| Lₐ₃₁₇₈ | Q₁ | Q₁ | Q₄ | Q₁ | O | O | Q₄ | Q₁ | Q₁ |
| Lₐ₃₁₇₉ | Q₁ | Q₁ | Q₅ | Q₁ | O | O | Q₄ | Q₁ | Q₁ |
| Lₐ₃₁₈₀ | Q₁ | Q₁ | Q₆ | Q₁ | O | O | Q₄ | Q₁ | Q₁ |
| Lₐ₃₁₈₁ | Q₁ | Q₁ | Q₇ | Q₁ | O | O | Q₄ | Q₁ | Q₁ |
| Lₐ₃₁₈₂ | Q₁ | Q₁ | Q₈ | Q₁ | O | O | Q₄ | Q₁ | Q₁ |
| Lₐ₃₁₈₃ | Q₁ | Q₁ | Q₉ | Q₁ | O | O | Q₄ | Q₁ | Q₁ |
| Lₐ₃₁₈₄ | Q₁ | Q₁ | Q₁₀ | Q₁ | O | O | Q₄ | Q₁ | Q₁ |
| Lₐ₃₁₈₅ | Q₁ | Q₁ | Q₁₁ | Q₁ | O | O | Q₄ | Q₁ | Q₁ |
| Lₐ₃₁₈₆ | Q₁ | Q₁ | Q₁₂ | Q₁ | O | O | Q₄ | Q₁ | Q₁ |
| Lₐ₃₁₈₇ | Q₁ | Q₁ | Q₁₃ | Q₁ | O | O | Q₄ | Q₁ | Q₁ |
| Lₐ₃₁₈₈ | Q₁ | Q₁ | Q₁₄ | Q₁ | O | O | Q₄ | Q₁ | Q₁ |
| Lₐ₃₁₈₉ | Q₁ | Q₁ | Q₁₅ | Q₁ | O | O | Q₄ | Q₁ | Q₁ |
| Lₐ₃₁₉₀ | Q₁ | Q₁ | Q₁₆ | Q₁ | O | O | Q₄ | Q₁ | Q₁ |
| Lₐ₃₁₉₁ | Q₁ | Q₁ | Q₁₇ | Q₁ | O | O | Q₄ | Q₁ | Q₁ |
| Lₐ₃₁₉₂ | Q₁ | Q₁ | Q₁₈ | Q₁ | O | O | Q₄ | Q₁ | Q₁ |
| Lₐ₃₁₉₃ | Q₁ | Q₁ | Q₁₉ | Q₁ | O | O | Q₄ | Q₁ | Q₁ |
| Lₐ₃₁₉₄ | Q₁ | Q₁ | Q₂₀ | Q₁ | O | O | Q₄ | Q₁ | Q₁ |
| Lₐ₃₁₉₅ | Q₁ | Q₁ | Q₂₁ | Q₁ | O | O | Q₄ | Q₁ | Q₁ |
| Lₐ₃₁₉₆ | Q₁ | Q₁ | Q₂₂ | Q₁ | O | O | Q₄ | Q₁ | Q₁ |
| Lₐ₃₁₉₇ | Q₁ | Q₁ | Q₂₃ | Q₁ | O | O | Q₄ | Q₁ | Q₁ |
| Lₐ₃₁₉₈ | Q₁ | Q₂ | Q₁ | Q₁ | O | O | Q₆ | Q₁ | Q₁ |
| Lₐ₃₁₉₉ | Q₁ | Q₃ | Q₁ | Q₁ | O | O | Q₆ | Q₁ | Q₁ |
| Lₐ₃₂₀₀ | Q₁ | Q₄ | Q₁ | Q₁ | O | O | Q₆ | Q₁ | Q₁ |
| Lₐ₃₂₀₁ | Q₁ | Q₅ | Q₁ | Q₁ | O | O | Q₆ | Q₁ | Q₁ |
| Lₐ₃₂₀₂ | Q₁ | Q₆ | Q₁ | Q₁ | O | O | Q₆ | Q₁ | Q₁ |
| Lₐ₃₂₀₃ | Q₁ | Q₇ | Q₁ | Q₁ | O | O | Q₆ | Q₁ | Q₁ |
| Lₐ₃₂₀₄ | Q₁ | Q₈ | Q₁ | Q₁ | O | O | Q₆ | Q₁ | Q₁ |
| Lₐ₃₂₀₅ | Q₁ | Q₉ | Q₁ | Q₁ | O | O | Q₆ | Q₁ | Q₁ |
| Lₐ₃₂₀₆ | Q₁ | Q₁₀ | Q₁ | Q₁ | O | O | Q₆ | Q₁ | Q₁ |
| Lₐ₃₂₀₇ | Q₁ | Q₁₁ | Q₁ | Q₁ | O | O | Q₆ | Q₁ | Q₁ |
| Lₐ₃₂₀₈ | Q₁ | Q₁₂ | Q₁ | Q₁ | O | O | Q₆ | Q₁ | Q₁ |
| Lₐ₃₂₀₉ | Q₁ | Q₁₃ | Q₁ | Q₁ | O | O | Q₆ | Q₁ | Q₁ |
| Lₐ₃₂₁₀ | Q₁ | Q₁₄ | Q₁ | Q₁ | O | O | Q₆ | Q₁ | Q₁ |
| Lₐ₃₂₁₁ | Q₁ | Q₁₅ | Q₁ | Q₁ | O | O | Q₆ | Q₁ | Q₁ |
| Lₐ₃₂₁₂ | Q₁ | Q₁₆ | Q₁ | Q₁ | O | O | Q₆ | Q₁ | Q₁ |
| Lₐ₃₂₁₃ | Q₁ | Q₁₇ | Q₁ | Q₁ | O | O | Q₆ | Q₁ | Q₁ |
| Lₐ₃₂₁₄ | Q₁ | Q₁₈ | Q₁ | Q₁ | O | O | Q₆ | Q₁ | Q₁ |
| Lₐ₃₂₁₅ | Q₁ | Q₁₉ | Q₁ | Q₁ | O | O | Q₆ | Q₁ | Q₁ |
| Lₐ₃₂₁₆ | Q₁ | Q₂₀ | Q₁ | Q₁ | O | O | Q₆ | Q₁ | Q₁ |
| Lₐ₃₂₁₇ | Q₁ | Q₂₁ | Q₁ | Q₁ | O | O | Q₆ | Q₁ | Q₁ |
| Lₐ₃₂₁₈ | Q₁ | Q₂₂ | Q₁ | Q₁ | O | O | Q₆ | Q₁ | Q₁ |
| Lₐ₃₂₁₉ | Q₁ | Q₂₃ | Q₁ | Q₁ | O | O | Q₆ | Q₁ | Q₁ |
| Lₐ₃₂₂₀ | Q₁ | Q₁ | Q₁ | Q₁ | O | O | Q₆ | Q₁ | Q₁ |
| Lₐ₃₂₂₁ | Q₁ | Q₁ | Q₃ | Q₁ | O | O | Q₆ | Q₁ | Q₁ |
| Lₐ₃₂₂₂ | Q₁ | Q₁ | Q₄ | Q₁ | O | O | Q₆ | Q₁ | Q₁ |
| Lₐ₃₂₂₃ | Q₁ | Q₁ | Q₅ | Q₁ | O | O | Q₆ | Q₁ | Q₁ |
| Lₐ₃₂₂₄ | Q₁ | Q₁ | Q₆ | Q₁ | O | O | Q₆ | Q₁ | Q₁ |
| Lₐ₃₂₂₅ | Q₁ | Q₁ | Q₇ | Q₁ | O | O | Q₆ | Q₁ | Q₁ |
| Lₐ₃₂₂₆ | Q₁ | Q₁ | Q₈ | Q₁ | O | O | Q₆ | Q₁ | Q₁ |
| Lₐ₃₂₂₇ | Q | Q₁ | Q₉ | Q₁ | O | O | Q₆ | Q₁ | Q₁ |
| Lₐ₃₂₂₈ | Q₁ | Q₁ | Q₁₀ | Q₁ | O | O | Q₆ | Q₁ | Q₁ |
| Lₐ₃₂₂₉ | Q₁ | Q₁ | Q₁₁ | Q₁ | O | O | Q₆ | Q₁ | Q₁ |
| Lₐ₃₂₃₀ | Q₁ | Q₁ | Q₁₂ | Q₁ | O | O | Q₆ | Q₁ | Q₁ |
| Lₐ₃₂₃₁ | Q₁ | Q₁ | Q₁₃ | Q₁ | O | O | Q₆ | Q₁ | Q₁ |
| Lₐ₃₂₃₂ | Q₁ | Q₁ | Q₁₄ | Q₁ | O | O | Q₆ | Q₁ | Q₁ |
| Lₐ₃₂₃₃ | Q₁ | Q₁ | Q₁₅ | Q₁ | O | O | Q₆ | Q₁ | Q₁ |
| Lₐ₃₂₃₄ | Q₁ | Q₁ | Q₁₆ | Q₁ | O | O | Q₆ | Q₁ | Q₁ |
| Lₐ₃₂₃₅ | Q₁ | Q₁ | Q₁₇ | Q₁ | O | O | Q₆ | Q₁ | Q₁ |
| Lₐ₃₂₃₆ | Q₁ | Q₁ | Q₁₈ | Q₁ | O | O | Q₆ | Q₁ | Q₁ |
| Lₐ₃₂₃₇ | Q₁ | Q₁ | Q₁₉ | Q₁ | O | O | Q₆ | Q₁ | Q₁ |
| Lₐ₃₂₃₈ | Q₁ | Q₁ | Q₂₀ | Q₁ | O | O | Q₆ | Q₁ | Q₁ |
| Lₐ₃₂₃₉ | Q₁ | Q₁ | Q₂₁ | Q₁ | O | O | Q₆ | Q₁ | Q₁ |
| Lₐ₃₂₄₀ | Q₁ | Q₁ | Q₂₂ | Q₁ | O | O | Q₆ | Q₁ | Q₁ |
| Lₐ₃₂₄₁ | Q₁ | Q₁ | Q₂₃ | Q₁ | O | O | Q₆ | Q₁ | Q₁ |
| Lₐ₃₂₄₂ | Q₁ | Q₂ | Q₁ | Q₁ | O | O | Q₇ | Q₁ | Q₁ |
| Lₐ₃₂₄₃ | Q₁ | Q₃ | Q₁ | Q₁ | O | O | Q₇ | Q₁ | Q₁ |
| Lₐ₃₂₄₄ | Q₁ | Q₄ | Q₁ | Q₁ | O | O | Q₇ | Q₁ | Q₁ |
| Lₐ₃₂₄₅ | Q₁ | Q₅ | Q₁ | Q₁ | O | O | Q₇ | Q₁ | Q₁ |
| Lₐ₃₂₄₆ | Q₁ | Q₆ | Q₁ | Q₁ | O | O | Q₇ | Q₁ | Q₁ |
| Lₐ₃₂₄₇ | Q₁ | Q₇ | Q₁ | Q₁ | O | O | Q₇ | Q₁ | Q₁ |
| Lₐ₃₂₄₈ | Q₁ | Q₈ | Q₁ | Q₁ | O | O | Q₇ | Q₁ | Q₁ |
| Lₐ₃₂₄₉ | Q₁ | Q₉ | Q₁ | Q₁ | O | O | Q₇ | Q₁ | Q₁ |
| Lₐ₃₂₅₀ | Q₁ | Q₁₀ | Q₁ | Q₁ | O | O | Q₇ | Q₁ | Q₁ |
| Lₐ₃₂₅₁ | Q₁ | Q₁₁ | Q₁ | Q₁ | O | O | Q₇ | Q₁ | Q₁ |
| Lₐ₃₂₅₂ | Q₁ | Q₁₂ | Q₁ | Q₁ | O | O | Q₇ | Q₁ | Q₁ |
| Lₐ₃₂₅₃ | Q₁ | Q₁₃ | Q₁ | Q₁ | O | O | Q₇ | Q₁ | Q₁ |
| Lₐ₃₂₅₄ | Q₁ | Q₁₄ | Q₁ | Q₁ | O | O | Q₇ | Q₁ | Q₁ |
| Lₐ₃₂₅₅ | Q₁ | Q₁₅ | Q₁ | Q₁ | O | O | Q₇ | Q₁ | Q₁ |
| Lₐ₃₂₅₆ | Q₁ | Q₁₆ | Q₁ | Q₁ | O | O | Q₇ | Q₁ | Q₁ |
| Lₐ₃₂₅₇ | Q₁ | Q₁₇ | Q₁ | Q₁ | O | O | Q₇ | Q₁ | Q₁ |
| Lₐ₃₂₅₈ | Q₁ | Q₁₈ | Q₁ | Q₁ | O | O | Q₇ | Q₁ | Q₁ |
| Lₐ₃₂₅₉ | Q₁ | Q₁₉ | Q₁ | Q₁ | O | O | Q₇ | Q₁ | Q₁ |
| Lₐ₃₂₆₀ | Q₁ | Q₂₀ | Q₁ | Q₁ | O | O | Q₇ | Q₁ | Q₁ |
| Lₐ₃₂₆₁ | Q₁ | Q₂₁ | Q₁ | Q₁ | O | O | Q₇ | Q₁ | Q₁ |
| Lₐ₃₂₆₂ | Q₁ | Q₂₂ | Q₁ | Q₁ | O | O | Q₇ | Q₁ | Q₁ |
| Lₐ₃₂₆₃ | Q₁ | Q₂₃ | Q₁ | Q₁ | O | O | Q₇ | Q₁ | Q₁ |
| Lₐ₃₂₆₄ | Q₁ | Q₁ | Q₂ | Q₁ | O | O | Q₇ | Q₁ | Q₁ |
| Lₐ₃₂₆₅ | Q₁ | Q₁ | Q₃ | Q₁ | O | O | Q₇ | Q₁ | Q₁ |
| Lₐ₃₂₆₆ | Q₁ | Q₁ | Q₄ | Q₁ | O | O | Q₇ | Q₁ | Q₁ |
| Lₐ₃₂₆₇ | Q₁ | Q₁ | Q₅ | Q₁ | O | O | Q₇ | Q₁ | Q₁ |
| Lₐ₃₂₆₈ | Q₁ | Q₁ | Q₆ | Q₁ | O | O | Q₇ | Q₁ | Q₁ |
| Lₐ₃₂₆₉ | Q₁ | Q₁ | Q₇ | Q₁ | O | O | Q₇ | Q₁ | Q₁ |
| Lₐ₃₂₇₀ | Q₁ | Q₁ | Q₈ | Q₁ | O | O | Q₇ | Q₁ | Q₁ |
| Lₐ₃₂₇₁ | Q₁ | Q₁ | Q₉ | Q₁ | O | O | Q₇ | Q₁ | Q₁ |
| Lₐ₃₂₇₂ | Q₁ | Q₁ | Q₁₀ | Q₁ | O | O | Q₇ | Q₁ | Q₁ |
| Lₐ₃₂₇₃ | Q₁ | Q₁ | Q₁₁ | Q₁ | O | O | Q₇ | Q₁ | Q₁ |
| Lₐ₃₂₇₄ | Q₁ | Q₁ | Q₁₂ | Q₁ | O | O | Q₇ | Q₁ | Q₁ |
| Lₐ₃₂₇₅ | Q₁ | Q₁ | Q₁₃ | Q₁ | O | O | Q₇ | Q₁ | Q₁ |
| Lₐ₃₂₇₆ | Q₁ | Q₁ | Q₁₄ | Q₁ | O | O | Q₇ | Q₁ | Q₁ |
| Lₐ₃₂₇₇ | Q₁ | Q₁ | Q₁₅ | Q₁ | O | O | Q₇ | Q₁ | Q₁ |
| Lₐ₃₂₇₈ | Q₁ | Q₁ | Q₁₆ | Q₁ | O | O | Q₇ | Q₁ | Q₁ |
| Lₐ₃₂₇₉ | Q₁ | Q₁ | Q₁₇ | Q₁ | O | O | Q₇ | Q₁ | Q₁ |
| Lₐ₃₂₈₀ | Q₁ | Q₁ | Q₁₈ | Q₁ | O | O | Q₇ | Q₁ | Q₁ |
| Lₐ₃₂₈₁ | Q₁ | Q₁ | Q₁₉ | Q₁ | O | O | Q₇ | Q₁ | Q₁ |
| Lₐ₃₂₈₂ | Q₁ | Q₁ | Q₂₀ | Q₁ | O | O | Q₇ | Q₁ | Q₁ |
| Lₐ₃₂₈₃ | Q₁ | Q₁ | Q₂₁ | Q₁ | O | O | Q₇ | Q₁ | Q₁ |
| Lₐ₃₂₈₄ | Q₁ | Q₁ | Q₂₂ | Q₁ | O | O | Q₇ | Q₁ | Q₁ |
| Lₐ₃₂₈₅ | Q₁ | Q₁ | Q₂₃ | Q₁ | O | O | Q₇ | Q₁ | Q₁ |
| Lₐ₃₂₈₆ | Q₁ | Q₂ | Q₁ | Q₁ | O | O | Q₈ | Q₁ | Q₁ |
| Lₐ₃₂₈₇ | Q₁ | Q₃ | Q₁ | Q₁ | O | O | Q₈ | Q₁ | Q₁ |
| Lₐ₃₂₈₈ | Q₁ | Q₄ | Q₁ | Q₁ | O | O | Q₈ | Q₁ | Q₁ |
| Lₐ₃₂₈₉ | Q₁ | Q₅ | Q₁ | Q₁ | O | O | Q₈ | Q₁ | Q₁ |
| Lₐ₃₂₉₀ | Q₁ | Q₆ | Q₁ | Q₁ | O | O | Q₈ | Q₁ | Q₁ |
| Lₐ₃₂₉₁ | Q₁ | Q₇ | Q₁ | Q₁ | O | O | Q₈ | Q₁ | Q₁ |
| Lₐ₃₂₉₂ | Q₁ | Q₈ | Q₁ | Q₁ | O | O | Q₈ | Q₁ | Q₁ |
| Lₐ₃₂₉₃ | Q₁ | Q₉ | Q₁ | Q₁ | O | O | Q₈ | Q₁ | Q₁ |
| Lₐ₃₂₉₄ | Q₁ | Q₁₀ | Q₁ | Q₁ | O | O | Q₈ | Q₁ | Q₁ |
| Lₐ₃₂₉₅ | Q₁ | Q₁₁ | Q₁ | Q₁ | O | O | Q₈ | Q₁ | Q₁ |
| Lₐ₃₂₉₆ | Q₁ | Q₁₂ | Q₁ | Q₁ | O | O | Q₈ | Q₁ | Q₁ |
| Lₐ₃₂₉₇ | Q₁ | Q₁₃ | Q₁ | Q₁ | O | O | Q₈ | Q₁ | Q₁ |
| Lₐ₃₂₉₈ | Q₁ | Q₁₄ | Q₁ | Q₁ | O | O | Q₈ | Q₁ | Q₁ |
| Lₐ₃₂₉₉ | Q₁ | Q₁₅ | Q₁ | Q₁ | O | O | Q₈ | Q₁ | Q₁ |
| Lₐ₃₃₀₀ | Q₁ | Q₁₆ | Q₁ | Q₁ | O | O | Q₈ | Q₁ | Q₁ |
| Lₐ₃₃₀₁ | Q₁ | Q₁₇ | Q₁ | Q₁ | O | O | Q₈ | Q₁ | Q₁ |
| Lₐ₃₃₀₂ | Q₁ | Q₁₈ | Q₁ | Q₁ | O | O | Q₈ | Q₁ | Q₁ |
| Lₐ₃₃₀₃ | Q₁ | Q₁₉ | Q₁ | Q₁ | O | O | Q₈ | Q₁ | Q₁ |
| Lₐ₃₃₀₄ | Q₁ | Q₂₀ | Q₁ | Q₁ | O | O | Q₈ | Q₁ | Q₁ |
| Lₐ₃₃₀₅ | Q₁ | Q₂₁ | Q₁ | Q₁ | O | O | Q₈ | Q₁ | Q₁ |
| Lₐ₃₃₀₆ | Q₁ | Q₂₂ | Q₁ | Q₁ | O | O | Q₈ | Q₁ | Q₁ |
| Lₐ₃₃₀₇ | Q₁ | Q₂₃ | Q₁ | Q₁ | O | O | Q₈ | Q₁ | Q₁ |
| Lₐ₃₃₀₈ | Q₁ | Q₁ | Q₂ | Q₁ | O | O | Q₈ | Q₁ | Q₁ |
| Lₐ₃₃₀₉ | Q₁ | Q₁ | Q₃ | Q₁ | O | O | Q₈ | Q₁ | Q₁ |
| Lₐ₃₃₁₀ | Q₁ | Q₁ | Q₄ | Q₁ | O | O | Q₈ | Q₁ | Q₁ |
| Lₐ₃₃₁₁ | Q₁ | Q₁ | Q₅ | Q₁ | O | O | Q₈ | Q₁ | Q₁ |
| Lₐ₃₃₁₂ | Q₁ | Q₁ | Q₆ | Q₁ | O | O | Q₈ | Q₁ | Q₁ |
| Lₐ₃₃₁₃ | Q₁ | Q₁ | Q₇ | Q₁ | O | O | Q₈ | Q₁ | Q₁ |
| Lₐ₃₃₁₄ | Q₁ | Q₁ | Q₈ | Q₁ | O | O | Q₈ | Q₁ | Q₁ |
| Lₐ₃₃₁₅ | Q₁ | Q₁ | Q₉ | Q₁ | O | O | Q₈ | Q₁ | Q₁ |
| Lₐ₃₃₁₆ | Q₁ | Q₁ | Q₁₀ | Q₁ | O | O | Q₈ | Q₁ | Q₁ |
| Lₐ₃₃₁₇ | Q₁ | Q₁ | Q₁₁ | Q₁ | O | O | Q₈ | Q₁ | Q₁ |
| Lₐ₃₃₁₈ | Q₁ | Q₁ | Q₁₂ | Q₁ | O | O | Q₈ | Q₁ | Q₁ |
| Lₐ₃₃₁₉ | Q₁ | Q₁ | Q₁₃ | Q₁ | O | O | Q₈ | Q₁ | Q₁ |
| Lₐ₃₃₂₀ | Q₁ | Q₁ | Q₁₄ | Q₁ | O | O | Q₈ | Q₁ | Q₁ |
| Lₐ₃₃₂₁ | Q₁ | Q₁ | Q₁₅ | Q₁ | O | O | Q₈ | Q₁ | Q₁ |
| Lₐ₃₃₂₂ | Q₁ | Q₁ | Q₁₆ | Q₁ | O | O | Q₈ | Q₁ | Q₁ |
| Lₐ₃₃₂₃ | Q₁ | Q₁ | Q₁₇ | Q₁ | O | O | Q₈ | Q₁ | Q₁ |
| Lₐ₃₃₂₄ | Q₁ | Q₁ | Q₁₈ | Q₁ | O | O | Q₈ | Q₁ | Q₁ |
| Lₐ₃₃₂₅ | Q₁ | Q₁ | Q₁₉ | Q₁ | O | O | Q₈ | Q₁ | Q₁ |
| Lₐ₃₃₂₆ | Q₁ | Q₁ | Q₂₀ | Q₁ | O | O | Q₈ | Q₁ | Q₁ |
| Lₐ₃₃₂₇ | Q₁ | Q₁ | Q₂₁ | Q₁ | O | O | Q₈ | Q₁ | Q₁ |
| Lₐ₃₃₂₈ | Q₁ | Q₁ | Q₂₂ | Q₁ | O | O | Q₈ | Q₁ | Q₁ |
| Lₐ₃₃₂₉ | Q₁ | Q₁ | Q₂₃ | Q₁ | O | O | Q₈ | Q₁ | Q₁ |
| Lₐ₃₃₃₀ | Q₁ | Q₂ | Q₁ | Q₁ | O | O | Q₈ | Q₄ | Q₁ |
| Lₐ₃₃₃₁ | Q₁ | Q₃ | Q₁ | Q₁ | O | O | Q₈ | Q₄ | Q₁ |
| Lₐ₃₃₃₂ | Q₁ | Q₄ | Q₁ | Q₁ | O | O | Q₈ | Q₄ | Q₁ |
| Lₐ₃₃₃₃ | Q₁ | Q₅ | Q₁ | Q₁ | O | O | Q₈ | Q₄ | Q₁ |
| Lₐ₃₃₃₄ | Q₁ | Q₆ | Q₁ | Q₁ | O | O | Q₈ | Q₄ | Q₁ |
| Lₐ₃₃₃₅ | Q₁ | Q₇ | Q₁ | Q₁ | O | O | Q₈ | Q₄ | Q₁ |
| Lₐ₃₃₃₆ | Q₁ | Q₈ | Q₁ | Q₁ | O | O | Q₈ | Q₄ | Q₁ |
| Lₐ₃₃₃₇ | Q₁ | Q₉ | Q₁ | Q₁ | O | O | Q₈ | Q₄ | Q₁ |
| Lₐ₃₃₃₈ | Q₁ | Q₁₀ | Q₁ | Q₁ | O | O | Q₈ | Q₄ | Q₁ |
| Lₐ₃₃₃₉ | Q₁ | Q₁₁ | Q₁ | Q₁ | O | O | Q₈ | Q₄ | Q₁ |
| Lₐ₃₃₄₀ | Q₁ | Q₁₂ | Q₁ | Q₁ | O | O | Q₈ | Q₄ | Q₁ |
| Lₐ₃₃₄₁ | Q₁ | Q₁₃ | Q₁ | Q₁ | O | O | Q₈ | Q₄ | Q₁ |
| Lₐ₃₃₄₂ | Q₁ | Q₁₄ | Q₁ | Q₁ | O | O | Q₈ | Q₄ | Q₁ |
| Lₐ₃₃₄₃ | Q₁ | Q₁₅ | Q₁ | Q₁ | O | O | Q₈ | Q₄ | Q₁ |
| Lₐ₃₃₄₄ | Q₁ | Q₁₆ | Q₁ | Q₁ | O | O | Q₈ | Q₄ | Q₁ |
| Lₐ₃₃₄₅ | Q₁ | Q₁₇ | Q₁ | Q₁ | O | O | Q₈ | Q₄ | Q₁ |
| Lₐ₃₃₄₆ | Q₁ | Q₁₈ | Q₁ | Q₁ | O | O | Q₈ | Q₄ | Q₁ |
| Lₐ₃₃₄₇ | Q₁ | Q₁₉ | Q₁ | Q₁ | O | O | Q₈ | Q₄ | Q₁ |
| Lₐ₃₃₄₈ | Q₁ | Q₂₀ | Q₁ | Q₁ | O | O | Q₈ | Q₄ | Q₁ |
| Lₐ₃₃₄₉ | Q₁ | Q₂₁ | Q₁ | Q₁ | O | O | Q₈ | Q₄ | Q₁ |
| Lₐ₃₃₅₀ | Q₁ | Q₂₂ | Q₁ | Q₁ | O | O | Q₈ | Q₄ | Q₁ |
| Lₐ₃₃₅₁ | Q₁ | Q₂₃ | Q₁ | Q₁ | O | O | Q₈ | Q₄ | Q₁ |
| Lₐ₃₃₅₂ | Q₁ | Q₁ | Q₂ | Q₁ | O | O | Q₈ | Q₄ | Q₁ |
| Lₐ₃₃₅₃ | Q₁ | Q₁ | Q₃ | Q₁ | O | O | Q₈ | Q₄ | Q₁ |
| Lₐ₃₃₅₄ | Q₁ | Q₁ | Q₄ | Q₁ | O | O | Q₈ | Q₄ | Q₁ |
| Lₐ₃₃₅₅ | Q₁ | Q₁ | Q₅ | Q₁ | O | O | Q₈ | Q₄ | Q₁ |
| Lₐ₃₃₅₆ | Q₁ | Q₁ | Q₆ | Q₁ | O | O | Q₈ | Q₄ | Q₁ |
| Lₐ₃₃₅₇ | Q₁ | Q₁ | Q₇ | Q₁ | O | O | Q₈ | Q₄ | Q₁ |
| Lₐ₃₃₅₈ | Q₁ | Q₁ | Q₈ | Q₁ | O | O | Q₈ | Q₄ | Q₁ |
| Lₐ₃₃₅₉ | Q₁ | Q₁ | Q₉ | Q₁ | O | O | Q₈ | Q₄ | Q₁ |
| Lₐ₃₃₆₀ | Q₁ | Q₁ | Q₁₀ | Q₁ | O | O | Q₈ | Q₄ | Q₁ |
| Lₐ₃₃₆₁ | Q₁ | Q₁ | Q₁₁ | Q₁ | O | O | Q₈ | Q₄ | Q₁ |
| Lₐ₃₃₆₂ | Q₁ | Q₁ | Q₁₂ | Q₁ | O | O | Q₈ | Q₄ | Q₁ |
| Lₐ₃₃₆₃ | Q₁ | Q₁ | Q₁₃ | Q₁ | O | O | Q₈ | Q₄ | Q₁ |
| Lₐ₃₃₆₄ | Q₁ | Q₁ | Q₁₄ | Q₁ | O | O | Q₈ | Q₄ | Q₁ |
| Lₐ₃₃₆₅ | Q₁ | Q₁ | Q₁₅ | Q₁ | O | O | Q₈ | Q₄ | Q₁ |
| Lₐ₃₃₆₆ | Q₁ | Q₁ | Q₁₆ | Q₁ | O | O | Q₈ | Q₄ | Q₁ |
| Lₐ₃₃₆₇ | Q₁ | Q₁ | Q₁₇ | Q₁ | O | O | Q₈ | Q₄ | Q₁ |
| Lₐ₃₃₆₈ | Q₁ | Q₁ | Q₁₈ | Q₁ | O | O | Q₈ | Q₄ | Q₁ |
| Lₐ₃₃₆₉ | Q₁ | Q₁ | Q₁₉ | Q₁ | O | O | Q₈ | Q₄ | Q₁ |
| Lₐ₃₃₇₀ | Q₁ | Q₁ | Q₂₀ | Q₁ | O | O | Q₈ | Q₄ | Q₁ |
| Lₐ₃₃₇₁ | Q₁ | Q₁ | Q₂₁ | Q₁ | O | O | Q₈ | Q₄ | Q₁ |
| Lₐ₃₃₇₂ | Q₁ | Q₁ | Q₂₂ | Q₁ | O | O | Q₈ | Q₄ | Q₁ |
| Lₐ₃₃₇₃ | Q₁ | Q₁ | Q₂₃ | Q₁ | O | O | Q₈ | Q₄ | Q₁ |
| Lₐ₃₃₇₄ | Q₁ | Q₂ | Q₁ | Q₁ | O | O | Q₈ | Q₁ | Q₄ |
| Lₐ₃₃₇₅ | Q₁ | Q₃ | Q₁ | Q₁ | O | O | Q₈ | Q₁ | Q₄ |
| Lₐ₃₃₇₆ | Q₁ | Q₄ | Q₁ | Q₁ | O | O | Q₈ | Q₁ | Q₄ |
| Lₐ₃₃₇₇ | Q₁ | Q₅ | Q₁ | Q₁ | O | O | Q₈ | Q₁ | Q₄ |
| Lₐ₃₃₇₈ | Q₁ | Q₆ | Q₁ | Q₁ | O | O | Q₈ | Q₁ | Q₄ |
| Lₐ₃₃₇₉ | Q₁ | Q₇ | Q₁ | Q₁ | O | O | Q₈ | Q₁ | Q₄ |
| Lₐ₃₃₈₀ | Q₁ | Q₈ | Q₁ | Q₁ | O | O | Q₈ | Q₁ | Q₄ |
| Lₐ₃₃₈₁ | Q₁ | Q₉ | Q₁ | Q₁ | O | O | Q₈ | Q₁ | Q₄ |
| Lₐ₃₃₈₂ | Q₁ | Q₁₀ | Q₁ | Q₁ | O | O | Q₈ | Q₁ | Q₄ |
| Lₐ₃₃₈₃ | Q₁ | Q₁₁ | Q₁ | Q₁ | O | O | Q₈ | Q₁ | Q₄ |
| Lₐ₃₃₈₄ | Q₁ | Q₁₂ | Q₁ | Q₁ | O | O | Q₈ | Q₁ | Q₄ |
| Lₐ₃₃₈₅ | Q₁ | Q₁₃ | Q₁ | Q₁ | O | O | Q₈ | Q₁ | Q₄ |
| Lₐ₃₃₈₆ | Q₁ | Q₁₄ | Q₁ | Q₁ | O | O | Q₈ | Q₁ | Q₄ |
| Lₐ₃₃₈₇ | Q₁ | Q₁₅ | Q₁ | Q₁ | O | O | Q₈ | Q₁ | Q₄ |
| Lₐ₃₃₈₈ | Q₁ | Q₁₆ | Q₁ | Q₁ | O | O | Q₈ | Q₁ | Q₄ |
| Lₐ₃₃₈₉ | Q₁ | Q₁₇ | Q₁ | Q₁ | O | O | Q₈ | Q₁ | Q₄ |
| Lₐ₃₃₉₀ | Q₁ | Q₁₈ | Q₁ | Q₁ | O | O | Q₈ | Q₁ | Q₄ |
| Lₐ₃₃₉₁ | Q₁ | Q₁₉ | Q₁ | Q₁ | O | O | Q₈ | Q₁ | Q₄ |
| Lₐ₃₃₉₂ | Q₁ | Q₂₀ | Q₁ | Q₁ | O | O | Q₈ | Q₁ | Q₄ |
| Lₐ₃₃₉₃ | Q₁ | Q₂₁ | Q₁ | Q₁ | O | O | Q₈ | Q₁ | Q₄ |
| Lₐ₃₃₉₄ | Q₁ | Q₂₂ | Q₁ | Q₁ | O | O | Q₈ | Q₁ | Q₄ |
| Lₐ₃₃₉₅ | Q₁ | Q₂₃ | Q₁ | Q₁ | O | O | Q₈ | Q₁ | Q₄ |
| Lₐ₃₃₉₆ | Q₁ | Q₁ | Q₂ | Q₁ | O | O | Q₈ | Q₁ | Q₄ |
| Lₐ₃₃₉₇ | Q₁ | Q₁ | Q₃ | Q₁ | O | O | Q₈ | Q₁ | Q₄ |
| Lₐ₃₃₉₈ | Q₁ | Q₁ | Q₄ | Q₁ | O | O | Q₈ | Q₁ | Q₄ |
| Lₐ₃₃₉₉ | Q₁ | Q₁ | Q₅ | Q₁ | O | O | Q₈ | Q₁ | Q₄ |
| Lₐ₃₄₀₀ | Q₁ | Q₁ | Q₆ | Q₁ | O | O | Q₈ | Q₁ | Q₄ |
| Lₐ₃₄₀₁ | Q₁ | Q₁ | Q₇ | Q₁ | O | O | Q₈ | Q₁ | Q₄ |
| Lₐ₃₄₀₂ | Q₁ | Q₁ | Q₈ | Q₁ | O | O | Q₈ | Q₁ | Q₄ |
| Lₐ₃₄₀₃ | Q₁ | Q₁ | Q₉ | Q₁ | O | O | Q₈ | Q₁ | Q₄ |
| Lₐ₃₄₀₄ | Q₁ | Q₁ | Q₁₀ | Q₁ | O | O | Q₈ | Q₁ | Q₄ |
| Lₐ₃₄₀₅ | Q₁ | Q₁ | Q₁₁ | Q₁ | O | O | Q₈ | Q₁ | Q₄ |
| Lₐ₃₄₀₆ | Q₁ | Q₁ | Q₁₂ | Q₁ | O | O | Q₈ | Q₁ | Q₄ |
| Lₐ₃₄₀₇ | Q₁ | Q₁ | Q₁₃ | Q₁ | O | O | Q₈ | Q₁ | Q₄ |
| Lₐ₃₄₀₈ | Q₁ | Q₁ | Q₁₄ | Q₁ | O | O | Q₈ | Q₁ | Q₄ |
| Lₐ₃₄₀₉ | Q₁ | Q₁ | Q₁₅ | Q₁ | O | O | Q₈ | Q₁ | Q₄ |
| Lₐ₃₄₁₀ | Q₁ | Q₁ | Q₁₆ | Q₁ | O | O | Q₈ | Q₁ | Q₄ |
| Lₐ₃₄₁₁ | Q₁ | Q₁ | Q₁₇ | Q₁ | O | O | Q₈ | Q₁ | Q₄ |
| Lₐ₃₄₁₂ | Q₁ | Q₁ | Q₁₈ | Q₁ | O | O | Q₈ | Q₁ | Q₄ |
| Lₐ₃₄₁₃ | Q₁ | Q₁ | Q₁₉ | Q₁ | O | O | Q₈ | Q₁ | Q₄ |
| Lₐ₃₄₁₄ | Q₁ | Q₁ | Q₂₀ | Q₁ | O | O | Q₈ | Q₁ | Q₄ |
| Lₐ₃₄₁₅ | Q₁ | Q₁ | Q₂₁ | Q₁ | O | O | Q₈ | Q₁ | Q₄ |
| Lₐ₃₄₁₆ | Q₁ | Q₁ | Q₂₂ | Q₁ | O | O | Q₈ | Q₁ | Q₄ |
| Lₐ₃₄₁₇ | Q₁ | Q₁ | Q₂₃ | Q₁ | O | O | Q₈ | Q₁ | Q₄ |
| Lₐ₃₄₁₈ | Q₁ | Q₂ | Q₁ | Q₁ | O | O | Q₈ | Q₁ | Q₁ |
| Lₐ₃₄₁₉ | Q₁ | Q₃ | Q₁ | Q₁ | O | O | Q₈ | Q₁ | Q₁ |
| Lₐ₃₄₂₀ | Q₁ | Q₄ | Q₁ | Q₁ | O | O | Q₈ | Q₁ | Q₁ |
| Lₐ₃₄₂₁ | Q₁ | Q₅ | Q₁ | Q₁ | O | O | Q₈ | Q₁ | Q₁ |
| Lₐ₃₄₂₂ | Q₁ | Q₆ | Q₁ | Q₁ | O | O | Q₈ | Q₁ | Q₁ |
| Lₐ₃₄₂₃ | Q₁ | Q₇ | Q₁ | Q₁ | O | O | Q₈ | Q₁ | Q₁ |
| Lₐ₃₄₂₄ | Q₁ | Q₈ | Q₁ | Q₁ | O | O | Q₈ | Q₁ | Q₁ |
| Lₐ₃₄₂₅ | Q₁ | Q₉ | Q₁ | Q₁ | O | O | Q₈ | Q₁ | Q₁ |
| Lₐ₃₄₂₆ | Q₁ | Q₁₀ | Q₁ | Q₁ | O | O | Q₈ | Q₁ | Q₁ |
| Lₐ₃₄₂₇ | Q₁ | Q₁₁ | Q₁ | Q₁ | O | O | Q₈ | Q₁ | Q₁ |
| Lₐ₃₄₂₈ | Q₁ | Q₁₂ | Q₁ | Q₁ | O | O | Q₈ | Q₁ | Q₁ |
| Lₐ₃₄₂₉ | Q₁ | Q₁₃ | Q₁ | Q₁ | O | O | Q₈ | Q₁ | Q₁ |
| Lₐ₃₄₃₀ | Q₁ | Q₁₄ | Q₁ | Q₁ | O | O | Q₈ | Q₁ | Q₁ |
| Lₐ₃₄₃₁ | Q₁ | Q₁₅ | Q₁ | Q₁ | O | O | Q₈ | Q₁ | Q₁ |
| Lₐ₃₄₃₂ | Q₁ | Q₁₆ | Q₁ | Q₁ | O | O | Q₈ | Q₁ | Q₁ |
| Lₐ₃₄₃₃ | Q₁ | Q₁₇ | Q₁ | Q₁ | O | O | Q₈ | Q₁ | Q₁ |
| Lₐ₃₄₃₄ | Q₁ | Q₁₈ | Q₁ | Q₁ | O | O | Q₈ | Q₁ | Q₁ |
| Lₐ₃₄₃₅ | Q₁ | Q₁₉ | Q₁ | Q₁ | O | O | Q₈ | Q₁ | Q₁ |
| Lₐ₃₄₃₆ | Q₁ | Q₂₀ | Q₁ | Q₁ | O | O | Q₈ | Q₁ | Q₁ |
| Lₐ₃₄₃₇ | Q₁ | Q₂₁ | Q₁ | Q₁ | O | O | Q₈ | Q₁ | Q₁ |
| Lₐ₃₄₃₈ | Q₁ | Q₂₂ | Q₁ | Q₁ | O | O | Q₈ | Q₁ | Q₁ |
| Lₐ₃₄₃₉ | Q₁ | Q₂₃ | Q₁ | Q₁ | O | O | Q₈ | Q₁ | Q₁ |
| Lₐ₃₄₄₀ | Q₁ | Q₁ | Q₂ | Q₁ | O | O | Q₈ | Q₁ | Q₁ |
| Lₐ₃₄₄₁ | Q₁ | Q₁ | Q₃ | Q₁ | O | O | Q₈ | Q₁ | Q₁ |
| Lₐ₃₄₄₂ | Q₁ | Q₁ | Q₄ | Q₁ | O | O | Q₈ | Q₁ | Q₁ |
| Lₐ₃₄₄₃ | Q₁ | Q₁ | Q₅ | Q₁ | O | O | Q₈ | Q₁ | Q₁ |
| Lₐ₃₄₄₄ | Q₁ | Q₁ | Q₆ | Q₁ | O | O | Q₈ | Q₁ | Q₁ |
| Lₐ₃₄₄₅ | Q₁ | Q₁ | Q₇ | Q₁ | O | O | Q₈ | Q₁ | Q₁ |
| Lₐ₃₄₄₆ | Q₁ | Q₁ | Q₈ | Q₁ | O | O | Q₈ | Q₁ | Q₁ |
| Lₐ₃₄₄₇ | Q₁ | Q₁ | Q₉ | Q₁ | O | O | Q₈ | Q₁ | Q₁ |
| Lₐ₃₄₄₈ | Q₁ | Q₁ | Q₁₀ | Q₁ | O | O | Q₈ | Q₁ | Q₁ |
| Lₐ₃₄₄₉ | Q₁ | Q₁ | Q₁₁ | Q₁ | O | O | Q₈ | Q₁ | Q₁ |
| Lₐ₃₄₅₀ | Q₁ | Q₁ | Q₁₂ | Q₁ | O | O | Q₈ | Q₁ | Q₁ |
| Lₐ₃₄₅₁ | Q₁ | Q₁ | Q₁₃ | Q₁ | O | O | Q₈ | Q₁ | Q₁ |
| Lₐ₃₄₅₂ | Q₁ | Q₁ | Q₁₄ | Q₁ | O | O | Q₈ | Q₁ | Q₁ |
| Lₐ₃₄₅₃ | Q₁ | Q₁ | Q₁₅ | Q₁ | O | O | Q₈ | Q₁ | Q₁ |
| Lₐ₃₄₅₄ | Q₁ | Q₁ | Q₁₆ | Q₁ | O | O | Q₈ | Q₁ | Q₁ |
| Lₐ₃₄₅₅ | Q₁ | Q₁ | Q₁₇ | Q₁ | O | O | Q₈ | Q₁ | Q₁ |
| Lₐ₃₄₅₆ | Q₁ | Q₁ | Q₁₈ | Q₁ | O | O | Q₈ | Q₁ | Q₁ |
| Lₐ₃₄₅₇ | Q₁ | Q₁ | Q₁₉ | Q₁ | O | O | Q₈ | Q₁ | Q₁ |
| Lₐ₃₄₅₈ | Q₁ | Q₁ | Q₂₀ | Q₁ | O | O | Q₈ | Q₁ | Q₁ |
| Lₐ₃₄₅₉ | Q₁ | Q₁ | Q₂₁ | Q₁ | O | O | Q₈ | Q₁ | Q₁ |
| Lₐ₃₄₆₀ | Q₁ | Q₁ | Q₂₂ | Q₁ | O | O | Q₈ | Q₁ | Q₁ |
| Lₐ₃₄₆₁ | Q₁ | Q₁ | Q₂₃ | Q₁ | O | O | Q₈ | Q₁ | Q₁ |
| Lₐ₃₄₆₂ | Q₁ | Q₂ | Q₁ | Q₁ | O | O | Q₄ | Q₁ | Q₄ |
| Lₐ₃₄₆₃ | Q₁ | Q₃ | Q₁ | Q₁ | O | O | Q₄ | Q₁ | Q₄ |
| Lₐ₃₄₆₄ | Q₁ | Q₄ | Q₁ | Q₁ | O | O | Q₄ | Q₁ | Q₄ |
| Lₐ₃₄₆₅ | Q₁ | Q₅ | Q₁ | Q₁ | O | O | Q₄ | Q₁ | Q₄ |
| Lₐ₃₄₆₆ | Q₁ | Q₆ | Q₁ | Q₁ | O | O | Q₄ | Q₁ | Q₄ |
| Lₐ₃₄₆₇ | Q₁ | Q₇ | Q₁ | Q₁ | O | O | Q₄ | Q₁ | Q₄ |
| Lₐ₃₄₆₈ | Q₁ | Q₈ | Q₁ | Q₁ | O | O | Q₄ | Q₁ | Q₄ |
| Lₐ₃₄₆₉ | Q₁ | Q₉ | Q₁ | Q₁ | O | O | Q₄ | Q₁ | Q₄ |
| Lₐ₃₄₇₀ | Q₁ | Q₁₀ | Q₁ | Q₁ | O | O | Q₄ | Q₁ | Q₄ |
| Lₐ₃₄₇₁ | Q₁ | Q₁₁ | Q₁ | Q₁ | O | O | Q₄ | Q₁ | Q₄ |
| Lₐ₃₄₇₂ | Q₁ | Q₁₂ | Q₁ | Q₁ | O | O | Q₄ | Q₁ | Q₄ |
| Lₐ₃₄₇₃ | Q₁ | Q₁₃ | Q₁ | Q₁ | O | O | Q₄ | Q₁ | Q₄ |
| Lₐ₃₄₇₄ | Q₁ | Q₁₄ | Q₁ | Q₁ | O | O | Q₄ | Q₁ | Q₄ |
| Lₐ₃₄₇₅ | Q₁ | Q₁₅ | Q₁ | Q₁ | O | O | Q₄ | Q₁ | Q₄ |
| Lₐ₃₄₇₆ | Q₁ | Q₁₆ | Q₁ | Q₁ | O | O | Q₄ | Q₁ | Q₄ |
| Lₐ₃₄₇₇ | Q₁ | Q₁₇ | Q₁ | Q₁ | O | O | Q₄ | Q₁ | Q₄ |
| Lₐ₃₄₇₈ | Q₁ | Q₁₈ | Q₁ | Q₁ | O | O | Q₄ | Q₁ | Q₄ |
| Lₐ₃₄₇₉ | Q₁ | Q₁₉ | Q₁ | Q₁ | O | O | Q₄ | Q₁ | Q₄ |
| Lₐ₃₄₈₀ | Q₁ | Q₂₀ | Q₁ | Q₁ | O | O | Q₄ | Q₁ | Q₄ |
| Lₐ₃₄₈₁ | Q₁ | Q₂₁ | Q₁ | Q₁ | O | O | Q₄ | Q₁ | Q₄ |
| Lₐ₃₄₈₂ | Q₁ | Q₂₂ | Q₁ | Q₁ | O | O | Q₄ | Q₁ | Q₄ |
| Lₐ₃₄₈₃ | Q₁ | Q₂₃ | Q₁ | Q₁ | O | O | Q₄ | Q₁ | Q₄ |
| Lₐ₃₄₈₄ | Q₁ | Q₁ | Q₂ | Q₁ | O | O | Q₄ | Q₁ | Q₄ |
| Lₐ₃₄₈₅ | Q₁ | Q₁ | Q₃ | Q₁ | O | O | Q₄ | Q₁ | Q₄ |
| Lₐ₃₄₈₆ | Q₁ | Q₁ | Q₄ | Q₁ | O | O | Q₄ | Q₁ | Q₄ |
| Lₐ₃₄₈₇ | Q₁ | Q₁ | Q₅ | Q₁ | O | O | Q₄ | Q₁ | Q₄ |
| Lₐ₃₄₈₈ | Q₁ | Q₁ | Q₆ | Q₁ | O | O | Q₄ | Q₁ | Q₄ |
| Lₐ₃₄₈₉ | Q₁ | Q₁ | Q₇ | Q₁ | O | O | Q₄ | Q₁ | Q₄ |
| Lₐ₃₄₉₀ | Q₁ | Q₁ | Q₈ | Q₁ | O | O | Q₄ | Q₁ | Q₄ |
| Lₐ₃₄₉₁ | Q₁ | Q₁ | Q₉ | Q₁ | O | O | Q₄ | Q₁ | Q₄ |
| Lₐ₃₄₉₂ | Q₁ | Q₁ | Q₁₀ | Q₁ | O | O | Q₄ | Q₁ | Q₄ |
| Lₐ₃₄₉₃ | Q₁ | Q₁ | Q₁₁ | Q₁ | O | O | Q₄ | Q₁ | Q₄ |
| Lₐ₃₄₉₄ | Q₁ | Q₁ | Q₁₂ | Q₁ | O | O | Q₄ | Q₁ | Q₄ |
| Lₐ₃₄₉₅ | Q₁ | Q₁ | Q₁₃ | Q₁ | O | O | Q₄ | Q₁ | Q₄ |
| Lₐ₃₄₉₆ | Q₁ | Q₁ | Q₁₄ | Q₁ | O | O | Q₄ | Q₁ | Q₄ |
| Lₐ₃₄₉₇ | Q₁ | Q₁ | Q₁₅ | Q₁ | O | O | Q₄ | Q₁ | Q₄ |
| Lₐ₃₄₉₈ | Q₁ | Q₁ | Q₁₆ | Q₁ | O | O | Q₄ | Q₁ | Q₄ |
| Lₐ₃₄₉₉ | Q₁ | Q₁ | Q₁₇ | Q₁ | O | O | Q₄ | Q₁ | Q₄ |
| Lₐ₃₅₀₀ | Q₁ | Q₁ | Q₁₈ | Q₁ | O | O | Q₄ | Q₁ | Q₄ |
| Lₐ₃₅₀₁ | Q₁ | Q₁ | Q₁₉ | Q₁ | O | O | Q₄ | Q₁ | Q₄ |
| Lₐ₃₅₀₂ | Q₁ | Q₁ | Q₂₀ | Q₁ | O | O | Q₄ | Q₁ | Q₄ |
| Lₐ₃₅₀₃ | Q₁ | Q₁ | Q₂₁ | Q₁ | O | O | Q₄ | Q₁ | Q₄ |
| Lₐ₃₅₀₄ | Q₁ | Q₁ | Q₂₂ | Q₁ | O | O | Q₄ | Q₁ | Q₄ |
| Lₐ₃₅₀₅ | Q₁ | Q₁ | Q₂₃ | Q₁ | O | O | Q₄ | Q₁ | Q₄ |
| Lₐ₃₅₀₆ | Q₁ | Q₁ | Q₁ | Q₂ | O | O | Q₄ | Q₁ | Q₄ |
| Lₐ₃₅₀₇ | Q₁ | Q₁ | Q₁ | Q₃ | O | O | Q₄ | Q₁ | Q₄ |
| Lₐ₃₅₀₈ | Q₁ | Q₁ | Q₁ | Q₄ | O | O | Q₄ | Q₁ | Q₄ |
| Lₐ₃₅₀₉ | Q₁ | Q₁ | Q₁ | Q₅ | O | O | Q₄ | Q₁ | Q₄ |
| Lₐ₃₅₁₀ | Q₁ | Q₁ | Q₁ | Q₆ | O | O | Q₄ | Q₁ | Q₄ |
| Lₐ₃₅₁₁ | Q₁ | Q₁ | Q₁ | Q₇ | O | O | Q₄ | Q₁ | Q₄ |
| Lₐ₃₅₁₂ | Q₁ | Q₁ | Q₁ | Q₈ | O | O | Q₄ | Q₁ | Q₄ |
| Lₐ₃₅₁₃ | Q₁ | Q₁ | Q₁ | Q₉ | O | O | Q₄ | Q₁ | Q₄ |
| Lₐ₃₅₁₄ | Q₁ | Q₁ | Q₁ | Q₁₀ | O | O | Q₄ | Q₁ | Q₄ |
| Lₐ₃₅₁₅ | Q₁ | Q₁ | Q₁ | Q₁₁ | O | O | Q₄ | Q₁ | Q₄ |
| Lₐ₃₅₁₆ | Q₁ | Q₁ | Q₁ | Q₁₂ | O | O | Q₄ | Q₁ | Q₄ |
| Lₐ₃₅₁₇ | Q₁ | Q₁ | Q₁ | Q₁₃ | O | O | Q₄ | Q₁ | Q₄ |
| Lₐ₃₅₁₈ | Q₁ | Q₁ | Q₁ | Q₁₄ | O | O | Q₄ | Q₁ | Q₄ |
| Lₐ₃₅₁₉ | Q₁ | Q₁ | Q₁ | Q₁₅ | O | O | Q₄ | Q₁ | Q₄ |
| Lₐ₃₅₂₀ | Q₁ | Q₁ | Q₁ | Q₁₆ | O | O | Q₄ | Q₁ | Q₄ |
| Lₐ₃₅₂₁ | Q₁ | Q₁ | Q₁ | Q₁₇ | O | O | Q₄ | Q₁ | Q₄ |
| Lₐ₃₅₂₂ | Q₁ | Q₁ | Q₁ | Q₁₈ | O | O | Q₄ | Q₁ | Q₄ |
| Lₐ₃₅₂₃ | Q₁ | Q₁ | Q₁ | Q₁₉ | O | O | Q₄ | Q₁ | Q₄ |
| Lₐ₃₅₂₄ | Q₁ | Q₁ | Q₁ | Q₂₀ | O | O | Q₄ | Q₁ | Q₄ |
| Lₐ₃₅₂₅ | Q₁ | Q₁ | Q₁ | Q₂₁ | O | O | Q₄ | Q₁ | Q₄ |
| Lₐ₃₅₂₆ | Q₁ | Q₁ | Q₁ | Q₂₂ | O | O | Q₄ | Q₁ | Q₄ |
| Lₐ₃₅₂₇ | Q₁ | Q₁ | Q₁ | Q₂₃ | O | O | Q₄ | Q₁ | Q₄ |
| Lₐ₃₅₂₈ | Q₁ | Q₁ | Q₁ | Q₁ | O | S | Q₁ | Q₁ | Q₁ |
| Lₐ₃₅₂₉ | Q₂ | Q₁ | Q₁ | Q₁ | O | S | Q₁ | Q₁ | Q₁ |
| Lₐ₃₅₃₀ | Q₃ | Q₁ | Q₁ | Q₁ | O | S | Q₁ | Q₁ | Q₁ |
| Lₐ₃₅₃₁ | Q₄ | Q₁ | Q₁ | Q₁ | O | S | Q₁ | Q₁ | Q₁ |
| Lₐ₃₅₃₂ | Q₅ | Q₁ | Q₁ | Q₁ | O | S | Q₁ | Q₁ | Q₁ |
| Lₐ₃₅₃₃ | Q₆ | Q₁ | Q₁ | Q₁ | O | S | Q₁ | Q₁ | Q₁ |
| Lₐ₃₅₃₄ | Q₇ | Q₁ | Q₁ | Q₁ | O | S | Q₁ | Q₁ | Q₁ |
| Lₐ₃₅₃₅ | Q₈ | Q₁ | Q₁ | Q₁ | O | S | Q₁ | Q₁ | Q₁ |
| Lₐ₃₅₃₆ | Q₉ | Q₁ | Q₁ | Q₁ | O | S | Q₁ | Q₁ | Q₁ |
| Lₐ₃₅₃₇ | Q₁₀ | Q₁ | Q₁ | Q₁ | O | S | Q₁ | Q₁ | Q₁ |
| Lₐ₃₅₃₈ | Q₁₁ | Q₁ | Q₁ | Q₁ | O | S | Q₁ | Q₁ | Q₁ |
| Lₐ₃₅₃₉ | Q₁₂ | Q₁ | Q₁ | Q₁ | O | S | Q₁ | Q₁ | Q₁ |
| Lₐ₃₅₄₀ | Q₁₃ | Q₁ | Q₁ | Q₁ | O | S | Q₁ | Q₁ | Q₁ |
| Lₐ₃₅₄₁ | Q₁₄ | Q₁ | Q₁ | Q₁ | O | S | Q₁ | Q₁ | Q₁ |
| Lₐ₃₅₄₂ | Q₁₅ | Q₁ | Q₁ | Q₁ | O | S | Q₁ | Q₁ | Q₁ |
| Lₐ₃₅₄₃ | Q₁₆ | Q₁ | Q₁ | Q₁ | O | S | Q₁ | Q₁ | Q₁ |
| Lₐ₃₅₄₄ | Q₁₇ | Q₁ | Q₁ | Q₁ | O | S | Q₁ | Q₁ | Q₁ |
| Lₐ₃₅₄₅ | Q₁₈ | Q₁ | Q₁ | Q₁ | O | S | Q₁ | Q₁ | Q₁ |
| Lₐ₃₅₄₆ | Q₁₉ | Q₁ | Q₁ | Q₁ | O | S | Q₁ | Q₁ | Q₁ |
| Lₐ₃₅₄₇ | Q₂₀ | Q₁ | Q₁ | Q₁ | O | S | Q₁ | Q₁ | Q₁ |
| Lₐ₃₅₄₈ | Q₂₁ | Q₁ | Q₁ | Q₁ | O | S | Q₁ | Q₁ | Q₁ |
| Lₐ₃₅₄₉ | Q₂₂ | Q₁ | Q₁ | Q₁ | O | S | Q₁ | Q₁ | Q₁ |
| Lₐ₃₅₅₀ | Q₂₃ | Q₁ | Q₁ | Q₁ | O | S | Q₁ | Q₁ | Q₁ |
| Lₐ₃₅₅₁ | Q₁ | Q₂ | Q₁ | Q₁ | O | S | Q₁ | Q₁ | Q₁ |
| Lₐ₃₅₅₂ | Q₁ | Q₃ | Q₁ | Q₁ | O | S | Q₁ | Q₁ | Q₁ |
| Lₐ₃₅₅₃ | Q₁ | Q₄ | Q₁ | Q₁ | O | S | Q₁ | Q₁ | Q₁ |
| Lₐ₃₅₅₄ | Q₁ | Q₅ | Q₁ | Q₁ | O | S | Q₁ | Q₁ | Q₁ |
| Lₐ₃₅₅₅ | Q₁ | Q₆ | Q₁ | Q₁ | O | S | Q₁ | Q₁ | Q₁ |
| Lₐ₃₅₅₆ | Q₁ | Q₇ | Q₁ | Q₁ | O | S | Q₁ | Q₁ | Q₁ |
| Lₐ₃₅₅₇ | Q₁ | Q₈ | Q₁ | Q₁ | O | S | Q₁ | Q₁ | Q₁ |
| Lₐ₃₅₅₈ | Q₁ | Q₉ | Q₁ | Q₁ | O | S | Q₁ | Q₁ | Q₁ |
| Lₐ₃₅₅₉ | Q₁ | Q₁₀ | Q₁ | Q₁ | O | S | Q₁ | Q₁ | Q₁ |
| Lₐ₃₅₆₀ | Q₁ | Q₁₁ | Q₁ | Q₁ | O | S | Q₁ | Q₁ | Q₁ |
| Lₐ₃₅₆₁ | Q₁ | Q₁₂ | Q₁ | Q₁ | O | S | Q₁ | Q₁ | Q₁ |
| Lₐ₃₅₆₂ | Q₁ | Q₁₃ | Q₁ | Q₁ | O | S | Q₁ | Q₁ | Q₁ |
| Lₐ₃₅₆₃ | Q₁ | Q₁₄ | Q₁ | Q₁ | O | S | Q₁ | Q₁ | Q₁ |
| Lₐ₃₅₆₄ | Q₁ | Q₁₅ | Q₁ | Q₁ | O | S | Q₁ | Q₁ | Q₁ |
| Lₐ₃₅₆₅ | Q₁ | Q₁₆ | Q₁ | Q₁ | O | S | Q₁ | Q₁ | Q₁ |
| Lₐ₃₅₆₆ | Q₁ | Q₁₇ | Q₁ | Q₁ | O | S | Q₁ | Q₁ | Q₁ |
| Lₐ₃₅₆₇ | Q₁ | Q₁₈ | Q₁ | Q₁ | O | S | Q₁ | Q₁ | Q₁ |
| Lₐ₃₅₆₈ | Q₁ | Q₁₉ | Q₁ | Q₁ | O | S | Q₁ | Q₁ | Q₁ |
| Lₐ₃₅₆₉ | Q₁ | Q₂₀ | Q₁ | Q₁ | O | S | Q₁ | Q₁ | Q₁ |
| Lₐ₃₅₇₀ | Q₁ | Q₂₁ | Q₁ | Q₁ | O | S | Q₁ | Q₁ | Q₁ |
| Lₐ₃₅₇₁ | Q₁ | Q₂₂ | Q₁ | Q₁ | O | S | Q₁ | Q₁ | Q₁ |
| Lₐ₃₅₇₂ | Q₁ | Q₂₃ | Q₁ | Q₁ | O | S | Q₁ | Q₁ | Q₁ |
| Lₐ₃₅₇₃ | Q₁ | Q₁ | Q₂ | Q₁ | O | S | Q₁ | Q₁ | Q₁ |
| Lₐ₃₅₇₄ | Q₁ | Q₁ | Q₃ | Q₁ | O | S | Q₁ | Q₁ | Q₁ |
| Lₐ₃₅₇₅ | Q₁ | Q₁ | Q₄ | Q₁ | O | S | Q₁ | Q₁ | Q₁ |
| Lₐ₃₅₇₆ | Q₁ | Q₁ | Q₅ | Q₁ | O | S | Q₁ | Q₁ | Q₁ |
| Lₐ₃₅₇₇ | Q₁ | Q₁ | Q₆ | Q₁ | O | S | Q₁ | Q₁ | Q₁ |
| Lₐ₃₅₇₈ | Q₁ | Q₁ | Q₇ | Q₁ | O | S | Q₁ | Q₁ | Q₁ |
| Lₐ₃₅₇₉ | Q₁ | Q₁ | Q₈ | Q₁ | O | S | Q₁ | Q₁ | Q₁ |
| Lₐ₃₅₈₀ | Q₁ | Q₁ | Q₉ | Q₁ | O | S | Q₁ | Q₁ | Q₁ |
| Lₐ₃₅₈₁ | Q₁ | Q₁ | Q₁₀ | Q₁ | O | S | Q₁ | Q₁ | Q₁ |
| Lₐ₃₅₈₂ | Q₁ | Q₁ | Q₁₁ | Q₁ | O | S | Q₁ | Q₁ | Q₁ |
| Lₐ₃₅₈₃ | Q₁ | Q₁ | Q₁₂ | Q₁ | O | S | Q₁ | Q₁ | Q₁ |
| Lₐ₃₅₈₄ | Q₁ | Q₁ | Q₁₃ | Q₁ | O | S | Q₁ | Q₁ | Q₁ |
| Lₐ₃₅₈₅ | Q₁ | Q₁ | Q₁₄ | Q₁ | O | S | Q₁ | Q₁ | Q₁ |
| Lₐ₃₅₈₆ | Q₁ | Q₁ | Q₁₅ | Q₁ | O | S | Q₁ | Q₁ | Q₁ |
| Lₐ₃₅₈₇ | Q₁ | Q₁ | Q₁₆ | Q₁ | O | S | Q₁ | Q₁ | Q₁ |
| Lₐ₃₅₈₈ | Q₁ | Q₁ | Q₁₇ | Q₁ | O | S | Q₁ | Q₁ | Q₁ |
| Lₐ₃₅₈₉ | Q₁ | Q₁ | Q₁₈ | Q₁ | O | S | Q₁ | Q₁ | Q₁ |
| Lₐ₃₅₉₀ | Q₁ | Q₁ | Q₁₉ | Q₁ | O | S | Q₁ | Q₁ | Q₁ |
| Lₐ₃₅₉₁ | Q₁ | Q₁ | Q₂₀ | Q₁ | O | S | Q₁ | Q₁ | Q₁ |
| Lₐ₃₅₉₂ | Q₁ | Q₁ | Q₂₁ | Q₁ | O | S | Q₁ | Q₁ | Q₁ |
| Lₐ₃₅₉₃ | Q₁ | Q₁ | Q₂₂ | Q₁ | O | S | Q₁ | Q₁ | Q₁ |
| Lₐ₃₅₉₄ | Q₁ | Q₁ | Q₂₃ | Q₁ | O | S | Q₁ | Q₁ | Q₁ |
| Lₐ₃₅₉₅ | Q₁ | Q₁ | Q₁ | Q₂ | O | S | Q₁ | Q₁ | Q₁ |
| Lₐ₃₅₉₆ | Q₁ | Q₁ | Q₁ | Q₃ | O | S | Q₁ | Q₁ | Q₁ |
| Lₐ₃₅₉₇ | Q₁ | Q₁ | Q₁ | Q₄ | O | S | Q₁ | Q₁ | Q₁ |
| Lₐ₃₅₉₈ | Q₁ | Q₁ | Q₁ | Q₅ | O | S | Q₁ | Q₁ | Q₁ |
| Lₐ₃₅₉₉ | Q₁ | Q₁ | Q₁ | Q₆ | O | S | Q₁ | Q₁ | Q₁ |
| Lₐ₃₆₀₀ | Q₁ | Q₁ | Q₁ | Q₇ | O | S | Q₁ | Q₁ | Q₁ |
| Lₐ₃₆₀₁ | Q₁ | Q₁ | Q₁ | Q₈ | O | S | Q₁ | Q₁ | Q₁ |
| Lₐ₃₆₀₂ | Q₁ | Q₁ | Q₁ | Q₉ | O | S | Q₁ | Q₁ | Q₁ |
| Lₐ₃₆₀₃ | Q₁ | Q₁ | Q₁ | Q₁₀ | O | S | Q₁ | Q₁ | Q₁ |
| Lₐ₃₆₀₄ | Q₁ | Q₁ | Q₁ | Q₁₁ | O | S | Q₁ | Q₁ | Q₁ |
| Lₐ₃₆₀₅ | Q₁ | Q₁ | Q₁ | Q₁₂ | O | S | Q₁ | Q₁ | Q₁ |
| Lₐ₃₆₀₆ | Q₁ | Q₁ | Q₁ | Q₁₃ | O | S | Q₁ | Q₁ | Q₁ |
| Lₐ₃₆₀₇ | Q₁ | Q₁ | Q₁ | Q₁₄ | O | S | Q₁ | Q₁ | Q₁ |
| Lₐ₃₆₀₈ | Q₁ | Q₁ | Q₁ | Q₁₅ | O | S | Q₁ | Q₁ | Q₁ |
| Lₐ₃₆₀₉ | Q₁ | Q₁ | Q₁ | Q₁₆ | O | S | Q₁ | Q₁ | Q₁ |
| Lₐ₃₆₁₀ | Q₁ | Q₁ | Q₁ | Q₁₇ | O | S | Q₁ | Q₁ | Q₁ |
| Lₐ₃₆₁₁ | Q₁ | Q₁ | Q₁ | Q₁₈ | O | S | Q₁ | Q₁ | Q₁ |
| Lₐ₃₆₁₂ | Q₁ | Q₁ | Q₁ | Q₁₉ | O | S | Q₁ | Q₁ | Q₁ |
| Lₐ₃₆₁₃ | Q₁ | Q₁ | Q₁ | Q₂₀ | O | S | Q₁ | Q₁ | Q₁ |
| Lₐ₃₆₁₄ | Q₁ | Q₁ | Q₁ | Q₂₁ | O | S | Q₁ | Q₁ | Q₁ |
| Lₐ₃₆₁₅ | Q₁ | Q₁ | Q₁ | Q₂₂ | O | S | Q₁ | Q₁ | Q₁ |
| Lₐ₃₆₁₆ | Q₁ | Q₁ | Q₁ | Q₂₃ | O | S | Q₁ | Q₁ | Q₁ |
| Lₐ₃₆₁₇ | Q₁ | Q₁ | Q₁ | Q₁ | O | S | Q₂ | Q₁ | Q₁ |
| Lₐ₃₆₁₈ | Q₁ | Q₁ | Q₁ | Q₁ | O | S | Q₃ | Q₁ | Q₁ |
| Lₐ₃₆₁₉ | Q₁ | Q₁ | Q₁ | Q₁ | O | S | Q₄ | Q₁ | Q₁ |
| Lₐ₃₆₂₀ | Q₁ | Q₁ | Q₁ | Q₁ | O | S | Q₅ | Q₁ | Q₁ |
| Lₐ₃₆₂₁ | Q₁ | Q₁ | Q₁ | Q₁ | O | S | Q₆ | Q₁ | Q₁ |
| Lₐ₃₆₂₂ | Q₁ | Q₁ | Q₁ | Q₁ | O | S | Q₇ | Q₁ | Q₁ |
| Lₐ₃₆₂₃ | Q₁ | Q₁ | Q₁ | Q₁ | O | S | Q₈ | Q₁ | Q₁ |
| Lₐ₃₆₂₄ | Q₁ | Q₁ | Q₁ | Q₁ | O | S | Q₉ | Q₁ | Q₁ |
| Lₐ₃₆₂₅ | Q₁ | Q₁ | Q₁ | Q₁ | O | S | Q₁₀ | Q₁ | Q₁ |
| Lₐ₃₆₂₆ | Q₁ | Q₁ | Q₁ | Q₁ | O | S | Q₁₁ | Q₁ | Q₁ |
| Lₐ₃₆₂₇ | Q₁ | Q₁ | Q₁ | Q₁ | O | S | Q₁₂ | Q₁ | Q₁ |
| Lₐ₃₆₂₈ | Q₁ | Q₁ | Q₁ | Q₁ | O | S | Q₁₃ | Q₁ | Q₁ |
| Lₐ₃₆₂₉ | Q₁ | Q₁ | Q₁ | Q₁ | O | S | Q₁₄ | Q₁ | Q₁ |
| Lₐ₃₆₃₀ | Q₁ | Q₁ | Q₁ | Q₁ | O | S | Q₁₅ | Q₁ | Q₁ |
| Lₐ₃₆₃₁ | Q₁ | Q₁ | Q₁ | Q₁ | O | S | Q₁₆ | Q₁ | Q₁ |
| Lₐ₃₆₃₂ | Q₁ | Q₁ | Q₁ | Q₁ | O | S | Q₁₇ | Q₁ | Q₁ |
| Lₐ₃₆₃₃ | Q₁ | Q₁ | Q₁ | Q₁ | O | S | Q₁₈ | Q₁ | Q₁ |
| Lₐ₃₆₃₄ | Q₁ | Q₁ | Q₁ | Q₁ | O | S | Q₁₉ | Q₁ | Q₁ |
| Lₐ₃₆₃₅ | Q₁ | Q₁ | Q₁ | Q₁ | O | S | Q₂₀ | Q₁ | Q₁ |
| Lₐ₃₆₃₆ | Q₁ | Q₁ | Q₁ | Q₁ | O | S | Q₂₁ | Q₁ | Q₁ |
| Lₐ₃₆₃₇ | Q₁ | Q₁ | Q₁ | Q₁ | O | S | Q₂₂ | Q₁ | Q₁ |
| Lₐ₃₆₃₈ | Q₁ | Q₁ | Q₁ | Q₁ | O | S | Q₂₃ | Q₁ | Q₁ |
| Lₐ₃₆₃₉ | Q₁ | Q₁ | Q₁ | Q₁ | O | S | Q₁ | Q₂ | Q₁ |
| Lₐ₃₆₄₀ | Q₁ | Q₁ | Q₁ | Q₁ | O | S | Q₁ | Q₃ | Q₁ |
| Lₐ₃₆₄₁ | Q₁ | Q₁ | Q₁ | Q₁ | O | S | Q₁ | Q₄ | Q₁ |
| Lₐ₃₆₄₂ | Q₁ | Q₁ | Q₁ | Q₁ | O | S | Q₁ | Q₅ | Q₁ |
| Lₐ₃₆₄₃ | Q₁ | Q₁ | Q₁ | Q₁ | O | S | Q₁ | Q₆ | Q₁ |
| Lₐ₃₆₄₄ | Q₁ | Q₁ | Q₁ | Q₁ | O | S | Q₁ | Q₇ | Q₁ |
| Lₐ₃₆₄₅ | Q₁ | Q₁ | Q₁ | Q₁ | O | S | Q₁ | Q₈ | Q₁ |
| Lₐ₃₆₄₆ | Q₁ | Q₁ | Q₁ | Q₁ | O | S | Q₁ | Q₉ | Q₁ |
| Lₐ₃₆₄₇ | Q₁ | Q₁ | Q₁ | Q₁ | O | S | Q₁ | Q₁₀ | Q₁ |
| Lₐ₃₆₄₈ | Q₁ | Q₁ | Q₁ | Q₁ | O | S | Q₁ | Q₁₁ | Q₁ |
| Lₐ₃₆₄₉ | Q₁ | Q₁ | Q₁ | Q₁ | O | S | Q₁ | Q₁₂ | Q₁ |
| Lₐ₃₆₅₀ | Q₁ | Q₁ | Q₁ | Q₁ | O | S | Q₁ | Q₁₃ | Q₁ |
| Lₐ₃₆₅₁ | Q₁ | Q₁ | Q₁ | Q₁ | O | S | Q₁ | Q₁₄ | Q₁ |
| Lₐ₃₆₅₂ | Q₁ | Q₁ | Q₁ | Q₁ | O | S | Q₁ | Q₁₅ | Q₁ |
| Lₐ₃₆₅₃ | Q₁ | Q₁ | Q₁ | Q₁ | O | S | Q₁ | Q₁₆ | Q₁ |
| Lₐ₃₆₅₄ | Q₁ | Q₁ | Q₁ | Q₁ | O | S | Q₁ | Q₁₇ | Q₁ |
| Lₐ₃₆₅₅ | Q₁ | Q₁ | Q₁ | Q₁ | O | S | Q₁ | Q₁₈ | Q₁ |
| Lₐ₃₆₅₆ | Q₁ | Q₁ | Q₁ | Q₁ | O | S | Q₁ | Q₁₉ | Q₁ |
| Lₐ₃₆₅₇ | Q₁ | Q₁ | Q₁ | Q₁ | O | S | Q₁ | Q₂₀ | Q₁ |
| Lₐ₃₆₅₈ | Q₁ | Q₁ | Q₁ | Q₁ | O | S | Q₁ | Q₂₁ | Q₁ |
| Lₐ₃₆₅₉ | Q₁ | Q₁ | Q₁ | Q₁ | O | S | Q₁ | Q₂₂ | Q₁ |
| Lₐ₃₆₆₀ | Q₁ | Q₁ | Q₁ | Q₁ | O | S | Q₁ | Q₂₃ | Q₁ |
| Lₐ₃₆₆₁ | Q₁ | Q₁ | Q₁ | Q₁ | O | S | Q₁ | Q₁ | Q₂ |
| Lₐ₃₆₆₂ | Q₁ | Q₁ | Q₁ | Q₁ | O | S | Q₁ | Q₁ | Q₃ |
| Lₐ₃₆₆₃ | Q₁ | Q₁ | Q₁ | Q₁ | O | S | Q₁ | Q₁ | Q₄ |
| Lₐ₃₆₆₄ | Q₁ | Q₁ | Q₁ | Q₁ | O | S | Q₁ | Q₁ | Q₅ |
| Lₐ₃₆₆₅ | Q₁ | Q₁ | Q₁ | Q₁ | O | S | Q₁ | Q₁ | Q₆ |
| Lₐ₃₆₆₆ | Q₁ | Q₁ | Q₁ | Q₁ | O | S | Q₁ | Q₁ | Q₇ |
| Lₐ₃₆₆₇ | Q₁ | Q₁ | Q₁ | Q₁ | O | S | Q₁ | Q₁ | Q₈ |
| Lₐ₃₆₆₈ | Q₁ | Q₁ | Q₁ | Q₁ | O | S | Q₁ | Q₁ | Q₉ |
| Lₐ₃₆₆₉ | Q₁ | Q₁ | Q₁ | Q₁ | O | S | Q₁ | Q₁ | Q₁₀ |
| Lₐ₃₆₇₀ | Q₁ | Q₁ | Q₁ | Q₁ | O | S | Q₁ | Q₁ | Q₁₁ |
| Lₐ₃₆₇₁ | Q₁ | Q₁ | Q₁ | Q₁ | O | S | Q₁ | Q₁ | Q₁₂ |
| Lₐ₃₆₇₂ | Q₁ | Q₁ | Q₁ | Q₁ | O | S | Q₁ | Q₁ | Q₁₃ |
| Lₐ₃₆₇₃ | Q₁ | Q₁ | Q₁ | Q₁ | O | S | Q₁ | Q₁ | Q₁₄ |
| Lₐ₃₆₇₄ | Q₁ | Q₁ | Q | Q₁ | O | S | Q₁ | Q₁ | Q₁₅ |
| Lₐ₃₆₇₅ | Q₁ | Q₁ | Q₁ | Q₁ | O | S | Q₁ | Q₁ | Q₁₆ |
| Lₐ₃₆₇₆ | Q₁ | Q₁ | Q₁ | Q₁ | O | S | Q₁ | Q₁ | Q₁₇ |
| Lₐ₃₆₇₇ | Q₁ | Q₁ | Q₁ | Q₁ | O | S | Q₁ | Q₁ | Q₁₈ |
| Lₐ₃₆₇₈ | Q₁ | Q₁ | Q₁ | Q₁ | O | S | Q₁ | Q₁ | Q₁₉ |
| Lₐ₃₆₇₉ | Q₁ | Q₁ | Q₁ | Q₁ | O | S | Q₁ | Q₁ | Q₂₀ |
| Lₐ₃₆₈₀ | Q₁ | Q₁ | Q₁ | Q₁ | O | S | Q₁ | Q₁ | Q₂₁ |
| Lₐ₃₆₈₁ | Q₁ | Q₁ | Q₁ | Q₁ | O | S | Q₁ | Q₁ | Q₂₂ |
| Lₐ₃₆₈₂ | Q₁ | Q₁ | Q₁ | Q₁ | O | S | Q₁ | Q₁ | Q₂₃ |
| Lₐ₃₆₈₃ | Q₁ | Q₂ | Q₁ | Q₁ | O | S | Q₄ | Q₁ | Q₁ |
| Lₐ₃₆₈₄ | Q₁ | Q₃ | Q₁ | Q₁ | O | S | Q₄ | Q₁ | Q₁ |
| Lₐ₃₆₈₅ | Q₁ | Q₄ | Q₁ | Q₁ | O | S | Q₄ | Q₁ | Q₁ |
| Lₐ₃₆₈₆ | Q₁ | Q₅ | Q₁ | Q₁ | O | S | Q₄ | Q₁ | Q₁ |
| Lₐ₃₆₈₇ | Q₁ | Q₆ | Q₁ | Q₁ | O | S | Q₄ | Q₁ | Q₁ |
| Lₐ₃₆₈₈ | Q₁ | Q₇ | Q₁ | Q₁ | O | S | Q₄ | Q₁ | Q₁ |
| Lₐ₃₆₈₉ | Q₁ | Q₈ | Q₁ | Q₁ | O | S | Q₄ | Q₁ | Q₁ |
| Lₐ₃₆₉₀ | Q₁ | Q₉ | Q₁ | Q₁ | O | S | Q₄ | Q₁ | Q₁ |
| Lₐ₃₆₉₁ | Q₁ | Q₁₀ | Q₁ | Q₁ | O | S | Q₄ | Q₁ | Q₁ |
| Lₐ₃₆₉₂ | Q₁ | Q₁₁ | Q₁ | Q₁ | O | S | Q₄ | Q₁ | Q₁ |
| Lₐ₃₆₉₃ | Q₁ | Q₁₂ | Q₁ | Q₁ | O | S | Q₄ | Q₁ | Q₁ |
| Lₐ₃₆₉₄ | Q₁ | Q₁₃ | Q₁ | Q₁ | O | S | Q₄ | Q₁ | Q₁ |
| Lₐ₃₆₉₅ | Q₁ | Q₁₄ | Q₁ | Q₁ | O | S | Q₄ | Q₁ | Q₁ |
| Lₐ₃₆₉₆ | Q₁ | Q₁₅ | Q₁ | Q₁ | O | S | Q₄ | Q₁ | Q₁ |
| Lₐ₃₆₉₇ | Q₁ | Q₁₆ | Q₁ | Q₁ | O | S | Q₄ | Q₁ | Q₁ |
| Lₐ₃₆₉₈ | Q₁ | Q₁₇ | Q₁ | Q₁ | O | S | Q₄ | Q₁ | Q₁ |
| Lₐ₃₆₉₉ | Q₁ | Q₁₈ | Q₁ | Q₁ | O | S | Q₄ | Q₁ | Q₁ |
| Lₐ₃₇₀₀ | Q₁ | Q₁₉ | Q₁ | Q₁ | O | S | Q₄ | Q₁ | Q₁ |
| Lₐ₃₇₀₁ | Q₁ | Q₂₀ | Q₁ | Q₁ | O | S | Q₄ | Q₁ | Q₁ |
| Lₐ₃₇₀₂ | Q₁ | Q₂₁ | Q₁ | Q₁ | O | S | Q₄ | Q₁ | Q₁ |
| Lₐ₃₇₀₃ | Q₁ | Q₂₂ | Q₁ | Q₁ | O | S | Q₄ | Q₁ | Q₁ |
| Lₐ₃₇₀₄ | Q₁ | Q₂₃ | Q₁ | Q₁ | O | S | Q₄ | Q₁ | Q₁ |
| Lₐ₃₇₀₅ | Q₁ | Q₁ | Q₂ | Q₁ | O | S | Q₄ | Q₁ | Q₁ |
| Lₐ₃₇₀₆ | Q₁ | Q₁ | Q₃ | Q₁ | O | S | Q₄ | Q₁ | Q₁ |
| Lₐ₃₇₀₇ | Q₁ | Q₁ | Q₄ | Q₁ | O | S | Q₄ | Q₁ | Q₁ |
| Lₐ₃₇₀₈ | Q₁ | Q₁ | Q₅ | Q₁ | O | S | Q₄ | Q₁ | Q₁ |
| Lₐ₃₇₀₉ | Q₁ | Q₁ | Q₆ | Q₁ | O | S | Q₄ | Q₁ | Q₁ |
| Lₐ₃₇₁₀ | Q₁ | Q₁ | Q₇ | Q₁ | O | S | Q₄ | Q₁ | Q₁ |
| Lₐ₃₇₁₁ | Q₁ | Q₁ | Q₈ | Q₁ | O | S | Q₄ | Q₁ | Q₁ |
| Lₐ₃₇₁₂ | Q₁ | Q₁ | Q₉ | Q₁ | O | S | Q₄ | Q₁ | Q₁ |
| Lₐ₃₇₁₃ | Q₁ | Q₁ | Q₁₀ | Q₁ | O | S | Q₄ | Q₁ | Q₁ |
| Lₐ₃₇₁₄ | Q₁ | Q₁ | Q₁₁ | Q₁ | O | S | Q₄ | Q₁ | Q₁ |
| Lₐ₃₇₁₅ | Q₁ | Q₁ | Q₁₂ | Q₁ | O | S | Q₄ | Q₁ | Q₁ |
| Lₐ₃₇₁₆ | Q₁ | Q₁ | Q₁₃ | Q₁ | O | S | Q₄ | Q₁ | Q₁ |
| Lₐ₃₇₁₇ | Q₁ | Q₁ | Q₁₄ | Q₁ | O | S | Q₄ | Q₁ | Q₁ |
| Lₐ₃₇₁₈ | Q₁ | Q₁ | Q₁₅ | Q₁ | O | S | Q₄ | Q₁ | Q₁ |
| Lₐ₃₇₁₉ | Q₁ | Q₁ | Q₁₆ | Q₁ | O | S | Q₄ | Q₁ | Q₁ |
| Lₐ₃₇₂₀ | Q₁ | Q₁ | Q₁₇ | Q₁ | O | S | Q₄ | Q₁ | Q₁ |
| Lₐ₃₇₂₁ | Q₁ | Q₁ | Q₁₈ | Q₁ | O | S | Q₄ | Q₁ | Q₁ |
| Lₐ₃₇₂₂ | Q₁ | Q₁ | Q₁₉ | Q₁ | O | S | Q₄ | Q₁ | Q₁ |
| Lₐ₃₇₂₃ | Q₁ | Q₁ | Q₂₀ | Q₁ | O | S | Q₄ | Q₁ | Q₁ |
| Lₐ₃₇₂₄ | Q₁ | Q₁ | Q₂₁ | Q₁ | O | S | Q₄ | Q₁ | Q₁ |
| Lₐ₃₇₂₅ | Q₁ | Q₁ | Q₂₂ | Q₁ | O | S | Q₄ | Q₁ | Q₁ |
| Lₐ₃₇₂₆ | Q₁ | Q₁ | Q₂₃ | Q₁ | O | S | Q₄ | Q₁ | Q₁ |
| Lₐ₃₇₂₇ | Q₁ | Q₂ | Q₁ | Q₁ | O | S | Q₆ | Q₁ | Q₁ |
| Lₐ₃₇₂₈ | Q₁ | Q₃ | Q₁ | Q₁ | O | S | Q₆ | Q₁ | Q₁ |
| Lₐ₃₇₂₉ | Q₁ | Q₄ | Q₁ | Q₁ | O | S | Q₆ | Q₁ | Q₁ |
| Lₐ₃₇₃₀ | Q₁ | Q₅ | Q₁ | Q₁ | O | S | Q₆ | Q₁ | Q₁ |
| Lₐ₃₇₃₁ | Q₁ | Q₆ | Q₁ | Q₁ | O | S | Q₆ | Q₁ | Q₁ |
| Lₐ₃₇₃₂ | Q₁ | Q₇ | Q₁ | Q₁ | O | S | Q₆ | Q₁ | Q₁ |
| Lₐ₃₇₃₃ | Q₁ | Q₈ | Q₁ | Q₁ | O | S | Q₆ | Q₁ | Q₁ |
| Lₐ₃₇₃₄ | Q₁ | Q₉ | Q₁ | Q₁ | O | S | Q₆ | Q₁ | Q₁ |
| Lₐ₃₇₃₅ | Q₁ | Q₁₀ | Q₁ | Q₁ | O | S | Q₆ | Q₁ | Q₁ |
| Lₐ₃₇₃₆ | Q₁ | Q₁₁ | Q₁ | Q₁ | O | S | Q₆ | Q₁ | Q₁ |
| Lₐ₃₇₃₇ | Q₁ | Q₁₂ | Q₁ | Q₁ | O | S | Q₆ | Q₁ | Q₁ |
| Lₐ₃₇₃₈ | Q₁ | Q₁₃ | Q₁ | Q₁ | O | S | Q₆ | Q₁ | Q₁ |
| Lₐ₃₇₃₉ | Q₁ | Q₁₄ | Q₁ | Q₁ | O | S | Q₆ | Q₁ | Q₁ |
| Lₐ₃₇₄₀ | Q₁ | Q₁₅ | Q₁ | Q₁ | O | S | Q₆ | Q₁ | Q₁ |
| Lₐ₃₇₄₁ | Q₁ | Q₁₆ | Q₁ | Q₁ | O | S | Q₆ | Q₁ | Q₁ |
| Lₐ₃₇₄₂ | Q₁ | Q₁₇ | Q₁ | Q₁ | O | S | Q₆ | Q₁ | Q₁ |
| Lₐ₃₇₄₃ | Q₁ | Q₁₈ | Q₁ | Q₁ | O | S | Q₆ | Q₁ | Q₁ |
| Lₐ₃₇₄₄ | Q₁ | Q₁₉ | Q₁ | Q₁ | O | S | Q₆ | Q₁ | Q₁ |
| Lₐ₃₇₄₅ | Q₁ | Q₂₀ | Q₁ | Q₁ | O | S | Q₆ | Q₁ | Q₁ |
| Lₐ₃₇₄₆ | Q₁ | Q₂₁ | Q₁ | Q₁ | O | S | Q₆ | Q₁ | Q₁ |
| Lₐ₃₇₄₇ | Q₁ | Q₂₂ | Q₁ | Q₁ | O | S | Q₆ | Q₁ | Q₁ |
| Lₐ₃₇₄₈ | Q₁ | Q₂₃ | Q₁ | Q₁ | O | S | Q₆ | Q₁ | Q₁ |
| Lₐ₃₇₄₉ | Q₁ | Q₁ | Q₁ | Q₁ | O | S | Q₆ | Q₁ | Q₁ |
| Lₐ₃₇₅₀ | Q₁ | Q₁ | Q₃ | Q₁ | O | S | Q₆ | Q₁ | Q₁ |
| Lₐ₃₇₅₁ | Q₁ | Q₁ | Q₄ | Q₁ | O | S | Q₆ | Q₁ | Q₁ |
| Lₐ₃₇₅₂ | Q₁ | Q₁ | Q₅ | Q₁ | O | S | Q₆ | Q₁ | Q₁ |
| Lₐ₃₇₅₃ | Q₁ | Q₁ | Q₆ | Q₁ | O | S | Q₆ | Q₁ | Q₁ |
| Lₐ₃₇₅₄ | Q₁ | Q₁ | Q₇ | Q₁ | O | S | Q₆ | Q₁ | Q₁ |
| Lₐ₃₇₅₅ | Q₁ | Q₁ | Q₈ | Q₁ | O | S | Q₆ | Q₁ | Q₁ |
| Lₐ₃₇₅₆ | Q₁ | Q₁ | Q₉ | Q₁ | O | S | Q₆ | Q₁ | Q₁ |
| Lₐ₃₇₅₇ | Q₁ | Q₁ | Q₁₀ | Q₁ | O | S | Q₆ | Q₁ | Q₁ |
| Lₐ₃₇₅₈ | Q₁ | Q₁ | Q₁₁ | Q₁ | O | S | Q₆ | Q₁ | Q₁ |
| Lₐ₃₇₅₉ | Q₁ | Q₁ | Q₁₂ | Q₁ | O | S | Q₆ | Q₁ | Q₁ |
| Lₐ₃₇₆₀ | Q₁ | Q₁ | Q₁₃ | Q₁ | O | S | Q₆ | Q₁ | Q₁ |
| Lₐ₃₇₆₁ | Q₁ | Q₁ | Q₁₄ | Q₁ | O | S | Q₆ | Q₁ | Q₁ |
| Lₐ₃₇₆₂ | Q₁ | Q₁ | Q₁₅ | Q₁ | O | S | Q₆ | Q₁ | Q₁ |
| Lₐ₃₇₆₃ | Q₁ | Q₁ | Q₁₆ | Q₁ | O | S | Q₆ | Q₁ | Q₁ |
| Lₐ₃₇₆₄ | Q₁ | Q₁ | Q₁₇ | Q₁ | O | S | Q₆ | Q₁ | Q₁ |
| Lₐ₃₇₆₅ | Q₁ | Q₁ | Q₁₈ | Q₁ | O | S | Q₆ | Q₁ | Q₁ |
| Lₐ₃₇₆₆ | Q₁ | Q₁ | Q₁₉ | Q₁ | O | S | Q₆ | Q₁ | Q₁ |
| Lₐ₃₇₆₇ | Q₁ | Q₁ | Q₂₀ | Q₁ | O | S | Q₆ | Q₁ | Q₁ |
| Lₐ₃₇₆₈ | Q₁ | Q₁ | Q₂₁ | Q₁ | O | S | Q₆ | Q₁ | Q₁ |
| Lₐ₃₇₆₉ | Q₁ | Q₁ | Q₂₂ | Q₁ | O | S | Q₆ | Q₁ | Q₁ |
| Lₐ₃₇₇₀ | Q₁ | Q₁ | Q₂₃ | Q₁ | O | S | Q₆ | Q₁ | Q₁ |
| Lₐ₃₇₇₁ | Q₁ | Q₂ | Q₁ | Q₁ | O | S | Q₇ | Q₁ | Q₁ |
| Lₐ₃₇₇₂ | Q₁ | Q₃ | Q₁ | Q₁ | O | S | Q₇ | Q₁ | Q₁ |
| Lₐ₃₇₇₃ | Q₁ | Q₄ | Q₁ | Q₁ | O | S | Q₇ | Q₁ | Q₁ |
| Lₐ₃₇₇₄ | Q₁ | Q₅ | Q₁ | Q₁ | O | S | Q₇ | Q₁ | Q₁ |
| Lₐ₃₇₇₅ | Q₁ | Q₆ | Q₁ | Q₁ | O | S | Q₇ | Q₁ | Q₁ |
| Lₐ₃₇₇₆ | Q₁ | Q₇ | Q₁ | Q₁ | O | S | Q₇ | Q₁ | Q₁ |
| Lₐ₃₇₇₇ | Q₁ | Q₈ | Q₁ | Q₁ | O | S | Q₇ | Q₁ | Q₁ |
| Lₐ₃₇₇₈ | Q₁ | Q₉ | Q₁ | Q₁ | O | S | Q₇ | Q₁ | Q₁ |
| Lₐ₃₇₇₉ | Q₁ | Q₁₀ | Q₁ | Q₁ | O | S | Q₇ | Q₁ | Q₁ |
| Lₐ₃₇₈₀ | Q₁ | Q₁₁ | Q₁ | Q₁ | O | S | Q₇ | Q₁ | Q₁ |
| Lₐ₃₇₈₁ | Q₁ | Q₁₂ | Q₁ | Q₁ | O | S | Q₇ | Q₁ | Q₁ |
| Lₐ₃₇₈₂ | Q₁ | Q₁₃ | Q₁ | Q₁ | O | S | Q₇ | Q₁ | Q₁ |
| Lₐ₃₇₈₃ | Q₁ | Q₁₄ | Q₁ | Q₁ | O | S | Q₇ | Q₁ | Q₁ |
| Lₐ₃₇₈₄ | Q₁ | Q₁₅ | Q₁ | Q₁ | O | S | Q₇ | Q₁ | Q₁ |
| Lₐ₃₇₈₅ | Q₁ | Q₁₆ | Q₁ | Q₁ | O | S | Q₇ | Q₁ | Q₁ |
| Lₐ₃₇₈₆ | Q₁ | Q₁₇ | Q₁ | Q₁ | O | S | Q₇ | Q₁ | Q₁ |
| Lₐ₃₇₈₇ | Q₁ | Q₁₈ | Q₁ | Q₁ | O | S | Q₇ | Q₁ | Q₁ |
| Lₐ₃₇₈₈ | Q₁ | Q₁₉ | Q₁ | Q₁ | O | S | Q₇ | Q₁ | Q₁ |
| Lₐ₃₇₈₉ | Q₁ | Q₂₀ | Q₁ | Q₁ | O | S | Q₇ | Q₁ | Q₁ |
| Lₐ₃₇₉₀ | Q₁ | Q₂₁ | Q₁ | Q₁ | O | S | Q₇ | Q₁ | Q₁ |
| Lₐ₃₇₉₁ | Q₁ | Q₂₂ | Q₁ | Q₁ | O | S | Q₇ | Q₁ | Q₁ |
| Lₐ₃₇₉₂ | Q₁ | Q₂₃ | Q₁ | Q₁ | O | S | Q₇ | Q₁ | Q₁ |
| Lₐ₃₇₉₃ | Q₁ | Q₁ | Q₂ | Q₁ | O | S | Q₇ | Q₁ | Q₁ |
| Lₐ₃₇₉₄ | Q₁ | Q₁ | Q₃ | Q₁ | O | S | Q₇ | Q₁ | Q₁ |
| Lₐ₃₇₉₅ | Q₁ | Q₁ | Q₄ | Q₁ | O | S | Q₇ | Q₁ | Q₁ |
| Lₐ₃₇₉₆ | Q₁ | Q₁ | Q₅ | Q₁ | O | S | Q₇ | Q₁ | Q₁ |
| Lₐ₃₇₉₇ | Q₁ | Q₁ | Q₆ | Q₁ | O | S | Q₇ | Q₁ | Q₁ |
| Lₐ₃₇₉₈ | Q₁ | Q₁ | Q₇ | Q₁ | O | S | Q₇ | Q₁ | Q₁ |
| Lₐ₃₇₉₉ | Q₁ | Q₁ | Q₈ | Q₁ | O | S | Q₇ | Q₁ | Q₁ |
| Lₐ₃₈₀₀ | Q₁ | Q₁ | Q₉ | Q₁ | O | S | Q₇ | Q₁ | Q₁ |
| Lₐ₃₈₀₁ | Q₁ | Q₁ | Q₁₀ | Q₁ | O | S | Q₇ | Q₁ | Q₁ |
| Lₐ₃₈₀₂ | Q₁ | Q₁ | Q₁₁ | Q₁ | O | S | Q₇ | Q₁ | Q₁ |
| Lₐ₃₈₀₃ | Q₁ | Q₁ | Q₁₂ | Q₁ | O | S | Q₇ | Q₁ | Q₁ |
| Lₐ₃₈₀₄ | Q₁ | Q₁ | Q₁₃ | Q₁ | O | S | Q₇ | Q₁ | Q₁ |
| Lₐ₃₈₀₅ | Q₁ | Q₁ | Q₁₄ | Q₁ | O | S | Q₇ | Q₁ | Q₁ |
| Lₐ₃₈₀₆ | Q₁ | Q₁ | Q₁₅ | Q₁ | O | S | Q₇ | Q₁ | Q₁ |
| Lₐ₃₈₀₇ | Q₁ | Q₁ | Q₁₆ | Q₁ | O | S | Q₇ | Q₁ | Q₁ |
| Lₐ₃₈₀₈ | Q₁ | Q₁ | Q₁₇ | Q₁ | O | S | Q₇ | Q₁ | Q₁ |
| Lₐ₃₈₀₉ | Q₁ | Q₁ | Q₁₈ | Q₁ | O | S | Q₇ | Q₁ | Q₁ |
| Lₐ₃₈₁₀ | Q₁ | Q₁ | Q₁₉ | Q₁ | O | S | Q₇ | Q₁ | Q₁ |
| Lₐ₃₈₁₁ | Q₁ | Q₁ | Q₂₀ | Q₁ | O | S | Q₇ | Q₁ | Q₁ |
| Lₐ₃₈₁₂ | Q₁ | Q₁ | Q₂₁ | Q₁ | O | S | Q₇ | Q₁ | Q₁ |
| Lₐ₃₈₁₃ | Q₁ | Q₁ | Q₂₂ | Q₁ | O | S | Q₇ | Q₁ | Q₁ |
| Lₐ₃₈₁₄ | Q₁ | Q₁ | Q₂₃ | Q₁ | O | S | Q₇ | Q₁ | Q₁ |
| Lₐ₃₈₁₅ | Q₁ | Q₂ | Q₁ | Q₁ | O | S | Q₈ | Q₁ | Q₁ |
| Lₐ₃₈₁₆ | Q₁ | Q₃ | Q₁ | Q₁ | O | S | Q₈ | Q₁ | Q₁ |
| Lₐ₃₈₁₇ | Q₁ | Q₄ | Q₁ | Q₁ | O | S | Q₈ | Q₁ | Q₁ |
| Lₐ₃₈₁₈ | Q₁ | Q₅ | Q₁ | Q₁ | O | S | Q₈ | Q₁ | Q₁ |
| Lₐ₃₈₁₉ | Q₁ | Q₆ | Q₁ | Q₁ | O | S | Q₈ | Q₁ | Q₁ |
| Lₐ₃₈₂₀ | Q₁ | Q₇ | Q₁ | Q₁ | O | S | Q₈ | Q₁ | Q₁ |
| Lₐ₃₈₂₁ | Q₁ | Q₈ | Q₁ | Q₁ | O | S | Q₈ | Q₁ | Q₁ |
| Lₐ₃₈₂₂ | Q₁ | Q₉ | Q₁ | Q₁ | O | S | Q₈ | Q₁ | Q₁ |
| Lₐ₃₈₂₃ | Q₁ | Q₁₀ | Q₁ | Q₁ | O | S | Q₈ | Q₁ | Q₁ |
| Lₐ₃₈₂₄ | Q₁ | Q₁₁ | Q₁ | Q₁ | O | S | Q₈ | Q₁ | Q₁ |
| Lₐ₃₈₂₅ | Q₁ | Q₁₂ | Q₁ | Q₁ | O | S | Q₈ | Q₁ | Q₁ |
| Lₐ₃₈₂₆ | Q₁ | Q₁₃ | Q₁ | Q₁ | O | S | Q₈ | Q₁ | Q₁ |
| Lₐ₃₈₂₇ | Q₁ | Q₁₄ | Q₁ | Q₁ | O | S | Q₈ | Q₁ | Q₁ |
| Lₐ₃₈₂₈ | Q₁ | Q₁₅ | Q₁ | Q₁ | O | S | Q₈ | Q₁ | Q₁ |
| Lₐ₃₈₂₉ | Q₁ | Q₁₆ | Q₁ | Q₁ | O | S | Q₈ | Q₁ | Q₁ |
| Lₐ₃₈₃₀ | Q₁ | Q₁₇ | Q₁ | Q₁ | O | S | Q₈ | Q₁ | Q₁ |
| Lₐ₃₈₃₁ | Q₁ | Q₁₈ | Q₁ | Q₁ | O | S | Q₈ | Q₁ | Q₁ |
| Lₐ₃₈₃₂ | Q₁ | Q₁₉ | Q₁ | Q₁ | O | S | Q₈ | Q₁ | Q₁ |
| Lₐ₃₈₃₃ | Q₁ | Q₂₀ | Q₁ | Q₁ | O | S | Q₈ | Q₁ | Q₁ |
| Lₐ₃₈₃₄ | Q₁ | Q₂₁ | Q₁ | Q₁ | O | S | Q₈ | Q₁ | Q₁ |
| Lₐ₃₈₃₅ | Q₁ | Q₂₂ | Q₁ | Q₁ | O | S | Q₈ | Q₁ | Q₁ |
| Lₐ₃₈₃₆ | Q₁ | Q₂₃ | Q₁ | Q₁ | O | S | Q₈ | Q₁ | Q₁ |
| Lₐ₃₈₃₇ | Q₁ | Q₁ | Q₂ | Q₁ | O | S | Q₈ | Q₁ | Q₁ |
| Lₐ₃₈₃₈ | Q₁ | Q₁ | Q₃ | Q₁ | O | S | Q₈ | Q₁ | Q₁ |
| Lₐ₃₈₃₉ | Q₁ | Q₁ | Q₄ | Q₁ | O | S | Q₈ | Q₁ | Q₁ |
| Lₐ₃₈₄₀ | Q₁ | Q₁ | Q₅ | Q₁ | O | S | Q₈ | Q₁ | Q₁ |
| Lₐ₃₈₄₁ | Q₁ | Q₁ | Q₆ | Q₁ | O | S | Q₈ | Q₁ | Q₁ |
| Lₐ₃₈₄₂ | Q₁ | Q₁ | Q₇ | Q₁ | O | S | Q₈ | Q₁ | Q₁ |
| Lₐ₃₈₄₃ | Q₁ | Q₁ | Q₈ | Q₁ | O | S | Q₈ | Q₁ | Q₁ |
| Lₐ₃₈₄₄ | Q₁ | Q₁ | Q₉ | Q₁ | O | S | Q₈ | Q₁ | Q₁ |
| Lₐ₃₈₄₅ | Q₁ | Q₁ | Q₁₀ | Q₁ | O | S | Q₈ | Q₁ | Q₁ |
| Lₐ₃₈₄₆ | Q₁ | Q₁ | Q₁₁ | Q₁ | O | S | Q₈ | Q₁ | Q₁ |
| Lₐ₃₈₄₇ | Q₁ | Q₁ | Q₁₂ | Q₁ | O | S | Q₈ | Q₁ | Q₁ |
| Lₐ₃₈₄₈ | Q₁ | Q₁ | Q₁₃ | Q₁ | O | S | Q₈ | Q₁ | Q₁ |
| Lₐ₃₈₄₉ | Q₁ | Q₁ | Q₁₄ | Q₁ | O | S | Q₈ | Q₁ | Q₁ |
| Lₐ₃₈₅₀ | Q₁ | Q₁ | Q₁₅ | Q₁ | O | S | Q₈ | Q₁ | Q₁ |
| Lₐ₃₈₅₁ | Q₁ | Q₁ | Q₁₆ | Q₁ | O | S | Q₈ | Q₁ | Q₁ |
| Lₐ₃₈₅₂ | Q₁ | Q₁ | Q₁₇ | Q₁ | O | S | Q₈ | Q₁ | Q₁ |
| Lₐ₃₈₅₃ | Q₁ | Q₁ | Q₁₈ | Q₁ | O | S | Q₈ | Q₁ | Q₁ |
| Lₐ₃₈₅₄ | Q₁ | Q₁ | Q₁₉ | Q₁ | O | S | Q₈ | Q₁ | Q₁ |
| Lₐ₃₈₅₅ | Q₁ | Q₁ | Q₂₀ | Q₁ | O | S | Q₈ | Q₁ | Q₁ |
| Lₐ₃₈₅₆ | Q₁ | Q₁ | Q₂₁ | Q₁ | O | S | Q₈ | Q₁ | Q₁ |
| Lₐ₃₈₅₇ | Q₁ | Q₁ | Q₂₂ | Q₁ | O | S | Q₈ | Q₁ | Q₁ |
| Lₐ₃₈₅₈ | Q₁ | Q₁ | Q₂₃ | Q₁ | O | S | Q₈ | Q₁ | Q₁ |
| Lₐ₃₈₅₉ | Q₁ | Q₂ | Q₁ | Q₁ | O | S | Q₈ | Q₄ | Q₁ |
| Lₐ₃₈₆₀ | Q₁ | Q₃ | Q₁ | Q₁ | O | S | Q₈ | Q₄ | Q₁ |
| Lₐ₃₈₆₁ | Q₁ | Q₄ | Q₁ | Q₁ | O | S | Q₈ | Q₄ | Q₁ |
| Lₐ₃₈₆₂ | Q₁ | Q₅ | Q₁ | Q₁ | O | S | Q₈ | Q₄ | Q₁ |
| Lₐ₃₈₆₃ | Q₁ | Q₆ | Q₁ | Q₁ | O | S | Q₈ | Q₄ | Q₁ |
| Lₐ₃₈₆₄ | Q₁ | Q₇ | Q₁ | Q₁ | O | S | Q₈ | Q₄ | Q₁ |
| Lₐ₃₈₆₅ | Q₁ | Q₈ | Q₁ | Q₁ | O | S | Q₈ | Q₄ | Q₁ |
| Lₐ₃₈₆₆ | Q₁ | Q₉ | Q₁ | Q₁ | O | S | Q₈ | Q₄ | Q₁ |
| Lₐ₃₈₆₇ | Q₁ | Q₁₀ | Q₁ | Q₁ | O | S | Q₈ | Q₄ | Q₁ |
| Lₐ₃₈₆₈ | Q₁ | Q₁₁ | Q₁ | Q₁ | O | S | Q₈ | Q₄ | Q₁ |
| Lₐ₃₈₆₉ | Q₁ | Q₁₂ | Q₁ | Q₁ | O | S | Q₈ | Q₄ | Q₁ |
| Lₐ₃₈₇₀ | Q₁ | Q₁₃ | Q₁ | Q₁ | O | S | Q₈ | Q₄ | Q₁ |
| Lₐ₃₈₇₁ | Q₁ | Q₁₄ | Q₁ | Q₁ | O | S | Q₈ | Q₄ | Q₁ |
| Lₐ₃₈₇₂ | Q₁ | Q₁₅ | Q₁ | Q₁ | O | S | Q₈ | Q₄ | Q₁ |
| Lₐ₃₈₇₃ | Q₁ | Q₁₆ | Q₁ | Q₁ | O | S | Q₈ | Q₄ | Q₁ |
| Lₐ₃₈₇₄ | Q₁ | Q₁₇ | Q₁ | Q₁ | O | S | Q₈ | Q₄ | Q₁ |
| Lₐ₃₈₇₅ | Q₁ | Q₁₈ | Q₁ | Q₁ | O | S | Q₈ | Q₄ | Q₁ |
| Lₐ₃₈₇₆ | Q₁ | Q₁₉ | Q₁ | Q₁ | O | S | Q₈ | Q₄ | Q₁ |
| Lₐ₃₈₇₇ | Q₁ | Q₂₀ | Q₁ | Q₁ | O | S | Q₈ | Q₄ | Q₁ |
| Lₐ₃₈₇₈ | Q₁ | Q₂₁ | Q₁ | Q₁ | O | S | Q₈ | Q₄ | Q₁ |
| Lₐ₃₈₇₉ | Q₁ | Q₂₂ | Q₁ | Q₁ | O | S | Q₈ | Q₄ | Q₁ |
| Lₐ₃₈₈₀ | Q₁ | Q₂₃ | Q₁ | Q₁ | O | S | Q₈ | Q₄ | Q₁ |
| Lₐ₃₈₈₁ | Q₁ | Q₁ | Q₂ | Q₁ | O | S | Q₈ | Q₄ | Q₁ |
| Lₐ₃₈₈₂ | Q₁ | Q₁ | Q₃ | Q₁ | O | S | Q₈ | Q₄ | Q₁ |
| Lₐ₃₈₈₃ | Q₁ | Q₁ | Q₄ | Q₁ | O | S | Q₈ | Q₄ | Q₁ |
| Lₐ₃₈₈₄ | Q₁ | Q₁ | Q₅ | Q₁ | O | S | Q₈ | Q₄ | Q₁ |
| Lₐ₃₈₈₅ | Q₁ | Q₁ | Q₆ | Q₁ | O | S | Q₈ | Q₄ | Q₁ |
| Lₐ₃₈₈₆ | Q₁ | Q₁ | Q₇ | Q₁ | O | S | Q₈ | Q₄ | Q₁ |
| Lₐ₃₈₈₇ | Q₁ | Q₁ | Q₈ | Q₁ | O | S | Q₈ | Q₄ | Q₁ |
| Lₐ₃₈₈₈ | Q₁ | Q₁ | Q₉ | Q₁ | O | S | Q₈ | Q₄ | Q₁ |
| Lₐ₃₈₈₉ | Q₁ | Q₁ | Q₁₀ | Q₁ | O | S | Q₈ | Q₄ | Q₁ |
| Lₐ₃₈₉₀ | Q₁ | Q₁ | Q₁₁ | Q₁ | O | S | Q₈ | Q₄ | Q₁ |
| Lₐ₃₈₉₁ | Q₁ | Q₁ | Q₁₂ | Q₁ | O | S | Q₈ | Q₄ | Q₁ |
| Lₐ₃₈₉₂ | Q₁ | Q₁ | Q₁₃ | Q₁ | O | S | Q₈ | Q₄ | Q₁ |
| Lₐ₃₈₉₃ | Q₁ | Q₁ | Q₁₄ | Q₁ | O | S | Q₈ | Q₄ | Q₁ |
| Lₐ₃₈₉₄ | Q₁ | Q₁ | Q₁₅ | Q₁ | O | S | Q₈ | Q₄ | Q₁ |
| Lₐ₃₈₉₅ | Q₁ | Q₁ | Q₁₆ | Q₁ | O | S | Q₈ | Q₄ | Q₁ |
| Lₐ₃₈₉₆ | Q₁ | Q₁ | Q₁₇ | Q₁ | O | S | Q₈ | Q₄ | Q₁ |
| Lₐ₃₈₉₇ | Q₁ | Q₁ | Q₁₈ | Q₁ | O | S | Q₈ | Q₄ | Q₁ |
| Lₐ₃₈₉₈ | Q₁ | Q₁ | Q₁₉ | Q₁ | O | S | Q₈ | Q₄ | Q₁ |
| Lₐ₃₈₉₉ | Q₁ | Q₁ | Q₂₀ | Q₁ | O | S | Q₈ | Q₄ | Q₁ |
| Lₐ₃₉₀₀ | Q₁ | Q₁ | Q₂₁ | Q₁ | O | S | Q₈ | Q₄ | Q₁ |
| Lₐ₃₉₀₁ | Q₁ | Q₁ | Q₂₂ | Q₁ | O | S | Q₈ | Q₄ | Q₁ |
| Lₐ₃₉₀₂ | Q₁ | Q₁ | Q₂₃ | Q₁ | O | S | Q₈ | Q₄ | Q₁ |
| Lₐ₃₉₀₃ | Q₁ | Q₂ | Q₁ | Q₁ | O | S | Q₈ | Q₁ | Q₄ |
| Lₐ₃₉₀₄ | Q₁ | Q₃ | Q₁ | Q₁ | O | S | Q₈ | Q₁ | Q₄ |
| Lₐ₃₉₀₅ | Q₁ | Q₄ | Q₁ | Q₁ | O | S | Q₈ | Q₁ | Q₄ |
| Lₐ₃₉₀₆ | Q₁ | Q₅ | Q₁ | Q₁ | O | S | Q₈ | Q₁ | Q₄ |
| Lₐ₃₉₀₇ | Q₁ | Q₆ | Q₁ | Q₁ | O | S | Q₈ | Q₁ | Q₄ |
| Lₐ₃₉₀₈ | Q₁ | Q₇ | Q₁ | Q₁ | O | S | Q₈ | Q₁ | Q₄ |
| Lₐ₃₉₀₉ | Q₁ | Q₈ | Q₁ | Q₁ | O | S | Q₈ | Q₁ | Q₄ |
| Lₐ₃₉₁₀ | Q₁ | Q₉ | Q₁ | Q₁ | O | S | Q₈ | Q₁ | Q₄ |
| Lₐ₃₉₁₁ | Q₁ | Q₁₀ | Q₁ | Q₁ | O | S | Q₈ | Q₁ | Q₄ |
| Lₐ₃₉₁₂ | Q₁ | Q₁₁ | Q₁ | Q₁ | O | S | Q₈ | Q₁ | Q₄ |
| Lₐ₃₉₁₃ | Q₁ | Q₁₂ | Q₁ | Q₁ | O | S | Q₈ | Q₁ | Q₄ |
| Lₐ₃₉₁₄ | Q₁ | Q₁₃ | Q₁ | Q₁ | O | S | Q₈ | Q₁ | Q₄ |
| Lₐ₃₉₁₅ | Q₁ | Q₁₄ | Q₁ | Q₁ | O | S | Q₈ | Q₁ | Q₄ |
| Lₐ₃₉₁₆ | Q₁ | Q₁₅ | Q₁ | Q₁ | O | S | Q₈ | Q₁ | Q₄ |
| Lₐ₃₉₁₇ | Q₁ | Q₁₆ | Q₁ | Q₁ | O | S | Q₈ | Q₁ | Q₄ |
| Lₐ₃₉₁₈ | Q₁ | Q₁₇ | Q₁ | Q₁ | O | S | Q₈ | Q₁ | Q₄ |
| Lₐ₃₉₁₉ | Q₁ | Q₁₈ | Q₁ | Q₁ | O | S | Q₈ | Q₁ | Q₄ |
| Lₐ₃₉₂₀ | Q₁ | Q₁₉ | Q₁ | Q₁ | O | S | Q₈ | Q₁ | Q₄ |
| Lₐ₃₉₂₁ | Q₁ | Q₂₀ | Q₁ | Q₁ | O | S | Q₈ | Q₁ | Q₄ |
| Lₐ₃₉₂₂ | Q₁ | Q₂₁ | Q₁ | Q₁ | O | S | Q₈ | Q₁ | Q₄ |
| Lₐ₃₉₂₃ | Q₁ | Q₂₂ | Q₁ | Q₁ | O | S | Q₈ | Q₁ | Q₄ |
| Lₐ₃₉₂₄ | Q₁ | Q₂₃ | Q₁ | Q₁ | O | S | Q₈ | Q₁ | Q₄ |
| Lₐ₃₉₂₅ | Q₁ | Q₁ | Q₂ | Q₁ | O | S | Q₈ | Q₁ | Q₄ |
| Lₐ₃₉₂₆ | Q₁ | Q₁ | Q₃ | Q₁ | O | S | Q₈ | Q₁ | Q₄ |
| Lₐ₃₉₂₇ | Q₁ | Q₁ | Q₄ | Q₁ | O | S | Q₈ | Q₁ | Q₄ |
| Lₐ₃₉₂₈ | Q₁ | Q₁ | Q₅ | Q₁ | O | S | Q₈ | Q₁ | Q₄ |
| Lₐ₃₉₂₉ | Q₁ | Q₁ | Q₆ | Q₁ | O | S | Q₈ | Q₁ | Q₄ |
| Lₐ₃₉₃₀ | Q₁ | Q₁ | Q₇ | Q₁ | O | S | Q₈ | Q₁ | Q₄ |
| Lₐ₃₉₃₁ | Q₁ | Q₁ | Q₈ | Q₁ | O | S | Q₈ | Q₁ | Q₄ |
| Lₐ₃₉₃₂ | Q₁ | Q₁ | Q₉ | Q₁ | O | S | Q₈ | Q₁ | Q₄ |
| Lₐ₃₉₃₃ | Q₁ | Q₁ | Q₁₀ | Q₁ | O | S | Q₈ | Q₁ | Q₄ |
| Lₐ₃₉₃₄ | Q₁ | Q₁ | Q₁₁ | Q₁ | O | S | Q₈ | Q₁ | Q₄ |
| Lₐ₃₉₃₅ | Q₁ | Q₁ | Q₁₂ | Q₁ | O | S | Q₈ | Q₁ | Q₄ |
| Lₐ₃₉₃₆ | Q₁ | Q₁ | Q₁₃ | Q₁ | O | S | Q₈ | Q₁ | Q₄ |
| Lₐ₃₉₃₇ | Q₁ | Q₁ | Q₁₄ | Q₁ | O | S | Q₈ | Q₁ | Q₄ |
| Lₐ₃₉₃₈ | Q₁ | Q₁ | Q₁₅ | Q₁ | O | S | Q₈ | Q₁ | Q₄ |
| Lₐ₃₉₃₉ | Q₁ | Q₁ | Q₁₆ | Q₁ | O | S | Q₈ | Q₁ | Q₄ |
| Lₐ₃₉₄₀ | Q₁ | Q₁ | Q₁₇ | Q₁ | O | S | Q₈ | Q₁ | Q₄ |
| Lₐ₃₉₄₁ | Q₁ | Q₁ | Q₁₈ | Q₁ | O | S | Q₈ | Q₁ | Q₄ |
| Lₐ₃₉₄₂ | Q₁ | Q₁ | Q₁₉ | Q₁ | O | S | Q₈ | Q₁ | Q₄ |
| Lₐ₃₉₄₃ | Q₁ | Q₁ | Q₂₀ | Q₁ | O | S | Q₈ | Q₁ | Q₄ |
| Lₐ₃₉₄₄ | Q₁ | Q₁ | Q₂₁ | Q₁ | O | S | Q₈ | Q₁ | Q₄ |
| Lₐ₃₉₄₅ | Q₁ | Q₁ | Q₂₂ | Q₁ | O | S | Q₈ | Q₁ | Q₄ |
| Lₐ₃₉₄₆ | Q₁ | Q₁ | Q₂₃ | Q₁ | O | S | Q₈ | Q₁ | Q₄ |
| Lₐ₃₉₄₇ | Q₁ | Q₂ | Q₁ | Q₁ | O | S | Q₈ | Q₁ | Q₁ |
| Lₐ₃₉₄₈ | Q₁ | Q₃ | Q₁ | Q₁ | O | S | Q₈ | Q₁ | Q₁ |
| Lₐ₃₉₄₉ | Q₁ | Q₄ | Q₁ | Q₁ | O | S | Q₈ | Q₁ | Q₁ |
| Lₐ₃₉₅₀ | Q₁ | Q₅ | Q₁ | Q₁ | O | S | Q₈ | Q₁ | Q₁ |
| Lₐ₃₉₅₁ | Q₁ | Q₆ | Q₁ | Q₁ | O | S | Q₈ | Q₁ | Q₁ |
| Lₐ₃₉₅₂ | Q₁ | Q₇ | Q₁ | Q₁ | O | S | Q₈ | Q₁ | Q₁ |
| Lₐ₃₉₅₃ | Q₁ | Q₈ | Q₁ | Q₁ | O | S | Q₈ | Q₁ | Q₁ |
| Lₐ₃₉₅₄ | Q₁ | Q₉ | Q₁ | Q₁ | O | S | Q₈ | Q₁ | Q₁ |
| Lₐ₃₉₅₅ | Q₁ | Q₁₀ | Q₁ | Q₁ | O | S | Q₈ | Q₁ | Q₁ |
| Lₐ₃₉₅₆ | Q₁ | Q₁₁ | Q₁ | Q₁ | O | S | Q₈ | Q₁ | Q₁ |
| Lₐ₃₉₅₇ | Q₁ | Q₁₂ | Q₁ | Q₁ | O | S | Q₈ | Q₁ | Q₁ |
| Lₐ₃₉₅₈ | Q₁ | Q₁₃ | Q₁ | Q₁ | O | S | Q₈ | Q₁ | Q₁ |
| Lₐ₃₉₅₉ | Q₁ | Q₁₄ | Q₁ | Q₁ | O | S | Q₈ | Q₁ | Q₁ |
| Lₐ₃₉₆₀ | Q₁ | Q₁₅ | Q₁ | Q₁ | O | S | Q₈ | Q₁ | Q₁ |
| Lₐ₃₉₆₁ | Q₁ | Q₁₆ | Q₁ | Q₁ | O | S | Q₈ | Q₁ | Q₁ |
| Lₐ₃₉₆₂ | Q₁ | Q₁₇ | Q₁ | Q₁ | O | S | Q₈ | Q₁ | Q₁ |
| Lₐ₃₉₆₃ | Q₁ | Q₁₈ | Q₁ | Q₁ | O | S | Q₈ | Q₁ | Q₁ |
| Lₐ₃₉₆₄ | Q₁ | Q₁₉ | Q₁ | Q₁ | O | S | Q₈ | Q₁ | Q₁ |
| Lₐ₃₉₆₅ | Q₁ | Q₂₀ | Q₁ | Q₁ | O | S | Q₈ | Q₁ | Q₁ |
| Lₐ₃₉₆₆ | Q₁ | Q₂₁ | Q₁ | Q₁ | O | S | Q₈ | Q₁ | Q₁ |
| Lₐ₃₉₆₇ | Q₁ | Q₂₂ | Q₁ | Q₁ | O | S | Q₈ | Q₁ | Q₁ |
| Lₐ₃₉₆₈ | Q₁ | Q₂₃ | Q₁ | Q₁ | O | S | Q₈ | Q₁ | Q₁ |
| Lₐ₃₉₆₉ | Q₁ | Q₁ | Q₂ | Q₁ | O | S | Q₈ | Q₁ | Q₁ |
| Lₐ₃₉₇₀ | Q₁ | Q₁ | Q₃ | Q₁ | O | S | Q₈ | Q₁ | Q₁ |
| Lₐ₃₉₇₁ | Q₁ | Q₁ | Q₄ | Q₁ | O | S | Q₈ | Q₁ | Q₁ |
| Lₐ₃₉₇₂ | Q₁ | Q₁ | Q₅ | Q₁ | O | S | Q₈ | Q₁ | Q₁ |
| Lₐ₃₉₇₃ | Q₁ | Q₁ | Q₆ | Q₁ | O | S | Q₈ | Q₁ | Q₁ |
| Lₐ₃₉₇₄ | Q₁ | Q₁ | Q₇ | Q₁ | O | S | Q₈ | Q₁ | Q₁ |
| Lₐ₃₉₇₅ | Q₁ | Q₁ | Q₈ | Q₁ | O | S | Q₈ | Q₁ | Q₁ |
| Lₐ₃₉₇₆ | Q₁ | Q₁ | Q₉ | Q₁ | O | S | Q₈ | Q₁ | Q₁ |
| Lₐ₃₉₇₇ | Q₁ | Q₁ | Q₁₀ | Q₁ | O | S | Q₈ | Q₁ | Q₁ |
| Lₐ₃₉₇₈ | Q₁ | Q₁ | Q₁₁ | Q₁ | O | S | Q₈ | Q₁ | Q₁ |
| Lₐ₃₉₇₉ | Q₁ | Q₁ | Q₁₂ | Q₁ | O | S | Q₈ | Q₁ | Q₁ |
| Lₐ₃₉₈₀ | Q₁ | Q₁ | Q₁₃ | Q₁ | O | S | Q₈ | Q₁ | Q₁ |
| Lₐ₃₉₈₁ | Q₁ | Q₁ | Q₁₄ | Q₁ | O | S | Q₈ | Q₁ | Q₁ |
| Lₐ₃₉₈₂ | Q₁ | Q₁ | Q₁₅ | Q₁ | O | S | Q₈ | Q₁ | Q₁ |
| Lₐ₃₉₈₃ | Q₁ | Q₁ | Q₁₆ | Q₁ | O | S | Q₈ | Q₁ | Q₁ |
| Lₐ₃₉₈₄ | Q₁ | Q₁ | Q₁₇ | Q₁ | O | S | Q₈ | Q₁ | Q₁ |
| Lₐ₃₉₈₅ | Q₁ | Q₁ | Q₁₈ | Q₁ | O | S | Q₈ | Q₁ | Q₁ |
| Lₐ₃₉₈₆ | Q₁ | Q₁ | Q₁₉ | Q₁ | O | S | Q₈ | Q₁ | Q₁ |
| Lₐ₃₉₈₇ | Q₁ | Q₁ | Q₂₀ | Q₁ | O | S | Q₈ | Q₁ | Q₁ |
| Lₐ₃₉₈₈ | Q₁ | Q₁ | Q₂₁ | Q₁ | O | S | Q₈ | Q₁ | Q₁ |
| Lₐ₃₉₈₉ | Q₁ | Q₁ | Q₂₂ | Q₁ | O | S | Q₈ | Q₁ | Q₁ |
| Lₐ₃₉₉₀ | Q₁ | Q₁ | Q₂₃ | Q₁ | O | S | Q₈ | Q₁ | Q₁ |
| Lₐ₃₉₉₁ | Q₁ | Q₂ | Q₁ | Q₁ | O | S | Q₄ | Q₁ | Q₄ |
| Lₐ₃₉₉₂ | Q₁ | Q₃ | Q₁ | Q₁ | O | S | Q₄ | Q₁ | Q₄ |
| Lₐ₃₉₉₃ | Q₁ | Q₄ | Q₁ | Q₁ | O | S | Q₄ | Q₁ | Q₄ |
| Lₐ₃₉₉₄ | Q₁ | Q₅ | Q₁ | Q₁ | O | S | Q₄ | Q₁ | Q₄ |
| Lₐ₃₉₉₅ | Q₁ | Q₆ | Q₁ | Q₁ | O | S | Q₄ | Q₁ | Q₄ |
| Lₐ₃₉₉₆ | Q₁ | Q₇ | Q₁ | Q₁ | O | S | Q₄ | Q₁ | Q₄ |
| Lₐ₃₉₉₇ | Q₁ | Q₈ | Q₁ | Q₁ | O | S | Q₄ | Q₁ | Q₄ |
| Lₐ₃₉₉₈ | Q₁ | Q₉ | Q₁ | Q₁ | O | S | Q₄ | Q₁ | Q₄ |
| Lₐ₃₉₉₉ | Q₁ | Q₁₀ | Q₁ | Q₁ | O | S | Q₄ | Q₁ | Q₄ |
| Lₐ₄₀₀₀ | Q₁ | Q₁₁ | Q₁ | Q₁ | O | S | Q₄ | Q₁ | Q₄ |
| Lₐ₄₀₀₁ | Q₁ | Q₁₂ | Q₁ | Q₁ | O | S | Q₄ | Q₁ | Q₄ |
| Lₐ₄₀₀₂ | Q₁ | Q₁₃ | Q₁ | Q₁ | O | S | Q₄ | Q₁ | Q₄ |
| Lₐ₄₀₀₃ | Q₁ | Q₁₄ | Q₁ | Q₁ | O | S | Q₄ | Q₁ | Q₄ |
| Lₐ₄₀₀₄ | Q₁ | Q₁₅ | Q₁ | Q₁ | O | S | Q₄ | Q₁ | Q₄ |
| Lₐ₄₀₀₅ | Q₁ | Q₁₆ | Q₁ | Q₁ | O | S | Q₄ | Q₁ | Q₄ |
| Lₐ₄₀₀₆ | Q₁ | Q₁₇ | Q₁ | Q₁ | O | S | Q₄ | Q₁ | Q₄ |
| Lₐ₄₀₀₇ | Q₁ | Q₁₈ | Q₁ | Q₁ | O | S | Q₄ | Q₁ | Q₄ |
| Lₐ₄₀₀₈ | Q₁ | Q₁₉ | Q₁ | Q₁ | O | S | Q₄ | Q₁ | Q₄ |
| Lₐ₄₀₀₉ | Q₁ | Q₂₀ | Q₁ | Q₁ | O | S | Q₄ | Q₁ | Q₄ |
| Lₐ₄₀₁₀ | Q₁ | Q₂₁ | Q₁ | Q₁ | O | S | Q₄ | Q₁ | Q₄ |
| Lₐ₄₀₁₁ | Q₁ | Q₂₂ | Q₁ | Q₁ | O | S | Q₄ | Q₁ | Q₄ |
| Lₐ₄₀₁₂ | Q₁ | Q₂₃ | Q₁ | Q₁ | O | S | Q₄ | Q₁ | Q₄ |
| Lₐ₄₀₁₃ | Q₁ | Q₁ | Q₂ | Q₁ | O | S | Q₄ | Q₁ | Q₄ |
| Lₐ₄₀₁₄ | Q₁ | Q₁ | Q₃ | Q₁ | O | S | Q₄ | Q₁ | Q₄ |
| Lₐ₄₀₁₅ | Q₁ | Q₁ | Q₄ | Q₁ | O | S | Q₄ | Q₁ | Q₄ |
| Lₐ₄₀₁₆ | Q₁ | Q₁ | Q₅ | Q₁ | O | S | Q₄ | Q₁ | Q₄ |
| Lₐ₄₀₁₇ | Q₁ | Q₁ | Q₆ | Q₁ | O | S | Q₄ | Q₁ | Q₄ |
| Lₐ₄₀₁₈ | Q₁ | Q₁ | Q₇ | Q₁ | O | S | Q₄ | Q₁ | Q₄ |
| Lₐ₄₀₁₉ | Q₁ | Q₁ | Q₈ | Q₁ | O | S | Q₄ | Q₁ | Q₄ |
| Lₐ₄₀₂₀ | Q₁ | Q₁ | Q₉ | Q₁ | O | S | Q₄ | Q₁ | Q₄ |
| Lₐ₄₀₂₁ | Q₁ | Q₁ | Q₁₀ | Q₁ | O | S | Q₄ | Q₁ | Q₄ |
| Lₐ₄₀₂₂ | Q₁ | Q₁ | Q₁₁ | Q₁ | O | S | Q₄ | Q₁ | Q₄ |
| Lₐ₄₀₂₃ | Q₁ | Q₁ | Q₁₂ | Q₁ | O | S | Q₄ | Q₁ | Q₄ |
| Lₐ₄₀₂₄ | Q₁ | Q₁ | Q₁₃ | Q₁ | O | S | Q₄ | Q₁ | Q₄ |
| Lₐ₄₀₂₅ | Q₁ | Q₁ | Q₁₄ | Q₁ | O | S | Q₄ | Q₁ | Q₄ |
| Lₐ₄₀₂₆ | Q₁ | Q₁ | Q₁₅ | Q₁ | O | S | Q₄ | Q₁ | Q₄ |
| Lₐ₄₀₂₇ | Q₁ | Q₁ | Q₁₆ | Q₁ | O | S | Q₄ | Q₁ | Q₄ |
| Lₐ₄₀₂₈ | Q₁ | Q₁ | Q₁₇ | Q₁ | O | S | Q₄ | Q₁ | Q₄ |
| Lₐ₄₀₂₉ | Q₁ | Q₁ | Q₁₈ | Q₁ | O | S | Q₄ | Q₁ | Q₄ |
| Lₐ₄₀₃₀ | Q₁ | Q₁ | Q₁₉ | Q₁ | O | S | Q₄ | Q₁ | Q₄ |
| Lₐ₄₀₃₁ | Q₁ | Q₁ | Q₂₀ | Q₁ | O | S | Q₄ | Q₁ | Q₄ |
| Lₐ₄₀₃₂ | Q₁ | Q₁ | Q₂₁ | Q₁ | O | S | Q₄ | Q₁ | Q₄ |
| Lₐ₄₀₃₃ | Q₁ | Q₁ | Q₂₂ | Q₁ | O | S | Q₄ | Q₁ | Q₄ |
| Lₐ₄₀₃₄ | Q₁ | Q₁ | Q₂₃ | Q₁ | O | S | Q₄ | Q₁ | Q₄ |
| Lₐ₄₀₃₅ | Q₁ | Q₁ | Q₁ | Q₂ | O | S | Q₄ | Q₁ | Q₄ |
| Lₐ₄₀₃₆ | Q₁ | Q₁ | Q₁ | Q₃ | O | S | Q₄ | Q₁ | Q₄ |
| Lₐ₄₀₃₇ | Q₁ | Q₁ | Q₁ | Q₄ | O | S | Q₄ | Q₁ | Q₄ |
| Lₐ₄₀₃₈ | Q₁ | Q₁ | Q₁ | Q₅ | O | S | Q₄ | Q₁ | Q₄ |
| Lₐ₄₀₃₉ | Q₁ | Q₁ | Q₁ | Q₆ | O | S | Q₄ | Q₁ | Q₄ |
| Lₐ₄₀₄₀ | Q₁ | Q₁ | Q₁ | Q₇ | O | S | Q₄ | Q₁ | Q₄ |
| Lₐ₄₀₄₁ | Q₁ | Q₁ | Q₁ | Q₈ | O | S | Q₄ | Q₁ | Q₄ |
| Lₐ₄₀₄₂ | Q₁ | Q₁ | Q₁ | Q₉ | O | S | Q₄ | Q₁ | Q₄ |
| Lₐ₄₀₄₃ | Q₁ | Q₁ | Q₁ | Q₁₀ | O | S | Q₄ | Q₁ | Q₄ |
| Lₐ₄₀₄₄ | Q₁ | Q₁ | Q₁ | Q₁₁ | O | S | Q₄ | Q₁ | Q₄ |
| Lₐ₄₀₄₅ | Q₁ | Q₁ | Q₁ | Q₁₂ | O | S | Q₄ | Q₁ | Q₄ |
| Lₐ₄₀₄₆ | Q₁ | Q₁ | Q₁ | Q₁₃ | O | S | Q₄ | Q₁ | Q₄ |
| Lₐ₄₀₄₇ | Q₁ | Q₁ | Q₁ | Q₁₄ | O | S | Q₄ | Q₁ | Q₄ |
| Lₐ₄₀₄₈ | Q₁ | Q₁ | Q₁ | Q₁₅ | O | S | Q₄ | Q₁ | Q₄ |
| Lₐ₄₀₄₉ | Q₁ | Q₁ | Q₁ | Q₁₆ | O | S | Q₄ | Q₁ | Q₄ |
| Lₐ₄₀₅₀ | Q₁ | Q₁ | Q₁ | Q₁₇ | O | S | Q₄ | Q₁ | Q₄ |
| Lₐ₄₀₅₁ | Q₁ | Q₁ | Q₁ | Q₁₈ | O | S | Q₄ | Q₁ | Q₄ |
| Lₐ₄₀₅₂ | Q₁ | Q₁ | Q₁ | Q₁₉ | O | S | Q₄ | Q₁ | Q₄ |
| Lₐ₄₀₅₃ | Q₁ | Q₁ | Q₁ | Q₂₀ | O | S | Q₄ | Q₁ | Q₄ |
| Lₐ₄₀₅₄ | Q₁ | Q₁ | Q₁ | Q₂₁ | O | S | Q₄ | Q₁ | Q₄ |
| Lₐ₄₀₅₅ | Q₁ | Q₁ | Q₁ | Q₂₂ | O | S | Q₄ | Q₁ | Q₄ |
| Lₐ₄₀₅₆ | Q₁ | Q₁ | Q₁ | Q₂₃ | O | S | Q₄ | Q₁ | Q₄ |

wherein specific structures of Lₐ₄₀₅₇ to Lₐ₄₄₈₉ are as follows: 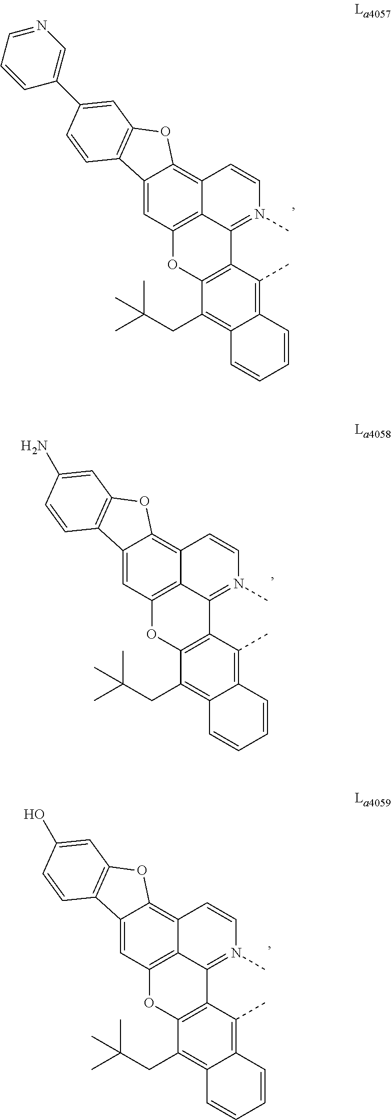 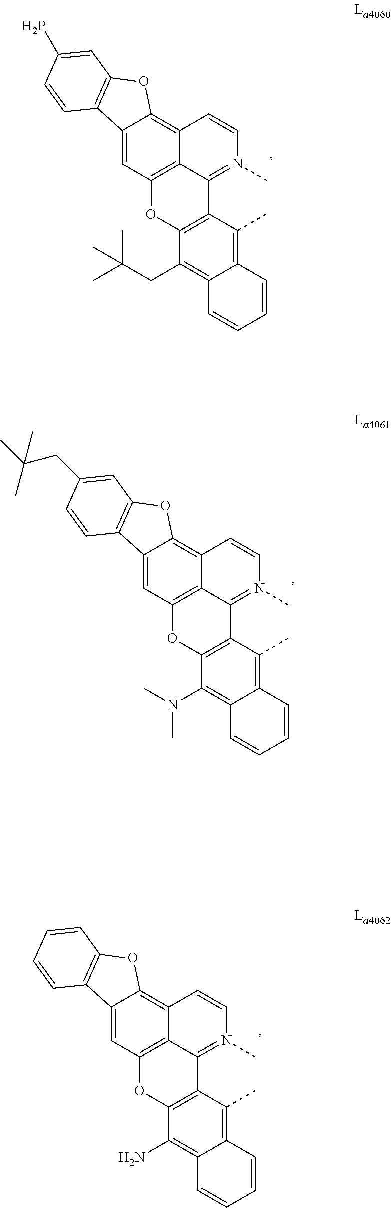 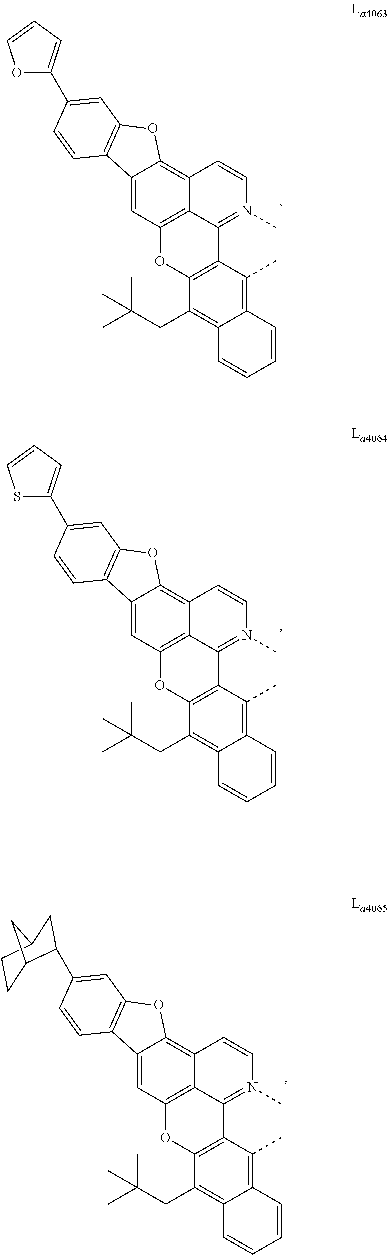 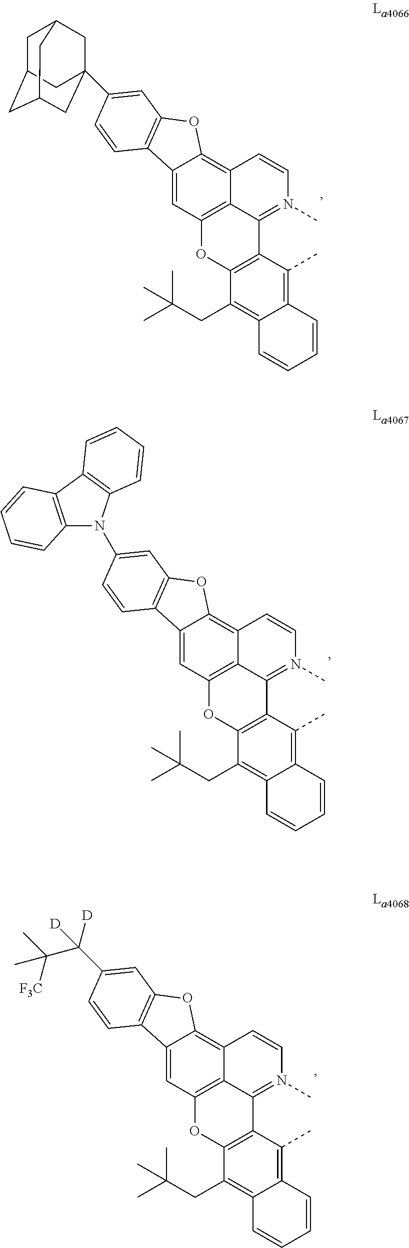 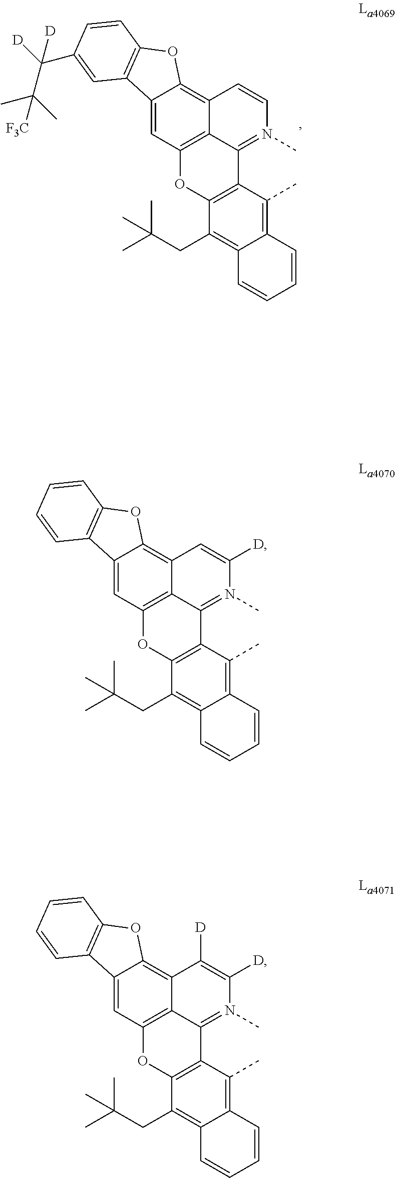 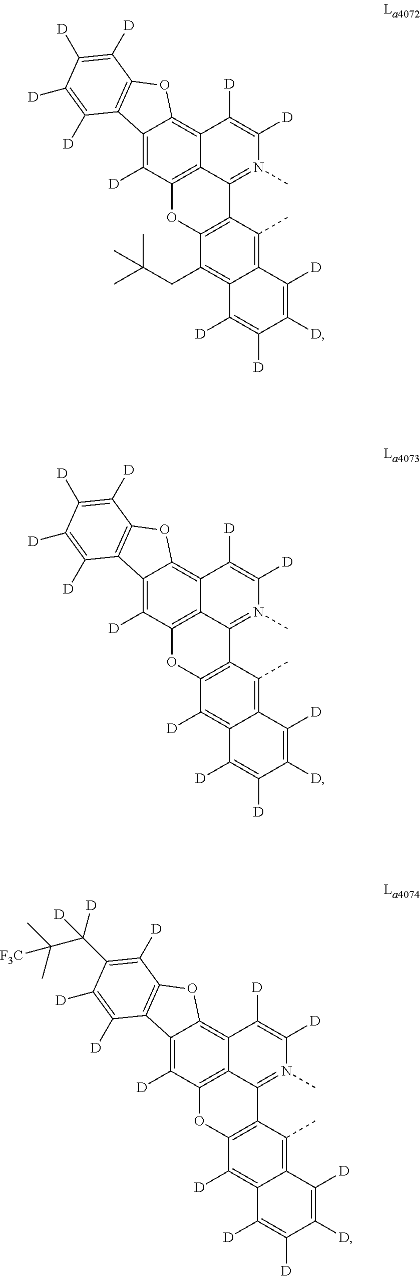 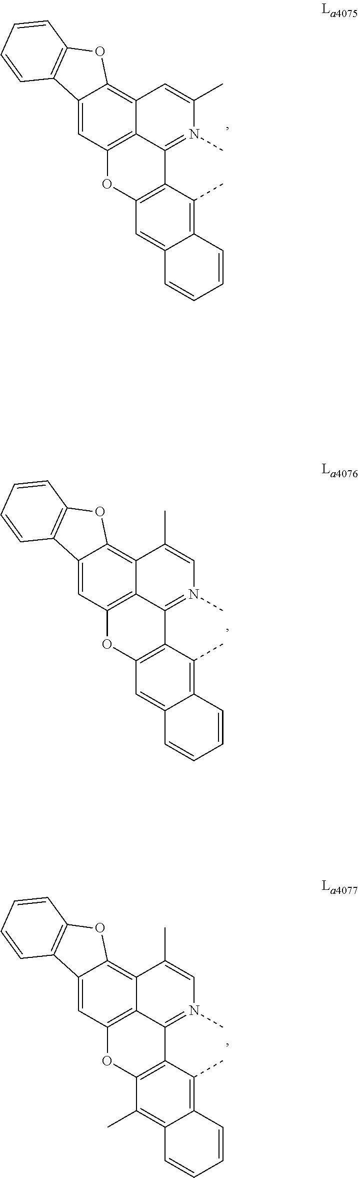 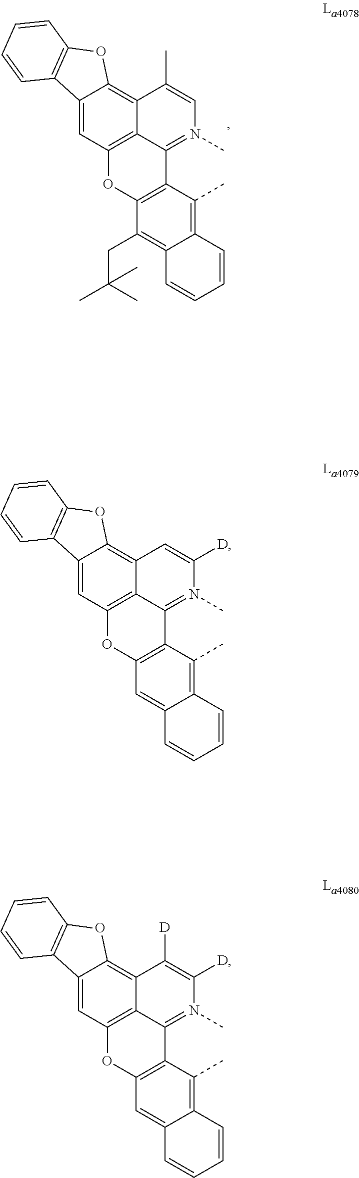 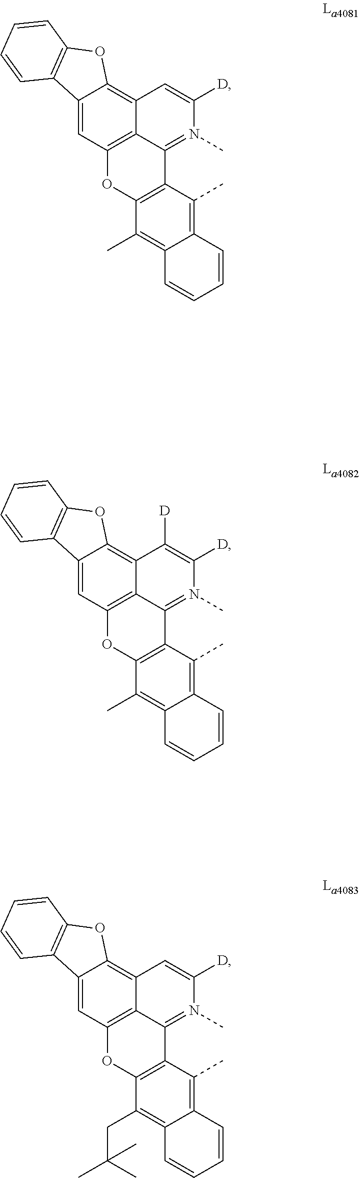 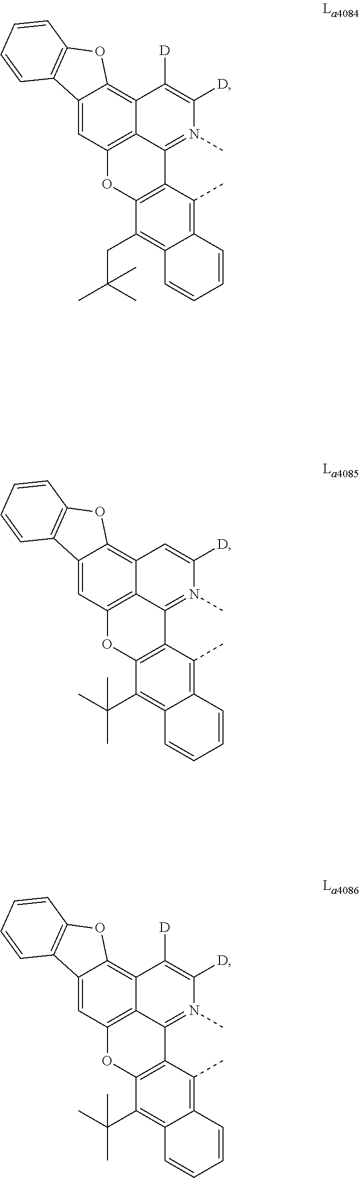 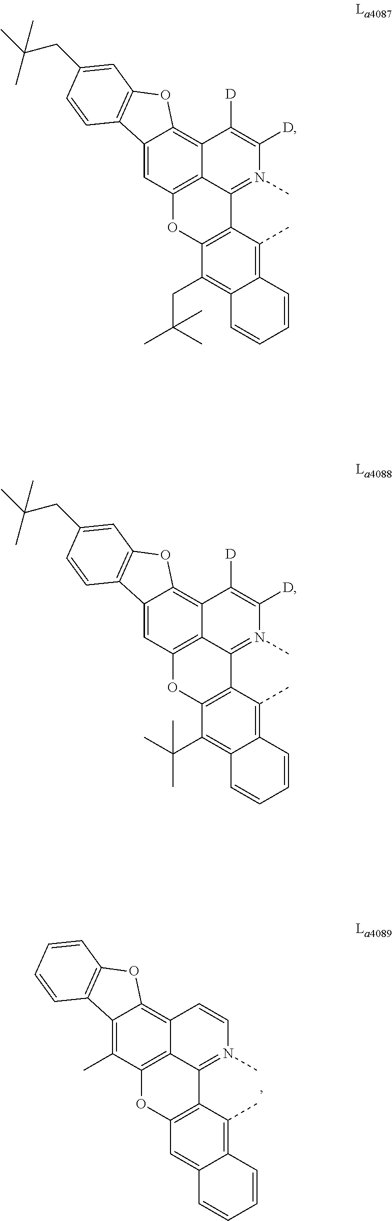 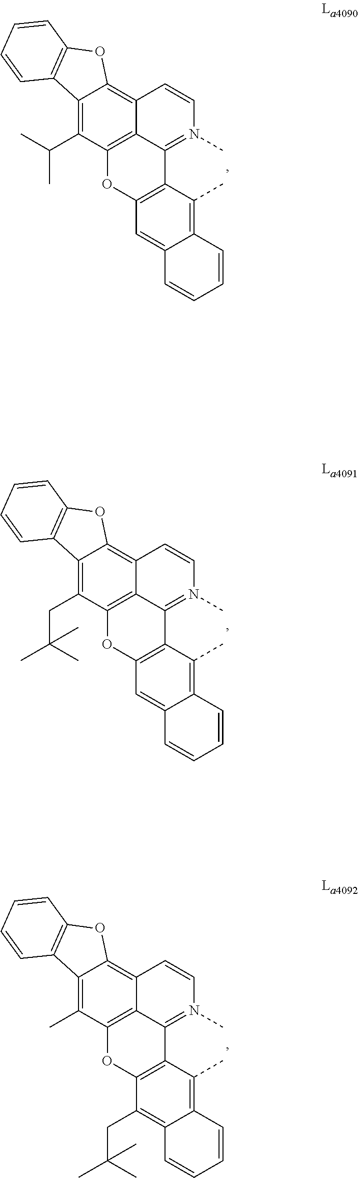 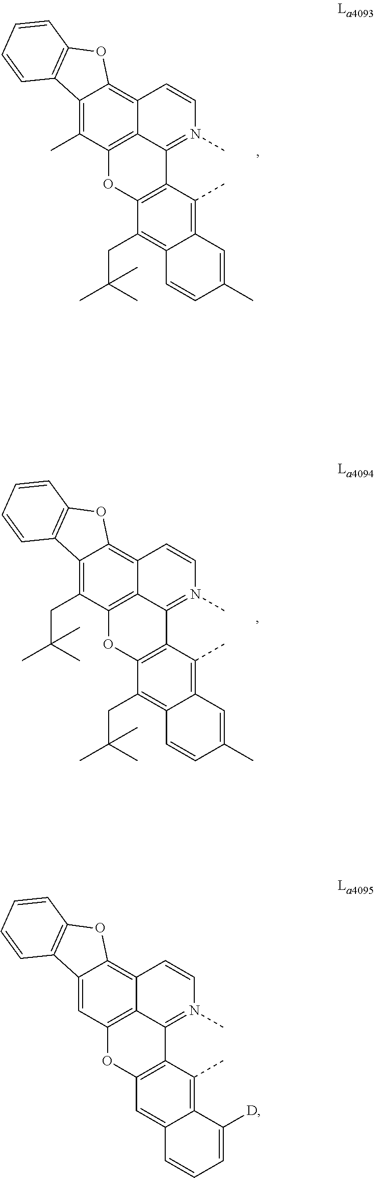 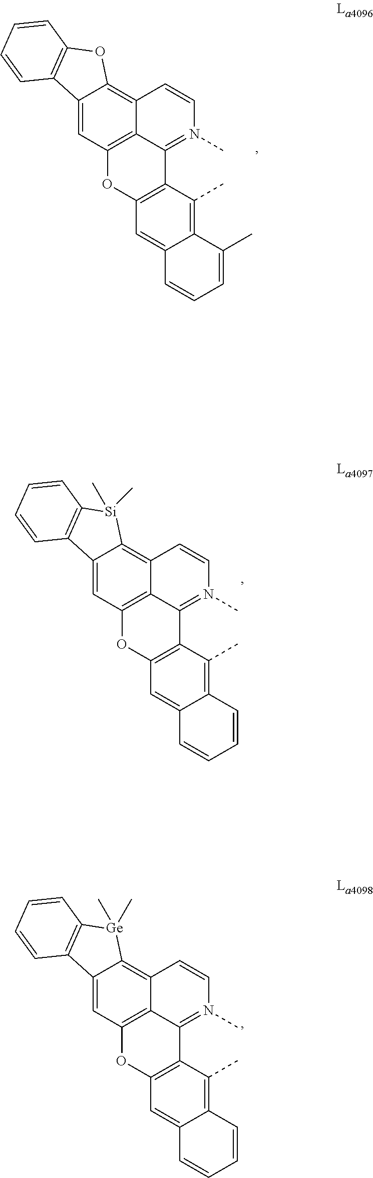 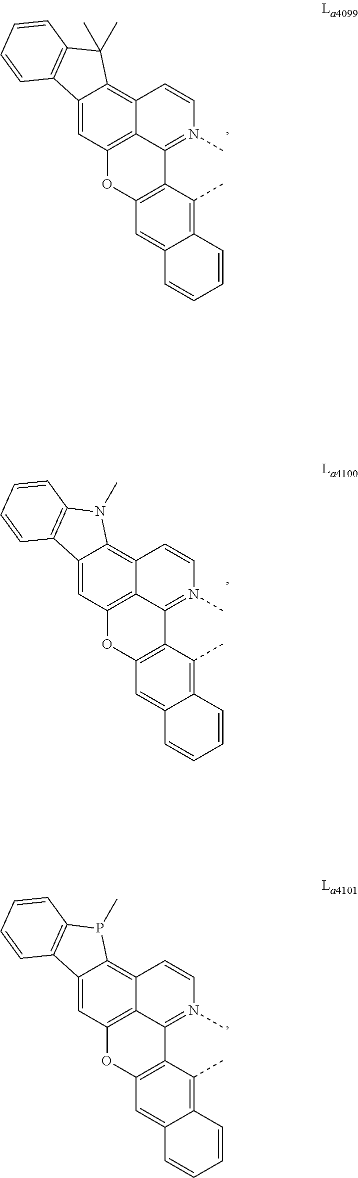 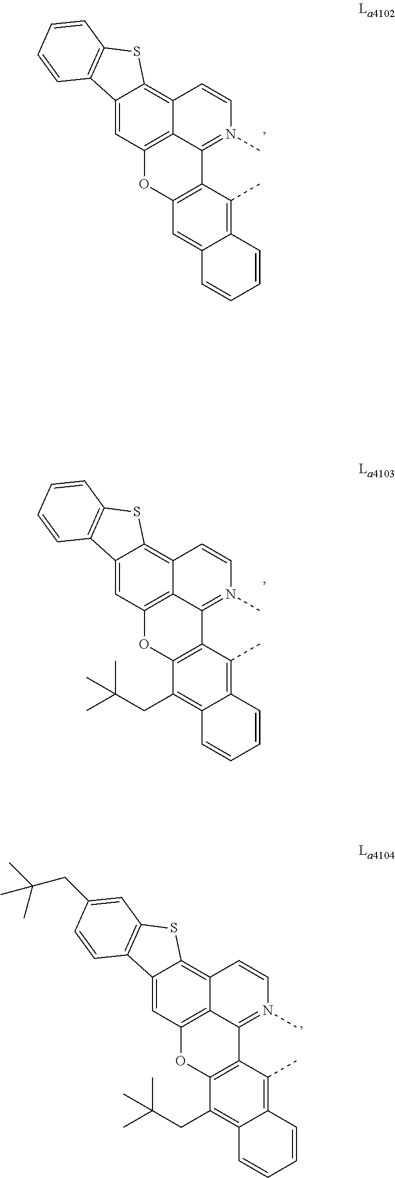 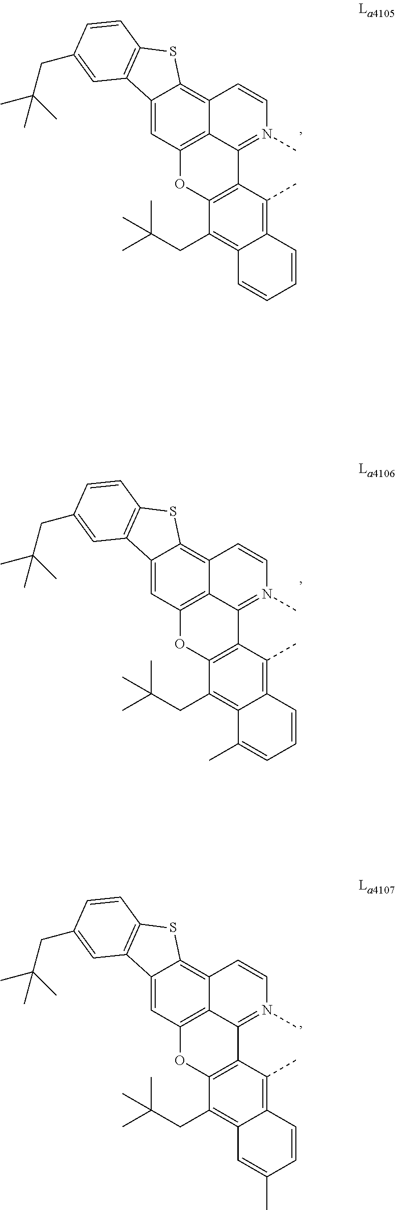 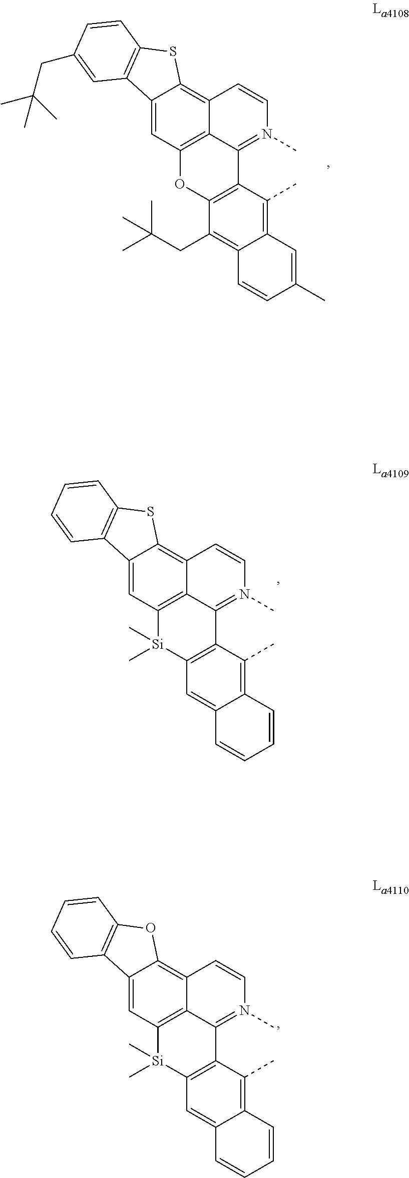 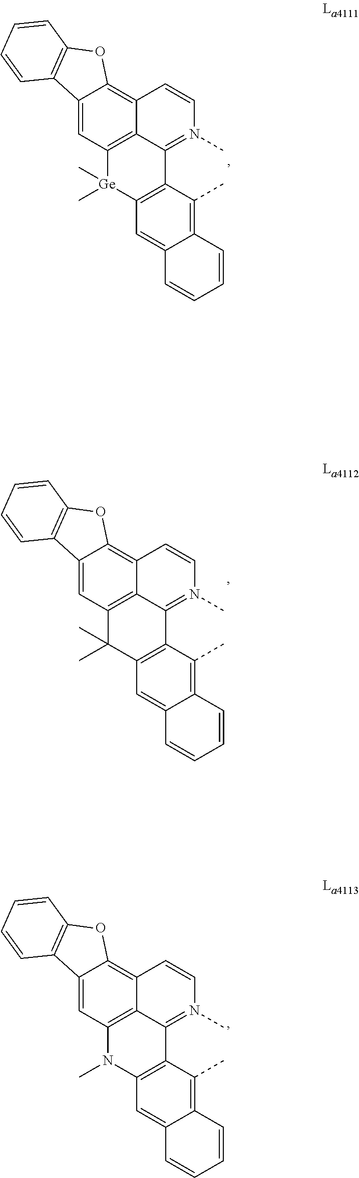 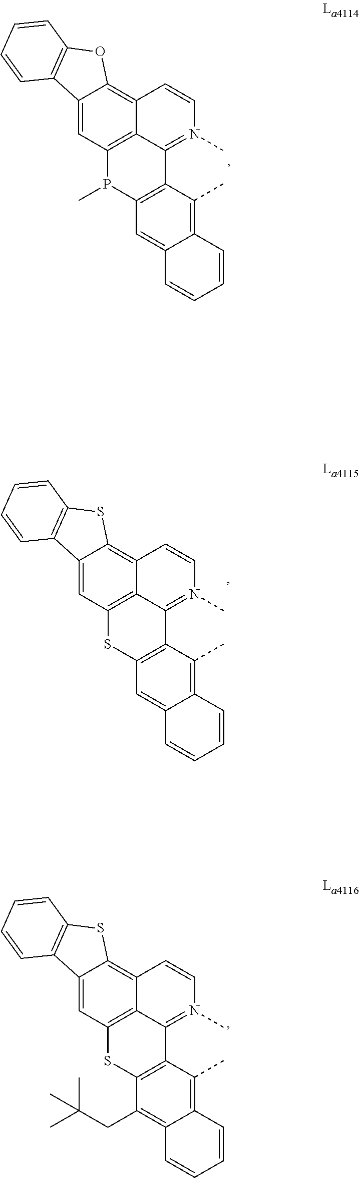 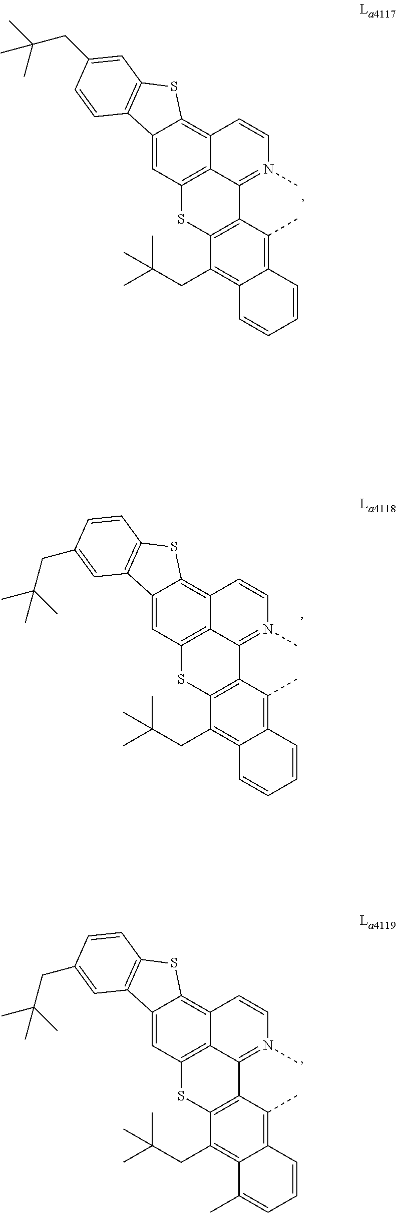 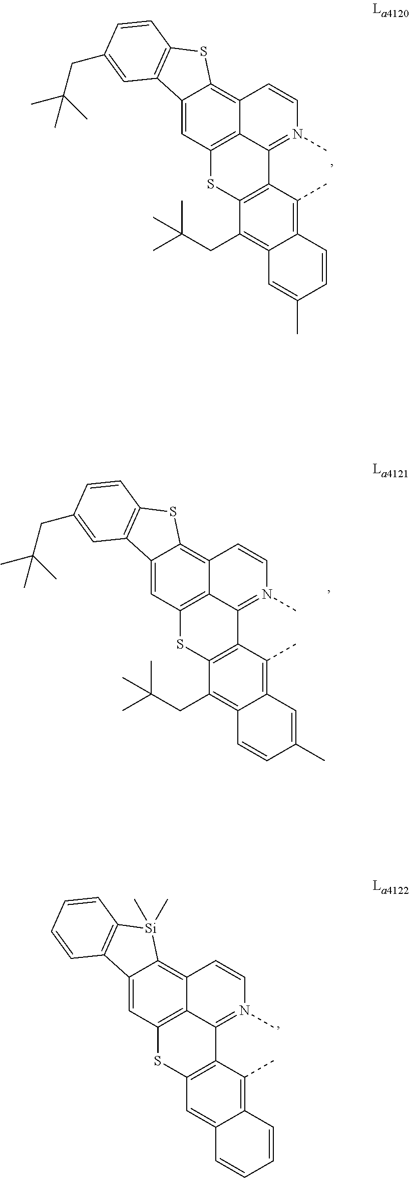 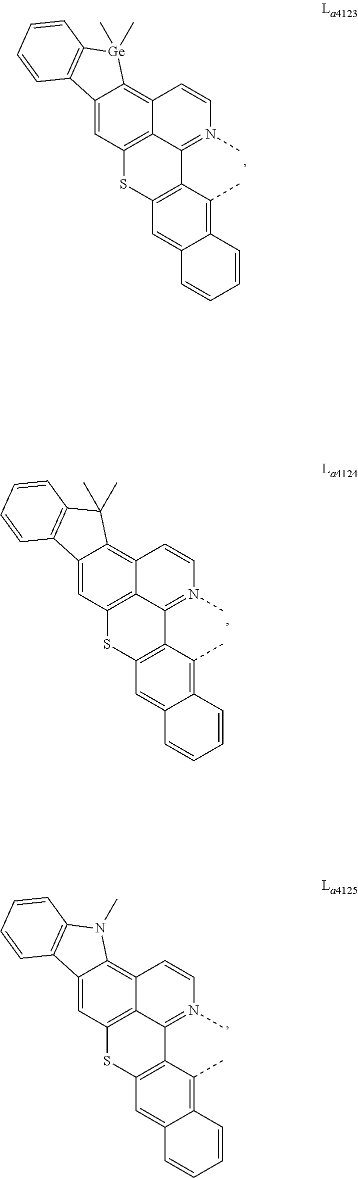 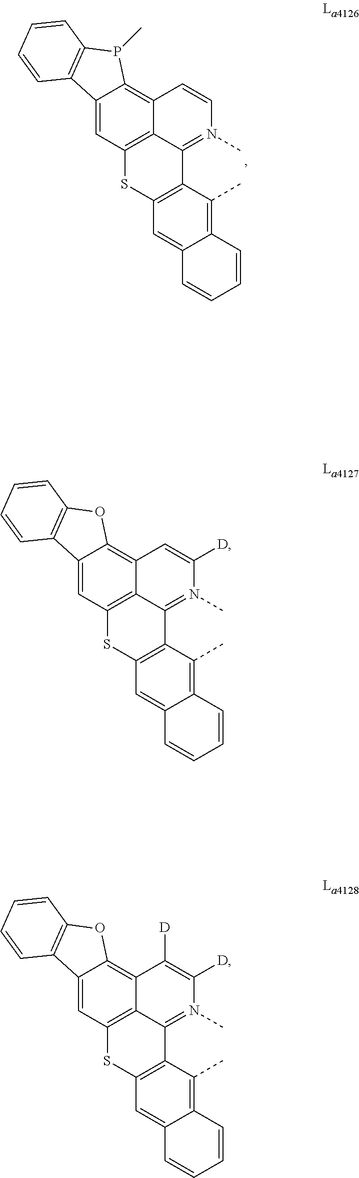 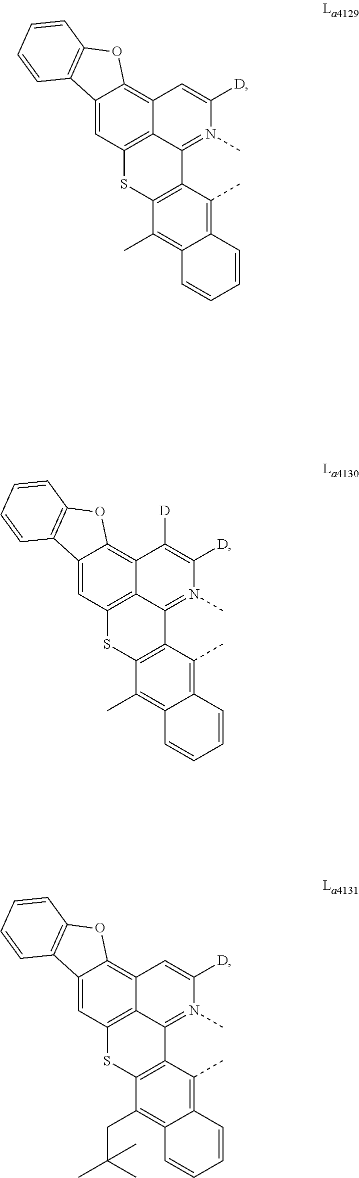 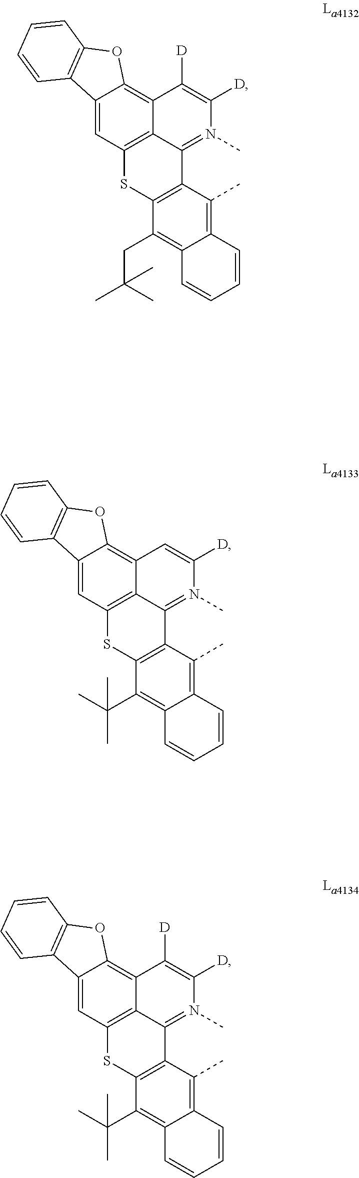 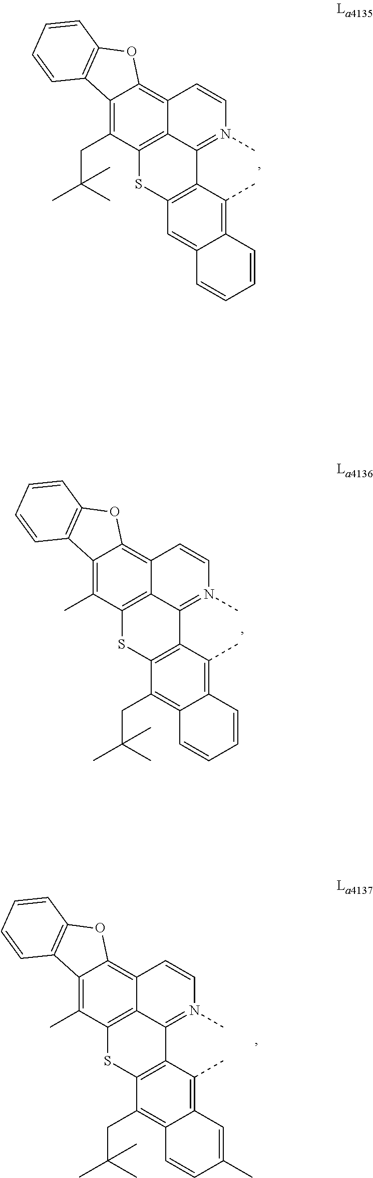 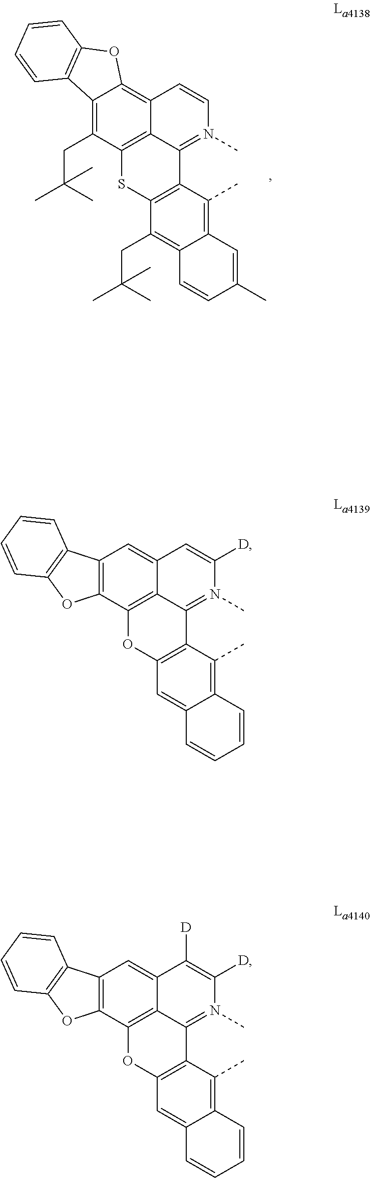 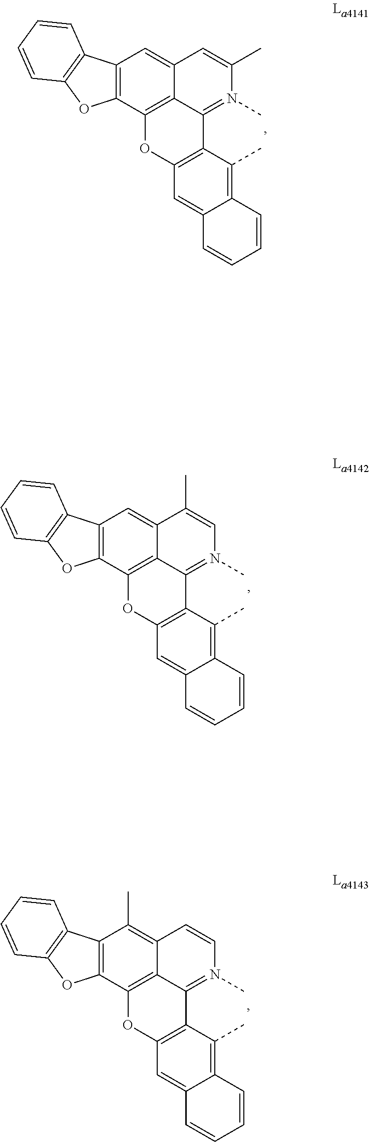 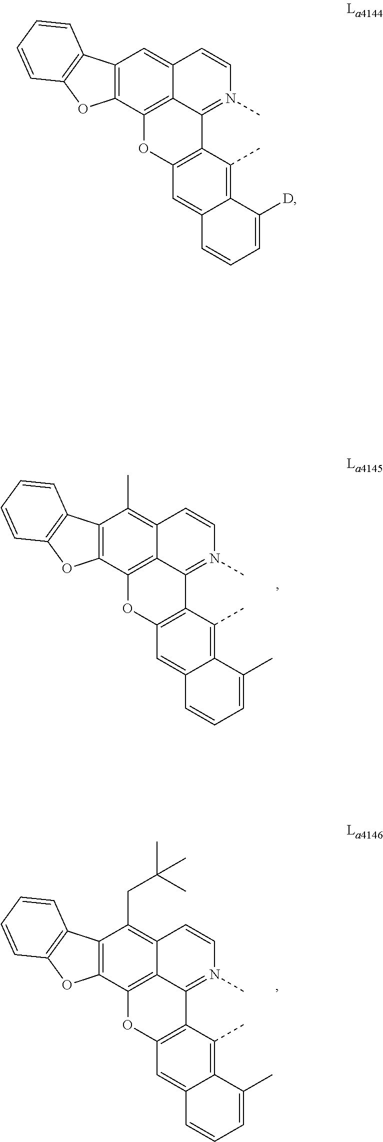 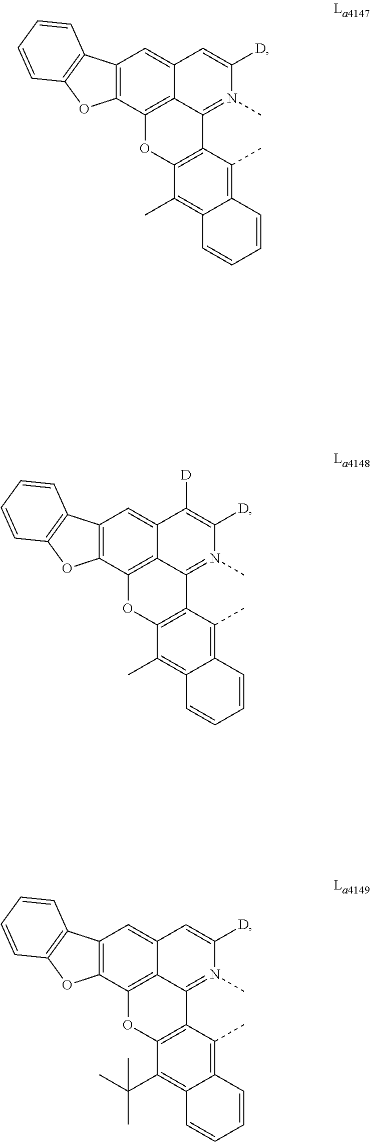 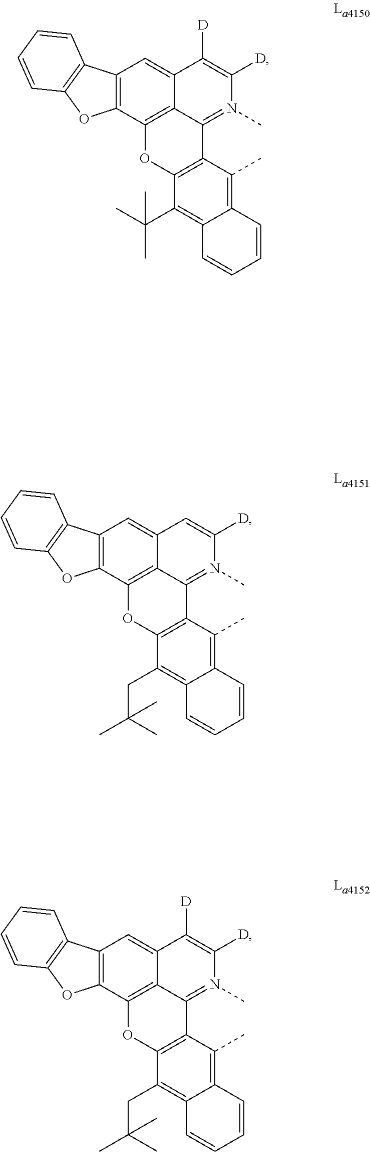 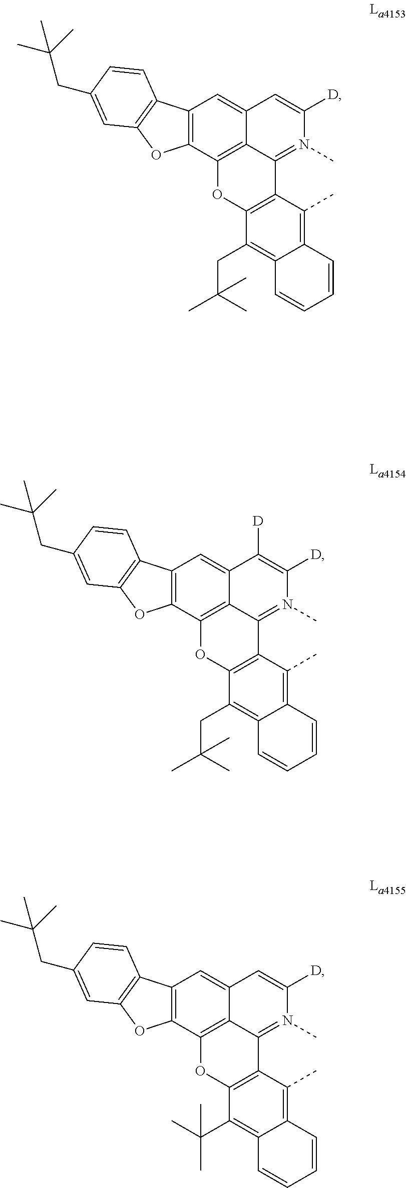 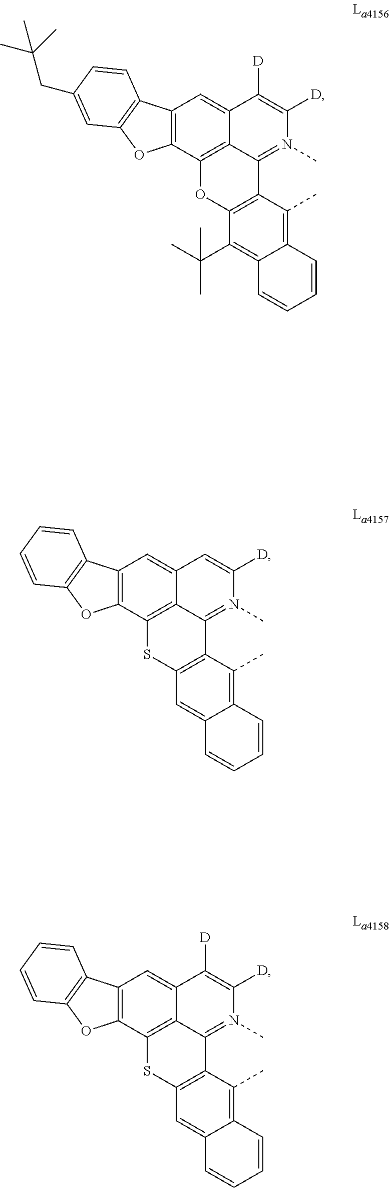 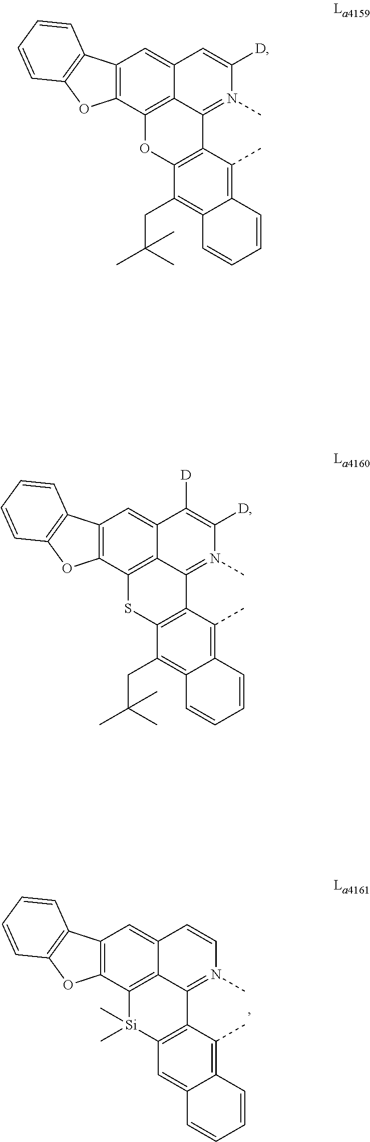 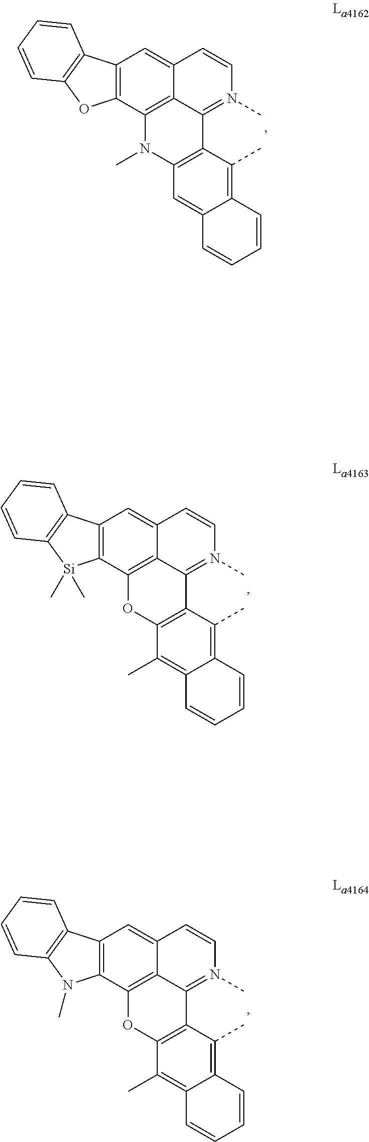 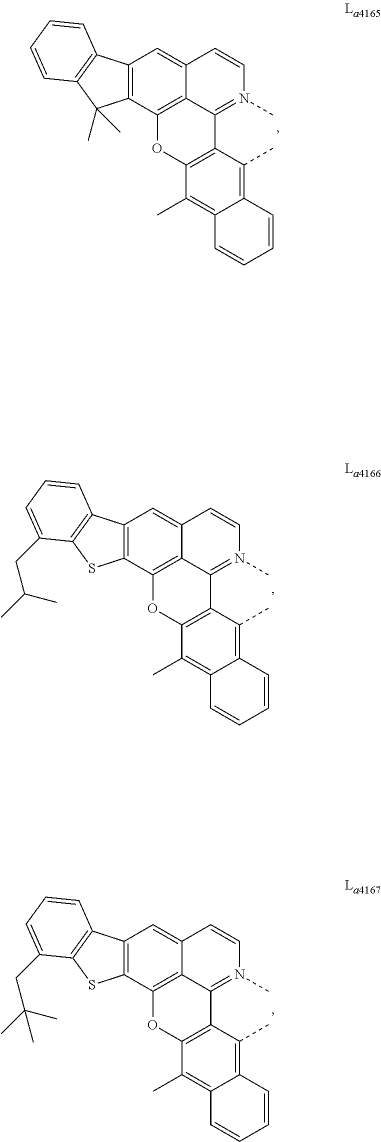 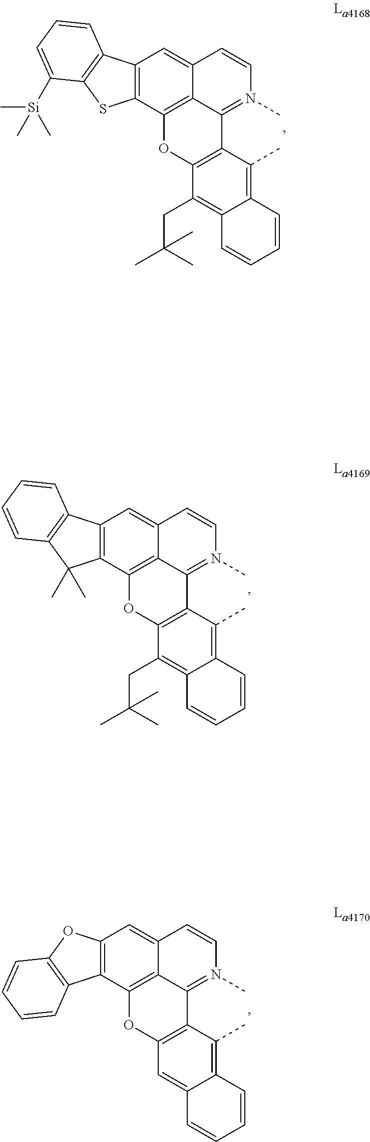 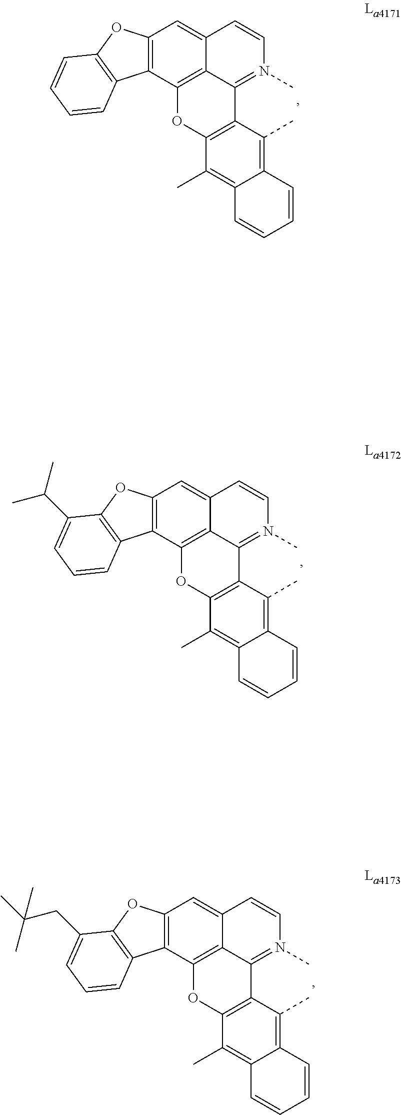 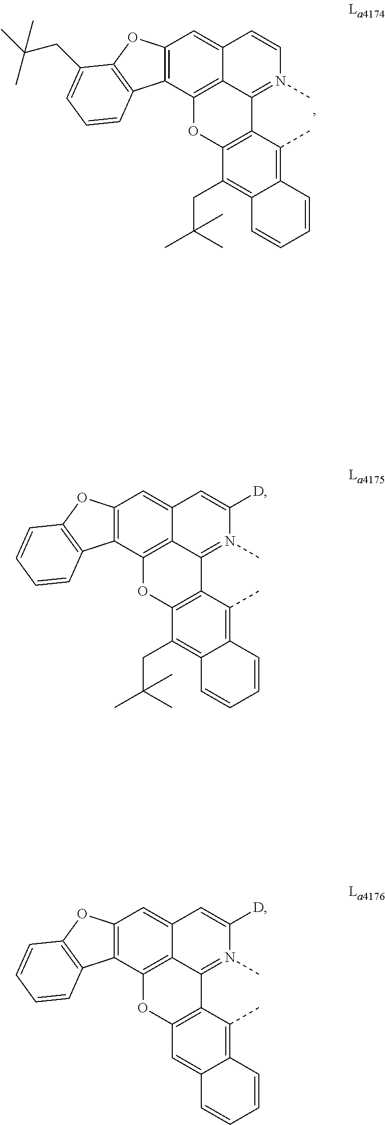 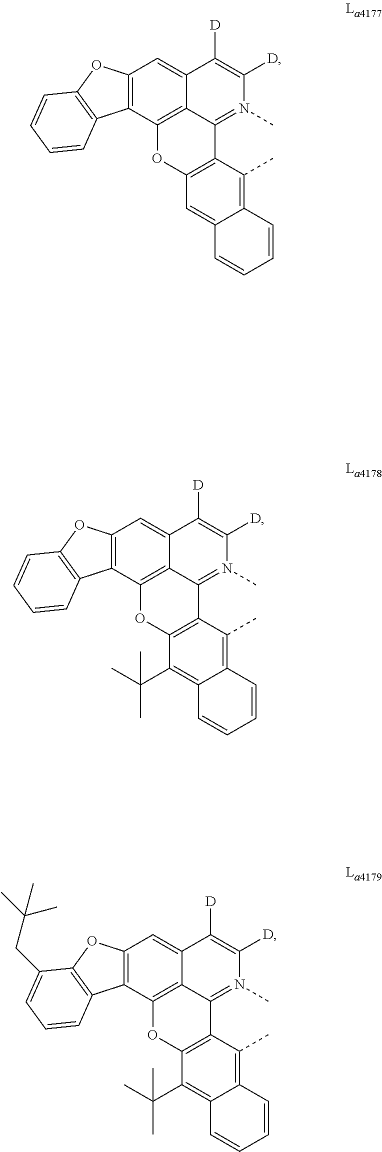 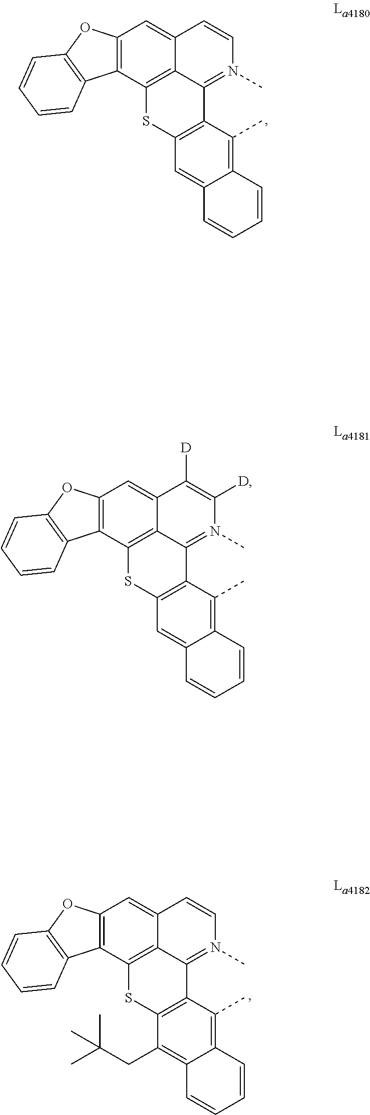 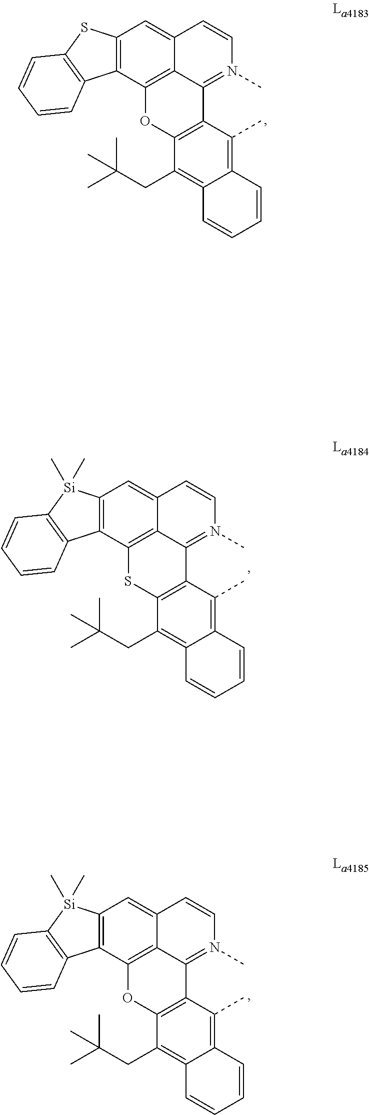 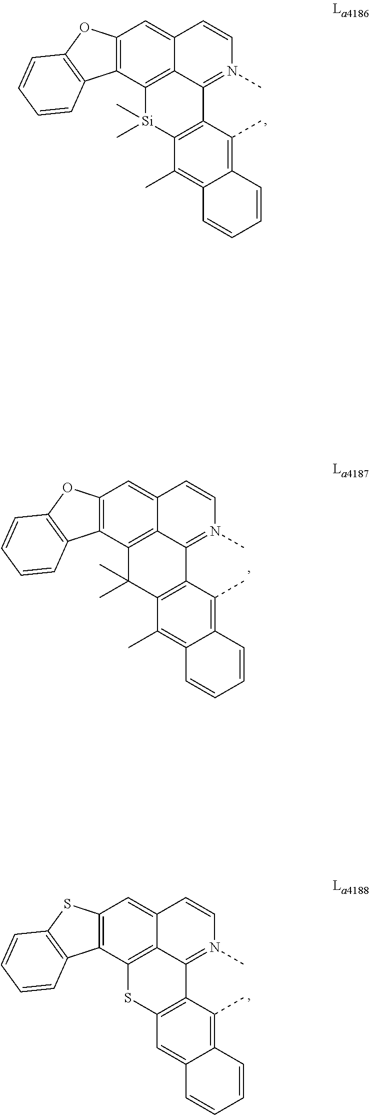 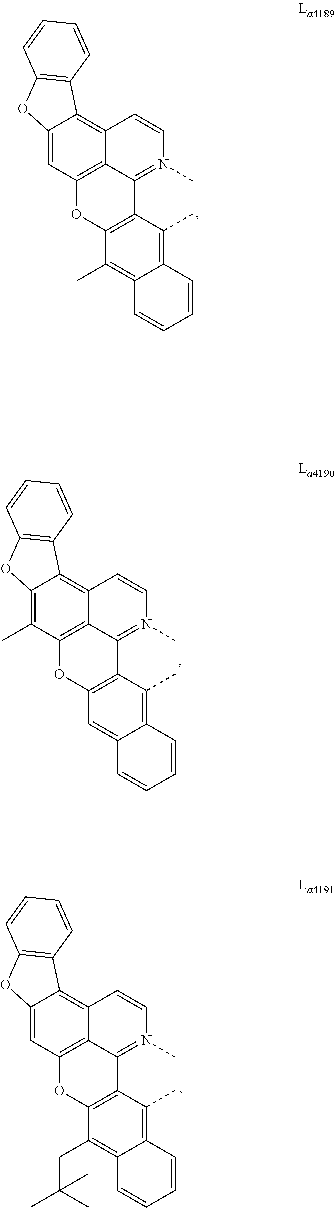 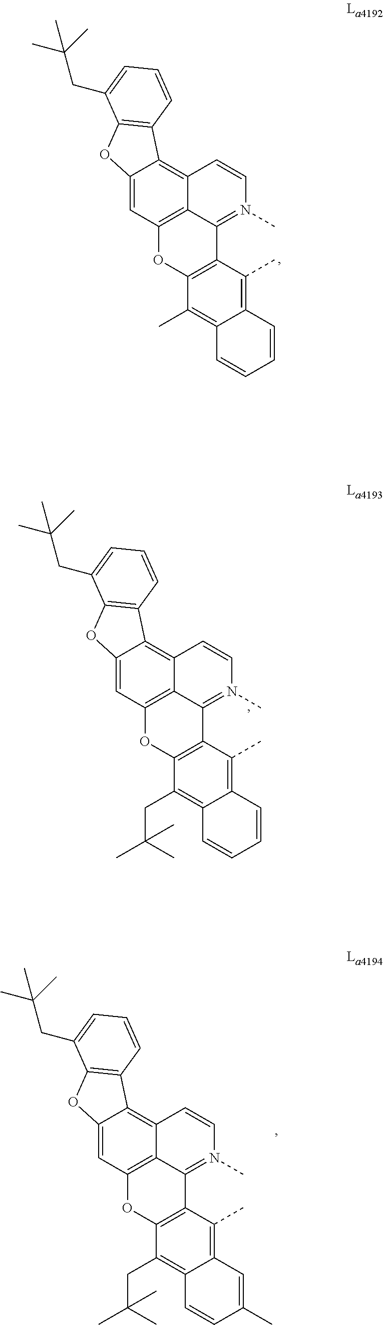 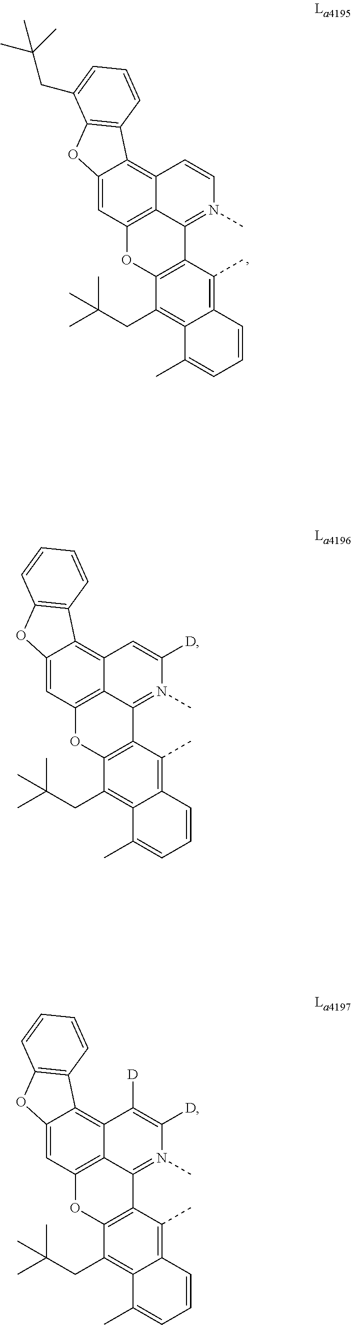 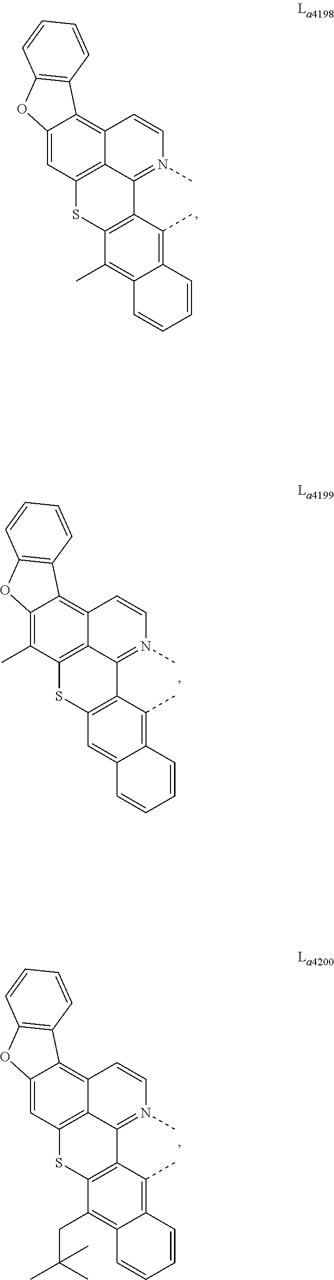 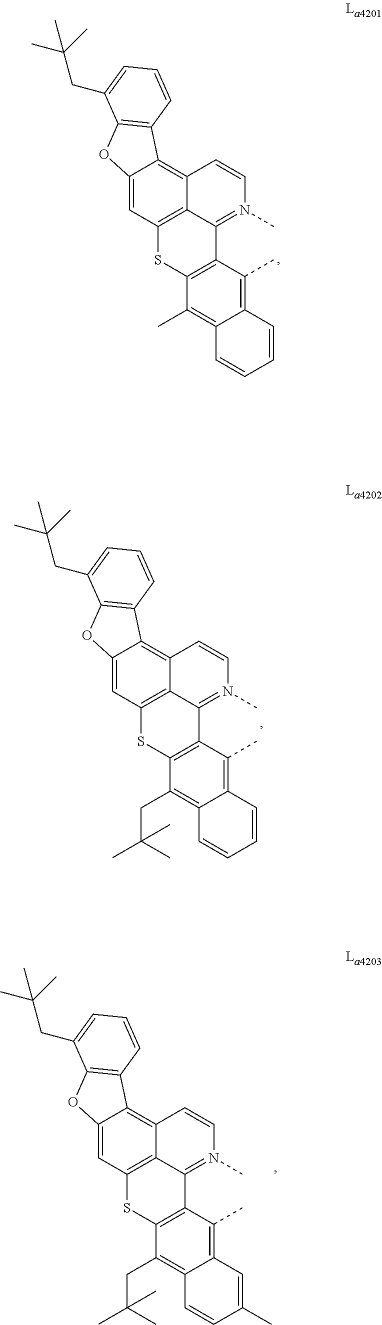 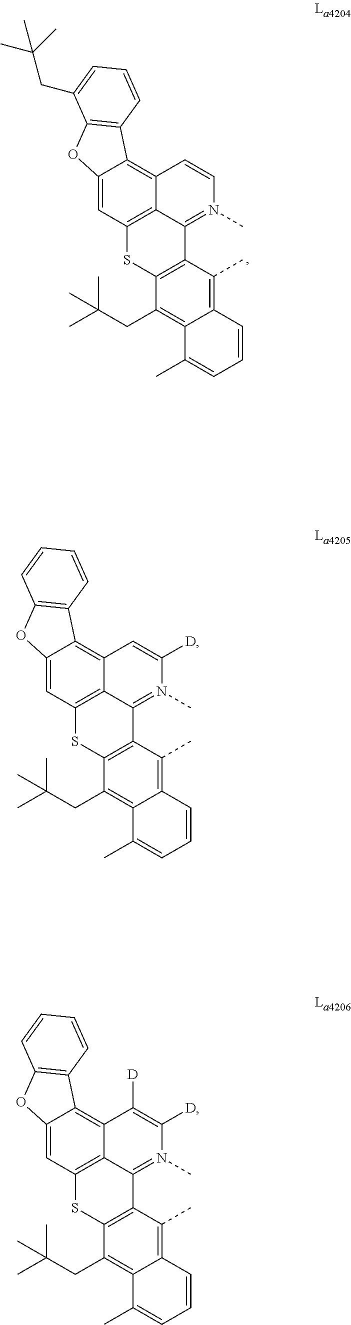 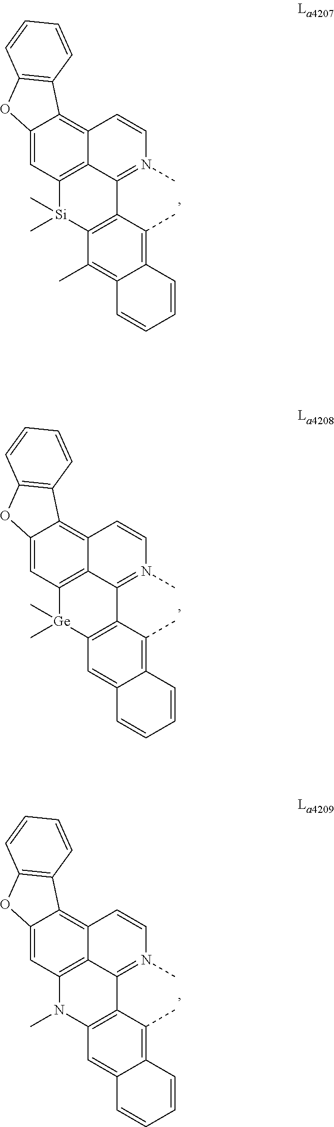 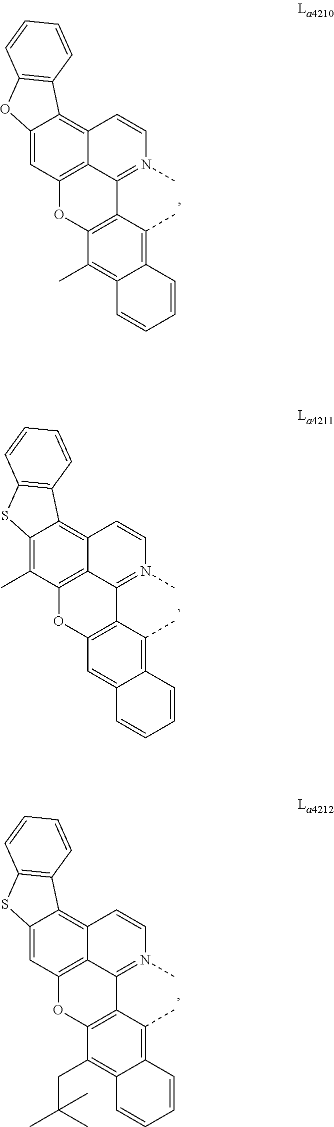 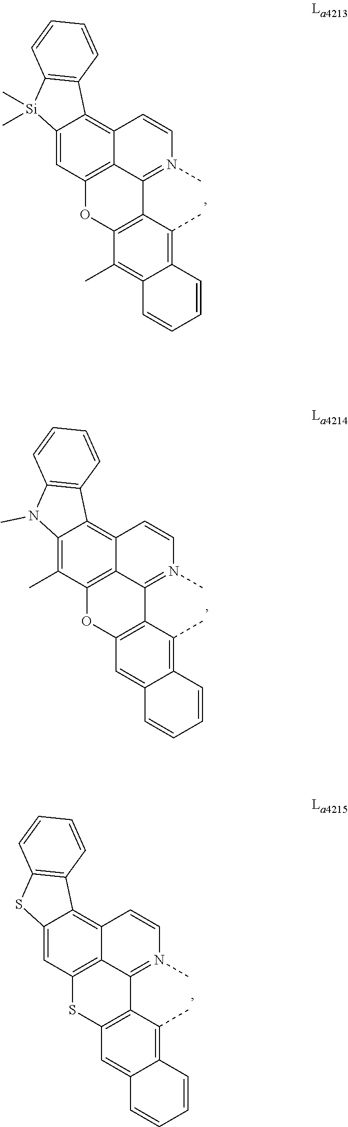 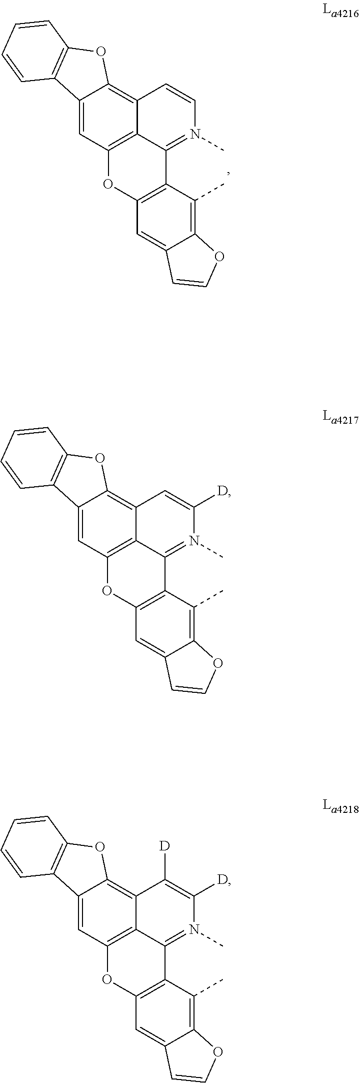 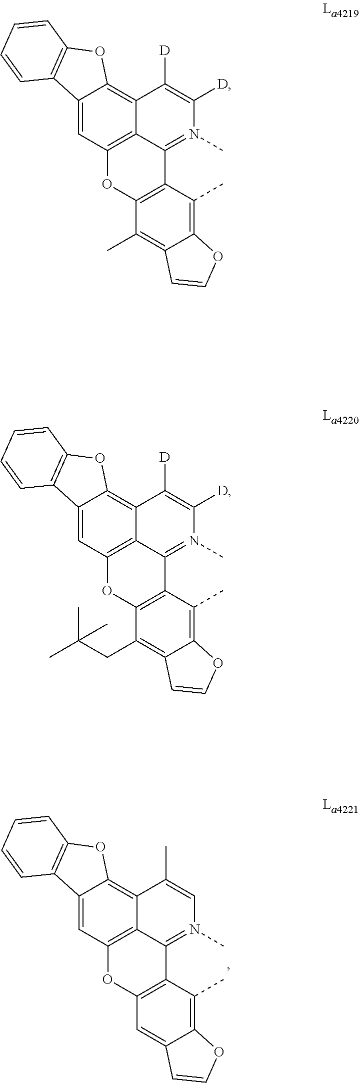 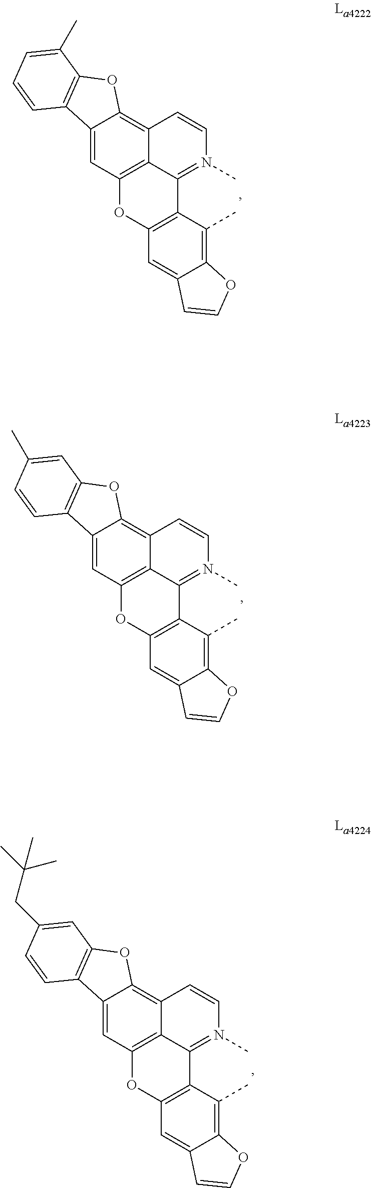 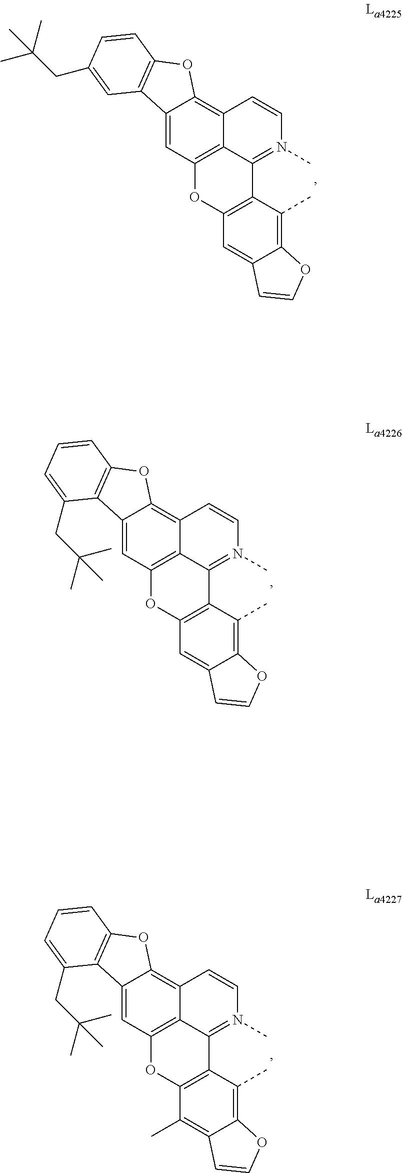 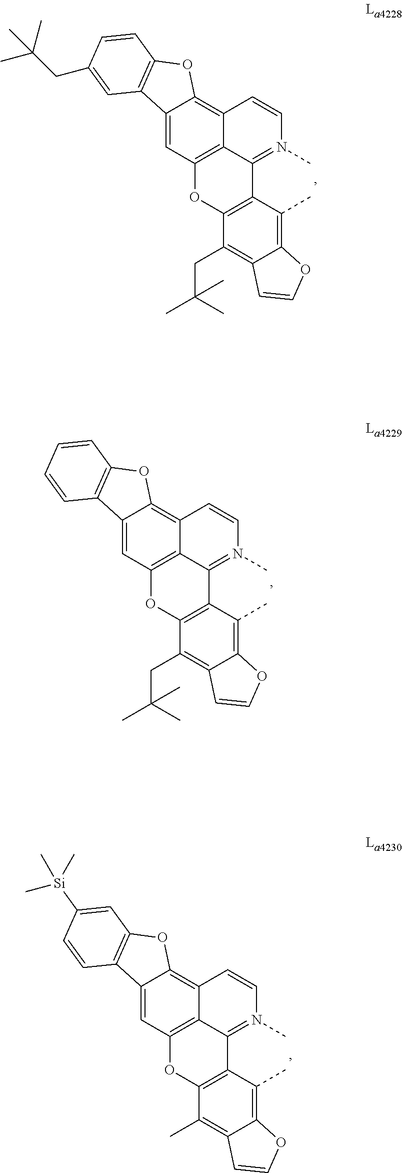 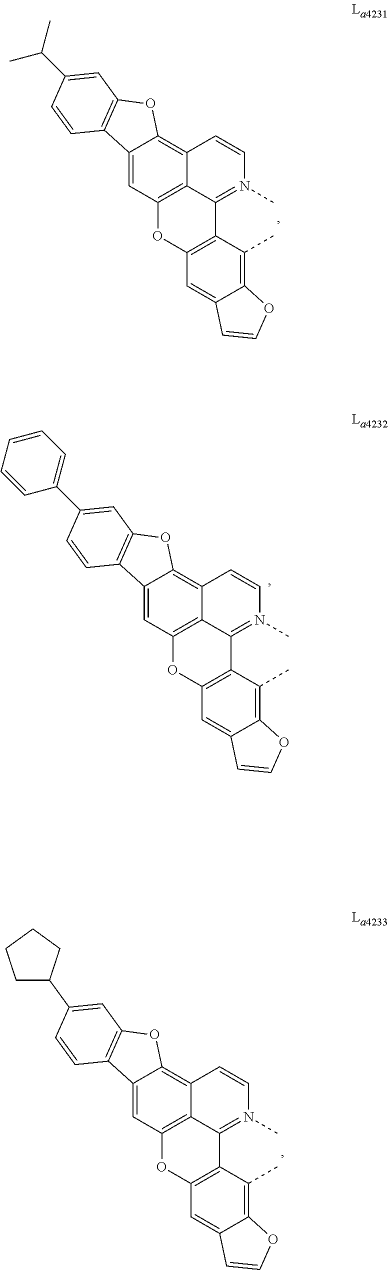 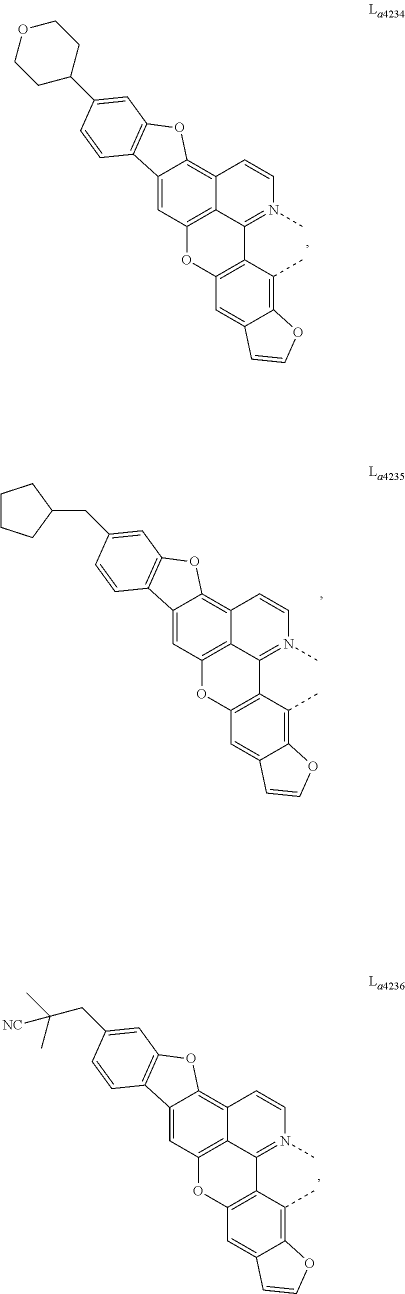 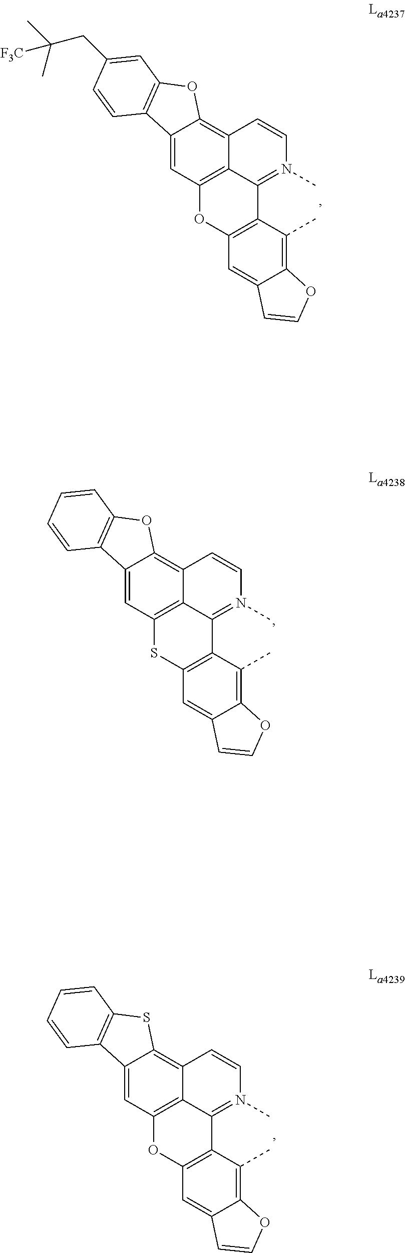 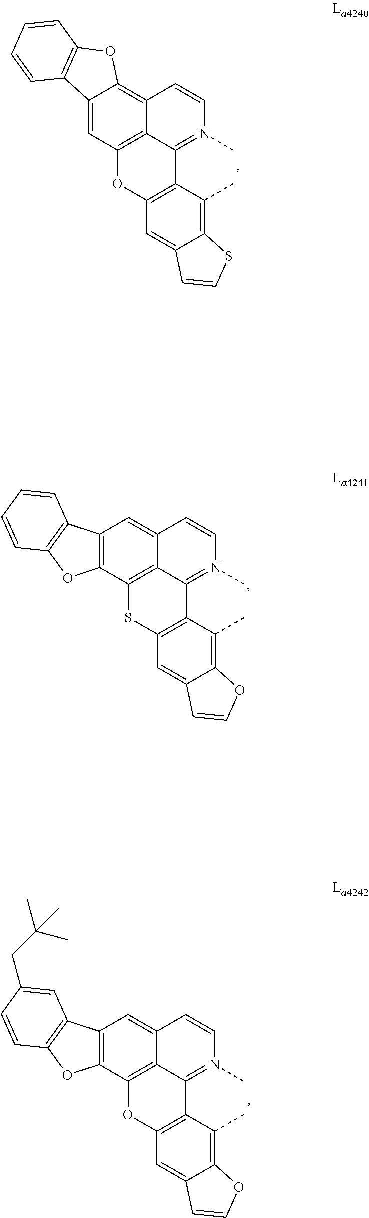 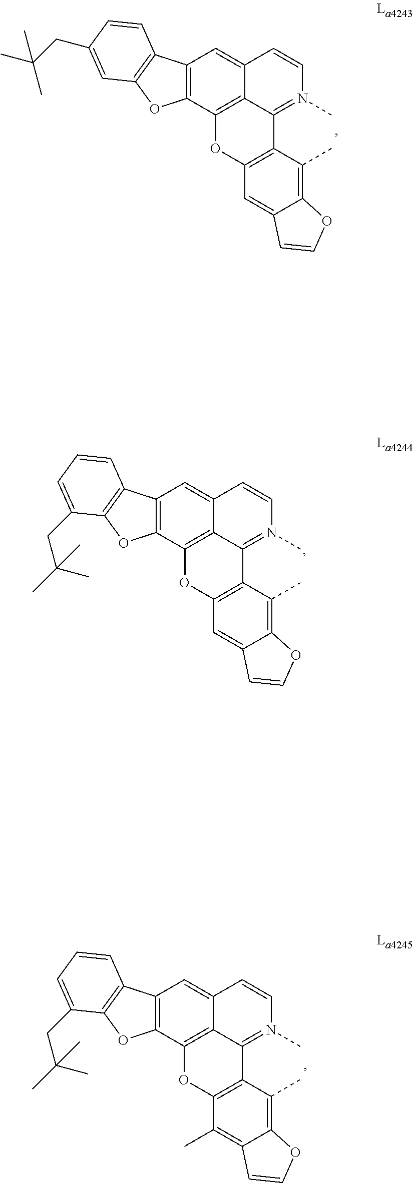 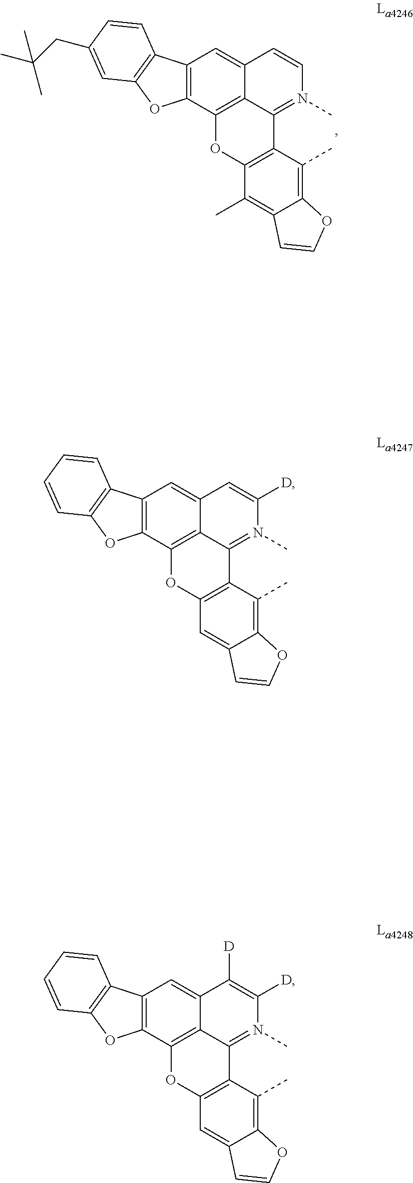 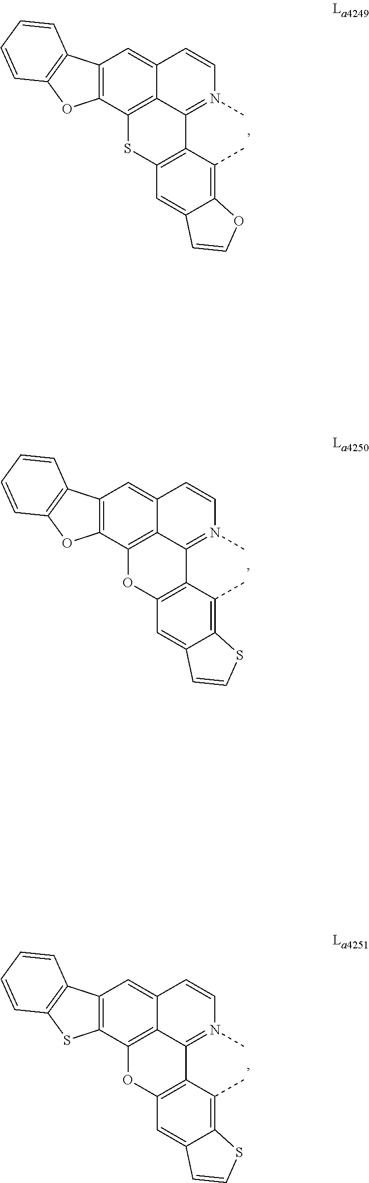 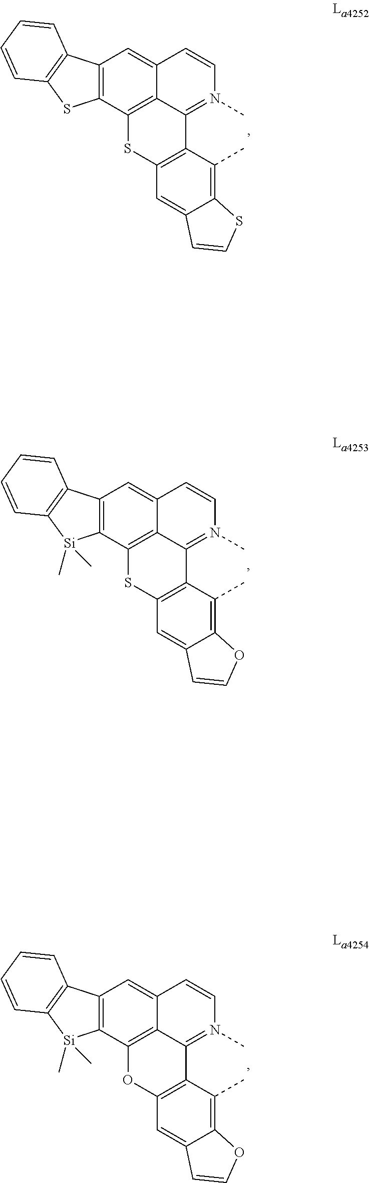 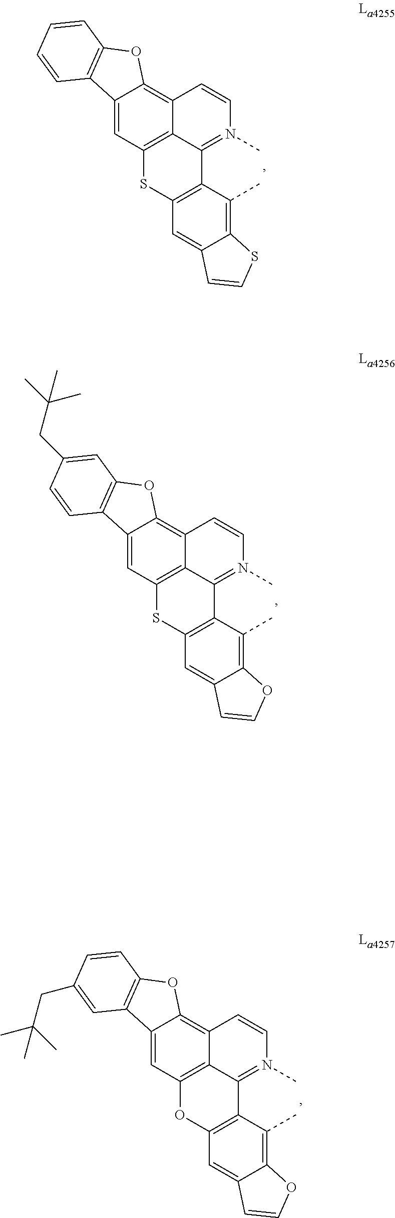 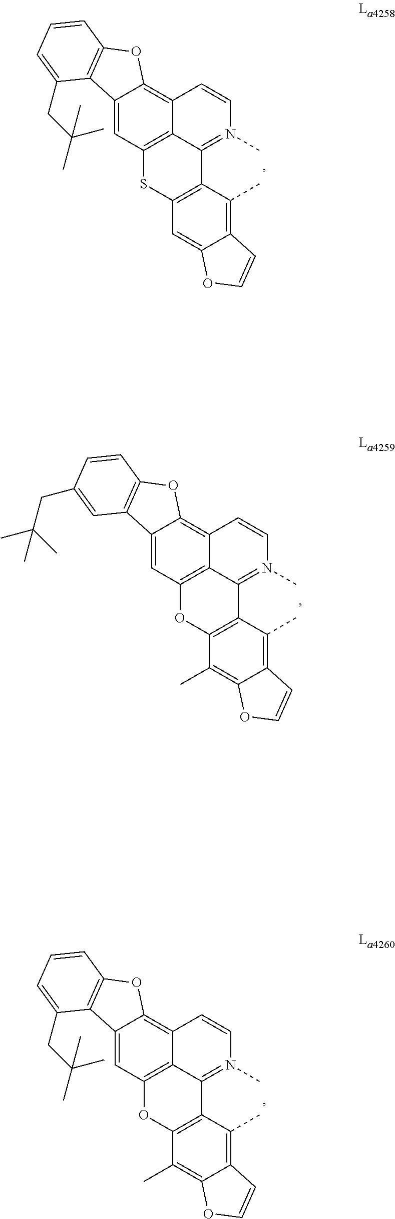 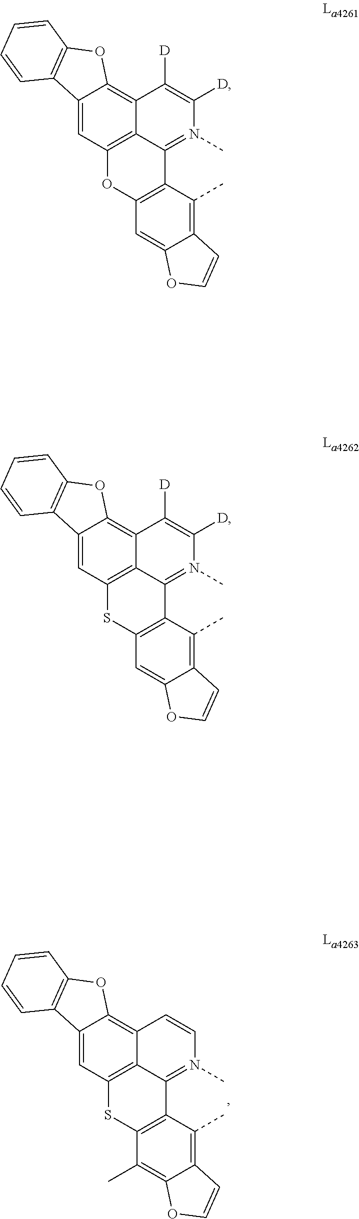 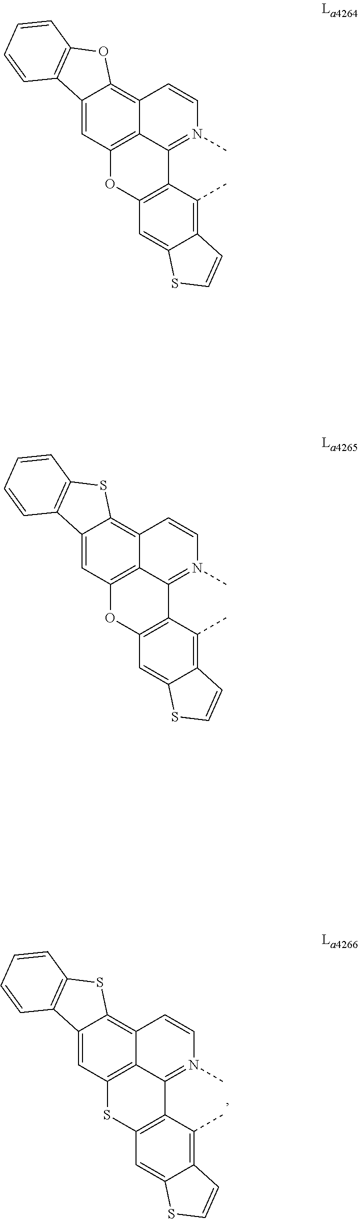 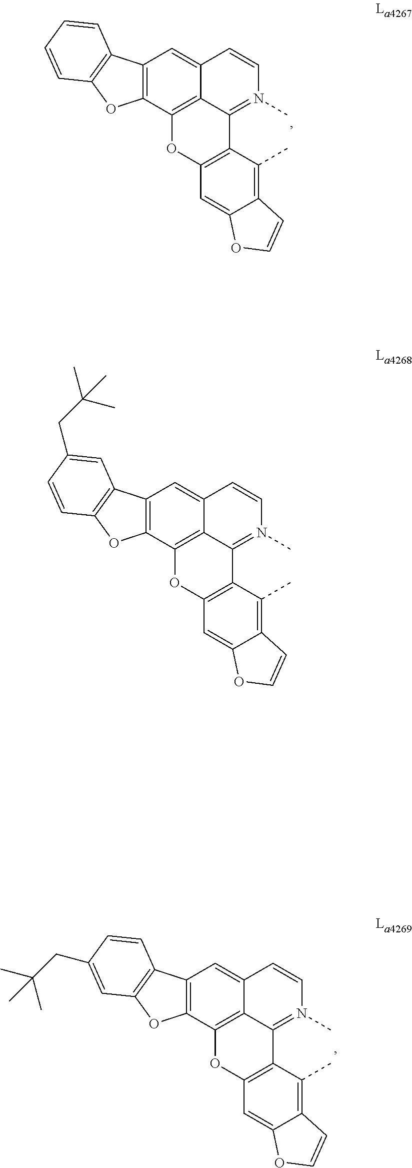 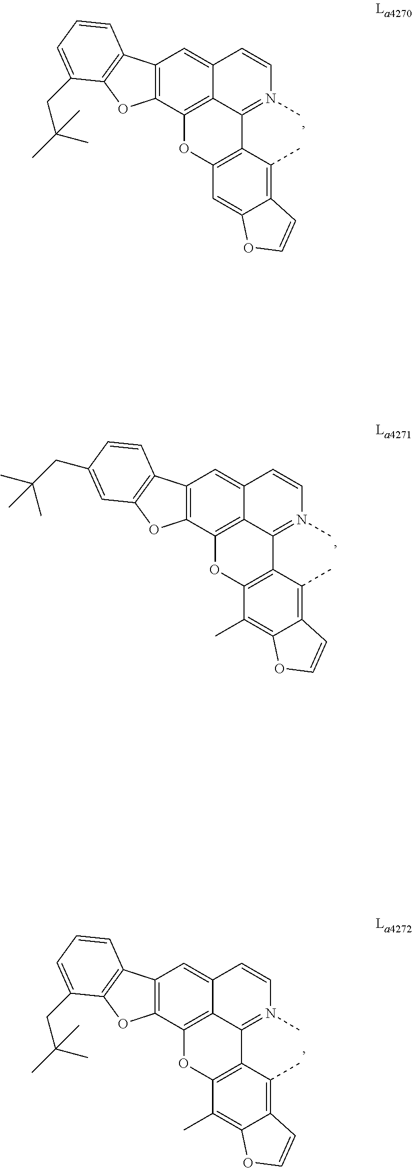 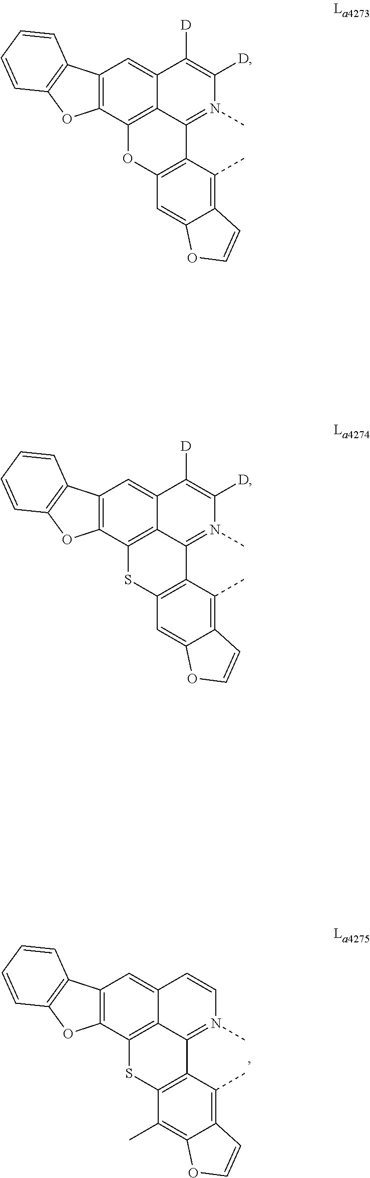 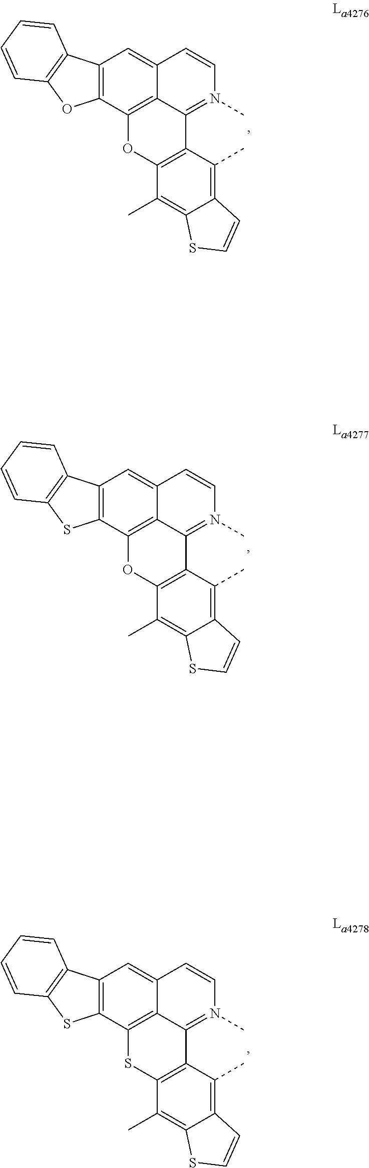 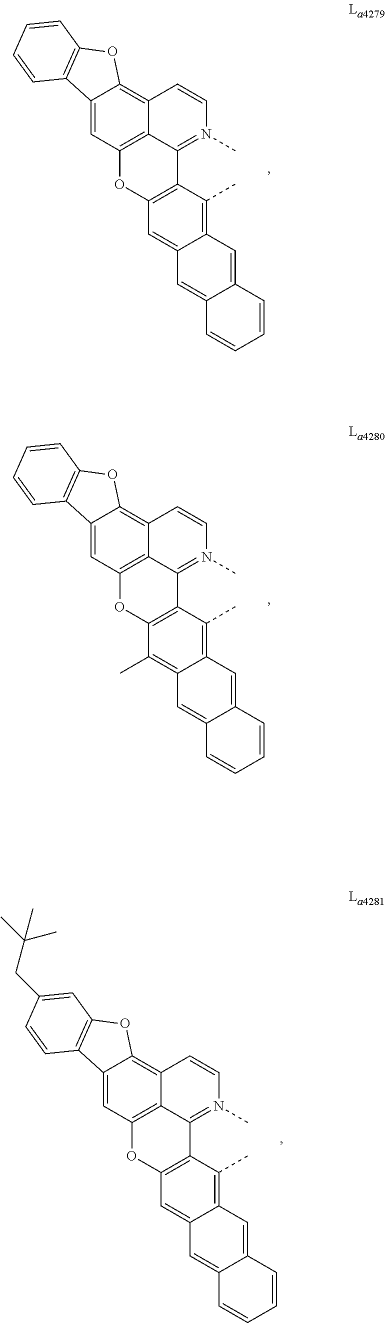 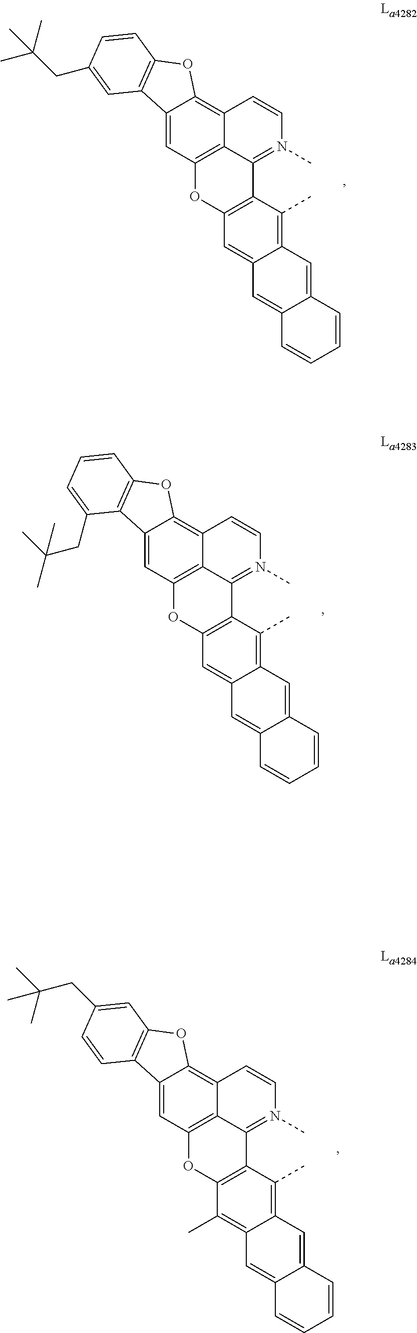 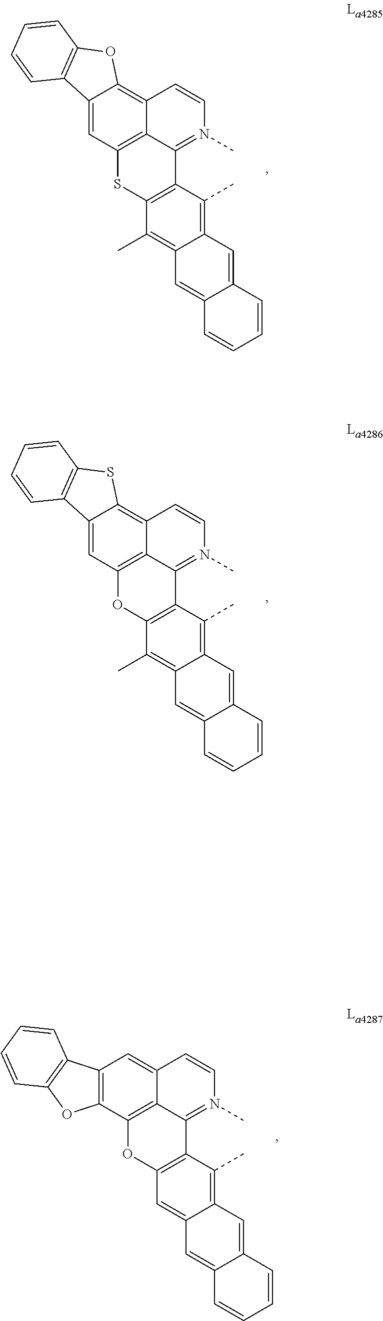 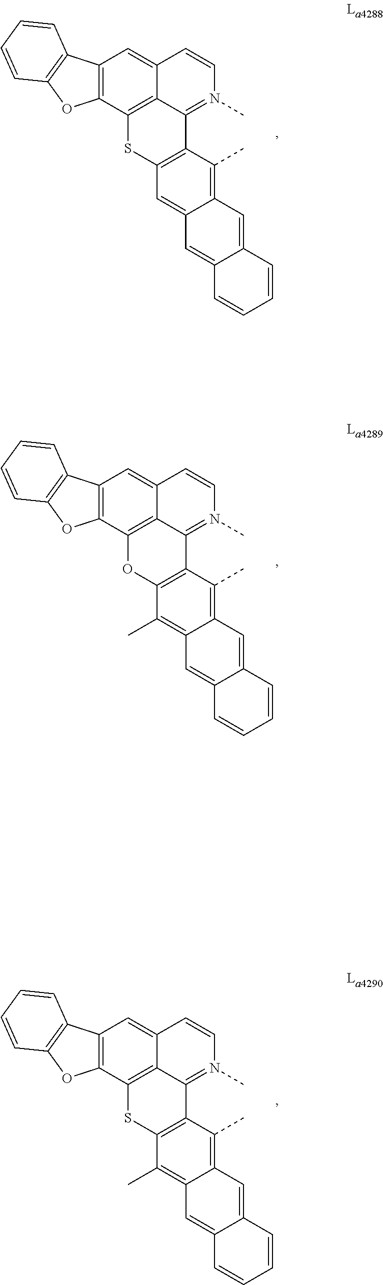 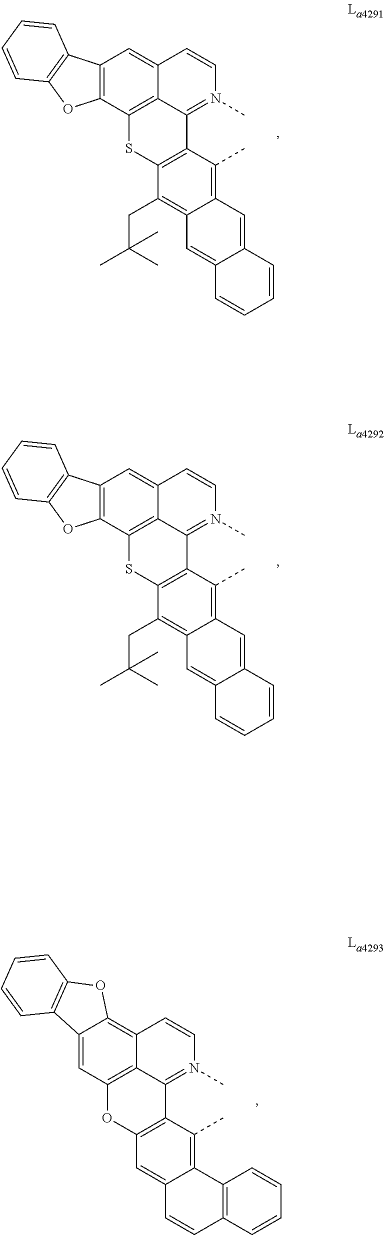 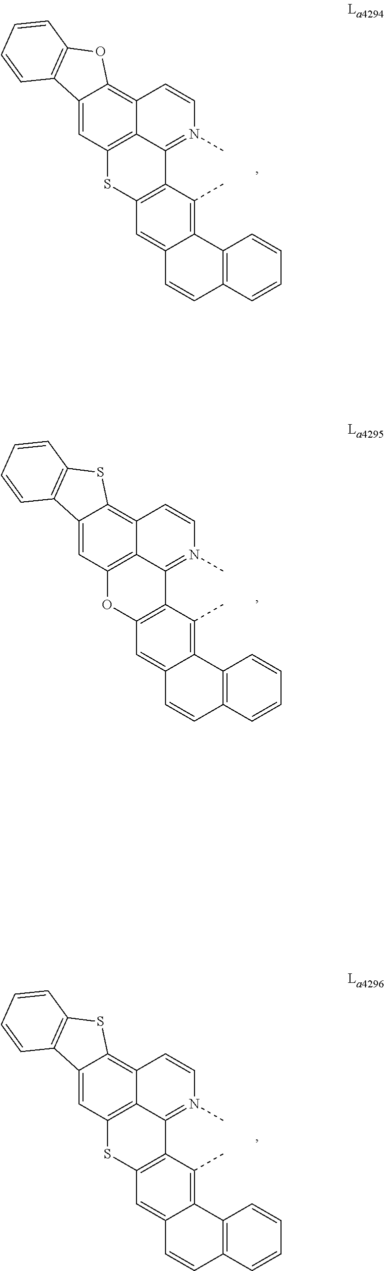 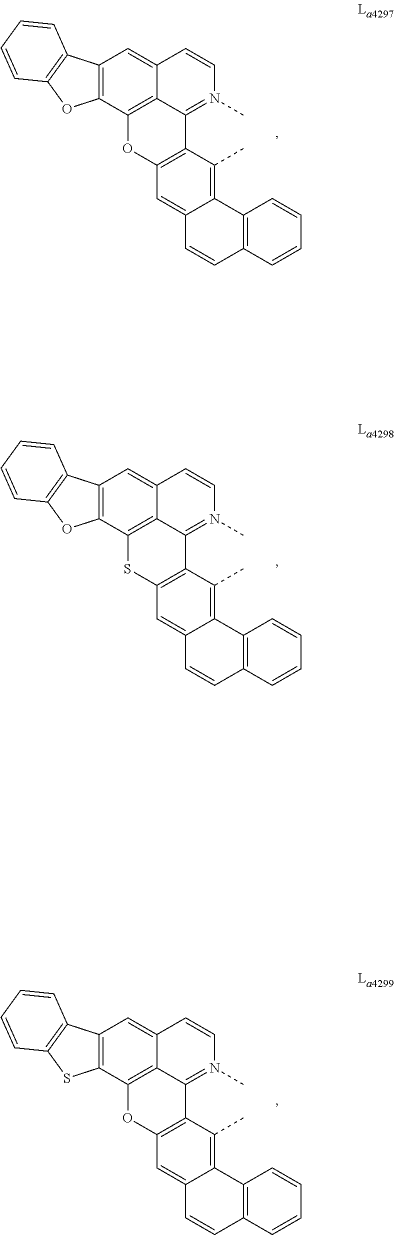 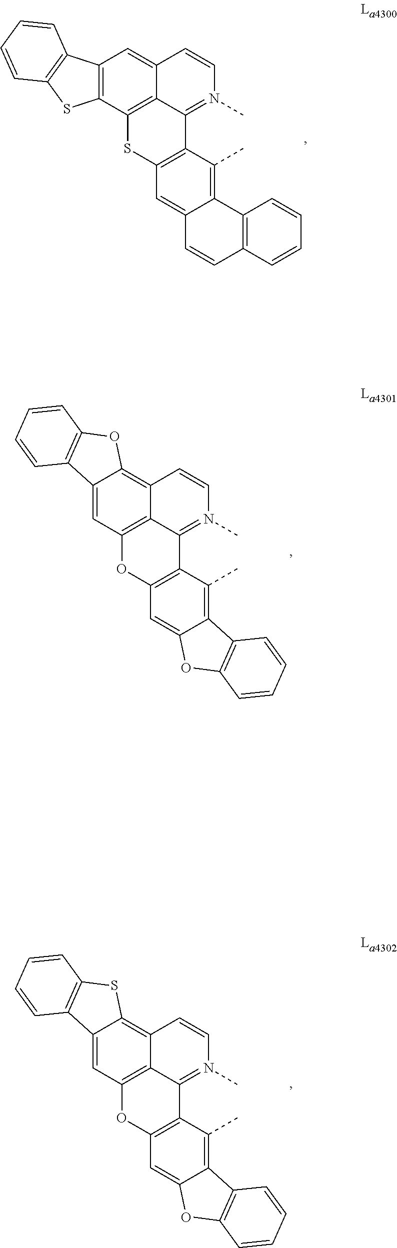 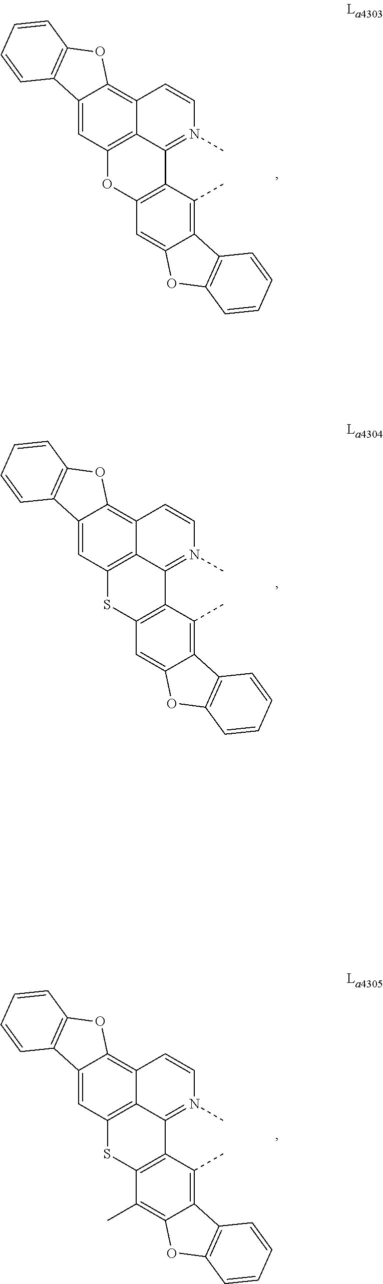 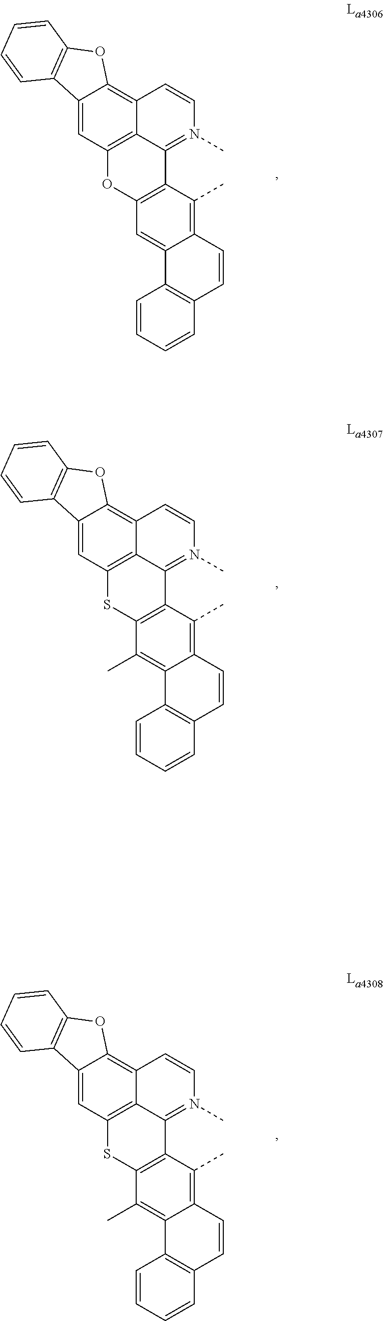 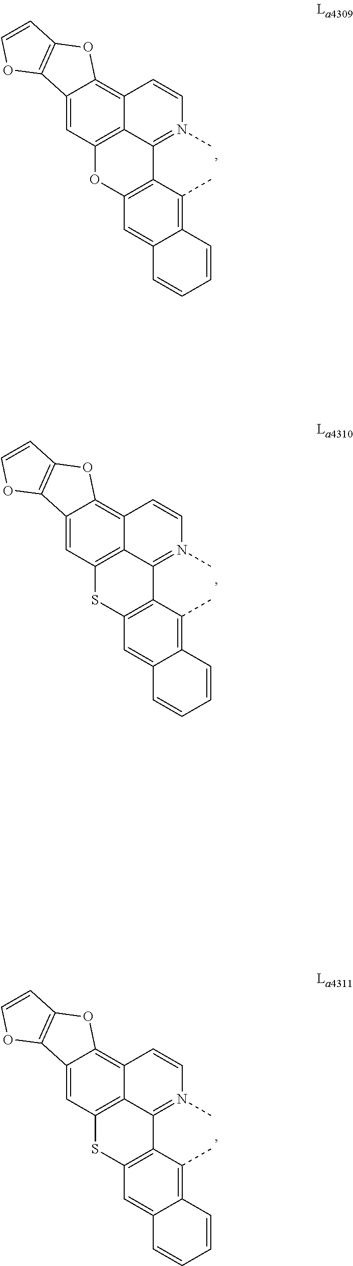 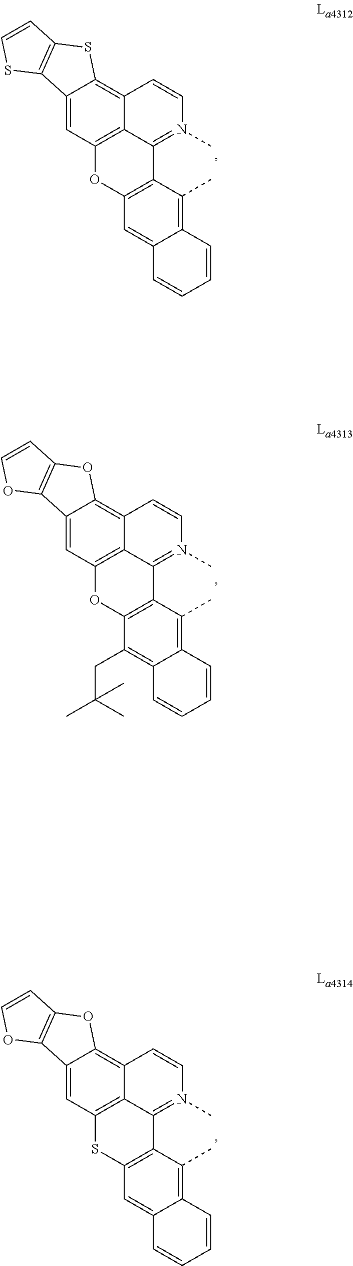 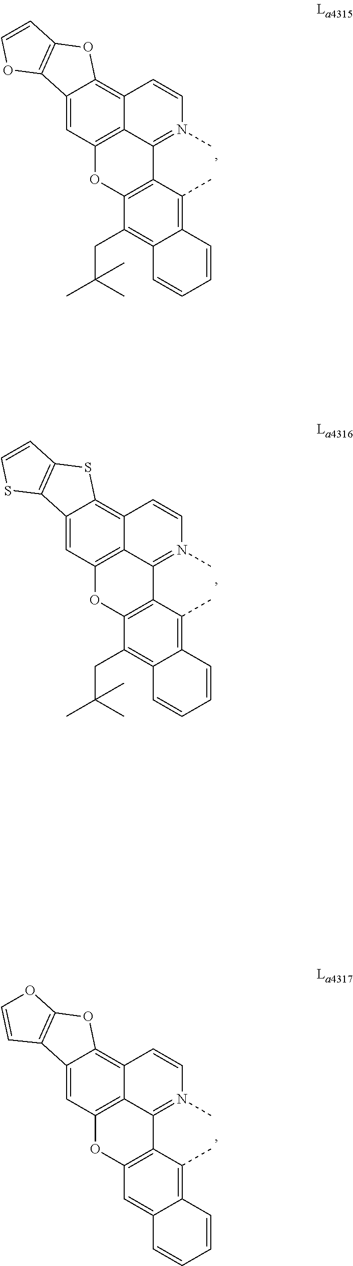 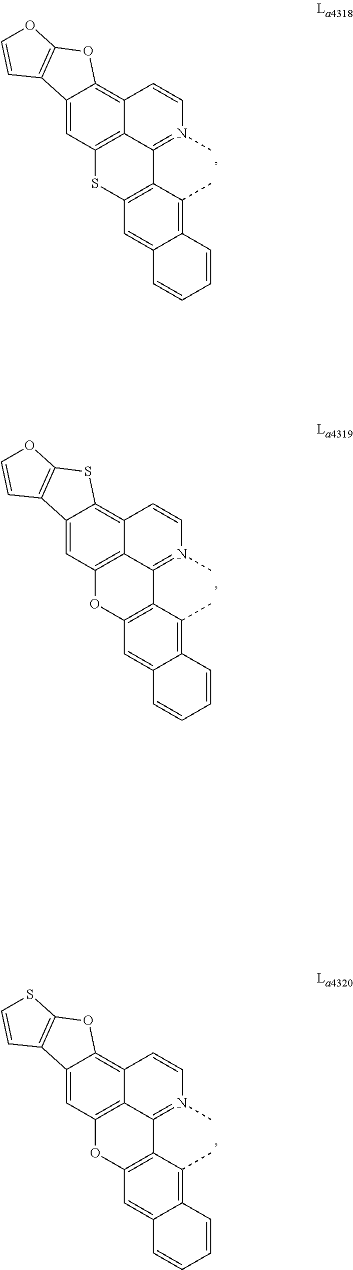 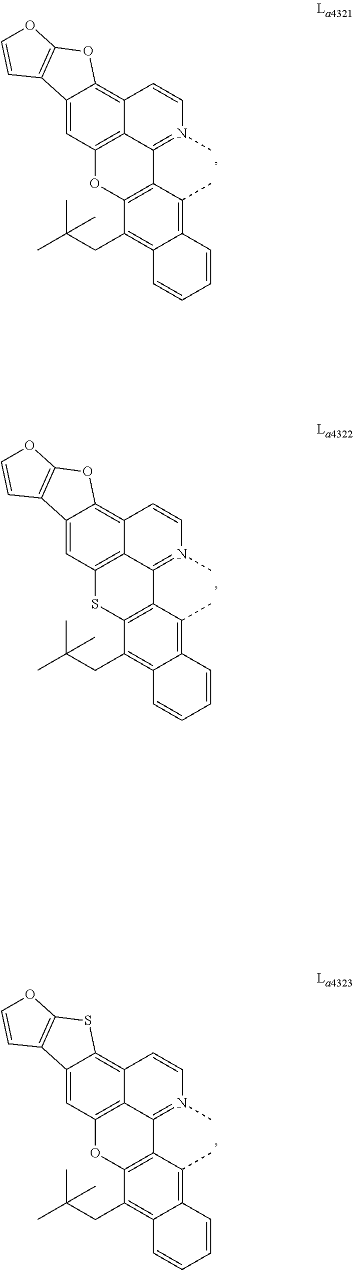 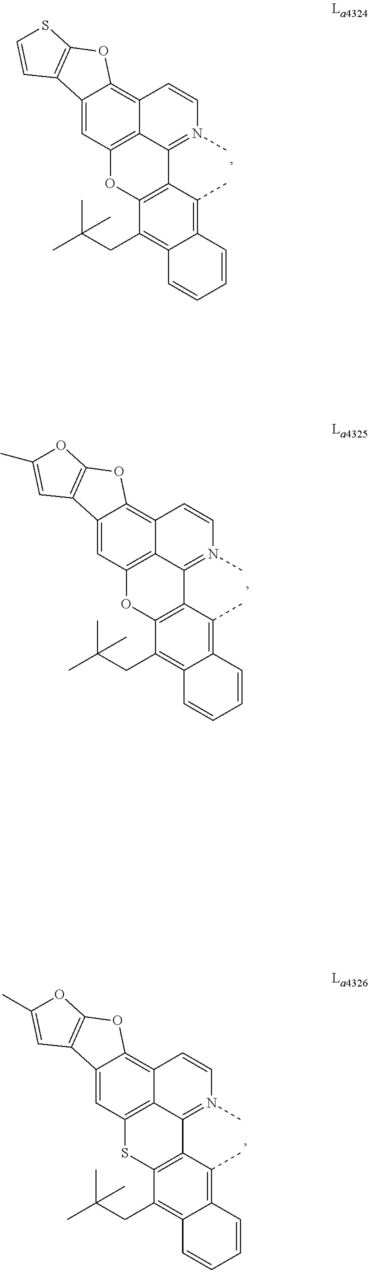 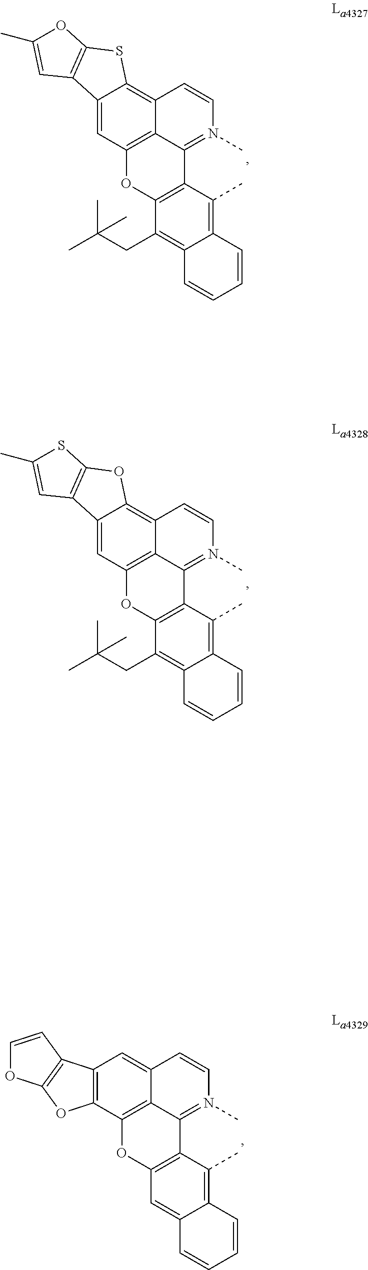 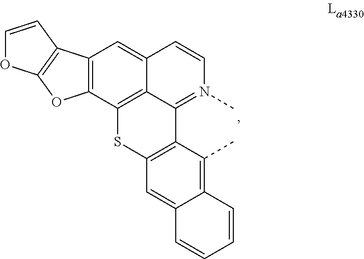 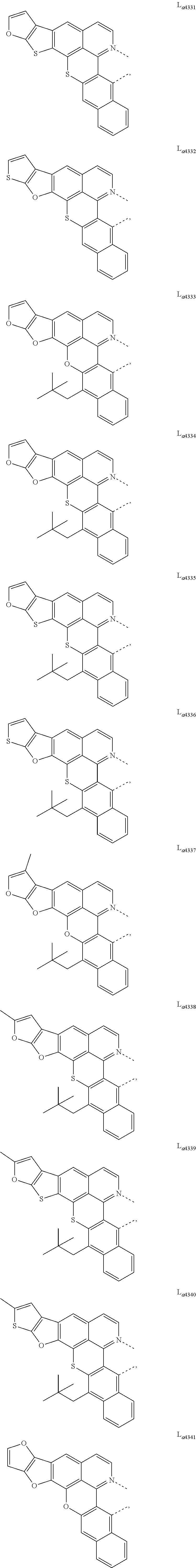 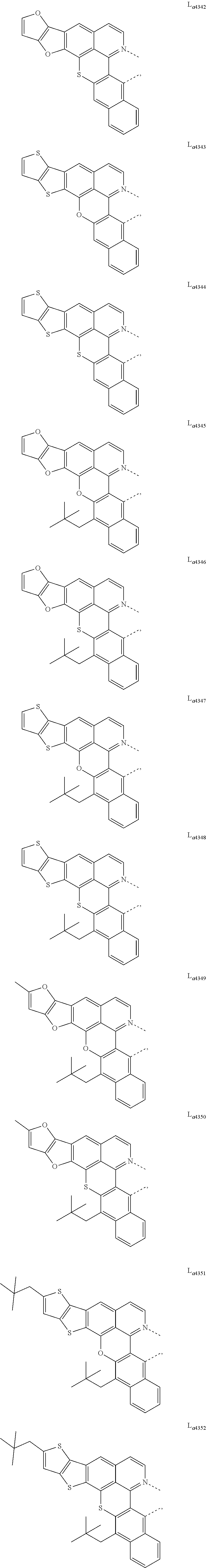 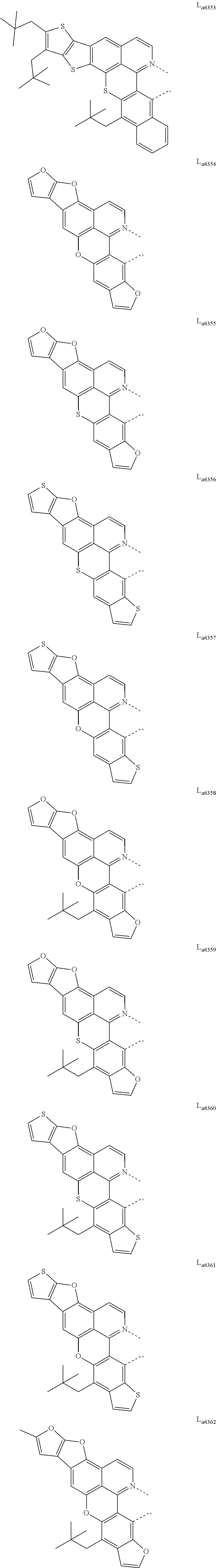 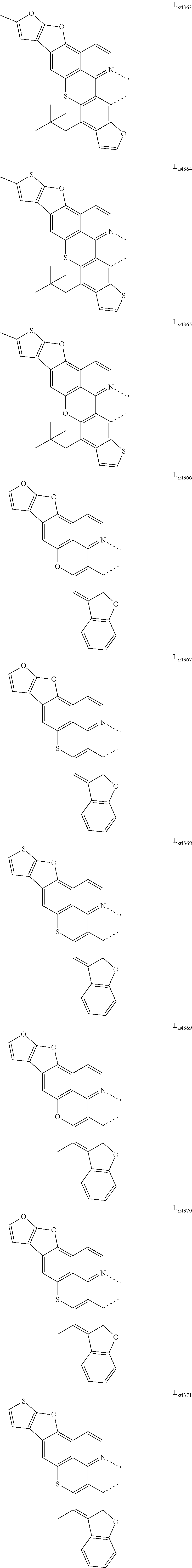 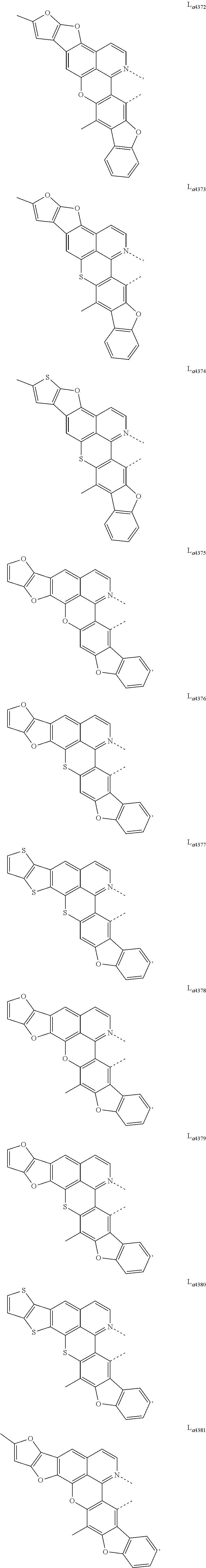 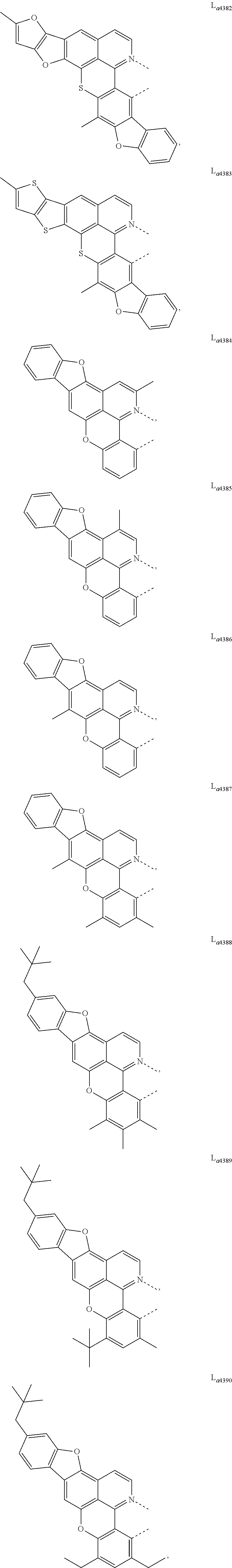 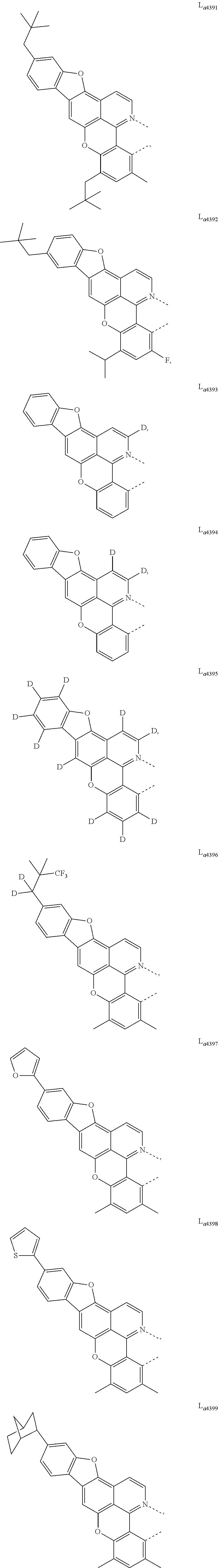 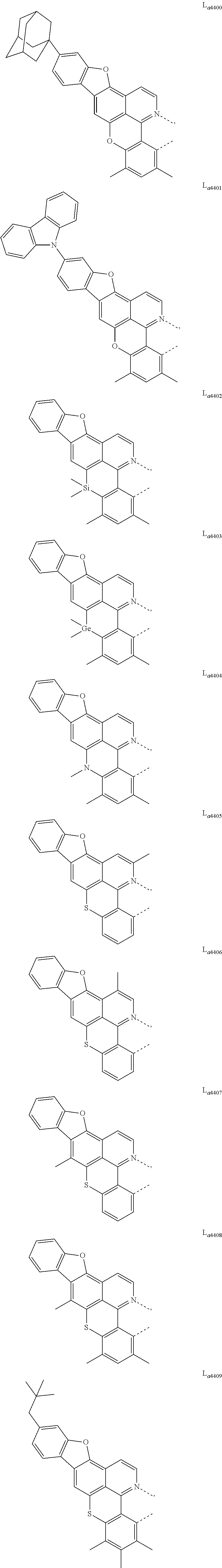 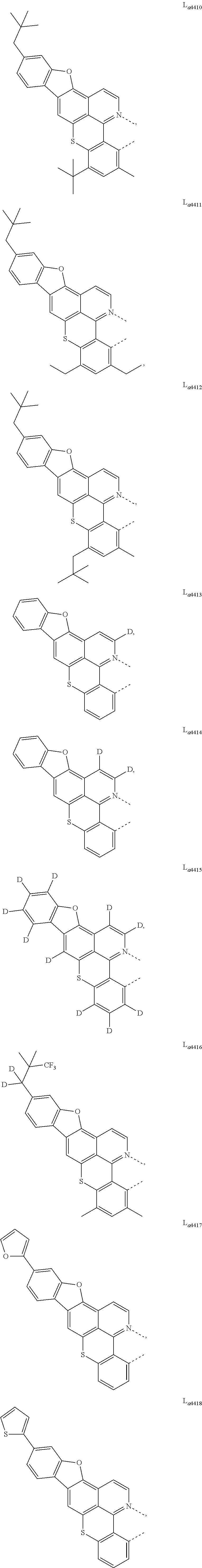 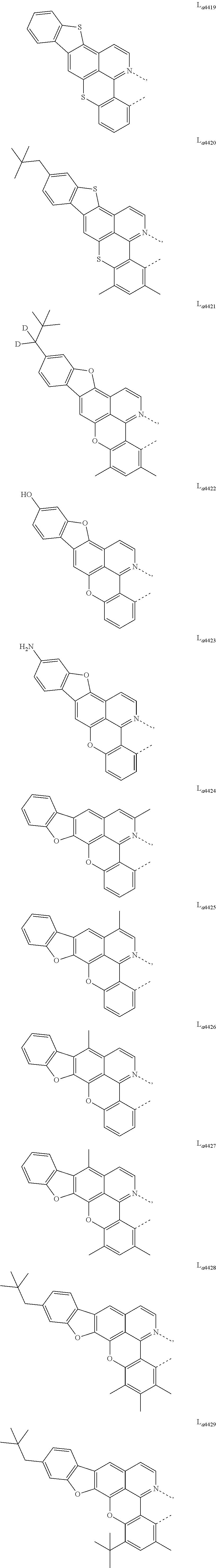 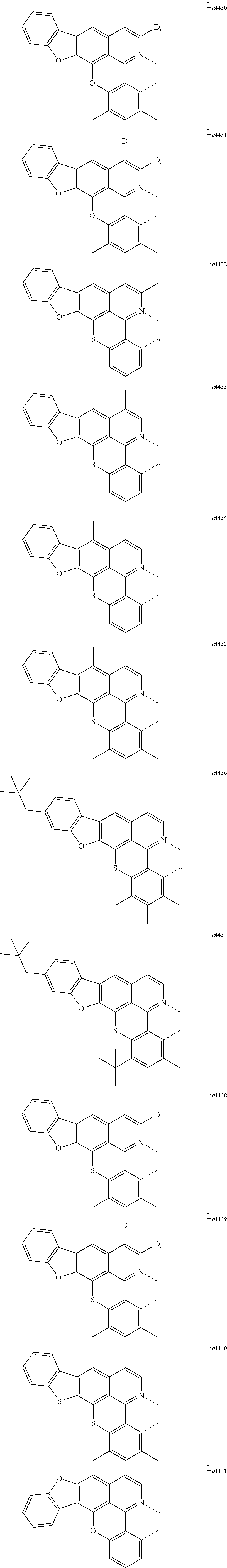 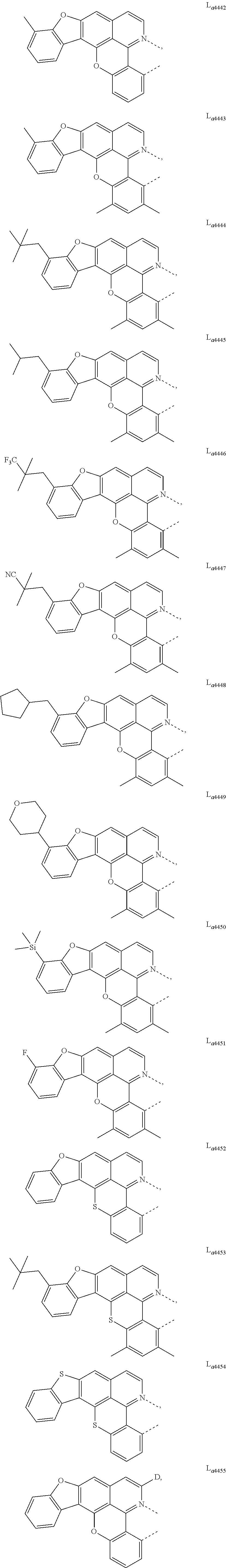 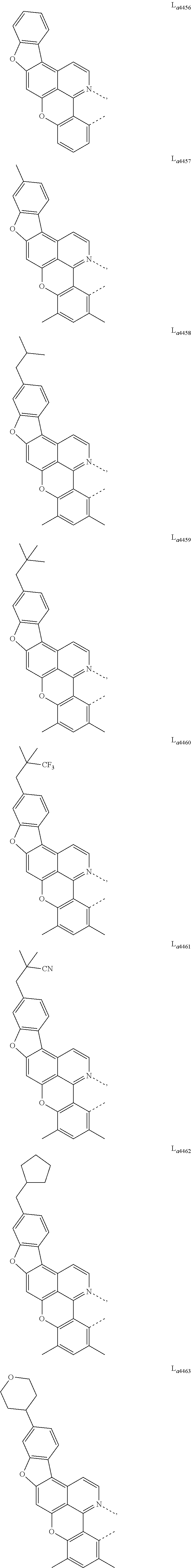 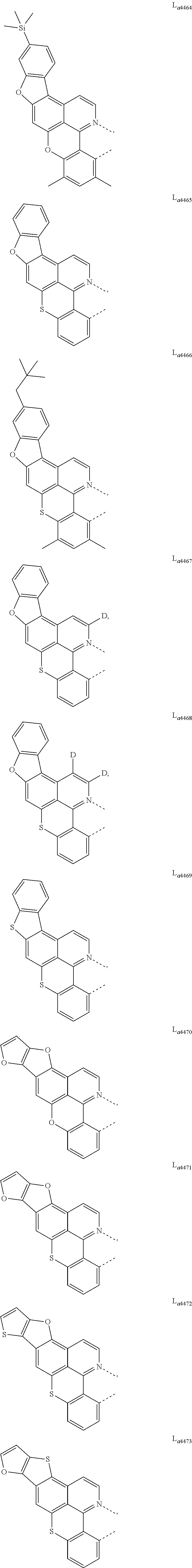 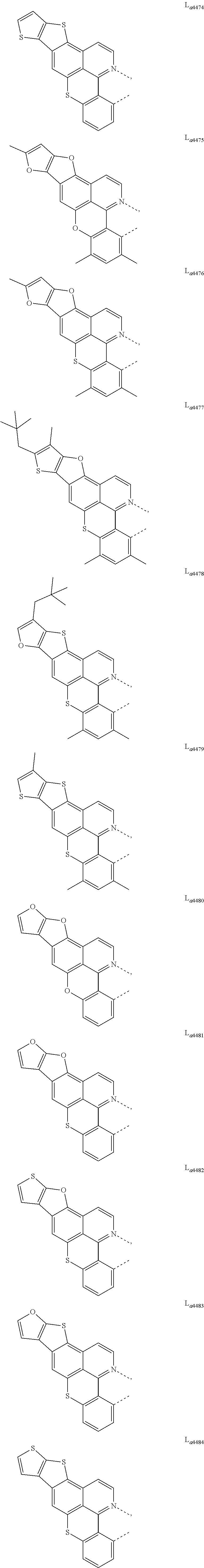 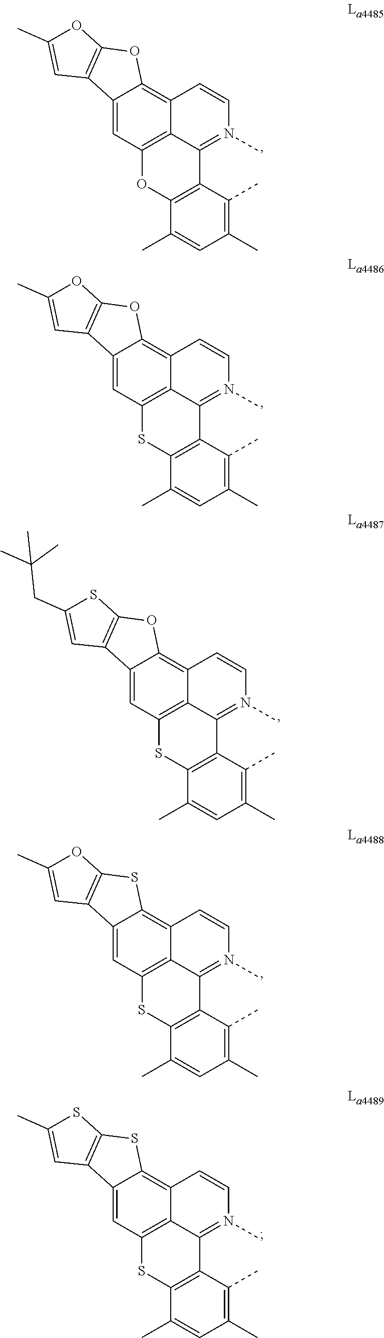
wherein in the structures of Lₐ₁ to Lₐ₄₀₅₆, Q₁ to Q₂₃ represent the following structures, respectively: 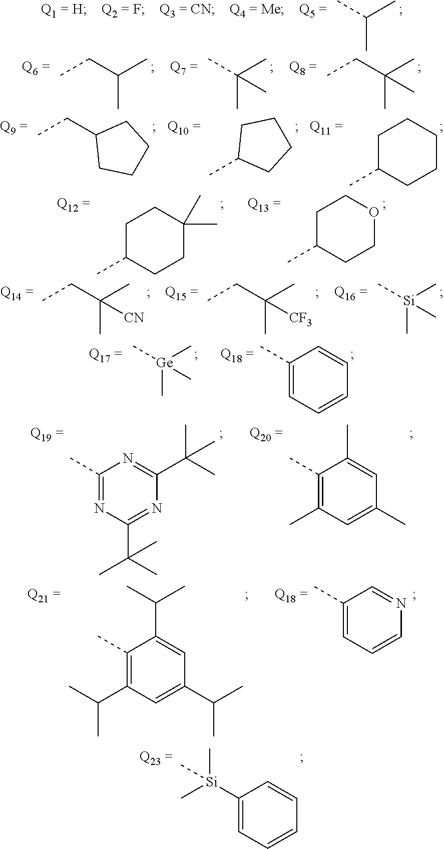
wherein optionally, hydrogens in the structures of Lₐ₁ to Lₐ₄₄₈₉ can be partially or fully substituted with deuterium.

16. The metal complex according to claim 1, wherein the metal complex has a structure of M(Lₐ)ₘ(L_{b})ₙ(L_{c})_{q};
wherein the metal M is selected from a metal with a relative atomic mass greater than 40; Lₐ, L_{b} and L_{c} are a first ligand, a second ligand and a third ligand of the complex, respectively; m is 1, 2 or 3, n is 0, 1 or 2, q is 0, 1 or 2, and m+n+q is equal to an oxidation state of the metal M; when m is greater than 1, a plurality of Lₐ are identical or different; when n is 2, two L_{b} are identical or different; when q is 2, two L_{c} are identical or different;
Lₐ, L_{b} and L_{c} can be optionally joined to form a multidentate ligand;
L_{b} and L_{c} are, at each occurrence identically or differently, selected from the group consisting of the following structures: 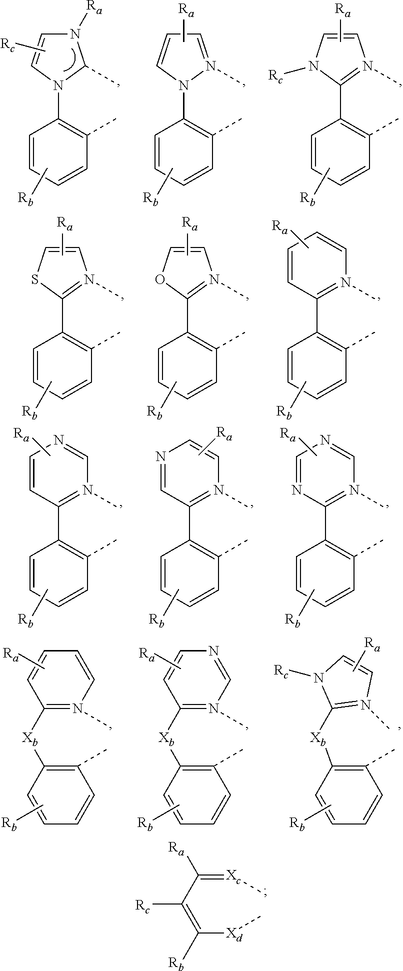
wherein Rₐ, R_{b} and R_{c} represent, at each occurrence identically or differently, mono-substitution, multiple substitutions or non-substitution;
X_{b} is, at each occurrence identically or differently, selected from the group consisting of: O, S, Se, NR_{N1} and CR_{C1}R_{C2};
X_{c} and X_{d} are, at each occurrence identically or differently, selected from the group consisting of: O, S, Se and NR_{N2};
Rₐ, R_{b}, R_{c}, R_{N1}, R_{N2}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₐ, R_{b}, R_{c}, R_{N1}, R_{N2}, R_{C1} and R_{C2} can be optionally joined to form a ring.

17. The metal complex according to claim 16, wherein the metal M is selected from Ir, Rh, Re, Os, Pt, Au or Cu; preferably, the metal M is selected from Ir, Pt or Os; more preferably, the metal M is Ir.

18. The metal complex according to claim 17, wherein L_{b} is, at each occurrence identically or differently, selected from the following structure: 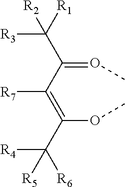
wherein R₁ to R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R₁, R₂, R₃, R₄, R₅, R₆ and R₇ can be optionally joined to form a ring;
preferably, at least one or two of R₁ to R₃ is(are), at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or a combination thereof; and/or at least one or two of R₄ to R₆ is(are), at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or a combination thereof; and
more preferably, at least two of R₁ to R₃ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or a combination thereof, and/or at least two of R₄ to R₆ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or a combination thereof.

19. The metal complex according to claim 16, wherein L_{b} is, at each occurrence identically or differently, selected from the group consisting of the following structures: 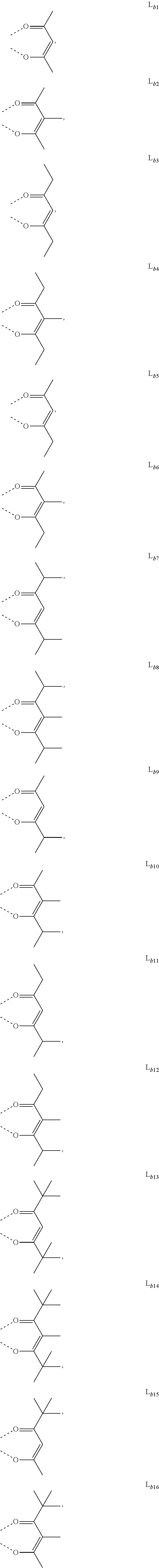 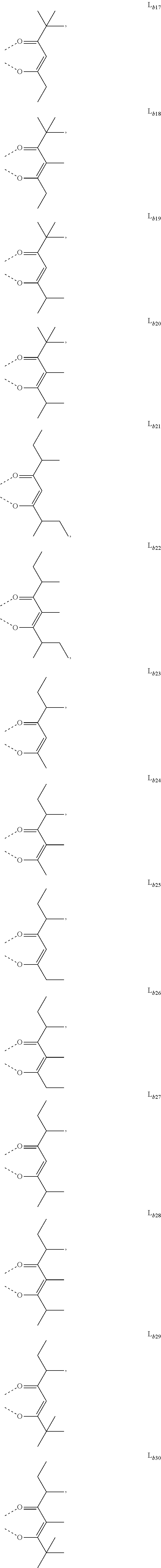 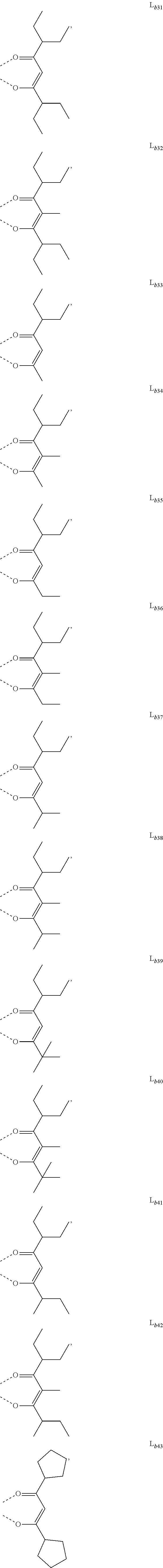 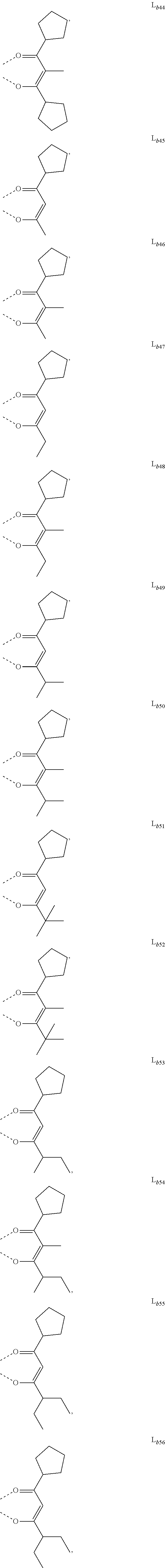 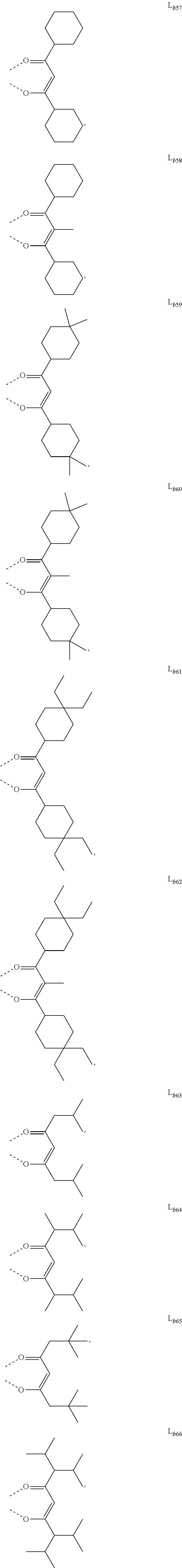 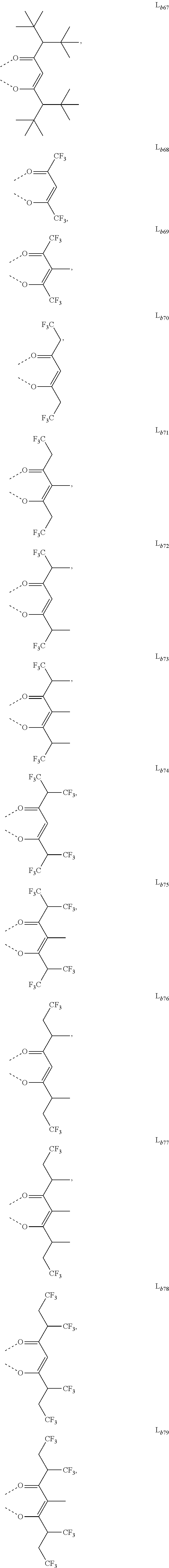 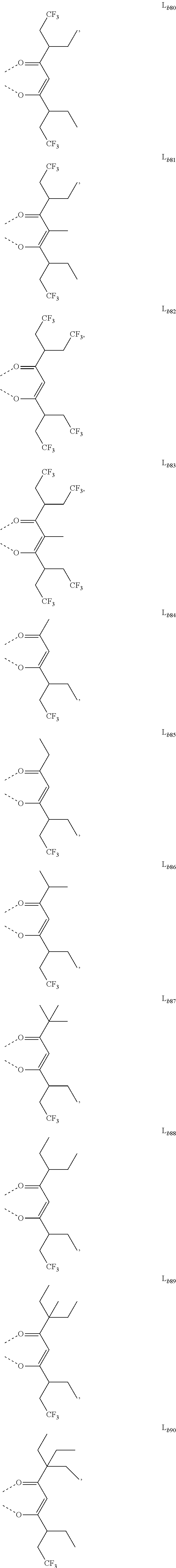 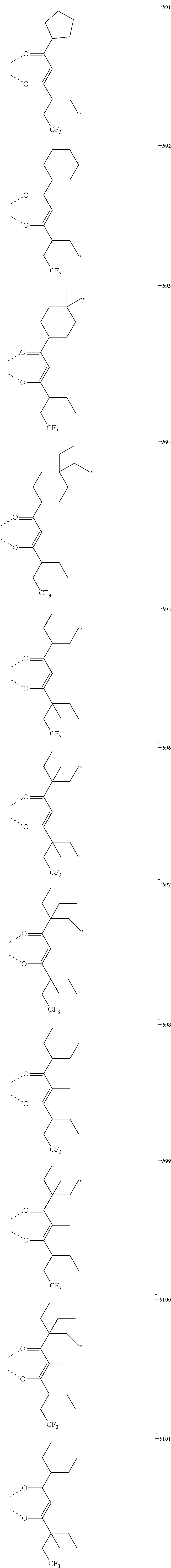 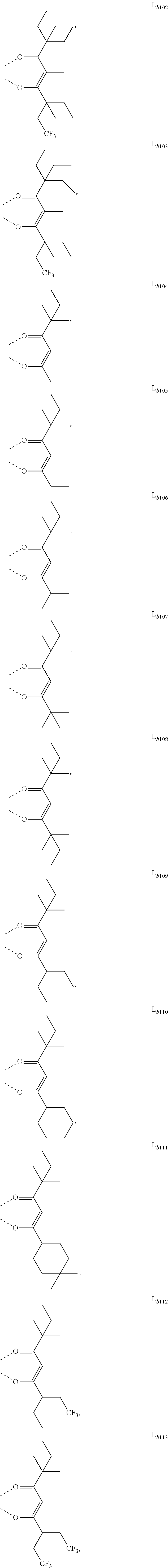 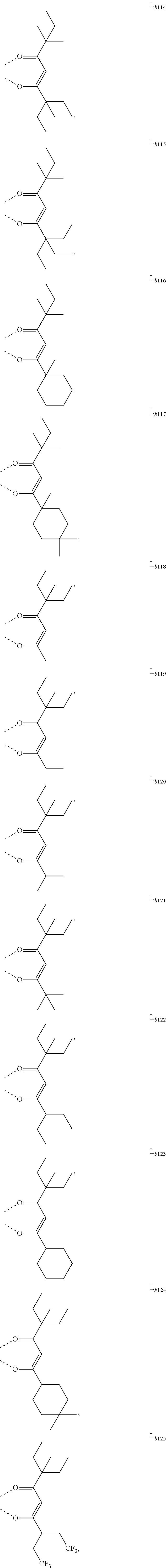 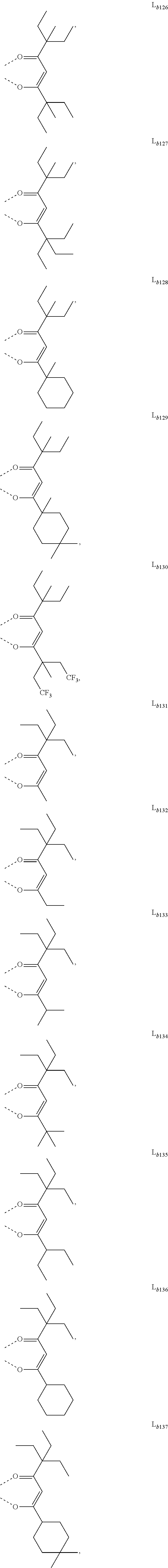 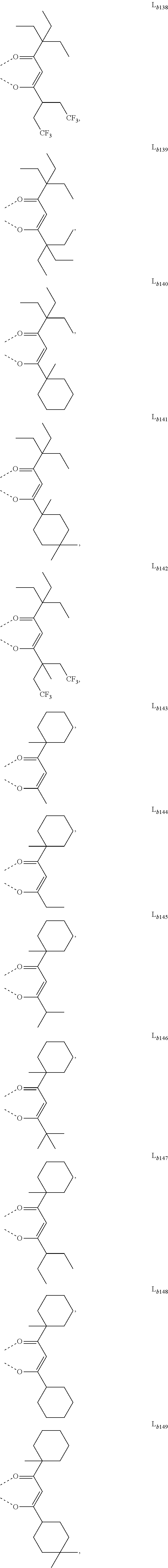 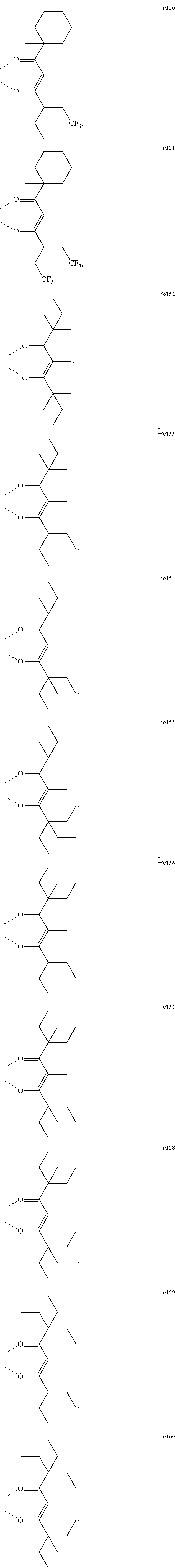 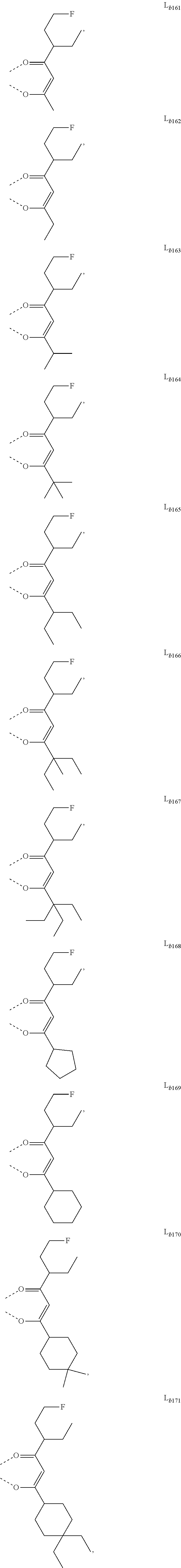 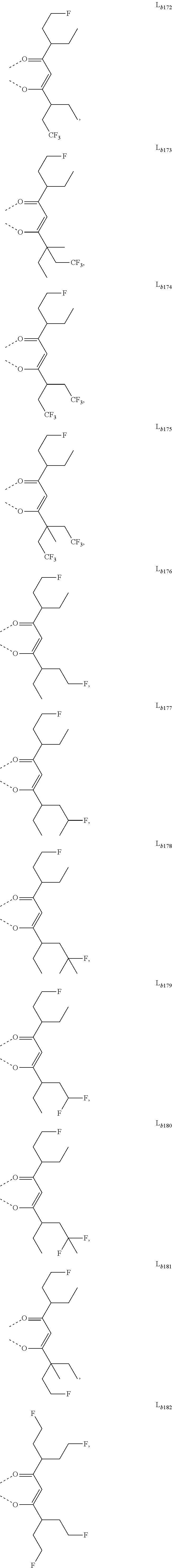 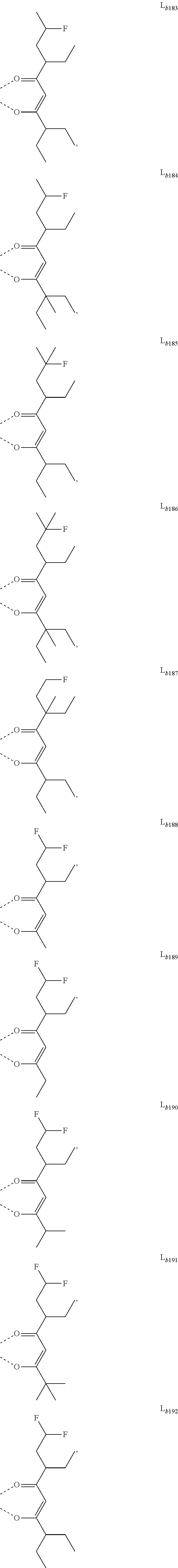 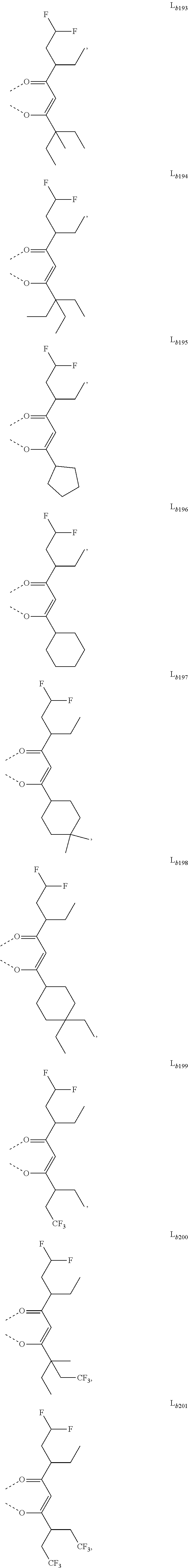 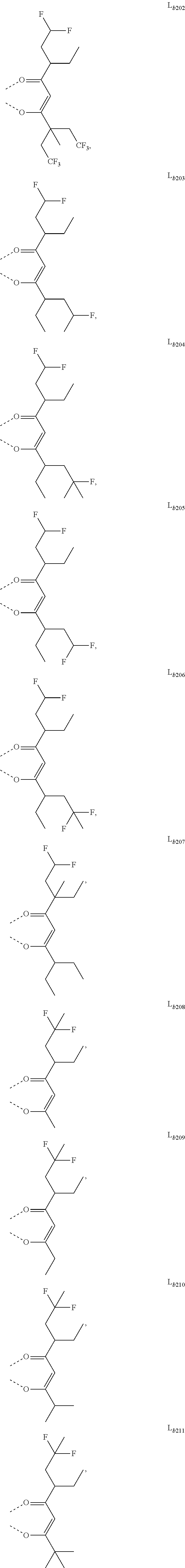 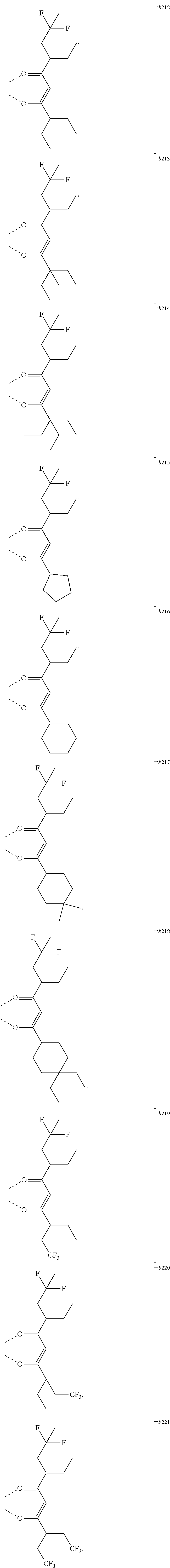 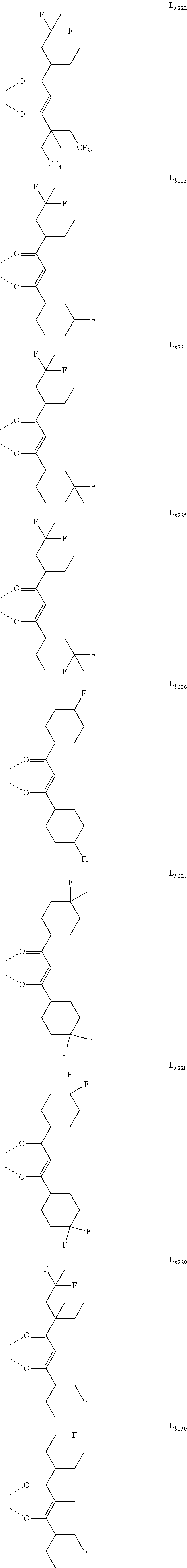 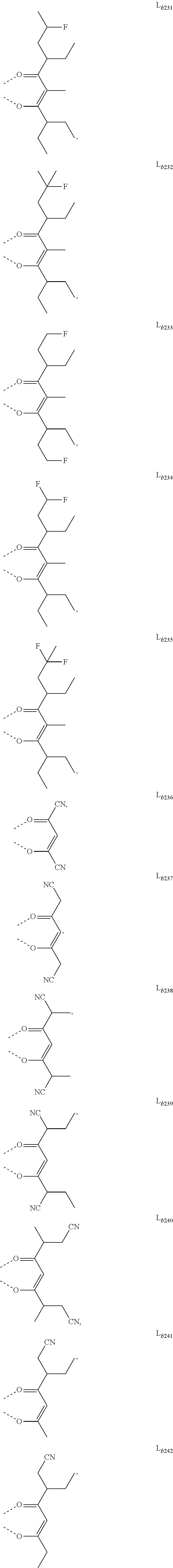 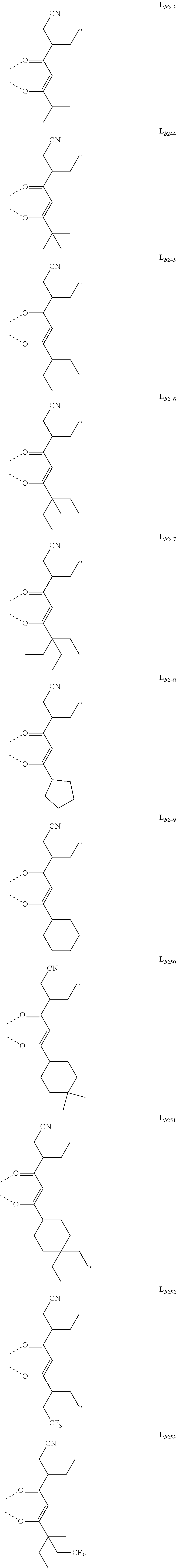 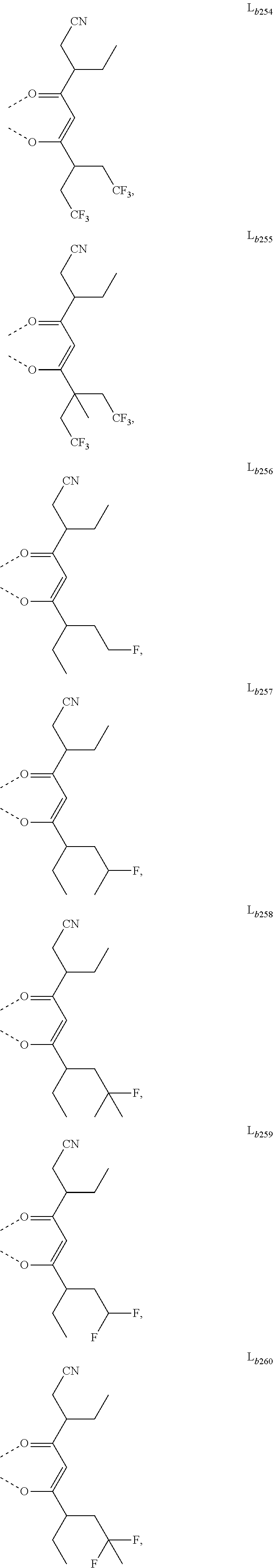 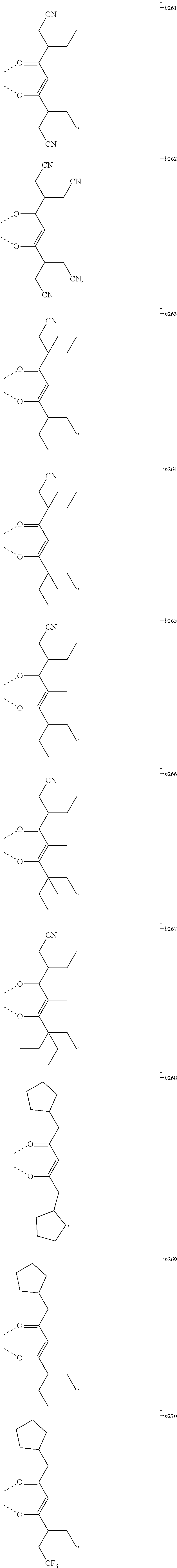 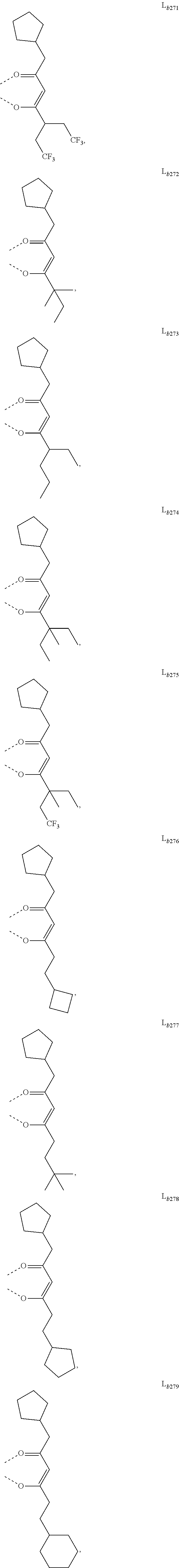 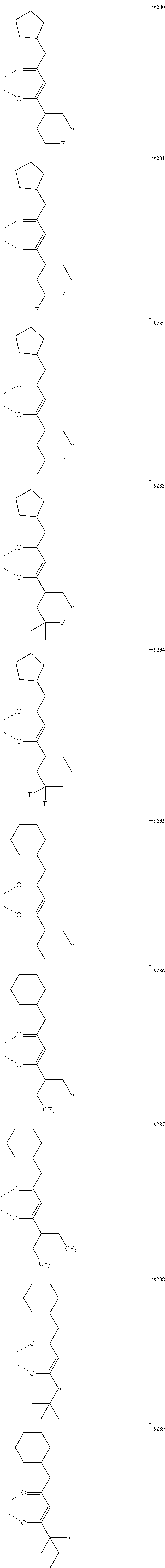 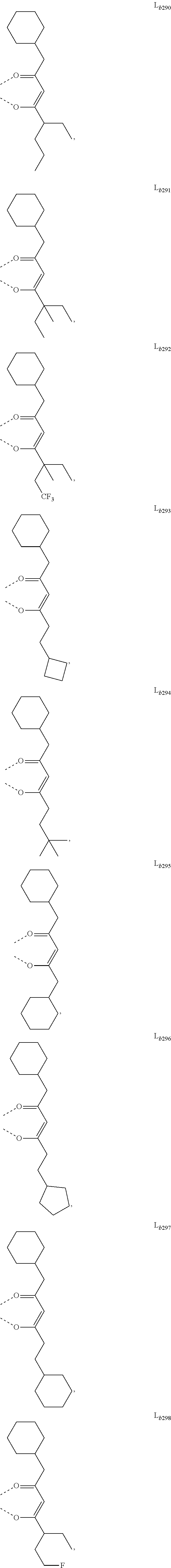 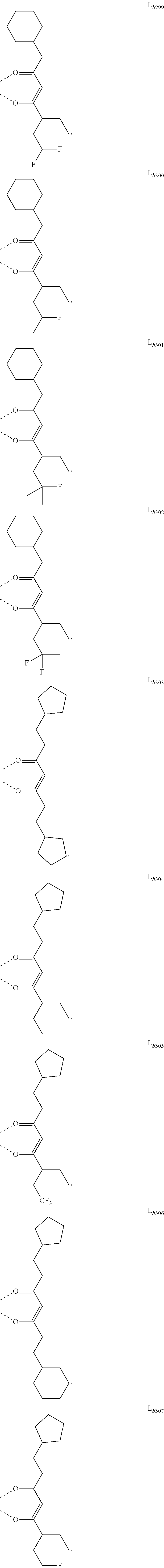 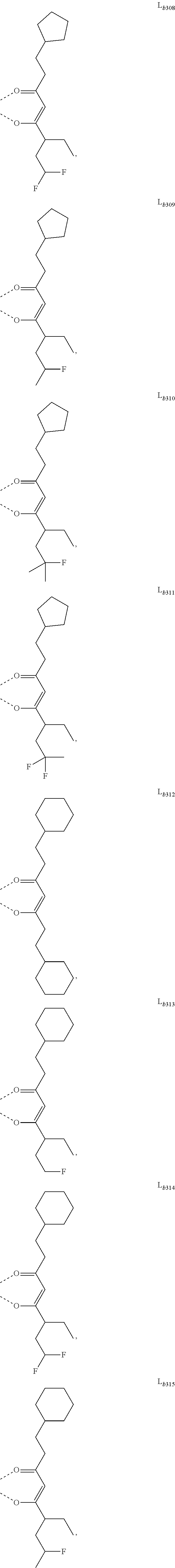 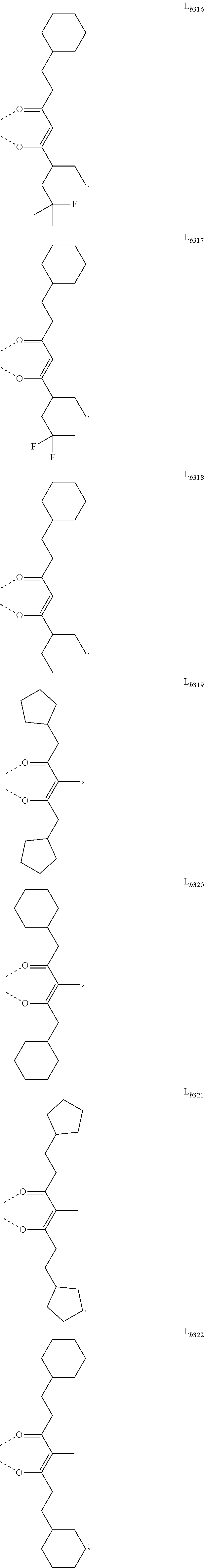
wherein L_{c} is, at each occurrence identically or differently, selected from the group consisting of the following structures:

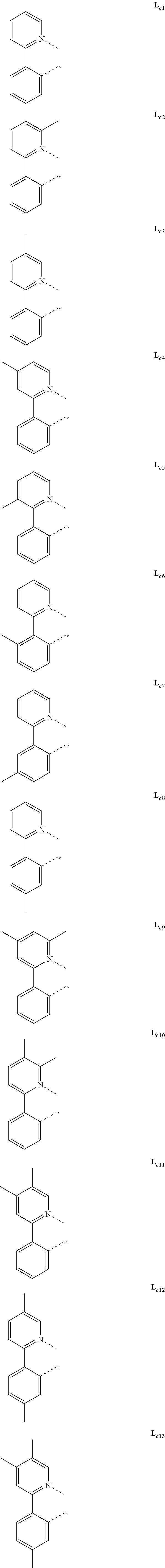

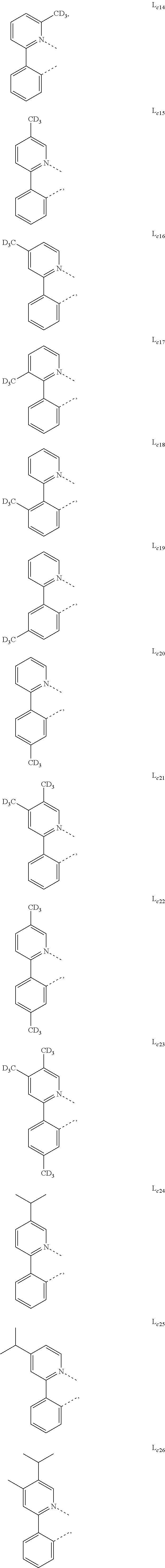

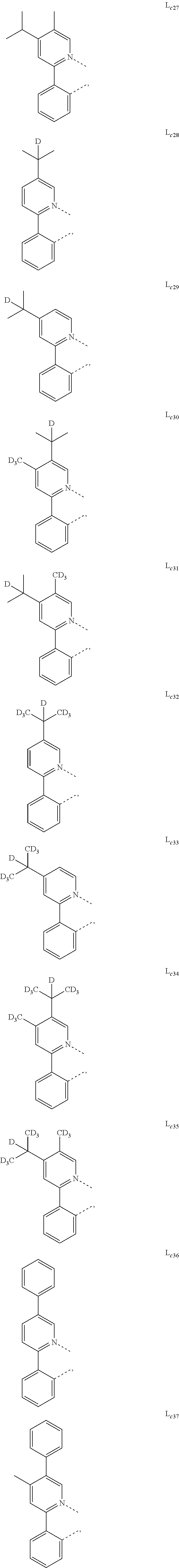

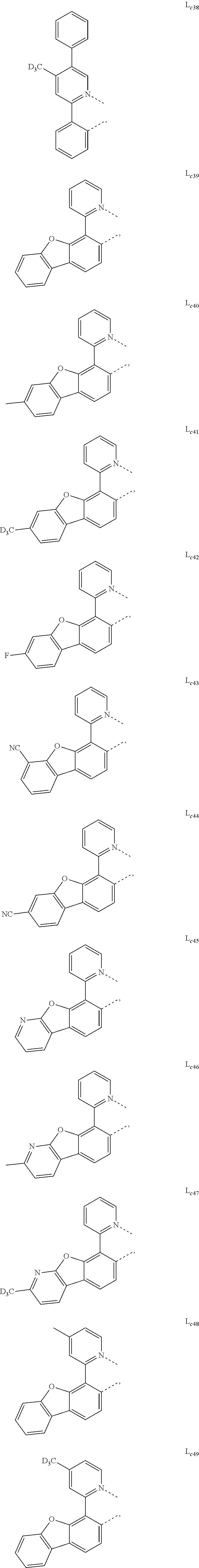

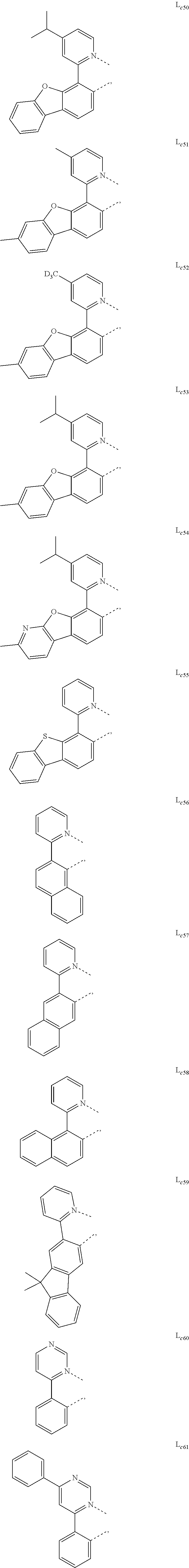

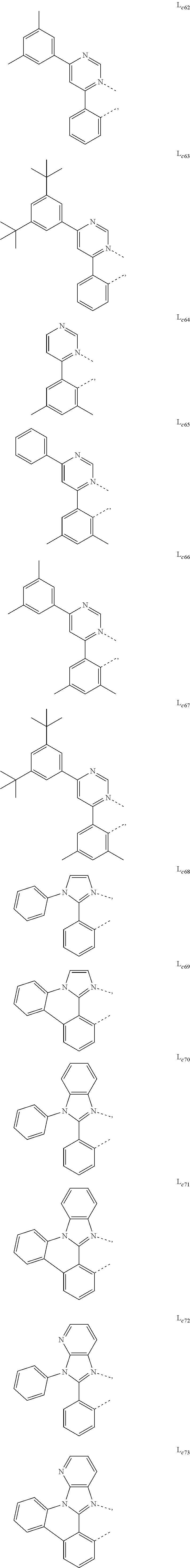

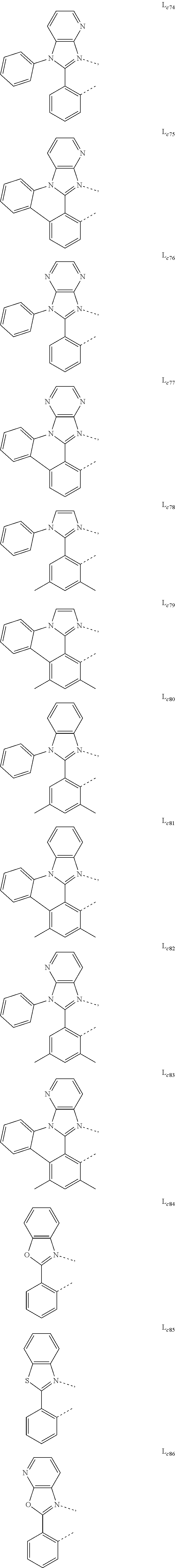

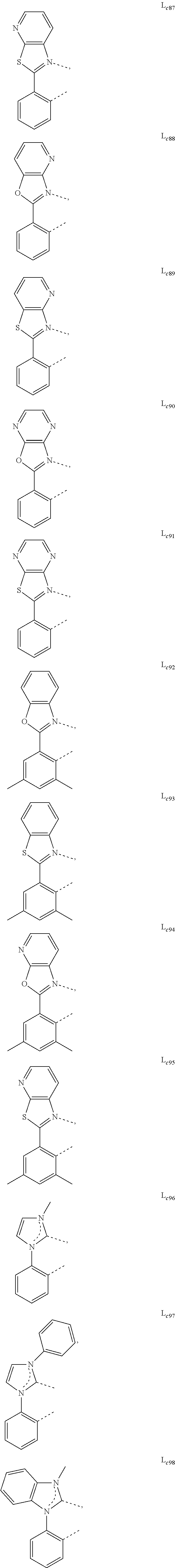

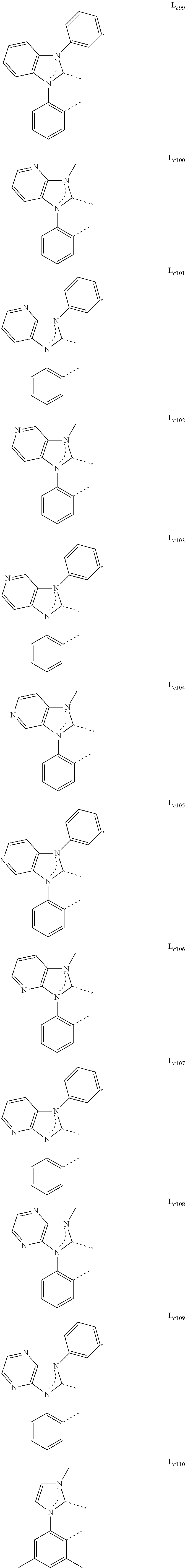

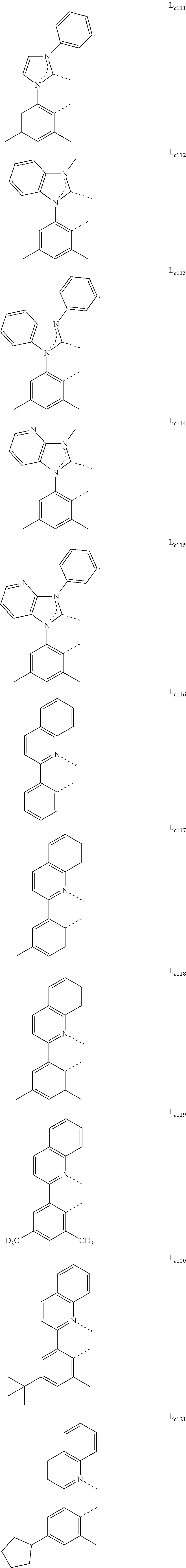

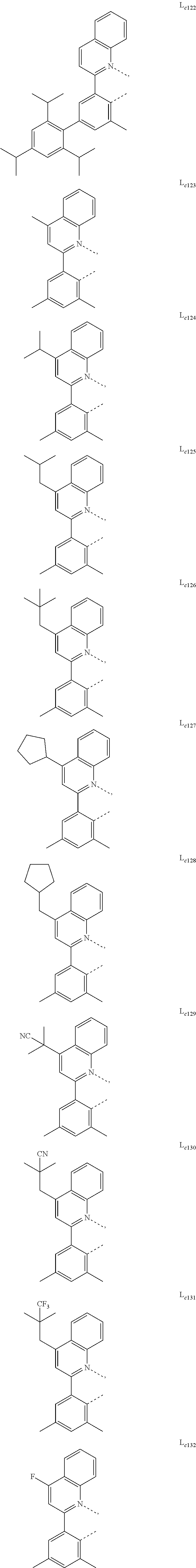

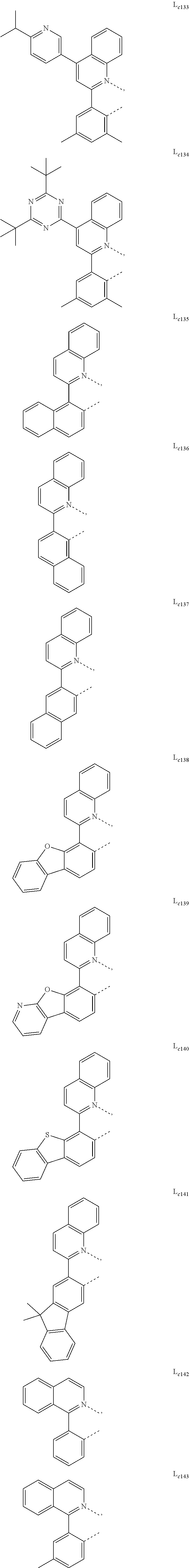

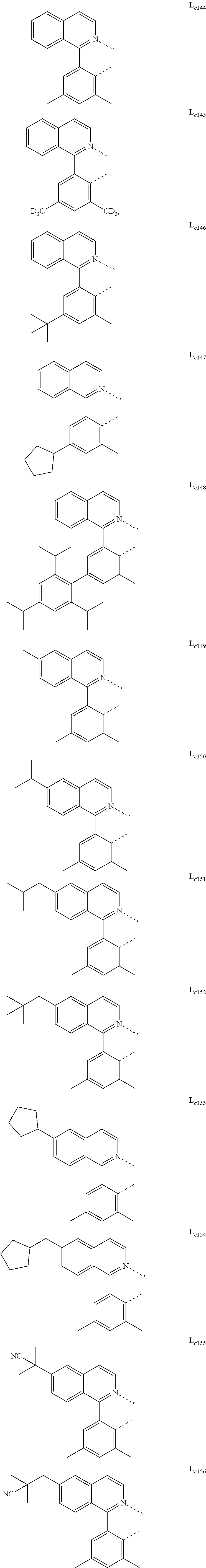

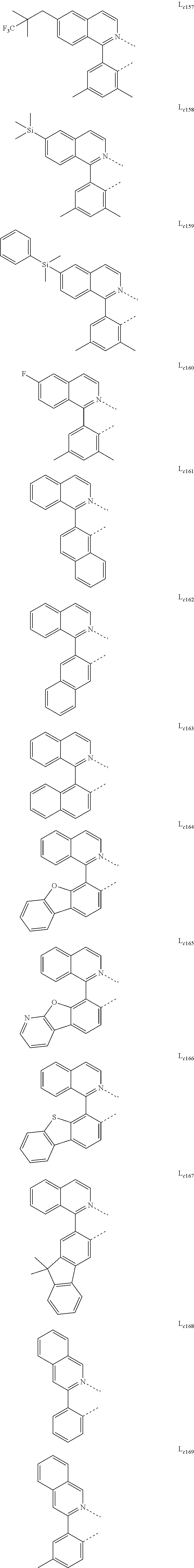

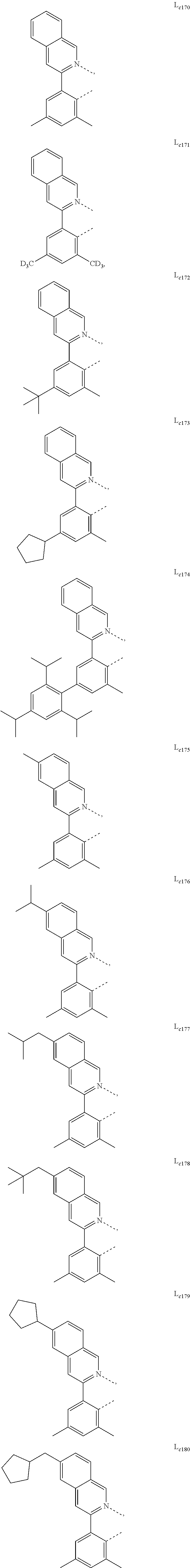

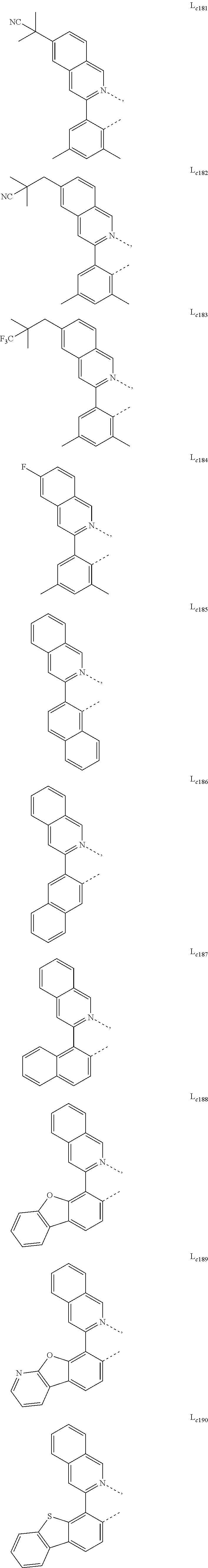

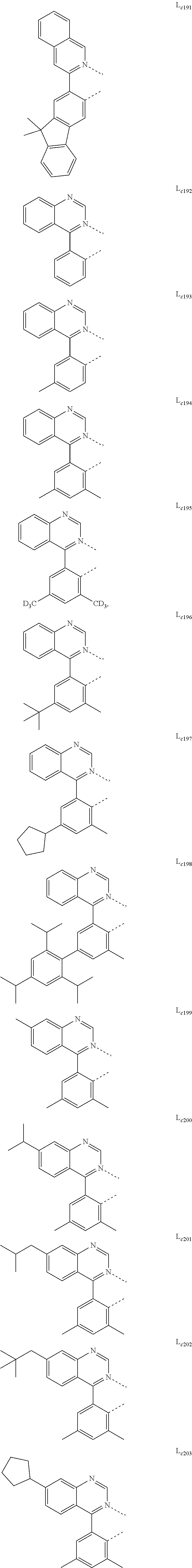

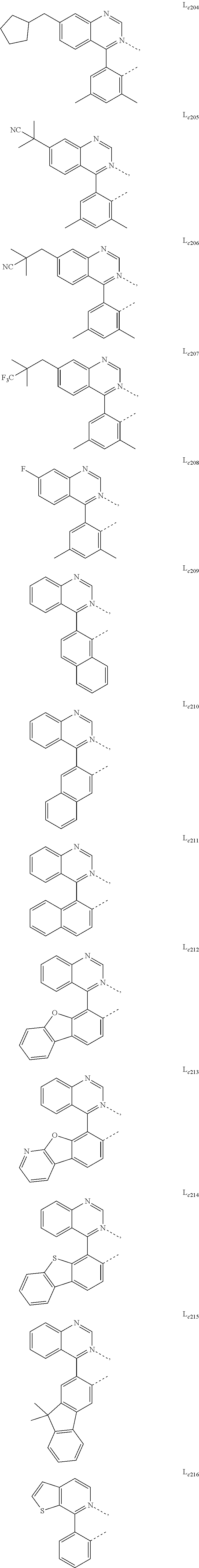

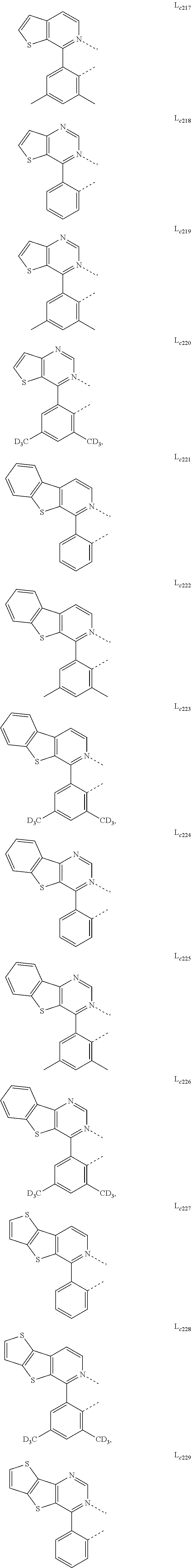

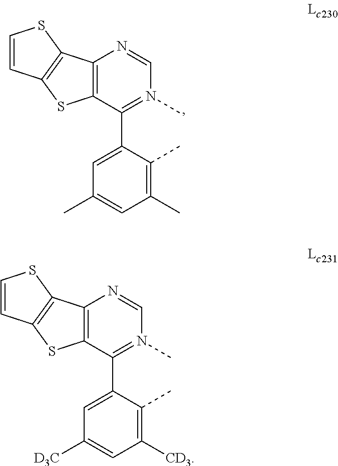

20. The metal complex according to claim 19, wherein the metal complex has a structure of Ir(Lₐ)₂(L_{b}) or Ir(Lₐ)₂(L_{c}) or Ir(Lₐ)(L_{c})₂ or Ir(Lₐ)(L_{b})(L_{c});
wherein when the metal complex has a structure of Ir(Lₐ)₂(L_{b}), Lₐ is, at each occurrence identically or differently, selected from any one or any two of the group consisting of Lₐ₁ to Lₐ₄₄₈₉, and L_{b} is selected from any one of the group consisting of L_{b1} to L_{b322}; when the metal complex has a structure of Ir(Lₐ)₂(L_{c}), Lₐ is, at each occurrence identically or differently, selected from any one or any two of the group consisting of Lₐ₁ to Lₐ₄₄₈₉, and Lₑ is selected from any one of the group consisting of L_{c1} to L_{c231}; when the metal complex has a structure of Ir(Lₐ)(L_{c})₂, Lₐ is selected from any one of the group consisting of Lₐ₁ to Lₐ₄₄₈₉, and L_{c} is, at each occurrence identically or differently, selected from any one or any two of the group consisting of L_{c1} to L_{c231}; when the metal complex has a structure of Ir(Lₐ)(L_{b})(L_{c}), Lₐ is selected from any one of the group consisting of Lₐ₁ to Lₐ₄₄₈₉, L_{b} is selected from any one of the group consisting of L_{b1} to L_{b322}, and L_{c} is selected from any one of the group consisting of L_{c1} to L_{c231}; and
preferably, the metal complex is selected from the group consisting of Compound 1 to Compound 1646;
wherein Compound 1 to Compound 1524 each have a structure of Ir(Lₐ)₂(L_{b}), wherein the two Lₐ are identical, and Lₐ and L_{b} are selected from the structures listed in the following table, respectively:

| Compound | | | Compound | | |
|---|---|---|---|---|---|
| No. | Lₐ | L_{b} | No. | Lₐ | L_{b} |
| 1 | Lₐₗ | L_{b31} | 2 | Lₐ₁₂₂₇ | L_{b31} |
| 3 | Lₐ₄ | L_{b31} | 4 | Lₐ₁₂₂₈ | L_{b31} |
| 5 | Lₐ₈ | L_{b31} | 6 | Lₐ₁₂₃₈ | L_{b31} |
| 7 | Lₐ₁₅ | L_{b31} | 8 | Lₐ₁₂₄₂ | L_{b31} |
| 9 | Lₐ₁₆ | L_{b31} | 10 | Lₐ₁₂₄₆ | L_{b31} |
| 11 | Lₐ₂₆ | L_{b31} | 12 | Lₐ₁₂₄₉ | L_{b31} |
| 13 | Lₐ₃₀ | L_{b31} | 14 | Lₐ₁₂₅₀ | L_{b31} |
| 15 | Lₐ₃₁ | L_{b31} | 16 | Lₐ₁₂₅₁ | L_{b31} |
| 17 | Lₐ₃₇ | L_{b31} | 18 | Lₐ₁₂₆₀ | L_{b31} |
| 19 | Lₐ₃₈ | L_{b31} | 20 | Lₐ₁₂₇₀ | L_{b31} |
| 21 | Lₐ₃₉ | L_{b31} | 22 | Lₐ₁₂₇₁ | L_{b31} |
| 23 | Lₐ₄₀ | L_{b31} | 24 | Lₐ₁₂₇₂ | L_{b31} |
| 25 | Lₐ₄₂ | L_{b31} | 26 | Lₐ₁₂₇₃ | L_{b31} |
| 27 | Lₐ₄₈ | L_{b31} | 28 | Lₐ₁₂₈₆ | L_{b31} |
| 29 | Lₐ₅₂ | L_{b31} | 30 | Lₐ₁₂₈₆ | L_{b31} |
| 31 | Lₐ₅₃ | L_{b31} | 32 | Lₐ₁₂₈₇ | L_{b31} |
| 33 | Lₐ₅₉ | L_{b31} | 34 | Lₐ₁₂₉₁ | L_{b31} |
| 35 | Lₐ₆₀ | L_{b31} | 36 | Lₐ₁₂₉₂ | L_{b31} |
| 37 | Lₐ₆₁ | L_{b31} | 38 | Lₐ₁₂₉₃ | L_{b31} |
| 39 | Lₐ₇₂ | L_{b31} | 40 | Lₐ₁₂₉₄ | L_{b31} |
| 41 | Lₐ₇₄ | L_{b31} | 42 | Lₐ₁₂₉₅ | L_{b31} |
| 43 | Lₐ₈₂ | L_{b31} | 44 | Lₐ₁₃₀₆ | L_{b31} |
| 45 | Lₐ₉₂ | L_{b31} | 46 | Lₐ₁₃₀₈ | L_{b31} |
| 47 | Lₐ₉₅ | L_{b31} | 48 | Lₐ₁₃₁₂ | L_{b31} |
| 49 | Lₐ₉₆ | L_{b31} | 50 | Lₐ₁₃₁₃ | L_{b31} |
| 51 | Lₐ₁₀₄ | L_{b31} | 52 | Lₐ₁₃₁₄ | L_{b31} |
| 53 | Lₐ₁₁₄ | L_{b31} | 54 | Lₐ₁₃₁₅ | L_{b31} |
| 55 | Lₐ₁₁₈ | L_{b31} | 56 | Lₐ₁₃₁₆ | L_{b31} |
| 57 | Lₐ₁₈₀ | L_{b31} | 58 | Lₐ₁₃₁₇ | L_{b31} |
| 59 | Lₐ₁₈₂ | L_{b31} | 60 | Lₐ₁₃₁₈ | L_{b31} |
| 61 | Lₐ₁₈₄ | L_{b31} | 62 | Lₐ₁₃₃₀ | L_{b31} |
| 63 | Lₐ₁₈₈ | L_{b31} | 64 | Lₐ₁₃₃₈ | L_{b31} |
| 65 | Lₐ₂₀₂ | L_{b31} | 66 | Lₐ₁₃₇₄ | L_{b31} |
| 67 | Lₐ₂₀₃ | L_{b31} | 68 | Lₐ₁₃₇₈ | L_{b31} |
| 69 | Lₐ₂₀₆ | L_{b31} | 70 | Lₐ₁₃₇₉ | L_{b31} |
| 71 | Lₐ₂₁₃ | L_{b31} | 72 | Lₐ₁₃₈₀ | L_{b31} |
| 73 | Lₐ₂₁₄ | L_{b31} | 74 | Lₐ₁₃₈₁ | L_{b31} |
| 75 | Lₐ₂₂₈ | L_{b31} | 76 | Lₐ₁₃₈₂ | L_{b31} |
| 77 | Lₐ₂₃₅ | L_{b31} | 78 | Lₐ₁₃₈₃ | L_{b31} |
| 79 | Lₐ₂₃₆ | L_{b31} | 80 | Lₐ₁₃₈₄ | L_{b31} |
| 81 | Lₐ₂₅₀ | L_{b31} | 82 | Lₐ₁₃₉₆ | L_{b31} |
| 83 | Lₐ₂₅₇ | L_{b31} | 84 | Lₐ₁₄₀₂ | L_{b31} |
| 85 | Lₐ₂₅₈ | L_{b31} | 86 | Lₐ₁₄₀₃ | L_{b31} |
| 87 | Lₐ₂₆₈ | L_{b31} | 88 | Lₐ₁₄₀₄ | L_{b31} |
| 89 | Lₐ₂₇₂ | L_{b31} | 90 | Lₐ₁₄₀₅ | L_{b31} |
| 91 | Lₐ₂₇₆ | L_{b31} | 92 | Lₐ₁₄₀₆ | L_{b31} |
| 93 | Lₐ₂₇₉ | L_{b31} | 94 | Lₐ₁₄₁₈ | L_{b31} |
| 95 | L₂₂₈₀ | L_{b31} | 96 | Lₐ₁₄₂₂ | L_{b31} |
| 97 | Lₐ₂₈₁ | L_{b31} | 98 | Lₐ₁₄₂₃ | L_{b31} |
| 99 | Lₐ₂₉₀ | L_{b31} | 100 | Lₐ₁₄₂₄ | L_{b31} |
| 101 | Lₐ₂₉₄ | L_{b31} | 102 | Lₐ₁₄₂₅ | L_{b31} |
| 103 | Lₐ₃₀₀ | L_{b31} | 104 | Lₐ₁₄₂₆ | L_{b31} |
| 105 | Lₐ₃₀₁ | L_{b31} | 106 | Lₐ₁₄₂₇ | L_{b31} |
| 107 | Lₐ₃₀₂ | L_{b31} | 108 | Lₐ₁₄₂₈ | L_{b31} |
| 109 | Lₐ₃₀₃ | L_{b31} | 110 | Lₐ₁₄₄₄ | L_{b31} |
| 111 | Lₐ₃₁₂ | L_{b31} | 112 | Lₐ₁₄₄₅ | L_{b31} |
| 113 | Lₐ₃₁₆ | L_{b31} | 114 | Lₐ₁₄₄₆ | L_{b31} |
| 115 | Lₐ₃₁₇ | L_{b31} | 116 | Lₐ₁₄₄₇ | L_{b31} |
| 117 | Lₐ₃₂₁ | L_{b31} | 118 | Lₐ₁₄₄₈ | L_{b31} |
| 119 | Lₐ₃₂₂ | L_{b31} | 120 | Lₐ₁₄₄₉ | L_{b31} |
| 121 | Lₐ₃₂₃ | L_{b31} | 122 | Lₐ₁₄₅₀ | L_{b31} |
| 123 | Lₐ₃₂₄ | L_{b31} | 124 | Lₐ₁₄₆₃ | L_{b31} |
| 125 | Lₐ₃₂₅ | L_{b31} | 126 | Lₐ₁₄₈₅ | L_{b31} |
| 127 | Lₐ₃₃₆ | L_{b31} | 128 | Lₐ₁₄₈₉ | L_{b31} |
| 129 | Lₐ₃₃₈ | L_{b31} | 130 | Lₐ₁₄₉₀ | L_{b31} |
| 131 | Lₐ₃₄₂ | L_{b31} | 132 | Lₐ₁₄₉₁ | L_{b31} |
| 133 | Lₐ₃₄₃ | L_{b31} | 134 | Lₐ₁₄₉₂ | L_{b31} |
| 135 | Lₐ₃₄₄ | L_{b31} | 136 | Lₐ₁₄₉₃ | L_{b31} |
| 137 | Lₐ₃₄₅ | L_{b31} | 138 | Lₐ₁₄₉₄ | L_{b31} |
| 139 | Lₐ₃₄₆ | L_{b31} | 140 | Lₐ₁₄₉₅ | L_{b31} |
| 141 | Lₐ₃₄₇ | L_{b31} | 142 | Lₐ₁₅₀₇ | L_{b31} |
| 143 | Lₐ₃₄₈ | L_{b31} | 144 | Lₐ₁₅₁₁ | L_{b31} |
| 145 | Lₐ₃₆₀ | L_{b31} | 146 | Lₐ₁₅₁₂ | L_{b31} |
| 147 | Lₐ₃₆₈ | L_{b31} | 148 | Lₐ₁₅₁₃ | L_{b31} |
| 149 | Lₐ₄₀₄ | L_{b31} | 150 | Lₐ₁₅₁₄ | L_{b31} |
| 151 | Lₐ₄₀₈ | L_{b31} | 152 | Lₐ₁₅₁₅ | L_{b31} |
| 153 | Lₐ₄₀₉ | L_{b31} | 154 | Lₐ₁₅₁₆ | L_{b31} |
| 155 | Lₐ₄₁₀ | L_{b31} | 156 | Lₐ₁₅₁₇ | L_{b31} |
| 157 | Lₐ₄₁₁ | L_{b31} | 158 | Lₐ₁₅₂₉ | L_{b31} |
| 159 | Lₐ₄₁₂ | L_{b31} | 160 | Lₐ₁₅₃₇ | L_{b31} |
| 161 | Lₐ₄₁₃ | L_{b31} | 162 | Lₐ₁₆₃₉ | L_{b31} |
| 163 | Lₐ₄₁₄ | L_{b31} | 164 | Lₐ₁₆₈₃ | L_{b31} |
| 165 | Lₐ₄₂₆ | L_{b31} | 166 | Lₐ₁₇₇₁ | L_{b31} |
| 167 | Lₐ₄₃₂ | L_{b31} | 168 | Lₐ₁₈₁₅ | L_{b31} |
| 169 | Lₐ₄₃₃ | L_{b31} | 170 | Lₐ₁₈₂₃ | L_{b31} |
| 171 | Lₐ₄₃₄ | L_{b31} | 172 | Lₐ₁₈₈₁ | L_{b31} |
| 173 | Lₐ₄₃₅ | L_{b31} | 174 | Lₐ₁₈₈₉ | L_{b31} |
| 175 | Lₐ₄₃₆ | L_{b31} | 176 | Lₐ₁₉₀₃ | L_{b31} |
| 177 | Lₐ₄₄₈ | L_{b31} | 178 | Lₐ₁₉₁₀ | L_{b31} |
| 179 | Lₐ₄₅₂ | L_{b31} | 180 | Lₐ₁₉₁₁ | L_{b31} |
| 181 | Lₐ₄₅₃ | L_{b31} | 182 | Lₐ₁₉₃₃ | L_{b31} |
| 183 | Lₐ₄₅₄ | L_{b31} | 184 | Lₐ₁₉₄₈ | L_{b31} |
| 185 | Lₐ₄₅₅ | L_{b31} | 186 | Lₐ₁₉₇₀ | L_{b31} |
| 187 | Lₐ₄₅₆ | L_{b31} | 188 | Lₐ₁₉₉₂ | L_{b31} |
| 189 | Lₐ₄₅₇ | L_{b31} | 190 | Lₐ₂₀₁₄ | L_{b31} |
| 191 | Lₐ₄₅₈ | L_{b31} | 192 | Lₐ₂₀₃₂ | L_{b31} |
| 193 | Lₐ₄₇₄ | L_{b31} | 194 | Lₐ₂₀₃₆ | L_{b31} |
| 195 | Lₐ₄₇₅ | L_{b31} | 196 | Lₐ₂₀₅₄ | L_{b31} |
| 197 | Lₐ₄₇₆ | L_{b31} | 198 | Lₐ₂₀₅₈ | L_{b31} |
| 199 | Lₐ₄₇₇ | L_{b31} | 200 | Lₐ₂₀₉₈ | L_{b31} |
| 201 | Lₐ₄₇₈ | L_{b31} | 202 | Lₐ₂₁₀₂ | L_{b31} |
| 203 | Lₐ₄₇₉ | L_{b31} | 204 | Lₐ₂₁₁₀ | L_{b31} |
| 205 | Lₐ₄₈₀ | L_{b31} | 206 | Lₐ₂₁₂₀ | L_{b31} |
| 207 | Lₐ₄₉₃ | L_{b31} | 208 | Lₐ₂₁₂₄ | L_{b31} |
| 209 | Lₐ₅₁₅ | L_{b31} | 210 | Lₐ₂₂₈₆ | L_{b31} |
| 211 | Lₐ₅₁₉ | L_{b31} | 212 | Lₐ₂₃₀₀ | L_{b31} |
| 213 | Lₐ₅₂₀ | L_{b31} | 214 | Lₐ₂₃₀₈ | L_{b31} |
| 215 | Lₐ₅₂₁ | L_{b31} | 216 | Lₐ₂₃₁₈ | L_{b31} |
| 217 | Lₐ₅₂₂ | L_{b31} | 218 | Lₐ₂₃₃₀ | L_{b31} |
| 219 | Lₐ₅₂₃ | L_{b31} | 220 | Lₐ₂₃₄₄ | L_{b31} |
| 221 | Lₐ₅₂₄ | L_{b31} | 222 | Lₐ₂₃₅₂ | L_{b31} |
| 223 | Lₐ₅₂₅ | L_{b31} | 224 | Lₐ₂₄₀₆ | L_{b31} |
| 225 | Lₐ₅₃₇ | L_{b31} | 226 | Lₐ₂₄₁₀ | L_{b31} |
| 227 | Lₐ₅₄₁ | L_{b31} | 228 | Lₐ₂₄₁₄ | L_{b31} |
| 229 | L₂₅₄₂ | L_{b31} | 230 | Lₐ₂₄₁₅ | L_{b31} |
| 231 | Lₐ₅₄₃ | L_{b31} | 232 | Lₐ₂₄₁₆ | L_{b31} |
| 233 | Lₐ₅₄₄ | L_{b31} | 234 | Lₐ₂₄₁₇ | L_{b31} |
| 235 | Lₐ₅₄₅ | L_{b31} | 236 | Lₐ₂₄₁₈ | L_{b31} |
| 237 | Lₐ₅₄₆ | L_{b31} | 238 | Lₐ₂₄₁₉ | L_{b31} |
| 239 | Lₐ₅₄₇ | L_{b31} | 240 | Lₐ₂₄₂₀ | L_{b31} |
| 241 | Lₐ₅₅₉ | L_{b31} | 242 | Lₐ₂₄₃₂ | L_{b31} |
| 243 | Lₐ₅₉₇ | L_{b31} | 244 | Lₐ₂₄₃₆ | L_{b31} |
| 245 | Lₐ₅₉₉ | L_{b31} | 246 | Lₐ₂₄₃₇ | L_{b31} |
| 247 | Lₐ₆₀₁ | L_{b31} | 248 | Lₐ₂₄₃₈ | L_{b31} |
| 249 | Lₐ₆₀₅ | L_{b31} | 250 | Lₐ₂₄₃₉ | L_{b31} |
| 251 | Lₐ₆₁₉ | L_{b31} | 252 | Lₐ₂₄₄₀ | L_{b31} |
| 253 | Lₐ₆₂₀ | L_{b31} | 254 | Lₐ₂₄₄₁ | L_{b31} |
| 255 | Lₐ₆₂₃ | L_{b31} | 256 | Lₐ₂₄₄₂ | L_{b31} |
| 257 | Lₐ₆₃₀ | L_{b31} | 258 | Lₐ₂₄₅₄ | L_{b31} |
| 259 | Lₐ₆₃₁ | L_{b31} | 260 | Lₐ₂₄₆₂ | L_{b31} |
| 261 | Lₐ₆₄₅ | L_{b31} | 262 | Lₐ₂₈₂₉ | L_{b31} |
| 263 | Lₐ₆₅₂ | L_{b31} | 264 | Lₐ₂₈₃₇ | L_{b31} |
| 265 | Lₐ₆₅₃ | L_{b88} | 266 | Lₐ₂₈₈₁ | L_{b88} |
| 267 | Lₐ₆₆₇ | L_{b88} | 268 | Lₐ₂₉₃₅ | L_{b88} |
| 269 | Lₐ₆₇₄ | L_{b88} | 270 | Lₐ₂₉₃₉ | L_{b88} |
| 271 | Lₐ₆₇₅ | L_{b88} | 272 | Lₐ₂₉₄₇ | L_{b88} |
| 273 | Lₐ₆₈₅ | L_{b88} | 274 | Lₐ₂₉₆₁ | L_{b88} |
| 275 | Lₐ₆₈₉ | L_{b88} | 276 | Lₐ₂₉₆₉ | L_{b88} |
| 277 | Lₐ₆₉₃ | L_{b88} | 278 | Lₐ₂₉₈₃ | L_{b88} |
| 279 | Lₐ₆₉₆ | L_{b88} | 280 | Lₐ₂₉₉₁ | L_{b88} |
| 281 | Lₐ₆₉₇ | L_{b88} | 282 | Lₐ₃₀₀₆ | L_{b88} |
| 283 | Lₐ₆₉₈ | L_{b88} | 284 | Lₐ₃₀₂₈ | L_{b88} |
| 285 | Lₐ₇₀₇ | L_{b88} | 286 | Lₐ₃₀₅₀ | L_{b88} |
| 287 | Lₐ₇₁₁ | L_{b88} | 288 | Lₐ₃₀₇₂ | L_{b88} |
| 289 | Lₐ₇₁₇ | L_{b88} | 290 | Lₐ₃₀₉₀ | L_{b88} |
| 291 | Lₐ₇₁₈ | L_{b88} | 292 | Lₐ₃₀₉₄ | L_{b88} |
| 293 | Lₐ₇₁₉ | L_{b88} | 294 | Lₐ₃₁₁₂ | L_{b88} |
| 295 | Lₐ₇₂₀ | L_{b88} | 296 | Lₐ₃₁₁₆ | L_{b88} |
| 297 | Lₐ₇₂₉ | L_{b88} | 298 | Lₐ₃₁₅₆ | L_{b88} |
| 299 | Lₐ₇₃₃ | L_{b88} | 300 | Lₐ₃₁₆₀ | L_{b88} |
| 301 | Lₐ₇₃₄ | L_{b88} | 302 | Lₐ₃₁₆₈ | L_{b88} |
| 303 | Lₐ₇₃₈ | L_{b88} | 304 | Lₐ₃₁₈₂ | L_{b88} |
| 305 | Lₐ₇₃₉ | L_{b88} | 306 | Lₐ₃₁₉₀ | L_{b88} |
| 307 | Lₐ₇₄₀ | L_{b88} | 308 | Lₐ₃₁₉₁ | L_{b88} |
| 309 | Lₐ₇₄₁ | L_{b88} | 310 | Lₐ₃₃₄₄ | L_{b88} |
| 311 | Lₐ₇₄₂ | L_{b88} | 312 | Lₐ₃₃₅₈ | L_{b88} |
| 313 | Lₐ₇₅₃ | L_{b88} | 314 | Lₐ₃₃₆₆ | L_{b88} |
| 315 | Lₐ₇₅₅ | L_{b88} | 316 | Lₐ₃₃₈₈ | L_{b88} |
| 317 | Lₐ₇₅₉ | L_{b88} | 318 | Lₐ₃₄₁₀ | L_{b88} |
| 319 | Lₐ₇₆₀ | L_{b88} | 320 | Lₐ₃₄₆₄ | L_{b88} |
| 321 | Lₐ₇₆₁ | L_{b88} | 322 | Lₐ₃₄₆₈ | L_{b88} |
| 323 | Lₐ₇₆₂ | L_{b88} | 324 | Lₐ₃₄₇₆ | L_{b88} |
| 325 | Lₐ₇₆₃ | L_{b88} | 326 | Lₐ₃₄₉₀ | L_{b88} |
| 327 | Lₐ₇₆₄ | L_{b88} | 328 | Lₐ₃₄₉₈ | L_{b88} |
| 329 | Lₐ₇₆₅ | L_{b88} | 330 | Lₐ₃₅₁₂ | L_{b88} |
| 331 | Lₐ₇₇₇ | L_{b88} | 332 | Lₐ₃₅₂₀ | L_{b88} |
| 333 | Lₐ₇₈₅ | L_{b88} | 334 | Lₐ₃₅₃₅ | L_{b88} |
| 335 | Lₐ₈₂₁ | L_{b88} | 336 | Lₐ₃₅₅₇ | L_{b88} |
| 337 | Lₐ₈₂₅ | L_{b88} | 338 | Lₐ₃₅₇₉ | L_{b88} |
| 339 | Lₐ₈₂₆ | L_{b88} | 340 | Lₐ₃₆₀₁ | L_{b88} |
| 341 | Lₐ₈₂₇ | L_{b88} | 342 | Lₐ₃₆₄₁ | L_{b88} |
| 343 | Lₐ₈₂₈ | L_{b88} | 344 | Lₐ₃₆₈₅ | L_{b88} |
| 345 | Lₐ₈₂₉ | L_{b88} | 346 | Lₐ₃₈₇₃ | L_{b88} |
| 347 | Lₐ₈₃₀ | L_{b88} | 348 | Lₐ₃₈₈₇ | L_{b88} |
| 349 | Lₐ₈₃₁ | L_{b88} | 350 | Lₐ₃₈₉₅ | L_{b88} |
| 351 | Lₐ₈₄₃ | L_{b88} | 352 | Lₐ₃₉₀₅ | L_{b88} |
| 353 | Lₐ₈₄₉ | L_{b88} | 354 | Lₐ₃₉₁₇ | L_{b88} |
| 355 | Lₐ₈₅₀ | L_{b88} | 356 | Lₐ₃₉₃₉ | L_{b88} |
| 357 | Lₐ₈₅₁ | L_{b88} | 358 | Lₐ₃₉₉₃ | L_{b88} |
| 359 | Lₐ₈₅₂ | L_{b88} | 360 | Lₐ₃₉₉₇ | L_{b88} |
| 361 | Lₐ₈₅₃ | L_{b88} | 362 | Lₐ₄₀₀₁ | L_{b88} |
| 363 | Lₐ₈₆₅ | L_{b88} | 364 | Lₐ₄₀₀₂ | L_{b88} |
| 365 | Lₐ₈₆₉ | L_{b88} | 366 | Lₐ₄₀₀₃ | L_{b88} |
| 367 | Lₐ₈₇₀ | L_{b88} | 368 | Lₐ₄₀₀₄ | L_{b88} |
| 369 | Lₐ₈₇₁ | L_{b88} | 370 | Lₐ₄₀₀₅ | L_{b88} |
| 371 | Lₐ₈₇₂ | L_{b88} | 372 | Lₐ₄₀₀₆ | L_{b88} |
| 373 | Lₐ₈₇₃ | L_{b88} | 374 | Lₐ₄₀₀₇ | L_{b88} |
| 375 | Lₐ₈₇₄ | L_{b88} | 376 | Lₐ₄₀₁₉ | L_{b88} |
| 377 | Lₐ₈₇₅ | L_{b88} | 378 | Lₐ₄₀₂₃ | L_{b88} |
| 379 | Lₐ₈₉₁ | L_{b88} | 380 | Lₐ₄₀₂₄ | L_{b88} |
| 381 | Lₐ₈₉₂ | L_{b88} | 382 | Lₐ₄₀₂₅ | L_{b88} |
| 383 | Lₐ₈₉₃ | L_{b88} | 384 | Lₐ₄₀₂₆ | L_{b88} |
| 385 | Lₐ₈₉₄ | L_{b88} | 386 | Lₐ₄₀₂₇ | L_{b88} |
| 387 | Lₐ₈₉₅ | L_{b88} | 388 | Lₐ₄₀₂₈ | L_{b88} |
| 389 | Lₐ₈₉₆ | L_{b88} | 390 | Lₐ₄₀₂₉ | L_{b88} |
| 391 | Lₐ₈₉₇ | L_{b88} | 392 | Lₐ₄₀₄₁ | L_{b88} |
| 393 | Lₐ₉₁₀ | L_{b88} | 394 | Lₐ₄₀₄₉ | L_{b88} |
| 395 | L₂₉₃₂ | L_{b88} | 396 | Lₐ₄₀₆₁ | L_{b88} |
| 397 | Lₐ₉₃₆ | L_{b88} | 398 | Lₐ₄₀₆₈ | L_{b88} |
| 399 | Lₐ₉₃₇ | L_{b88} | 400 | Lₐ₄₀₇₀ | L_{b88} |
| 401 | Lₐ₉₃₈ | L_{b88} | 402 | Lₐ₄₀₇₁ | L_{b88} |
| 403 | Lₐ₉₃₉ | L_{b88} | 404 | Lₐ₄₀₇₃ | L_{b88} |
| 405 | Lₐ₉₄₀ | L_{b88} | 406 | Lₐ₄₀₇₄ | L_{b88} |
| 407 | Lₐ₉₄₁ | L_{b88} | 408 | Lₐ₄₀₈₄ | L_{b88} |
| 409 | Lₐ₉₄₂ | L_{b88} | 410 | Lₐ₄₁₀₉ | L_{b88} |
| 411 | Lₐ₉₅₄ | L_{b88} | 412 | Lₐ₄₁₁₆ | L_{b88} |
| 413 | Lₐ₉₅₈ | L_{b88} | 414 | Lₐ₄₁₂₉ | L_{b88} |
| 415 | Lₐ₉₅₉ | L_{b88} | 416 | Lₐ₄₁₅₁ | L_{b88} |
| 417 | Lₐ₉₆₀ | L_{b88} | 418 | Lₐ₄₁₅₂ | L_{b88} |
| 419 | Lₐ₉₆₁ | L_{b88} | 420 | Lₐ₄₁₅₆ | L_{b88} |
| 421 | Lₐ₉₆₂ | L_{b88} | 422 | Lₐ₄₁₆₀ | L_{b88} |
| 423 | Lₐ₉₆₃ | L_{b88} | 424 | Lₐ₄₁₇₄ | L_{b88} |
| 425 | Lₐ₉₆₄ | L_{b88} | 426 | Lₐ₄₁₈₈ | L_{b88} |
| 427 | Lₐ₉₇₁ | L_{b88} | 428 | Lₐ₄₉₁ | L_{b88} |
| 429 | Lₐ₉₇₄ | L_{b88} | 430 | Lₐ₄₂₀₄ | L_{b88} |
| 431 | Lₐ₉₇₈ | L_{b88} | 432 | Lₐ₄₂₁₈ | L_{b88} |
| 433 | Lₐ₉₈₅ | L_{b88} | 434 | Lₐ₄₂₂₅ | L_{b88} |
| 435 | Lₐ₉₈₆ | L_{b88} | 436 | Lₐ₄₂₃₄ | L_{b88} |
| 437 | Lₐ₉₉₆ | L_{b88} | 438 | Lₐ₄₂₄₁ | L_{b88} |
| 439 | Lₐ₁₀₀₀ | L_{b88} | 440 | Lₐ₄₂₅₇ | L_{b88} |
| 441 | Lₐ₁₀₀₁ | L_{b88} | 442 | Lₐ₄₂₆₂ | L_{b88} |
| 443 | Lₐ₁₀₀₇ | L_{b88} | 444 | Lₐ₄₂₇₂ | L_{b88} |
| 445 | Lₐ₁₀₀₈ | L_{b88} | 446 | Lₐ₄₂₈₂ | L_{b88} |
| 447 | Lₐ₁₀₀₉ | L_{b88} | 448 | Lₐ₄₂₉₁ | L_{b88} |
| 449 | Lₐ₁₀₁₀ | L_{b88} | 450 | Lₐ₄₂₉₃ | L_{b88} |
| 451 | Lₐ₁₀₁₂ | L_{b88} | 452 | Lₐ₄₃₀₁ | L_{b88} |
| 453 | Lₐ₁₀₁₈ | L_{b88} | 454 | Lₐ₄₃₀₈ | L_{b88} |
| 455 | Lₐ₁₀₂₂ | L_{b88} | 456 | Lₐ₄₃₁₃ | L_{b88} |
| 457 | Lₐ₁₀₂₃ | L_{b88} | 458 | Lₐ₄₃₁₆ | L_{b88} |
| 459 | Lₐ₁₀₂₉ | L_{b88} | 460 | Lₐ₄₃₂₁ | L_{b88} |
| 461 | Lₐ₁₀₃₀ | L_{b88} | 462 | Lₐ₄₃₃₃ | L_{b88} |
| 463 | Lₐ₁₀₃₁ | L_{b88} | 464 | Lₐ₄₃₃₄ | L_{b88} |
| 465 | Lₐ₁₀₄₂ | L_{b88} | 466 | Lₐ₄₃₄₆ | L_{b88} |
| 467 | Lₐ₁₀₄₄ | L_{b88} | 468 | Lₐ₄₃₄₇ | L_{b88} |
| 469 | Lₐ₁₀₅₂ | L_{b88} | 470 | Lₐ₄₃₅₈ | L_{b88} |
| 471 | Lₐ₁₀₆₂ | L_{b88} | 472 | Lₐ₄₃₆₀ | L_{b88} |
| 473 | Lₐ₁₀₆₅ | L_{b88} | 474 | Lₐ₄₃₆₈ | L_{b88} |
| 475 | Lₐ₁₀₆₆ | L_{b88} | 476 | Lₐ₄₃₈₆ | L_{b88} |
| 477 | Lₐ₁₀₇₄ | L_{b88} | 478 | Lₐ₄₄₁₀ | L_{b88} |
| 479 | Lₐ₁₀₈₄ | L_{b88} | 480 | Lₐ₄₄₂₉ | L_{b88} |
| 481 | Lₐ₁₁₅₀ | L_{b88} | 482 | Lₐ₄₄₃₁ | L_{b88} |
| 483 | Lₐ₁₁₅₂ | L_{b88} | 484 | Lₐ₄₄₃₉ | L_{b31} |
| 485 | Lₐ₁₁₅₂ | L_{b88} | 486 | Lₐ₄₄₄₆ | L_{b88} |
| 487 | Lₐ₁₁₅₄ | L_{b88} | 488 | Lₐ₄₄₆₀ | L_{b88} |
| 489 | Lₐ₁₁₅₈ | L_{b88} | 490 | Lₐ₄₄₈₀ | L_{b88} |
| 491 | Lₐ₁₁₇₂ | L_{b88} | 492 | Lₐ₁₁₈₆ | L_{b88} |
| 493 | Lₐ₁₁₇₃ | L_{b88} | 494 | Lₐ₁₂₂₁ | L_{b88} |
| 495 | Lₐ₁₁₇₆ | L_{b88} | 496 | Lₐ₁₀₆₈ | L_{b88} |
| 497 | Lₐ₁₁₈₃ | L_{b88} | 498 | Lₐ₉₈₁ | L_{b88} |
| 499 | Lₐ₁₁₈₄ | L_{b88} | 500 | Lₐ₄₂₄₀ | L_{b88} |
| 501 | Lₐ₁₁₉₈ | L_{b88} | 502 | Lₐ₈₉₀ | L_{b88} |
| 503 | Lₐ₁₂₀₅ | L_{b88} | 504 | Lₐ₃₈₇₈ | L_{b88} |
| 505 | Lₐ₁₂₀₆ | L_{b88} | 506 | Lₐ₃₄₆₅ | L_{b88} |
| 507 | Lₐ₁₂₂₀ | L_{b88} | 508 | Lₐ₇₈₀ | L_{b88} |
| 509 | Lₐ₁ | L_{b122} | 510 | Lₐ₁₂₂₇ | L_{b122} |
| 511 | Lₐ₄ | L_{b122} | 512 | Lₐ₁₂₂₈ | L_{b122} |
| 513 | Lₐ₈ | L_{b122} | 514 | Lₐ₁₂₃₈ | L_{b122} |
| 515 | Lₐ₁₅ | L_{b122} | 516 | Lₐ₁₂₄₂ | L_{b122} |
| 517 | Lₐ₁₆ | L_{b122} | 518 | Lₐ₁₂₄₆ | L_{b122} |
| 519 | Lₐ₂₆ | L_{b122} | 520 | Lₐ₁₂₄₉ | L_{b122} |
| 521 | Lₐ₃₀ | L_{b122} | 522 | Lₐ₁₂₅₀ | L_{b122} |
| 523 | Lₐ₃₁ | L_{b122} | 524 | Lₐ₁₂₅₁ | L_{b122} |
| 525 | Lₐ₃₇ | L_{b122} | 526 | Lₐ₁₂₆₀ | L_{b122} |
| 527 | Lₐ₃₈ | L_{b122} | 528 | Lₐ₁₂₇₀ | L_{b122} |
| 529 | Lₐ₃₉ | L_{b122} | 530 | Lₐ₁₂₇₁ | L_{b122} |
| 531 | Lₐ₄₀ | L_{b122} | 532 | Lₐ₁₂₇₂ | L_{b122} |
| 533 | Lₐ₄₂ | L_{b122} | 534 | Lₐ₁₂₇₃ | L_{b122} |
| 535 | Lₐ₄₈ | L_{b122} | 536 | Lₐ₁₂₈₆ | L_{b122} |
| 537 | Lₐ₅₂ | L_{b122} | 538 | Lₐ₁₂₈₆ | L_{b122} |
| 539 | Lₐ₅₃ | L_{b122} | 540 | Lₐ₁₂₈₇ | L_{b122} |
| 541 | Lₐ₅₉ | L_{b122} | 542 | Lₐ₁₂₉₁ | L_{b122} |
| 543 | Lₐ₆₀ | L_{b122} | 544 | Lₐ₁₂₉₂ | L_{b122} |
| 545 | Lₐ₆₁ | L_{b122} | 546 | Lₐ₁₂₉₃ | L_{b122} |
| 547 | Lₐ₇₂ | L_{b122} | 548 | Lₐ₁₂₉₄ | L_{b122} |
| 549 | Lₐ₇₄ | L_{b122} | 550 | Lₐ₁₂₉₅ | L_{b122} |
| 551 | Lₐ₈₂ | L_{b122} | 552 | Lₐ₁₃₀₆ | L_{b122} |
| 553 | Lₐ₉₂ | L_{b122} | 554 | Lₐ₁₃₀₈ | L_{b122} |
| 555 | Lₐ₉₅ | L_{b122} | 556 | Lₐ₁₃₁₂ | L_{b122} |
| 557 | Lₐ₉₆ | L_{b122} | 558 | Lₐ₁₃₁₃ | L_{b122} |
| 559 | Lₐ₁₀₄ | L_{b122} | 560 | Lₐ₁₃₁₄ | L_{b122} |
| 561 | Lₐ₁₁₄ | L_{b122} | 562 | Lₐ₁₃₁₅ | L_{b122} |
| 563 | Lₐ₁₁₈ | L_{b122} | 564 | Lₐ₁₃₁₆ | L_{b122} |
| 565 | Lₐ₁₈₀ | L_{b122} | 566 | Lₐ₁₃₁₇ | L_{b122} |
| 567 | Lₐ₁₈₂ | L_{b122} | 568 | Lₐ₁₃₁₈ | L_{b122} |
| 569 | Lₐ₁₈₄ | L_{b122} | 570 | Lₐ₁₃₃₀ | L_{b122} |
| 571 | Lₐ₁₈₈ | L_{b122} | 572 | Lₐ₁₃₃₈ | L_{b122} |
| 573 | Lₐ₂₀₂ | L_{b122} | 574 | Lₐ₁₃₇₄ | L_{b122} |
| 575 | Lₐ₂₀₃ | L_{b122} | 576 | Lₐ₁₃₇₈ | L_{b122} |
| 577 | Lₐ₂₀₆ | L_{b122} | 578 | Lₐ₁₃₇₉ | L_{b122} |
| 579 | Lₐ₂₁₃ | L_{b122} | 580 | Lₐ₁₃₈₀ | L_{b122} |
| 581 | Lₐ₂₁₄ | L_{b122} | 582 | Lₐ₁₃₈₁ | L_{b122} |
| 583 | Lₐ₂₂₈ | L_{b122} | 584 | Lₐ₁₃₈₂ | L_{b122} |
| 585 | Lₐ₂₃₅ | L_{b122} | 586 | Lₐ₁₃₈₃ | L_{b122} |
| 587 | Lₐ₂₃₆ | L_{b122} | 588 | Lₐ₁₃₈₄ | L_{b122} |
| 589 | Lₐ₂₅₀ | L_{b122} | 590 | Lₐ₁₃₉₆ | L_{b122} |
| 591 | Lₐ₂₅₇ | L_{b122} | 592 | Lₐ₁₄₀₂ | L_{b122} |
| 593 | Lₐ₂₅₈ | L_{b122} | 594 | Lₐ₁₄₀₃ | L_{b122} |
| 595 | Lₐ₂₆₈ | L_{b122} | 596 | Lₐ₁₄₀₄ | L_{b122} |
| 597 | Lₐ₂₇₂ | L_{b122} | 598 | Lₐ₁₄₀₅ | L_{b122} |
| 599 | Lₐ₂₇₆ | L_{b122} | 600 | Lₐ₁₄₀₆ | L_{b122} |
| 601 | Lₐ₂₇₉ | L_{b122} | 602 | Lₐ₁₄₁₈ | L_{b122} |
| 603 | Lₐ₂₈₀ | L_{b122} | 604 | Lₐ₁₄₂₂ | L_{b122} |
| 605 | Lₐ₂₈₁ | L_{b122} | 606 | Lₐ₁₄₂₃ | L_{b122} |
| 607 | Lₐ₂₉₀ | L_{b122} | 608 | Lₐ₁₄₂₄ | L_{b122} |
| 609 | Lₐ₂₉₄ | L_{b122} | 610 | Lₐ₁₄₂₅ | L_{b122} |
| 611 | Lₐ₃₀₀ | L_{b122} | 612 | Lₐ₁₄₂₆ | L_{b122} |
| 613 | Lₐ₃₀₁ | L_{b122} | 614 | Lₐ₁₄₂₇ | L_{b122} |
| 615 | Lₐ₃₀₂ | L_{b122} | 616 | Lₐ₁₄₂₈ | L_{b122} |
| 617 | Lₐ₃₀₃ | L_{b122} | 618 | Lₐ₁₄₄₄ | L_{b122} |
| 619 | Lₐ₃₁₂ | L_{b122} | 620 | Lₐ₁₄₄₅ | L_{b122} |
| 621 | L₂₃₁₆ | L_{b122} | 622 | Lₐ₁₄₄₆ | L_{b122} |
| 623 | Lₐ₃₁₇ | L_{b122} | 624 | Lₐ₁₄₄₇ | L_{b122} |
| 625 | Lₐ₃₂₁ | L_{b122} | 626 | Lₐ₁₄₄₈ | L_{b122} |
| 627 | Lₐ₃₂₂ | L_{b122} | 628 | Lₐ₁₄₄₉ | L_{b122} |
| 629 | Lₐ₃₂₃ | L_{b122} | 630 | Lₐ₁₄₅₀ | L_{b122} |
| 631 | Lₐ₃₂₄ | L_{b122} | 632 | Lₐ₁₄₆₃ | L_{b122} |
| 633 | Lₐ₃₂₅ | L_{b122} | 634 | Lₐ₁₄₈₅ | L_{b122} |
| 635 | Lₐ₃₃₆ | L_{b122} | 636 | Lₐ₁₄₈₉ | L_{b122} |
| 637 | L₂₃₃₈ | L_{b122} | 638 | Lₐ₁₄₉₀ | L_{b122} |
| 639 | Lₐ₃₄₂ | L_{b122} | 640 | Lₐ₁₄₉₁ | L_{b122} |
| 641 | Lₐ₃₄₃ | L_{b122} | 642 | Lₐ₁₄₉₂ | L_{b122} |
| 643 | Lₐ₃₄₄ | L_{b122} | 644 | Lₐ₁₄₉₃ | L_{b122} |
| 645 | L₂₃₄₅ | L_{b122} | 646 | Lₐ₁₄₉₄ | L_{b122} |
| 647 | Lₐ₃₄₆ | L_{b122} | 648 | Lₐ₁₄₉₅ | L_{b122} |
| 649 | Lₐ₃₄₇ | L_{b122} | 650 | Lₐ₁₅₀₇ | L_{b122} |
| 651 | Lₐ₃₄₈ | L_{b122} | 652 | Lₐ₁₅₁₁ | L_{b122} |
| 653 | Lₐ₃₆₀ | L_{b122} | 654 | Lₐ₁₅₁₂ | L_{b122} |
| 655 | Lₐ₃₆₈ | L_{b122} | 656 | Lₐ₁₅₁₃ | L_{b122} |
| 657 | Lₐ₄₀₄ | L_{b122} | 658 | Lₐ₁₅₁₄ | L_{b122} |
| 659 | Lₐ₄₀₈ | L_{b122} | 660 | Lₐ₁₅₁₅ | L_{b122} |
| 661 | Lₐ₄₀₉ | L_{b122} | 662 | Lₐ₁₅₁₆ | L_{b122} |
| 663 | Lₐ₄₁₀ | L_{b122} | 664 | Lₐ₁₅₁₇ | L_{b122} |
| 665 | Lₐ₄₁₁ | L_{b122} | 666 | Lₐ₁₅₂₉ | L_{b122} |
| 667 | Lₐ₄₁₂ | L_{b122} | 668 | Lₐ₁₅₃₇ | L_{b122} |
| 669 | Lₐ₄₁₃ | L_{b122} | 670 | Lₐ₁₆₃₉ | L_{b122} |
| 671 | Lₐ₄₁₄ | L_{b122} | 672 | Lₐ₁₆₈₃ | L_{b122} |
| 673 | Lₐ₄₂₆ | L_{b122} | 674 | Lₐ₁₇₇₁ | L_{b122} |
| 675 | Lₐ₄₃₂ | L_{b122} | 676 | Lₐ₁₈₁₅ | L_{b122} |
| 677 | Lₐ₄₃₃ | L_{b122} | 678 | Lₐ₁₈₂₃ | L_{b122} |
| 679 | Lₐ₄₃₄ | L_{b122} | 680 | Lₐ₁₈₈₁ | L_{b122} |
| 681 | Lₐ₄₃₅ | L_{b122} | 682 | Lₐ₁₈₈₉ | L_{b122} |
| 683 | Lₐ₄₃₆ | L_{b122} | 684 | Lₐ₁₉₀₃ | L_{b122} |
| 685 | Lₐ₄₄₈ | L_{b122} | 686 | Lₐ₁₉₁₀ | L_{b122} |
| 687 | Lₐ₄₅₂ | L_{b122} | 688 | Lₐ₁₉₁₁ | L_{b122} |
| 689 | Lₐ₄₅₃ | L_{b122} | 690 | Lₐ₁₉₃₃ | L_{b122} |
| 691 | Lₐ₄₅₄ | L_{b122} | 692 | Lₐ₁₉₄₈ | L_{b122} |
| 693 | Lₐ₄₅₅ | L_{b122} | 694 | Lₐ₁₉₇₀ | L_{b122} |
| 695 | Lₐ₄₅₆ | L_{b122} | 696 | Lₐ₁₉₉₂ | L_{b122} |
| 697 | Lₐ₄₅₇ | L_{b122} | 698 | Lₐ₂₀₁₄ | L_{b122} |
| 699 | Lₐ₄₅₈ | L_{b122} | 700 | Lₐ₂₀₃₂ | L_{b122} |
| 701 | Lₐ₄₇₄ | L_{b122} | 702 | Lₐ₂₀₃₆ | L_{b122} |
| 703 | Lₐ₄₇₅ | L_{b122} | 704 | Lₐ₂₀₅₄ | L_{b122} |
| 705 | Lₐ₄₇₆ | L_{b122} | 706 | Lₐ₂₀₅₈ | L_{b122} |
| 707 | Lₐ₄₇₇ | L_{b122} | 708 | Lₐ₂₀₉₈ | L_{b122} |
| 709 | Lₐ₄₇₈ | L_{b122} | 710 | Lₐ₂₁₀₂ | L_{b122} |
| 711 | Lₐ₄₇₉ | L_{b122} | 712 | Lₐ₂₁₁₀ | L_{b122} |
| 713 | Lₐ₄₈₀ | L_{b122} | 714 | Lₐ₂₁₂₀ | L_{b122} |
| 715 | Lₐ₄₉₃ | L_{b122} | 716 | Lₐ₂₁₂₄ | L_{b122} |
| 717 | Lₐ₅₁₅ | L_{b122} | 718 | Lₐ₂₂₈₆ | L_{b122} |
| 719 | Lₐ₅₁₉ | L_{b122} | 720 | Lₐ₂₃₀₀ | L_{b122} |
| 721 | Lₐ₅₂₀ | L_{b122} | 722 | Lₐ₂₃₀₈ | L_{b122} |
| 723 | Lₐ₅₂₁ | L_{b122} | 724 | Lₐ₂₃₁₈ | L_{b122} |
| 725 | Lₐ₅₂₂ | L_{b122} | 726 | Lₐ₂₃₃₀ | L_{b122} |
| 727 | Lₐ₅₂₃ | L_{b122} | 728 | Lₐ₂₃₄₄ | L_{b122} |
| 729 | Lₐ₅₂₄ | L_{b122} | 730 | Lₐ₂₃₅₂ | L_{b122} |
| 731 | Lₐ₅₂₅ | L_{b122} | 732 | Lₐ₂₄₀₆ | L_{b122} |
| 733 | Lₐ₅₃₇ | L_{b122} | 734 | Lₐ₂₄₁₀ | L_{b122} |
| 735 | Lₐ₅₄₁ | L_{b122} | 736 | Lₐ₂₄₁₄ | L_{b122} |
| 737 | Lₐ₅₄₂ | L_{b122} | 738 | Lₐ₂₄₁₅ | L_{b122} |
| 739 | Lₐ₅₄₃ | L_{b122} | 740 | Lₐ₂₄₁₆ | L_{b122} |
| 741 | Lₐ₅₄₄ | L_{b122} | 742 | Lₐ₂₄₁₇ | L_{b122} |
| 743 | Lₐ₅₄₅ | L_{b122} | 744 | Lₐ₂₄₁₈ | L_{b122} |
| 745 | Lₐ₅₄₆ | L_{b122} | 746 | Lₐ₂₄₁₉ | L_{b122} |
| 747 | Lₐ₅₄₇ | L_{b122} | 748 | Lₐ₂₄₂₀ | L_{b122} |
| 749 | Lₐ₅₅₉ | L_{b122} | 750 | Lₐ₂₄₃₂ | L_{b122} |
| 751 | Lₐ₅₉₇ | L_{b122} | 752 | Lₐ₂₄₃₆ | L_{b122} |
| 753 | Lₐ₅₉₉ | L_{b122} | 754 | Lₐ₂₄₃₇ | L_{b122} |
| 755 | Lₐ₆₀₁ | L_{b122} | 756 | Lₐ₂₄₃₈ | L_{b122} |
| 757 | Lₐ₆₀₅ | L_{b122} | 758 | Lₐ₂₄₃₉ | L_{b122} |
| 759 | Lₐ₆₁₉ | L_{b122} | 760 | Lₐ₂₄₄₀ | L_{b122} |
| 761 | Lₐ₆₂₀ | L_{b122} | 762 | Lₐ₂₄₄₁ | L_{b122} |
| 763 | Lₐ₆₂₃ | L_{b122} | 764 | Lₐ₂₄₄₂ | L_{b122} |
| 765 | Lₐ₆₃₀ | L_{b122} | 766 | Lₐ₂₄₅₄ | L_{b122} |
| 767 | Lₐ₆₃₁ | L_{b122} | 768 | Lₐ₂₄₆₂ | L_{b122} |
| 769 | Lₐ₆₄₅ | L_{b122} | 770 | Lₐ₂₈₂₉ | L_{b122} |
| 771 | Lₐ₆₅₂ | L_{b122} | 772 | Lₐ₂₈₃₇ | L_{b122} |
| 773 | Lₐ₆₅₃ | L_{b122} | 774 | Lₐ₂₈₈₁ | L_{b122} |
| 775 | Lₐ₆₆₇ | L_{b122} | 776 | Lₐ₂₉₃₅ | L_{b122} |
| 777 | Lₐ₆₇₄ | L_{b122} | 778 | Lₐ₂₉₃₉ | L_{b122} |
| 779 | Lₐ₆₇₅ | L_{b122} | 780 | Lₐ₂₉₄₇ | L_{b122} |
| 781 | Lₐ₆₈₅ | L_{b122} | 782 | Lₐ₂₉₆₁ | L_{b122} |
| 783 | Lₐ₆₈₉ | L_{b122} | 784 | Lₐ₂₉₆₉ | L_{b122} |
| 785 | Lₐ₆₉₃ | L_{b122} | 786 | Lₐ₂₉₈₃ | L_{b122} |
| 787 | Lₐ₆₉₆ | L_{b122} | 788 | Lₐ₂₉₉₁ | L_{b122} |
| 789 | Lₐ₆₉₇ | L_{b122} | 790 | Lₐ₃₀₀₆ | L_{b122} |
| 791 | Lₐ₆₉₈ | L_{b122} | 792 | Lₐ₃₀₂₈ | L_{b122} |
| 793 | Lₐ₇₀₇ | L_{b122} | 794 | Lₐ₃₀₅₀ | L_{b122} |
| 795 | Lₐ₇₁₁ | L_{b122} | 796 | Lₐ₃₀₇₂ | L_{b122} |
| 797 | Lₐ₇₁₇ | L_{b122} | 798 | Lₐ₃₀₉₀ | L_{b122} |
| 799 | Lₐ₇₁₈ | L_{b122} | 800 | Lₐ₃₀₉₄ | L_{b122} |
| 801 | Lₐ₇₁₉ | L_{b122} | 802 | Lₐ₃₁₁₂ | L_{b122} |
| 803 | Lₐ₇₂₀ | L_{b122} | 804 | Lₐ₃₁₁₆ | L_{b122} |
| 805 | Lₐ₇₂₉ | L_{b122} | 806 | Lₐ₃₁₅₆ | L_{b122} |
| 807 | Lₐ₇₃₃ | L_{b122} | 808 | Lₐ₃₁₆₀ | L_{b122} |
| 809 | Lₐ₇₃₄ | L_{b122} | 810 | Lₐ₃₁₆₈ | L_{b122} |
| 811 | Lₐ₇₃₈ | L_{b122} | 812 | Lₐ₃₁₈₂ | L_{b122} |
| 813 | Lₐ₇₃₉ | L_{b122} | 814 | Lₐ₃₁₉₀ | L_{b122} |
| 815 | Lₐ₇₄₀ | L_{b122} | 816 | Lₐ₃₁₉₁ | L_{b122} |
| 817 | Lₐ₇₄₁ | L_{b122} | 818 | Lₐ₃₃₄₄ | L_{b122} |
| 819 | Lₐ₇₄₂ | L_{b122} | 820 | Lₐ₃₃₅₈ | L_{b122} |
| 821 | Lₐ₇₅₃ | L_{b122} | 822 | Lₐ₃₃₆₆ | L_{b122} |
| 823 | Lₐ₇₅₅ | L_{b122} | 824 | Lₐ₃₃₈₈ | L_{b122} |
| 825 | Lₐ₇₅₉ | L_{b122} | 826 | Lₐ₃₄₁₀ | L_{b122} |
| 827 | Lₐ₇₆₀ | L_{b122} | 828 | Lₐ₃₄₆₄ | L_{b122} |
| 829 | Lₐ₇₆₁ | L_{b122} | 830 | Lₐ₃₄₆₈ | L_{b122} |
| 831 | Lₐ₇₆₂ | L_{b122} | 832 | Lₐ₃₄₇₆ | L_{b122} |
| 833 | Lₐ₇₆₃ | L_{b122} | 834 | Lₐ₃₄₉₀ | L_{b122} |
| 835 | Lₐ₇₆₄ | L_{b122} | 836 | Lₐ₃₄₉₈ | L_{b122} |
| 837 | Lₐ₇₆₅ | L_{b122} | 838 | Lₐ₃₅₁₂ | L_{b122} |
| 839 | Lₐ₇₇₇ | L_{b122} | 840 | Lₐ₃₅₂₀ | L_{b122} |
| 841 | Lₐ₇₈₅ | L_{b122} | 842 | Lₐ₃₅₃₅ | L_{b122} |
| 843 | Lₐ₈₂₁ | L_{b122} | 844 | Lₐ₃₅₅₇ | L_{b122} |
| 845 | Lₐ₈₂₅ | L_{b122} | 846 | Lₐ₃₅₇₉ | L_{b122} |
| 847 | Lₐ₈₂₆ | L_{b122} | 848 | Lₐ₃₆₀₁ | L_{b122} |
| 849 | Lₐ₈₂₇ | L_{b122} | 850 | Lₐ₃₆₄₁ | L_{b122} |
| 851 | L₂₈₂₈ | L_{b122} | 852 | Lₐ₃₆₈₅ | L_{b122} |
| 853 | Lₐ₈₂₉ | L_{b122} | 854 | Lₐ₃₈₇₃ | L_{b122} |
| 855 | Lₐ₈₃₀ | L_{b122} | 856 | Lₐ₃₈₈₇ | L_{b122} |
| 857 | Lₐ₈₃₁ | L_{b122} | 858 | Lₐ₃₈₉₅ | L_{b122} |
| 859 | Lₐ₈₄₃ | L_{b122} | 860 | Lₐ₃₉₀₅ | L_{b122} |
| 861 | Lₐ₈₄₉ | L_{b122} | 862 | Lₐ₃₉₁₇ | L_{b122} |
| 863 | Lₐ₈₅₀ | L_{b122} | 864 | Lₐ₃₉₃₉ | L_{b122} |
| 865 | Lₐ₈₅₁ | L_{b122} | 866 | Lₐ₃₉₉₃ | L_{b122} |
| 867 | Lₐ₈₅₂ | L_{b122} | 868 | Lₐ₃₉₉₇ | L_{b122} |
| 869 | Lₐ₈₅₃ | L_{b122} | 870 | Lₐ₄₀₀₁ | L_{b122} |
| 871 | Lₐ₈₆₅ | L_{b122} | 872 | Lₐ₄₀₀₂ | L_{b122} |
| 873 | Lₐ₈₆₉ | L_{b122} | 874 | Lₐ₄₀₀₃ | L_{b122} |
| 875 | Lₐ₈₇₀ | L_{b122} | 876 | Lₐ₄₀₀₄ | L_{b122} |
| 877 | Lₐ₈₇₁ | L_{b122} | 878 | Lₐ₄₀₀₅ | L_{b122} |
| 879 | Lₐ₈₇₂ | L_{b122} | 880 | Lₐ₄₀₀₆ | L_{b122} |
| 881 | Lₐ₈₇₃ | L_{b122} | 882 | Lₐ₄₀₀₇ | L_{b122} |
| 883 | Lₐ₈₇₄ | L_{b122} | 884 | Lₐ₄₀₁₉ | L_{b122} |
| 885 | Lₐ₈₇₅ | L_{b122} | 886 | Lₐ₄₀₂₃ | L_{b122} |
| 887 | Lₐ₈₉₁ | L_{b122} | 888 | Lₐ₄₀₂₄ | L_{b122} |
| 889 | Lₐ₈₉₂ | L_{b122} | 890 | Lₐ₄₀₂₅ | L_{b122} |
| 891 | Lₐ₈₉₃ | L_{b122} | 892 | Lₐ₄₀₂₆ | L_{b122} |
| 893 | Lₐ₈₉₄ | L_{b122} | 894 | Lₐ₄₀₂₇ | L_{b122} |
| 895 | Lₐ₈₉₅ | L_{b122} | 896 | Lₐ₄₀₂₈ | L_{b122} |
| 897 | Lₐ₈₉₆ | L_{b122} | 898 | Lₐ₄₀₂₉ | L_{b122} |
| 899 | Lₐ₈₉₇ | L_{b122} | 900 | Lₐ₄₀₄₁ | L_{b122} |
| 901 | Lₐ₉₁₀ | L_{b122} | 902 | Lₐ₄₀₄₉ | L_{b122} |
| 903 | Lₐ₉₃₂ | L_{b122} | 904 | Lₐ₄₀₆₁ | L_{b122} |
| 905 | Lₐ₉₃₆ | L_{b122} | 906 | Lₐ₄₀₆₈ | L_{b122} |
| 907 | Lₐ₉₃₇ | L_{b122} | 908 | Lₐ₄₀₇₀ | L_{b122} |
| 909 | Lₐ₉₃₈ | L_{b122} | 910 | Lₐ₄₀₇₁ | L_{b122} |
| 911 | Lₐ₉₃₉ | L_{b122} | 912 | Lₐ₄₀₇₃ | L_{b122} |
| 913 | Lₐ₉₄₀ | L_{b122} | 914 | Lₐ₄₀₇₄ | L_{b122} |
| 915 | Lₐ₉₄₁ | L_{b122} | 916 | Lₐ₄₀₈₄ | L_{b122} |
| 917 | Lₐ₉₄₂ | L_{b122} | 918 | Lₐ₄₁₀₉ | L_{b122} |
| 919 | Lₐ₉₅₄ | L_{b122} | 920 | Lₐ₄₁₁₆ | L_{b122} |
| 921 | Lₐ₉₅₈ | L_{b122} | 922 | Lₐ₄₁₂₉ | L_{b122} |
| 923 | Lₐ₉₅₉ | L_{b122} | 924 | Lₐ₄₁₅₁ | L_{b122} |
| 925 | Lₐ₉₆₀ | L_{b122} | 926 | Lₐ₄₁₅₂ | L_{b122} |
| 927 | Lₐ₉₆₁ | L_{b122} | 928 | Lₐ₄₁₅₆ | L_{b122} |
| 929 | Lₐ₉₆₂ | L_{b122} | 930 | Lₐ₄₁₆₀ | L_{b122} |
| 931 | Lₐ₉₆₃ | L_{b122} | 932 | Lₐ₄₁₇₄ | L_{b122} |
| 933 | Lₐ₉₆₄ | L_{b122} | 934 | Lₐ₄₁₈₈ | L_{b122} |
| 935 | Lₐ₉₇₁ | L_{b122} | 936 | Lₐ₄₉₁ | L_{b122} |
| 937 | Lₐ₉₇₄ | L_{b122} | 938 | Lₐ₄₂₀₄ | L_{b122} |
| 939 | Lₐ₉₇₈ | L_{b122} | 940 | Lₐ₄₂₁₈ | L_{b122} |
| 941 | Lₐ₉₈₅ | L_{b122} | 942 | Lₐ₄₂₂₅ | L_{b122} |
| 943 | Lₐ₉₈₆ | L_{b122} | 944 | Lₐ₄₂₃₄ | L_{b122} |
| 945 | Lₐ₉₉₆ | L_{b122} | 946 | Lₐ₄₂₄₁ | L_{b122} |
| 947 | Lₐ₁₀₀₀ | L_{b122} | 948 | Lₐ₄₂₅₇ | L_{b122} |
| 949 | Lₐ₁₀₀₁ | L_{b122} | 950 | Lₐ₄₂₆₂ | L_{b122} |
| 951 | Lₐ₁₀₀₇ | L_{b122} | 952 | Lₐ₄₂₇₂ | L_{b122} |
| 953 | Lₐ₁₀₀₈ | L_{b122} | 954 | Lₐ₄₂₈₂ | L_{b122} |
| 955 | Lₐ₁₀₀₉ | L_{b122} | 956 | Lₐ₄₂₉₁ | L_{b122} |
| 957 | Lₐ₁₀₁₀ | L_{b122} | 958 | Lₐ₄₂₉₃ | L_{b122} |
| 959 | Lₐ₁₀₁₂ | L_{b122} | 960 | Lₐ₄₃₀₁ | L_{b122} |
| 961 | Lₐ₁₀₁₈ | L_{b122} | 962 | Lₐ₄₃₀₈ | L_{b122} |
| 963 | Lₐ₁₀₂₂ | L_{b122} | 964 | Lₐ₄₃₁₃ | L_{b122} |
| 965 | Lₐ₁₀₂₃ | L_{b122} | 966 | Lₐ₄₃₁₆ | L_{b122} |
| 967 | Lₐ₁₀₂₉ | L_{b122} | 968 | Lₐ₄₃₂₁ | L_{b122} |
| 969 | Lₐ₁₀₃₀ | L_{b122} | 970 | Lₐ₄₃₃₃ | L_{b122} |
| 971 | Lₐ₁₀₃₁ | L_{b122} | 972 | Lₐ₄₃₃₄ | L_{b122} |
| 973 | Lₐ₁₀₄₂ | L_{b122} | 974 | Lₐ₄₃₄₆ | L_{b122} |
| 975 | Lₐ₁₀₄₄ | L_{b122} | 976 | Lₐ₄₃₄₇ | L_{b122} |
| 977 | Lₐ₁₀₅₂ | L_{b122} | 978 | Lₐ₄₃₅₈ | L_{b122} |
| 979 | Lₐ₁₀₆₂ | L_{b122} | 980 | Lₐ₄₃₆₀ | L_{b122} |
| 981 | Lₐ₁₀₆₅ | L_{b122} | 982 | Lₐ₄₃₆₈ | L_{b122} |
| 983 | Lₐ₁₀₆₆ | L_{b122} | 984 | Lₐ₄₃₈₆ | L_{b122} |
| 985 | Lₐ₁₀₇₄ | L_{b122} | 986 | Lₐ₄₄₁₀ | L_{b122} |
| 987 | Lₐ₁₀₈₄ | L_{b122} | 988 | Lₐ₄₄₂₉ | L_{b122} |
| 989 | Lₐ₁₁₅₀ | L_{b122} | 990 | Lₐ₄₄₃₁ | L_{b122} |
| 991 | Lₐ₁₁₅₂ | L_{b122} | 992 | Lₐ₄₄₃₉ | L_{b122} |
| 993 | Lₐ₁₁₅₂ | L_{b122} | 994 | Lₐ₄₄₄₆ | L_{b122} |
| 995 | Lₐ₁₁₅₄ | L_{b122} | 996 | Lₐ₄₄₆₀ | L_{b122} |
| 997 | Lₐ₁₁₅₈ | L_{b122} | 998 | Lₐ₄₄₈₀ | L_{b122} |
| 999 | Lₐ₁₁₇₂ | L_{b122} | 1000 | Lₐ₁₁₈₆ | L_{b122} |
| 1001 | Lₐ₁₁₇₃ | L_{b122} | 1002 | Lₐ₁₂₂₁ | L_{b122} |
| 1003 | Lₐ₁₁₇₆ | L_{b122} | 1004 | Lₐ₁₀₆₈ | L_{b122} |
| 1005 | Lₐ₁₁₈₃ | L_{b122} | 1006 | Lₐ₉₈₁ | L_{b122} |
| 1007 | Lₐ₁₁₈₄ | L_{b122} | 1008 | Lₐ₄₂₄₀ | L_{b122} |
| 1009 | Lₐ₁₁₉₈ | L_{b122} | 1010 | Lₐ₈₉₀ | L_{b122} |
| 1011 | Lₐ₁₂₀₅ | L_{b122} | 1012 | Lₐ₃₈₇₈ | L_{b122} |
| 1013 | Lₐ₁₂₀₆ | L_{b122} | 1014 | Lₐ₃₄₆₅ | L_{b122} |
| 1015 | Lₐ₁₂₂₀ | L_{b122} | 1016 | Lₐ₇₈₀ | L_{b122} |
| 1017 | Lₐₗ | L_{b126} | 1018 | Lₐ₁₂₂₇ | L_{b126} |
| 1019 | Lₐ₄ | L_{b126} | 1020 | Lₐ₁₂₂₈ | L_{b126} |
| 1021 | Lₐ₈ | L_{b126} | 1022 | Lₐ₁₂₃₈ | L_{b126} |
| 1023 | Lₐ₁₅ | L_{b126} | 1024 | Lₐ₁₂₄₂ | L_{b126} |
| 1025 | Lₐ₁₆ | L_{b126} | 1026 | Lₐ₁₂₄₆ | L_{b126} |
| 1027 | Lₐ₂₆ | L_{b126} | 1028 | Lₐ₁₂₄₉ | L_{b126} |
| 1029 | Lₐ₃₀ | L_{b126} | 1030 | Lₐ₁₂₅₀ | L_{b126} |
| 1031 | Lₐ₃₁ | L_{b126} | 1032 | Lₐ₁₂₅₁ | L_{b126} |
| 1033 | Lₐ₃₇ | L_{b126} | 1034 | Lₐ₁₂₆₀ | L_{b126} |
| 1035 | Lₐ₃₈ | L_{b126} | 1036 | Lₐ₁₂₇₀ | L_{b126} |
| 1037 | Lₐ₃₉ | L_{b126} | 1038 | Lₐ₁₂₇₁ | L_{b126} |
| 1039 | Lₐ₄₀ | L_{b126} | 1040 | Lₐ₁₂₇₂ | L_{b126} |
| 1041 | Lₐ₄₂ | L_{b126} | 1042 | Lₐ₁₂₇₃ | L_{b126} |
| 1043 | Lₐ₄₈ | L_{b126} | 1044 | Lₐ₁₂₈₆ | L_{b126} |
| 1045 | Lₐ₅₂ | L_{b126} | 1046 | Lₐ₁₂₈₆ | L_{b126} |
| 1047 | Lₐ₅₃ | L_{b126} | 1048 | Lₐ₁₂₈₇ | L_{b126} |
| 1049 | Lₐ₅₉ | L_{b126} | 1050 | Lₐ₁₂₉₁ | L_{b126} |
| 1051 | Lₐ₆₀ | L_{b126} | 1052 | Lₐ₁₂₉₂ | L_{b126} |
| 1053 | Lₐ₆₁ | L_{b126} | 1054 | Lₐ₁₂₉₃ | L_{b126} |
| 1055 | Lₐ₇₂ | L_{b126} | 1056 | Lₐ₁₂₉₄ | L_{b126} |
| 1057 | Lₐ₇₄ | L_{b126} | 1058 | Lₐ₁₂₉₅ | L_{b126} |
| 1059 | Lₐ₈₂ | L_{b126} | 1060 | Lₐ₁₃₀₆ | L_{b126} |
| 1061 | Lₐ₉₂ | L_{b126} | 1062 | Lₐ₁₃₀₈ | L_{b126} |
| 1063 | Lₐ₉₅ | L_{b126} | 1064 | Lₐ₁₃₁₂ | L_{b126} |
| 1065 | Lₐ₉₆ | L_{b126} | 1066 | Lₐ₁₃₁₃ | L_{b126} |
| 1067 | Lₐ₁₀₄ | L_{b126} | 1068 | Lₐ₁₃₁₄ | L_{b126} |
| 1069 | Lₐ₁₁₄ | L_{b126} | 1070 | Lₐ₁₃₁₅ | L_{b126} |
| 1071 | Lₐ₁₁₈ | L_{b126} | 1072 | Lₐ₁₃₁₆ | L_{b126} |
| 1073 | Lₐ₁₈₀ | L_{b126} | 1074 | Lₐ₁₃₁₇ | L_{b126} |
| 1075 | Lₐ₁₈₂ | L_{b126} | 1076 | Lₐ₁₃₁₈ | L_{b126} |
| 1077 | Lₐ₁₈₄ | L_{b126} | 1078 | Lₐ₁₃₃₀ | L_{b126} |
| 1079 | Lₐ₁₈₈ | L_{b126} | 1080 | Lₐ₁₃₃₈ | L_{b126} |
| 1081 | L₂₂₀₂ | L_{b126} | 1082 | Lₐ₁₃₇₄ | L_{b126} |
| 1083 | L₂₂₀₃ | L_{b126} | 1084 | Lₐ₁₃₇₈ | L_{b126} |
| 1085 | L₂₂₀₆ | L_{b126} | 1086 | Lₐ₁₃₇₉ | L_{b126} |
| 1087 | Lₐ₂₁₃ | L_{b126} | 1088 | Lₐ₁₃₈₀ | L_{b126} |
| 1089 | Lₐ₂₁₄ | L_{b126} | 1090 | Lₐ₁₃₈₁ | L_{b126} |
| 1091 | Lₐ₂₂₈ | L_{b126} | 1092 | Lₐ₁₃₈₂ | L_{b126} |
| 1093 | Lₐ₂₃₅ | L_{b126} | 1094 | Lₐ₁₃₈₃ | L_{b126} |
| 1095 | Lₐ₂₃₆ | L_{b126} | 1096 | Lₐ₁₃₈₄ | L_{b126} |
| 1097 | Lₐ₂₅₀ | L_{b126} | 1098 | Lₐ₁₃₉₆ | L_{b126} |
| 1099 | Lₐ₂₅₇ | L_{b126} | 1100 | Lₐ₁₄₀₂ | L_{b126} |
| 1101 | Lₐ₂₅₈ | L_{b126} | 1102 | Lₐ₁₄₀₃ | L_{b126} |
| 1103 | Lₐ₂₆₈ | L_{b126} | 1104 | Lₐ₁₄₀₄ | L_{b126} |
| 1105 | Lₐ₂₇₂ | L_{b126} | 1106 | Lₐ₁₄₀₅ | L_{b126} |
| 1107 | Lₐ₂₇₆ | L_{b126} | 1108 | Lₐ₁₄₀₆ | L_{b126} |
| 1109 | Lₐ₂₇₉ | L_{b126} | 1110 | Lₐ₁₄₁₈ | L_{b126} |
| 1111 | Lₐ₂₈₀ | L_{b126} | 1112 | Lₐ₁₄₂₂ | L_{b126} |
| 1113 | Lₐ₂₈₁ | L_{b126} | 1114 | Lₐ₁₄₂₃ | L_{b126} |
| 1115 | Lₐ₂₉₀ | L_{b126} | 1116 | Lₐ₁₄₂₄ | L_{b126} |
| 1117 | Lₐ₂₉₄ | L_{b126} | 1118 | Lₐ₁₄₂₅ | L_{b126} |
| 1119 | Lₐ₃₀₀ | L_{b126} | 1120 | Lₐ₁₄₂₆ | L_{b126} |
| 1121 | Lₐ₃₀₁ | L_{b126} | 1122 | Lₐ₁₄₂₇ | L_{b126} |
| 1123 | Lₐ₃₀₂ | L_{b126} | 1124 | Lₐ₁₄₂₈ | L_{b126} |
| 1125 | Lₐ₃₀₃ | L_{b126} | 1126 | Lₐ₁₄₄₄ | L_{b126} |
| 1127 | Lₐ₃₁₂ | L_{b126} | 1128 | Lₐ₁₄₄₅ | L_{b126} |
| 1129 | Lₐ₃₁₆ | L_{b126} | 1130 | Lₐ₁₄₄₆ | L_{b126} |
| 1131 | Lₐ₃₁₇ | L_{b126} | 1132 | Lₐ₁₄₄₇ | L_{b126} |
| 1133 | Lₐ₃₂₁ | L_{b126} | 1134 | Lₐ₁₄₄₈ | L_{b126} |
| 1135 | Lₐ₃₂₂ | L_{b126} | 1136 | Lₐ₁₄₄₉ | L_{b126} |
| 1137 | Lₐ₃₂₃ | L_{b126} | 1138 | Lₐ₁₄₅₀ | L_{b126} |
| 1139 | Lₐ₃₂₄ | L_{b126} | 1140 | Lₐ₁₄₆₃ | L_{b126} |
| 1141 | Lₐ₃₂₅ | L_{b126} | 1142 | Lₐ₁₄₈₅ | L_{b126} |
| 1143 | Lₐ₃₃₆ | L_{b126} | 1144 | Lₐ₁₄₈₉ | L_{b126} |
| 1145 | Lₐ₃₃₈ | L_{b126} | 1146 | Lₐ₁₄₉₀ | L_{b126} |
| 1147 | Lₐ₃₄₂ | L_{b126} | 1148 | Lₐ₁₄₉₁ | L_{b126} |
| 1149 | Lₐ₃₄₃ | L_{b126} | 1150 | Lₐ₁₄₉₂ | L_{b126} |
| 1151 | Lₐ₃₄₄ | L_{b126} | 1152 | Lₐ₁₄₉₃ | L_{b126} |
| 1153 | Lₐ₃₄₅ | L_{b126} | 1154 | Lₐ₁₄₉₄ | L_{b126} |
| 1155 | Lₐ₃₄₆ | L_{b126} | 1156 | Lₐ₁₄₉₅ | L_{b126} |
| 1157 | Lₐ₃₄₇ | L_{b126} | 1158 | Lₐ₁₅₀₇ | L_{b126} |
| 1159 | Lₐ₃₄₈ | L_{b126} | 1160 | Lₐ₁₅₁₁ | L_{b126} |
| 1161 | Lₐ₃₆₀ | L_{b126} | 1162 | Lₐ₁₅₁₂ | L_{b126} |
| 1163 | Lₐ₃₆₈ | L_{b126} | 1164 | Lₐ₁₅₁₃ | L_{b126} |
| 1165 | Lₐ₄₀₄ | L_{b126} | 1166 | Lₐ₁₅₁₄ | L_{b126} |
| 1167 | Lₐ₄₀₈ | L_{b126} | 1168 | Lₐ₁₅₁₅ | L_{b126} |
| 1169 | Lₐ₄₀₉ | L_{b126} | 1170 | Lₐ₁₅₁₆ | L_{b126} |
| 1171 | Lₐ₄₁₀ | L_{b126} | 1172 | Lₐ₁₅₁₇ | L_{b126} |
| 1173 | Lₐ₄₁₁ | L_{b126} | 1174 | Lₐ₁₅₂₉ | L_{b126} |
| 1175 | Lₐ₄₁₂ | L_{b126} | 1176 | Lₐ₁₅₃₇ | L_{b126} |
| 1177 | Lₐ₄₁₃ | L_{b126} | 1178 | Lₐ₁₆₃₉ | L_{b126} |
| 1179 | Lₐ₄₁₄ | L_{b126} | 1180 | Lₐ₁₆₈₃ | L_{b126} |
| 1181 | Lₐ₄₂₆ | L_{b126} | 1182 | Lₐ₁₇₇₁ | L_{b126} |
| 1183 | Lₐ₄₃₂ | L_{b126} | 1184 | Lₐ₁₈₁₅ | L_{b126} |
| 1185 | Lₐ₄₃₃ | L_{b126} | 1186 | Lₐ₁₈₂₃ | L_{b126} |
| 1187 | Lₐ₄₃₄ | L_{b126} | 1188 | Lₐ₁₈₈₁ | L_{b126} |
| 1189 | Lₐ₄₃₅ | L_{b126} | 1190 | Lₐ₁₈₈₉ | L_{b126} |
| 1191 | Lₐ₄₃₆ | L_{b126} | 1192 | Lₐ₁₉₀₃ | L_{b126} |
| 1193 | Lₐ₄₄₈ | L_{b126} | 1194 | Lₐ₁₉₁₀ | L_{b126} |
| 1195 | Lₐ₄₅₂ | L_{b126} | 1196 | Lₐ₁₉₁₁ | L_{b126} |
| 1197 | Lₐ₄₅₃ | L_{b126} | 1198 | Lₐ₁₉₃₃ | L_{b126} |
| 1199 | Lₐ₄₅₄ | L_{b126} | 1200 | Lₐ₁₉₄₈ | L_{b126} |
| 1201 | Lₐ₄₅₅ | L_{b126} | 1202 | Lₐ₁₉₇₀ | L_{b126} |
| 1203 | Lₐ₄₅₆ | L_{b126} | 1204 | Lₐ₁₉₉₂ | L_{b126} |
| 1205 | Lₐ₄₅₇ | L_{b126} | 1206 | Lₐ₂₀₁₄ | L_{b126} |
| 1207 | Lₐ₄₅₈ | L_{b126} | 1208 | Lₐ₂₀₃₂ | L_{b126} |
| 1209 | Lₐ₄₇₄ | L_{b126} | 1210 | Lₐ₂₀₃₆ | L_{b126} |
| 1211 | Lₐ₄₇₅ | L_{b126} | 1212 | Lₐ₂₀₅₄ | L_{b126} |
| 1213 | Lₐ₄₇₆ | L_{b126} | 1214 | Lₐ₂₀₅₈ | L_{b126} |
| 1215 | Lₐ₄₇₇ | L_{b126} | 1216 | Lₐ₂₀₉₈ | L_{b126} |
| 1217 | Lₐ₄₇₈ | L_{b126} | 1218 | Lₐ₂₁₀₂ | L_{b126} |
| 1219 | Lₐ₄₇₉ | L_{b126} | 1220 | Lₐ₂₁₁₀ | L_{b126} |
| 1221 | Lₐ₄₈₀ | L_{b126} | 1222 | Lₐ₂₁₂₀ | L_{b126} |
| 1223 | Lₐ₄₉₃ | L_{b126} | 1224 | Lₐ₂₁₂₄ | L_{b126} |
| 1225 | Lₐ₅₁₅ | L_{b126} | 1226 | Lₐ₂₂₈₆ | L_{b126} |
| 1227 | Lₐ₅₁₉ | L_{b126} | 1228 | Lₐ₂₃₀₀ | L_{b126} |
| 1229 | Lₐ₅₂₀ | L_{b126} | 1230 | Lₐ₂₃₀₈ | L_{b126} |
| 1231 | Lₐ₅₂₁ | L_{b126} | 1232 | Lₐ₂₃₁₈ | L_{b126} |
| 1233 | Lₐ₅₂₂ | L_{b126} | 1234 | L₂₂₃₃₀ | L_{b126} |
| 1235 | Lₐ₅₂₃ | L_{b126} | 1236 | Lₐ₂₃₄₄ | L_{b126} |
| 1237 | Lₐ₅₂₄ | L_{b126} | 1238 | Lₐ₂₃₅₂ | L_{b126} |
| 1239 | Lₐ₅₂₅ | L_{b126} | 1240 | Lₐ₂₄₀₆ | L_{b126} |
| 1241 | Lₐ₅₃₇ | L_{b126} | 1242 | Lₐ₂₄₁₀ | L_{b126} |
| 1243 | Lₐ₅₄₁ | L_{b126} | 1244 | Lₐ₂₄₁₄ | L_{b126} |
| 1245 | Lₐ₅₄₂ | L_{b126} | 1246 | Lₐ₂₄₁₅ | L_{b126} |
| 1247 | Lₐ₅₄₃ | L_{b126} | 1248 | Lₐ₂₄₁₆ | L_{b126} |
| 1249 | Lₐ₅₄₄ | L_{b126} | 1250 | Lₐ₂₄₁₇ | L_{b126} |
| 1251 | Lₐ₅₄₅ | L_{b126} | 1252 | Lₐ₂₄₁₈ | L_{b126} |
| 1253 | Lₐ₅₄₆ | L_{b126} | 1254 | Lₐ₂₄₁₉ | L_{b126} |
| 1255 | Lₐ₅₄₇ | L_{b126} | 1256 | Lₐ₂₄₂₀ | L_{b126} |
| 1257 | Lₐ₅₅₉ | L_{b126} | 1258 | Lₐ₂₄₃₂ | L_{b126} |
| 1259 | Lₐ₅₉₇ | L_{b126} | 1260 | Lₐ₂₄₃₆ | L_{b126} |
| 1261 | Lₐ₅₉₉ | L_{b126} | 1262 | Lₐ₂₄₃₇ | L_{b126} |
| 1263 | Lₐ₆₀₁ | L_{b126} | 1264 | Lₐ₂₄₃₈ | L_{b126} |
| 1265 | Lₐ₆₀₅ | L_{b126} | 1266 | Lₐ₂₄₃₉ | L_{b126} |
| 1267 | Lₐ₆₁₉ | L_{b126} | 1268 | Lₐ₂₄₄₀ | L_{b126} |
| 1269 | Lₐ₆₂₀ | L_{b126} | 1270 | Lₐ₂₄₄₁ | L_{b126} |
| 1271 | Lₐ₆₂₃ | L_{b126} | 1272 | Lₐ₂₄₄₂ | L_{b126} |
| 1273 | Lₐ₆₃₀ | L_{b126} | 1274 | Lₐ₂₄₅₄ | L_{b126} |
| 1275 | Lₐ₆₃₁ | L_{b126} | 1276 | Lₐ₂₄₆₂ | L_{b126} |
| 1277 | Lₐ₆₄₅ | L_{b126} | 1278 | Lₐ₂₈₂₉ | L_{b126} |
| 1279 | Lₐ₆₅₂ | L_{b126} | 1280 | Lₐ₂₈₃₇ | L_{b126} |
| 1281 | Lₐ₆₅₃ | L_{b126} | 1282 | Lₐ₂₈₈₁ | L_{b126} |
| 1283 | Lₐ₆₆₇ | L_{b126} | 1284 | Lₐ₂₉₃₅ | L_{b126} |
| 1285 | Lₐ₆₇₄ | L_{b126} | 1286 | Lₐ₂₉₃₉ | L_{b126} |
| 1287 | Lₐ₆₇₅ | L_{b126} | 1288 | Lₐ₂₉₄₇ | L_{b126} |
| 1289 | Lₐ₆₈₅ | L_{b126} | 1290 | Lₐ₂₉₆₁ | L_{b126} |
| 1291 | Lₐ₆₈₉ | L_{b126} | 1292 | Lₐ₂₉₆₉ | L_{b126} |
| 1293 | Lₐ₆₉₃ | L_{b126} | 1294 | Lₐ₂₉₈₃ | L_{b126} |
| 1295 | Lₐ₆₉₆ | L_{b126} | 1296 | Lₐ₂₉₉₁ | L_{b126} |
| 1297 | Lₐ₆₉₇ | L_{b126} | 1298 | Lₐ₃₀₀₆ | L_{b126} |
| 1299 | Lₐ₆₉₈ | L_{b126} | 1300 | Lₐ₃₀₂₈ | L_{b126} |
| 1301 | Lₐ₇₀₇ | L_{b126} | 1302 | Lₐ₃₀₅₀ | L_{b126} |
| 1303 | Lₐ₇₁₁ | L_{b126} | 1304 | Lₐ₃₀₇₂ | L_{b126} |
| 1305 | Lₐ₇₁₇ | L_{b126} | 1306 | Lₐ₃₀₉₀ | L_{b126} |
| 1307 | Lₐ₇₁₈ | L_{b126} | 1308 | Lₐ₃₀₉₄ | L_{b126} |
| 1309 | Lₐ₇₁₉ | L_{b126} | 1310 | Lₐ₃₁₁₂ | L_{b126} |
| 1311 | Lₐ₇₂₀ | L_{b126} | 1312 | Lₐ₃₁₁₆ | L_{b126} |
| 1313 | Lₐ₇₂₉ | L_{b126} | 1314 | Lₐ₃₁₅₆ | L_{b126} |
| 1315 | Lₐ₇₃₃ | L_{b126} | 1316 | Lₐ₃₁₆₀ | L_{b126} |
| 1317 | Lₐ₇₃₄ | L_{b126} | 1318 | Lₐ₃₁₆₈ | L_{b126} |
| 1319 | Lₐ₇₃₈ | L_{b126} | 1320 | Lₐ₃₁₈₂ | L_{b126} |
| 1321 | Lₐ₇₃₉ | L_{b126} | 1322 | Lₐ₃₁₉₀ | L_{b126} |
| 1323 | Lₐ₇₄₀ | L_{b126} | 1324 | Lₐ₃₁₉₁ | L_{b126} |
| 1325 | Lₐ₇₄₁ | L_{b126} | 1326 | Lₐ₃₃₄₄ | L_{b126} |
| 1327 | Lₐ₇₄₂ | L_{b126} | 1328 | Lₐ₃₃₅₈ | L_{b126} |
| 1329 | Lₐ₇₅₃ | L_{b126} | 1330 | Lₐ₃₃₆₆ | L_{b126} |
| 1331 | Lₐ₇₅₅ | L_{b126} | 1332 | Lₐ₃₃₈₈ | L_{b126} |
| 1333 | Lₐ₇₅₉ | L_{b126} | 1334 | Lₐ₃₄₁₀ | L_{b126} |
| 1335 | Lₐ₇₆₀ | L_{b126} | 1336 | Lₐ₃₄₆₄ | L_{b126} |
| 1337 | Lₐ₇₆₁ | L_{b126} | 1338 | Lₐ₃₄₆₈ | L_{b126} |
| 1339 | Lₐ₇₆₂ | L_{b126} | 1340 | Lₐ₃₄₇₆ | L_{b126} |
| 1341 | Lₐ₇₆₃ | L_{b126} | 1342 | L₂₃₄₉₀ | L_{b126} |
| 1343 | Lₐ₇₆₄ | L_{b126} | 1344 | Lₐ₃₄₉₈ | L_{b126} |
| 1345 | Lₐ₇₆₅ | L_{b126} | 1346 | Lₐ₃₅₁₂ | L_{b126} |
| 1347 | Lₐ₇₇₇ | L_{b126} | 1348 | Lₐ₃₅₂₀ | L_{b126} |
| 1349 | Lₐ₇₈₅ | L_{b126} | 1350 | Lₐ₃₅₃₅ | L_{b126} |
| 1351 | Lₐ₈₂₁ | L_{b126} | 1352 | Lₐ₃₅₅₇ | L_{b126} |
| 1353 | Lₐ₈₂₅ | L_{b126} | 1354 | Lₐ₃₅₇₉ | L_{b126} |
| 1355 | Lₐ₈₂₆ | L_{b126} | 1356 | L₂₃₆₀₁ | L_{b126} |
| 1357 | Lₐ₈₂₇ | L_{b126} | 1358 | Lₐ₃₆₄₁ | L_{b126} |
| 1359 | Lₐ₈₂₈ | L_{b126} | 1360 | Lₐ₃₆₈₅ | L_{b126} |
| 1361 | Lₐ₈₂₉ | L_{b126} | 1362 | Lₐ₃₈₇₃ | L_{b126} |
| 1363 | Lₐ₈₃₀ | L_{b126} | 1364 | Lₐ₃₈₈₇ | L_{b126} |
| 1365 | Lₐ₈₃₁ | L_{b126} | 1366 | Lₐ₃₈₉₅ | L_{b126} |
| 1367 | Lₐ₈₄₃ | L_{b126} | 1368 | Lₐ₃₉₀₅ | L_{b126} |
| 1369 | Lₐ₈₄₉ | L_{b126} | 1370 | Lₐ₃₉₁₇ | L_{b126} |
| 1371 | Lₐ₈₅₀ | L_{b126} | 1372 | Lₐ₃₉₃₉ | L_{b126} |
| 1373 | Lₐ₈₅₁ | L_{b126} | 1374 | Lₐ₃₉₉₃ | L_{b126} |
| 1375 | Lₐ₈₅₂ | L_{b126} | 1376 | Lₐ₃₉₉₇ | L_{b126} |
| 1377 | Lₐ₈₅₃ | L_{b126} | 1378 | Lₐ₄₀₀₁ | L_{b126} |
| 1379 | Lₐ₈₆₅ | L_{b126} | 1380 | Lₐ₄₀₀₂ | L_{b126} |
| 1381 | Lₐ₈₆₉ | L_{b126} | 1382 | Lₐ₄₀₀₃ | L_{b126} |
| 1383 | Lₐ₈₇₀ | L_{b126} | 1384 | Lₐ₄₀₀₄ | L_{b126} |
| 1385 | Lₐ₈₇₁ | L_{b126} | 1386 | Lₐ₄₀₀₅ | L_{b126} |
| 1387 | Lₐ₈₇₂ | L_{b126} | 1388 | Lₐ₄₀₀₆ | L_{b126} |
| 1389 | Lₐ₈₇₃ | L_{b126} | 1390 | Lₐ₄₀₀₇ | L_{b126} |
| 1391 | Lₐ₈₇₄ | L_{b126} | 1392 | Lₐ₄₀₁₉ | L_{b126} |
| 1393 | Lₐ₈₇₅ | L_{b126} | 1394 | Lₐ₄₀₂₃ | L_{b126} |
| 1395 | Lₐ₈₉₁ | L_{b126} | 1396 | Lₐ₄₀₂₄ | L_{b126} |
| 1397 | Lₐ₈₉₂ | L_{b126} | 1398 | Lₐ₄₀₂₅ | L_{b126} |
| 1399 | Lₐ₈₉₃ | L_{b126} | 1400 | Lₐ₄₀₂₆ | L_{b126} |
| 1401 | Lₐ₈₉₄ | L_{b126} | 1402 | Lₐ₄₀₂₇ | L_{b126} |
| 1403 | Lₐ₈₉₅ | L_{b126} | 1404 | Lₐ₄₀₂₈ | L_{b126} |
| 1405 | Lₐ₈₉₆ | L_{b126} | 1406 | Lₐ₄₀₂₉ | L_{b126} |
| 1407 | Lₐ₈₉₇ | L_{b126} | 1408 | Lₐ₄₀₄₁ | L_{b126} |
| 1409 | Lₐ₉₁₀ | L_{b126} | 1410 | Lₐ₄₀₄₉ | L_{b126} |
| 1411 | Lₐ₉₃₂ | L_{b126} | 1412 | Lₐ₄₀₆₁ | L_{b126} |
| 1413 | Lₐ₉₃₆ | L_{b126} | 1414 | Lₐ₄₀₆₈ | L_{b126} |
| 1415 | Lₐ₉₃₇ | L_{b126} | 1416 | Lₐ₄₀₇₀ | L_{b126} |
| 1417 | Lₐ₉₃₈ | L_{b126} | 1418 | Lₐ₄₀₇₁ | L_{b126} |
| 1419 | Lₐ₉₃₉ | L_{b126} | 1420 | Lₐ₄₀₇₃ | L_{b126} |
| 1421 | L₂₉₄₀ | L_{b126} | 1422 | Lₐ₄₀₇₄ | L_{b126} |
| 1423 | Lₐ₉₄₁ | L_{b126} | 1424 | Lₐ₄₀₈₄ | L_{b126} |
| 1425 | Lₐ₉₄₂ | L_{b126} | 1426 | Lₐ₄₁₀₉ | L_{b126} |
| 1427 | Lₐ₉₅₄ | L_{b126} | 1428 | Lₐ₄₁₁₆ | L_{b126} |
| 1429 | Lₐ₉₅₈ | L_{b126} | 1430 | Lₐ₄₁₂₉ | L_{b126} |
| 1431 | Lₐ₉₅₉ | L_{b126} | 1432 | Lₐ₄₁₅₁ | L_{b126} |
| 1433 | Lₐ₉₆₀ | L_{b126} | 1434 | Lₐ₄₁₅₂ | L_{b126} |
| 1435 | Lₐ₉₆₁ | L_{b126} | 1436 | Lₐ₄₁₅₆ | L_{b126} |
| 1437 | Lₐ₉₆₂ | L_{b126} | 1438 | Lₐ₄₁₆₀ | L_{b126} |
| 1439 | Lₐ₉₆₃ | L_{b126} | 1440 | Lₐ₄₁₇₄ | L_{b126} |
| 1441 | Lₐ₉₆₄ | L_{b126} | 1442 | Lₐ₄₁₈₈ | L_{b126} |
| 1443 | Lₐ₉₇₁ | L_{b126} | 1444 | Lₐ₄₉₁ | L_{b126} |
| 1445 | Lₐ₉₇₄ | L_{b126} | 1446 | Lₐ₄₂₀₄ | L_{b126} |
| 1447 | Lₐ₉₇₈ | L_{b126} | 1448 | Lₐ₄₂₁₈ | L_{b126} |
| 1449 | Lₐ₉₈₅ | L_{b126} | 1450 | Lₐ₄₂₂₅ | L_{b126} |
| 1451 | Lₐ₉₈₆ | L_{b126} | 1452 | Lₐ₄₂₃₄ | L_{b126} |
| 1453 | Lₐ₉₉₆ | L_{b126} | 1454 | Lₐ₄₂₄₁ | L_{b126} |
| 1455 | Lₐ₁₀₀₀ | L_{b126} | 1456 | Lₐ₄₂₅₇ | L_{b126} |
| 1457 | Lₐ₁₀₀₁ | L_{b126} | 1458 | Lₐ₄₂₆₂ | L_{b126} |
| 1459 | Lₐ₁₀₀₇ | L_{b126} | 1460 | Lₐ₄₂₇₂ | L_{b126} |
| 1461 | Lₐ₁₀₀₈ | L_{b126} | 1462 | Lₐ₄₂₈₂ | L_{b126} |
| 1463 | Lₐ₁₀₀₉ | L_{b126} | 1464 | Lₐ₄₂₉₁ | L_{b126} |
| 1465 | Lₐ₁₀₁₀ | L_{b126} | 1466 | Lₐ₄₂₉₃ | L_{b126} |
| 1467 | Lₐ₁₀₁₂ | L_{b126} | 1468 | Lₐ₄₃₀₁ | L_{b126} |
| 1469 | Lₐ₁₀₁₈ | L_{b126} | 1470 | Lₐ₄₃₀₈ | L_{b126} |
| 1471 | Lₐ₁₀₂₂ | L_{b126} | 1472 | Lₐ₄₃₁₃ | L_{b126} |
| 1473 | Lₐ₁₀₂₃ | L_{b126} | 1474 | Lₐ₄₃₁₆ | L_{b126} |
| 1475 | Lₐ₁₀₂₉ | L_{b126} | 1476 | Lₐ₄₃₂₁ | L_{b126} |
| 1477 | Lₐ₁₀₃₀ | L_{b126} | 1478 | Lₐ₄₃₃₃ | L_{b126} |
| 1479 | Lₐ₁₀₃₁ | L_{b126} | 1480 | Lₐ₄₃₃₄ | L_{b126} |
| 1481 | Lₐ₁₀₄₂ | L_{b126} | 1482 | Lₐ₄₃₄₆ | L_{b126} |
| 1483 | Lₐ₁₀₄₄ | L_{b126} | 1484 | Lₐ₄₃₄₇ | L_{b126} |
| 1485 | Lₐ₁₀₅₂ | L_{b126} | 1486 | Lₐ₄₃₅₈ | L_{b126} |
| 1487 | Lₐ₁₀₆₂ | L_{b126} | 1488 | Lₐ₄₃₆₀ | L_{b126} |
| 1489 | Lₐ₁₀₆₅ | L_{b126} | 1490 | Lₐ₄₃₆₈ | L_{b126} |
| 1491 | Lₐ₁₀₆₆ | L_{b126} | 1492 | Lₐ₄₃₈₆ | L_{b126} |
| 1493 | Lₐ₁₀₇₄ | L_{b126} | 1494 | Lₐ₄₄₁₀ | L_{b126} |
| 1495 | Lₐ₁₀₈₄ | L_{b126} | 1496 | Lₐ₄₄₂₉ | L_{b126} |
| 1497 | Lₐ₁₁₅₀ | L_{b126} | 1498 | Lₐ₄₄₃₁ | L_{b126} |
| 1499 | Lₐ₁₁₅₂ | L_{b126} | 1500 | Lₐ₄₄₃₉ | L_{b126} |
| 1501 | Lₐ₁₁₅₂ | L_{b126} | 1502 | Lₐ₄₄₄₆ | L_{b126} |
| 1503 | Lₐ₁₁₅₄ | L_{b126} | 1504 | Lₐ₄₄₆₀ | L_{b126} |
| 1505 | Lₐ₁₁₅₈ | L_{b126} | 1506 | Lₐ₄₄₈₀ | L_{b126} |
| 1507 | Lₐ₁₁₇₂ | L_{b126} | 1508 | Lₐ₁₁₈₆ | L_{b126} |
| 1509 | Lₐ₁₁₇₃ | L_{b126} | 1510 | Lₐ₁₂₂₁ | L_{b126} |
| 1511 | Lₐ₁₁₇₆ | L_{b126} | 1512 | Lₐ₁₀₆₈ | L_{b126} |
| 1513 | Lₐ₁₁₈₃ | L_{b126} | 1514 | Lₐ₉₈₁ | L_{b126} |
| 1515 | Lₐ₁₁₈₄ | L_{b126} | 1516 | Lₐ₄₂₄₀ | L_{b126} |
| 1517 | Lₐ₁₁₉₈ | L_{b126} | 1518 | Lₐ₈₉₀ | L_{b126} |
| 1519 | Lₐ₁₂₀₅ | L_{b126} | 1520 | Lₐ₃₈₇₈ | L_{b126} |
| 1521 | Lₐ₁₂₀₆ | L_{b126} | 1522 | Lₐ₃₄₆₅ | L_{b126} |
| 1523 | Lₐ₁₂₂₀ | L_{b126} | 1524 | Lₐ₇₈₀ | L_{b126} |

wherein Compound 1525 to Compound 1592 each have a structure of Ir(Lₐ)₂(L_{b}), wherein the two Lₐ are different, and the two Lₐ and L_{b} are selected from the structures listed in the following table, respectively:

| Compound | | | |
|---|---|---|---|
| No. | Lₐ | Lₐ | L_{b} |
| 1525 | Lₐ₁ | Lₐ₈ | L_{b57} |
| 1526 | Lₐ₃₁₂ | Lₐ₂₁₄ | L_{b57} |
| 1527 | Lₐ₄ | Lₐ₁₅ | L_{b57} |
| 1528 | Lₐ₃₁₆ | Lₐ₂₂₈ | L_{b57} |
| 1529 | Lₐ₈ | Lₐ₁₆ | L_{b57} |
| 1530 | Lₐ₃₁₇ | Lₐ₂₃₅ | L_{b57} |
| 1531 | Lₐ₁₅ | Lₐ₂₆ | L_{b57} |
| 1532 | Lₐ₃₂₁ | Lₐ₂₃₆ | L_{b57} |
| 1533 | Lₐ₁₆ | Lₐ₃₀ | L_{b57} |
| 1534 | Lₐ₃₂₂ | Lₐ₂₅₀ | L_{b57} |
| 1535 | Lₐ₂₆ | Lₐ₃₁ | L_{b57} |
| 1536 | Lₐ₃₂₃ | Lₐ₂₅₇ | L_{b57} |
| 1537 | Lₐ₃₀ | Lₐ₃₇ | L_{b88} |
| 1538 | Lₐ₃₂₄ | Lₐ₂₅₈ | L_{b88} |
| 1539 | Lₐ₃₁ | Lₐ₃₈ | L_{b88} |
| 1540 | Lₐ₃₂₅ | Lₐ₂₆₈ | L_{b88} |
| 1541 | Lₐ₃₇ | Lₐ₃₉ | L_{b88} |
| 1542 | Lₐ₃₃₆ | Lₐ₂₇₂ | L_{b88} |
| 1543 | Lₐ₃₈ | Lₐ₄₀ | L_{b88} |
| 1544 | Lₐ₃₃₈ | Lₐ₂₇₆ | L_{b88} |
| 1545 | Lₐ₃₉ | Lₐ₄₂ | L_{b88} |
| 1546 | Lₐ₃₄₂ | Lₐ₂₇₉ | L_{b88} |
| 1547 | Lₐ₄₀ | Lₐ₄₈ | L_{b88} |
| 1548 | Lₐ₃₄₃ | Lₐ₂₈₀ | L_{b88} |
| 1549 | Lₐ₄₂ | Lₐ₅₂ | L_{b88} |
| 1550 | Lₐ₃₄₄ | Lₐ₂₈₁ | L_{b88} |
| 1551 | Lₐ₄₈ | Lₐ₅₃ | L_{b122} |
| 1552 | Lₐ₃₄₅ | Lₐ₂₉₀ | L_{b122} |
| 1553 | Lₐ₅₂ | Lₐ₅₉ | L_{b122} |
| 1554 | Lₐ₃₄₆ | Lₐ₁₅₂₉ | L_{b122} |
| 1555 | Lₐ₅₃ | Lₐ₆₀ | L_{b122} |
| 1556 | Lₐ₃₄₇ | Lₐ₁₅₃₇ | L_{b122} |
| 1557 | Lₐ₅₉ | Lₐ₆₁ | L_{b122} |
| 1558 | Lₐ₃₄₈ | Lₐ₁₆₃₉ | L_{b122} |
| 1559 | Lₐ₆₀ | Lₐ₇₂ | L_{b122} |
| 1560 | Lₐ₃₆₀ | Lₐ₁₆₈₃ | L_{b122} |
| 1561 | Lₐ₆₁ | Lₐ₇₄ | L_{b122} |
| 1562 | Lₐ₃₆₈ | Lₐ₁₇₇₁ | L_{b122} |
| 1563 | Lₐ₇₂ | Lₐ₈₂ | L_{b122} |
| 1564 | Lₐ₄₀₄ | Lₐ₁₈₁₅ | L_{b122} |
| 1565 | Lₐ₇₄ | Lₐ₉₂ | L_{b126} |
| 1566 | Lₐ₄₀₈ | Lₐ₁₈₂₃ | L_{b126} |
| 1567 | Lₐ₈₂ | Lₐ₉₅ | L_{b126} |
| 1568 | Lₐ₄₀₉ | Lₐ₁₈₈₁ | L_{b126} |
| 1569 | Lₐ₉₂ | Lₐ₉₆ | L_{b126} |
| 1570 | Lₐ₄₁₀ | Lₐ₁₈₈₉ | L_{b126} |
| 1571 | Lₐ₉₅ | Lₐ₁₀₄ | L_{b126} |
| 1572 | Lₐ₄₁₁ | Lₐ₁₉₀₃ | L_{b126} |
| 1573 | Lₐ₉₆ | Lₐ₁₁₄ | L_{b126} |
| 1574 | Lₐ₄₁₂ | Lₐ₁₉₁₀ | L_{b126} |
| 1575 | Lₐ₄₅₂ | Lₐ₁₁₈ | L_{b126} |
| 1576 | Lₐ₄₁₃ | Lₐ₁₉₁₁ | L_{b126} |
| 1577 | Lₐ₄₅₃ | Lₐ₁₈₀ | L_{b126} |
| 1578 | Lₐ₄₁₄ | Lₐ₁₉₃₃ | L_{b126} |
| 1579 | Lₐ₄₅₄ | Lₐ₁₈₂ | L_{b212} |
| 1580 | Lₐ₄₂₆ | Lₐ₁₉₄₈ | L_{b212} |
| 1581 | Lₐ₄₅₅ | Lₐ₁₈₄ | L_{b212} |
| 1582 | Lₐ₄₃₂ | Lₐ₁₉₇₀ | L_{b212} |
| 1583 | Lₐ₄₅₆ | Lₐ₁₈₈ | L_{b212} |
| 1584 | Lₐ₄₃₃ | Lₐ₁₉₉₂ | L_{b212} |
| 1585 | Lₐ₄₅₇ | Lₐ₂₀₂ | L_{b212} |
| 1586 | Lₐ₄₃₄ | Lₐ₂₀₁₄ | L_{b212} |
| 1587 | Lₐ₄₅₈ | Lₐ₂₀₃ | L_{b212} |
| 1588 | Lₐ₄₃₅ | Lₐ₂₀₃₂ | L_{b212} |
| 1589 | Lₐ₃₆₈₅ | Lₐ₂₀₆ | L_{b212} |
| 1590 | Lₐ₄₃₆ | Lₐ₂₀₃₆ | L_{b212} |
| 1591 | Lₐ₄₂₄₁ | Lₐ₂₁₃ | L_{b212} |
| 1592 | Lₐ₄₄₈ | Lₐ₂₀₅₄ | L_{b212}; |

wherein Compound 1593 to Compound 1610 each have a structure of Ir(Lₐ)(L_{c})₂, wherein the two L_{c} are identical, and Lₐ and L_{c} are selected from the structures listed in the following table, respectively:

| Compound No. | Lₐ | L_{c} | Compound No. | Lₐ | L_{c} |
|---|---|---|---|---|---|
| 1593 | Lₐₗ | _{Lc1} | 1594 | Lₐ₃₉₃₉ | L_{c1} |
| 1595 | Lₐ₉₂ | L_{c1} | 1596 | Lₐ₄₁₄₂ | L_{cl} |
| 1597 | Lₐ₉₆ | L_{c1} | 1598 | Lₐ₃₉₁₇ | L_{c1} |
| 1599 | Lₐ₃₁₆ | L_{c39} | 1600 | Lₐ₄₀₀₁ | L_{c39} |
| 1601 | Lₐ₄₈₀ | L_{c39} | 1602 | Lₐ₄₃₁₆ | L_{c39} |
| 1603 | Lₐ₅₂₂ | L_{c39} | 1604 | Lₐ₃₅₁₁ | L_{c39} |
| 1605 | Lₐ₈₅₀ | L_{c60} | 1606 | Lₐ₂₃₀₀ | L_{c60} |
| 1607 | Lₐ₁₀₈₃ | L_{c60} | 1608 | Lₐ₃₅₇₉ | L_{c60} |
| 1609 | Lₐ₂₀₅₈ | L_{c60} | 1610 | Lₐ₉₇₁ | L_{c60} |

wherein Compound 1611 to Compound 1628 each have a structure of Ir(Lₐ)(L_{c})₂, wherein the two L_{c} are different, and Lₐ and the two L_{c} are selected from the structures listed in the following table, respectively:

| Compound | | | |
|---|---|---|---|
| No. | Lₐ | L_{c} | L_{c} |
| 1611 | Lₐ₁ | L_{c1} | L_{c39} |
| 1612 | Lₐ₃₉₃₉ | L_{c1} | L_{c60} |
| 1613 | Lₐ₉₂ | L_{c1} | L_{c125} |
| 1614 | Lₐ₄₁₄₂ | L_{c1} | L_{c150} |
| 1615 | Lₐ₉₆ | L_{c39} | L_{c60} |
| 1616 | Lₐ₃₉₁₇ | L_{c39} | L_{c125} |
| 1617 | Lₐ₃₁₆ | L_{c1} | L_{c39} |
| 1618 | Lₐ₄₀₀₁ | L_{c1} | L_{c60} |
| 1619 | Lₐ₄₈₀ | L_{c1} | L_{c125} |
| 1620 | Lₐ₄₃₁₆ | L_{c1} | L_{c150} |
| 1621 | Lₐ₅₂₂ | L_{c39} | L_{c60} |
| 1622 | Lₐ₃₅₁₁ | L_{c39} | L_{c125} |
| 1623 | Lₐ₈₅₀ | L_{c1} | L_{c39} |
| 1624 | Lₐ₂₃₀₀ | L_{c1} | L_{c60} |
| 1625 | Lₐ₁₀₈₃ | L_{c1} | L_{c125} |
| 1626 | Lₐ₃₅₇₉ | L_{c1} | L_{c150} |
| 1627 | Lₐ₂₀₅₈ | L_{c39} | L_{c60} |
| 1628 | Lₐ₉₇₁ | L_{c39} | L_{c125}; |

wherein Compound 1629 to Compound 1646 each have a structure of Ir(Lₐ)(L_{b})(L_{c}), wherein Lₐ, L_{b} and L_{c} are selected from the structures listed in the following table, respectively:

| Compound | | | |
|---|---|---|---|
| No. | Lₐ | L_{c} | L_{c} |
| 1629 | Lₐ₁ | L_{b31} | L_{c1} |
| 1630 | Lₐ₃₉₃₉ | L_{b57} | L_{c1} |
| 1631 | Lₐ₉₂ | L_{b88} | L_{c1} |
| 1632 | Lₐ₄₁₄₂ | L_{b122} | L_{c1} |
| 1633 | Lₐ₉₆ | L_{b126} | L_{c1} |
| 1634 | Lₐ₃₉₁₇ | L_{b212} | L_{c1} |
| 1635 | Lₐ₃₁₆ | L_{b31} | L_{c1} |
| 1636 | Lₐ₄₀₀₁ | L_{b57} | L_{c1} |
| 1637 | Lₐ₄₈₀ | L_{b88} | L_{c1} |
| 1638 | Lₐ₄₃₁₆ | L_{b122} | L_{c1} |
| 1639 | Lₐ₅₂₂ | L_{b126} | L_{c1} |
| 1640 | Lₐ₃₅₁₁ | L_{b212} | L_{c1} |
| 1641 | Lₐ₈₅₀ | L_{b31} | L_{c1} |
| 1642 | Lₐ₂₃₀₀ | L_{b57} | L_{c1} |
| 1643 | Lₐ₁₀₈₃ | L_{b88} | L_{c1} |
| 1644 | Lₐ₃₅₇₉ | L_{b122} | L_{c1} |
| 1645 | Lₐ₂₀₅₈ | L_{b126} | L_{c1} |
| 1646 | Lₐ₉₇₁ | L_{b212} | L_{c1}. |

21. An electroluminescent device, comprising:
an anode,
a cathode, and
an organic layer disposed between the anode and the cathode, wherein the organic layer comprises the metal complex according to claim 1.

22. The electrolumine scent device according to claim 21, wherein the organic layer is a light-emitting layer, and the metal complex is a light-emitting material.

23. The electroluminescent device according to claim 21, wherein the electroluminescent device emits red light or white light.

24. The electrolumine scent device according to claim 22, wherein the light-emitting layer further comprises at least one host material; and
preferably, the at least one host material comprises at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene and combinations thereof.

25. A compound composition, comprising the metal complex according to claim 1.
